(19) United States
(12) Patent Application Publication
(10) Pub. No.: US 2023/0058635 A1
(43) Pub. Date: Feb. 23, 2023

(54) ELECTRONIC DEVICE

(71) Applicant: Merck Patent GmbH, Darmstadt (DE)

(72) Inventors: Florian MAIER-FLAIG, Weinheim (DE); Christian EICKHOFF, Mannheim (DE); Frank VOGES, Bad Duerkheim (DE); Elvira MONTENEGRO, Weinheim (DE); Teresa MUJICA-FERNAUD, Darmstadt (DE); Rémi Manouk ANÉMIAN, Frankfurt am Main (DE); Aaron LACKNER, Mannheim (DE); Jens ENGELHART, Darmstadt (DE)

(21) Appl. No.: 17/298,544

(22) PCT Filed: Oct. 28, 2019
(86) PCT No.: PCT/EP2019/079334

§ 371 Date: May 29, 2021

(30) Foreign Application Priority Data
Nov. 29, 2018 (EP) 18209042.3

(51) Int. Cl. H01L 51/00

(52) U.S. Cl. CPC H01L 51/0072; H01L 51/0061; H01L 51/0067; H01L 51/0058; H01L 51/0094; H01L 51/56; H01L 51/0056; H01L 51/006; H01L 51/0073; H01L 51/0074; H01L 51/0055

(57) ABSTRACT

The present application relates to an electronic device, to the use thereof, and to a process for production thereof.

The present application relates to an electronic device comprising particular amine compounds in a hole-transporting layer, and comprising emitting compounds of a particular structure type in an emitting layer.

Electronic devices in the context of this application are understood to mean what are called organic electronic devices, which contain organic semiconductor materials as functional materials. More particularly, these are understood to mean OLEDs (organic electroluminescent devices). The term OLEDs is understood to mean electronic devices which have one or more layers comprising organic compounds and emit light on application of electrical voltage. The construction and general principle of function of OLEDs are known to those skilled in the art.

In electronic devices, especially OLEDs, there is continuing great interest in an improvement in the performance data.

Materials known for hole-transporting layers in electronic devices are a multitude of different materials, most of which form part of the substance class of the triarylamines, for example N,N′-di(1-naphthyl)-N,N′-diphenyl-(1,1′-biphenyl)-4,4′-diamine (NPD) or tris-(4-carbazolyl-9-ylphenyl)amine (TCTA).

Known emitting compounds in electronic devices are likewise a multitude of different compounds. Essentially fluorescent compounds are employed for this use, for example pyreneamines, or phosphorescent compounds typically selected from transition metal complexes with an organometallic bond, especially iridium complexes such as Ir(PPy)₃ (tris[2-phenylpyridinato-C²,N]iridium(III)). Fluorescent compounds used have also been bridged triarylboron compounds with a particular structure. For these compounds, in particular constructions, a high external quantum efficiency has been found when they are used as emitters in OLEDs.

There is therefore a great interest in combining these compounds in a suitable manner with other compounds in other layers of the electronic device in order to achieve good properties of the electronic device, especially in relation to lifetime, efficiency, operating voltage, low roll-off and a narrow emission band, i.e. an emission band with a very short half-height width.

In corresponding studies, it has now been found that the combination of particular spirobifluorenylamines or fluorenylamines in a hole-transporting layer with the abovementioned triarylboron derivatives in an emitting layer leads to particularly good properties of the electronic device, especially long lifetime, high-efficiency, low operating voltage, low roll-off and emission with a minimum half-height width.

The present invention thus provides an electronic device comprising a first electrode, a second electrode and, arranged in between,
an emitting layer E comprising a compound of a formula (E-1)

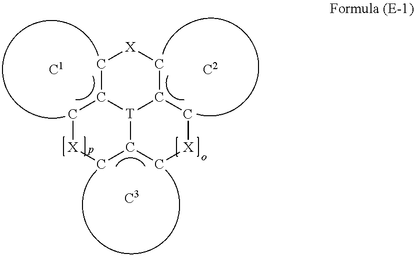

for which:

T is B, P, P(═O) or SiR^{E1};

X is the same or different at each instance and is selected from O, S, NR^{E2} and C(R^{E2})₂, where there must be at least one X present which is selected from O, S and NR^{E2};

C¹, C² and C³ are the same or different and are selected from ring systems which have 5 to 40 ring atoms and are substituted by R^{E3} radicals;

R^{E1} is selected from H, D, F, Cl, Br, I, C(═O)R^{E4}, CN, Si(R^{E4})₃, N(R^{E4})₂, P(═O)(R^{E4})₂, OR^{E4}, S(═O)R^{E4}, S(═O)₂R^{E4}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where the alkyl, alkoxy, alkenyl and alkynyl groups mentioned and the aromatic ring systems and heteroaromatic ring systems mentioned are each substituted by R^{E4} radicals; and where one or more CH₂ groups in the alkyl, alkoxy, alkenyl and alkynyl groups mentioned may be replaced by —R^{E4}C═CR^{E4}—, —C≡C—, —Si(R^{E4})₂, C═O, C═NR^{E4}, —C(═O)O—, —C(═O)NR^{E4}—, NR^{E4}, P(═O)(R^{E4}), —O—, —S—, SO or SO₂;

R^{E2} is the same or different at each instance and is selected from H, D, F, Cl, Br, I, C(═O)R^{E4}, CN, Si(R^{E4})₃, N(R^{E4})₂, P(═O)(R^{E4})₂, OR^{E4}, S(═O)R^{E4}, S(═O)₂R^{E4}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where the alkyl, alkoxy, alkenyl and alkynyl groups mentioned and the aromatic ring systems and heteroaromatic ring systems mentioned are each substituted by R^{E4} radicals; and where one or more CH₂ groups in the alkyl, alkoxy, alkenyl and alkynyl groups mentioned may be replaced by —R^{E4}C═CR^{E4}—, —C≡C—, Si(R^{E4})₂, C═O, C═NR^{E4}, —C(═O)O—, —C(═O)NR^{E4}—, NR^{E4}, P(═O)(R^{E4}), —O—, —S—, SO or SO₂; where two or more R^{E2} radicals may be joined to one another and may form a ring, and where one or more R^{E2} radicals may be joined via their R^{E4} radicals to a ring selected from C¹, C² and C³ and may form a ring;

R^{E3} is the same or different at each instance and is selected from H, D, F, Cl, Br, I, C(═O)R^{E4}, CN, Si(R^{E4})₃, N(R^{E4})₂, P(═O)(R^{E4})₂, OR^{E4}, S(═O)R^{E4}, S(═O)₂R^{E4}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{E3} radicals may be joined to one another and may form a ring; where the alkyl, alkoxy, alkenyl and alkynyl groups mentioned and the aromatic ring systems and heteroaromatic ring systems mentioned are each substituted by R^{E4} radicals; and where one or more CH₂ groups in the alkyl, alkoxy, alkenyl and alkynyl groups mentioned may be replaced by —R^{E4}C═CR^{E4}—, —C≡C—, Si(R^{E4})₂, C═O, C═NR^{E4}, —C(═O)O—, —C(═O)NR^{E4}—, NR^{E4}, P(═O)(R^{E4}), —O—, —S—, SO or SO₂;

R^{E4} is the same or different at each instance and is selected from H, D, F, Cl, Br, I, C(═O)R^{E5}, CN, Si(R^{E5})₃, N(R^{E5})₂, P(═O)(R^{E5})₂, OR^{E5}, S(═O)R^{E5}, S(═O)₂R^{E5}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{E4} radicals may be joined to one another and may form a ring; where the alkyl, alkoxy, alkenyl and alkynyl groups mentioned and the aromatic ring systems and heteroaromatic ring systems mentioned are each substituted by R^{E5} radicals; and where one or more CH₂ groups in the alkyl, alkoxy, alkenyl and alkynyl groups mentioned may be replaced by —R^{E5}C═CR^{E5}—, —C≡C—, Si(R^{E5})₂, C═O, C═NR^{E5}, —C(═O)O—, —C(═O)NR^{E5}—, NR^{E5}, P(═O)(R^{E5}), —O—, —S—, SO or SO₂;

R^{E5} is the same or different at each instance and is selected from H, D, F, Cl, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R^{E5} radicals may be joined to one another and may form a ring; and where the alkyl, alkoxy, alkenyl and alkynyl groups, aromatic ring systems and heteroaromatic ring systems mentioned may be substituted by one or more radicals selected from F and CN;

o and p are the same or different and are 0 or 1, where p=0 and o=0 mean that the X group indicated by p or o together with its bonds to the rings C¹, C² and C³ is absent;
a layer H1 which is disposed between the first electrode and the emitting layer and contains a compound of a formula (L-1), (L-2) or (L-3)

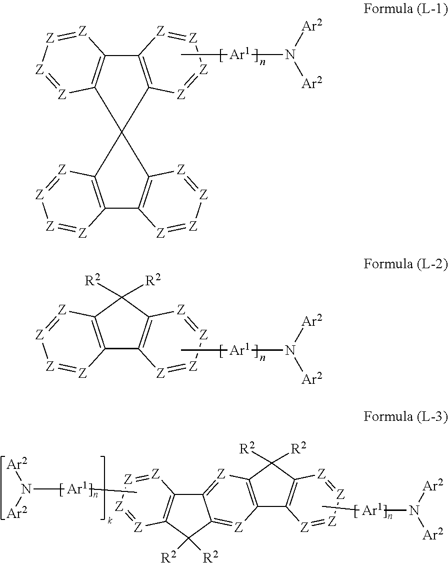

for which:
Z, when a —[Ar¹]ₙ—N(Ar²)₂ group is bonded thereto, is C, and Z, when no —[Ar¹]ₙ—N(Ar²)₂ group is bonded thereto, is the same or different at each instance and is N or CR¹;
Ar¹ is the same or different at each instance and is an aromatic ring system which has 6 to 40 aromatic ring atoms and is substituted by R³ radicals, or a heteroaromatic ring system which has 5 to 40 aromatic ring atoms and is substituted by R³ radicals;
Ar² is the same or different at each instance and is an aromatic ring system which has 6 to 40 aromatic ring atoms and is substituted by R³ radicals, or a heteroaromatic ring system which has 5 to 40 aromatic ring atoms and is substituted by R³ radicals:
R¹ is the same or different at each instance and is selected from H, D, F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R¹ radicals may be joined to one another and may form a ring; where the alkyl, alkoxy, alkenyl and alkynyl groups mentioned and the aromatic ring systems and heteroaromatic ring systems mentioned are each substituted by R⁴ radicals; and where one or more CH₂ groups in the alkyl, alkoxy, alkenyl and alkynyl groups mentioned may be replaced by —R⁴C═CR⁴—, —C≡C—, Si(R⁴)₂, C═0, C═NR⁴, —C(═O)O—, —C(═O)NR⁴—, NR⁴, P(═O)(R⁴), —O—, —S—, SO or SO₂;
R² is the same or different at each instance and is selected from H, D, F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R² radicals may be joined to one another and may form a ring; where the alkyl, alkoxy, alkenyl and alkynyl groups mentioned and the aromatic ring systems and heteroaromatic ring systems mentioned are each substituted by R⁴ radicals; and where one or more CH₂ groups in the alkyl, alkoxy, alkenyl and alkynyl groups mentioned may be replaced by —R⁴C═CR⁴—, —C≡C—, Si(R⁴)₂, C═O, C═NR⁴, —C(═O)O—, —C(═O)NR⁴—, NR⁴, P(═O)(R⁴), —O—, —S—, SO or SO₂;
R³ is the same or different at each instance and is selected from H, D, F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R³ radicals may be joined to one another and may form a ring; where the alkyl, alkoxy, alkenyl and alkynyl groups mentioned and the aromatic ring systems and heteroaromatic ring systems mentioned are each substituted by R⁴ radicals; and where one or more CH₂ groups in the alkyl, alkoxy, alkenyl and alkynyl groups mentioned may be replaced by —R⁴C═CR⁴—, —C≡C—, Si(R⁴)₂, C═O, C═NR⁴, —C(═O)O—, —C(═O)NR⁴—, NR⁴, P(═O)(R⁴), —O—, —S—, SO or SO₂;
R⁴ is the same or different at each instance and is selected from H, D, F, Cl, Br, I, C(═O)R⁵, CN, Si(R⁵)₃, N(R⁵)₂, P(═O)(R⁵)₂, OR⁵, S(═O)R⁵, S(═O)₂R⁵, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁴ radicals may be joined to one another and may form a ring; where the alkyl, alkoxy, alkenyl and alkynyl groups mentioned and the aromatic ring systems and heteroaromatic ring systems mentioned are each substituted by R⁵ radicals; and where one or more CH₂ groups in the alkyl, alkoxy, alkenyl and alkynyl groups mentioned may be replaced by —R⁵C═CR⁵—, —C≡C—, Si(R⁵)₂, C═O, C═NR⁵, —C(═O)O—, —C(═O)NR⁵—, NR⁵, P(═O)(R⁵), —O—, —S—, SO or SO₂;
R⁵ is the same or different at each instance and is selected from H, D, F, C, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R⁵ radicals may be joined to one another and may form a ring; and where the alkyl, alkoxy, alkenyl and alkynyl groups, aromatic ring systems and heteroaromatic ring systems mentioned may be substituted by one or more radicals selected from F and CN;
n is the same or different at each instance and is 0, 1, 2, 3 or 4;
k is 0 or 1;
and
a layer H2 disposed between layer H1 and the emitting layer.

When the index n is 0, this means that the —N(Ar²)₂ group and the spirobifluorenyl or fluorenyl or indenofluorenyl base structure are bonded directly to one another. When the index n is 2, 3 or 4, this means that two, three or four Ar¹ groups are bonded to one another in series.

The “C” groups in formula (E-1) indicate carbon atoms that are part of the ring systems C¹, C² and C³. The arc between the carbon atoms indicates that double bonds are present in such a way that each carbon atom has four bonds and each has three groups bonded thereto.

The definitions which follow are applicable to the chemical groups that are used in the present application. They are applicable unless any more specific definitions are given.

The term “ring system” is understood to mean any desired rings that may be individual rings or a system comprising multiple individual rings fused to one another, as is the case, for example, in decalin or fluorene. The rings may be the same or different and may be aliphatic, heteroaliphatic, aromatic or heteroaromatic. The ring atoms may be selected from carbon and heteroatoms, especially C, O, S, Si, B, P and N.

An aryl group in the context of this invention is understood to mean either a single aromatic cycle, i.e. benzene, or a fused aromatic polycycle, for example naphthalene, phenanthrene or anthracene. A fused aromatic polycycle in the context of the present application consists of two or more single aromatic cycles fused to one another. Fusion between cycles is understood here to mean that the cycles share at least one edge with one another. An aryl group in the context of this invention contains 6 to 40 aromatic ring atoms of which none is a heteroatom.

A heteroaryl group in the context of this invention is understood to mean either a single heteroaromatic cycle, for example pyridine, pyrimidine or thiophene, or a fused heteroaromatic polycycle, for example quinoline or carbazole. A fused heteroaromatic polycycle in the context of the present application consists of two or more single aromatic or heteroaromatic cycles that are fused to one another, where at least one of the aromatic and heteroaromatic cycles is a heteroaromatic cycle. Fusion between cycles is understood here to mean that the cycles share at least one edge with one another. A heteroaryl group in the context of this invention contains 5 to 40 aromatic ring atoms of which at least one is a heteroatom. The heteroatoms of the heteroaryl group are preferably selected from N, O and S.

An aryl or heteroaryl group, each of which may be substituted by the abovementioned radicals, is especially understood to mean groups derived from benzene, naphthalene, anthracene, phenanthrene, pyrene, dihydropyrene, chrysene, perylene, triphenylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, benzimidazolo[1,2-a]benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, pyrazine, phenazine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

An aromatic ring system in the context of this invention is a system which does not necessarily contain solely aryl groups, but which may additionally contain one or more non-aromatic rings fused to at least one aryl group. These non-aromatic rings contain exclusively carbon atoms as ring atoms. Examples of groups covered by this definition are tetrahydronaphthalene, fluorene and spirobifluorene. In addition, the term “aromatic ring system” includes systems that consist of two or more aromatic ring systems joined to one another via single bonds, for example biphenyl, terphenyl, 7-phenyl-2-fluorenyl, quaterphenyl and 3,5-diphenyl-1-phenyl. An aromatic ring system in the context of this invention contains 6 to 40 carbon atoms and no heteroatoms in the ring system. The definition of “aromatic ring system” does not include heteroaryl groups.

A heteroaromatic ring system conforms to the abovementioned definition of an aromatic ring system, except that it must contain at least one heteroatom as ring atom. As is the case for the aromatic ring system, the heteroaromatic ring system need not contain exclusively aryl groups and heteroaryl groups, but may additionally contain one or more non-aromatic rings fused to at least one aryl or heteroaryl group. The nonaromatic rings may contain exclusively carbon atoms as ring atoms, or they may additionally contain one or more heteroatoms, where the heteroatoms are preferably selected from N, O and S. One example of such a heteroaromatic ring system is benzopyranyl. In addition, the term “heteroaromatic ring system” is understood to mean systems that consist of two or more aromatic or heteroaromatic ring systems that are bonded to one another via single bonds, for example 4,6-diphenyl-2-triazinyl. A heteroaromatic ring system in the context of this invention contains 5 to 40 ring atoms selected from carbon and heteroatoms, where at least one of the ring atoms is a heteroatom. The heteroatoms of the heteroaromatic ring system are preferably selected from N, O and S.

The terms “heteroaromatic ring system” and “aromatic ring system” as defined in the present application thus differ from one another in that an aromatic ring system cannot have a heteroatom as ring atom, whereas a heteroaromatic ring system must have at least one heteroatom as ring atom. This heteroatom may be present as a ring atom of a non-aromatic heterocyclic ring or as a ring atom of an aromatic heterocyclic ring.

In accordance with the above definitions, any aryl group is covered by the term “aromatic ring system”, and any heteroaryl group is covered by the term “heteroaromatic ring system”.

An aromatic ring system having 6 to 40 aromatic ring atoms or a heteroaromatic ring system having 5 to 40 aromatic ring atoms is especially understood to mean groups derived from the groups mentioned above under aryl groups and heteroaryl groups, and from biphenyl, terphenyl, quaterphenyl, fluorene, spirobifluorene, dihydrophenanthrene, dihydropyrene, tetrahydropyrene, indenofluorene, truxene, isotruxene, spirotruxene, spiroisotruxene, indenocarbazole, or from combinations of these groups.

In the context of the present invention, a straight-chain alkyl group having 1 to 20 carbon atoms and a branched or cyclic alkyl group having 3 to 20 carbon atoms and an alkenyl or alkynyl group having 2 to 40 carbon atoms in which individual hydrogen atoms or CH₂ groups may also be substituted by the groups mentioned above in the definition of the radicals are preferably understood to mean the methyl, ethyl, n-propyl, i-propyl, n-butyl, i-butyl, s-butyl, t-butyl, 2-methylbutyl, n-pentyl, s-pentyl, cyclopentyl, neopentyl, n-hexyl, cyclohexyl, neohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl or octynyl radicals.

An alkoxy or thioalkyl group having 1 to 20 carbon atoms in which individual hydrogen atoms or CH₂ groups may also be replaced by the groups mentioned above in the definition of the radicals is preferably understood to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy, 2,2,2-trifluoroethoxy, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclooctylthio, 2-ethylhexylthio, trifluoromethylthio, pentafluoroethylthio, 2,2,2-trifluoroethylthio, ethenylthio, propenylthio, butenylthio, pentenylthio, cyclopentenylthio, hexenylthio, cyclohexenylthio, heptenylthio, cycloheptenylthio, octenylthio, cyclooctenylthio, ethynylthio, propynylthio, butynylthio, pentynylthio, hexynylthio, heptynylthio or octynylthio.

The wording that two or more radicals together may form a ring, in the context of the present application, shall be understood to mean, inter alia, that the two radicals are joined to one another by a chemical bond. In addition, however, the abovementioned wording should also be understood to mean that, if one of the two radicals is hydrogen, the second radical binds to the position to which the hydrogen atom was bonded, forming a ring.

T is preferably B.

X is preferably the same at each instance. More preferably, X is the same at each instance and is NR^{E2}. More preferably, at least one of the indices o and p is 1, such that at least two X groups are present in the compound, and at least two X groups in the compound are selected from O, S and NR^{E}, more preferably NR^{E}.

C¹, C² and C³ are preferably the same at each instance. They are further preferably selected from ring systems in which the ring atoms are selected from C, Si, N, P, O, S, B. The ring systems may be aliphatic, aromatic, heteroaliphatic or heteroaromatic. Preferably, the individual ring containing the carbon atoms shown in formula (E-1) is aromatic or heteroaromatic, more preferably aromatic.

Preferably, C¹, C² and C³ are aromatic or heteroaromatic, more preferably aromatic. C¹, C² and C³ are preferably the same or different at each instance, preferably the same, and are selected from benzene, naphthalene, fluorene, carbazole, dibenzofuran and dibenzothiophene, each substituted by R^{E3} radicals. More preferably, C¹, C² and C³ are benzene in each case substituted by R^{E3} radicals.

Preferably, R^{E1} is an aromatic or heteroaromatic ring system substituted by one or more R^{E4} radicals.

Preferably, R^{E2} is the same or different at each instance and is selected from straight-chain alkyl groups having 1 to 20 carbon atoms, branched or cyclic alkyl groups having 3 to 20 carbon atoms, aromatic ring systems having 6 to 40 aromatic ring atoms, and heteroaromatic ring systems having 5 to 40 aromatic ring atoms; where the alkyl groups mentioned and the aromatic ring systems and heteroaromatic ring systems mentioned are each substituted by R^{E4} radicals, where two or more R^{E2} radicals may be joined to one another and may form a ring, and where one or more R^{E2} radicals may be joined via their R^{E4} radicals to a ring selected from C¹, C² and C³ and may form a ring. More preferably, R^{E2} is the same or different at each instance and is selected from aromatic ring systems which have 6 to 40 aromatic ring atoms and are each substituted by R^{E4} radicals, where two or more R^{E2} radicals may be joined to one another and may form a ring and where one or more R^{E2} radicals may be joined via their R^{E4} radicals to a ring selected from C¹, C² and C³ and may form a ring.

In a preferred embodiment, the R^{E2} radicals selected are the same at each instance. In addition, in a preferred embodiment, C¹, C², C³ and all R^{E2} radicals are the same, especially phenyl that may have appropriate substitution, in which case preferably all phenyl groups in question have the same substitution.

Preferably, R^{E3} is the same or different at each instance and is selected from H, D, F, CN, Si(R^{E4})₃, N(R^{E4})₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R^{E4} radicals; and where one or more CH₂ groups in the alkyl or alkoxy groups mentioned may be replaced by —C≡C—, —R^{E4}C═CR^{E4}—, Si(R^{E4})₂, C═O, C═NR^{E4}, —NR^{E4}—, —O—, —S—, —C(═O)O— or —C(═O)NR^{E4}—.

More preferably, at least one R^{E3} radical in formula (E-1) is selected from alkyl groups having 1 to 10 carbon atoms, N(R^{E4})₂, aromatic ring systems having 6 to 40 aromatic ring atoms, and heteroaromatic ring systems having 5 to 40 aromatic ring atoms, where the alkyl groups mentioned, the aromatic ring systems mentioned and the heteroaromatic ring systems mentioned are each substituted by R^{E4} radicals. Most preferably, at least one R^{E3} radical in formula (E-1) is selected from alkyl groups which have 1 to 10 carbon atoms and are substituted by R^{E4} radicals, and N(R^{E4})₂.

Preferably, R^{E4} is the same or different at each instance and is selected from H, D, F, CN, Si(R^{E5})₃, N(R^{E5})₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R^{E5} radicals; and where one or more CH₂ groups in the alkyl or alkoxy groups mentioned may be replaced by —C≡C—, —R^{E5}C═CR^{E5}—, Si(R^{E5})₂, C═O, C═NR^{E5}, —NR^{E5}—, —O—, —S—, —C(═O)O— or —C(═O)NR^{E5}—.

Preferably, at least one of the indices o and p is 1. More preferably, one of the indices o and p is 1, and the other of the indices o and p is 0.

Preferably, the compound of the formula (E-1) is a mirror-symmetric compound of a formula (E-1S)

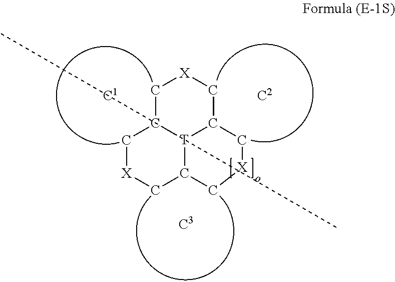

where the X groups selected are the same, the C² and C³ groups selected are the same, and all the groups that occur are selected such that the compound is mirror-symmetric, with a mirror plane that includes the dotted line and is at right angles to the plane of the paper.

In a preferred embodiment of the invention, the compound of the formula (E-1) conforms to the formula (E-1-1)

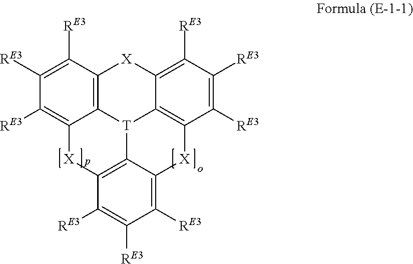

where the variables that occur are as defined above.

In a preferred embodiment, the compound of the formula (E-1-1) conforms to a mirror-symmetric compound of the formula (E-1-1S)

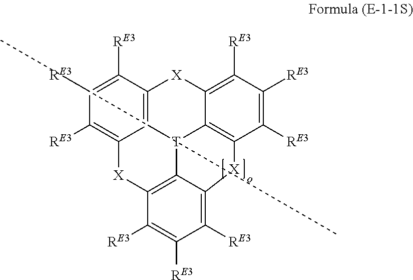

where the X groups selected are the same, and all the groups that occur are selected such that the compound is mirror-symmetric, with a mirror plane that includes the dotted line and is at right angles to the plane of the paper.

In an alternative preferred embodiment, the compound of the formula (E-1-1) is not mirror-symmetric in the mirror plane shown in formula (E-1-1S).

It is especially preferred when, in formula (E-1-1),
T is B, and/or
X is NR^{E2}
one of the indices p and o is 1, and the other of the indices p and o is 0.
at least one R^{E3} radical is selected from alkyl groups having 1 to 10 carbon atoms, N(R^{E4})₂, aromatic ring systems having 6 to 40 aromatic ring atoms, and heteroaromatic ring systems having 5 to 40 aromatic ring atoms, where the alkyl groups mentioned, the aromatic ring systems mentioned and the heteroaromatic ring systems mentioned are each substituted by R^{E4} radicals.

Preferably, in formula (E-1-1), R^{E2} is phenyl substituted by R^{E4} radicals.

Most preferably, at least one R^{E3} radical in formula (E-1-1) is selected from alkyl groups which have 1 to 10 carbon atoms and are substituted by R^{E4} radicals, and N(R^{E4})₂.

Particular preference is given to the formula (E-1-1-1).

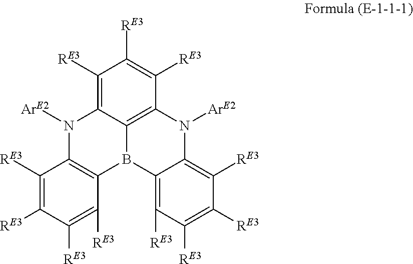

where Ar^{E2} is the same or different at each instance and is selected from aromatic ring systems which have 6 to 40 aromatic ring atoms and are substituted by R^{E4}, and heteroaromatic ring systems which have 5 to 40 aromatic ring atoms and are substituted by R^{E4}, more preferably phenyl or biphenyl, each substituted by R^{E4} radicals. In a preferred embodiment, the Ar^{E2} radicals selected are the same at each instance. In an alternative preferred embodiment, the Ar^{E2} radicals selected are different at each instance.

The other variables that occur are as defined above.

Preferably, in the formula, at least one R^{E3} radical is selected from alkyl groups having 1 to 10 carbon atoms, N(R^{E4})₂, aromatic ring systems having 6 to 40 aromatic ring atoms, and heteroaromatic ring systems having 5 to 40 aromatic ring atoms, where the alkyl groups mentioned, the aromatic ring systems mentioned and the heteroaromatic ring systems mentioned are each substituted by R^{E4} radicals. Most preferably, at least one R^{E3} radical in the formula is selected from alkyl groups which have 1 to 10 carbon atoms and are substituted by R^{E4} radicals, and N(R^{E4})₂.

In a preferred embodiment, the compound of the formula (E-1-1-1) is mirror-symmetric in a mirror plane which is at right angles to the plane of the paper and includes the bond from the boron to the uppermost of the three phenyl groups shown. Preferably, in this case, in formula (E-1-1-1), R^{E2} is phenyl or biphenyl, each substituted by R^{E4} radicals.

In an alternative preferred embodiment, the compound of the formula (E-1-1-1) is not mirror-symmetric in a mirror plane which is at right angles to the plane of the paper and includes the bond from the boron to the uppermost of the three phenyl groups shown. Preferably, in this case, in formula (E-1-1-1), R^{E2} is the same or different and is selected from phenyl and biphenyl, each substituted by R^{E4} radicals.

Very particular preference is given to the formulae (E-1-1-1-1) and (E-1-1-1-2)

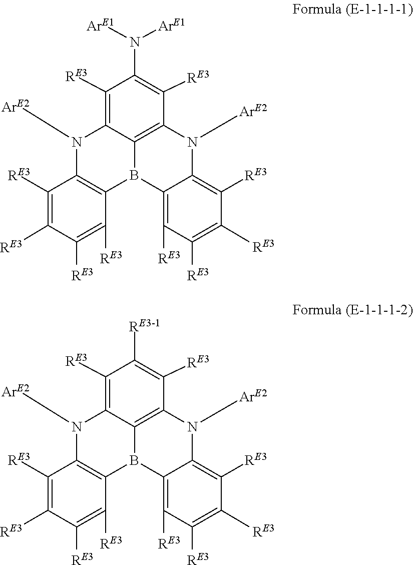

where Ar^{E1} is the same or different at each instance and is selected from aromatic ring systems which have 6 to 40 aromatic ring atoms and are substituted by R^{E5}, and heteroaromatic ring systems which have 5 to 40 aromatic ring atoms and are substituted by R^{E5}, and

where Ar^{E2} is the same or different at each instance and is selected from aromatic ring systems which have 6 to 40 aromatic ring atoms and are substituted by R^{E4}, and heteroaromatic ring systems which have 5 to 40 aromatic ring atoms and are substituted by R^{E4}, more preferably phenyl or biphenyl, each substituted by R^{E4} radicals, and

where R^{E3-1} is selected from alkyl groups which have 1 to 10 carbon atoms and are substituted by R^{E4} radicals, preferably methyl, ethyl, n-propyl, i-propyl and tert-butyl, more preferably methyl.

The other variables that occur are as defined above.

Ar^{E1} is preferably the same or different at each instance and is selected from phenyl, biphenyl, terphenyl, fluorenyl, naphthyl, dibenzofuranyl, dibenzothiophenyl and carbazolyl, each substituted by R^{E5} radicals, and combinations of two or more of these groups. More preferably, Ar^{E1} is the same or different at each instance and is selected from phenyl, o-biphenyl, m-biphenyl, p-biphenyl, terphenyl, p-tolyl, m-tolyl, o-tolyl, p-tert-butyl-phenyl, m-tert-butyl-phenyl, o-tert-butyl-phenyl, 9,9′-dimethylfluorenyl, 9,9′-diphenylfluorenyl, naphthyl, dibenzothiophenyl, dibenzofuranyl, naphthylphenylene, dibenzofuranylphenylene, dibenzothiophenylphenylene, carbazolylphenylene, especially N-carbazolylphenylene.

In a preferred embodiment, the compound of the formula (E-1-1-1-1) or (E-1-1-1-2) is mirror-symmetric in a mirror plane which is at right angles to the plane of the paper and includes the bond from the boron to the uppermost of the three phenyl groups shown. The two Ar^{E1} groups selected may be the same or different and are preferably the same.

In an alternative preferred embodiment, the compound of the formula (E-1-1-1-1) or (E-1-1-1-2) is not mirror-symmetric in a mirror plane which is at right angles to the plane of the paper and includes the bond from the boron to the uppermost of the three phenyl groups shown. The two Ar^{E1} groups selected may be the same or different and are preferably different.

Most preferred are the formulae (E-1-1-1-1-1) and (E-1-1-1-1-2)

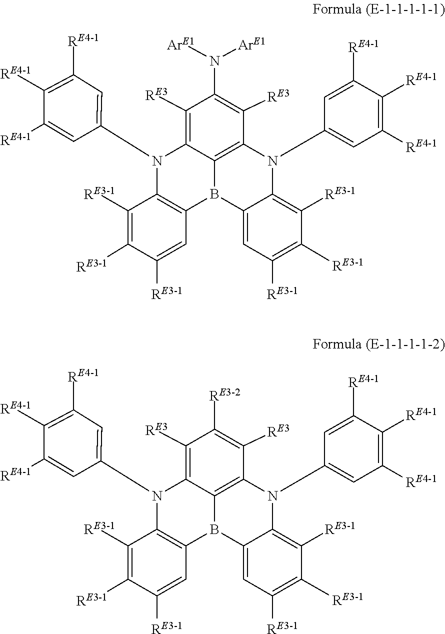

where R^{E3-1} is as defined for R^{E3}; and R^{E3-2} is selected from alkyl groups which have 1 to 10 carbon atoms and are substituted by R^{E4} radicals, preferably methyl, ethyl, isopropyl and tert-butyl, more preferably methyl; and R^{E4-1} is as defined for R^{E4}, and where the other variables are as defined above.

Preferably, in formula (E-1-1-1-1-1) and (E-1-1-1-1-2), R^{E3-1} and R^{E4-1} are the same or different at each instance and are selected from H, alkyl groups which have 1 to 10 carbon atoms and are substituted by R^{E4} or R^{E5} radicals and are preferably unsubstituted, and aromatic ring systems which have 6 to 40 ring atoms and are substituted by R^{E4} or R^{E5} radicals.

Preferably, exactly one or two R^{E3-1} or R^{E4-1} radicals per benzene ring are selected from alkyl groups which have 1 to 10 carbon atoms and are substituted by R^{E4} or R^{E5} radicals and are preferably unsubstituted, and aromatic ring systems which have 6 to 40 ring atoms and are substituted by R^{E4} or R^{E5} radicals, and the other R^{E3-1} or R^{E4-1} radicals are H.

In a preferred embodiment, the units marked by a circle in formula (E-1-1-1-1)

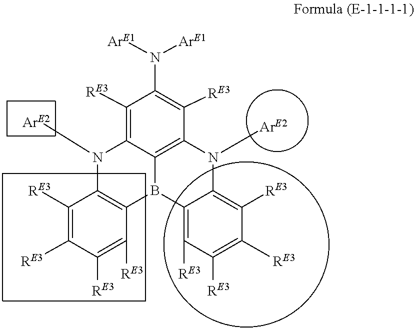

are each the same, and the units marked by a rectangle are likewise each the same. More preferably, all four marked units are the same.

Preferably, the units marked by circle and rectangle are the same or different, preferably the same, and are selected from appropriately substituted benzene, naphthalene, fluorene, dibenzofuran and dibenzothiophene. Particular preference is given to appropriately substituted benzene.

The compound of the formula (E-1-1-1-1) can be depicted as compound A-B containing the two subunits A and B:

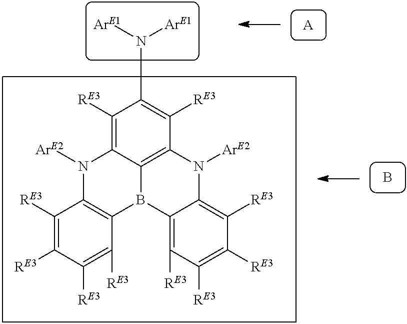

Preferred embodiments of the A unit are as follows (“B” in the formulae refers correspondingly to the B unit):

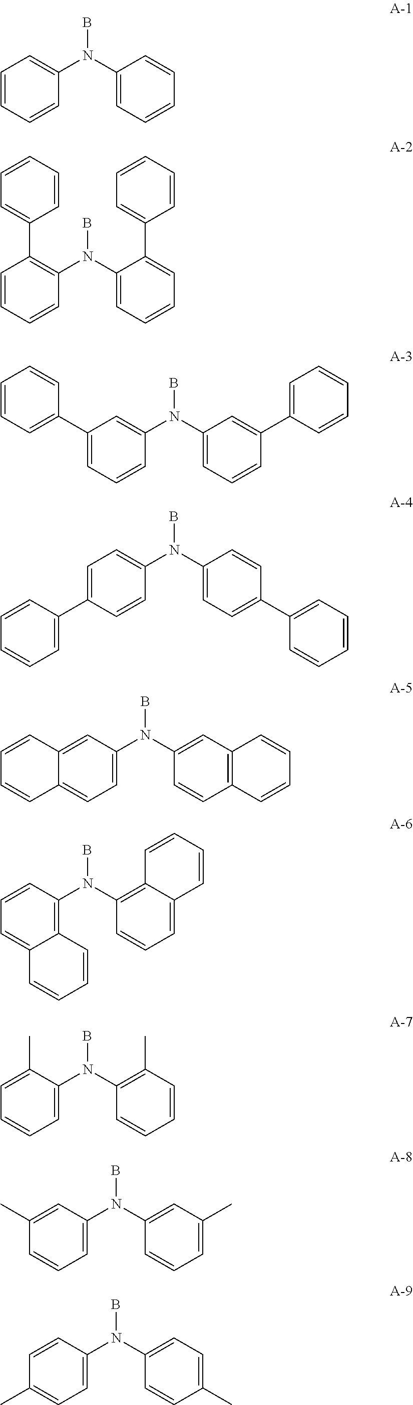

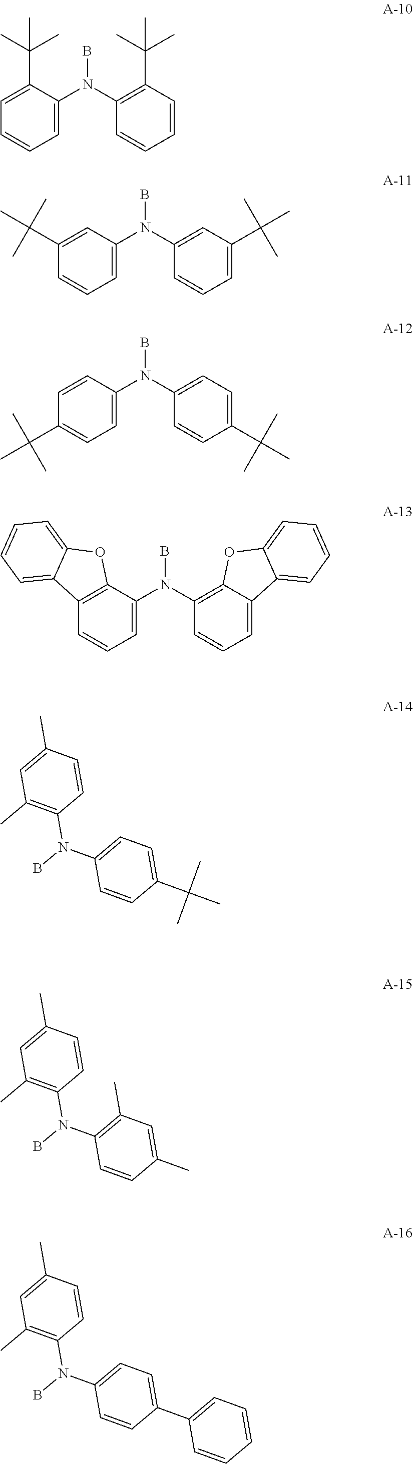

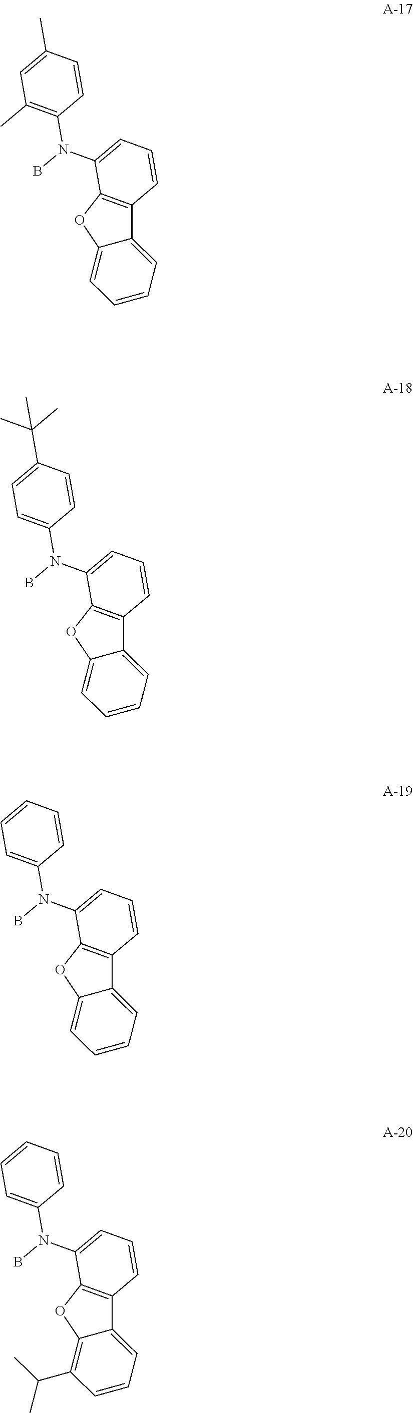

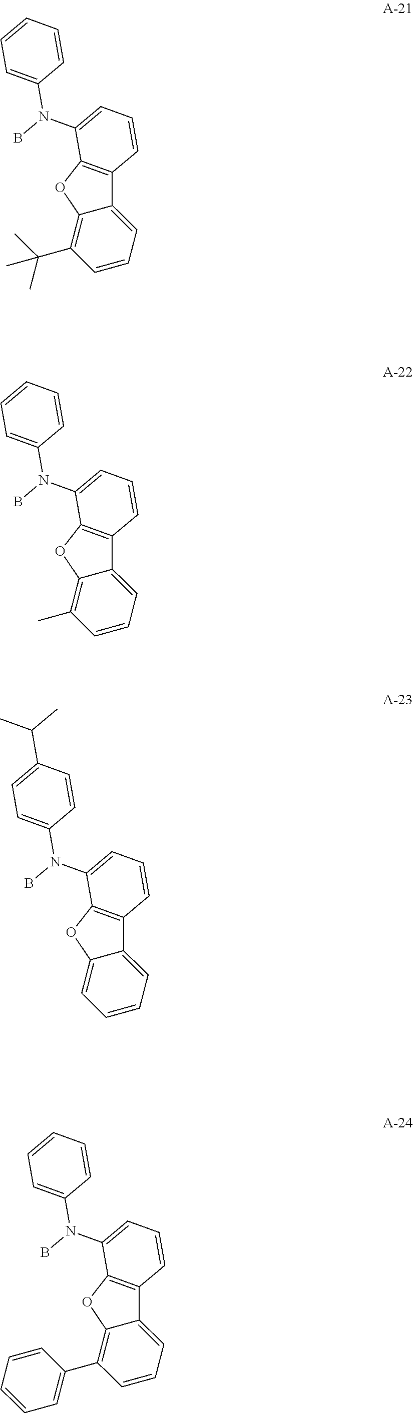

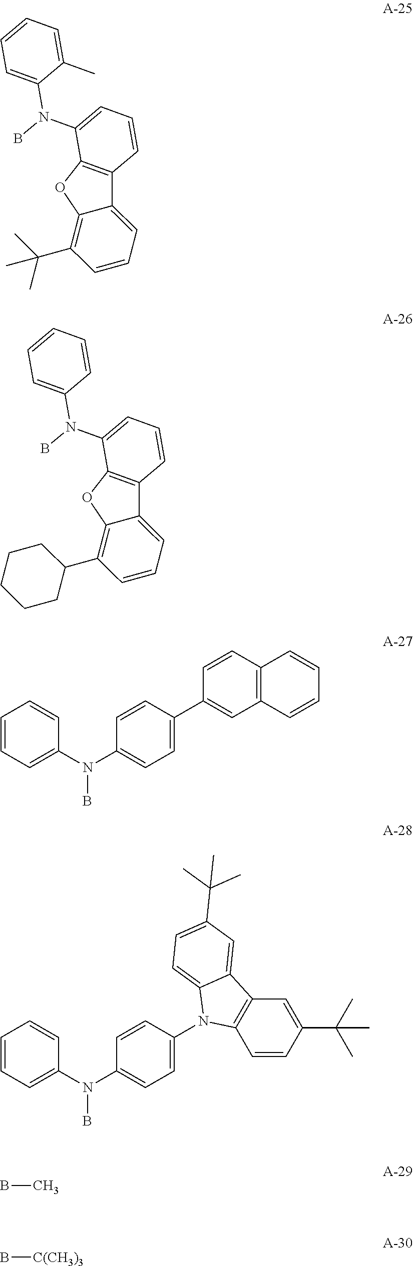

Preferred embodiments of the B unit are as follows (“A” in the formulae refers correspondingly to the A unit):

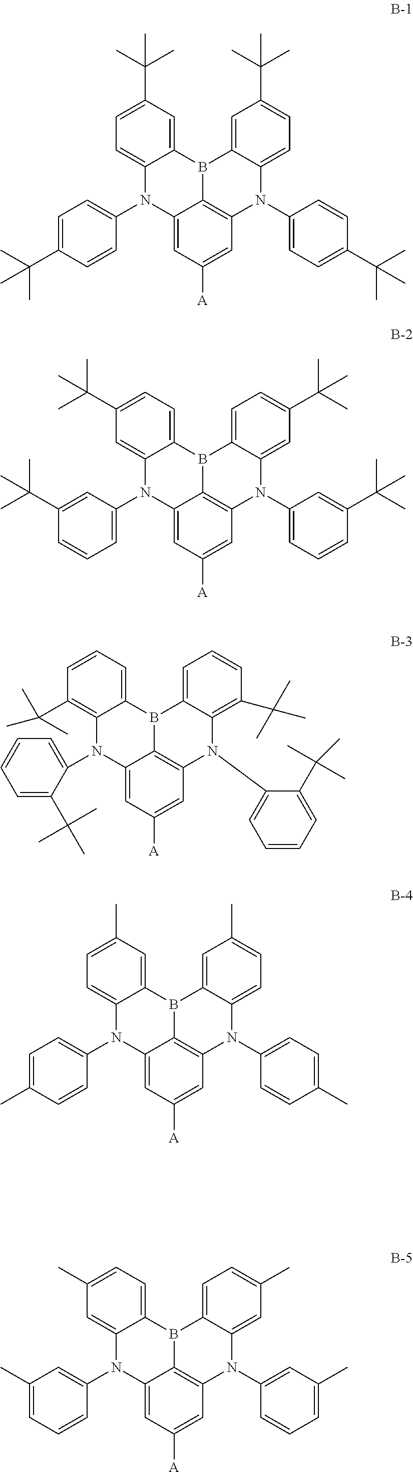

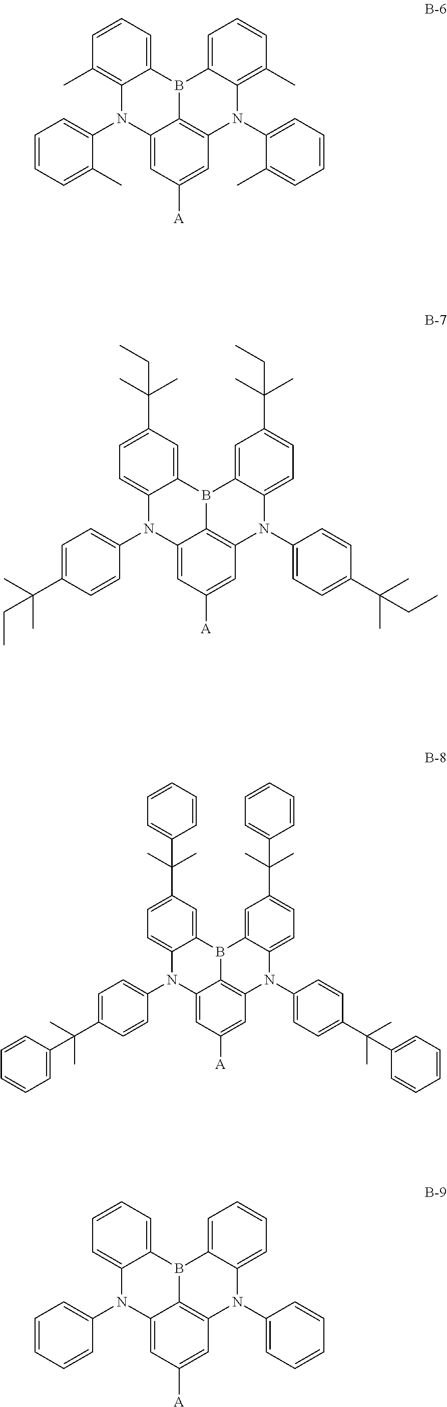

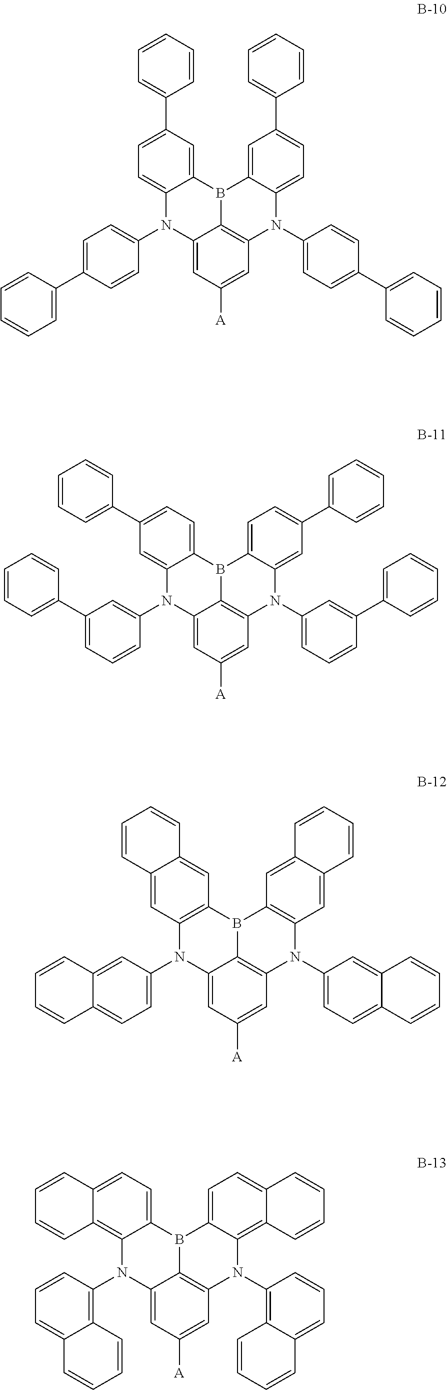

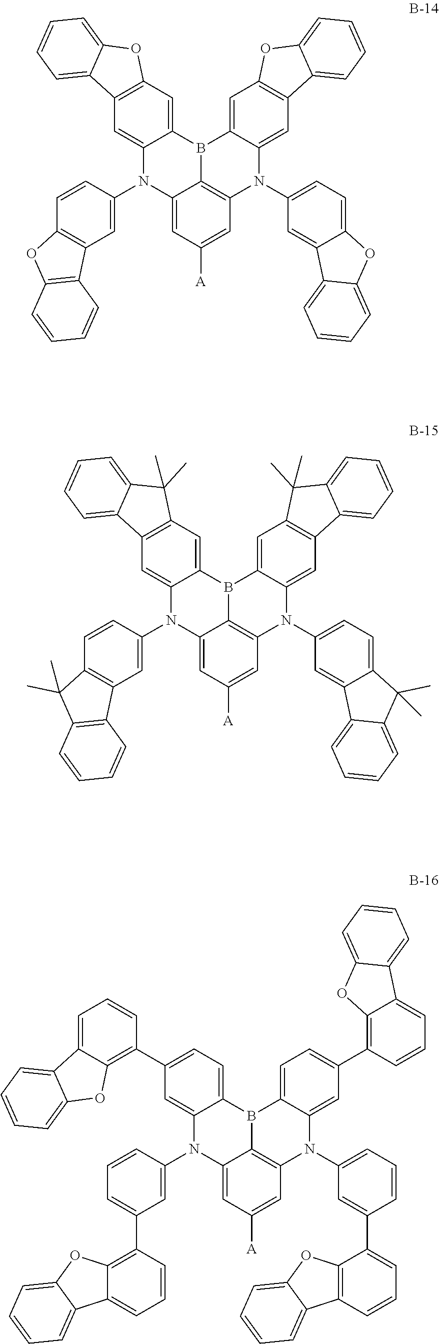

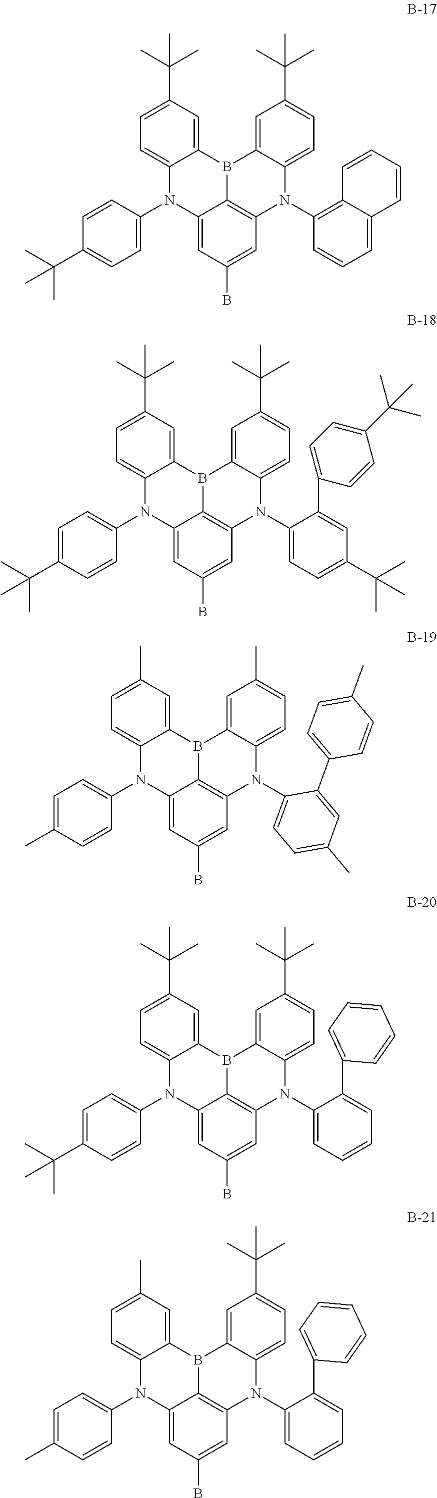

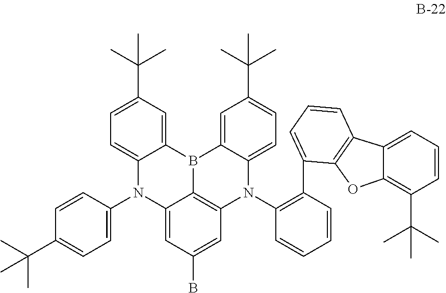

Preferred embodiments of the compounds of the formula (E-1-1-1-1) are those compounds of the following formulae in which part A and part B of the formula are selected as follows:

| Formula | | |
|---|---|---|
| (E-1-1-1-1-X) | | |
| with X= | Part A | Part B |
| 1 | A-1 | B-1 |
| 2 | A-1 | B-2 |
| 3 | A-1 | B-3 |
| 4 | A-1 | B-4 |
| 5 | A-1 | B-5 |
| 6 | A-1 | B-6 |
| 7 | A-1 | B-7 |
| 8 | A-1 | B-8 |
| 9 | A-1 | B-9 |
| 10 | A-1 | B-10 |
| 11 | A-1 | B-11 |
| 12 | A-1 | B-12 |
| 13 | A-1 | B-13 |
| 14 | A-1 | B-14 |
| 15 | A-1 | B-15 |
| 16 | A-1 | B-16 |
| 17 | A-1 | B-17 |
| 18 | A-1 | B-18 |
| 19 | A-1 | B-19 |
| 20 | A-1 | B-20 |
| 21 | A-1 | B-21 |
| 22 | A-1 | B-22 |
| 23 | A-2 | B-1 |
| 24 | A-2 | B-2 |
| 25 | A-2 | B-3 |
| 26 | A-2 | B-4 |
| 27 | A-2 | B-5 |
| 28 | A-2 | B-6 |
| 29 | A-2 | B-7 |
| 30 | A-2 | B-8 |
| 31 | A-2 | B-9 |
| 32 | A-2 | B-10 |
| 33 | A-2 | B-11 |
| 34 | A-2 | B-12 |
| 35 | A-2 | B-13 |
| 36 | A-2 | B-14 |
| 37 | A-2 | B-15 |
| 38 | A-2 | B-16 |
| 39 | A-2 | B-17 |
| 40 | A-2 | B-18 |
| 41 | A-2 | B-19 |
| 42 | A-2 | B-20 |
| 43 | A-2 | B-21 |
| 44 | A-2 | B-22 |
| 45 | A-3 | B-1 |
| 46 | A-3 | B-2 |
| 47 | A-3 | B-3 |
| 48 | A-3 | B-4 |
| 49 | A-3 | B-5 |
| 50 | A-3 | B-6 |
| 51 | A-3 | B-7 |
| 52 | A-3 | B-8 |
| 53 | A-3 | B-9 |
| 54 | A-3 | B-10 |
| 55 | A-3 | B-11 |
| 56 | A-3 | B-12 |
| 57 | A-3 | B-13 |
| 58 | A-3 | B-14 |
| 59 | A-3 | B-15 |
| 60 | A-3 | B-16 |
| 61 | A-3 | B-17 |
| 62 | A-3 | B-18 |
| 63 | A-3 | B-19 |
| 64 | A-3 | B-20 |
| 65 | A-3 | B-21 |
| 66 | A-3 | B-22 |
| 67 | A-4 | B-1 |
| 68 | A-4 | B-2 |
| 69 | A-4 | B-3 |
| 70 | A-4 | B-4 |
| 71 | A-4 | B-5 |
| 72 | A-4 | B-6 |
| 73 | A-4 | B-7 |
| 74 | A-4 | B-8 |
| 75 | A-4 | B-9 |
| 76 | A-4 | B-10 |
| 77 | A-4 | B-11 |
| 78 | A-4 | B-12 |
| 79 | A-4 | B-13 |
| 80 | A-4 | B-14 |
| 81 | A-4 | B-15 |
| 82 | A-4 | B-16 |
| 83 | A-4 | B-17 |
| 84 | A-4 | B-18 |
| 85 | A-4 | B-19 |
| 86 | A-4 | B-20 |
| 87 | A-4 | B-21 |
| 88 | A-4 | B-22 |
| 89 | A-5 | B-1 |
| 90 | A-5 | B-2 |
| 91 | A-5 | B-3 |
| 92 | A-5 | B-4 |
| 93 | A-5 | B-5 |
| 94 | A-5 | B-6 |
| 95 | A-5 | B-7 |
| 96 | A-5 | B-8 |
| 97 | A-5 | B-9 |
| 98 | A-5 | B-10 |
| 99 | A-5 | B-11 |
| 100 | A-5 | B-12 |
| 101 | A-5 | B-13 |
| 102 | A-5 | B-14 |
| 103 | A-5 | B-15 |
| 104 | A-5 | B-16 |
| 105 | A-5 | B-17 |
| 106 | A-5 | B-18 |
| 107 | A-5 | B-19 |
| 108 | A-5 | B-20 |
| 109 | A-5 | B-21 |
| 110 | A-5 | B-22 |
| 111 | A-6 | B-1 |
| 112 | A-6 | B-2 |
| 113 | A-6 | B-3 |
| 114 | A-6 | B-4 |
| 115 | A-6 | B-5 |
| 116 | A-6 | B-6 |
| 117 | A-6 | B-7 |
| 118 | A-6 | B-8 |
| 119 | A-6 | B-9 |
| 120 | A-6 | B-10 |
| 121 | A-6 | B-11 |
| 122 | A-6 | B-12 |
| 123 | A-6 | B-13 |
| 124 | A-6 | B-14 |
| 125 | A-6 | B-15 |
| 126 | A-6 | B-16 |
| 127 | A-6 | B-17 |
| 128 | A-6 | B-18 |
| 129 | A-6 | B-19 |
| 130 | A-6 | B-20 |
| 131 | A-6 | B-21 |
| 132 | A-6 | B-22 |
| 133 | A-7 | B-1 |
| 134 | A-7 | B-2 |
| 135 | A-7 | B-3 |
| 136 | A-7 | B-4 |
| 137 | A-7 | B-5 |
| 138 | A-7 | B-6 |
| 139 | A-7 | B-7 |
| 140 | A-7 | B-8 |
| 141 | A-7 | B-9 |
| 142 | A-7 | B-10 |
| 143 | A-7 | B-11 |
| 144 | A-7 | B-12 |
| 145 | A-7 | B-13 |
| 146 | A-7 | B-14 |
| 147 | A-7 | B-15 |
| 148 | A-7 | B-16 |
| 149 | A-7 | B-17 |
| 150 | A-7 | B-18 |
| 151 | A-7 | B-19 |
| 152 | A-7 | B-20 |
| 153 | A-7 | B-21 |
| 154 | A-7 | B-22 |
| 155 | A-8 | B-1 |
| 156 | A-8 | B-2 |
| 157 | A-8 | B-3 |
| 158 | A-8 | B-4 |
| 159 | A-8 | B-5 |
| 160 | A-8 | B-6 |
| 161 | A-8 | B-7 |
| 162 | A-8 | B-8 |
| 163 | A-8 | B-9 |
| 164 | A-8 | B-10 |
| 165 | A-8 | B-11 |
| 166 | A-8 | B-12 |
| 167 | A-8 | B-13 |
| 168 | A-8 | B-14 |
| 169 | A-8 | B-15 |
| 170 | A-8 | B-16 |
| 171 | A-8 | B-17 |
| 172 | A-8 | B-18 |
| 173 | A-8 | B-19 |
| 174 | A-8 | B-20 |
| 175 | A-8 | B-21 |
| 176 | A-8 | B-22 |
| 177 | A-9 | B-1 |
| 178 | A-9 | B-2 |
| 179 | A-9 | B-3 |
| 180 | A-9 | B-4 |
| 181 | A-9 | B-5 |
| 182 | A-9 | B-6 |
| 183 | A-9 | B-7 |
| 184 | A-9 | B-8 |
| 185 | A-9 | B-9 |
| 186 | A-9 | B-10 |
| 187 | A-9 | B-11 |
| 188 | A-9 | B-12 |
| 189 | A-9 | B-13 |
| 190 | A-9 | B-14 |
| 191 | A-9 | B-15 |
| 192 | A-9 | B-16 |
| 193 | A-9 | B-17 |
| 194 | A-9 | B-18 |
| 195 | A-9 | B-19 |
| 196 | A-9 | B-20 |
| 197 | A-9 | B-21 |
| 198 | A-9 | B-22 |
| 199 | A-10 | B-1 |
| 200 | A-10 | B-2 |
| 201 | A-10 | B-3 |
| 202 | A-10 | B-4 |
| 203 | A-10 | B-5 |
| 204 | A-10 | B-6 |
| 205 | A-10 | B-7 |
| 206 | A-10 | B-8 |
| 207 | A-10 | B-9 |
| 208 | A-10 | B-10 |
| 209 | A-10 | B-11 |
| 210 | A-10 | B-12 |
| 211 | A-10 | B-13 |
| 212 | A-10 | B-14 |
| 213 | A-10 | B-15 |
| 214 | A-10 | B-16 |
| 215 | A-10 | B-17 |
| 216 | A-10 | B-18 |
| 217 | A-10 | B-19 |
| 218 | A-10 | B-20 |
| 219 | A-10 | B-21 |
| 220 | A-10 | B-22 |
| 221 | A-11 | B-1 |
| 222 | A-11 | B-2 |
| 223 | A-11 | B-3 |
| 224 | A-11 | B-4 |
| 225 | A-11 | B-5 |
| 226 | A-11 | B-6 |
| 227 | A-11 | B-7 |
| 228 | A-11 | B-8 |
| 229 | A-11 | B-9 |
| 230 | A-11 | B-10 |
| 231 | A-11 | B-11 |
| 232 | A-11 | B-12 |
| 233 | A-11 | B-13 |
| 234 | A-11 | B-14 |
| 235 | A-11 | B-15 |
| 236 | A-11 | B-16 |
| 237 | A-11 | B-17 |
| 238 | A-11 | B-18 |
| 239 | A-11 | B-19 |
| 240 | A-11 | B-20 |
| 241 | A-11 | B-21 |
| 242 | A-11 | B-22 |
| 243 | A-12 | B-1 |
| 244 | A-12 | B-2 |
| 245 | A-12 | B-3 |
| 246 | A-12 | B-4 |
| 247 | A-12 | B-5 |
| 248 | A-12 | B-6 |
| 249 | A-12 | B-7 |
| 250 | A-12 | B-8 |
| 251 | A-12 | B-9 |
| 252 | A-12 | B-10 |
| 253 | A-12 | B-11 |
| 254 | A-12 | B-12 |
| 255 | A-12 | B-13 |
| 256 | A-12 | B-14 |
| 257 | A-12 | B-15 |
| 258 | A-12 | B-16 |
| 259 | A-12 | B-17 |
| 260 | A-12 | B-18 |
| 261 | A-12 | B-19 |
| 262 | A-12 | B-20 |
| 263 | A-12 | B-21 |
| 264 | A-12 | B-22 |
| 265 | A-13 | B-1 |
| 266 | A-13 | B-2 |
| 267 | A-13 | B-3 |
| 268 | A-13 | B-4 |
| 269 | A-13 | B-5 |
| 270 | A-13 | B-6 |
| 271 | A-13 | B-7 |
| 272 | A-13 | B-8 |
| 273 | A-13 | B-9 |
| 274 | A-13 | B-10 |
| 275 | A-13 | B-11 |
| 276 | A-13 | B-12 |
| 277 | A-13 | B-13 |
| 278 | A-13 | B-14 |
| 279 | A-13 | B-15 |
| 280 | A-13 | B-16 |
| 281 | A-13 | B-17 |
| 282 | A-13 | B-18 |
| 283 | A-13 | B-19 |
| 284 | A-13 | B-20 |
| 285 | A-13 | B-21 |
| 286 | A-13 | B-22 |
| 287 | A-14 | B-1 |
| 288 | A-14 | B-2 |
| 289 | A-14 | B-3 |
| 290 | A-14 | B-4 |
| 291 | A-14 | B-5 |
| 292 | A-14 | B-6 |
| 293 | A-14 | B-7 |
| 294 | A-14 | B-8 |
| 295 | A-14 | B-9 |
| 296 | A-14 | B-10 |
| 297 | A-14 | B-11 |
| 298 | A-14 | B-12 |
| 299 | A-14 | B-13 |
| 300 | A-14 | B-14 |
| 301 | A-14 | B-15 |
| 302 | A-14 | B-16 |
| 303 | A-14 | B-17 |
| 304 | A-14 | B-18 |
| 305 | A-14 | B-19 |
| 306 | A-14 | B-20 |
| 307 | A-14 | B-21 |
| 308 | A-14 | B-22 |
| 309 | A-15 | B-1 |
| 310 | A-15 | B-2 |
| 311 | A-15 | B-3 |
| 312 | A-15 | B-4 |
| 313 | A-15 | B-5 |
| 314 | A-15 | B-6 |
| 315 | A-15 | B-7 |
| 316 | A-15 | B-8 |
| 317 | A-15 | B-9 |
| 318 | A-15 | B-10 |
| 319 | A-15 | B-11 |
| 320 | A-15 | B-12 |
| 321 | A-15 | B-13 |
| 322 | A-15 | B-14 |
| 323 | A-15 | B-15 |
| 324 | A-15 | B-16 |
| 325 | A-15 | B-17 |
| 326 | A-15 | B-18 |
| 327 | A-15 | B-19 |
| 328 | A-15 | B-20 |
| 329 | A-15 | B-21 |
| 330 | A-15 | B-22 |
| 331 | A-16 | B-1 |
| 332 | A-16 | B-2 |
| 333 | A-16 | B-3 |
| 334 | A-16 | B-4 |
| 335 | A-16 | B-5 |
| 336 | A-16 | B-6 |
| 337 | A-16 | B-7 |
| 338 | A-16 | B-8 |
| 339 | A-16 | B-9 |
| 340 | A-16 | B-10 |
| 341 | A-16 | B-11 |
| 342 | A-16 | B-12 |
| 343 | A-16 | B-13 |
| 344 | A-16 | B-14 |
| 345 | A-16 | B-15 |
| 346 | A-16 | B-16 |
| 347 | A-16 | B-17 |
| 348 | A-16 | B-18 |
| 349 | A-16 | B-19 |
| 350 | A-16 | B-20 |
| 351 | A-16 | B-21 |
| 352 | A-16 | B-22 |
| 353 | A-17 | B-1 |
| 354 | A-17 | B-2 |
| 355 | A-17 | B-3 |
| 356 | A-17 | B-4 |
| 357 | A-17 | B-5 |
| 358 | A-17 | B-6 |
| 359 | A-17 | B-7 |
| 360 | A-17 | B-8 |
| 361 | A-17 | B-9 |
| 362 | A-17 | B-10 |
| 363 | A-17 | B-11 |
| 364 | A-17 | B-12 |
| 365 | A-17 | B-13 |
| 366 | A-17 | B-14 |
| 367 | A-17 | B-15 |
| 368 | A-17 | B-16 |
| 369 | A-17 | B-17 |
| 370 | A-17 | B-18 |
| 371 | A-17 | B-19 |
| 372 | A-17 | B-20 |
| 373 | A-17 | B-21 |
| 374 | A-17 | B-22 |
| 375 | A-18 | B-1 |
| 376 | A-18 | B-2 |
| 377 | A-18 | B-3 |
| 378 | A-18 | B-4 |
| 379 | A-18 | B-5 |
| 380 | A-18 | B-6 |
| 381 | A-18 | B-7 |
| 382 | A-18 | B-8 |
| 383 | A-18 | B-9 |
| 384 | A-18 | B-10 |
| 385 | A-18 | B-11 |
| 386 | A-18 | B-12 |
| 387 | A-18 | B-13 |
| 388 | A-18 | B-14 |
| 389 | A-18 | B-15 |
| 390 | A-18 | B-16 |
| 391 | A-18 | B-17 |
| 392 | A-18 | B-18 |
| 393 | A-18 | B-19 |
| 394 | A-18 | B-20 |
| 395 | A-18 | B-21 |
| 396 | A-18 | B-22 |
| 397 | A-19 | B-1 |
| 398 | A-19 | B-2 |
| 399 | A-19 | B-3 |
| 400 | A-19 | B-4 |
| 401 | A-19 | B-5 |
| 402 | A-19 | B-6 |
| 403 | A-19 | B-7 |
| 404 | A-19 | B-8 |
| 405 | A-19 | B-9 |
| 406 | A-19 | B-10 |
| 407 | A-19 | B-11 |
| 408 | A-19 | B-12 |
| 409 | A-19 | B-13 |
| 410 | A-19 | B-14 |
| 411 | A-19 | B-15 |
| 412 | A-19 | B-16 |
| 413 | A-19 | B-17 |
| 414 | A-19 | B-18 |
| 415 | A-19 | B-19 |
| 416 | A-19 | B-20 |
| 417 | A-19 | B-21 |
| 418 | A-19 | B-22 |
| 419 | A-20 | B-1 |
| 420 | A-20 | B-2 |
| 421 | A-20 | B-3 |
| 422 | A-20 | B-4 |
| 423 | A-20 | B-5 |
| 424 | A-20 | B-6 |
| 425 | A-20 | B-7 |
| 426 | A-20 | B-8 |
| 427 | A-20 | B-9 |
| 428 | A-20 | B-10 |
| 429 | A-20 | B-11 |
| 430 | A-20 | B-12 |
| 431 | A-20 | B-13 |
| 432 | A-20 | B-14 |
| 433 | A-20 | B-15 |
| 434 | A-20 | B-16 |
| 435 | A-20 | B-17 |
| 436 | A-20 | B-18 |
| 437 | A-20 | B-19 |
| 438 | A-20 | B-20 |
| 439 | A-20 | B-21 |
| 440 | A-20 | B-22 |
| 441 | A-21 | B-1 |
| 442 | A-21 | B-2 |
| 443 | A-21 | B-3 |
| 444 | A-21 | B-4 |
| 445 | A-21 | B-5 |
| 446 | A-21 | B-6 |
| 447 | A-21 | B-7 |
| 448 | A-21 | B-8 |
| 449 | A-21 | B-9 |
| 450 | A-21 | B-10 |
| 451 | A-21 | B-11 |
| 452 | A-21 | B-12 |
| 453 | A-21 | B-13 |
| 454 | A-21 | B-14 |
| 455 | A-21 | B-15 |
| 456 | A-21 | B-16 |
| 457 | A-21 | B-17 |
| 458 | A-21 | B-18 |
| 459 | A-21 | B-19 |
| 460 | A-21 | B-20 |
| 461 | A-21 | B-21 |
| 462 | A-21 | B-22 |
| 463 | A-22 | B-1 |
| 464 | A-22 | B-2 |
| 465 | A-22 | B-3 |
| 466 | A-22 | B-4 |
| 467 | A-22 | B-5 |
| 468 | A-22 | B-6 |
| 469 | A-22 | B-7 |
| 470 | A-22 | B-8 |
| 471 | A-22 | B-9 |
| 472 | A-22 | B-10 |
| 473 | A-22 | B-11 |
| 474 | A-22 | B-12 |
| 475 | A-22 | B-13 |
| 476 | A-22 | B-14 |
| 477 | A-22 | B-15 |
| 478 | A-22 | B-16 |
| 479 | A-22 | B-17 |
| 480 | A-22 | B-18 |
| 481 | A-22 | B-19 |
| 482 | A-22 | B-20 |
| 483 | A-22 | B-21 |
| 484 | A-22 | B-22 |
| 485 | A-23 | B-1 |
| 486 | A-23 | B-2 |
| 487 | A-23 | B-3 |
| 488 | A-23 | B-4 |
| 489 | A-23 | B-5 |
| 490 | A-23 | B-6 |
| 491 | A-23 | B-7 |
| 492 | A-23 | B-8 |
| 493 | A-23 | B-9 |
| 494 | A-23 | B-10 |
| 495 | A-23 | B-11 |
| 496 | A-23 | B-12 |
| 497 | A-23 | B-13 |
| 498 | A-23 | B-14 |
| 499 | A-23 | B-15 |
| 500 | A-23 | B-16 |
| 501 | A-23 | B-17 |
| 502 | A-23 | B-18 |
| 503 | A-23 | B-19 |
| 504 | A-23 | B-20 |
| 505 | A-23 | B-21 |
| 506 | A-23 | B-22 |
| 507 | A-24 | B-1 |
| 508 | A-24 | B-2 |
| 509 | A-24 | B-3 |
| 510 | A-24 | B-4 |
| 511 | A-24 | B-5 |
| 512 | A-24 | B-6 |
| 513 | A-24 | B-7 |
| 514 | A-24 | B-8 |
| 515 | A-24 | B-9 |
| 516 | A-24 | B-10 |
| 517 | A-24 | B-11 |
| 518 | A-24 | B-12 |
| 519 | A-24 | B-13 |
| 520 | A-24 | B-14 |
| 521 | A-24 | B-15 |
| 522 | A-24 | B-16 |
| 523 | A-24 | B-17 |
| 524 | A-24 | B-18 |
| 525 | A-24 | B-19 |
| 526 | A-24 | B-20 |
| 527 | A-24 | B-21 |
| 528 | A-24 | B-22 |
| 529 | A-25 | B-1 |
| 530 | A-25 | B-2 |
| 531 | A-25 | B-3 |
| 532 | A-25 | B-4 |
| 533 | A-25 | B-5 |
| 534 | A-25 | B-6 |
| 535 | A-25 | B-7 |
| 536 | A-25 | B-8 |
| 537 | A-25 | B-9 |
| 538 | A-25 | B-10 |
| 539 | A-25 | B-11 |
| 540 | A-25 | B-12 |
| 541 | A-25 | B-13 |
| 542 | A-25 | B-14 |
| 543 | A-25 | B-15 |
| 544 | A-25 | B-16 |
| 545 | A-25 | B-17 |
| 546 | A-25 | B-18 |
| 547 | A-25 | B-19 |
| 548 | A-25 | B-20 |
| 549 | A-25 | B-21 |
| 550 | A-25 | B-22 |
| 551 | A-26 | B-1 |
| 552 | A-26 | B-2 |
| 553 | A-26 | B-3 |
| 554 | A-26 | B-4 |
| 555 | A-26 | B-5 |
| 556 | A-26 | B-6 |
| 557 | A-26 | B-7 |
| 558 | A-26 | B-8 |
| 559 | A-26 | B-9 |
| 560 | A-26 | B-10 |
| 561 | A-26 | B-11 |
| 562 | A-26 | B-12 |
| 563 | A-26 | B-13 |
| 564 | A-26 | B-14 |
| 565 | A-26 | B-15 |
| 566 | A-26 | B-16 |
| 567 | A-26 | B-17 |
| 568 | A-26 | B-18 |
| 569 | A-26 | B-19 |
| 570 | A-26 | B-20 |
| 571 | A-26 | B-21 |
| 572 | A-26 | B-22 |
| 573 | A-27 | B-1 |
| 574 | A-27 | B-2 |
| 575 | A-27 | B-3 |
| 576 | A-27 | B-4 |
| 577 | A-27 | B-5 |
| 578 | A-27 | B-6 |
| 579 | A-27 | B-7 |
| 580 | A-27 | B-8 |
| 581 | A-27 | B-9 |
| 582 | A-27 | B-10 |
| 583 | A-27 | B-11 |
| 584 | A-27 | B-12 |
| 585 | A-27 | B-13 |
| 586 | A-27 | B-14 |
| 587 | A-27 | B-15 |
| 588 | A-27 | B-16 |
| 589 | A-27 | B-17 |
| 590 | A-27 | B-18 |
| 591 | A-27 | B-19 |
| 592 | A-27 | B-20 |
| 593 | A-27 | B-21 |
| 594 | A-27 | B-22 |
| 595 | A-28 | B-1 |
| 596 | A-28 | B-2 |
| 597 | A-28 | B-3 |
| 598 | A-28 | B-4 |
| 599 | A-28 | B-5 |
| 600 | A-28 | B-6 |
| 601 | A-28 | B-7 |
| 602 | A-28 | B-8 |
| 603 | A-28 | B-9 |
| 604 | A-28 | B-10 |
| 605 | A-28 | B-11 |
| 606 | A-28 | B-12 |
| 607 | A-28 | B-13 |
| 608 | A-28 | B-14 |
| 609 | A-28 | B-15 |
| 610 | A-28 | B-16 |
| 611 | A-28 | B-17 |
| 612 | A-28 | B-18 |
| 613 | A-28 | B-19 |
| 614 | A-28 | B-20 |
| 615 | A-28 | B-21 |
| 616 | A-28 | B-22 |
| 617 | A-29 | B-1 |
| 618 | A-29 | B-2 |
| 619 | A-29 | B-3 |
| 620 | A-29 | B-4 |
| 621 | A-29 | B-5 |
| 622 | A-29 | B-6 |
| 623 | A-29 | B-7 |
| 624 | A-29 | B-8 |
| 625 | A-29 | B-9 |
| 626 | A-29 | B-10 |
| 627 | A-29 | B-11 |
| 628 | A-29 | B-12 |
| 629 | A-29 | B-13 |
| 630 | A-29 | B-14 |
| 631 | A-29 | B-15 |
| 632 | A-29 | B-16 |
| 633 | A-29 | B-17 |
| 634 | A-29 | B-18 |
| 635 | A-29 | B-19 |
| 636 | A-29 | B-20 |
| 637 | A-29 | B-21 |
| 638 | A-29 | B-22 |
| 639 | A-30 | B-1 |
| 640 | A-30 | B-2 |
| 641 | A-30 | B-3 |
| 642 | A-30 | B-4 |
| 643 | A-30 | B-5 |
| 644 | A-30 | B-6 |
| 645 | A-30 | B-7 |
| 646 | A-30 | B-8 |
| 647 | A-30 | B-9 |
| 648 | A-30 | B-10 |
| 649 | A-30 | B-11 |
| 650 | A-30 | B-12 |
| 651 | A-30 | B-13 |
| 652 | A-30 | B-14 |
| 653 | A-30 | B-15 |
| 654 | A-30 | B-16 |
| 655 | A-30 | B-17 |
| 656 | A-30 | B-18 |
| 657 | A-30 | B-19 |
| 658 | A-30 | B-20 |
| 659 | A-30 | B-21 |
| 660 | A-30 | B-22 |

Preferred compounds of formula (E-1) are shown in the following table:

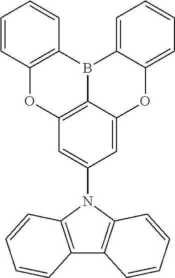 [SMILES: c1ccc2c(c1)Oc1cc(-n3c4ccccc4c4ccccc43)cc3c1B2c1ccccc1O3]

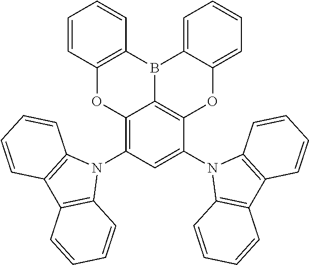 [SMILES: c1ccc2c(c1)Oc1c(-n3c4ccccc4c4ccccc43)cc(-n3c4ccccc4c4ccccc43)c3c1B2c1ccccc1O3]

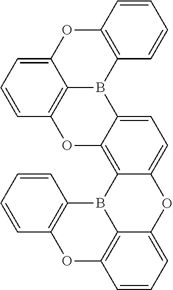 [SMILES: c1ccc2c(c1)Oc1cccc3c1B2c1ccc2c(c1O3)B1c3ccccc3Oc3cccc(c31)O2]

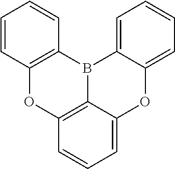 [SMILES: c1ccc2c(c1)Oc1cccc3c1B2c1ccccc1O3]

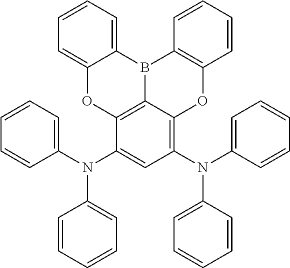 [SMILES: c1ccc(N(c2ccccc2)c2cc(N(c3ccccc3)c3ccccc3)c3c4c2Oc2ccccc2B4c2ccccc2O3)cc1]

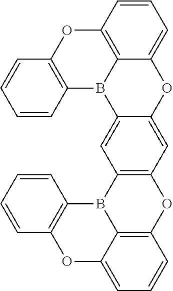 [SMILES: c1ccc2c(c1)Oc1cccc3c1B2c1cc2c(cc1O3)Oc1cccc3c1B2c1ccccc1O3]

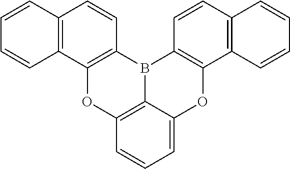 [SMILES: c1cc2c3c(c1)Oc1c(ccc4ccccc14)B3c1ccc3ccccc3c1O2]

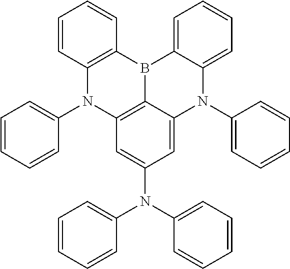 [SMILES: c1ccc(N(c2ccccc2)c2cc3c4c(c2)N(c2ccccc2)c2ccccc2B4c2ccccc2N3c2ccccc2)cc1]

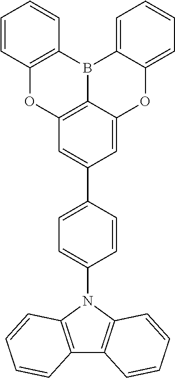 [SMILES: c1ccc2c(c1)Oc1cc(-c3ccc(-n4c5ccccc5c5ccccc54)cc3)cc3c1B2c1ccccc1O3]

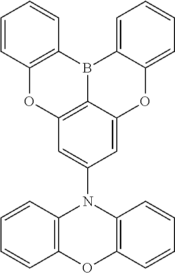 [SMILES: c1ccc2c(c1)Oc1cc(N3c4ccccc4Oc4ccccc43)cc3c1B2c1ccccc1O3]

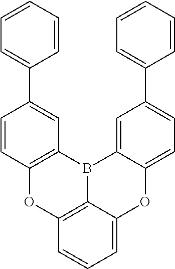 [SMILES: c1ccc(-c2ccc3c(c2)B2c4cc(-c5ccccc5)ccc4Oc4cccc(c42)O3)cc1]

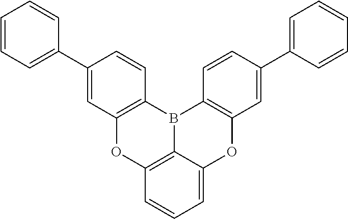 [SMILES: c1ccc(-c2ccc3c(c2)Oc2cccc4c2B3c2ccc(-c3ccccc3)cc2O4)cc1]

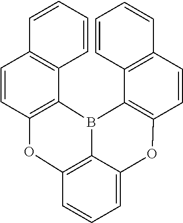 [SMILES: c1cc2c3c(c1)Oc1ccc4ccccc4c1B3c1c(ccc3ccccc13)O2]

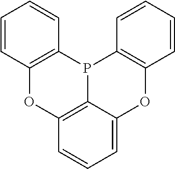 [SMILES: c1ccc2c(c1)Oc1cccc3c1P2c1ccccc1O3]

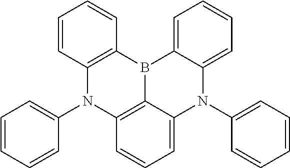 [SMILES: c1ccc(N2c3ccccc3B3c4ccccc4N(c4ccccc4)c4cccc2c43)cc1]

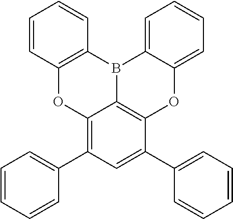 [SMILES: c1ccc(-c2cc(-c3ccccc3)c3c4c2Oc2ccccc2B4c2ccccc2O3)cc1]

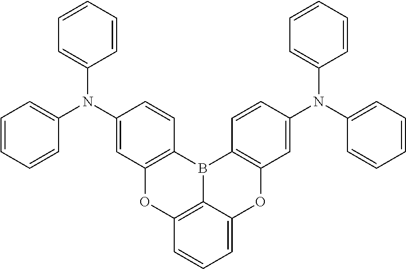 [SMILES: c1ccc(N(c2ccccc2)c2ccc3c(c2)Oc2cccc4c2B3c2ccc(N(c3ccccc3)c3ccccc3)cc2O4)cc1]

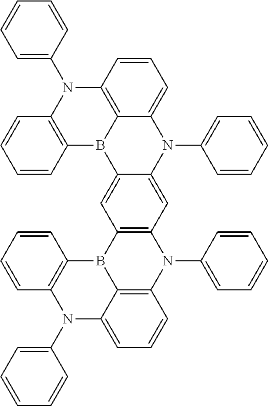 [SMILES: c1ccc(N2c3ccccc3B3c4cc5c(cc4N(c4ccccc4)c4cccc2c43)N(c2ccccc2)c2cccc3c2B5c2ccccc2N3c2ccccc2)cc1]

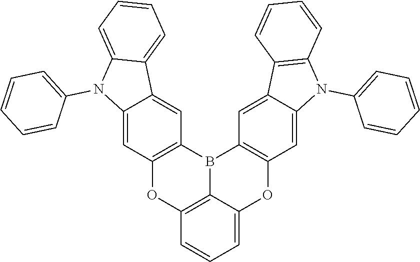 [SMILES: c1ccc(-n2c3ccccc3c3cc4c(cc32)Oc2cccc3c2B4c2cc4c5ccccc5n(-c5ccccc5)c4cc2O3)cc1]

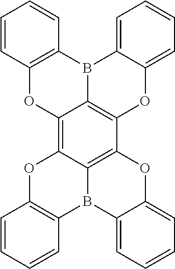 [SMILES: c1ccc2c(c1)Oc1c3c4c(c5c1B2c1ccccc1O5)Oc1ccccc1B4c1ccccc1O3]

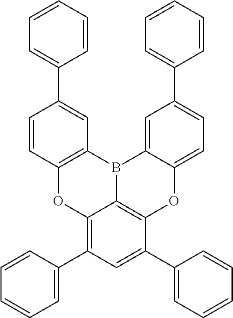 [SMILES: c1ccc(-c2ccc3c(c2)B2c4cc(-c5ccccc5)ccc4Oc4c(-c5ccccc5)cc(-c5ccccc5)c(c42)O3)cc1]

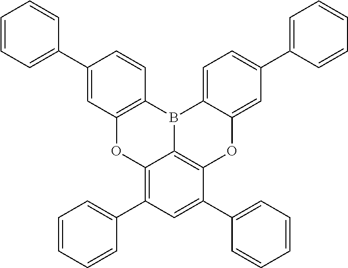 [SMILES: c1ccc(-c2ccc3c(c2)Oc2c(-c4ccccc4)cc(-c4ccccc4)c4c2B3c2ccc(-c3ccccc3)cc2O4)cc1]

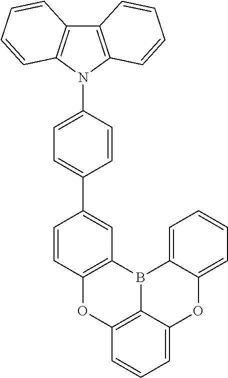 [SMILES: c1ccc2c(c1)Oc1cccc3c1B2c1cc(-c2ccc(-n4c5ccccc5c5ccccc54)cc2)ccc1O3]

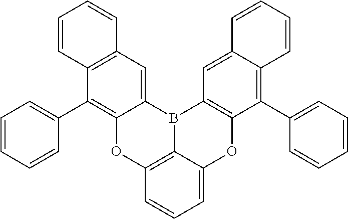 [SMILES: c1ccc(-c2c3c(cc4ccccc24)B2c4cc5ccccc5c(-c5ccccc5)c4Oc4cccc(c42)O3)cc1]

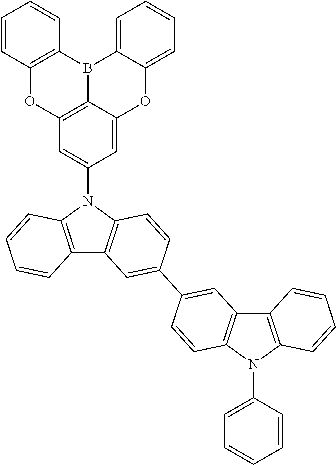 [SMILES: c1ccc(-n2c3ccccc3c3cc(-c4ccc5c(c4)c4ccccc4n5-c4cc5c6c(c4)Oc4ccccc4B6c4ccccc4O5)ccc32)cc1]

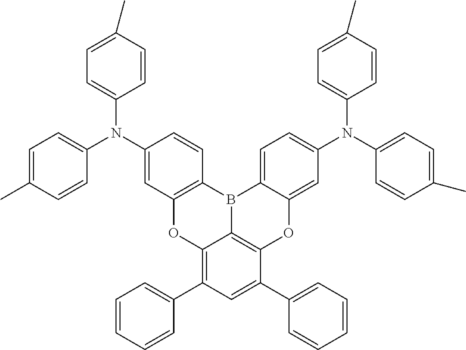

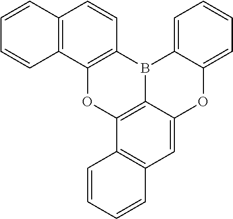 [SMILES: c1ccc2c(c1)Oc1cc3ccccc3c3c1B2c1ccc2ccccc2c1O3]

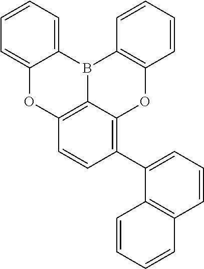 [SMILES: c1ccc2c(c1)Oc1ccc(-c3cccc4ccccc34)c3c1B2c1ccccc1O3]

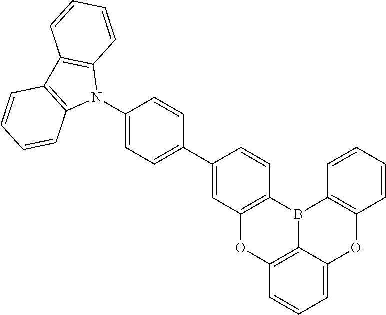 [SMILES: c1ccc2c(c1)Oc1cccc3c1B2c1ccc(-c2ccc(-n4c5ccccc5c5ccccc54)cc2)cc1O3]

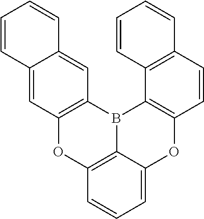 [SMILES: c1cc2c3c(c1)Oc1ccc4ccccc4c1B3c1cc3ccccc3cc1O2]

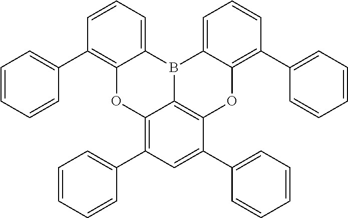 [SMILES: c1ccc(-c2cccc3c2Oc2c(-c4ccccc4)cc(-c4ccccc4)c4c2B3c2cccc(-c3ccccc3)c2O4)cc1]

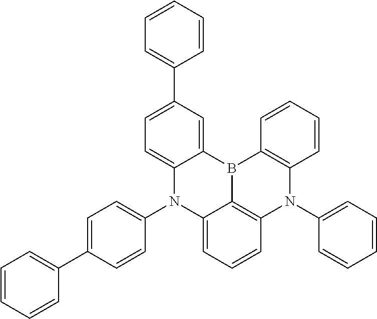 [SMILES: c1ccc(-c2ccc(N3c4ccc(-c5ccccc5)cc4B4c5ccccc5N(c5ccccc5)c5cccc3c54)cc2)cc1]

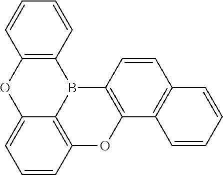 [SMILES: c1ccc2c(c1)Oc1cccc3c1B2c1ccc2ccccc2c1O3]

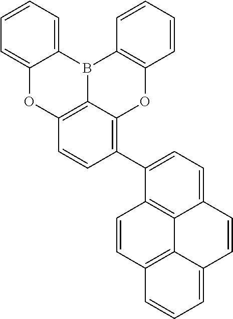 [SMILES: c1ccc2c(c1)Oc1ccc(-c3ccc4ccc5cccc6ccc3c4c56)c3c1B2c1ccccc1O3]

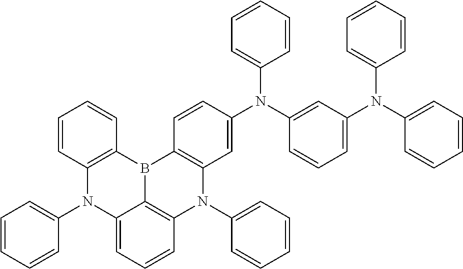 [SMILES: c1ccc(N(c2ccccc2)c2cccc(N(c3ccccc3)c3ccc4c(c3)N(c3ccccc3)c3cccc5c3B4c3ccccc3N5c3ccccc3)c2)cc1]

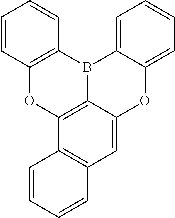 [SMILES: c1ccc2c(c1)Oc1cc3ccccc3c3c1B2c1ccccc1O3]

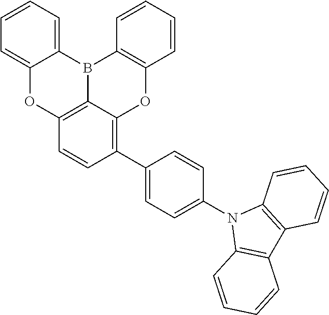 [SMILES: c1ccc2c(c1)Oc1ccc(-c3ccc(-n4c5ccccc5c5ccccc54)cc3)c3c1B2c1ccccc1O3]

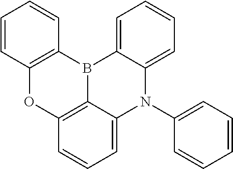 [SMILES: c1ccc(N2c3ccccc3B3c4ccccc4Oc4cccc2c43)cc1]

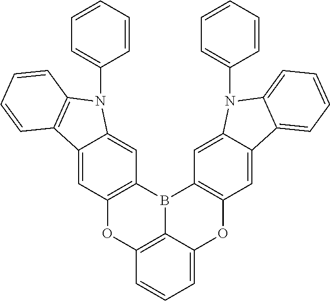 [SMILES: c1ccc(-n2c3ccccc3c3cc4c(cc32)B2c3cc5c(cc3Oc3cccc(c32)O4)c2ccccc2n5-c2ccccc2)cc1]

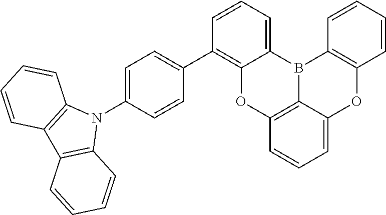 [SMILES: c1ccc2c(c1)Oc1cccc3c1B2c1cccc(-c2ccc(-n4c5ccccc5c5ccccc54)cc2)c1O3]

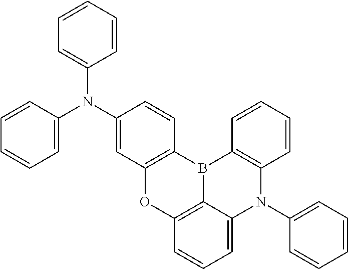 [SMILES: c1ccc(N(c2ccccc2)c2ccc3c(c2)Oc2cccc4c2B3c2ccccc2N4c2ccccc2)cc1]

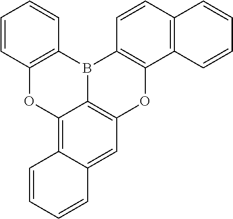 [SMILES: c1ccc2c(c1)Oc1c3c(cc4ccccc14)Oc1c(ccc4ccccc14)B23]

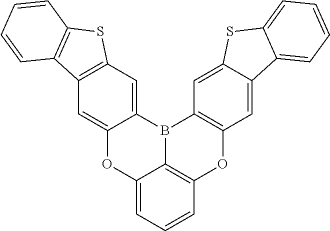 [SMILES: c1cc2c3c(c1)Oc1cc4c(cc1B3c1cc3sc5ccccc5c3cc1O2)sc1ccccc14]

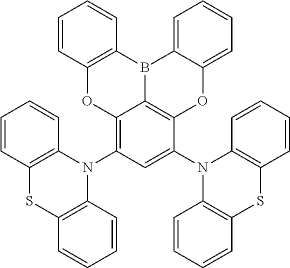 [SMILES: c1ccc2c(c1)Oc1c(N3c4ccccc4Sc4ccccc43)cc(N3c4ccccc4Sc4ccccc43)c3c1B2c1ccccc1O3]

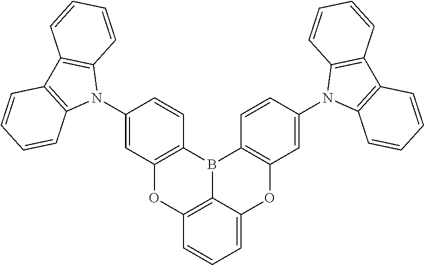 [SMILES: c1cc2c3c(c1)Oc1cc(-n4c5ccccc5c5ccccc54)ccc1B3c1ccc(-n3c4ccccc4c4ccccc43)cc1O2]

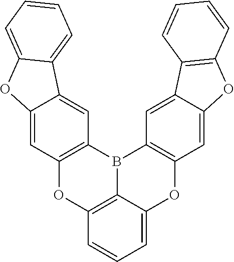 [SMILES: c1cc2c3c(c1)Oc1cc4oc5ccccc5c4cc1B3c1cc3c(cc1O2)oc1ccccc13]

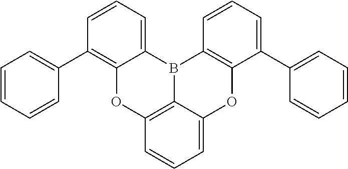 [SMILES: c1ccc(-c2cccc3c2Oc2cccc4c2B3c2cccc(-c3ccccc3)c2O4)cc1]

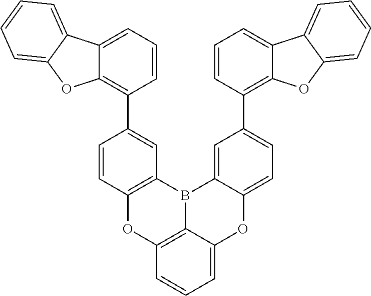 [SMILES: c1cc2c3c(c1)Oc1ccc(-c4cccc5c4oc4ccccc45)cc1B3c1cc(-c3cccc4c3oc3ccccc34)ccc1O2]

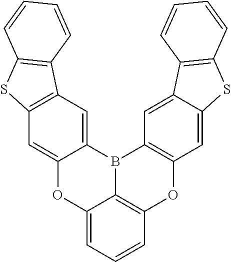 [SMILES: c1cc2c3c(c1)Oc1cc4sc5ccccc5c4cc1B3c1cc3c(cc1O2)sc1ccccc13]

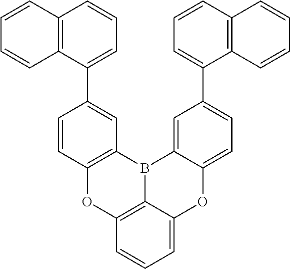 [SMILES: c1cc2c3c(c1)Oc1ccc(-c4cccc5ccccc45)cc1B3c1cc(-c3cccc4ccccc34)ccc1O2]

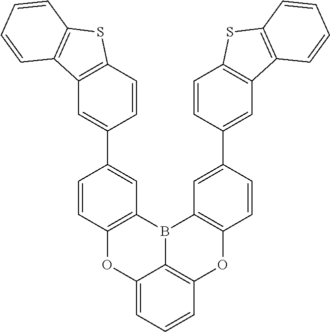 [SMILES: c1cc2c3c(c1)Oc1ccc(-c4ccc5sc6ccccc6c5c4)cc1B3c1cc(-c3ccc4sc5ccccc5c4c3)ccc1O2]

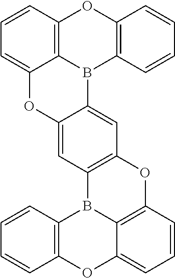 [SMILES: c1ccc2c(c1)Oc1cccc3c1B2c1cc2c(cc1O3)B1c3ccccc3Oc3cccc(c31)O2]

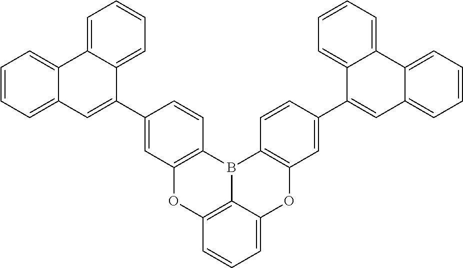 [SMILES: c1cc2c3c(c1)Oc1cc(-c4cc5ccccc5c5ccccc45)ccc1B3c1ccc(-c3cc4ccccc4c4ccccc34)cc1O2]

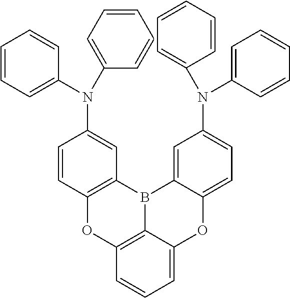 [SMILES: c1ccc(N(c2ccccc2)c2ccc3c(c2)B2c4cc(N(c5ccccc5)c5ccccc5)ccc4Oc4cccc(c42)O3)cc1]

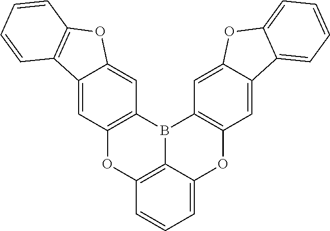 [SMILES: c1cc2c3c(c1)Oc1cc4c(cc1B3c1cc3oc5ccccc5c3cc1O2)oc1ccccc14]

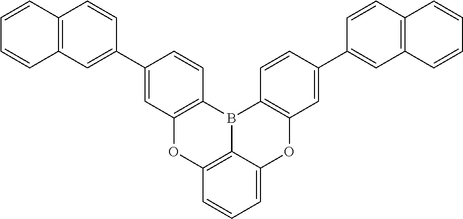 [SMILES: c1cc2c3c(c1)Oc1cc(-c4ccc5ccccc5c4)ccc1B3c1ccc(-c3ccc4ccccc4c3)cc1O2]

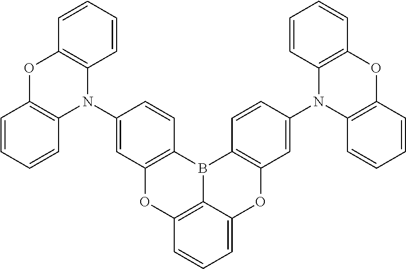 [SMILES: c1ccc2c(c1)Oc1ccccc1N2c1ccc2c(c1)Oc1cccc3c1B2c1ccc(N2c4ccccc4Oc4ccccc42)cc1O3]

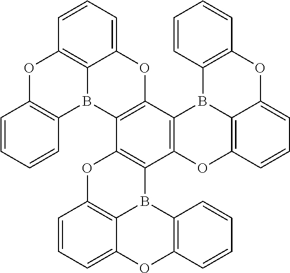 [SMILES: c1ccc2c(c1)Oc1cccc3c1B2c1c2c(c4c(c1O3)B1c3ccccc3Oc3cccc(c31)O4)B1c3ccccc3Oc3cccc(c31)O2]

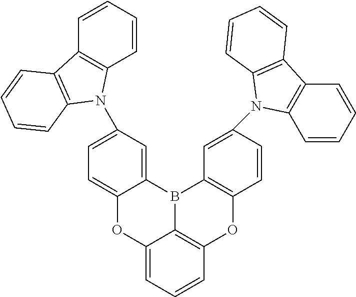 [SMILES: c1cc2c3c(c1)Oc1ccc(-n4c5ccccc5c5ccccc54)cc1B3c1cc(-n3c4ccccc4c4ccccc43)ccc1O2]

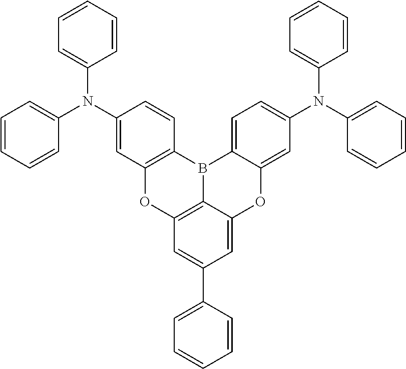 [SMILES: c1ccc(-c2cc3c4c(c2)Oc2cc(N(c5ccccc5)c5ccccc5)ccc2B4c2ccc(N(c4ccccc4)c4ccccc4)cc2O3)cc1]

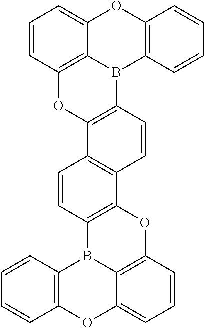 [SMILES: c1ccc2c(c1)Oc1cccc3c1B2c1ccc2c4c(ccc2c1O3)B1c2ccccc2Oc2cccc(c21)O4]

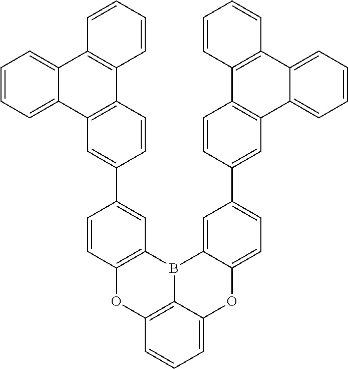 [SMILES: c1cc2c3c(c1)Oc1ccc(-c4ccc5c6ccccc6c6ccccc6c5c4)cc1B3c1cc(-c3ccc4c5ccccc5c5ccccc5c4c3)ccc1O2]

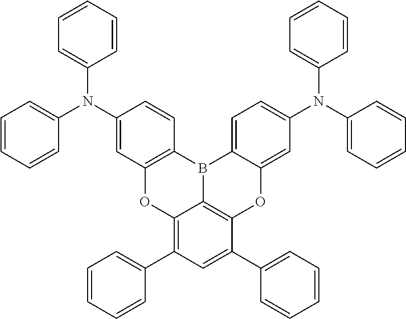 [SMILES: c1ccc(-c2cc(-c3ccccc3)c3c4c2Oc2cc(N(c5ccccc5)c5ccccc5)ccc2B4c2ccc(N(c4ccccc4)c4ccccc4)cc2O3)cc1]

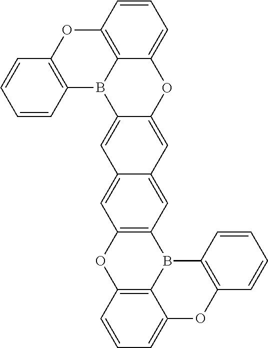 [SMILES: c1ccc2c(c1)Oc1cccc3c1B2c1cc2cc4c(cc2cc1O3)B1c2ccccc2Oc2cccc(c21)O4]

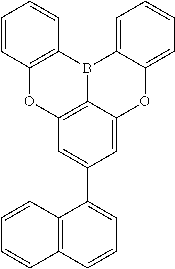 [SMILES: c1ccc2c(c1)Oc1cc(-c3cccc4ccccc34)cc3c1B2c1ccccc1O3]

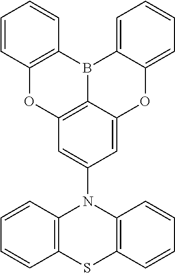 [SMILES: c1ccc2c(c1)Oc1cc(N3c4ccccc4Sc4ccccc43)cc3c1B2c1ccccc1O3]

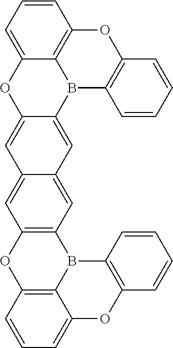 [SMILES: c1ccc2c(c1)Oc1cccc3c1B2c1cc2cc4c(cc2cc1O3)Oc1cccc2c1B4c1ccccc1O2]

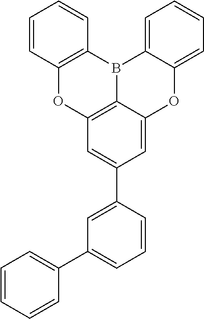 [SMILES: c1ccc(-c2cccc(-c3cc4c5c(c3)Oc3ccccc3B5c3ccccc3O4)c2)cc1]

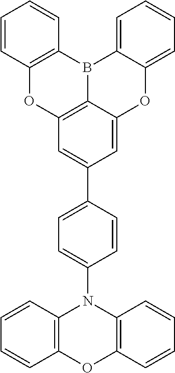 [SMILES: c1ccc2c(c1)Oc1cc(-c3ccc(N4c5ccccc5Oc5ccccc54)cc3)cc3c1B2c1ccccc1O3]

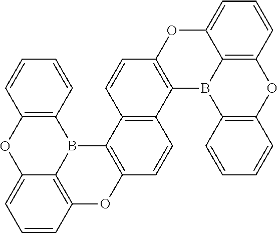 [SMILES: c1ccc2c(c1)Oc1cccc3c1B2c1c(ccc2c4c(ccc12)Oc1cccc2c1B4c1ccccc1O2)O3]

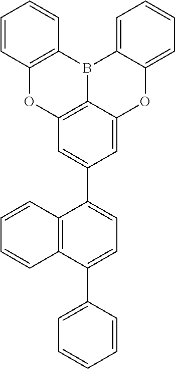 [SMILES: c1ccc(-c2ccc(-c3cc4c5c(c3)Oc3ccccc3B5c3ccccc3O4)c3ccccc23)cc1]

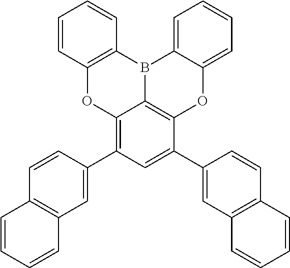 [SMILES: c1ccc2c(c1)Oc1c(-c3ccc4ccccc4c3)cc(-c3ccc4ccccc4c3)c3c1B2c1ccccc1O3]

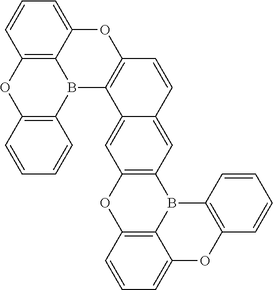 [SMILES: c1ccc2c(c1)Oc1cccc3c1B2c1cc2ccc4c(c2cc1O3)B1c2ccccc2Oc2cccc(c21)O4]

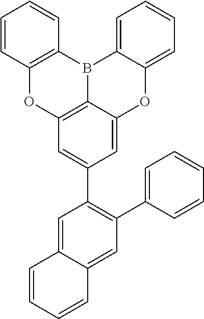 [SMILES: c1ccc(-c2cc3ccccc3cc2-c2cc3c4c(c2)Oc2ccccc2B4c2ccccc2O3)cc1]

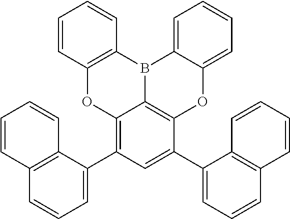 [SMILES: c1ccc2c(c1)Oc1c(-c3cccc4ccccc34)cc(-c3cccc4ccccc34)c3c1B2c1ccccc1O3]

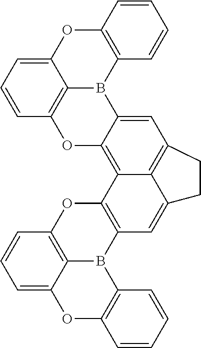 [SMILES: c1ccc2c(c1)Oc1cccc3c1B2c1cc2c4c(cc5c(c4c1O3)Oc1cccc3c1B5c1ccccc1O3)CC2]

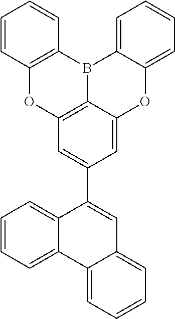 [SMILES: c1ccc2c(c1)Oc1cc(-c3cc4ccccc4c4ccccc34)cc3c1B2c1ccccc1O3]

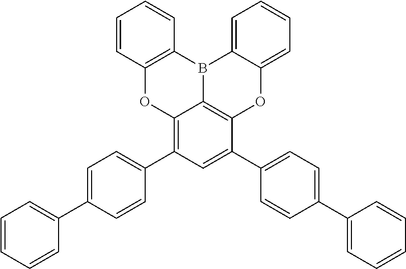 [SMILES: c1ccc(-c2ccc(-c3cc(-c4ccc(-c5ccccc5)cc4)c4c5c3Oc3ccccc3B5c3ccccc3O4)cc2)cc1]

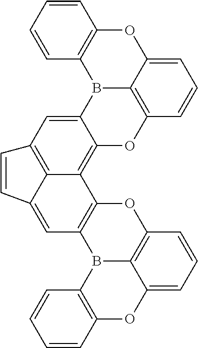 [SMILES: C1=Cc2cc3c(c4c5c(cc1c24)B1c2ccccc2Oc2cccc(c21)O5)Oc1cccc2c1B3c1ccccc1O2]

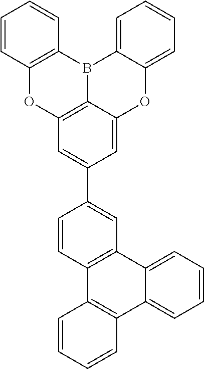 [SMILES: c1ccc2c(c1)Oc1cc(-c3ccc4c5ccccc5c5ccccc5c4c3)cc3c1B2c1ccccc1O3]

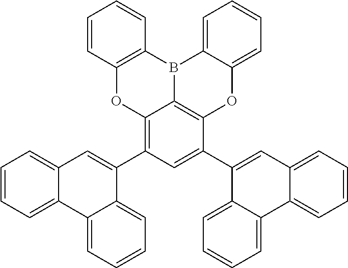 [SMILES: c1ccc2c(c1)Oc1c(-c3cc4ccccc4c4ccccc34)cc(-c3cc4ccccc4c4ccccc34)c3c1B2c1ccccc1O3]

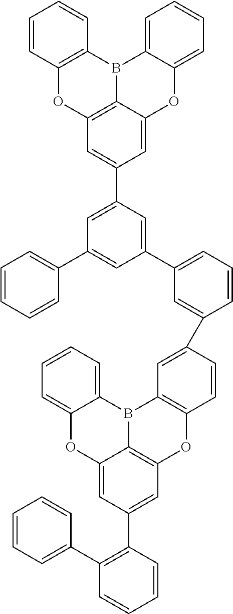 [SMILES: c1ccc(-c2cc(-c3cccc(-c4ccc5c(c4)B4c6ccccc6Oc6cc(-c7ccccc7-c7ccccc7)cc(c64)O5)c3)cc(-c3cc4c5c(c3)Oc3ccccc3B5c3ccccc3O4)c2)cc1]

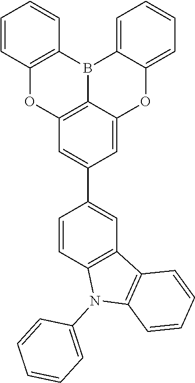 [SMILES: c1ccc(-n2c3ccccc3c3cc(-c4cc5c6c(c4)Oc4ccccc4B6c4ccccc4O5)ccc32)cc1]

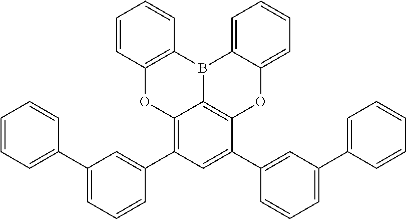 [SMILES: c1ccc(-c2cccc(-c3cc(-c4cccc(-c5ccccc5)c4)c4c5c3Oc3ccccc3B5c3ccccc3O4)c2)cc1]

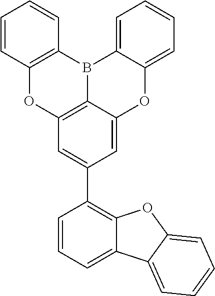 [SMILES: c1ccc2c(c1)Oc1cc(-c3cccc4c3oc3ccccc34)cc3c1B2c1ccccc1O3]

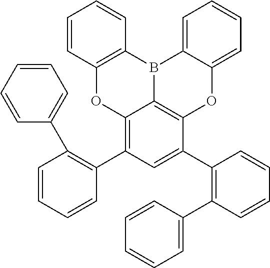 [SMILES: c1ccc(-c2ccccc2-c2cc(-c3ccccc3-c3ccccc3)c3c4c2Oc2ccccc2B4c2ccccc2O3)cc1]

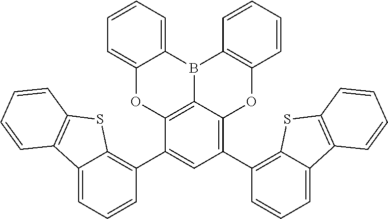 [SMILES: c1ccc2c(c1)Oc1c(-c3cccc4c3sc3ccccc34)cc(-c3cccc4c3sc3ccccc34)c3c1B2c1ccccc1O3]

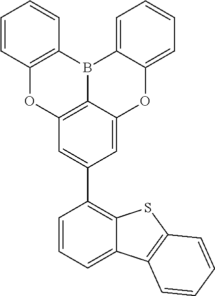 [SMILES: c1ccc2c(c1)Oc1cc(-c3cccc4c3sc3ccccc34)cc3c1B2c1ccccc1O3]

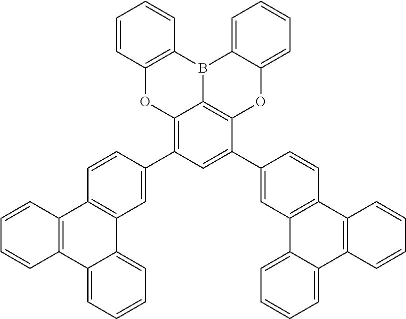 [SMILES: c1ccc2c(c1)Oc1c(-c3ccc4c5ccccc5c5ccccc5c4c3)cc(-c3ccc4c5ccccc5c5ccccc5c4c3)c3c1B2c1ccccc1O3]

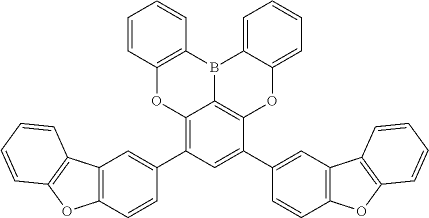 [SMILES: c1ccc2c(c1)Oc1c(-c3ccc4oc5ccccc5c4c3)cc(-c3ccc4oc5ccccc5c4c3)c3c1B2c1ccccc1O3]

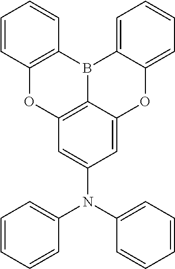 [SMILES: c1ccc(N(c2ccccc2)c2cc3c4c(c2)Oc2ccccc2B4c2ccccc2O3)cc1]

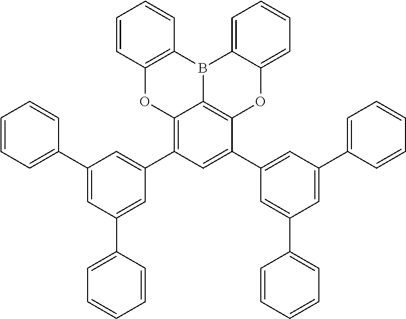 [SMILES: c1ccc(-c2cc(-c3ccccc3)cc(-c3cc(-c4cc(-c5ccccc5)cc(-c5ccccc5)c4)c4c5c3Oc3ccccc3B5c3ccccc3O4)c2)cc1]

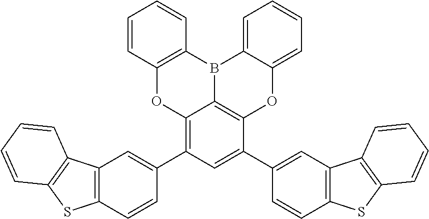 [SMILES: c1ccc2c(c1)Oc1c(-c3ccc4sc5ccccc5c4c3)cc(-c3ccc4sc5ccccc5c4c3)c3c1B2c1ccccc1O3]

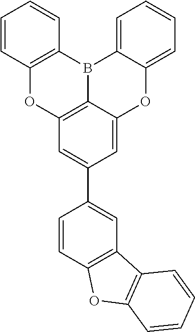 [SMILES: c1ccc2c(c1)Oc1cc(-c3ccc4oc5ccccc5c4c3)cc3c1B2c1ccccc1O3]

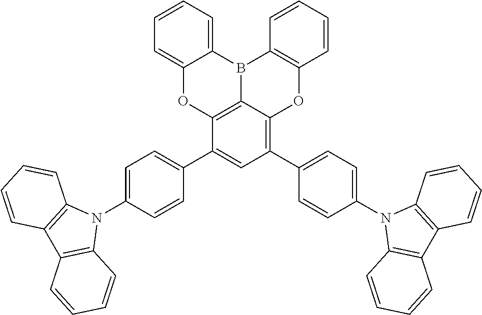 [SMILES: c1ccc2c(c1)Oc1c(-c3ccc(-n4c5ccccc5c5ccccc54)cc3)cc(-c3ccc(-n4c5ccccc5c5ccccc54)cc3)c3c1B2c1ccccc1O3]

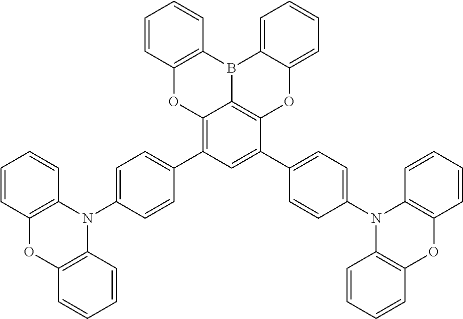 [SMILES: c1ccc2c(c1)Oc1c(-c3ccc(N4c5ccccc5Oc5ccccc54)cc3)cc(-c3ccc(N4c5ccccc5Oc5ccccc54)cc3)c3c1B2c1ccccc1O3]

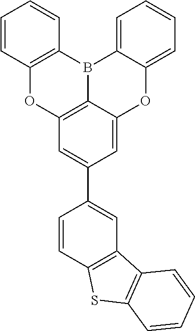 [SMILES: c1ccc2c(c1)Oc1cc(-c3ccc4sc5ccccc5c4c3)cc3c1B2c1ccccc1O3]

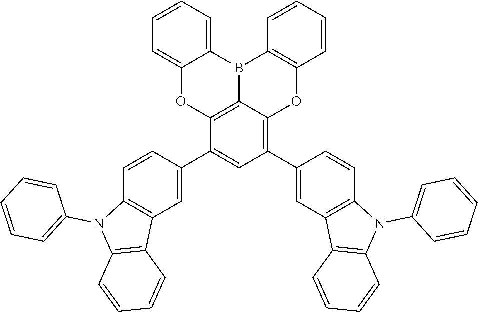 [SMILES: c1ccc(-n2c3ccccc3c3cc(-c4cc(-c5ccc6c(c5)c5ccccc5n6-c5ccccc5)c5c6c4Oc4ccccc4B6c4ccccc4O5)ccc32)cc1]

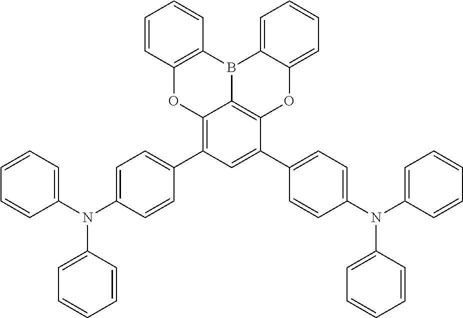 [SMILES: c1ccc(N(c2ccccc2)c2ccc(-c3cc(-c4ccc(N(c5ccccc5)c5ccccc5)cc4)c4c5c3Oc3ccccc3B5c3ccccc3O4)cc2)cc1]

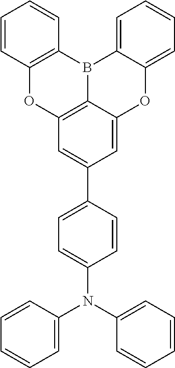 [SMILES: c1ccc(N(c2ccccc2)c2ccc(-c3cc4c5c(c3)Oc3ccccc3B5c3ccccc3O4)cc2)cc1]

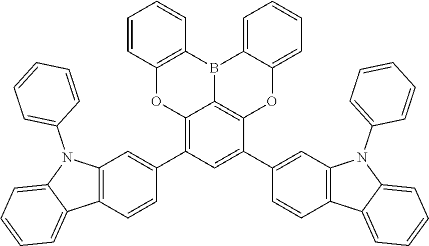 [SMILES: c1ccc(-n2c3ccccc3c3ccc(-c4cc(-c5ccc6c7ccccc7n(-c7ccccc7)c6c5)c5c6c4Oc4ccccc4B6c4ccccc4O5)cc32)cc1]

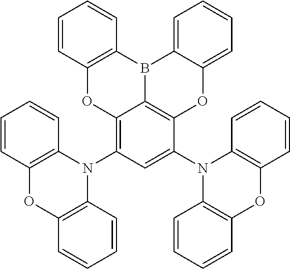 [SMILES: c1ccc2c(c1)Oc1c(N3c4ccccc4Oc4ccccc43)cc(N3c4ccccc4Oc4ccccc43)c3c1B2c1ccccc1O3]

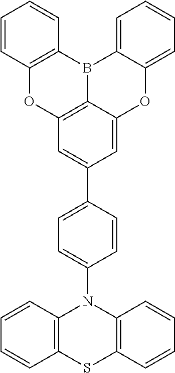 [SMILES: c1ccc2c(c1)Oc1cc(-c3ccc(N4c5ccccc5Sc5ccccc54)cc3)cc3c1B2c1ccccc1O3]

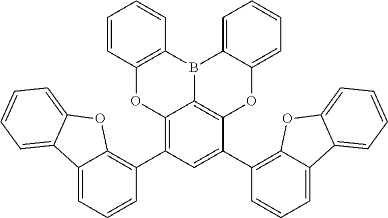 [SMILES: c1ccc2c(c1)Oc1c(-c3cccc4c3oc3ccccc34)cc(-c3cccc4c3oc3ccccc34)c3c1B2c1ccccc1O3]

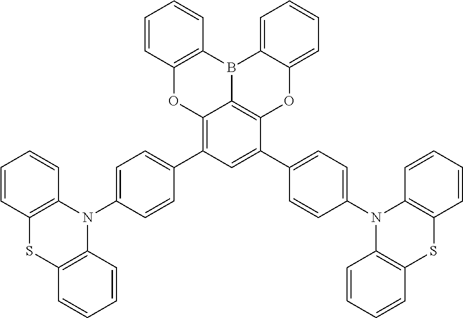 [SMILES: c1ccc2c(c1)Oc1c(-c3ccc(N4c5ccccc5Sc5ccccc54)cc3)cc(-c3ccc(N4c5ccccc5Sc5ccccc54)cc3)c3c1B2c1ccccc1O3]

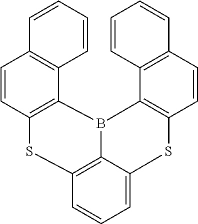 [SMILES: c1cc2c3c(c1)Sc1ccc4ccccc4c1B3c1c(ccc3ccccc13)S2]

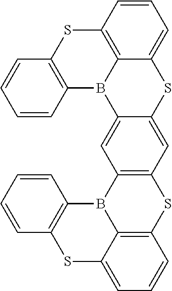 [SMILES: c1ccc2c(c1)Sc1cccc3c1B2c1cc2c(cc1S3)Sc1cccc3c1B2c1ccccc1S3]

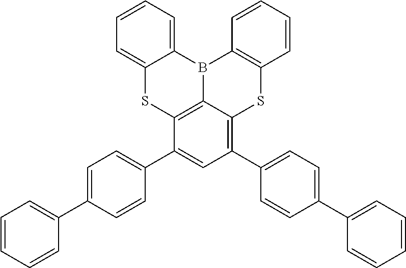 [SMILES: c1ccc(-c2ccc(-c3cc(-c4ccc(-c5ccccc5)cc4)c4c5c3Sc3ccccc3B5c3ccccc3S4)cc2)cc1]

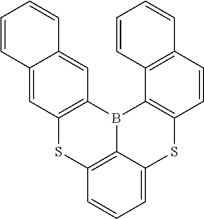 [SMILES: c1cc2c3c(c1)Sc1ccc4ccccc4c1B3c1cc3ccccc3cc1S2]

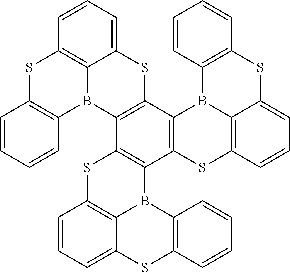 [SMILES: c1ccc2c(c1)Sc1cccc3c1B2c1c2c(c4c(c1S3)B1c3ccccc3Sc3cccc(c31)S4)B1c3ccccc3Sc3cccc(c31)S2]

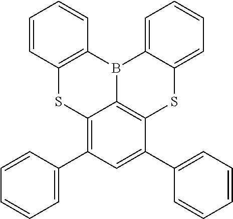 [SMILES: c1ccc(-c2cc(-c3ccccc3)c3c4c2Sc2ccccc2B4c2ccccc2S3)cc1]

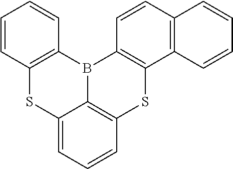 [SMILES: c1ccc2c(c1)Sc1cccc3c1B2c1ccc2ccccc2c1S3]

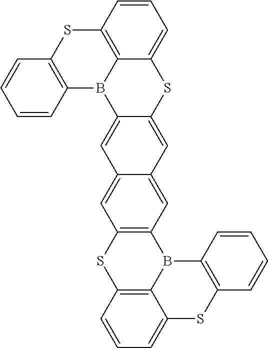 [SMILES: c1ccc2c(c1)Sc1cccc3c1B2c1cc2cc4c(cc2cc1S3)B1c2ccccc2Sc2cccc(c21)S4]

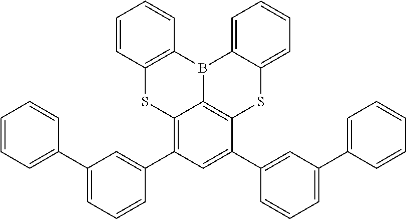 [SMILES: c1ccc(-c2cccc(-c3cc(-c4cccc(-c5ccccc5)c4)c4c5c3Sc3ccccc3B5c3ccccc3S4)c2)cc1]

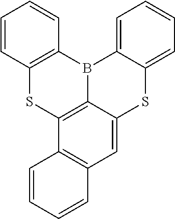 [SMILES: c1ccc2c(c1)Sc1cc3ccccc3c3c1B2c1ccccc1S3]

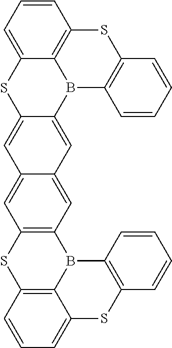 [SMILES: c1ccc2c(c1)Sc1cccc3c1B2c1cc2cc4c(cc2cc1S3)Sc1cccc2c1B4c1ccccc1S2]

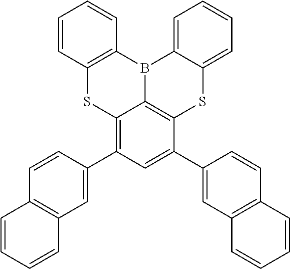 [SMILES: c1ccc2c(c1)Sc1c(-c3ccc4ccccc4c3)cc(-c3ccc4ccccc4c3)c3c1B2c1ccccc1S3]

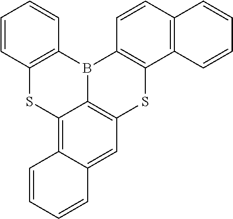 [SMILES: c1ccc2c(c1)Sc1c3c(cc4ccccc14)Sc1c(ccc4ccccc14)B23]

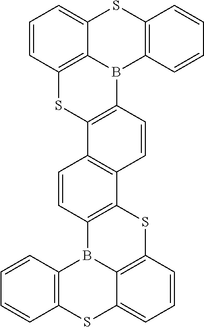 [SMILES: c1ccc2c(c1)Sc1cccc3c1B2c1ccc2c4c(ccc2c1S3)B1c2ccccc2Sc2cccc(c21)S4]

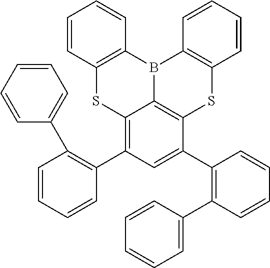 [SMILES: c1ccc(-c2ccccc2-c2cc(-c3ccccc3-c3ccccc3)c3c4c2Sc2ccccc2B4c2ccccc2S3)cc1]

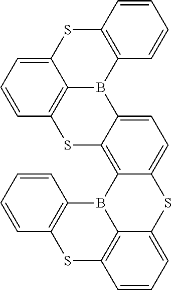 [SMILES: c1ccc2c(c1)Sc1cccc3c1B2c1ccc2c(c1S3)B1c3ccccc3Sc3cccc(c31)S2]

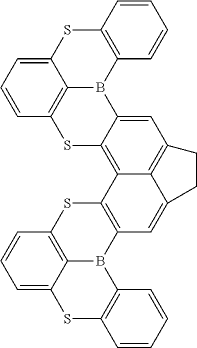 [SMILES: c1ccc2c(c1)Sc1cccc3c1B2c1cc2c4c(cc5c(c4c1S3)Sc1cccc3c1B5c1ccccc1S3)CC2]

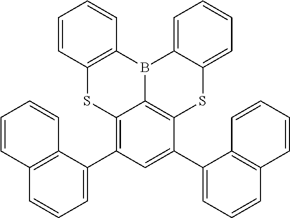 [SMILES: c1ccc2c(c1)Sc1c(-c3cccc4ccccc34)cc(-c3cccc4ccccc34)c3c1B2c1ccccc1S3]

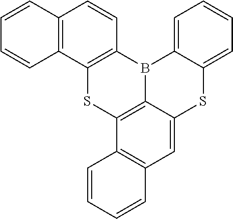 [SMILES: c1ccc2c(c1)Sc1cc3ccccc3c3c1B2c1ccc2ccccc2c1S3]

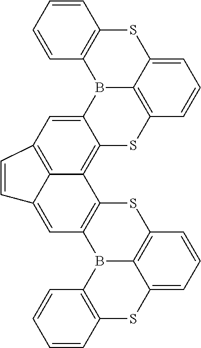 [SMILES: C1=Cc2cc3c(c4c5c(cc1c24)B1c2ccccc2Sc2cccc(c21)S5)Sc1cccc2c1B3c1ccccc1S2]

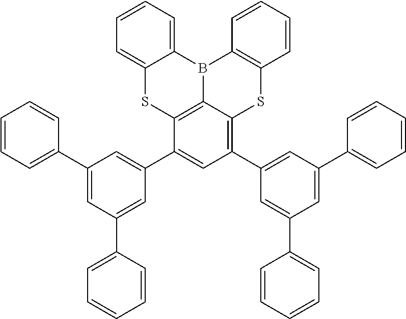 [SMILES: c1ccc(-c2cc(-c3ccccc3)cc(-c3cc(-c4cc(-c5ccccc5)cc(-c5ccccc5)c4)c4c5c3Sc3ccccc3B5c3ccccc3S4)c2)cc1]

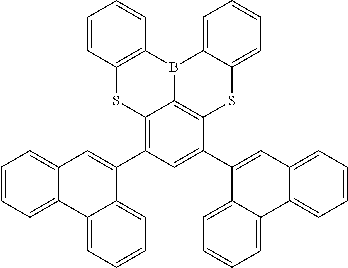 [SMILES: c1ccc2c(c1)Sc1c(-c3cc4ccccc4c4ccccc34)cc(-c3cc4ccccc4c4ccccc34)c3c1B2c1ccccc1S3]

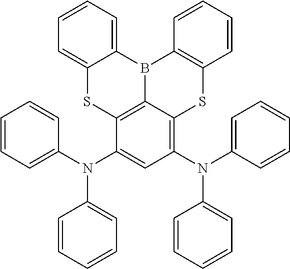 [SMILES: c1ccc(N(c2ccccc2)c2cc(N(c3ccccc3)c3ccccc3)c3c4c2Sc2ccccc2B4c2ccccc2S3)cc1]

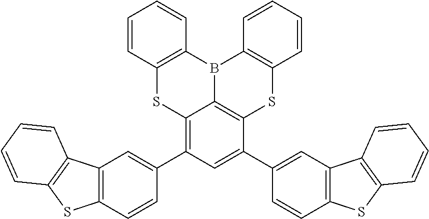 [SMILES: c1ccc2c(c1)Sc1c(-c3ccc4sc5ccccc5c4c3)cc(-c3ccc4sc5ccccc5c4c3)c3c1B2c1ccccc1S3]

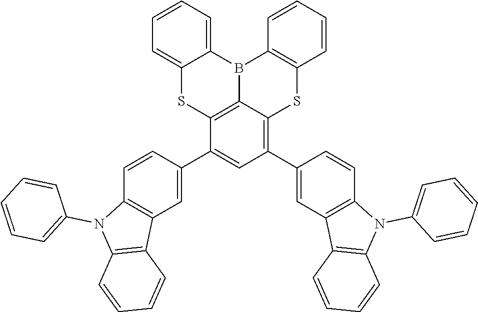

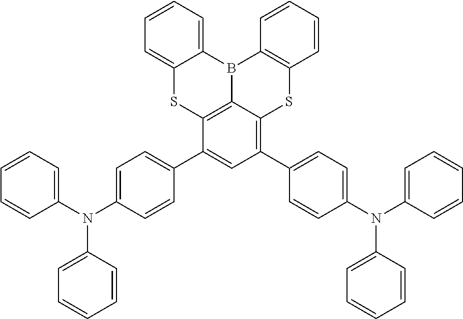

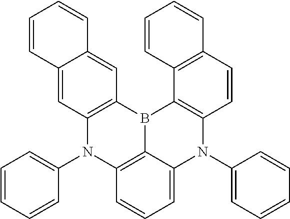 [SMILES: c1ccc(N2c3cc4ccccc4cc3B3c4c2cccc4N(c2ccccc2)c2ccc4ccccc4c23)cc1]

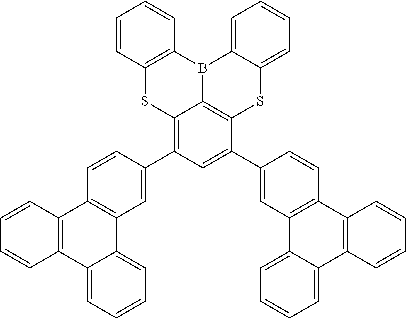 [SMILES: c1ccc2c(c1)Sc1c(-c3ccc4c5ccccc5c5ccccc5c4c3)cc(-c3ccc4c5ccccc5c5ccccc5c4c3)c3c1B2c1ccccc1S3]

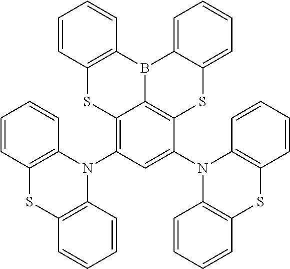 [SMILES: c1ccc2c(c1)Sc1c(N3c4ccccc4Sc4ccccc43)cc(N3c4ccccc4Sc4ccccc43)c3c1B2c1ccccc1S3]

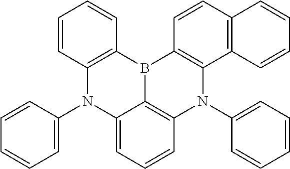 [SMILES: c1ccc(N2c3ccccc3B3c4ccc5ccccc5c4N(c4ccccc4)c4cccc2c43)cc1]

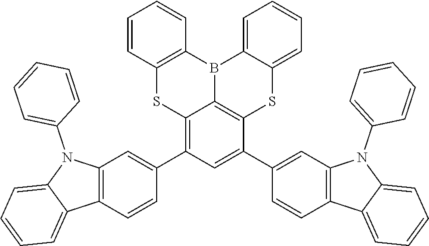 [SMILES: c1ccc(-n2c3ccccc3c3ccc(-c4cc(-c5ccc6c7ccccc7n(-c7ccccc7)c6c5)c5c6c4Sc4ccccc4B6c4ccccc4S5)cc32)cc1]

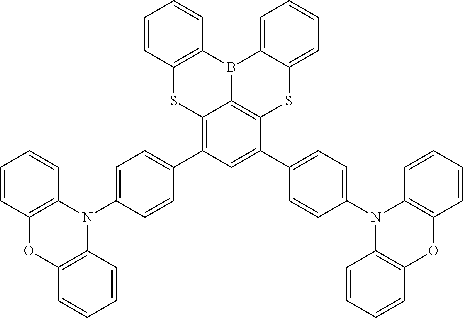 [SMILES: c1ccc2c(c1)Oc1ccccc1N2c1ccc(-c2cc(-c3ccc(N4c5ccccc5Oc5ccccc54)cc3)c3c4c2Sc2ccccc2B4c2ccccc2S3)cc1]

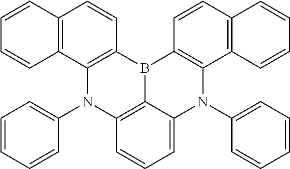 [SMILES: c1ccc(N2c3cccc4c3B(c3ccc5ccccc5c32)c2ccc3ccccc3c2N4c2ccccc2)cc1]

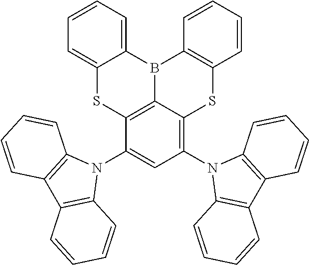

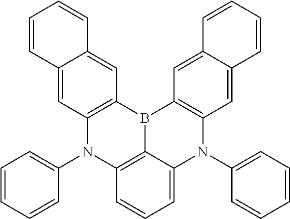 [SMILES: c1ccc(N2c3cc4ccccc4cc3B3c4cc5ccccc5cc4N(c4ccccc4)c4cccc2c43)cc1]

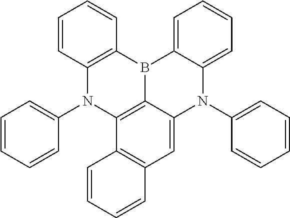 [SMILES: c1ccc(N2c3ccccc3B3c4ccccc4N(c4ccccc4)c4c3c2cc2ccccc42)cc1]

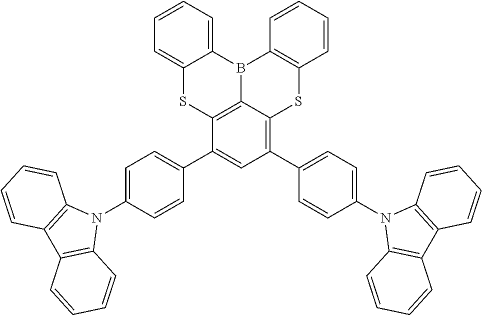

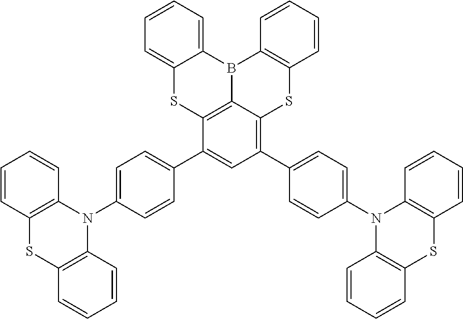

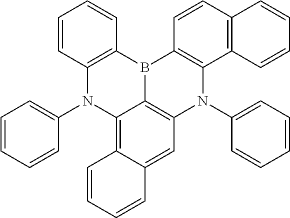 [SMILES: c1ccc(N2c3cc4ccccc4c4c3B(c3ccccc3N4c3ccccc3)c3ccc4ccccc4c32)cc1]

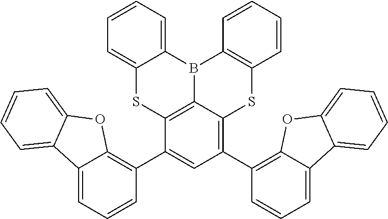

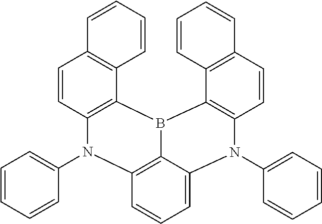 [SMILES: c1ccc(N2c3cccc4c3B(c3c2ccc2ccccc32)c2c(ccc3ccccc23)N4c2ccccc2)cc1]

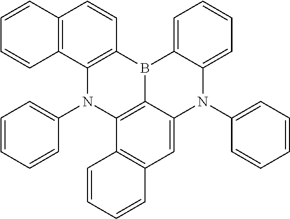 [SMILES: c1ccc(N2c3ccccc3B3c4ccc5ccccc5c4N(c4ccccc4)c4c3c2cc2ccccc42)cc1]

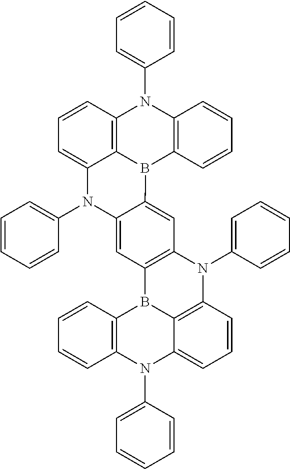 [SMILES: c1ccc(N2c3ccccc3B3c4cc5c(cc4N(c4ccccc4)c4cccc2c43)B2c3ccccc3N(c3ccccc3)c3cccc(c32)N5c2ccccc2)cc1]

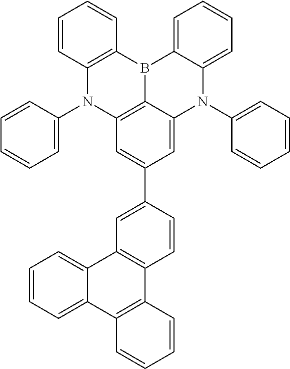 [SMILES: c1ccc(N2c3ccccc3B3c4ccccc4N(c4ccccc4)c4cc(-c5ccc6c7ccccc7c7ccccc7c6c5)cc2c43)cc1]

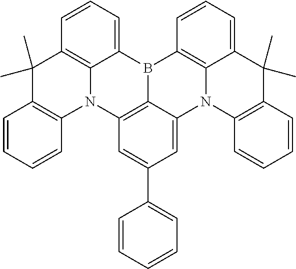

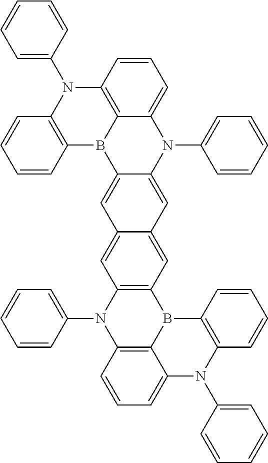 [SMILES: c1ccc(N2c3ccccc3B3c4cc5cc6c(cc5cc4N(c4ccccc4)c4cccc2c43)B2c3ccccc3N(c3ccccc3)c3cccc(c32)N6c2ccccc2)cc1]

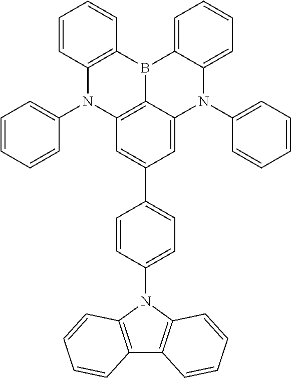 [SMILES: c1ccc(N2c3ccccc3B3c4ccccc4N(c4ccccc4)c4cc(-c5ccc(-n6c7ccccc7c7ccccc76)cc5)cc2c43)cc1]

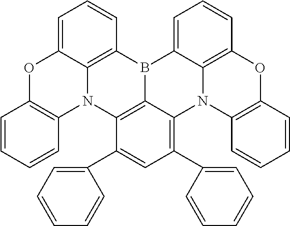 [SMILES: c1ccc(-c2cc(-c3ccccc3)c3c4c2N2c5ccccc5Oc5cccc(c52)B4c2cccc4c2N3c2ccccc2O4)cc1]

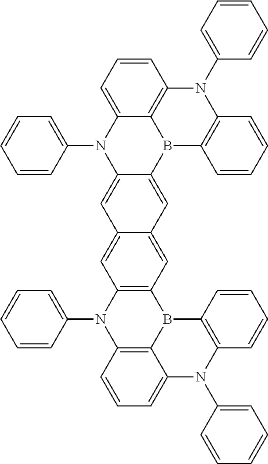 [SMILES: c1ccc(N2c3ccccc3B3c4cc5cc6c(cc5cc4N(c4ccccc4)c4cccc2c43)N(c2ccccc2)c2cccc3c2B6c2ccccc2N3c2ccccc2)cc1]

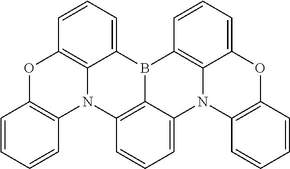 [SMILES: c1ccc2c(c1)Oc1cccc3c1N2c1cccc2c1B3c1cccc3c1N2c1ccccc1O3]

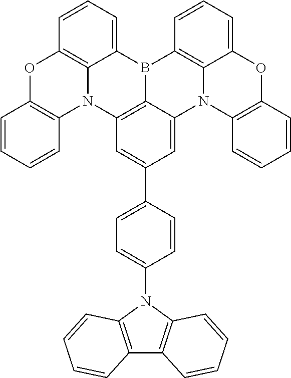 [SMILES: c1ccc2c(c1)Oc1cccc3c1N2c1cc(-c2ccc(-n4c5ccccc5c5ccccc54)cc2)cc2c1B3c1cccc3c1N2c1ccccc1O3]

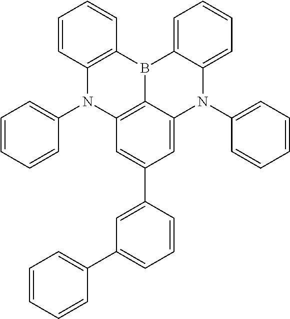 [SMILES: c1ccc(-c2cccc(-c3cc4c5c(c3)N(c3ccccc3)c3ccccc3B5c3ccccc3N4c3ccccc3)c2)cc1]

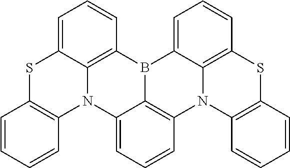 [SMILES: c1ccc2c(c1)Sc1cccc3c1N2c1cccc2c1B3c1cccc3c1N2c1ccccc1S3]

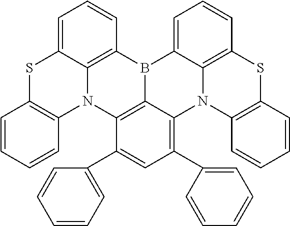 [SMILES: c1ccc(-c2cc(-c3ccccc3)c3c4c2N2c5ccccc5Sc5cccc(c52)B4c2cccc4c2N3c2ccccc2S4)cc1]

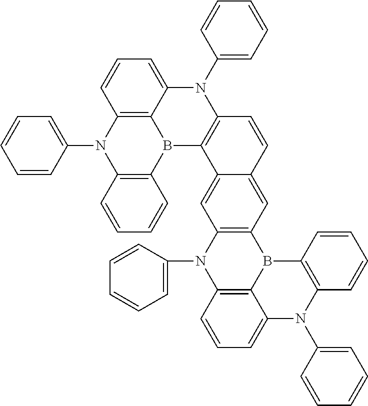 [SMILES: c1ccc(N2c3ccccc3B3c4cc5ccc6c(c5cc4N(c4ccccc4)c4cccc2c43)B2c3ccccc3N(c3ccccc3)c3cccc(c32)N6c2ccccc2)cc1]

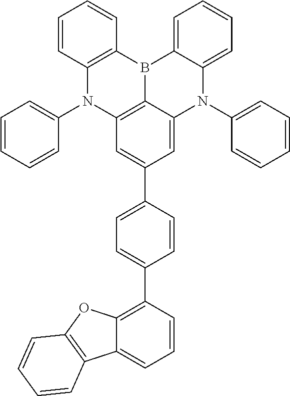 [SMILES: c1ccc(N2c3ccccc3B3c4ccccc4N(c4ccccc4)c4cc(-c5ccc(-c6cccc7c6oc6ccccc67)cc5)cc2c43)cc1]

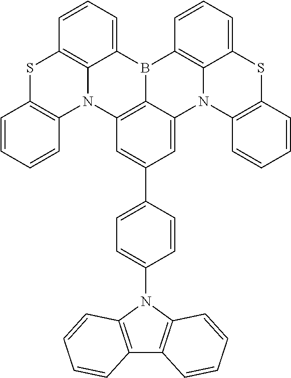 [SMILES: c1ccc2c(c1)Sc1cccc3c1N2c1cc(-c2ccc(-n4c5ccccc5c5ccccc54)cc2)cc2c1B3c1cccc3c1N2c1ccccc1S3]

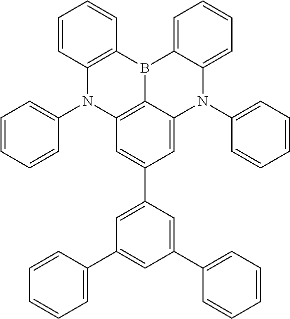 [SMILES: c1ccc(-c2cc(-c3ccccc3)cc(-c3cc4c5c(c3)N(c3ccccc3)c3ccccc3B5c3ccccc3N4c3ccccc3)c2)cc1]

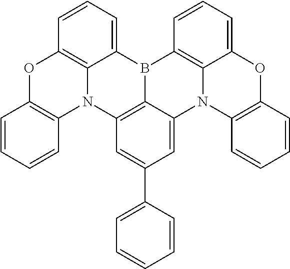 [SMILES: c1ccc(-c2cc3c4c(c2)N2c5ccccc5Oc5cccc(c52)B4c2cccc4c2N3c2ccccc2O4)cc1]

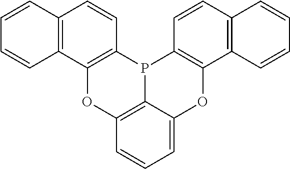 [SMILES: c1cc2c3c(c1)Oc1c(ccc4ccccc14)P3c1ccc3ccccc3c1O2]

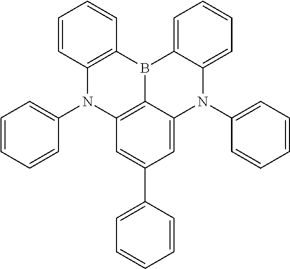 [SMILES: c1ccc(-c2cc3c4c(c2)N(c2ccccc2)c2ccccc2B4c2ccccc2N3c2ccccc2)cc1]

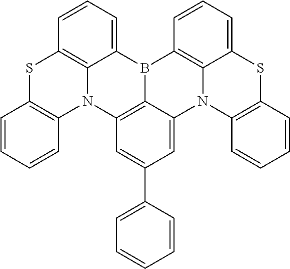 [SMILES: c1ccc(-c2cc3c4c(c2)N2c5ccccc5Sc5cccc(c52)B4c2cccc4c2N3c2ccccc2S4)cc1]

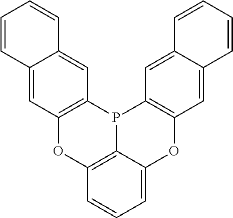 [SMILES: c1cc2c3c(c1)Oc1cc4ccccc4cc1P3c1cc3ccccc3cc1O2]

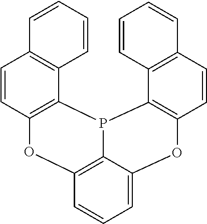 [SMILES: c1cc2c3c(c1)Oc1ccc4ccccc4c1P3c1c(ccc3ccccc13)O2]

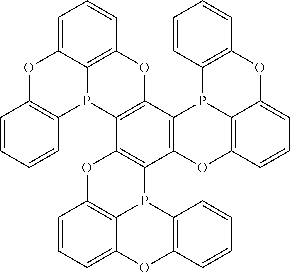 [SMILES: c1ccc2c(c1)oc1cccc3oc4c(c5oc6cccc7oc8ccccc8p(c76)c5c5oc6cccc7oc8ccccc8p(c76)c45)p2c13]

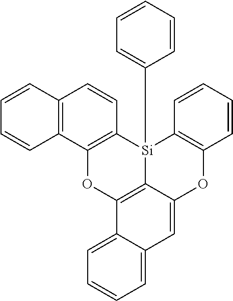 [SMILES: c1ccc([Si]23c4ccccc4Oc4cc5ccccc5c(c42)Oc2c3ccc3ccccc23)cc1]

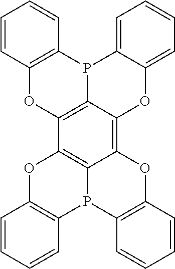 [SMILES: c1ccc2c(c1)oc1c3oc4ccccc4p4c5ccccc5oc(c5oc6ccccc6p2c15)c34]

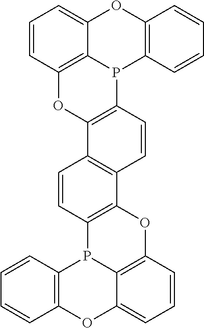 [SMILES: c1ccc2c(c1)Oc1cccc3oc4c5ccc6c(oc7cccc8c7p6-c6ccccc6O8)c5ccc4p-2c13]

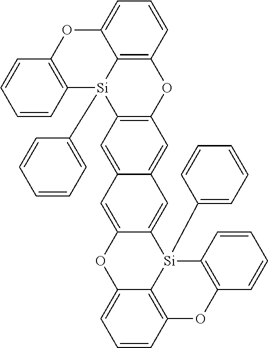 [SMILES: c1ccc([Si]23c4ccccc4Oc4cccc(c42)Oc2cc4cc5c(cc4cc23)Oc2cccc3c2[Si]5(c2ccccc2)c2ccccc2O3)cc1]

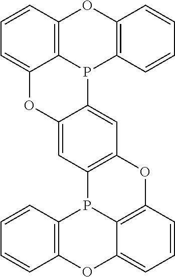 [SMILES: c1ccc2c(c1)oc1cccc3oc4cc5c(cc4p2c13)oc1cccc2oc3ccccc3p5c21]

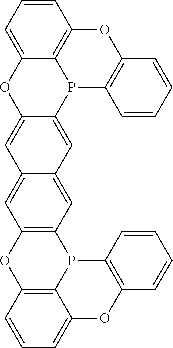 [SMILES: c1ccc2c(c1)Oc1cccc3oc4cc5cc6oc7cccc8c7p(c6cc5cc4p-2c13)-c1ccccc1O8]

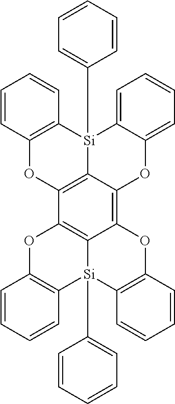 [SMILES: c1ccc([Si]23c4ccccc4Oc4c5c6c(c(c42)Oc2ccccc23)Oc2ccccc2[Si]6(c2ccccc2)c2ccccc2O5)cc1]

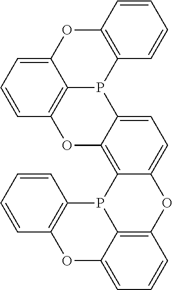 [SMILES: c1ccc2c(c1)oc1cccc3oc4c(ccc5oc6cccc7oc8ccccc8p(c76)c54)p2c13]

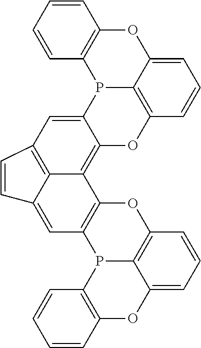 [SMILES: c1ccc2c(c1)oc1cccc3oc4c5c6oc7cccc8oc9ccccc9p(c6cc6ccc(cc4p2c13)c65)c87]

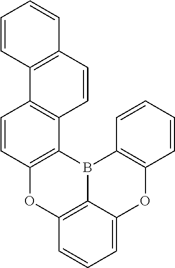 [SMILES: c1ccc2c(c1)Oc1cccc3c1B2c1c(ccc2c1ccc1ccccc12)O3]

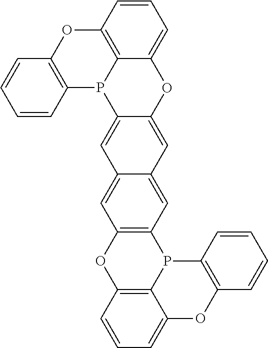 [SMILES: c1ccc2c(c1)Oc1cccc3oc4cc5cc6c(cc5cc4p-2c13)oc1cccc2c1p6-c1ccccc1O2]

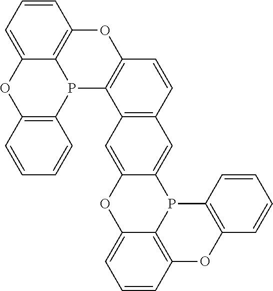 [SMILES: c1ccc2c(c1)Oc1cccc3oc4cc5c(ccc6oc7cccc8c7p(c65)-c5ccccc5O8)cc4p-2c13]

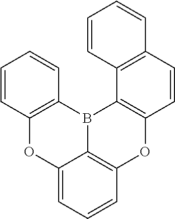 [SMILES: c1ccc2c(c1)Oc1cccc3c1B2c1c(ccc2ccccc12)O3]

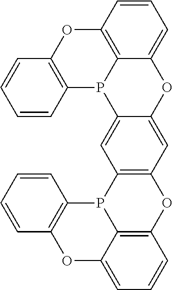 [SMILES: c1ccc2c(c1)oc1cccc3oc4cc5oc6cccc7oc8ccccc8p(c5cc4p2c13)c76]

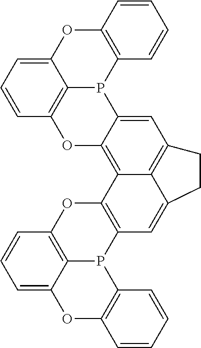 [SMILES: c1ccc2c(c1)Oc1cccc3oc4c5c6c(cc4p-2c13)CCc6cc1c5oc2cccc3c2p1-c1ccccc1O3]

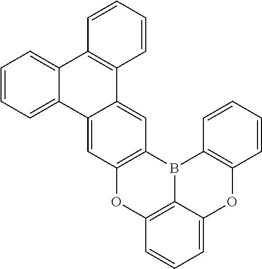 [SMILES: c1ccc2c(c1)Oc1cccc3c1B2c1cc2c4ccccc4c4ccccc4c2cc1O3]

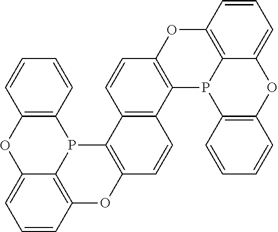 [SMILES: c1ccc2c(c1)Oc1cccc3oc4ccc5c(ccc6oc7cccc8c7p(c65)-c5ccccc5O8)c4p-2c13]

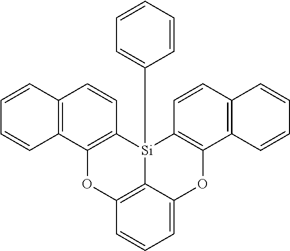 [SMILES: c1ccc([Si]23c4ccc5ccccc5c4Oc4cccc(c42)Oc2c3ccc3ccccc23)cc1]

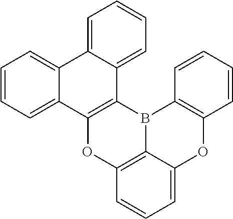 [SMILES: c1ccc2c(c1)Oc1cccc3c1B2c1c(c2ccccc2c2ccccc12)O3]

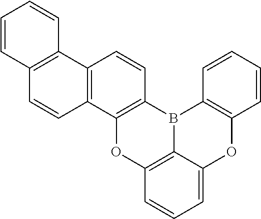 [SMILES: c1ccc2c(c1)Oc1cccc3c1B2c1ccc2c(ccc4ccccc42)c1O3]

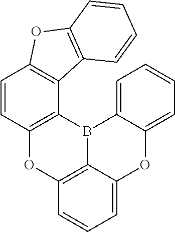 [SMILES: c1ccc2c(c1)Oc1cccc3c1B2c1c(ccc2oc4ccccc4c12)O3]

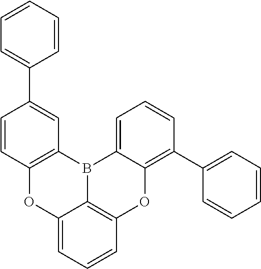 [SMILES: c1ccc(-c2ccc3c(c2)B2c4cccc(-c5ccccc5)c4Oc4cccc(c42)O3)cc1]

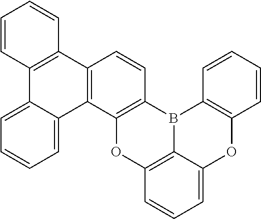 [SMILES: c1ccc2c(c1)Oc1cccc3c1B2c1ccc2c4ccccc4c4ccccc4c2c1O3]

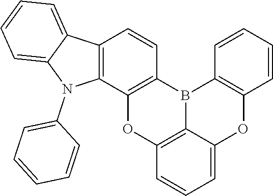 [SMILES: c1ccc(-n2c3ccccc3c3ccc4c(c32)Oc2cccc3c2B4c2ccccc2O3)cc1]

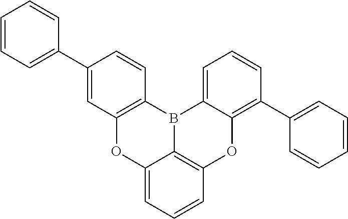 [SMILES: c1ccc(-c2ccc3c(c2)Oc2cccc4c2B3c2cccc(-c3ccccc3)c2O4)cc1]

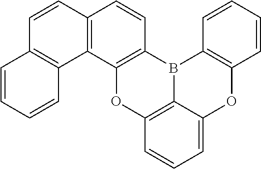 [SMILES: c1ccc2c(c1)Oc1cccc3c1B2c1ccc2ccc4ccccc4c2c1O3]

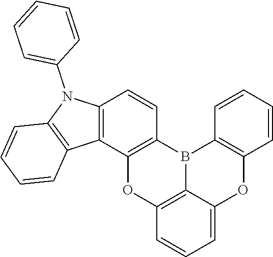 [SMILES: c1ccc(-n2c3ccccc3c3c4c(ccc32)B2c3ccccc3Oc3cccc(c32)O4)cc1]

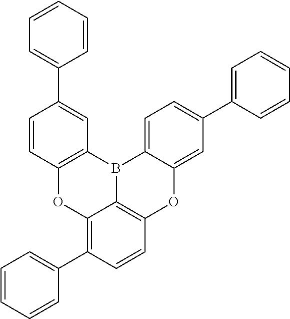 [SMILES: c1ccc(-c2ccc3c(c2)Oc2ccc(-c4ccccc4)c4c2B3c2cc(-c3ccccc3)ccc2O4)cc1]

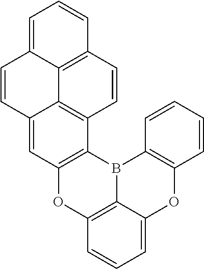 [SMILES: c1ccc2c(c1)Oc1cccc3c1B2c1c(cc2ccc4cccc5ccc1c2c45)O3]

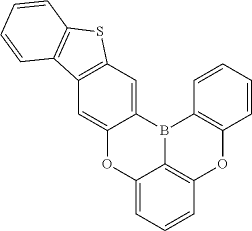 [SMILES: c1ccc2c(c1)Oc1cccc3c1B2c1cc2sc4ccccc4c2cc1O3]

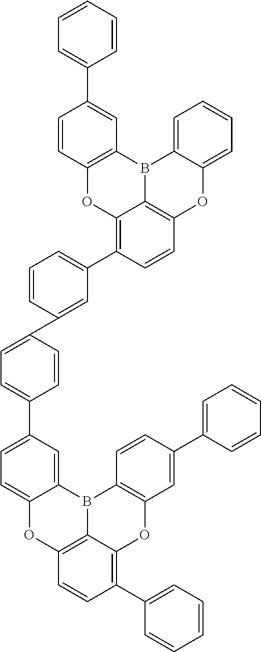 [SMILES: c1ccc(-c2ccc3c(c2)Oc2c(-c4ccccc4)ccc4c2B3c2cc(-c3ccc(-c5cccc(-c6ccc7c8c6Oc6ccc(-c9ccccc9)cc6B8c6ccccc6O7)c5)cc3)ccc2O4)cc1]

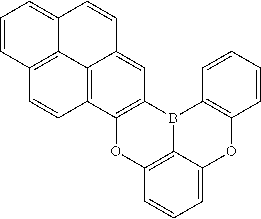 [SMILES: c1ccc2c(c1)Oc1cccc3c1B2c1cc2ccc4cccc5ccc(c1O3)c2c45]

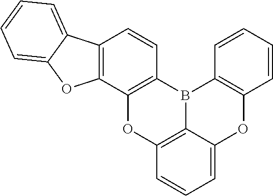 [SMILES: c1ccc2c(c1)Oc1cccc3c1B2c1ccc2c(oc4ccccc42)c1O3]

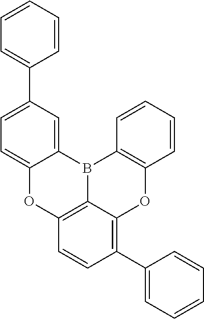 [SMILES: c1ccc(-c2ccc3c(c2)B2c4ccccc4Oc4c(-c5ccccc5)ccc(c42)O3)cc1]

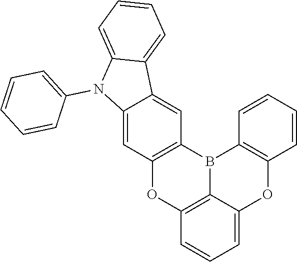 [SMILES: c1ccc(-n2c3ccccc3c3cc4c(cc32)Oc2cccc3c2B4c2ccccc2O3)cc1]

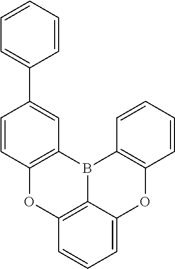 [SMILES: c1ccc(-c2ccc3c(c2)B2c4ccccc4Oc4cccc(c42)O3)cc1]

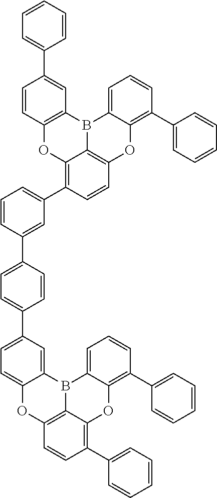 [SMILES: c1ccc(-c2ccc3c(c2)B2c4cccc(-c5ccccc5)c4Oc4ccc(-c5cccc(-c6ccc(-c7ccc8c(c7)B7c9cccc(-c%10ccccc%10)c9Oc9c(-c%10ccccc%10)ccc(c97)O8)cc6)c5)c(c42)O3)cc1]

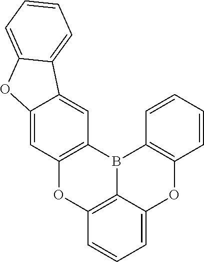 [SMILES: c1ccc2c(c1)Oc1cccc3c1B2c1cc2c(cc1O3)oc1ccccc12]

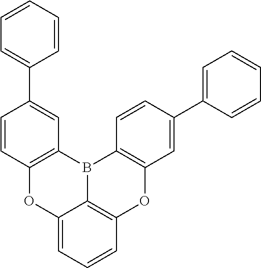 [SMILES: c1ccc(-c2ccc3c(c2)Oc2cccc4c2B3c2cc(-c3ccccc3)ccc2O4)cc1]

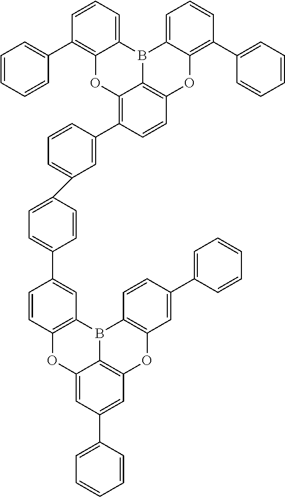 [SMILES: c1ccc(-c2ccc3c(c2)Oc2cc(-c4ccccc4)cc4c2B3c2cc(-c3ccc(-c5cccc(-c6ccc7c8c6Oc6c(cccc6-c6ccccc6)B8c6cccc(-c8ccccc8)c6O7)c5)cc3)ccc2O4)cc1]

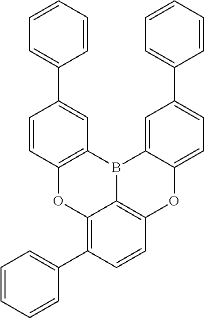 [SMILES: c1ccc(-c2ccc3c(c2)B2c4cc(-c5ccccc5)ccc4Oc4c(-c5ccccc5)ccc(c42)O3)cc1]

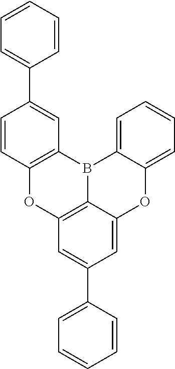 [SMILES: c1ccc(-c2cc3c4c(c2)Oc2ccc(-c5ccccc5)cc2B4c2ccccc2O3)cc1]

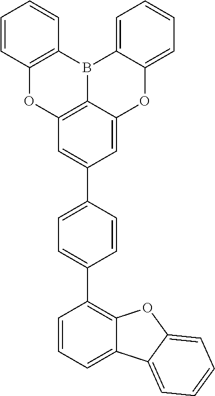 [SMILES: c1ccc2c(c1)Oc1cc(-c3ccc(-c4cccc5c4oc4ccccc45)cc3)cc3c1B2c1ccccc1O3]

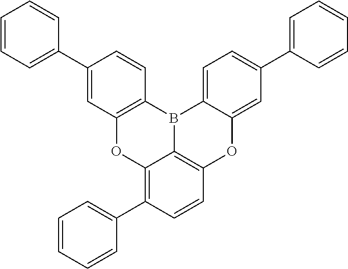 [SMILES: c1ccc(-c2ccc3c(c2)Oc2ccc(-c4ccccc4)c4c2B3c2ccc(-c3ccccc3)cc2O4)cc1]

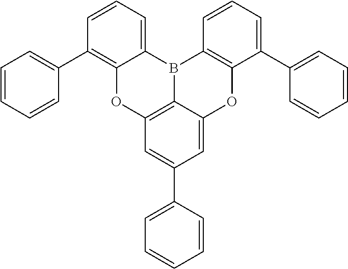 [SMILES: c1ccc(-c2cc3c4c(c2)Oc2c(cccc2-c2ccccc2)B4c2cccc(-c4ccccc4)c2O3)cc1]

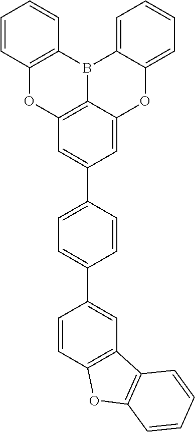 [SMILES: c1ccc2c(c1)Oc1cc(-c3ccc(-c4ccc5oc6ccccc6c5c4)cc3)cc3c1B2c1ccccc1O3]

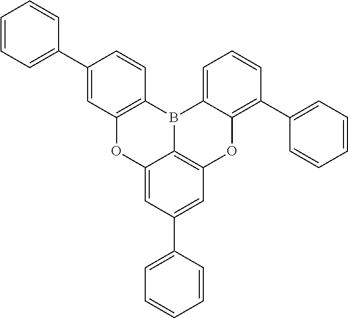 [SMILES: c1ccc(-c2ccc3c(c2)Oc2cc(-c4ccccc4)cc4c2B3c2cccc(-c3ccccc3)c2O4)cc1]

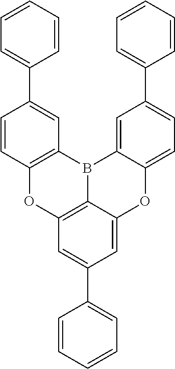 [SMILES: c1ccc(-c2cc3c4c(c2)Oc2ccc(-c5ccccc5)cc2B4c2cc(-c4ccccc4)ccc2O3)cc1]

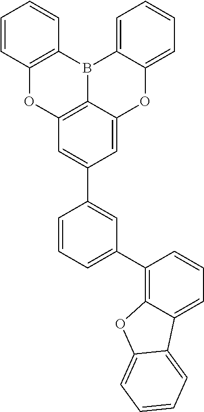 [SMILES: c1cc(-c2cc3c4c(c2)Oc2ccccc2B4c2ccccc2O3)cc(-c2cccc3c2oc2ccccc23)c1]

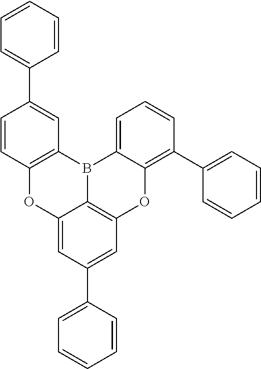 [SMILES: c1ccc(-c2cc3c4c(c2)Oc2c(cccc2-c2ccccc2)B4c2cc(-c4ccccc4)ccc2O3)cc1]

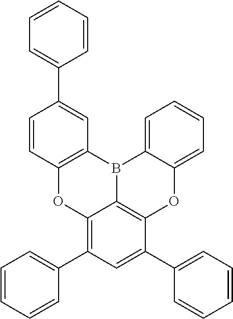 [SMILES: c1ccc(-c2ccc3c(c2)B2c4ccccc4Oc4c(-c5ccccc5)cc(-c5ccccc5)c(c42)O3)cc1]

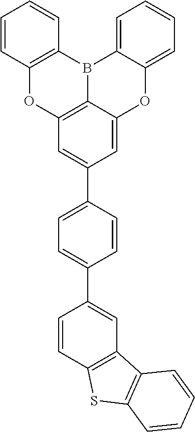 [SMILES: c1ccc2c(c1)Oc1cc(-c3ccc(-c4ccc5sc6ccccc6c5c4)cc3)cc3c1B2c1ccccc1O3]

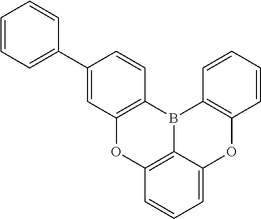 [SMILES: c1ccc(-c2ccc3c(c2)Oc2cccc4c2B3c2ccccc2O4)cc1]

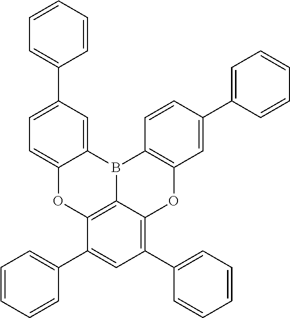 [SMILES: c1ccc(-c2ccc3c(c2)Oc2c(-c4ccccc4)cc(-c4ccccc4)c4c2B3c2cc(-c3ccccc3)ccc2O4)cc1]

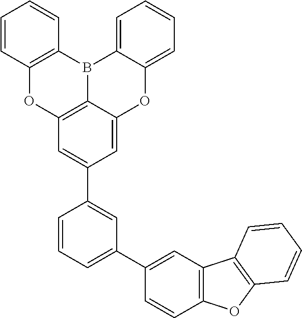 [SMILES: c1cc(-c2cc3c4c(c2)Oc2ccccc2B4c2ccccc2O3)cc(-c2ccc3oc4ccccc4c3c2)c1]

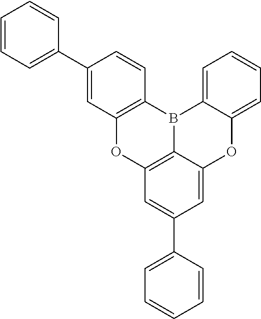 [SMILES: c1ccc(-c2ccc3c(c2)Oc2cc(-c4ccccc4)cc4c2B3c2ccccc2O4)cc1]

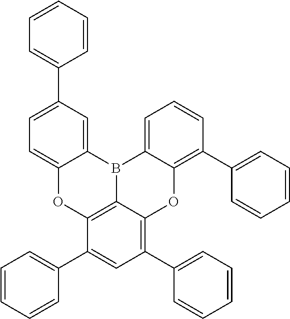 [SMILES: c1ccc(-c2ccc3c(c2)B2c4cccc(-c5ccccc5)c4Oc4c(-c5ccccc5)cc(-c5ccccc5)c(c42)O3)cc1]

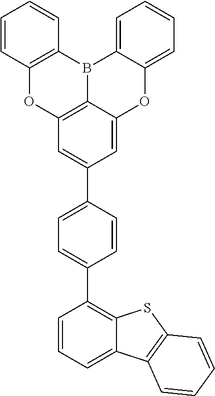 [SMILES: c1ccc2c(c1)Oc1cc(-c3ccc(-c4cccc5c4sc4ccccc45)cc3)cc3c1B2c1ccccc1O3]

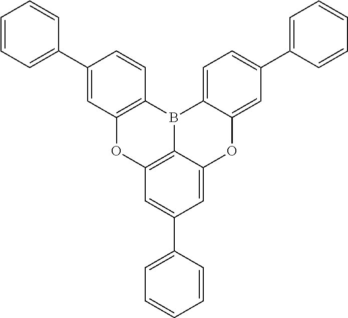 [SMILES: c1ccc(-c2ccc3c(c2)Oc2cc(-c4ccccc4)cc4c2B3c2ccc(-c3ccccc3)cc2O4)cc1]

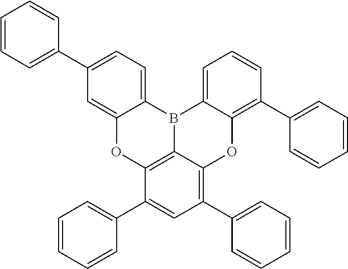 [SMILES: c1ccc(-c2ccc3c(c2)Oc2c(-c4ccccc4)cc(-c4ccccc4)c4c2B3c2cccc(-c3ccccc3)c2O4)cc1]

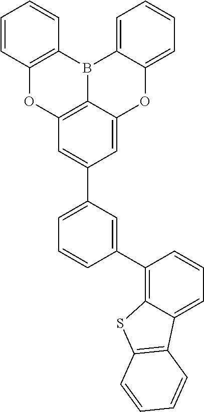 [SMILES: c1cc(-c2cc3c4c(c2)Oc2ccccc2B4c2ccccc2O3)cc(-c2cccc3c2sc2ccccc23)c1]

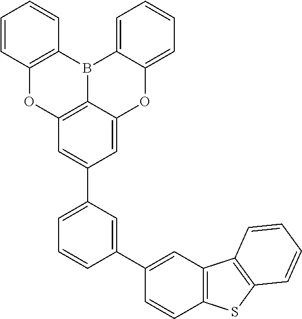 [SMILES: c1cc(-c2cc3c4c(c2)Oc2ccccc2B4c2ccccc2O3)cc(-c2ccc3sc4ccccc4c3c2)c1]

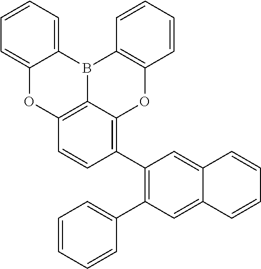 [SMILES: c1ccc(-c2cc3ccccc3cc2-c2ccc3c4c2Oc2ccccc2B4c2ccccc2O3)cc1]

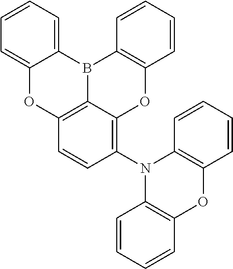 [SMILES: c1ccc2c(c1)Oc1ccc(N3c4ccccc4Oc4ccccc43)c3c1B2c1ccccc1O3]

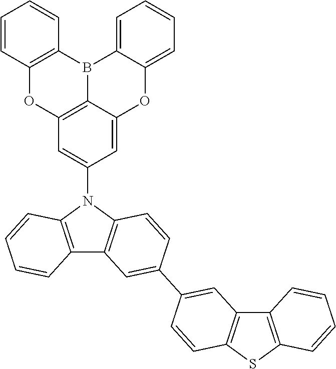 [SMILES: c1ccc2c(c1)Oc1cc(-n3c4ccccc4c4cc(-c5ccc6sc7ccccc7c6c5)ccc43)cc3c1B2c1ccccc1O3]

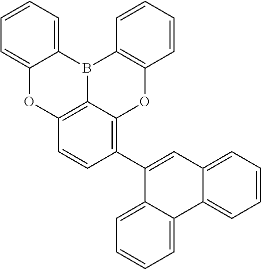 [SMILES: c1ccc2c(c1)Oc1ccc(-c3cc4ccccc4c4ccccc34)c3c1B2c1ccccc1O3]

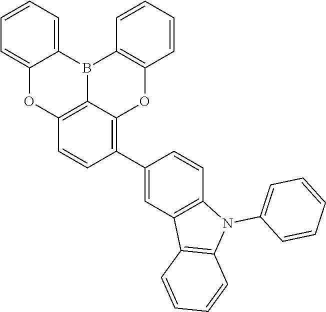 [SMILES: c1ccc(-n2c3ccccc3c3cc(-c4ccc5c6c4Oc4ccccc4B6c4ccccc4O5)ccc32)cc1]

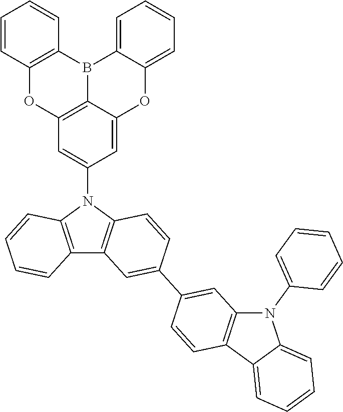 [SMILES: c1ccc(-n2c3ccccc3c3ccc(-c4ccc5c(c4)c4ccccc4n5-c4cc5c6c(c4)Oc4ccccc4B6c4ccccc4O5)cc32)cc1]

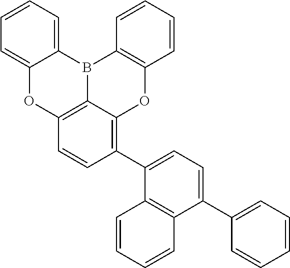 [SMILES: c1ccc(-c2ccc(-c3ccc4c5c3Oc3ccccc3B5c3ccccc3O4)c3ccccc23)cc1]

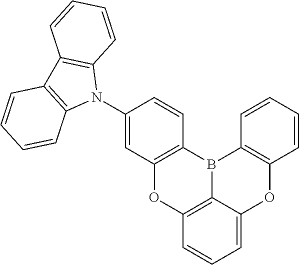 [SMILES: c1ccc2c(c1)Oc1cccc3c1B2c1ccc(-n2c4ccccc4c4ccccc42)cc1O3]

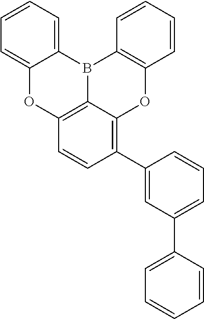 [SMILES: c1ccc(-c2cccc(-c3ccc4c5c3Oc3ccccc3B5c3ccccc3O4)c2)cc1]

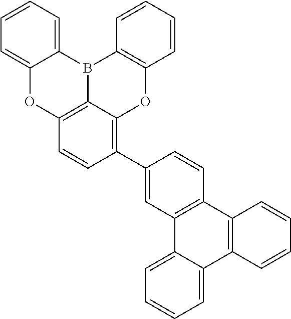 [SMILES: c1ccc2c(c1)Oc1ccc(-c3ccc4c5ccccc5c5ccccc5c4c3)c3c1B2c1ccccc1O3]

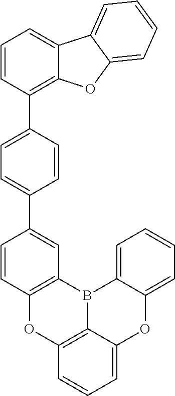 [SMILES: c1ccc2c(c1)Oc1cccc3c1B2c1cc(-c2ccc(-c4cccc5c4oc4ccccc45)cc2)ccc1O3]

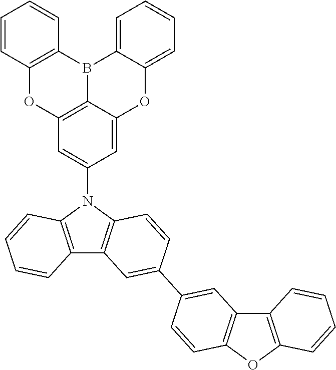 [SMILES: c1ccc2c(c1)Oc1cc(-n3c4ccccc4c4cc(-c5ccc6oc7ccccc7c6c5)ccc43)cc3c1B2c1ccccc1O3]

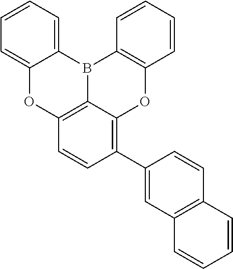 [SMILES: c1ccc2c(c1)Oc1ccc(-c3ccc4ccccc4c3)c3c1B2c1ccccc1O3]

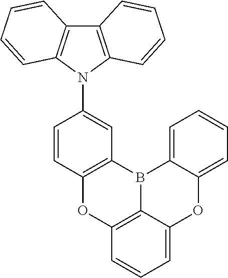 [SMILES: c1ccc2c(c1)Oc1cccc3c1B2c1cc(-n2c4ccccc4c4ccccc42)ccc1O3]

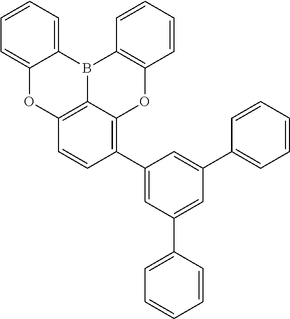 [SMILES: c1ccc(-c2cc(-c3ccccc3)cc(-c3ccc4c5c3Oc3ccccc3B5c3ccccc3O4)c2)cc1]

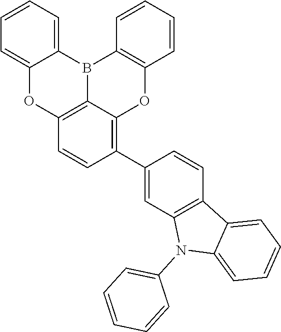 [SMILES: c1ccc(-n2c3ccccc3c3ccc(-c4ccc5c6c4Oc4ccccc4B6c4ccccc4O5)cc32)cc1]

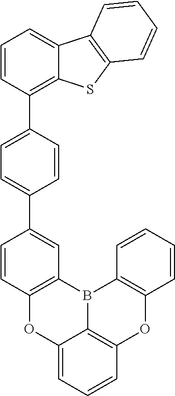 [SMILES: c1ccc2c(c1)Oc1cccc3c1B2c1cc(-c2ccc(-c4cccc5c4sc4ccccc45)cc2)ccc1O3]

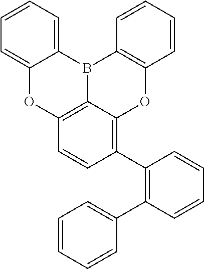 [SMILES: c1ccc(-c2ccccc2-c2ccc3c4c2Oc2ccccc2B4c2ccccc2O3)cc1]

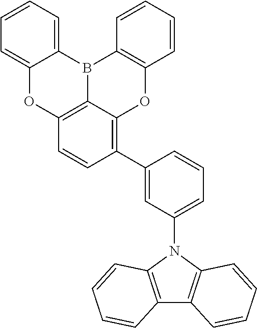 [SMILES: c1cc(-c2ccc3c4c2Oc2ccccc2B4c2ccccc2O3)cc(-n2c3ccccc3c3ccccc32)c1]

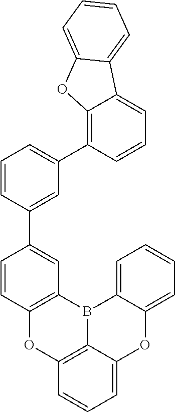 [SMILES: c1cc(-c2ccc3c(c2)B2c4ccccc4Oc4cccc(c42)O3)cc(-c2cccc3c2oc2ccccc23)c1]

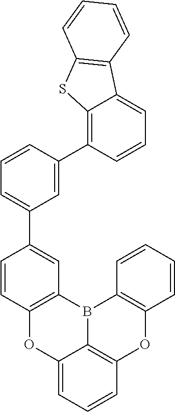 [SMILES: c1cc(-c2ccc3c(c2)B2c4ccccc4Oc4cccc(c42)O3)cc(-c2cccc3c2sc2ccccc23)c1]

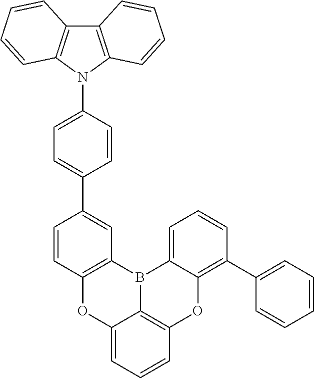 [SMILES: c1ccc(-c2cccc3c2Oc2cccc4c2B3c2cc(-c3ccc(-n5c6ccccc6c6ccccc65)cc3)ccc2O4)cc1]

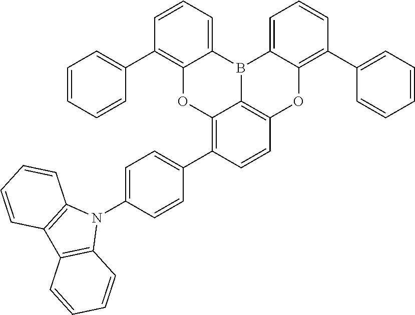 [SMILES: c1ccc(-c2cccc3c2Oc2ccc(-c4ccc(-n5c6ccccc6c6ccccc65)cc4)c4c2B3c2cccc(-c3ccccc3)c2O4)cc1]

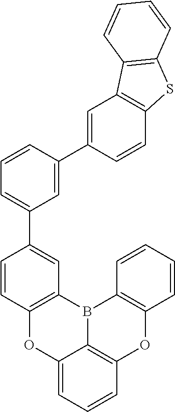 [SMILES: c1cc(-c2ccc3c(c2)B2c4ccccc4Oc4cccc(c42)O3)cc(-c2ccc3sc4ccccc4c3c2)c1]

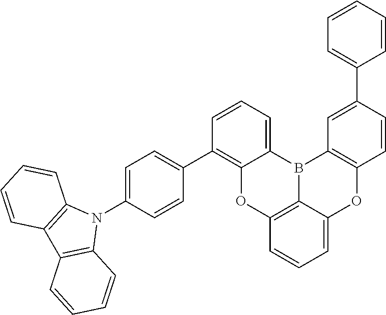 [SMILES: c1ccc(-c2ccc3c(c2)B2c4cccc(-c5ccc(-n6c7ccccc7c7ccccc76)cc5)c4Oc4cccc(c42)O3)cc1]

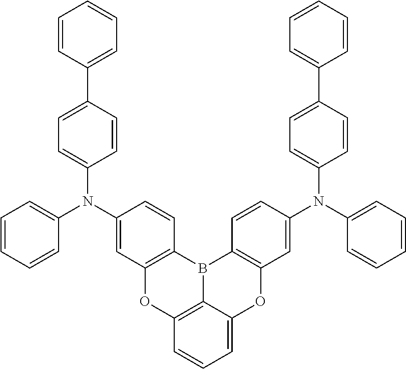 [SMILES: c1ccc(-c2ccc(N(c3ccccc3)c3ccc4c(c3)Oc3cccc5c3B4c3ccc(N(c4ccccc4)c4ccc(-c6ccccc6)cc4)cc3O5)cc2)cc1]

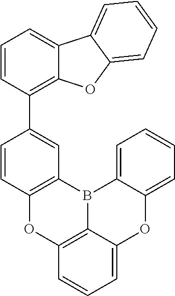 [SMILES: c1ccc2c(c1)Oc1cccc3c1B2c1cc(-c2cccc4c2oc2ccccc24)ccc1O3]

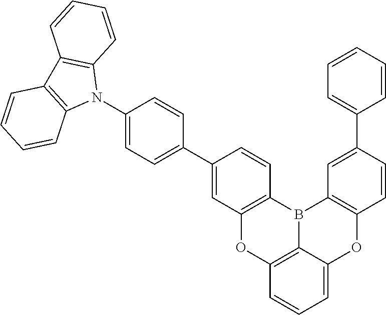 [SMILES: c1ccc(-c2ccc3c(c2)B2c4ccc(-c5ccc(-n6c7ccccc7c7ccccc76)cc5)cc4Oc4cccc(c42)O3)cc1]

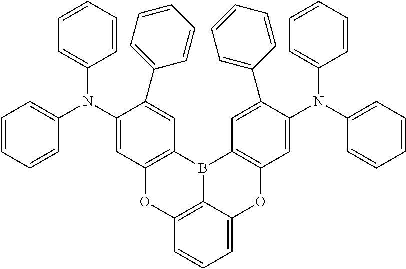 [SMILES: c1ccc(-c2cc3c(cc2N(c2ccccc2)c2ccccc2)Oc2cccc4c2B3c2cc(-c3ccccc3)c(N(c3ccccc3)c3ccccc3)cc2O4)cc1]

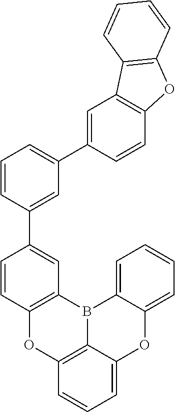 [SMILES: c1cc(-c2ccc3c(c2)B2c4ccccc4Oc4cccc(c42)O3)cc(-c2ccc3oc4ccccc4c3c2)c1]

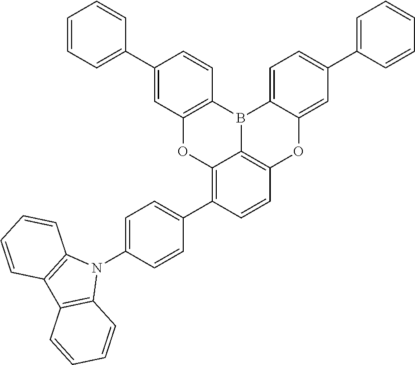 [SMILES: c1ccc(-c2ccc3c(c2)Oc2ccc(-c4ccc(-n5c6ccccc6c6ccccc65)cc4)c4c2B3c2ccc(-c3ccccc3)cc2O4)cc1]

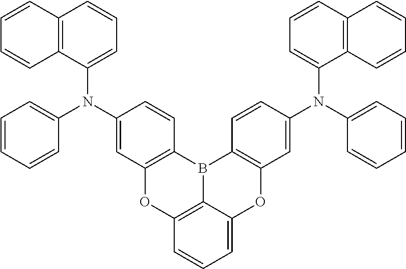 [SMILES: c1ccc(N(c2ccc3c(c2)Oc2cccc4c2B3c2ccc(N(c3ccccc3)c3cccc5ccccc35)cc2O4)c2cccc3ccccc23)cc1]

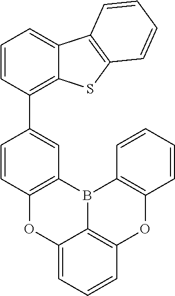 [SMILES: c1ccc2c(c1)Oc1cccc3c1B2c1cc(-c2cccc4c2sc2ccccc24)ccc1O3]

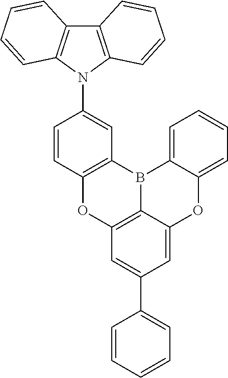 [SMILES: c1ccc(-c2cc3c4c(c2)Oc2ccc(-n5c6ccccc6c6ccccc65)cc2B4c2ccccc2O3)cc1]

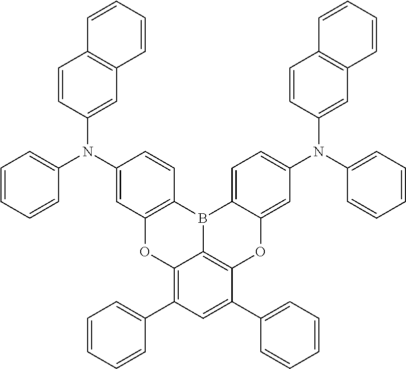 [SMILES: c1ccc(-c2cc(-c3ccccc3)c3c4c2Oc2cc(N(c5ccccc5)c5ccc6ccccc6c5)ccc2B4c2ccc(N(c4ccccc4)c4ccc5ccccc5c4)cc2O3)cc1]

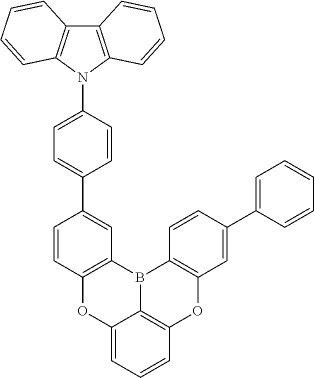 [SMILES: c1ccc(-c2ccc3c(c2)Oc2cccc4c2B3c2cc(-c3ccc(-n5c6ccccc6c6ccccc65)cc3)ccc2O4)cc1]

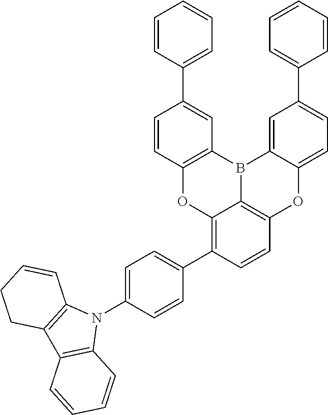 [SMILES: C1=Cc2c(c3ccccc3n2-c2ccc(-c3ccc4c5c3Oc3ccc(-c6ccccc6)cc3B5c3cc(-c5ccccc5)ccc3O4)cc2)CC1]

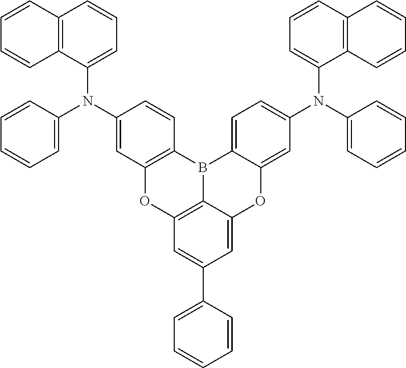 [SMILES: c1ccc(-c2cc3c4c(c2)Oc2cc(N(c5ccccc5)c5cccc6ccccc56)ccc2B4c2ccc(N(c4ccccc4)c4cccc5ccccc45)cc2O3)cc1]

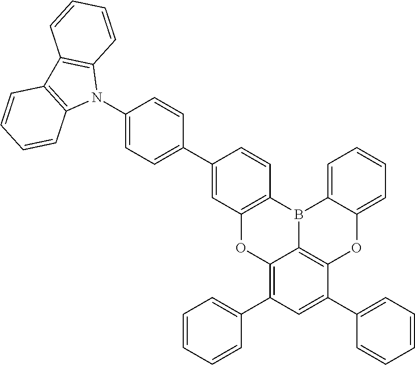 [SMILES: c1ccc(-c2cc(-c3ccccc3)c3c4c2Oc2ccccc2B4c2ccc(-c4ccc(-n5c6ccccc6c6ccccc65)cc4)cc2O3)cc1]

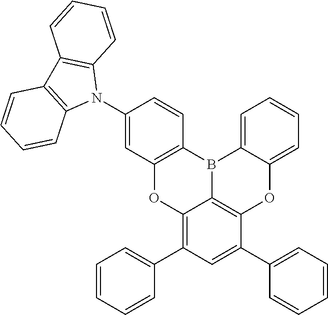 [SMILES: c1ccc(-c2cc(-c3ccccc3)c3c4c2Oc2ccccc2B4c2ccc(-n4c5ccccc5c5ccccc54)cc2O3)cc1]

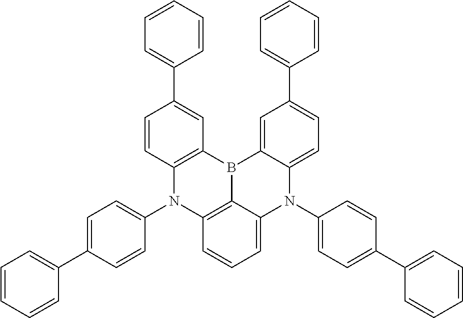 [SMILES: c1ccc(-c2ccc(N3c4ccc(-c5ccccc5)cc4B4c5cc(-c6ccccc6)ccc5N(c5ccc(-c6ccccc6)cc5)c5cccc3c54)cc2)cc1]

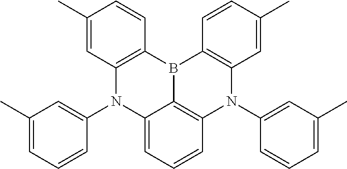

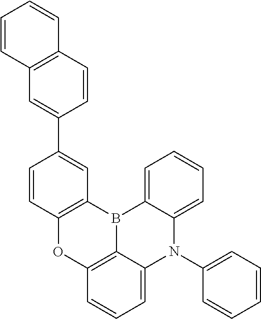 [SMILES: c1ccc(N2c3ccccc3B3c4cc(-c5ccc6ccccc6c5)ccc4Oc4cccc2c43)cc1]

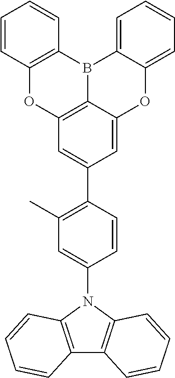 [SMILES: Cc1cc(-n2c3ccccc3c3ccccc32)ccc1-c1cc2c3c(c1)Oc1ccccc1B3c1ccccc1O2]

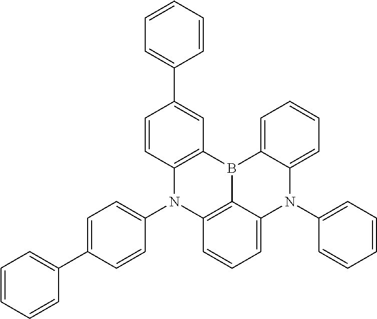 [SMILES: c1ccc(-c2ccc(N3c4ccc(-c5ccccc5)cc4B4c5ccccc5N(c5ccccc5)c5cccc3c54)cc2)cc1]

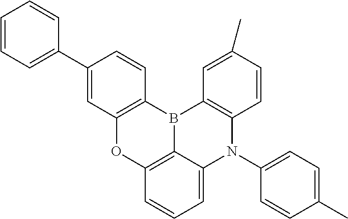 [SMILES: Cc1ccc(N2c3ccc(C)cc3B3c4ccc(-c5ccccc5)cc4Oc4cccc2c43)cc1]

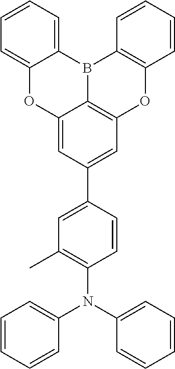 [SMILES: Cc1cc(-c2cc3c4c(c2)Oc2ccccc2B4c2ccccc2O3)ccc1N(c1ccccc1)c1ccccc1]

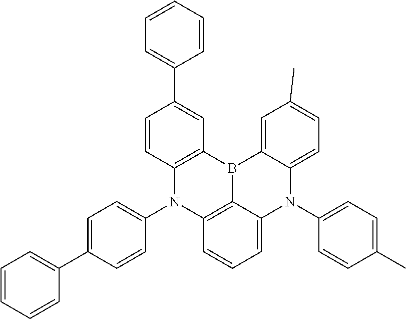 [SMILES: Cc1ccc(N2c3ccc(C)cc3B3c4cc(-c5ccccc5)ccc4N(c4ccc(-c5ccccc5)cc4)c4cccc2c43)cc1]

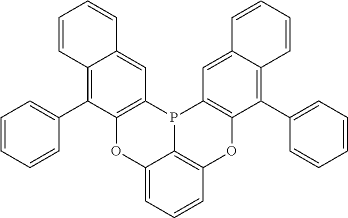 [SMILES: c1ccc(-c2c3c(cc4ccccc24)P2c4cc5ccccc5c(-c5ccccc5)c4Oc4cccc(c42)O3)cc1]

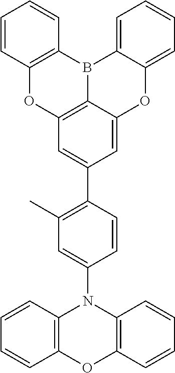 [SMILES: Cc1cc(N2c3ccccc3Oc3ccccc32)ccc1-c1cc2c3c(c1)Oc1ccccc1B3c1ccccc1O2]

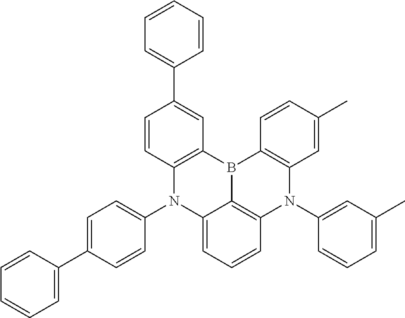 [SMILES: Cc1cccc(N2c3cc(C)ccc3B3c4cc(-c5ccccc5)ccc4N(c4ccc(-c5ccccc5)cc4)c4cccc2c43)c1]

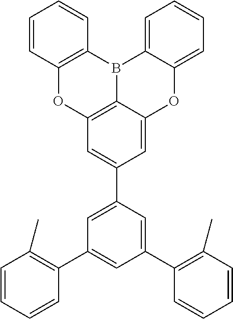 [SMILES: Cc1ccccc1-c1cc(-c2cc3c4c(c2)Oc2ccccc2B4c2ccccc2O3)cc(-c2ccccc2C)c1]

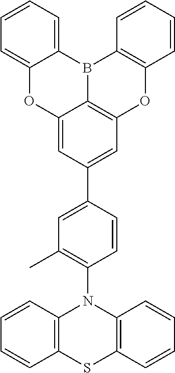 [SMILES: Cc1cc(-c2cc3c4c(c2)Oc2ccccc2B4c2ccccc2O3)ccc1N1c2ccccc2Sc2ccccc21]

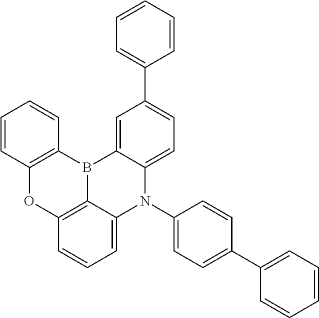 [SMILES: c1ccc(-c2ccc(N3c4ccc(-c5ccccc5)cc4B4c5ccccc5Oc5cccc3c54)cc2)cc1]

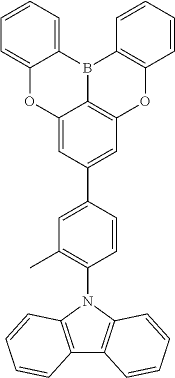 [SMILES: Cc1cc(-c2cc3c4c(c2)Oc2ccccc2B4c2ccccc2O3)ccc1-n1c2ccccc2c2ccccc21]

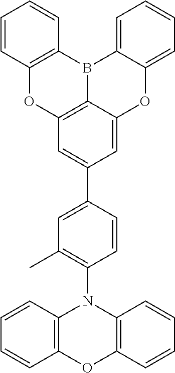 [SMILES: Cc1cc(-c2cc3c4c(c2)Oc2ccccc2B4c2ccccc2O3)ccc1N1c2ccccc2Oc2ccccc21]

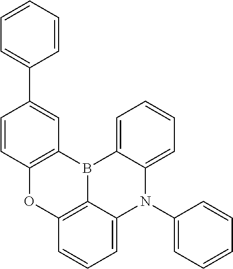 [SMILES: c1ccc(-c2ccc3c(c2)B2c4ccccc4N(c4ccccc4)c4cccc(c42)O3)cc1]

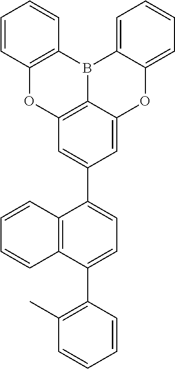 [SMILES: Cc1ccccc1-c1ccc(-c2cc3c4c(c2)Oc2ccccc2B4c2ccccc2O3)c2ccccc12]

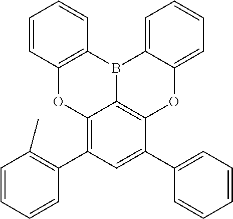 [SMILES: Cc1ccccc1-c1cc(-c2ccccc2)c2c3c1Oc1ccccc1B3c1ccccc1O2]

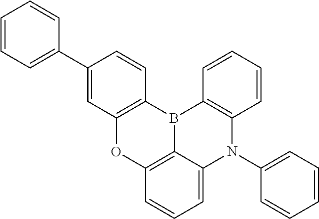 [SMILES: c1ccc(-c2ccc3c(c2)Oc2cccc4c2B3c2ccccc2N4c2ccccc2)cc1]

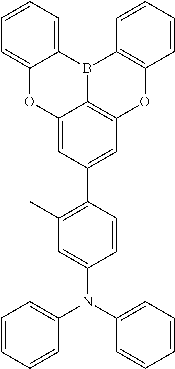 [SMILES: Cc1cc(N(c2ccccc2)c2ccccc2)ccc1-c1cc2c3c(c1)Oc1ccccc1B3c1ccccc1O2]

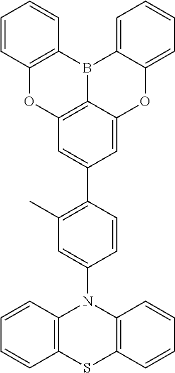 [SMILES: Cc1cc(N2c3ccccc3Sc3ccccc32)ccc1-c1cc2c3c(c1)Oc1ccccc1B3c1ccccc1O2]

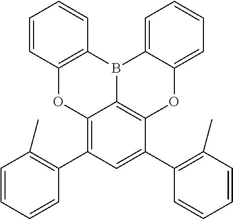 [SMILES: Cc1ccccc1-c1cc(-c2ccccc2C)c2c3c1Oc1ccccc1B3c1ccccc1O2]

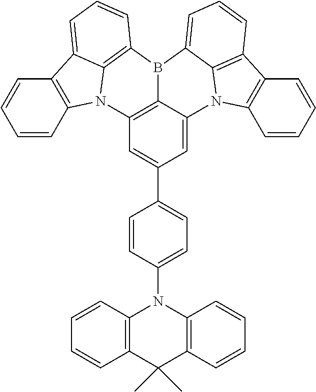 [SMILES: CC1(C)c2ccccc2N(c2ccc(-c3cc4c5c(c3)-n3c6ccccc6c6cccc(c63)B5c3cccc5c6ccccc6n-4c35)cc2)c2ccccc21]

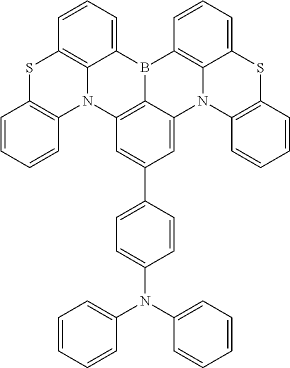 [SMILES: c1ccc(N(c2ccccc2)c2ccc(-c3cc4c5c(c3)N3c6ccccc6Sc6cccc(c63)B5c3cccc5c3N4c3ccccc3S5)cc2)cc1]

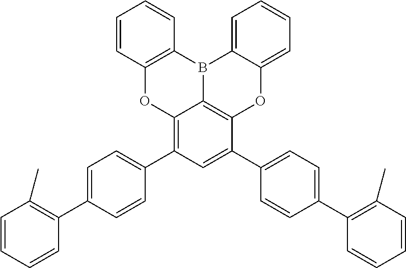 [SMILES: Cc1ccccc1-c1ccc(-c2cc(-c3ccc(-c4ccccc4C)cc3)c3c4c2Oc2ccccc2B4c2ccccc2O3)cc1]

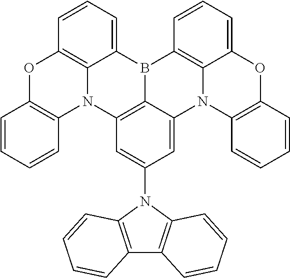 [SMILES: c1ccc2c(c1)Oc1cccc3c1N2c1cc(-n2c4ccccc4c4ccccc42)cc2c1B3c1cccc3c1N2c1ccccc1O3]

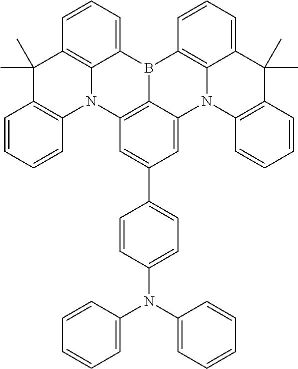

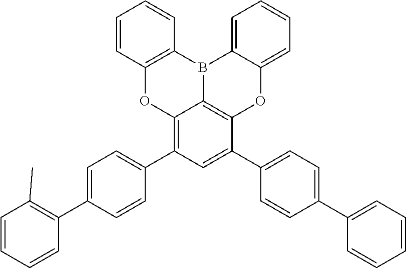 [SMILES: Cc1ccccc1-c1ccc(-c2cc(-c3ccc(-c4ccccc4)cc3)c3c4c2Oc2ccccc2B4c2ccccc2O3)cc1]

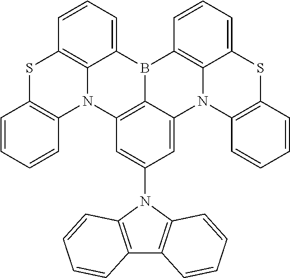 [SMILES: c1ccc2c(c1)Sc1cccc3c1N2c1cc(-n2c4ccccc4c4ccccc42)cc2c1B3c1cccc3c1N2c1ccccc1S3]

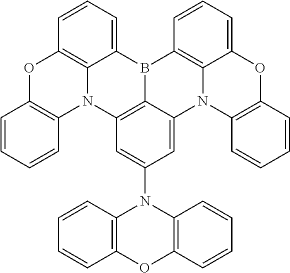 [SMILES: c1ccc2c(c1)Oc1ccccc1N2c1cc2c3c(c1)N1c4ccccc4Oc4cccc(c41)B3c1cccc3c1N2c1ccccc1O3]

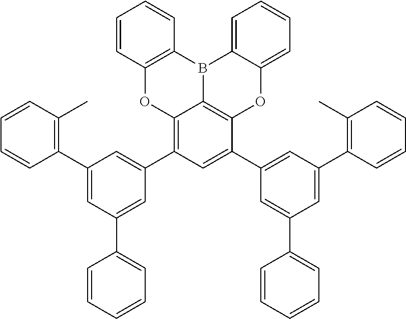 [SMILES: Cc1ccccc1-c1cc(-c2ccccc2)cc(-c2cc(-c3cc(-c4ccccc4)cc(-c4ccccc4C)c3)c3c4c2Oc2ccccc2B4c2ccccc2O3)c1]

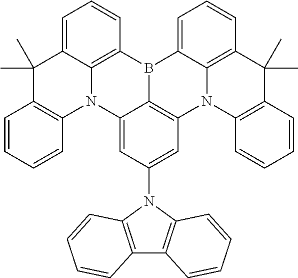

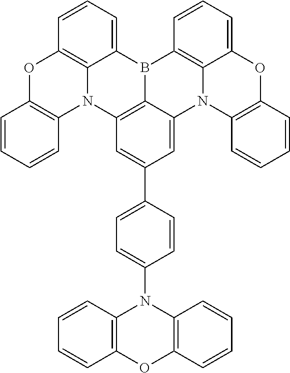 [SMILES: c1ccc2c(c1)Oc1ccccc1N2c1ccc(-c2cc3c4c(c2)N2c5ccccc5Oc5cccc(c52)B4c2cccc4c2N3c2ccccc2O4)cc1]

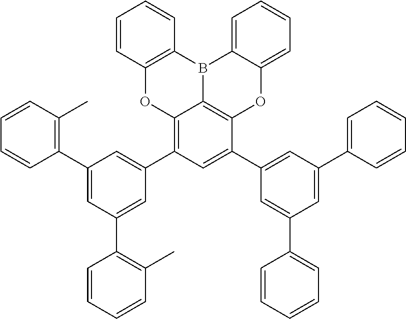 [SMILES: Cc1ccccc1-c1cc(-c2ccccc2C)cc(-c2cc(-c3cc(-c4ccccc4)cc(-c4ccccc4)c3)c3c4c2Oc2ccccc2B4c2ccccc2O3)c1]

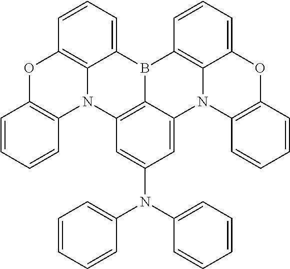 [SMILES: c1ccc(N(c2ccccc2)c2cc3c4c(c2)N2c5ccccc5Oc5cccc(c52)B4c2cccc4c2N3c2ccccc2O4)cc1]

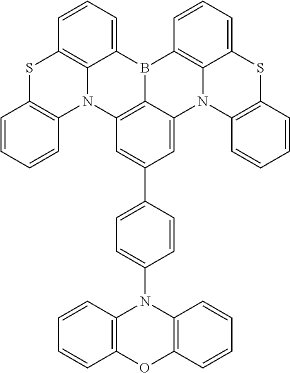 [SMILES: c1ccc2c(c1)Oc1ccccc1N2c1ccc(-c2cc3c4c(c2)N2c5ccccc5Sc5cccc(c52)B4c2cccc4c2N3c2ccccc2S4)cc1]

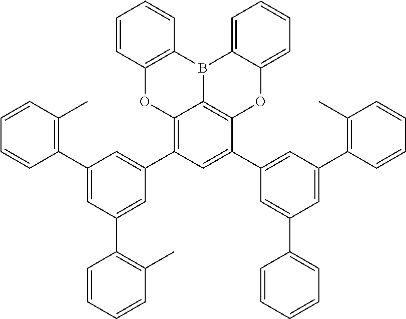 [SMILES: Cc1ccccc1-c1cc(-c2ccccc2)cc(-c2cc(-c3cc(-c4ccccc4C)cc(-c4ccccc4C)c3)c3c4c2Oc2ccccc2B4c2ccccc2O3)c1]

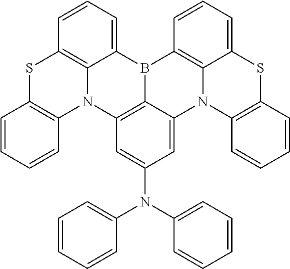 [SMILES: c1ccc(N(c2ccccc2)c2cc3c4c(c2)N2c5ccccc5Sc5cccc(c52)B4c2cccc4c2N3c2ccccc2S4)cc1]

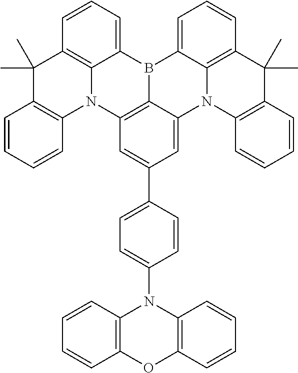

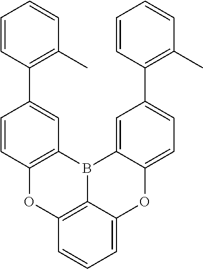 [SMILES: Cc1ccccc1-c1ccc2c(c1)B1c3cc(-c4ccccc4C)ccc3Oc3cccc(c31)O2]

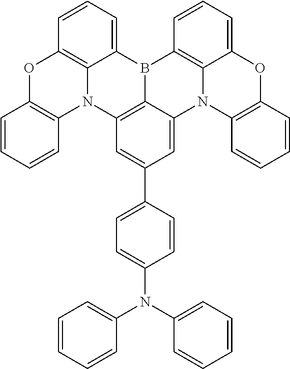 [SMILES: c1ccc(N(c2ccccc2)c2ccc(-c3cc4c5c(c3)N3c6ccccc6Oc6cccc(c63)B5c3cccc5c3N4c3ccccc3O5)cc2)cc1]

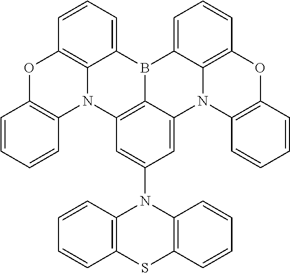 [SMILES: c1ccc2c(c1)Oc1cccc3c1N2c1cc(N2c4ccccc4Sc4ccccc42)cc2c1B3c1cccc3c1N2c1ccccc1O3]

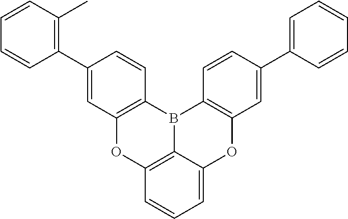 [SMILES: Cc1ccccc1-c1ccc2c(c1)Oc1cccc3c1B2c1ccc(-c2ccccc2)cc1O3]

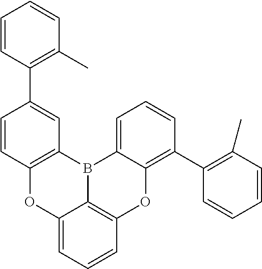 [SMILES: Cc1ccccc1-c1ccc2c(c1)B1c3cccc(-c4ccccc4C)c3Oc3cccc(c31)O2]

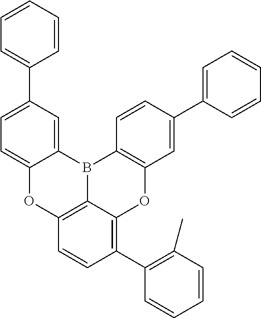 [SMILES: Cc1ccccc1-c1ccc2c3c1Oc1cc(-c4ccccc4)ccc1B3c1cc(-c3ccccc3)ccc1O2]

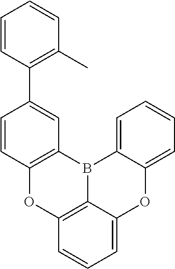 [SMILES: Cc1ccccc1-c1ccc2c(c1)B1c3ccccc3Oc3cccc(c31)O2]

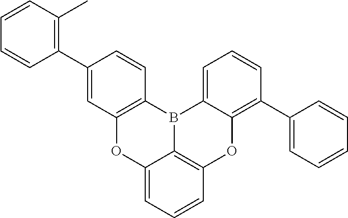 [SMILES: Cc1ccccc1-c1ccc2c(c1)Oc1cccc3c1B2c1cccc(-c2ccccc2)c1O3]

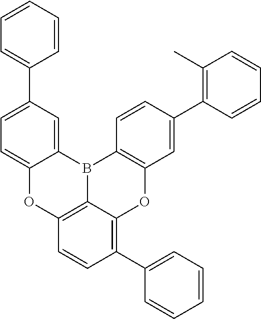 [SMILES: Cc1ccccc1-c1ccc2c(c1)Oc1c(-c3ccccc3)ccc3c1B2c1cc(-c2ccccc2)ccc1O3]

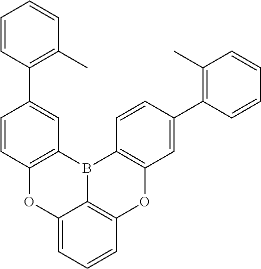 [SMILES: Cc1ccccc1-c1ccc2c(c1)Oc1cccc3c1B2c1cc(-c2ccccc2C)ccc1O3]

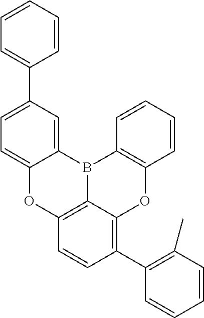 [SMILES: Cc1ccccc1-c1ccc2c3c1Oc1ccccc1B3c1cc(-c3ccccc3)ccc1O2]

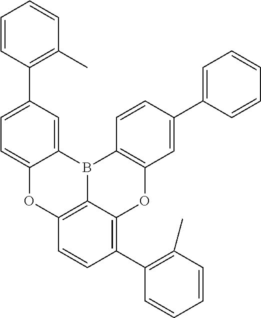 [SMILES: Cc1ccccc1-c1ccc2c(c1)B1c3ccc(-c4ccccc4)cc3Oc3c(-c4ccccc4C)ccc(c31)O2]

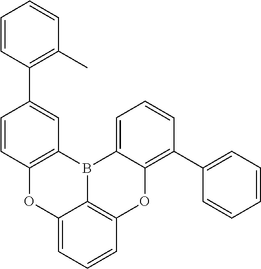 [SMILES: Cc1ccccc1-c1ccc2c(c1)B1c3cccc(-c4ccccc4)c3Oc3cccc(c31)O2]

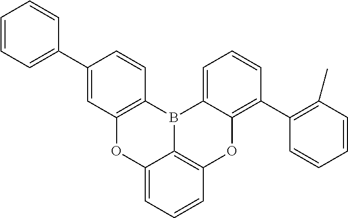 [SMILES: Cc1ccccc1-c1cccc2c1Oc1cccc3c1B2c1ccc(-c2ccccc2)cc1O3]

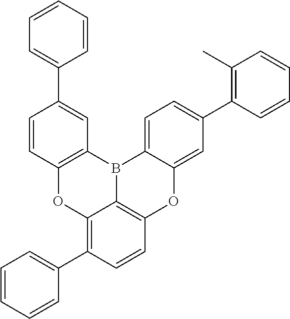 [SMILES: Cc1ccccc1-c1ccc2c(c1)Oc1ccc(-c3ccccc3)c3c1B2c1cc(-c2ccccc2)ccc1O3]

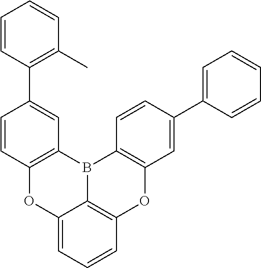 [SMILES: Cc1ccccc1-c1ccc2c(c1)B1c3ccc(-c4ccccc4)cc3Oc3cccc(c31)O2]

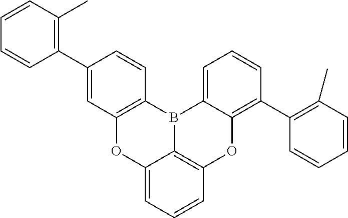 [SMILES: Cc1ccccc1-c1ccc2c(c1)Oc1cccc3c1B2c1cccc(-c2ccccc2C)c1O3]

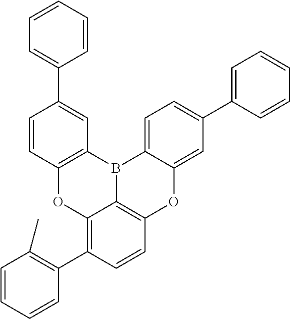 [SMILES: Cc1ccccc1-c1ccc2c3c1Oc1ccc(-c4ccccc4)cc1B3c1ccc(-c3ccccc3)cc1O2]

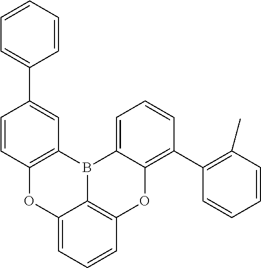 [SMILES: Cc1ccccc1-c1cccc2c1Oc1cccc3c1B2c1cc(-c2ccccc2)ccc1O3]

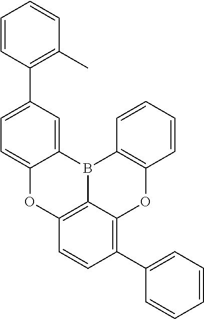 [SMILES: Cc1ccccc1-c1ccc2c(c1)B1c3ccccc3Oc3c(-c4ccccc4)ccc(c31)O2]

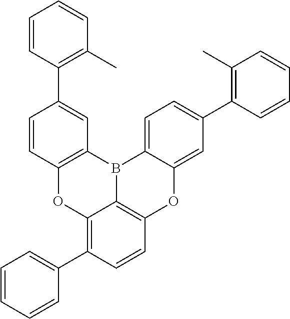 [SMILES: Cc1ccccc1-c1ccc2c(c1)Oc1ccc(-c3ccccc3)c3c1B2c1cc(-c2ccccc2C)ccc1O3]

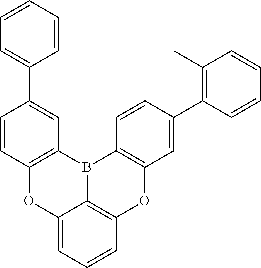 [SMILES: Cc1ccccc1-c1ccc2c(c1)Oc1cccc3c1B2c1cc(-c2ccccc2)ccc1O3]

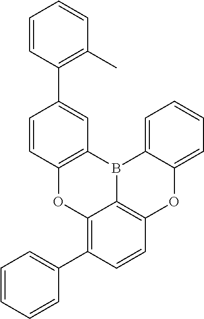 [SMILES: Cc1ccccc1-c1ccc2c(c1)B1c3ccccc3Oc3ccc(-c4ccccc4)c(c31)O2]

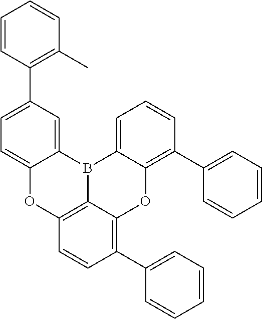 [SMILES: Cc1ccccc1-c1ccc2c(c1)B1c3cccc(-c4ccccc4)c3Oc3c(-c4ccccc4)ccc(c31)O2]

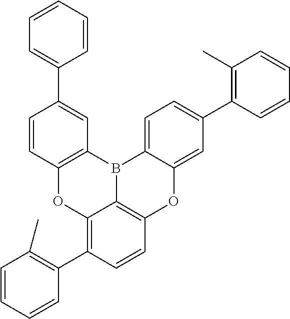 [SMILES: Cc1ccccc1-c1ccc2c(c1)Oc1ccc(-c3ccccc3C)c3c1B2c1cc(-c2ccccc2)ccc1O3]

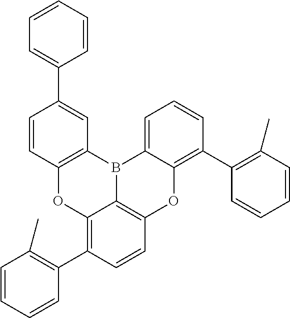 [SMILES: Cc1ccccc1-c1cccc2c1Oc1ccc(-c3ccccc3C)c3c1B2c1cc(-c2ccccc2)ccc1O3]

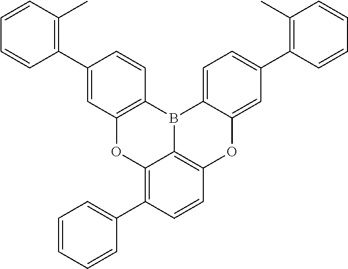 [SMILES: Cc1ccccc1-c1ccc2c(c1)Oc1ccc(-c3ccccc3)c3c1B2c1ccc(-c2ccccc2C)cc1O3]

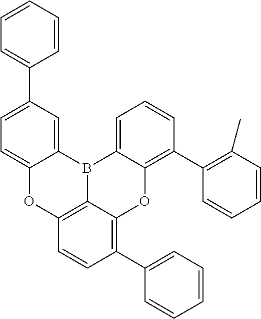 [SMILES: Cc1ccccc1-c1cccc2c1Oc1c(-c3ccccc3)ccc3c1B2c1cc(-c2ccccc2)ccc1O3]

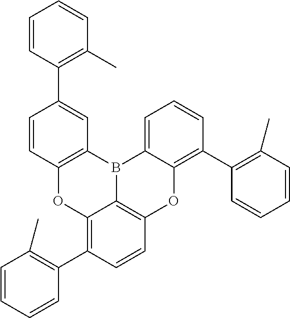 [SMILES: Cc1ccccc1-c1ccc2c(c1)B1c3cccc(-c4ccccc4C)c3Oc3ccc(-c4ccccc4C)c(c31)O2]

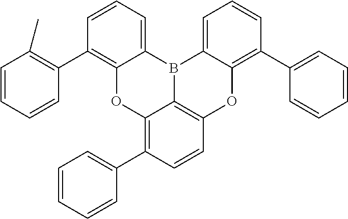 [SMILES: Cc1ccccc1-c1cccc2c1Oc1c(-c3ccccc3)ccc3c1B2c1cccc(-c2ccccc2)c1O3]

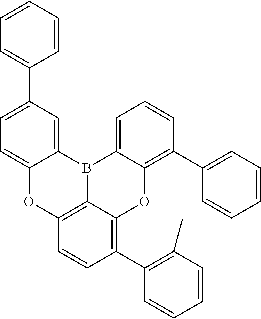 [SMILES: Cc1ccccc1-c1ccc2c3c1Oc1c(cccc1-c1ccccc1)B3c1cc(-c3ccccc3)ccc1O2]

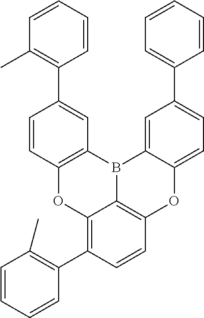 [SMILES: Cc1ccccc1-c1ccc2c(c1)B1c3cc(-c4ccccc4)ccc3Oc3ccc(-c4ccccc4C)c(c31)O2]

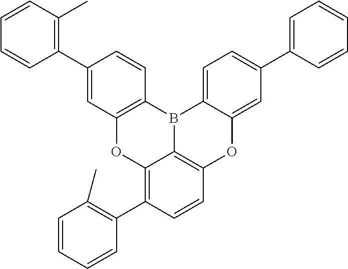 [SMILES: Cc1ccccc1-c1ccc2c(c1)Oc1c(-c3ccccc3C)ccc3c1B2c1ccc(-c2ccccc2)cc1O3]

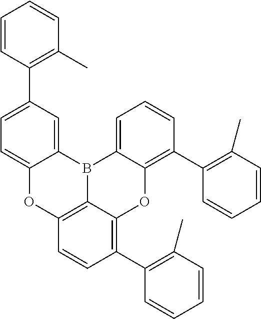 [SMILES: Cc1ccccc1-c1ccc2c(c1)B1c3cccc(-c4ccccc4C)c3Oc3c(-c4ccccc4C)ccc(c31)O2]

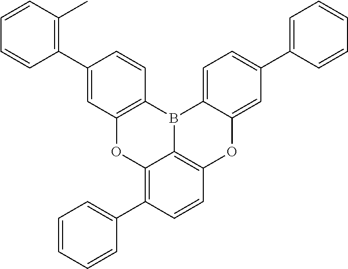 [SMILES: Cc1ccccc1-c1ccc2c(c1)Oc1c(-c3ccccc3)ccc3c1B2c1ccc(-c2ccccc2)cc1O3]

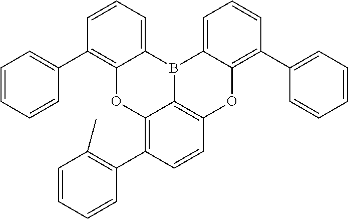 [SMILES: Cc1ccccc1-c1ccc2c3c1Oc1c(cccc1-c1ccccc1)B3c1cccc(-c3ccccc3)c1O2]

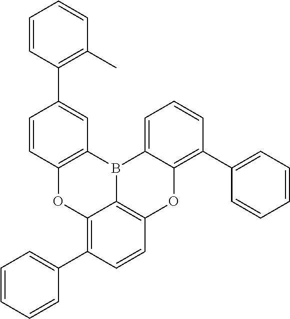 [SMILES: Cc1ccccc1-c1ccc2c(c1)B1c3cccc(-c4ccccc4)c3Oc3ccc(-c4ccccc4)c(c31)O2]

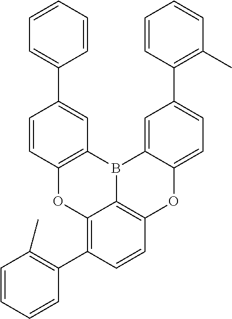 [SMILES: Cc1ccccc1-c1ccc2c(c1)B1c3cc(-c4ccccc4)ccc3Oc3c(-c4ccccc4C)ccc(c31)O2]

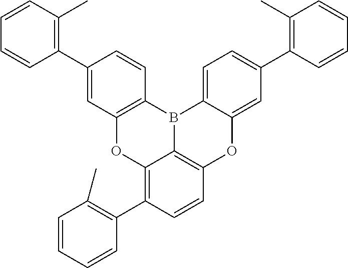 [SMILES: Cc1ccccc1-c1ccc2c(c1)Oc1ccc(-c3ccccc3C)c3c1B2c1ccc(-c2ccccc2C)cc1O3]

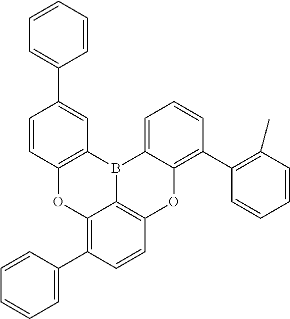 [SMILES: Cc1ccccc1-c1cccc2c1Oc1ccc(-c3ccccc3)c3c1B2c1cc(-c2ccccc2)ccc1O3]

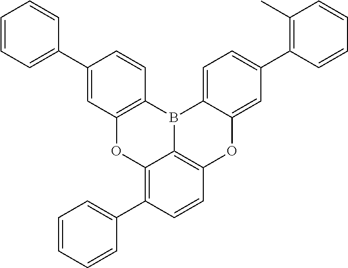 [SMILES: Cc1ccccc1-c1ccc2c(c1)Oc1ccc(-c3ccccc3)c3c1B2c1ccc(-c2ccccc2)cc1O3]

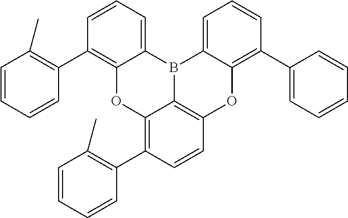 [SMILES: Cc1ccccc1-c1cccc2c1Oc1c(-c3ccccc3C)ccc3c1B2c1cccc(-c2ccccc2)c1O3]

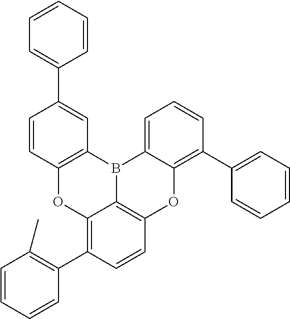 [SMILES: Cc1ccccc1-c1ccc2c3c1Oc1ccc(-c4ccccc4)cc1B3c1cccc(-c3ccccc3)c1O2]

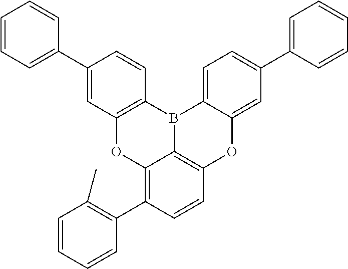 [SMILES: Cc1ccccc1-c1ccc2c3c1Oc1cc(-c4ccccc4)ccc1B3c1ccc(-c3ccccc3)cc1O2]

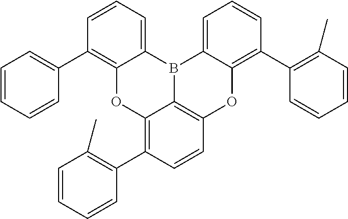 [SMILES: Cc1ccccc1-c1cccc2c1Oc1ccc(-c3ccccc3C)c3c1B2c1cccc(-c2ccccc2)c1O3]

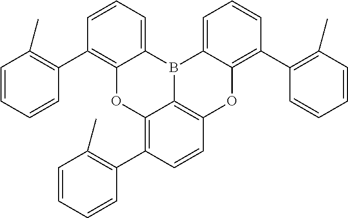 [SMILES: Cc1ccccc1-c1cccc2c1Oc1ccc(-c3ccccc3C)c3c1B2c1cccc(-c2ccccc2C)c1O3]

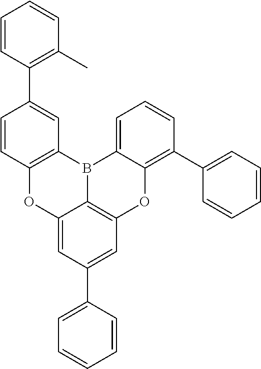 [SMILES: Cc1ccccc1-c1ccc2c(c1)B1c3cccc(-c4ccccc4)c3Oc3cc(-c4ccccc4)cc(c31)O2]

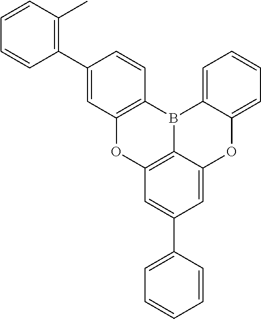 [SMILES: Cc1ccccc1-c1ccc2c(c1)Oc1cc(-c3ccccc3)cc3c1B2c1ccccc1O3]

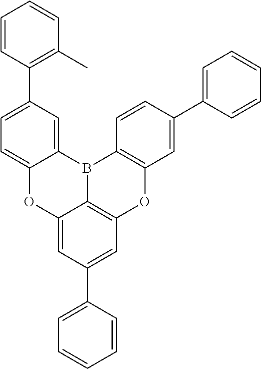 [SMILES: Cc1ccccc1-c1ccc2c(c1)B1c3ccc(-c4ccccc4)cc3Oc3cc(-c4ccccc4)cc(c31)O2]

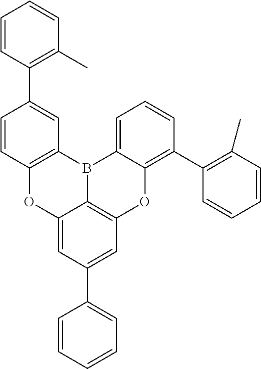 [SMILES: Cc1ccccc1-c1ccc2c(c1)B1c3cccc(-c4ccccc4C)c3Oc3cc(-c4ccccc4)cc(c31)O2]

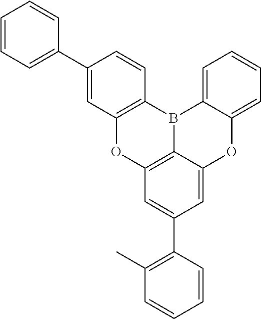 [SMILES: Cc1ccccc1-c1cc2c3c(c1)Oc1cc(-c4ccccc4)ccc1B3c1ccccc1O2]

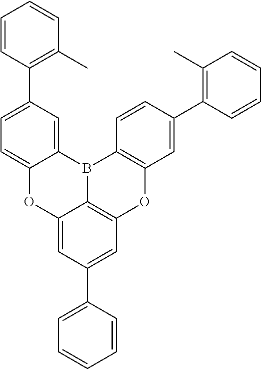 [SMILES: Cc1ccccc1-c1ccc2c(c1)Oc1cc(-c3ccccc3)cc3c1B2c1cc(-c2ccccc2C)ccc1O3]

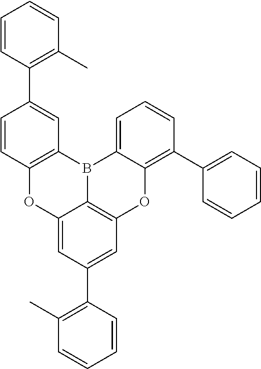 [SMILES: Cc1ccccc1-c1cc2c3c(c1)Oc1c(cccc1-c1ccccc1)B3c1cc(-c3ccccc3C)ccc1O2]

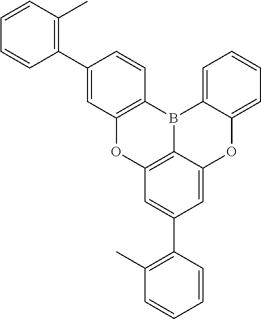 [SMILES: Cc1ccccc1-c1ccc2c(c1)Oc1cc(-c3ccccc3C)cc3c1B2c1ccccc1O3]

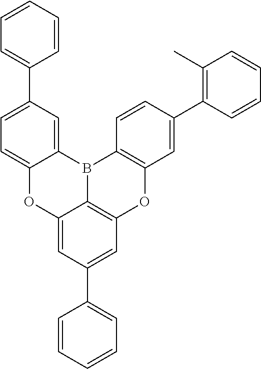 [SMILES: Cc1ccccc1-c1ccc2c(c1)Oc1cc(-c3ccccc3)cc3c1B2c1cc(-c2ccccc2)ccc1O3]

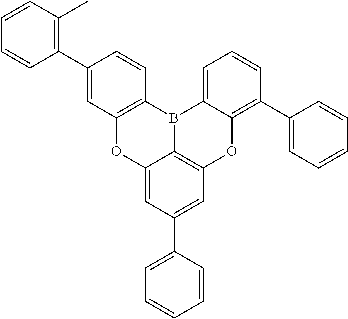 [SMILES: Cc1ccccc1-c1ccc2c(c1)Oc1cc(-c3ccccc3)cc3c1B2c1cccc(-c2ccccc2)c1O3]

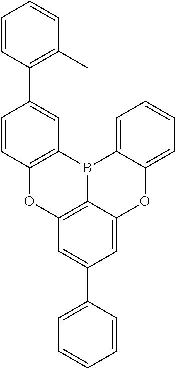 [SMILES: Cc1ccccc1-c1ccc2c(c1)B1c3ccccc3Oc3cc(-c4ccccc4)cc(c31)O2]

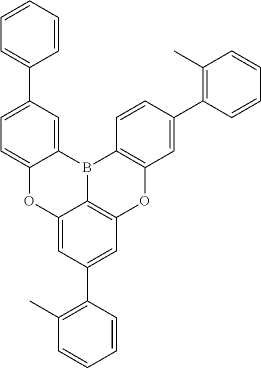 [SMILES: Cc1ccccc1-c1ccc2c(c1)Oc1cc(-c3ccccc3C)cc3c1B2c1cc(-c2ccccc2)ccc1O3]

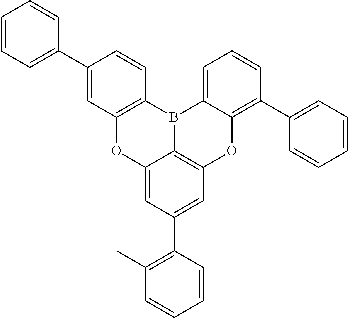 [SMILES: Cc1ccccc1-c1cc2c3c(c1)Oc1c(cccc1-c1ccccc1)B3c1ccc(-c3ccccc3)cc1O2]

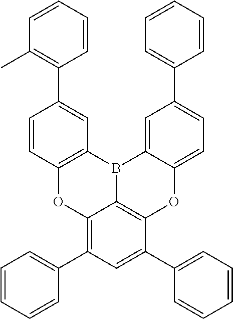 [SMILES: Cc1ccccc1-c1ccc2c(c1)B1c3cc(-c4ccccc4)ccc3Oc3c(-c4ccccc4)cc(-c4ccccc4)c(c31)O2]

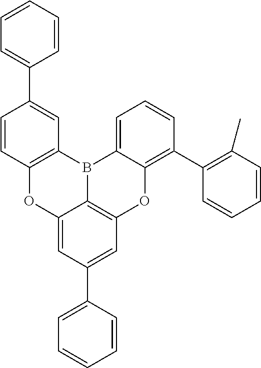 [SMILES: Cc1ccccc1-c1cccc2c1Oc1cc(-c3ccccc3)cc3c1B2c1cc(-c2ccccc2)ccc1O3]

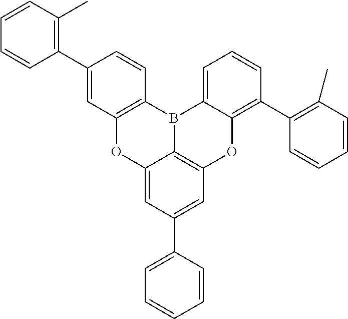 [SMILES: Cc1ccccc1-c1ccc2c(c1)Oc1cc(-c3ccccc3)cc3c1B2c1cccc(-c2ccccc2C)c1O3]

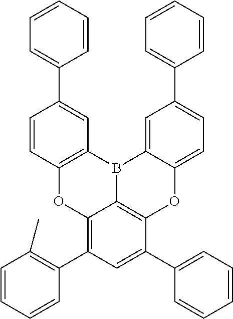 [SMILES: Cc1ccccc1-c1cc(-c2ccccc2)c2c3c1Oc1ccc(-c4ccccc4)cc1B3c1cc(-c3ccccc3)ccc1O2]

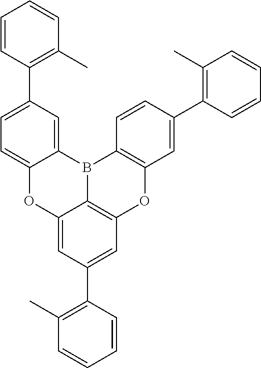 [SMILES: Cc1ccccc1-c1ccc2c(c1)Oc1cc(-c3ccccc3C)cc3c1B2c1cc(-c2ccccc2C)ccc1O3]

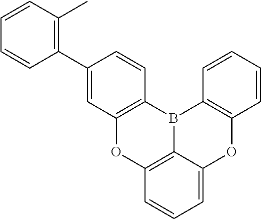 [SMILES: Cc1ccccc1-c1ccc2c(c1)Oc1cccc3c1B2c1ccccc1O3]

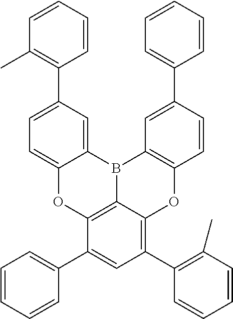 [SMILES: Cc1ccccc1-c1ccc2c(c1)B1c3cc(-c4ccccc4)ccc3Oc3c(-c4ccccc4C)cc(-c4ccccc4)c(c31)O2]

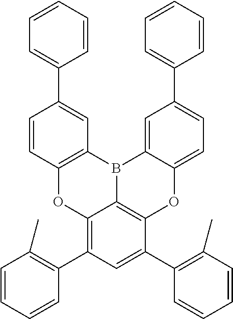 [SMILES: Cc1ccccc1-c1cc(-c2ccccc2C)c2c3c1Oc1ccc(-c4ccccc4)cc1B3c1cc(-c3ccccc3)ccc1O2]

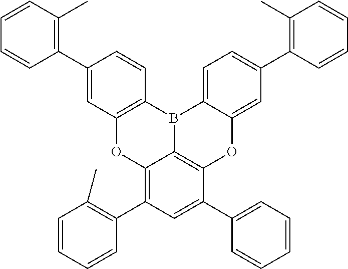 [SMILES: Cc1ccccc1-c1ccc2c(c1)Oc1c(-c3ccccc3)cc(-c3ccccc3C)c3c1B2c1ccc(-c2ccccc2C)cc1O3]

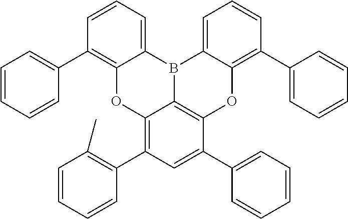 [SMILES: Cc1ccccc1-c1cc(-c2ccccc2)c2c3c1Oc1c(cccc1-c1ccccc1)B3c1cccc(-c3ccccc3)c1O2]

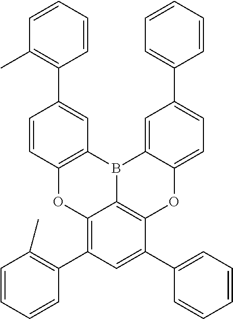 [SMILES: Cc1ccccc1-c1ccc2c(c1)B1c3cc(-c4ccccc4)ccc3Oc3c(-c4ccccc4)cc(-c4ccccc4C)c(c31)O2]

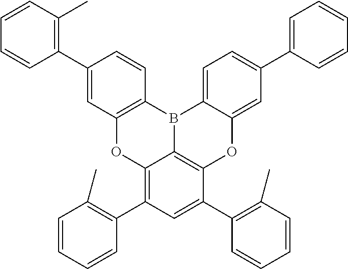 [SMILES: Cc1ccccc1-c1ccc2c(c1)Oc1c(-c3ccccc3C)cc(-c3ccccc3C)c3c1B2c1ccc(-c2ccccc2)cc1O3]

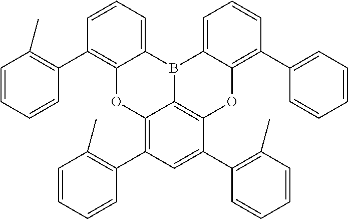 [SMILES: Cc1ccccc1-c1cccc2c1Oc1c(-c3ccccc3C)cc(-c3ccccc3C)c3c1B2c1cccc(-c2ccccc2)c1O3]

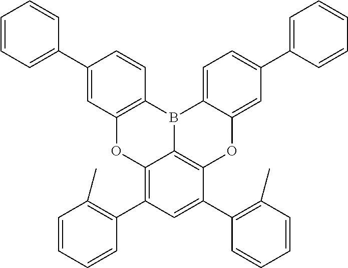 [SMILES: Cc1ccccc1-c1cc(-c2ccccc2C)c2c3c1Oc1cc(-c4ccccc4)ccc1B3c1ccc(-c3ccccc3)cc1O2]

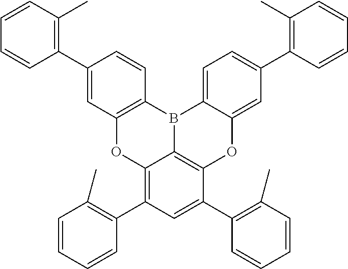 [SMILES: Cc1ccccc1-c1ccc2c(c1)Oc1c(-c3ccccc3C)cc(-c3ccccc3C)c3c1B2c1ccc(-c2ccccc2C)cc1O3]

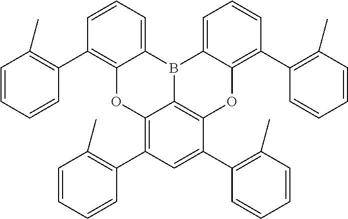 [SMILES: Cc1ccccc1-c1cccc2c1Oc1c(-c3ccccc3C)cc(-c3ccccc3C)c3c1B2c1cccc(-c2ccccc2C)c1O3]

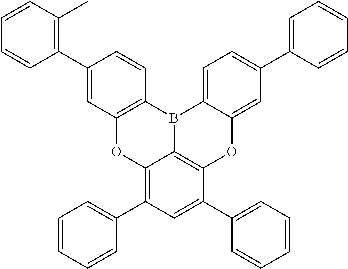 [SMILES: Cc1ccccc1-c1ccc2c(c1)Oc1c(-c3ccccc3)cc(-c3ccccc3)c3c1B2c1ccc(-c2ccccc2)cc1O3]

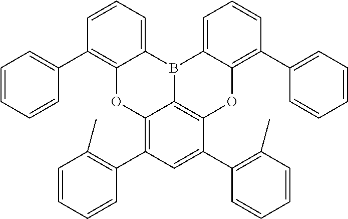 [SMILES: Cc1ccccc1-c1cc(-c2ccccc2C)c2c3c1Oc1c(cccc1-c1ccccc1)B3c1cccc(-c3ccccc3)c1O2]

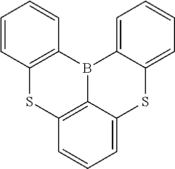 [SMILES: c1ccc2c(c1)Sc1cccc3c1B2c1ccccc1S3]

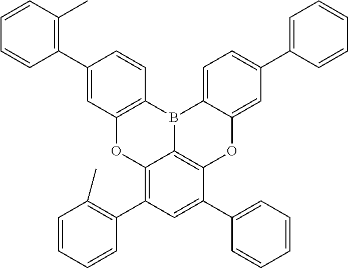 [SMILES: Cc1ccccc1-c1ccc2c(c1)Oc1c(-c3ccccc3C)cc(-c3ccccc3)c3c1B2c1ccc(-c2ccccc2)cc1O3]

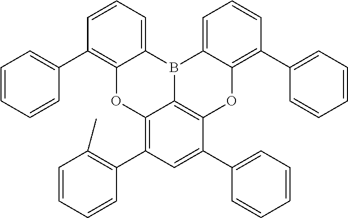 [SMILES: Cc1ccccc1-c1cc(-c2ccccc2)c2c3c1Oc1c(cccc1-c1ccccc1)B3c1cccc(-c3ccccc3)c1O2]

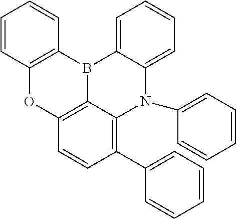 [SMILES: c1ccc(-c2ccc3c4c2N(c2ccccc2)c2ccccc2B4c2ccccc2O3)cc1]

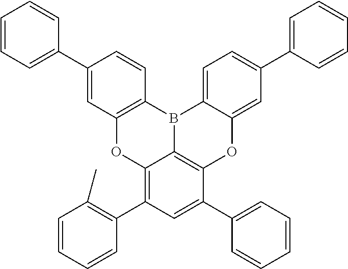 [SMILES: Cc1ccccc1-c1cc(-c2ccccc2)c2c3c1Oc1cc(-c4ccccc4)ccc1B3c1ccc(-c3ccccc3)cc1O2]

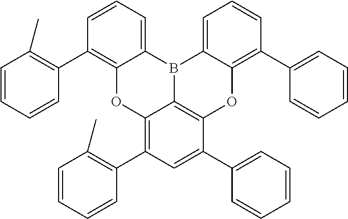 [SMILES: Cc1ccccc1-c1cccc2c1Oc1c(-c3ccccc3C)cc(-c3ccccc3)c3c1B2c1cccc(-c2ccccc2)c1O3]

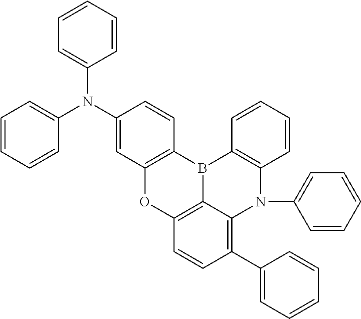 [SMILES: c1ccc(-c2ccc3c4c2N(c2ccccc2)c2ccccc2B4c2ccc(N(c4ccccc4)c4ccccc4)cc2O3)cc1]

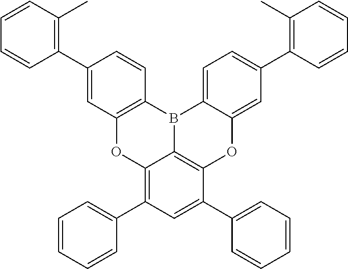 [SMILES: Cc1ccccc1-c1ccc2c(c1)Oc1c(-c3ccccc3)cc(-c3ccccc3)c3c1B2c1ccc(-c2ccccc2C)cc1O3]

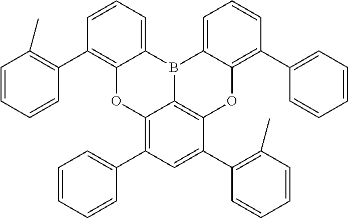 [SMILES: Cc1ccccc1-c1cccc2c1Oc1c(-c3ccccc3)cc(-c3ccccc3C)c3c1B2c1cccc(-c2ccccc2)c1O3]

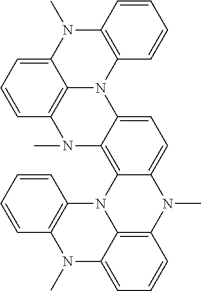 [SMILES: Cn1c2ccccc2n2c3ccc4c(c3n(C)c3cccc1c32)n1c2ccccc2n(C)c2cccc(c21)n4C]

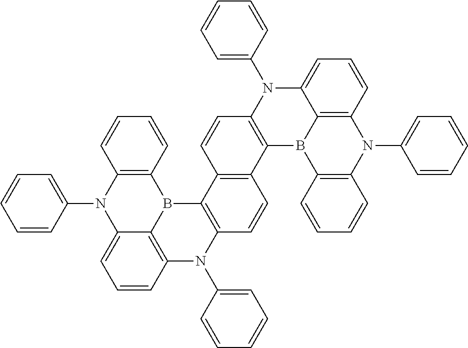 [SMILES: c1ccc(N2c3ccccc3B3c4c2cccc4N(c2ccccc2)c2ccc4c5c(ccc4c23)N(c2ccccc2)c2cccc3c2B5c2ccccc2N3c2ccccc2)cc1]

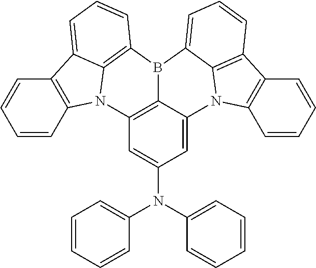 [SMILES: c1ccc(N(c2ccccc2)c2cc3c4c(c2)-n2c5ccccc5c5cccc(c52)B4c2cccc4c5ccccc5n-3c24)cc1]

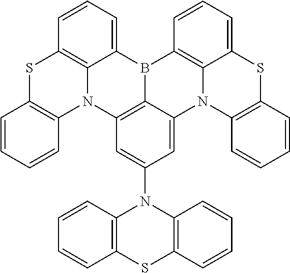 [SMILES: c1ccc2c(c1)Sc1ccccc1N2c1cc2c3c(c1)N1c4ccccc4Sc4cccc(c41)B3c1cccc3c1N2c1ccccc1S3]

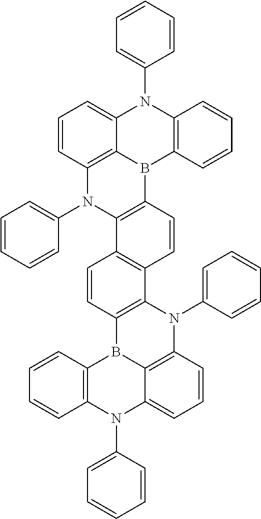 [SMILES: c1ccc(N2c3ccccc3B3c4ccc5c6c(ccc5c4N(c4ccccc4)c4cccc2c43)B2c3ccccc3N(c3ccccc3)c3cccc(c32)N6c2ccccc2)cc1]

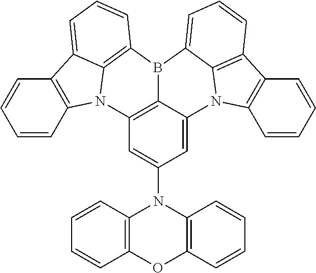 [SMILES: c1ccc2c(c1)Oc1ccccc1N2c1cc2c3c(c1)-n1c4ccccc4c4cccc(c41)B3c1cccc3c4ccccc4n-2c13]

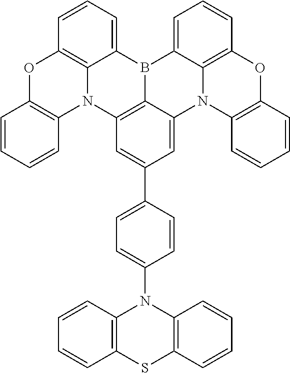 [SMILES: c1ccc2c(c1)Oc1cccc3c1N2c1cc(-c2ccc(N4c5ccccc5Sc5ccccc54)cc2)cc2c1B3c1cccc3c1N2c1ccccc1O3]

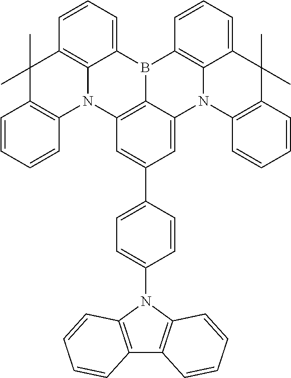 [SMILES: CC1(C)c2ccccc2N2c3cc(-c4ccc(-n5c6ccccc6c6ccccc65)cc4)cc4c3B(c3cccc1c32)c1cccc2c1N4c1ccccc1C2(C)C]

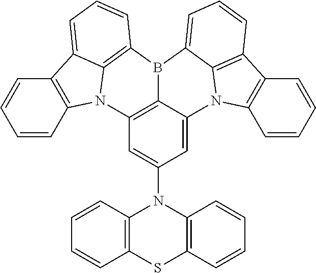 [SMILES: c1ccc2c(c1)Sc1ccccc1N2c1cc2c3c(c1)-n1c4ccccc4c4cccc(c41)B3c1cccc3c4ccccc4n-2c13]

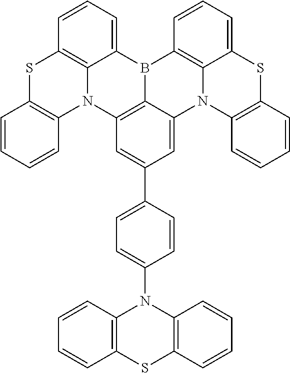 [SMILES: c1ccc2c(c1)Sc1ccccc1N2c1ccc(-c2cc3c4c(c2)N2c5ccccc5Sc5cccc(c52)B4c2cccc4c2N3c2ccccc2S4)cc1]

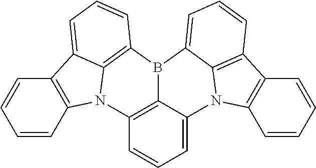 [SMILES: c1cc2c3c(c1)-n1c4ccccc4c4cccc(c41)B3c1cccc3c4ccccc4n-2c13]

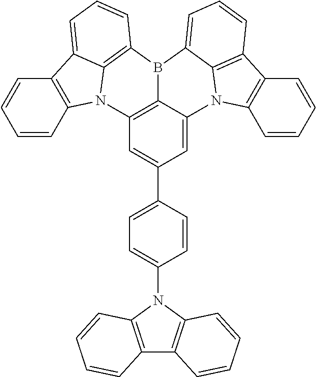 [SMILES: c1ccc2c(c1)c1ccccc1n2-c1ccc(-c2cc3c4c(c2)-n2c5ccccc5c5cccc(c52)B4c2cccc4c5ccccc5n-3c24)cc1]

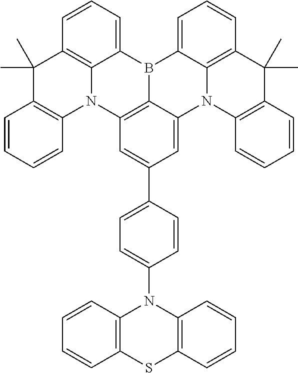

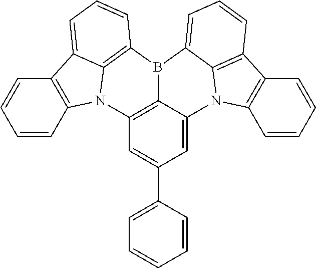 [SMILES: c1ccc(-c2cc3c4c(c2)-n2c5ccccc5c5cccc(c52)B4c2cccc4c5ccccc5n-3c24)cc1]

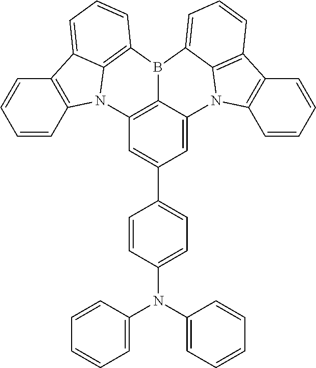 [SMILES: c1ccc(N(c2ccccc2)c2ccc(-c3cc4c5c(c3)-n3c6ccccc6c6cccc(c63)B5c3cccc5c6ccccc6n-4c35)cc2)cc1]

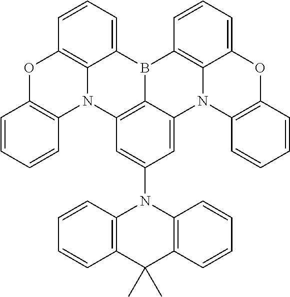 [SMILES: CC1(C)c2ccccc2N(c2cc3c4c(c2)N2c5ccccc5Oc5cccc(c52)B4c2cccc4c2N3c2ccccc2O4)c2ccccc21]

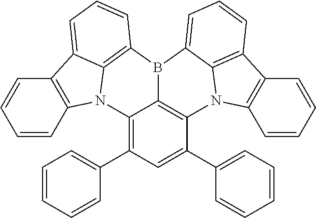 [SMILES: c1ccc(-c2cc(-c3ccccc3)c3c4c2-n2c5ccccc5c5cccc(c52)B4c2cccc4c5ccccc5n-3c24)cc1]

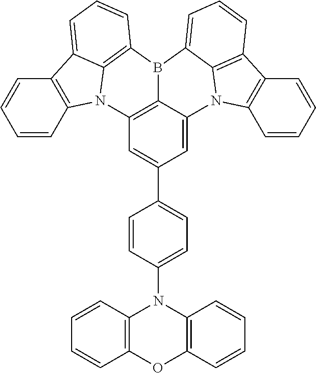 [SMILES: c1ccc2c(c1)Oc1ccccc1N2c1ccc(-c2cc3c4c(c2)-n2c5ccccc5c5cccc(c52)B4c2cccc4c5ccccc5n-3c24)cc1]

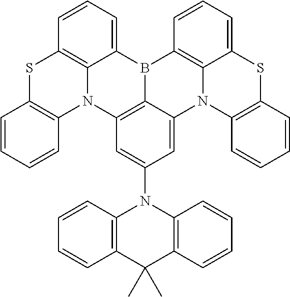 [SMILES: CC1(C)c2ccccc2N(c2cc3c4c(c2)N2c5ccccc5Sc5cccc(c52)B4c2cccc4c2N3c2ccccc2S4)c2ccccc21]

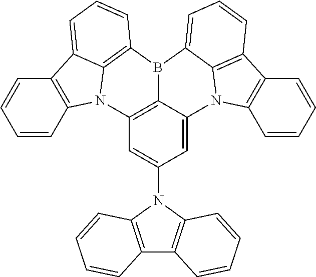 [SMILES: c1ccc2c(c1)c1ccccc1n2-c1cc2c3c(c1)-n1c4ccccc4c4cccc(c41)B3c1cccc3c4ccccc4n-2c13]

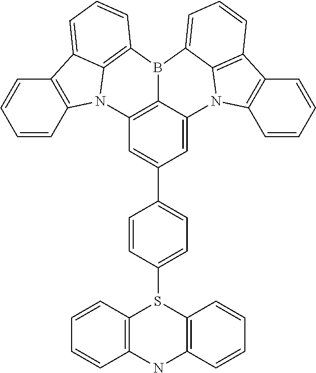

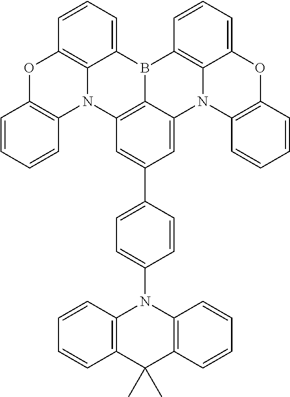 [SMILES: CC1(C)c2ccccc2N(c2ccc(-c3cc4c5c(c3)N3c6ccccc6Oc6cccc(c63)B5c3cccc5c3N4c3ccccc3O5)cc2)c2ccccc21]

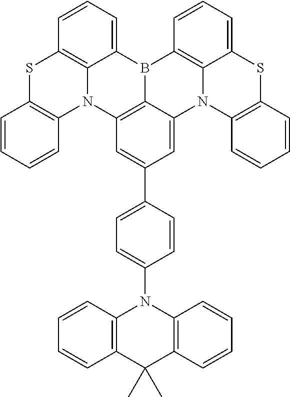 [SMILES: CC1(C)c2ccccc2N(c2ccc(-c3cc4c5c(c3)N3c6ccccc6Sc6cccc(c63)B5c3cccc5c3N4c3ccccc3S5)cc2)c2ccccc21]

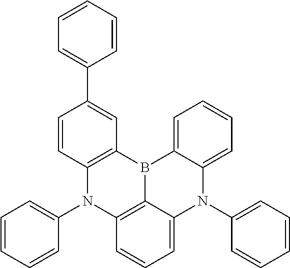 [SMILES: c1ccc(-c2ccc3c(c2)B2c4ccccc4N(c4ccccc4)c4cccc(c42)N3c2ccccc2)cc1]

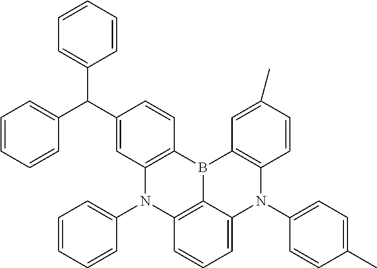 [SMILES: Cc1ccc(N2c3ccc(C)cc3B3c4ccc(C(c5ccccc5)c5ccccc5)cc4N(c4ccccc4)c4cccc2c43)cc1]

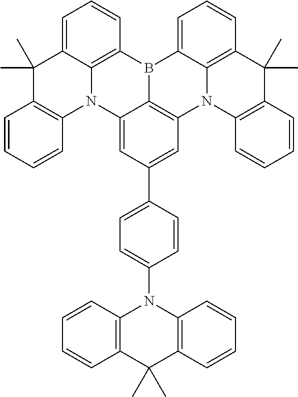

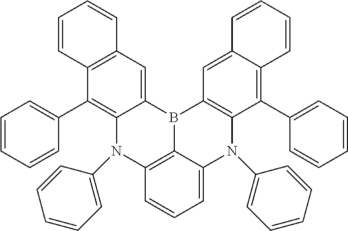 [SMILES: c1ccc(-c2c3c(cc4ccccc24)B2c4cc5ccccc5c(-c5ccccc5)c4N(c4ccccc4)c4cccc(c42)N3c2ccccc2)cc1]

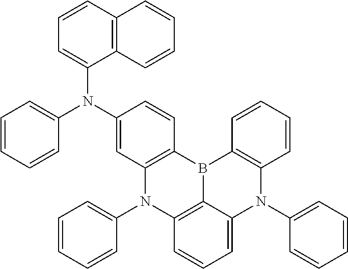 [SMILES: c1ccc(N2c3ccccc3B3c4ccc(N(c5ccccc5)c5cccc6ccccc56)cc4N(c4ccccc4)c4cccc2c43)cc1]

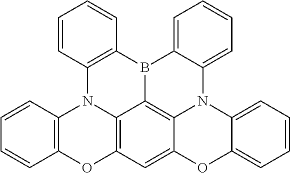 [SMILES: c1ccc2c(c1)B1c3ccccc3-n3c4ccccc4oc4cc5oc6ccccc6n-2c5c1c43]

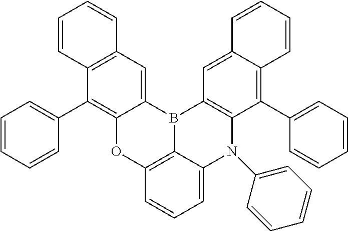 [SMILES: c1ccc(-c2c3c(cc4ccccc24)B2c4cc5ccccc5c(-c5ccccc5)c4N(c4ccccc4)c4cccc(c42)O3)cc1]

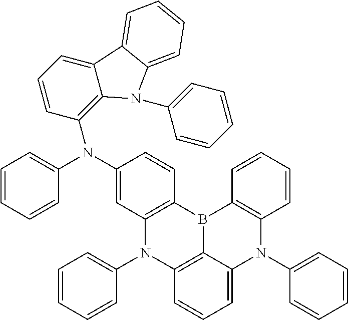 [SMILES: c1ccc(N2c3ccccc3B3c4ccc(N(c5ccccc5)c5cccc6c7ccccc7n(-c7ccccc7)c56)cc4N(c4ccccc4)c4cccc2c43)cc1]

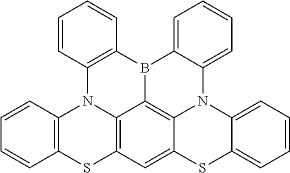 [SMILES: c1ccc2c(c1)B1c3ccccc3-n3c4ccccc4sc4cc5sc6ccccc6n-2c5c1c43]

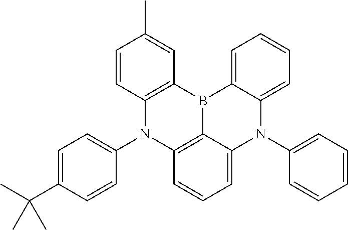 [SMILES: Cc1ccc2c(c1)B1c3ccccc3N(c3ccccc3)c3cccc(c31)N2c1ccc(C(C)(C)C)cc1]

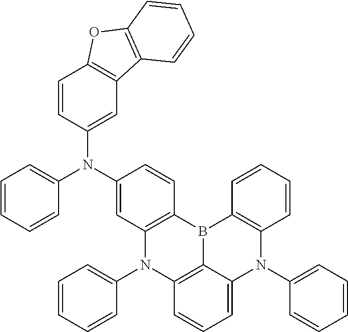 [SMILES: c1ccc(N(c2ccc3c(c2)N(c2ccccc2)c2cccc4c2B3c2ccccc2N4c2ccccc2)c2ccc3oc4ccccc4c3c2)cc1]

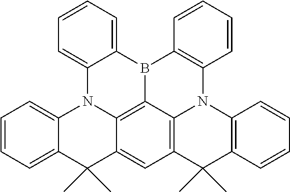 [SMILES: CC1(C)c2ccccc2N2c3ccccc3B3c4ccccc4N4c5ccccc5C(C)(C)c5cc1c2c3c54]

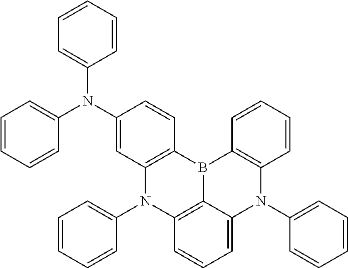 [SMILES: c1ccc(N(c2ccccc2)c2ccc3c(c2)N(c2ccccc2)c2cccc4c2B3c2ccccc2N4c2ccccc2)cc1]

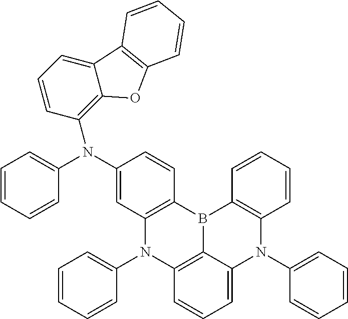 [SMILES: c1ccc(N2c3ccccc3B3c4ccc(N(c5ccccc5)c5cccc6c5oc5ccccc56)cc4N(c4ccccc4)c4cccc2c43)cc1]

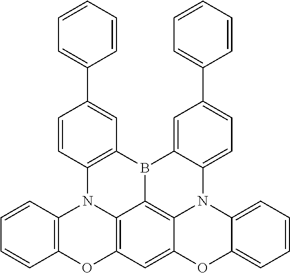 [SMILES: c1ccc(-c2ccc3c(c2)B2c4cc(-c5ccccc5)ccc4-n4c5ccccc5oc5cc6oc7ccccc7n-3c6c2c54)cc1]

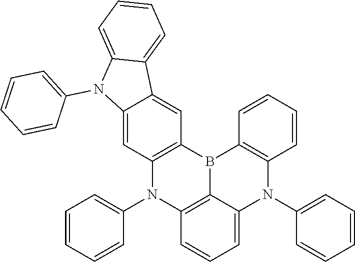 [SMILES: c1ccc(N2c3ccccc3B3c4cc5c6ccccc6n(-c6ccccc6)c5cc4N(c4ccccc4)c4cccc2c43)cc1]

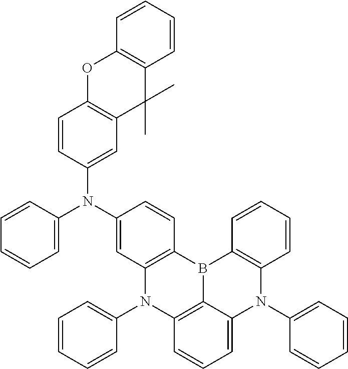 [SMILES: CC1(C)c2ccccc2Oc2ccc(N(c3ccccc3)c3ccc4c(c3)N(c3ccccc3)c3cccc5c3B4c3ccccc3N5c3ccccc3)cc21]

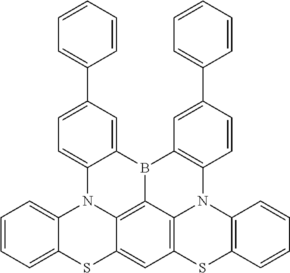 [SMILES: c1ccc(-c2ccc3c(c2)B2c4cc(-c5ccccc5)ccc4-n4c5ccccc5sc5cc6sc7ccccc7n-3c6c2c54)cc1]

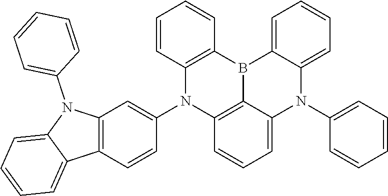 [SMILES: c1ccc(N2c3ccccc3B3c4ccccc4N(c4ccc5c6ccccc6n(-c6ccccc6)c5c4)c4cccc2c43)cc1]

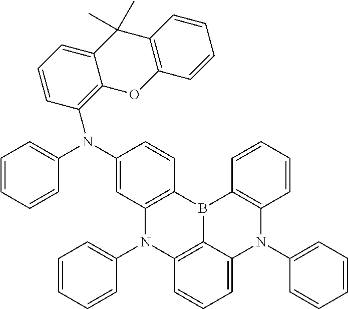 [SMILES: CC1(C)c2ccccc2Oc2c(N(c3ccccc3)c3ccc4c(c3)N(c3ccccc3)c3cccc5c3B4c3ccccc3N5c3ccccc3)cccc21]

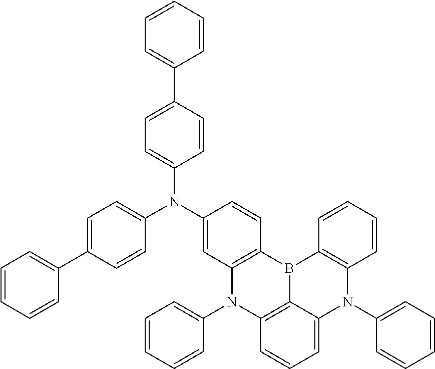 [SMILES: c1ccc(-c2ccc(N(c3ccc(-c4ccccc4)cc3)c3ccc4c(c3)N(c3ccccc3)c3cccc5c3B4c3ccccc3N5c3ccccc3)cc2)cc1]

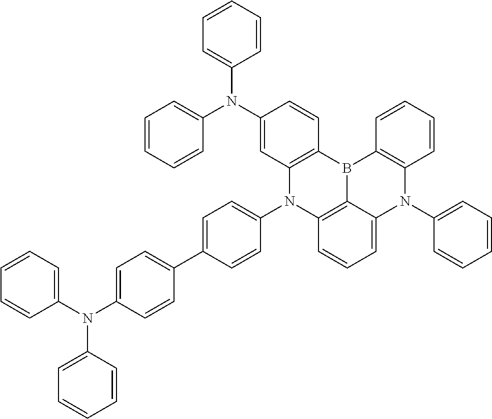 [SMILES: c1ccc(N(c2ccccc2)c2ccc(-c3ccc(N4c5cc(N(c6ccccc6)c6ccccc6)ccc5B5c6ccccc6N(c6ccccc6)c6cccc4c65)cc3)cc2)cc1]

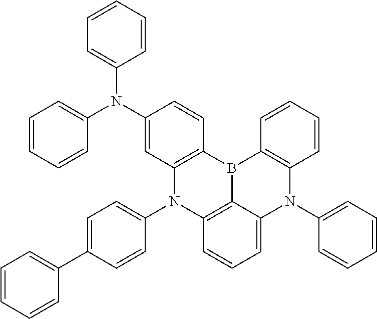 [SMILES: c1ccc(-c2ccc(N3c4cc(N(c5ccccc5)c5ccccc5)ccc4B4c5ccccc5N(c5ccccc5)c5cccc3c54)cc2)cc1]

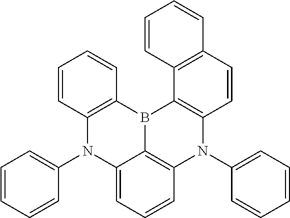 [SMILES: c1ccc(N2c3ccccc3B3c4c2cccc4N(c2ccccc2)c2ccc4ccccc4c23)cc1]

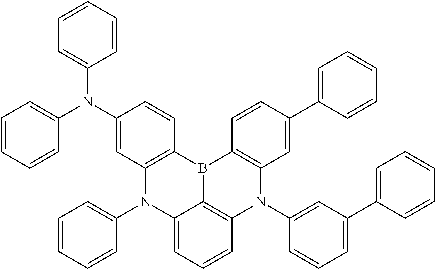 [SMILES: c1ccc(-c2cccc(N3c4cc(-c5ccccc5)ccc4B4c5ccc(N(c6ccccc6)c6ccccc6)cc5N(c5ccccc5)c5cccc3c54)c2)cc1]

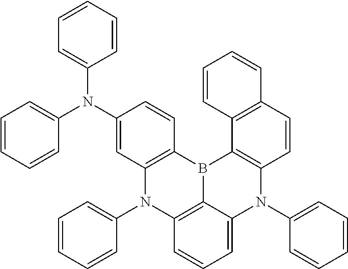 [SMILES: c1ccc(N(c2ccccc2)c2ccc3c(c2)N(c2ccccc2)c2cccc4c2B3c2c(ccc3ccccc23)N4c2ccccc2)cc1]

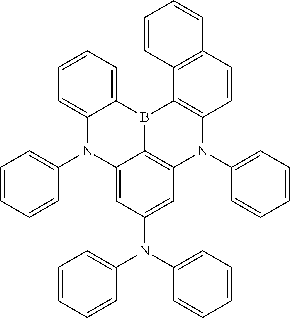 [SMILES: c1ccc(N(c2ccccc2)c2cc3c4c(c2)N(c2ccccc2)c2ccc5ccccc5c2B4c2ccccc2N3c2ccccc2)cc1]

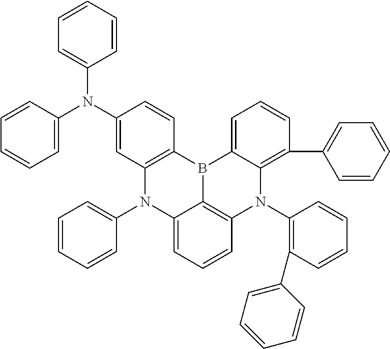 [SMILES: c1ccc(-c2ccccc2N2c3cccc4c3B(c3ccc(N(c5ccccc5)c5ccccc5)cc3N4c3ccccc3)c3cccc(-c4ccccc4)c32)cc1]

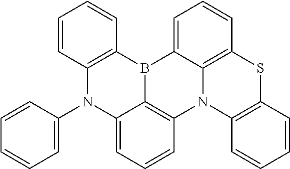 [SMILES: c1ccc(N2c3ccccc3B3c4cccc5c4N(c4ccccc4S5)c4cccc2c43)cc1]

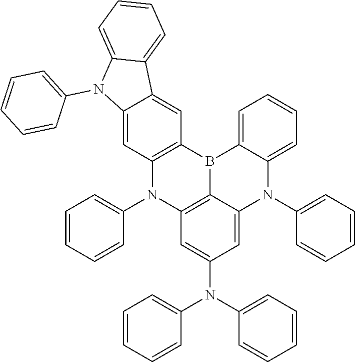 [SMILES: c1ccc(N(c2ccccc2)c2cc3c4c(c2)N(c2ccccc2)c2cc5c(cc2B4c2ccccc2N3c2ccccc2)c2ccccc2n5-c2ccccc2)cc1]

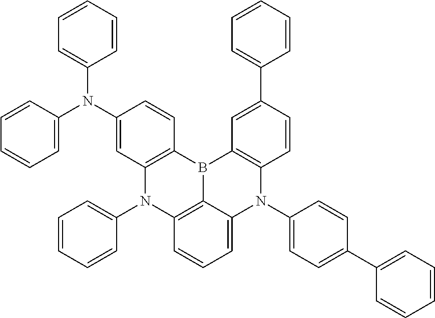 [SMILES: c1ccc(-c2ccc(N3c4ccc(-c5ccccc5)cc4B4c5ccc(N(c6ccccc6)c6ccccc6)cc5N(c5ccccc5)c5cccc3c54)cc2)cc1]

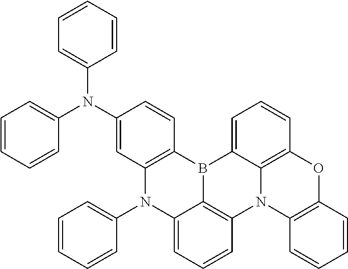 [SMILES: c1ccc(N(c2ccccc2)c2ccc3c(c2)N(c2ccccc2)c2cccc4c2B3c2cccc3c2N4c2ccccc2O3)cc1]

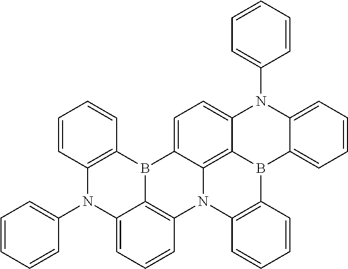 [SMILES: c1ccc(N2c3ccccc3B3c4ccc5c6c4N(c4ccccc4B6c4ccccc4N5c4ccccc4)c4cccc2c43)cc1]

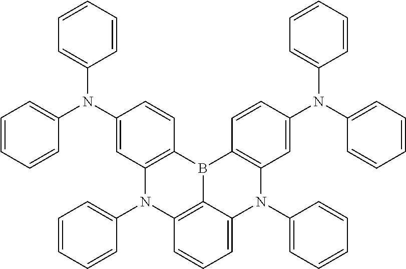 [SMILES: c1ccc(N(c2ccccc2)c2ccc3c(c2)N(c2ccccc2)c2cccc4c2B3c2ccc(N(c3ccccc3)c3ccccc3)cc2N4c2ccccc2)cc1]

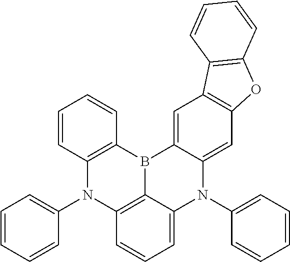 [SMILES: c1ccc(N2c3ccccc3B3c4cc5c(cc4N(c4ccccc4)c4cccc2c43)oc2ccccc25)cc1]

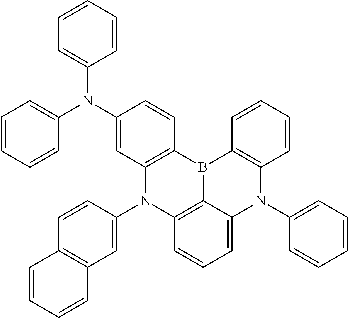 [SMILES: c1ccc(N(c2ccccc2)c2ccc3c(c2)N(c2ccc4ccccc4c2)c2cccc4c2B3c2ccccc2N4c2ccccc2)cc1]

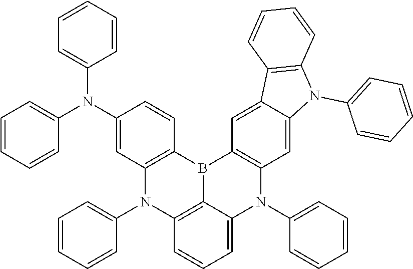 [SMILES: c1ccc(N(c2ccccc2)c2ccc3c(c2)N(c2ccccc2)c2cccc4c2B3c2cc3c5ccccc5n(-c5ccccc5)c3cc2N4c2ccccc2)cc1]

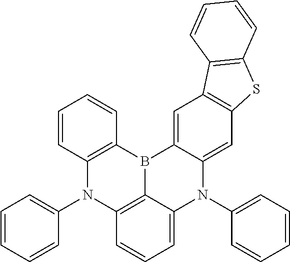 [SMILES: c1ccc(N2c3ccccc3B3c4cc5c(cc4N(c4ccccc4)c4cccc2c43)sc2ccccc25)cc1]

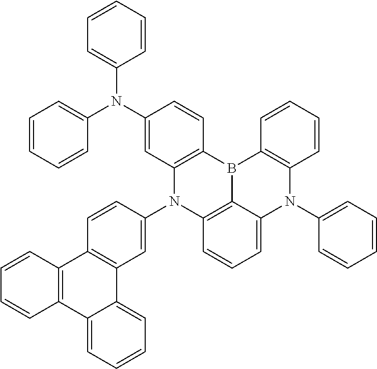 [SMILES: c1ccc(N(c2ccccc2)c2ccc3c(c2)N(c2ccc4c5ccccc5c5ccccc5c4c2)c2cccc4c2B3c2ccccc2N4c2ccccc2)cc1]

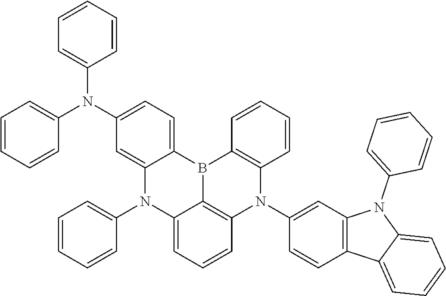 [SMILES: c1ccc(N(c2ccccc2)c2ccc3c(c2)N(c2ccccc2)c2cccc4c2B3c2ccccc2N4c2ccc3c4ccccc4n(-c4ccccc4)c3c2)cc1]

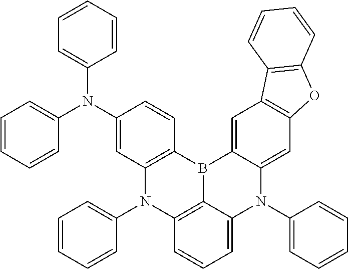 [SMILES: c1ccc(N(c2ccccc2)c2ccc3c(c2)N(c2ccccc2)c2cccc4c2B3c2cc3c(cc2N4c2ccccc2)oc2ccccc23)cc1]

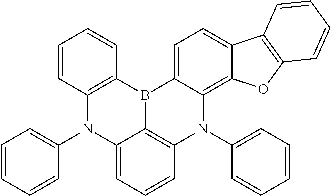 [SMILES: c1ccc(N2c3ccccc3B3c4ccc5c(oc6ccccc65)c4N(c4ccccc4)c4cccc2c43)cc1]

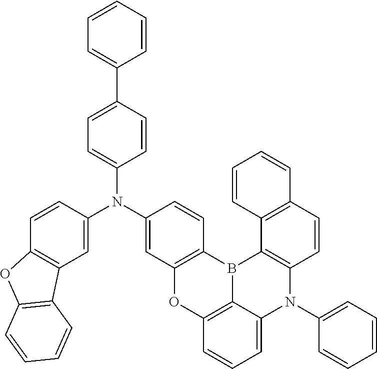 [SMILES: c1ccc(-c2ccc(N(c3ccc4c(c3)Oc3cccc5c3B4c3c(ccc4ccccc34)N5c3ccccc3)c3ccc4oc5ccccc5c4c3)cc2)cc1]

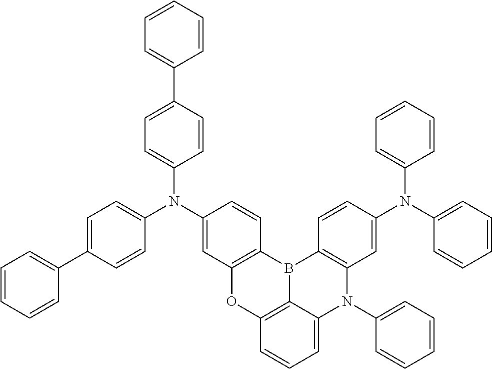 [SMILES: c1ccc(-c2ccc(N(c3ccc(-c4ccccc4)cc3)c3ccc4c(c3)Oc3cccc5c3B4c3ccc(N(c4ccccc4)c4ccccc4)cc3N5c3ccccc3)cc2)cc1]

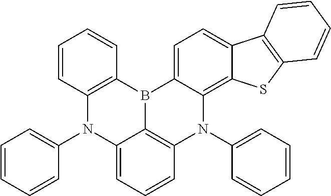 [SMILES: c1ccc(N2c3ccccc3B3c4ccc5c(sc6ccccc65)c4N(c4ccccc4)c4cccc2c43)cc1]

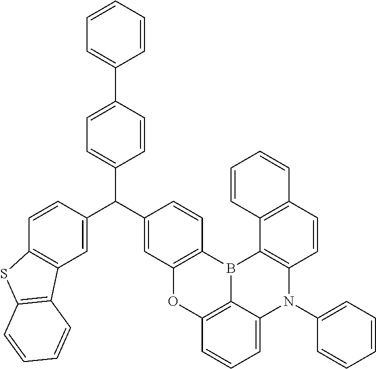 [SMILES: c1ccc(-c2ccc(C(c3ccc4c(c3)Oc3cccc5c3B4c3c(ccc4ccccc34)N5c3ccccc3)c3ccc4sc5ccccc5c4c3)cc2)cc1]

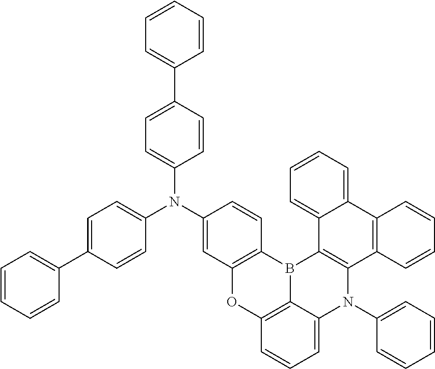 [SMILES: c1ccc(-c2ccc(N(c3ccc(-c4ccccc4)cc3)c3ccc4c(c3)Oc3cccc5c3B4c3c(c4ccccc4c4ccccc34)N5c3ccccc3)cc2)cc1]

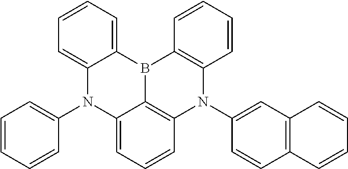 [SMILES: c1ccc(N2c3ccccc3B3c4ccccc4N(c4ccc5ccccc5c4)c4cccc2c43)cc1]

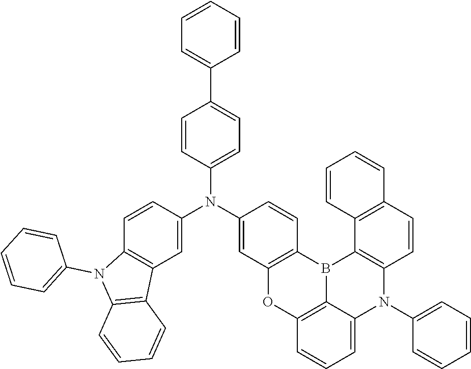 [SMILES: c1ccc(-c2ccc(N(c3ccc4c(c3)Oc3cccc5c3B4c3c(ccc4ccccc34)N5c3ccccc3)c3ccc4c(c3)c3ccccc3n4-c3ccccc3)cc2)cc1]

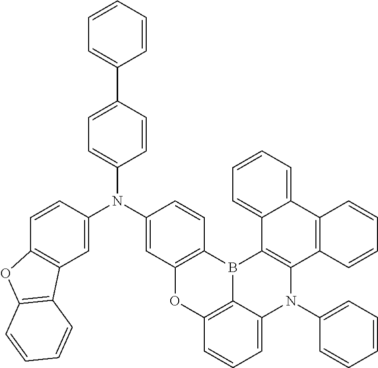 [SMILES: c1ccc(-c2ccc(N(c3ccc4c(c3)Oc3cccc5c3B4c3c(c4ccccc4c4ccccc34)N5c3ccccc3)c3ccc4oc5ccccc5c4c3)cc2)cc1]

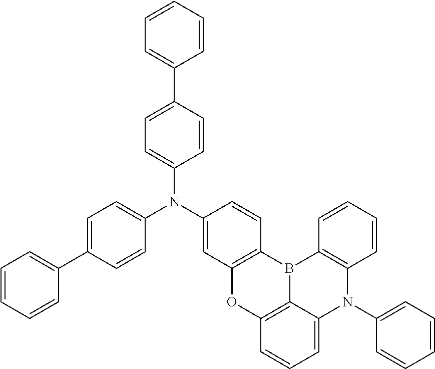 [SMILES: c1ccc(-c2ccc(N(c3ccc(-c4ccccc4)cc3)c3ccc4c(c3)Oc3cccc5c3B4c3ccccc3N5c3ccccc3)cc2)cc1]

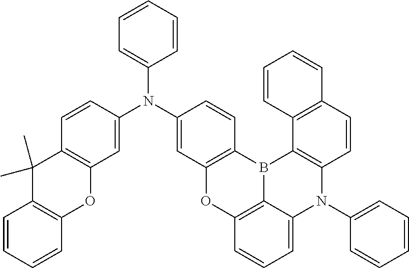 [SMILES: CC1(C)c2ccccc2Oc2cc(N(c3ccccc3)c3ccc4c(c3)Oc3cccc5c3B4c3c(ccc4ccccc34)N5c3ccccc3)ccc21]

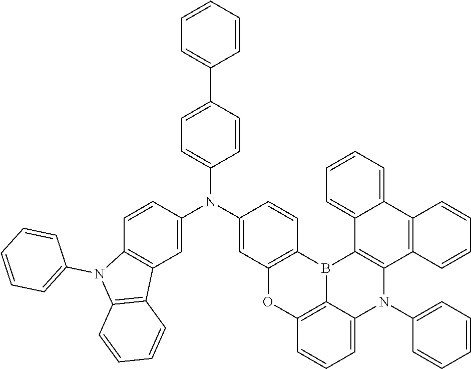 [SMILES: c1ccc(-c2ccc(N(c3ccc4c(c3)Oc3cccc5c3B4c3c(c4ccccc4c4ccccc34)N5c3ccccc3)c3ccc4c(c3)c3ccccc3n4-c3ccccc3)cc2)cc1]

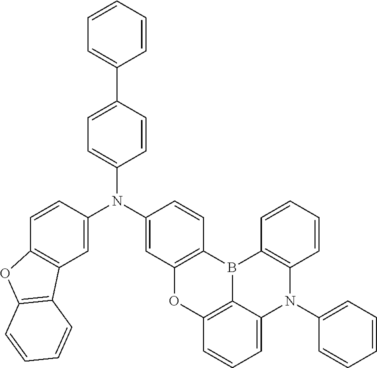 [SMILES: c1ccc(-c2ccc(N(c3ccc4c(c3)Oc3cccc5c3B4c3ccccc3N5c3ccccc3)c3ccc4oc5ccccc5c4c3)cc2)cc1]

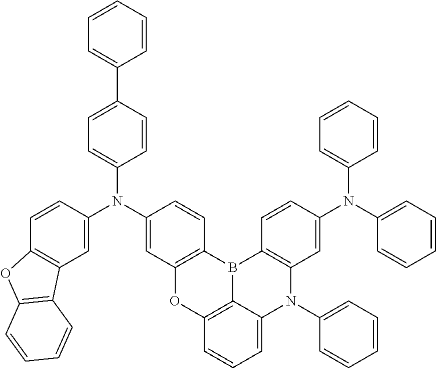 [SMILES: c1ccc(-c2ccc(N(c3ccc4c(c3)Oc3cccc5c3B4c3ccc(N(c4ccccc4)c4ccccc4)cc3N5c3ccccc3)c3ccc4oc5ccccc5c4c3)cc2)cc1]

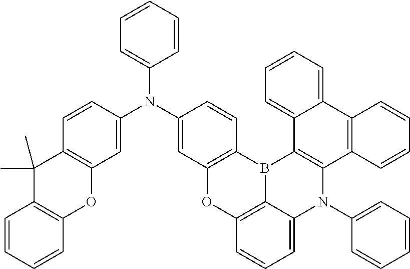 [SMILES: CC1(C)c2ccccc2Oc2cc(N(c3ccccc3)c3ccc4c(c3)Oc3cccc5c3B4c3c(c4ccccc4c4ccccc34)N5c3ccccc3)ccc21]

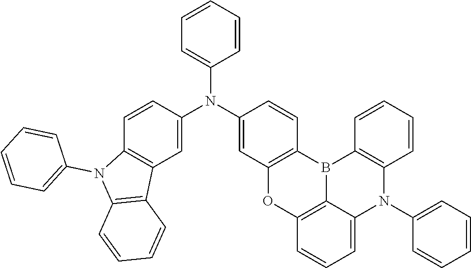 [SMILES: c1ccc(N(c2ccc3c(c2)Oc2cccc4c2B3c2ccccc2N4c2ccccc2)c2ccc3c(c2)c2ccccc2n3-c2ccccc2)cc1]

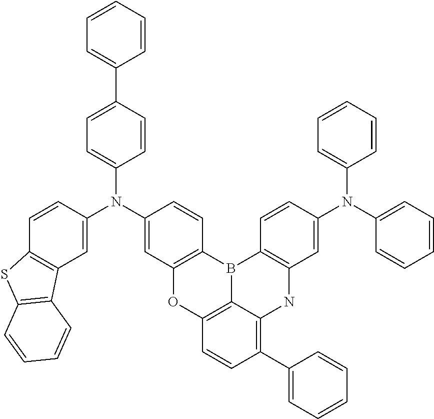 [SMILES: c1ccc(-c2ccc(N(c3ccc4c(c3)Oc3ccc(-c5ccccc5)c5c3B4c3ccc(N(c4ccccc4)c4ccccc4)cc3N5)c3ccc4sc5ccccc5c4c3)cc2)cc1]

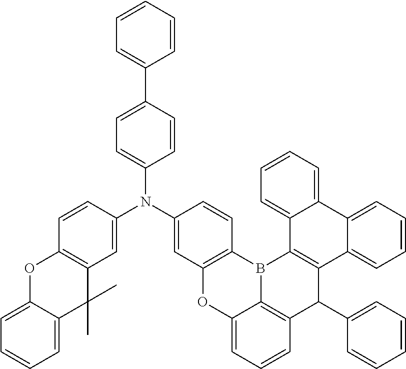 [SMILES: CC1(C)c2ccccc2Oc2ccc(N(c3ccc(-c4ccccc4)cc3)c3ccc4c(c3)Oc3cccc5c3B4c3c(c4ccccc4c4ccccc34)C5c3ccccc3)cc21]

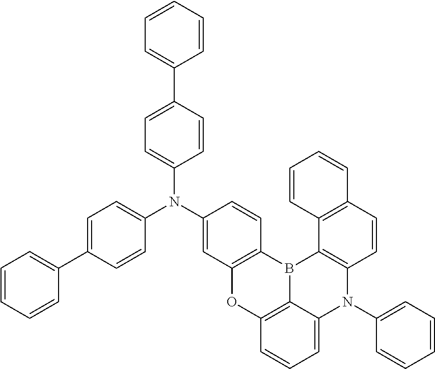 [SMILES: c1ccc(-c2ccc(N(c3ccc(-c4ccccc4)cc3)c3ccc4c(c3)Oc3cccc5c3B4c3c(ccc4ccccc34)N5c3ccccc3)cc2)cc1]

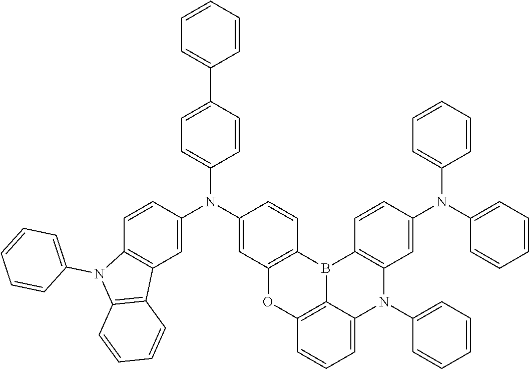 [SMILES: c1ccc(-c2ccc(N(c3ccc4c(c3)Oc3cccc5c3B4c3ccc(N(c4ccccc4)c4ccccc4)cc3N5c3ccccc3)c3ccc4c(c3)c3ccccc3n4-c3ccccc3)cc2)cc1]

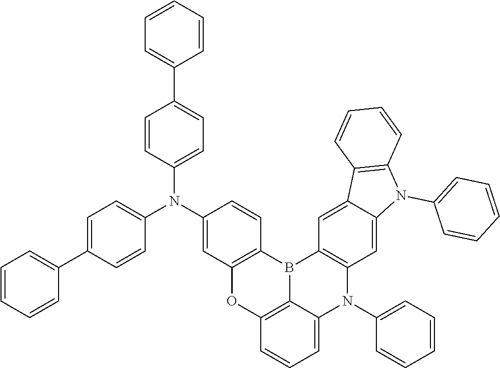 [SMILES: c1ccc(-c2ccc(N(c3ccc(-c4ccccc4)cc3)c3ccc4c(c3)Oc3cccc5c3B4c3cc4c6ccccc6n(-c6ccccc6)c4cc3N5c3ccccc3)cc2)cc1]

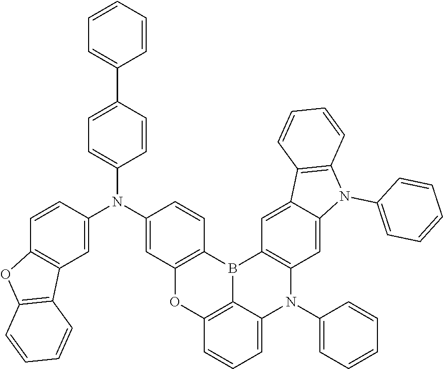 [SMILES: c1ccc(-c2ccc(N(c3ccc4c(c3)Oc3cccc5c3B4c3cc4c6ccccc6n(-c6ccccc6)c4cc3N5c3ccccc3)c3ccc4oc5ccccc5c4c3)cc2)cc1]

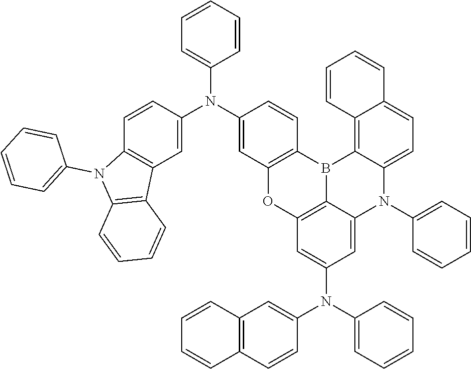 [SMILES: c1ccc(N(c2cc3c4c(c2)N(c2ccccc2)c2ccc5ccccc5c2B4c2ccc(N(c4ccccc4)c4ccc5c(c4)c4ccccc4n5-c4ccccc4)cc2O3)c2ccc3ccccc3c2)cc1]

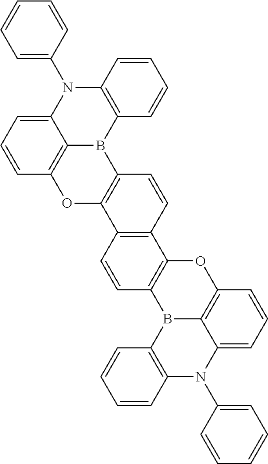 [SMILES: c1ccc(N2c3ccccc3B3c4ccc5c6c(ccc5c4Oc4cccc2c43)B2c3ccccc3N(c3ccccc3)c3cccc(c32)O6)cc1]

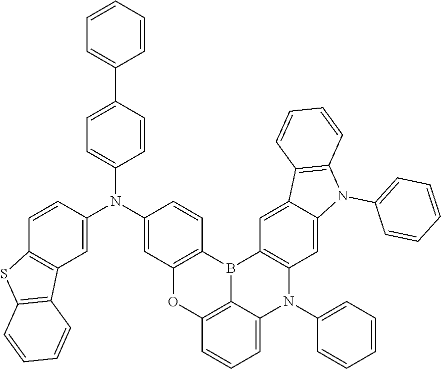 [SMILES: c1ccc(-c2ccc(N(c3ccc4c(c3)Oc3cccc5c3B4c3cc4c6ccccc6n(-c6ccccc6)c4cc3N5c3ccccc3)c3ccc4sc5ccccc5c4c3)cc2)cc1]

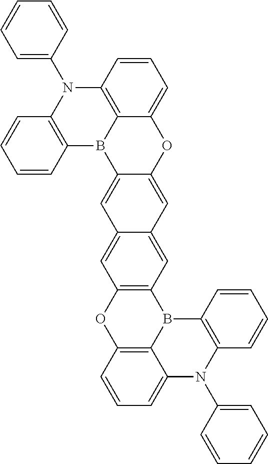 [SMILES: c1ccc(N2c3ccccc3B3c4cc5cc6c(cc5cc4Oc4cccc2c43)B2c3ccccc3N(c3ccccc3)c3cccc(c32)O6)cc1]

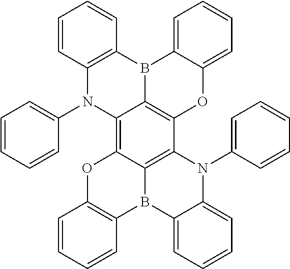 [SMILES: c1ccc(N2c3ccccc3B3c4ccccc4Oc4c3c2c2c3c4N(c4ccccc4)c4ccccc4B3c3ccccc3O2)cc1]

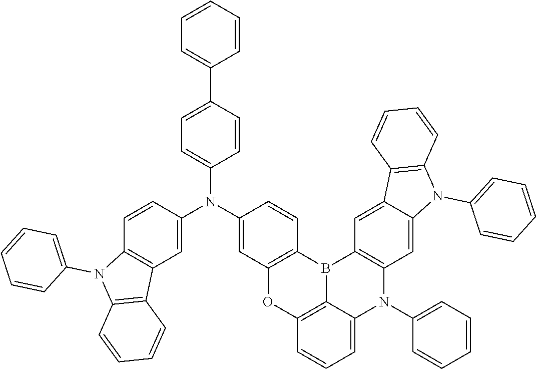 [SMILES: c1ccc(-c2ccc(N(c3ccc4c(c3)Oc3cccc5c3B4c3cc4c6ccccc6n(-c6ccccc6)c4cc3N5c3ccccc3)c3ccc4c(c3)c3ccccc3n4-c3ccccc3)cc2)cc1]

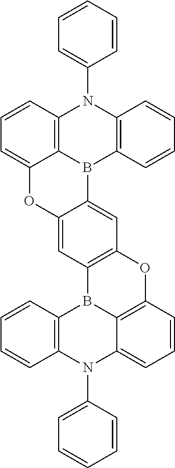 [SMILES: c1ccc(N2c3ccccc3B3c4cc5c(cc4Oc4cccc2c43)B2c3ccccc3N(c3ccccc3)c3cccc(c32)O5)cc1]

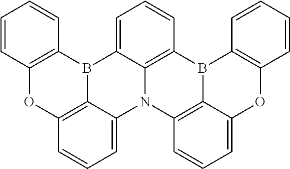 [SMILES: c1ccc2c(c1)Oc1cccc3c1B2c1cccc2c1N3c1cccc3c1B2c1ccccc1O3]

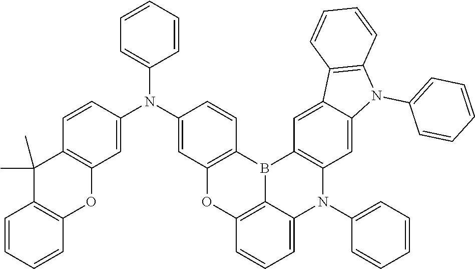 [SMILES: CC1(C)c2ccccc2Oc2cc(N(c3ccccc3)c3ccc4c(c3)Oc3cccc5c3B4c3cc4c6ccccc6n(-c6ccccc6)c4cc3N5c3ccccc3)ccc21]

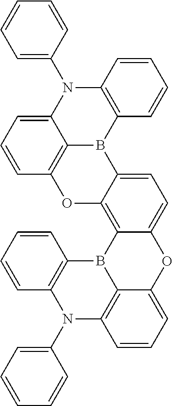 [SMILES: c1ccc(N2c3ccccc3B3c4ccc5c(c4Oc4cccc2c43)B2c3ccccc3N(c3ccccc3)c3cccc(c32)O5)cc1]

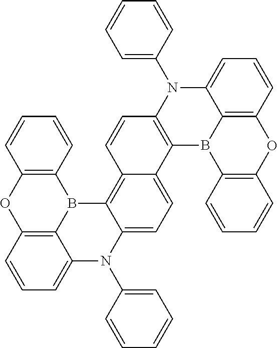 [SMILES: c1ccc(N2c3cccc4c3B(c3ccccc3O4)c3c2ccc2c4c(ccc32)N(c2ccccc2)c2cccc3c2B4c2ccccc2O3)cc1]

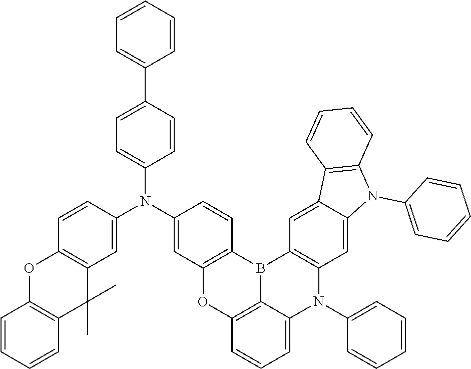 [SMILES: CC1(C)c2ccccc2Oc2ccc(N(c3ccc(-c4ccccc4)cc3)c3ccc4c(c3)Oc3cccc5c3B4c3cc4c6ccccc6n(-c6ccccc6)c4cc3N5c3ccccc3)cc21]

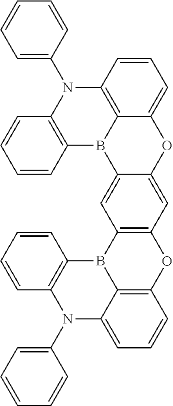 [SMILES: c1ccc(N2c3ccccc3B3c4cc5c(cc4Oc4cccc2c43)Oc2cccc3c2B5c2ccccc2N3c2ccccc2)cc1]

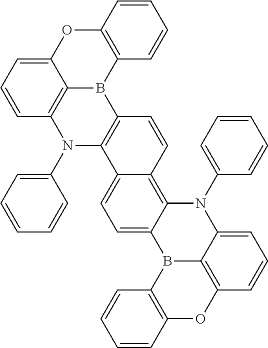 [SMILES: c1ccc(N2c3cccc4c3B(c3ccccc3O4)c3ccc4c5c(ccc4c32)B2c3ccccc3Oc3cccc(c32)N5c2ccccc2)cc1]

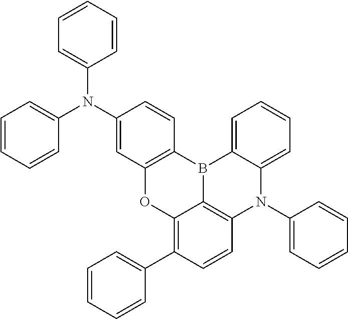 [SMILES: c1ccc(-c2ccc3c4c2Oc2cc(N(c5ccccc5)c5ccccc5)ccc2B4c2ccccc2N3c2ccccc2)cc1]

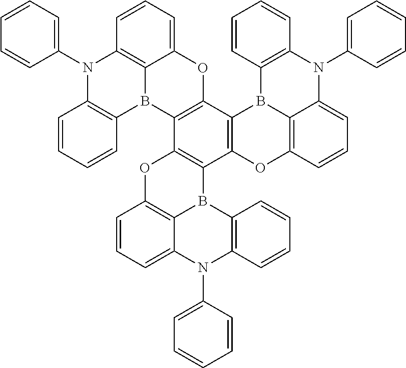 [SMILES: c1ccc(N2c3ccccc3B3c4c(cccc42)Oc2c4c(c5c(c23)Oc2cccc3c2B5c2ccccc2N3c2ccccc2)Oc2cccc3c2B4c2ccccc2N3c2ccccc2)cc1]

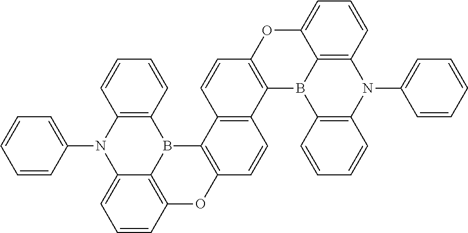 [SMILES: c1ccc(N2c3ccccc3B3c4c(cccc42)Oc2ccc4c5c(ccc4c23)Oc2cccc3c2B5c2ccccc2N3c2ccccc2)cc1]

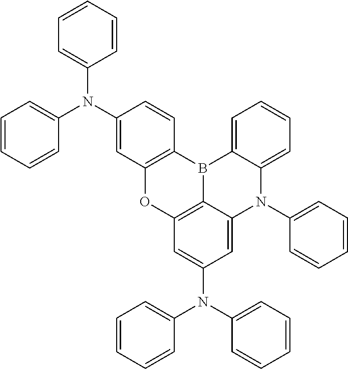 [SMILES: c1ccc(N(c2ccccc2)c2ccc3c(c2)Oc2cc(N(c4ccccc4)c4ccccc4)cc4c2B3c2ccccc2N4c2ccccc2)cc1]

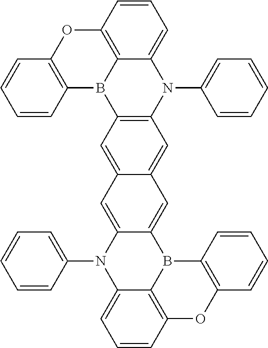 [SMILES: c1ccc(N2c3cc4cc5c(cc4cc3B3c4ccccc4Oc4cccc2c43)N(c2ccccc2)c2cccc3c2B5c2ccccc2O3)cc1]

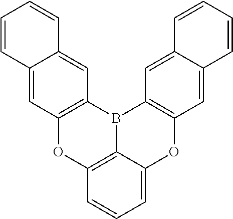 [SMILES: c1cc2c3c(c1)Oc1cc4ccccc4cc1B3c1cc3ccccc3cc1O2]

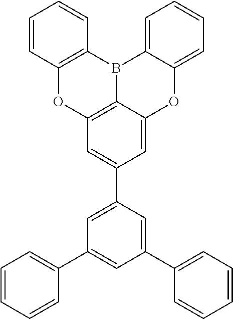 [SMILES: c1ccc(-c2cc(-c3ccccc3)cc(-c3cc4c5c(c3)Oc3ccccc3B5c3ccccc3O4)c2)cc1]

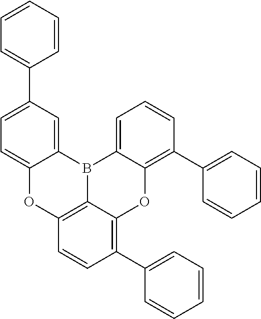 [SMILES: c1ccc(-c2ccc3c(c2)B2c4cccc(-c5ccccc5)c4Oc4c(-c5ccccc5)ccc(c42)O3)cc1]

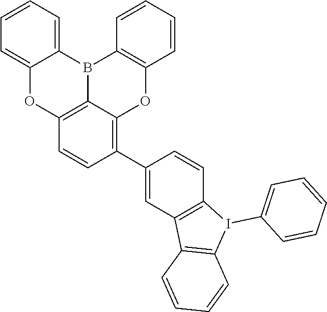 [SMILES: c1ccc(I2c3ccccc3-c3cc(-c4ccc5c6c4Oc4ccccc4B6c4ccccc4O5)ccc32)cc1]

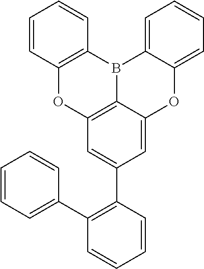 [SMILES: c1ccc(-c2ccccc2-c2cc3c4c(c2)Oc2ccccc2B4c2ccccc2O3)cc1]

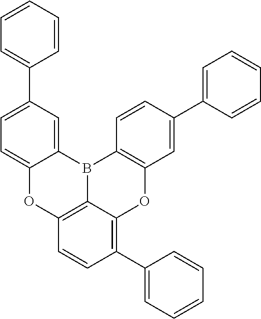 [SMILES: c1ccc(-c2ccc3c(c2)Oc2c(-c4ccccc4)ccc4c2B3c2cc(-c3ccccc3)ccc2O4)cc1]

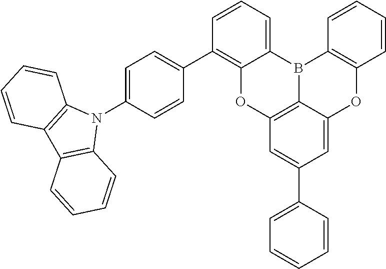 [SMILES: c1ccc(-c2cc3c4c(c2)Oc2c(cccc2-c2ccc(-n5c6ccccc6c6ccccc65)cc2)B4c2ccccc2O3)cc1]

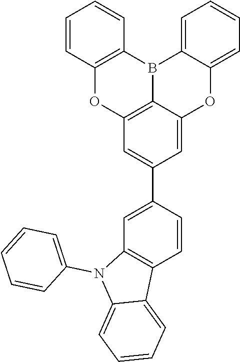 [SMILES: c1ccc(-n2c3ccccc3c3ccc(-c4cc5c6c(c4)Oc4ccccc4B6c4ccccc4O5)cc32)cc1]

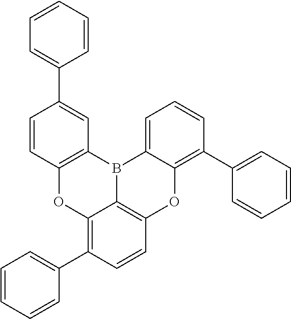 [SMILES: c1ccc(-c2ccc3c(c2)B2c4cccc(-c5ccccc5)c4Oc4ccc(-c5ccccc5)c(c42)O3)cc1]

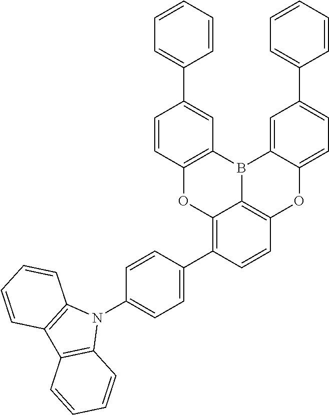 [SMILES: c1ccc(-c2ccc3c(c2)B2c4cc(-c5ccccc5)ccc4Oc4c(-c5ccc(-n6c7ccccc7c7ccccc76)cc5)ccc(c42)O3)cc1]

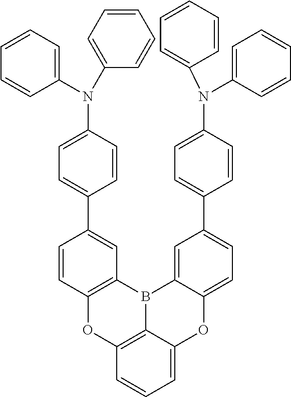 [SMILES: c1ccc(N(c2ccccc2)c2ccc(-c3ccc4c(c3)B3c5cc(-c6ccc(N(c7ccccc7)c7ccccc7)cc6)ccc5Oc5cccc(c53)O4)cc2)cc1]

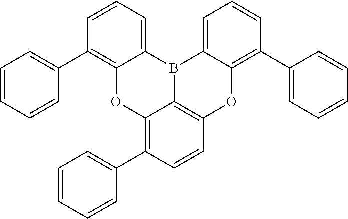 [SMILES: c1ccc(-c2cccc3c2Oc2ccc(-c4ccccc4)c4c2B3c2cccc(-c3ccccc3)c2O4)cc1]

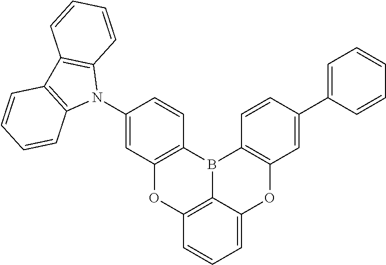 [SMILES: c1ccc(-c2ccc3c(c2)Oc2cccc4c2B3c2ccc(-n3c5ccccc5c5ccccc53)cc2O4)cc1]

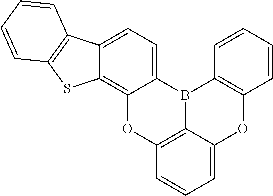 [SMILES: c1ccc2c(c1)Oc1cccc3c1B2c1ccc2c(sc4ccccc42)c1O3]

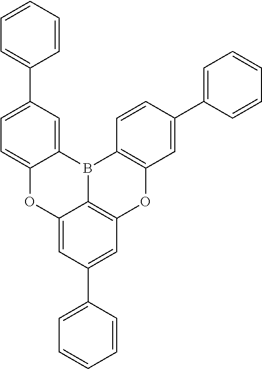 [SMILES: c1ccc(-c2ccc3c(c2)Oc2cc(-c4ccccc4)cc4c2B3c2cc(-c3ccccc3)ccc2O4)cc1]

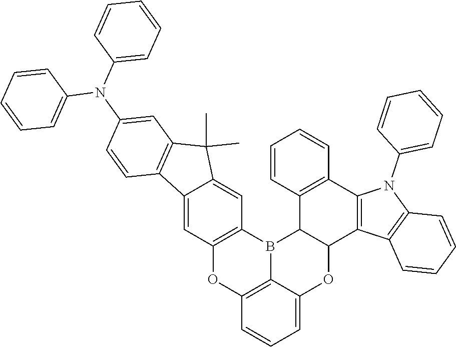 [SMILES: CC1(C)c2cc(N(c3ccccc3)c3ccccc3)ccc2-c2cc3c(cc21)B1c2c(cccc2OC2c4c(n(-c5ccccc5)c5ccccc45)-c4ccccc4C12)O3]

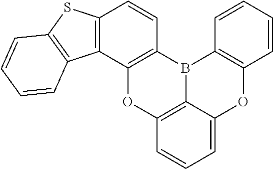 [SMILES: c1ccc2c(c1)Oc1cccc3c1B2c1ccc2sc4ccccc4c2c1O3]

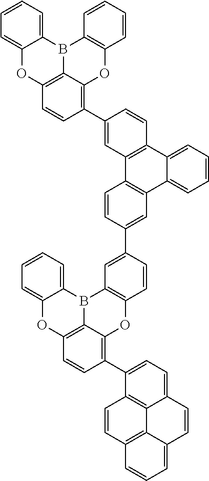 [SMILES: c1ccc2c(c1)Oc1ccc(-c3ccc4c5ccccc5c5cc(-c6ccc7c(c6)B6c8ccccc8Oc8ccc(-c9ccc%10ccc%11cccc%12ccc9c%10c%11%12)c(c86)O7)ccc5c4c3)c3c1B2c1ccccc1O3]

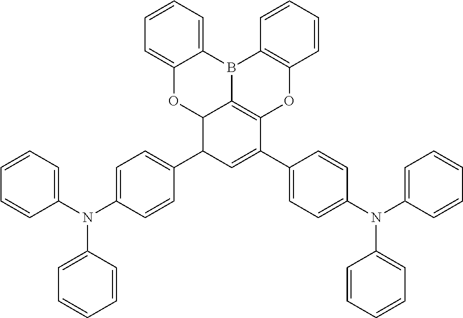 [SMILES: C1=C(c2ccc(N(c3ccccc3)c3ccccc3)cc2)C2=C3B(c4ccccc4O2)c2ccccc2OC3C1c1ccc(N(c2ccccc2)c2ccccc2)cc1]

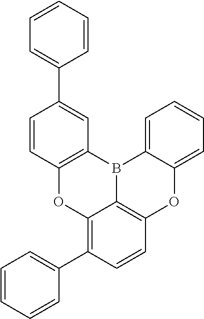 [SMILES: c1ccc(-c2ccc3c(c2)B2c4ccccc4Oc4ccc(-c5ccccc5)c(c42)O3)cc1]

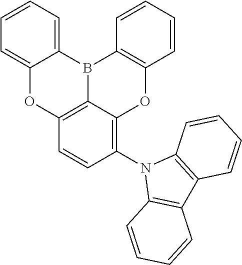 [SMILES: c1ccc2c(c1)Oc1ccc(-n3c4ccccc4c4ccccc43)c3c1B2c1ccccc1O3]

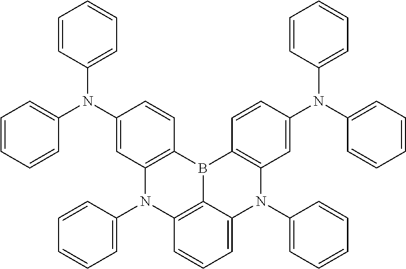 [SMILES: c1ccc(N(c2ccccc2)c2ccc3c(c2)N(c2ccccc2)c2cccc4c2B3c2ccc(N(c3ccccc3)c3ccccc3)cc2N4c2ccccc2)cc1]

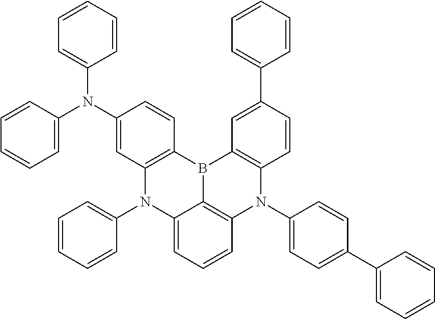 [SMILES: c1ccc(-c2ccc(N3c4ccc(-c5ccccc5)cc4B4c5ccc(N(c6ccccc6)c6ccccc6)cc5N(c5ccccc5)c5cccc3c54)cc2)cc1]

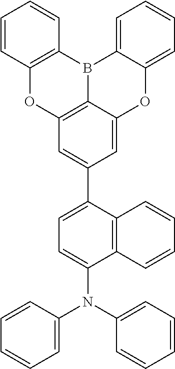 [SMILES: c1ccc(N(c2ccccc2)c2ccc(-c3cc4c5c(c3)Oc3ccccc3B5c3ccccc3O4)c3ccccc23)cc1]

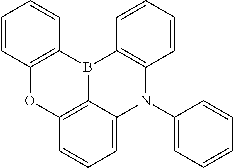 [SMILES: c1ccc(N2c3ccccc3B3c4ccccc4Oc4cccc2c43)cc1]

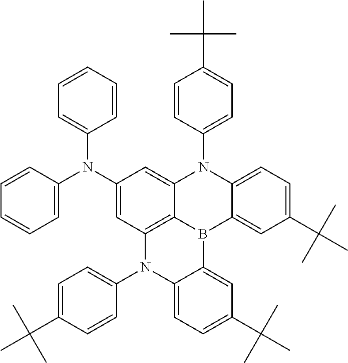 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1]

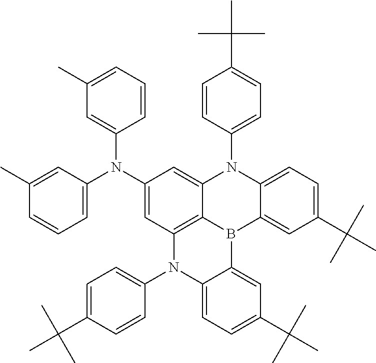 [SMILES: Cc1cccc(N(c2cccc(C)c2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)c1]

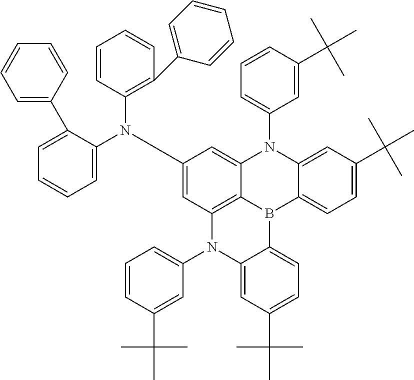 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5-c5ccccc5)c5ccccc5-c5ccccc5)cc2c43)c1]

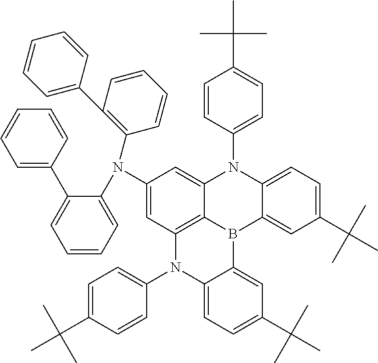 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5-c5ccccc5)c5ccccc5-c5ccccc5)cc2c43)cc1]

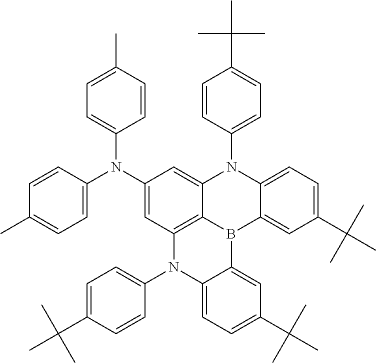 [SMILES: Cc1ccc(N(c2ccc(C)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)cc1]

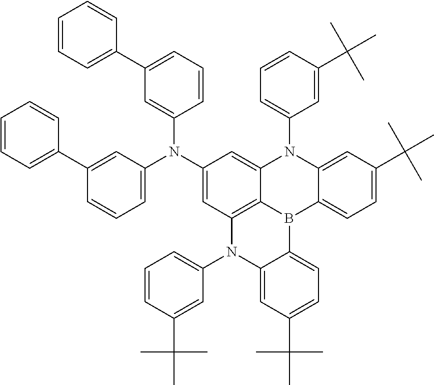 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5cccc(-c6ccccc6)c5)c5cccc(-c6ccccc6)c5)cc2c43)c1]

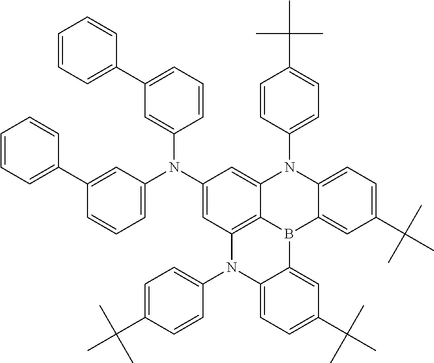 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5cccc(-c6ccccc6)c5)c5cccc(-c6ccccc6)c5)cc2c43)cc1]

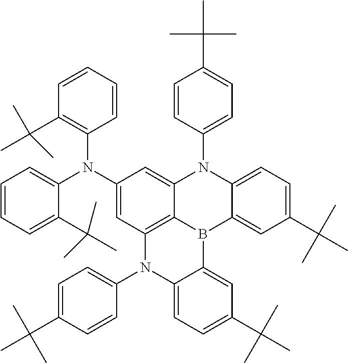 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5C(C)(C)C)c5ccccc5C(C)(C)C)cc2c43)cc1]

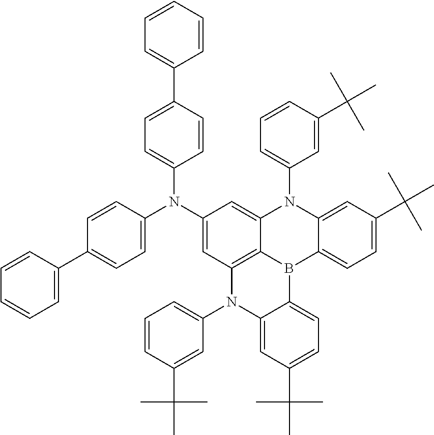 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccc(-c6ccccc6)cc5)c5ccc(-c6ccccc6)cc5)cc2c43)c1]

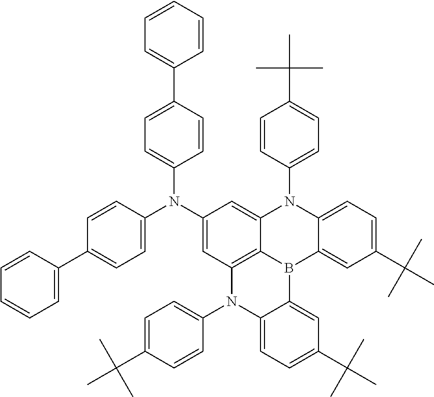 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccc(-c6ccccc6)cc5)c5ccc(-c6ccccc6)cc5)cc2c43)cc1]

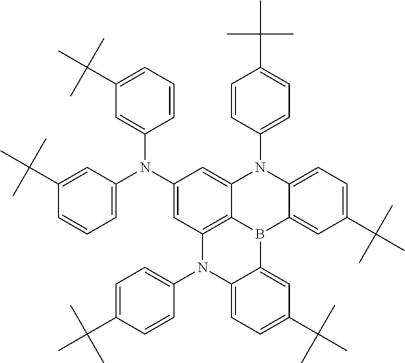 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5cccc(C(C)(C)C)c5)c5cccc(C(C)(C)C)c5)cc2c43)cc1]

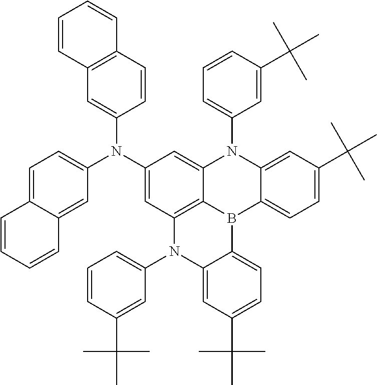 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccc6ccccc6c5)c5ccc6ccccc6c5)cc2c43)c1]

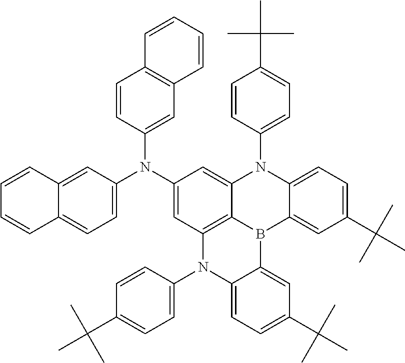 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccc6ccccc6c5)c5ccc6ccccc6c5)cc2c43)cc1]

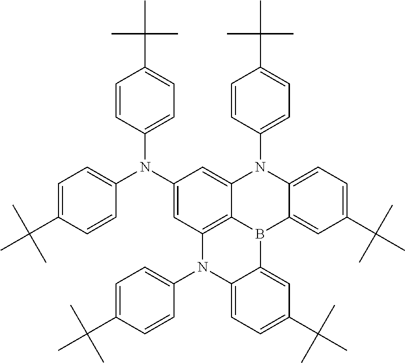 [SMILES: CC(C)(C)c1ccc(N(c2ccc(C(C)(C)C)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)cc1]

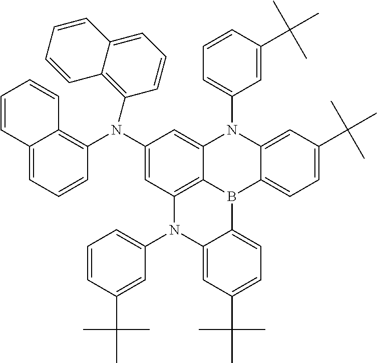 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5cccc6ccccc56)c5cccc6ccccc56)cc2c43)c1]

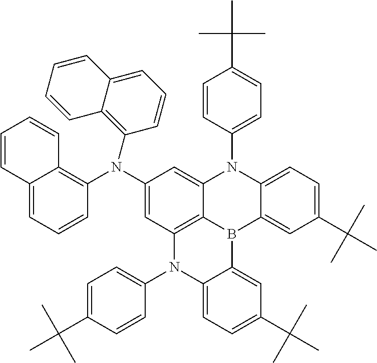 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5cccc6ccccc56)c5cccc6ccccc56)cc2c43)cc1]

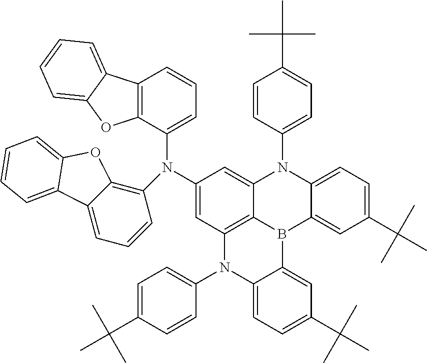 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5cccc6c5oc5ccccc56)c5cccc6c5oc5ccccc56)cc2c43)cc1]

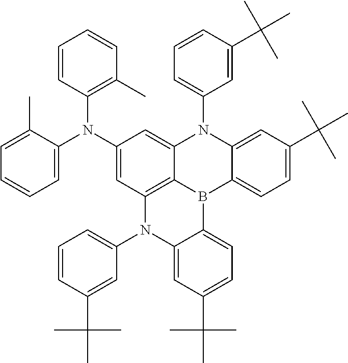 [SMILES: Cc1ccccc1N(c1cc2c3c(c1)N(c1cccc(C(C)(C)C)c1)c1cc(C(C)(C)C)ccc1B3c1ccc(C(C)(C)C)cc1N2c1cccc(C(C)(C)C)c1)c1ccccc1C]

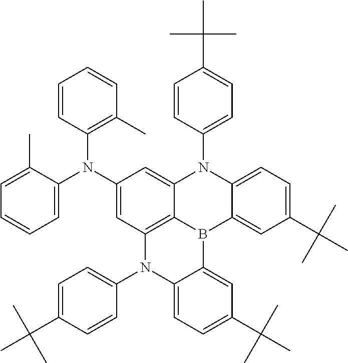 [SMILES: Cc1ccccc1N(c1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1)c1ccccc1C]

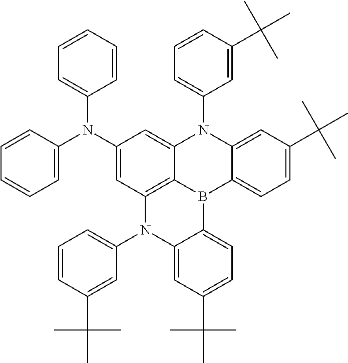 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5ccccc5)cc2c43)c1]

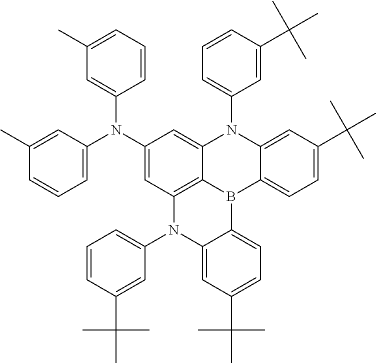 [SMILES: Cc1cccc(N(c2cccc(C)c2)c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c1]

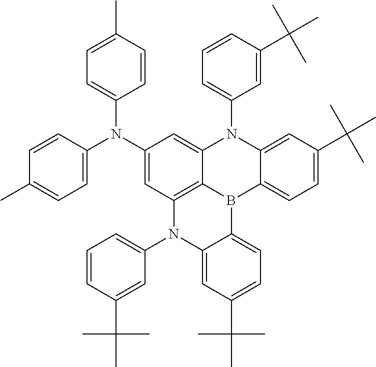 [SMILES: Cc1ccc(N(c2ccc(C)cc2)c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)cc1]

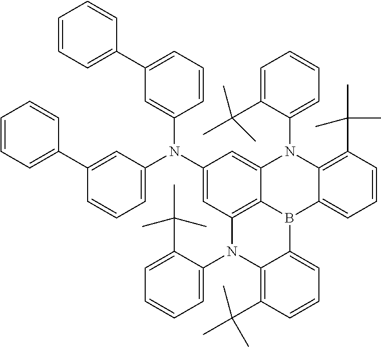 [SMILES: CC(C)(C)c1ccccc1N1c2cc(N(c3cccc(-c4ccccc4)c3)c3cccc(-c4ccccc4)c3)cc3c2B(c2cccc(C(C)(C)C)c21)c1cccc(C(C)(C)C)c1N3c1ccccc1C(C)(C)C]

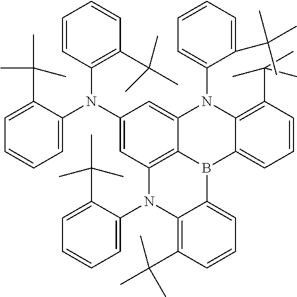 [SMILES: CC(C)(C)c1ccccc1N(c1cc2c3c(c1)N(c1ccccc1C(C)(C)C)c1c(cccc1C(C)(C)C)B3c1cccc(C(C)(C)C)c1N2c1ccccc1C(C)(C)C)c1ccccc1C(C)(C)C]

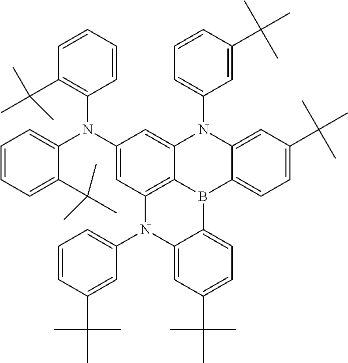 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5C(C)(C)C)c5ccccc5C(C)(C)C)cc2c43)c1]

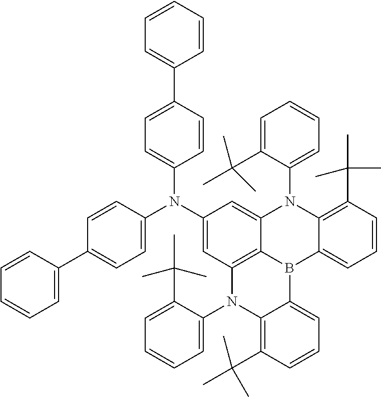 [SMILES: CC(C)(C)c1ccccc1N1c2cc(N(c3ccc(-c4ccccc4)cc3)c3ccc(-c4ccccc4)cc3)cc3c2B(c2cccc(C(C)(C)C)c21)c1cccc(C(C)(C)C)c1N3c1ccccc1C(C)(C)C]

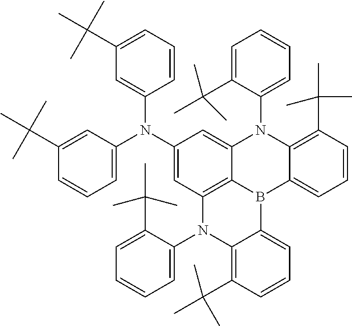 [SMILES: CC(C)(C)c1cccc(N(c2cccc(C(C)(C)C)c2)c2cc3c4c(c2)N(c2ccccc2C(C)(C)C)c2c(cccc2C(C)(C)C)B4c2cccc(C(C)(C)C)c2N3c2ccccc2C(C)(C)C)c1]

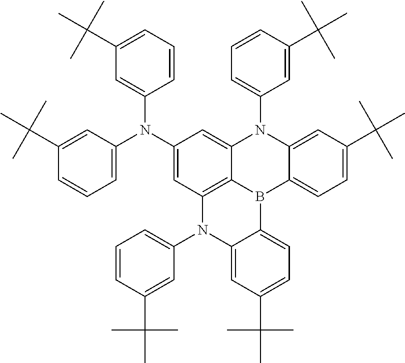 [SMILES: CC(C)(C)c1cccc(N(c2cccc(C(C)(C)C)c2)c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c1]

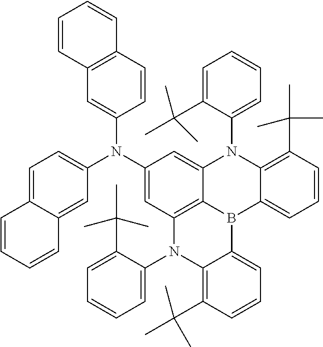 [SMILES: CC(C)(C)c1ccccc1N1c2cc(N(c3ccc4ccccc4c3)c3ccc4ccccc4c3)cc3c2B(c2cccc(C(C)(C)C)c21)c1cccc(C(C)(C)C)c1N3c1ccccc1C(C)(C)C]

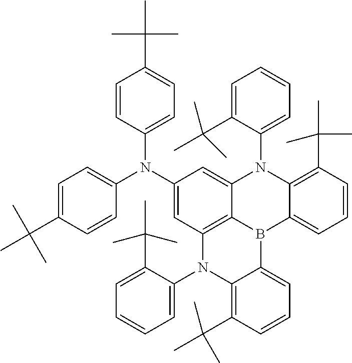 [SMILES: CC(C)(C)c1ccc(N(c2ccc(C(C)(C)C)cc2)c2cc3c4c(c2)N(c2ccccc2C(C)(C)C)c2c(cccc2C(C)(C)C)B4c2cccc(C(C)(C)C)c2N3c2ccccc2C(C)(C)C)cc1]

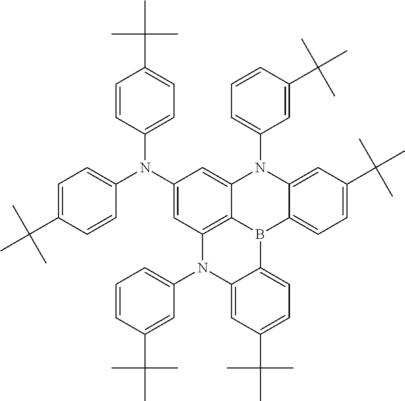 [SMILES: CC(C)(C)c1ccc(N(c2ccc(C(C)(C)C)cc2)c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)cc1]

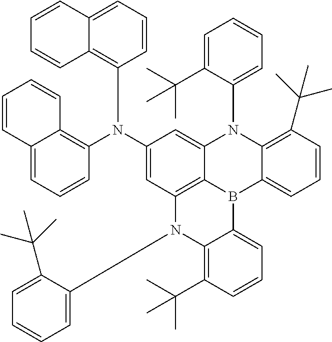 [SMILES: CC(C)(C)c1ccccc1N1c2cc(N(c3cccc4ccccc34)c3cccc4ccccc34)cc3c2B(c2cccc(C(C)(C)C)c21)c1cccc(C(C)(C)C)c1N3c1ccccc1C(C)(C)C]

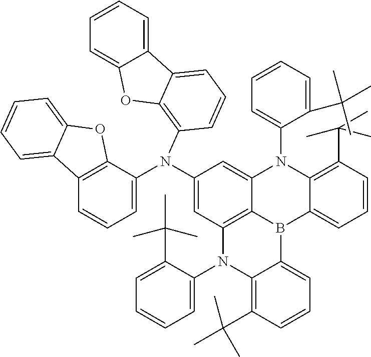 [SMILES: CC(C)(C)c1ccccc1N1c2cc(N(c3cccc4c3oc3ccccc34)c3cccc4c3oc3ccccc34)cc3c2B(c2cccc(C(C)(C)C)c21)c1cccc(C(C)(C)C)c1N3c1ccccc1C(C)(C)C]

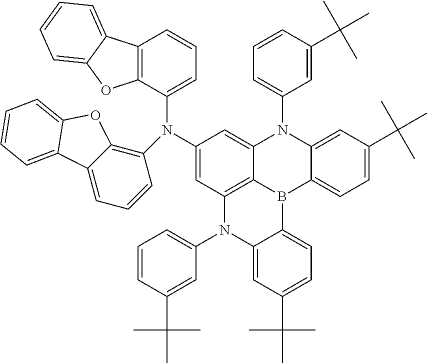 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5cccc6c5oc5ccccc56)c5cccc6c5oc5ccccc56)cc2c43)c1]

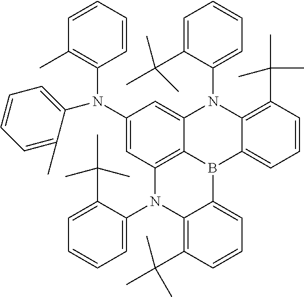 [SMILES: Cc1ccccc1N(c1cc2c3c(c1)N(c1ccccc1C(C)(C)C)c1c(cccc1C(C)(C)C)B3c1cccc(C(C)(C)C)c1N2c1ccccc1C(C)(C)C)c1ccccc1C]

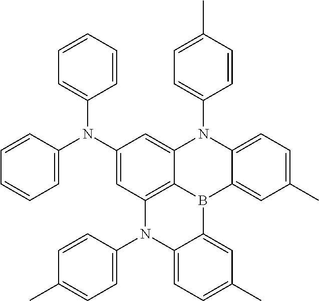 [SMILES: Cc1ccc(N2c3ccc(C)cc3B3c4cc(C)ccc4N(c4ccc(C)cc4)c4cc(N(c5ccccc5)c5ccccc5)cc2c43)cc1]

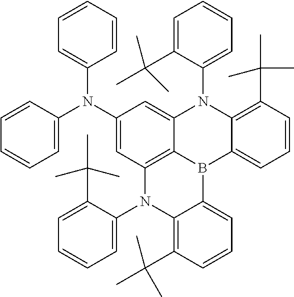 [SMILES: CC(C)(C)c1ccccc1N1c2cc(N(c3ccccc3)c3ccccc3)cc3c2B(c2cccc(C(C)(C)C)c21)c1cccc(C(C)(C)C)c1N3c1ccccc1C(C)(C)C]

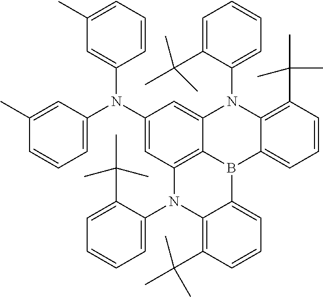 [SMILES: Cc1cccc(N(c2cccc(C)c2)c2cc3c4c(c2)N(c2ccccc2C(C)(C)C)c2c(cccc2C(C)(C)C)B4c2cccc(C(C)(C)C)c2N3c2ccccc2C(C)(C)C)c1]

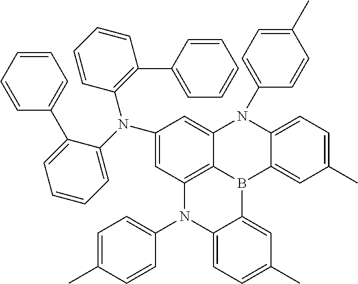 [SMILES: Cc1ccc(N2c3ccc(C)cc3B3c4cc(C)ccc4N(c4ccc(C)cc4)c4cc(N(c5ccccc5-c5ccccc5)c5ccccc5-c5ccccc5)cc2c43)cc1]

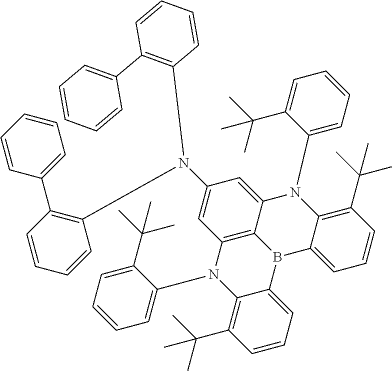 [SMILES: CC(C)(C)c1ccccc1N1c2cc(N(c3ccccc3-c3ccccc3)c3ccccc3-c3ccccc3)cc3c2B(c2cccc(C(C)(C)C)c21)c1cccc(C(C)(C)C)c1N3c1ccccc1C(C)(C)C]

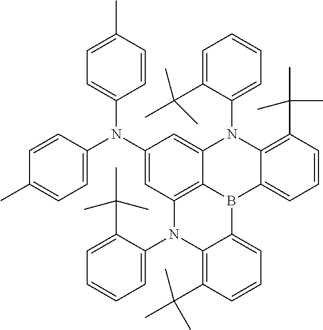 [SMILES: Cc1ccc(N(c2ccc(C)cc2)c2cc3c4c(c2)N(c2ccccc2C(C)(C)C)c2c(cccc2C(C)(C)C)B4c2cccc(C(C)(C)C)c2N3c2ccccc2C(C)(C)C)cc1]

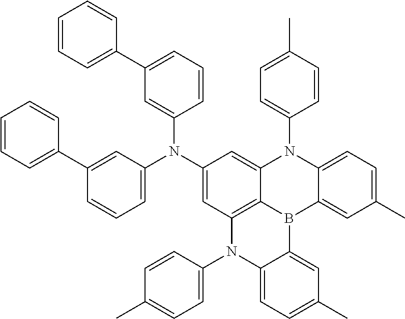 [SMILES: Cc1ccc(N2c3ccc(C)cc3B3c4cc(C)ccc4N(c4ccc(C)cc4)c4cc(N(c5cccc(-c6ccccc6)c5)c5cccc(-c6ccccc6)c5)cc2c43)cc1]

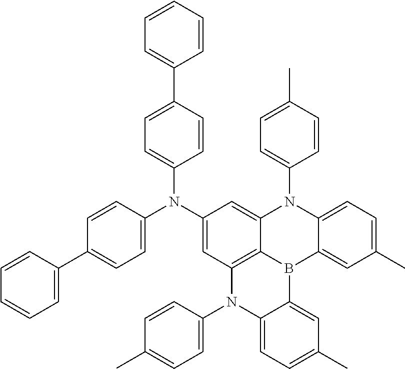 [SMILES: Cc1ccc(N2c3ccc(C)cc3B3c4cc(C)ccc4N(c4ccc(C)cc4)c4cc(N(c5ccc(-c6ccccc6)cc5)c5ccc(-c6ccccc6)cc5)cc2c43)cc1]

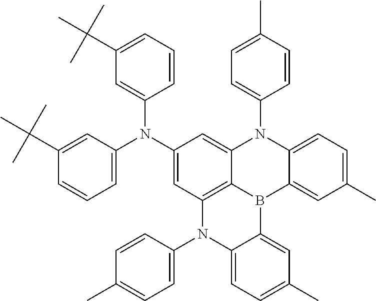 [SMILES: Cc1ccc(N2c3ccc(C)cc3B3c4cc(C)ccc4N(c4ccc(C)cc4)c4cc(N(c5cccc(C(C)(C)C)c5)c5cccc(C(C)(C)C)c5)cc2c43)cc1]

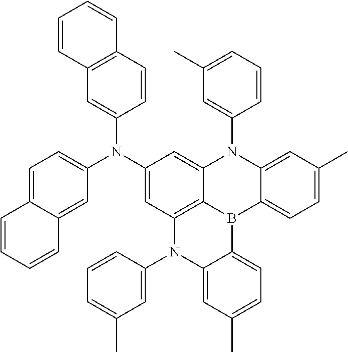 [SMILES: Cc1cccc(N2c3cc(C)ccc3B3c4ccc(C)cc4N(c4cccc(C)c4)c4cc(N(c5ccc6ccccc6c5)c5ccc6ccccc6c5)cc2c43)c1]

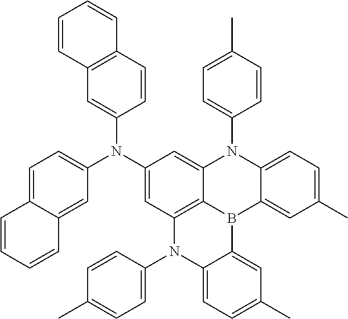 [SMILES: Cc1ccc(N2c3ccc(C)cc3B3c4cc(C)ccc4N(c4ccc(C)cc4)c4cc(N(c5ccc6ccccc6c5)c5ccc6ccccc6c5)cc2c43)cc1]

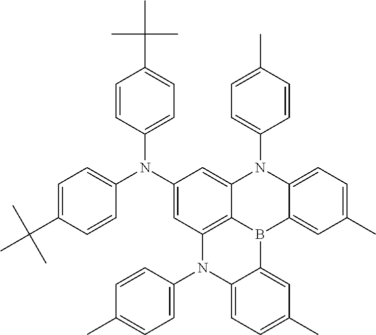 [SMILES: Cc1ccc(N2c3ccc(C)cc3B3c4cc(C)ccc4N(c4ccc(C)cc4)c4cc(N(c5ccc(C(C)(C)C)cc5)c5ccc(C(C)(C)C)cc5)cc2c43)cc1]

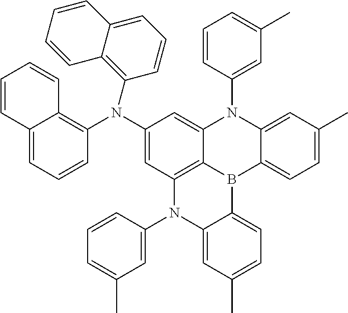 [SMILES: Cc1cccc(N2c3cc(C)ccc3B3c4ccc(C)cc4N(c4cccc(C)c4)c4cc(N(c5cccc6ccccc56)c5cccc6ccccc56)cc2c43)c1]

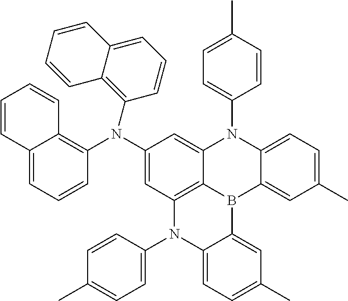 [SMILES: Cc1ccc(N2c3ccc(C)cc3B3c4cc(C)ccc4N(c4ccc(C)cc4)c4cc(N(c5cccc6ccccc56)c5cccc6ccccc56)cc2c43)cc1]

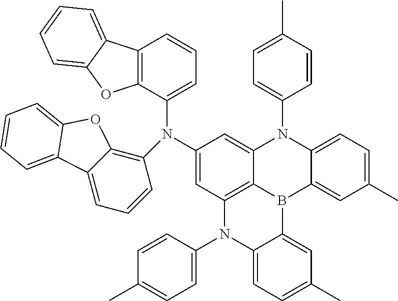 [SMILES: Cc1ccc(N2c3ccc(C)cc3B3c4cc(C)ccc4N(c4ccc(C)cc4)c4cc(N(c5cccc6c5oc5ccccc56)c5cccc6c5oc5ccccc56)cc2c43)cc1]

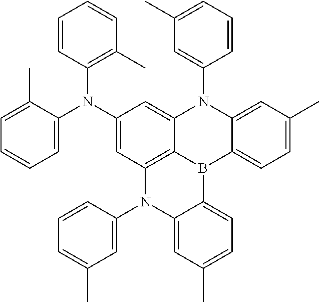 [SMILES: Cc1cccc(N2c3cc(C)ccc3B3c4ccc(C)cc4N(c4cccc(C)c4)c4cc(N(c5ccccc5C)c5ccccc5C)cc2c43)c1]

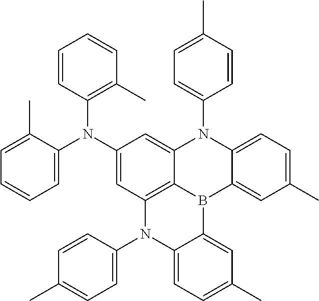 [SMILES: Cc1ccc(N2c3ccc(C)cc3B3c4cc(C)ccc4N(c4ccc(C)cc4)c4cc(N(c5ccccc5C)c5ccccc5C)cc2c43)cc1]

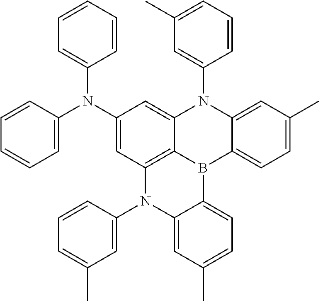 [SMILES: Cc1cccc(N2c3cc(C)ccc3B3c4ccc(C)cc4N(c4cccc(C)c4)c4cc(N(c5ccccc5)c5ccccc5)cc2c43)c1]

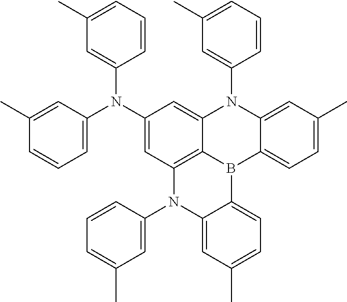

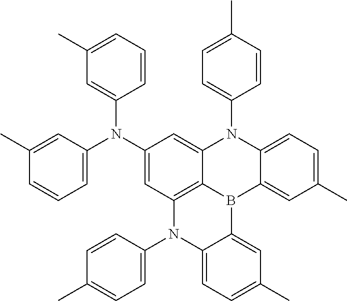

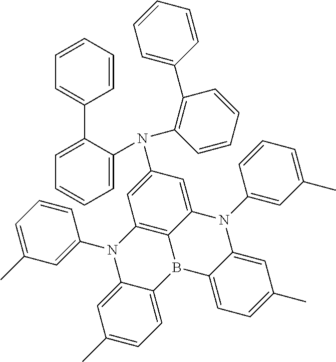

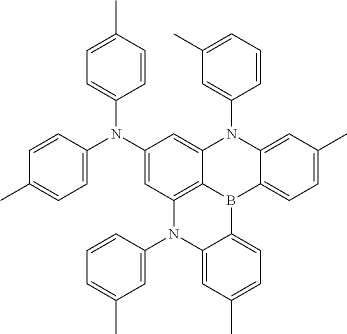

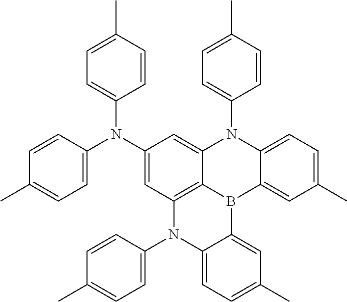

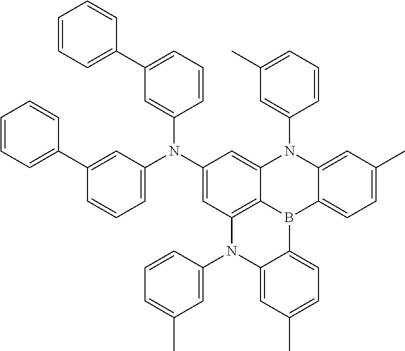 [SMILES: Cc1cccc(N2c3cc(C)ccc3B3c4ccc(C)cc4N(c4cccc(C)c4)c4cc(N(c5cccc(-c6ccccc6)c5)c5cccc(-c6ccccc6)c5)cc2c43)c1]

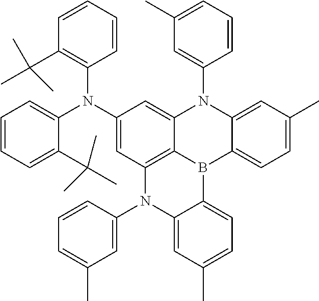 [SMILES: Cc1cccc(N2c3cc(C)ccc3B3c4ccc(C)cc4N(c4cccc(C)c4)c4cc(N(c5ccccc5C(C)(C)C)c5ccccc5C(C)(C)C)cc2c43)c1]

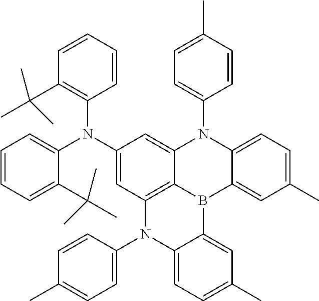 [SMILES: Cc1ccc(N2c3ccc(C)cc3B3c4cc(C)ccc4N(c4ccc(C)cc4)c4cc(N(c5ccccc5C(C)(C)C)c5ccccc5C(C)(C)C)cc2c43)cc1]

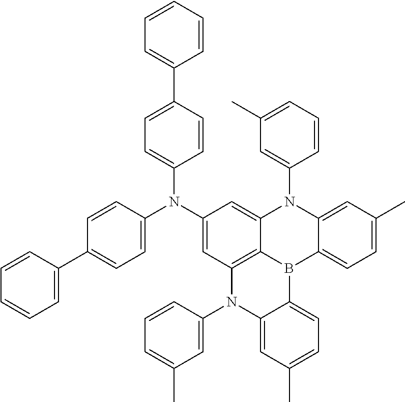 [SMILES: Cc1cccc(N2c3cc(C)ccc3B3c4ccc(C)cc4N(c4cccc(C)c4)c4cc(N(c5ccc(-c6ccccc6)cc5)c5ccc(-c6ccccc6)cc5)cc2c43)c1]

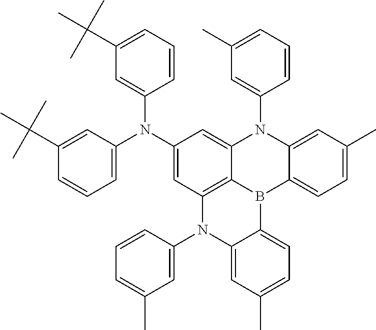 [SMILES: Cc1cccc(N2c3cc(C)ccc3B3c4ccc(C)cc4N(c4cccc(C)c4)c4cc(N(c5cccc(C(C)(C)C)c5)c5cccc(C(C)(C)C)c5)cc2c43)c1]

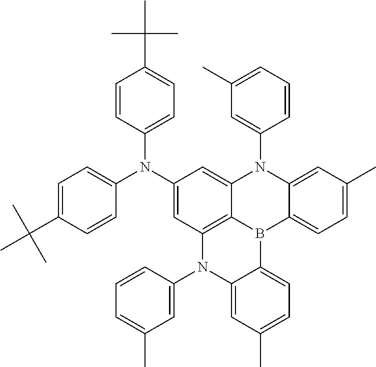 [SMILES: Cc1cccc(N2c3cc(C)ccc3B3c4ccc(C)cc4N(c4cccc(C)c4)c4cc(N(c5ccc(C(C)(C)C)cc5)c5ccc(C(C)(C)C)cc5)cc2c43)c1]

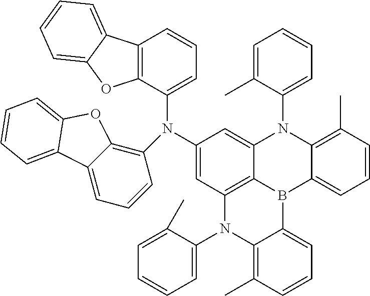 [SMILES: Cc1ccccc1N1c2cc(N(c3cccc4c3oc3ccccc34)c3cccc4c3oc3ccccc34)cc3c2B(c2cccc(C)c21)c1cccc(C)c1N3c1ccccc1C]

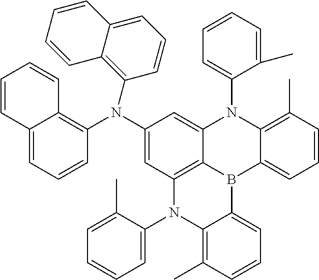 [SMILES: Cc1ccccc1N1c2cc(N(c3cccc4ccccc34)c3cccc4ccccc34)cc3c2B(c2cccc(C)c21)c1cccc(C)c1N3c1ccccc1C]

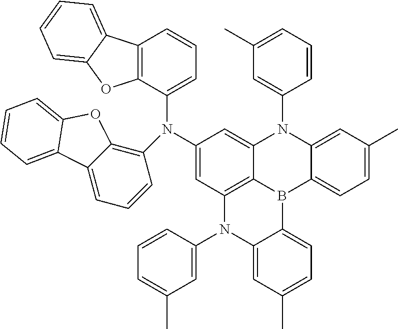 [SMILES: Cc1cccc(N2c3cc(C)ccc3B3c4ccc(C)cc4N(c4cccc(C)c4)c4cc(N(c5cccc6c5oc5ccccc56)c5cccc6c5oc5ccccc56)cc2c43)c1]

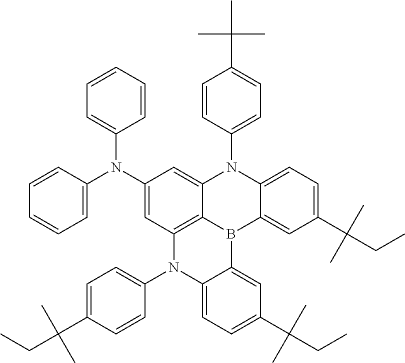 [SMILES: CCC(C)(C)c1ccc(N2c3ccc(C(C)(C)CC)cc3B3c4cc(C(C)(C)CC)ccc4N(c4ccc(C(C)(C)C)cc4)c4cc(N(c5ccccc5)c5ccccc5)cc2c43)cc1]

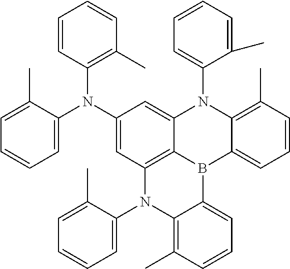 [SMILES: Cc1ccccc1N(c1cc2c3c(c1)N(c1ccccc1C)c1c(C)cccc1B3c1cccc(C)c1N2c1ccccc1C)c1ccccc1C]

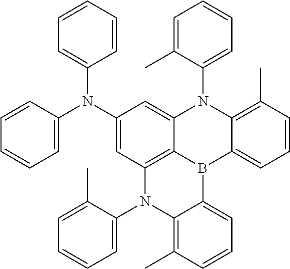 [SMILES: Cc1ccccc1N1c2cc(N(c3ccccc3)c3ccccc3)cc3c2B(c2cccc(C)c21)c1cccc(C)c1N3c1ccccc1C]

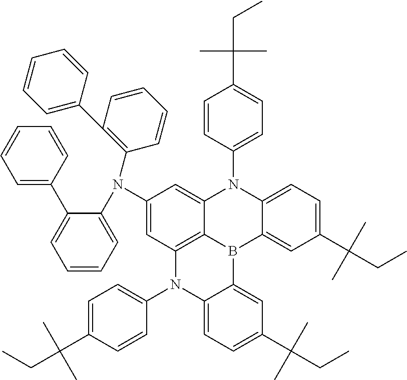 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5-c5ccccc5)c5ccccc5-c5ccccc5)cc2c43)cc1]

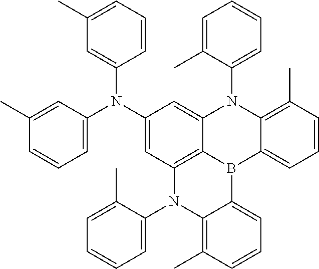 [SMILES: Cc1cccc(N(c2cccc(C)c2)c2cc3c4c(c2)N(c2ccccc2C)c2c(C)cccc2B4c2cccc(C)c2N3c2ccccc2C)c1]

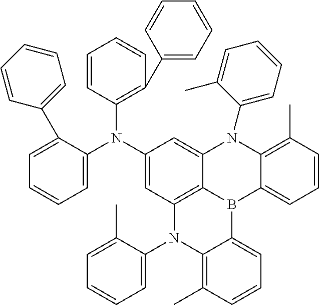 [SMILES: Cc1ccccc1N1c2cc(N(c3ccccc3-c3ccccc3)c3ccccc3-c3ccccc3)cc3c2B(c2cccc(C)c21)c1cccc(C)c1N3c1ccccc1C]

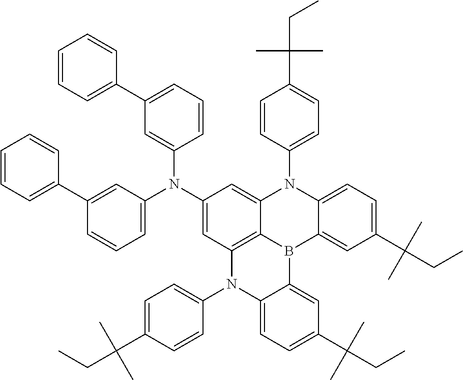 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5cccc(-c6ccccc6)c5)c5cccc(-c6ccccc6)c5)cc2c43)cc1]

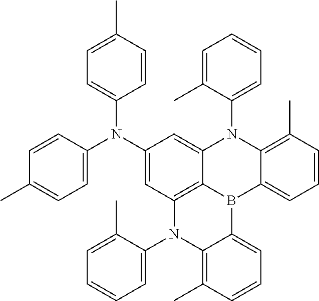 [SMILES: Cc1ccc(N(c2ccc(C)cc2)c2cc3c4c(c2)N(c2ccccc2C)c2c(C)cccc2B4c2cccc(C)c2N3c2ccccc2C)cc1]

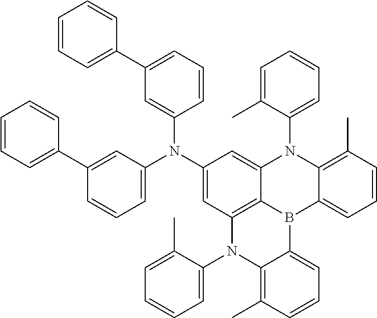 [SMILES: Cc1ccccc1N1c2cc(N(c3cccc(-c4ccccc4)c3)c3cccc(-c4ccccc4)c3)cc3c2B(c2cccc(C)c21)c1cccc(C)c1N3c1ccccc1C]

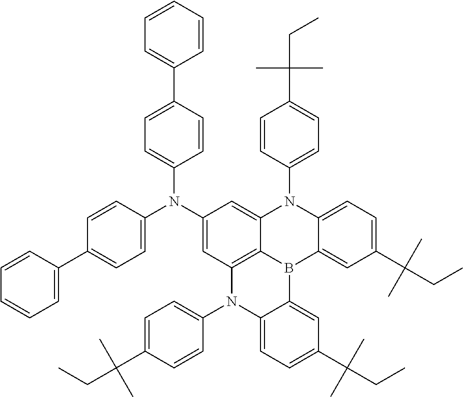 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(-c6ccccc6)cc5)c5ccc(-c6ccccc6)cc5)cc2c43)cc1]

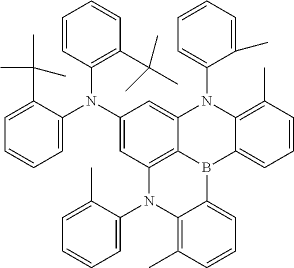 [SMILES: Cc1ccccc1N1c2cc(N(c3ccccc3C(C)(C)C)c3ccccc3C(C)(C)C)cc3c2B(c2cccc(C)c21)c1cccc(C)c1N3c1ccccc1C]

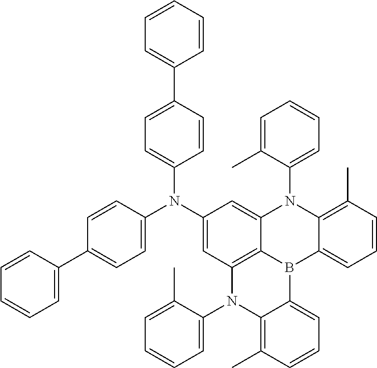 [SMILES: Cc1ccccc1N1c2cc(N(c3ccc(-c4ccccc4)cc3)c3ccc(-c4ccccc4)cc3)cc3c2B(c2cccc(C)c21)c1cccc(C)c1N3c1ccccc1C]

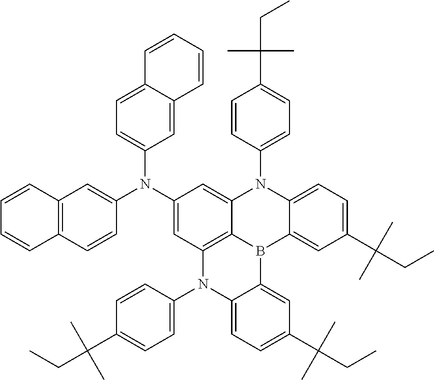 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc6ccccc6c5)c5ccc6ccccc6c5)cc2c43)cc1]

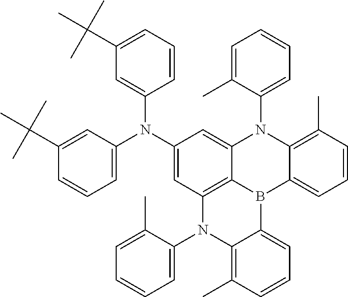 [SMILES: Cc1ccccc1N1c2cc(N(c3cccc(C(C)(C)C)c3)c3cccc(C(C)(C)C)c3)cc3c2B(c2cccc(C)c21)c1cccc(C)c1N3c1ccccc1C]

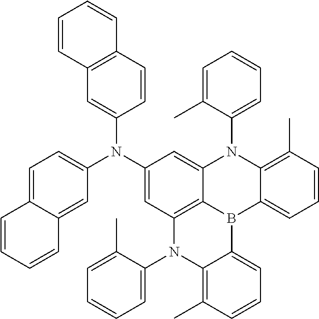 [SMILES: Cc1ccccc1N1c2cc(N(c3ccc4ccccc4c3)c3ccc4ccccc4c3)cc3c2B(c2cccc(C)c21)c1cccc(C)c1N3c1ccccc1C]

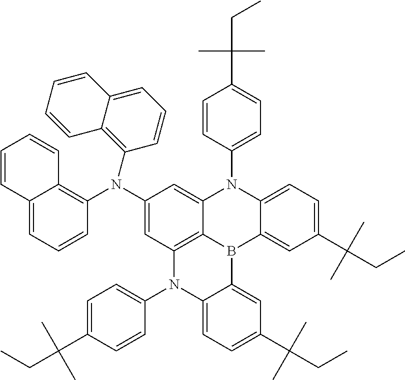 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5cccc6ccccc56)c5cccc6ccccc56)cc2c43)cc1]

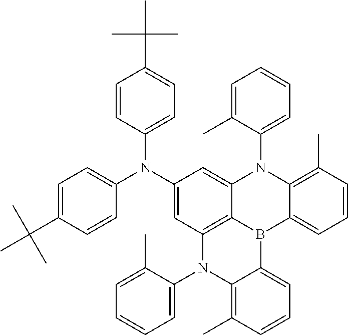 [SMILES: Cc1ccccc1N1c2cc(N(c3ccc(C(C)(C)C)cc3)c3ccc(C(C)(C)C)cc3)cc3c2B(c2cccc(C)c21)c1cccc(C)c1N3c1ccccc1C]

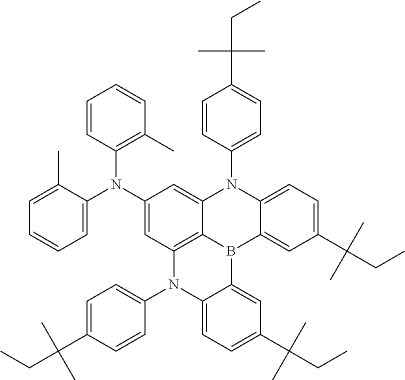 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5C)c5ccccc5C)cc2c43)cc1]

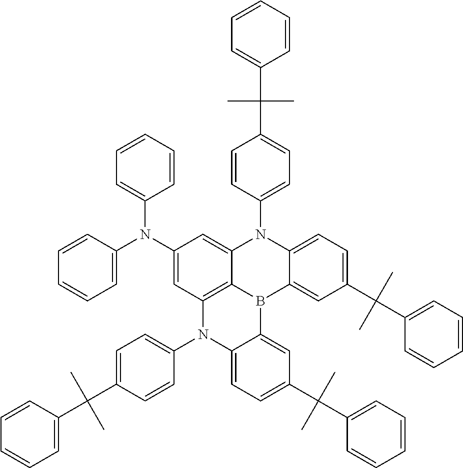 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccccc5)c5ccccc5)cc2c43)cc1]

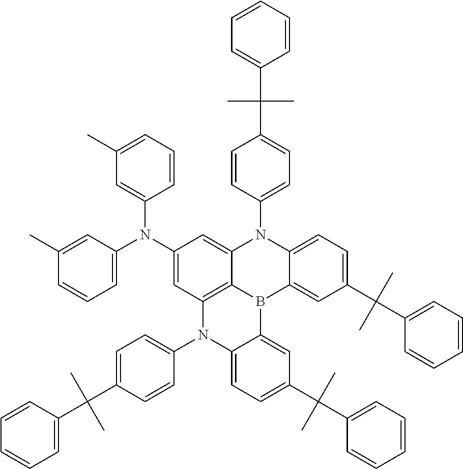 [SMILES: Cc1cccc(N(c2cccc(C)c2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c1]

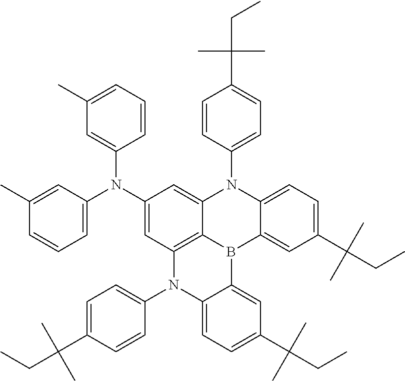 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5cccc(C)c5)c5cccc(C)c5)cc2c43)cc1]

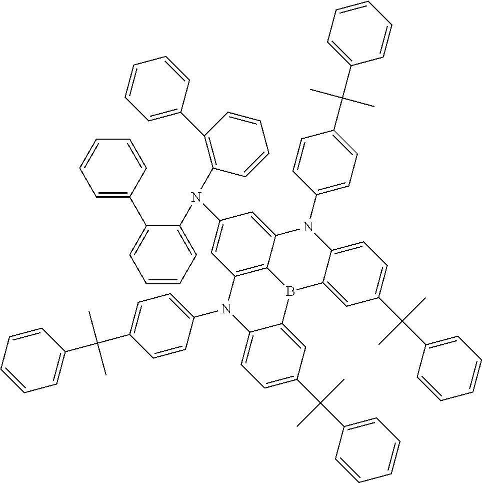 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccccc5-c5ccccc5)c5ccccc5-c5ccccc5)cc2c43)cc1]

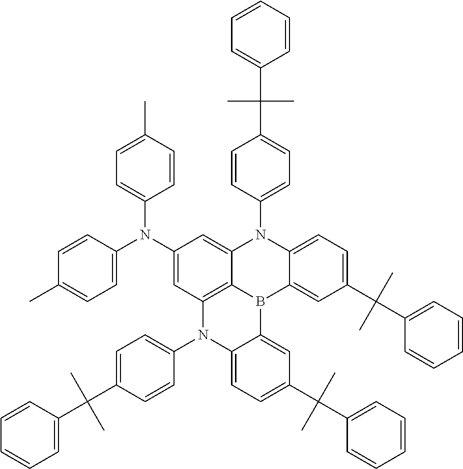 [SMILES: Cc1ccc(N(c2ccc(C)cc2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)cc1]

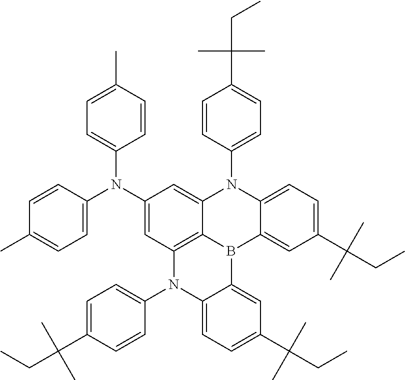 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(C)cc5)c5ccc(C)cc5)cc2c43)cc1]

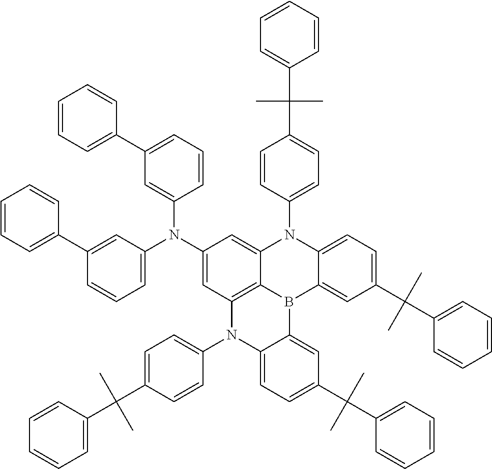 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5cccc(-c6ccccc6)c5)c5cccc(-c6ccccc6)c5)cc2c43)cc1]

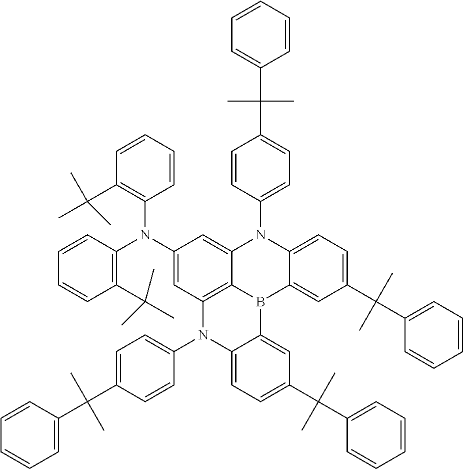 [SMILES: CC(C)(C)c1ccccc1N(c1cc2c3c(c1)N(c1ccc(C(C)(C)c4ccccc4)cc1)c1ccc(C(C)(C)c4ccccc4)cc1B3c1cc(C(C)(C)c3ccccc3)ccc1N2c1ccc(C(C)(C)c2ccccc2)cc1)c1ccccc1C(C)(C)C]

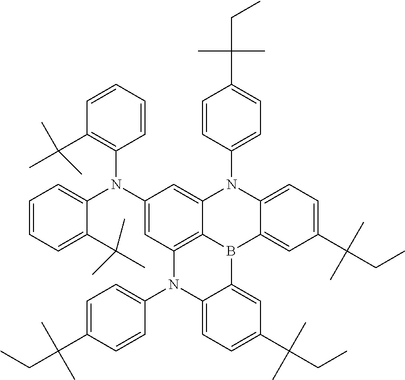 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5C(C)(C)C)c5ccccc5C(C)(C)C)cc2c43)cc1]

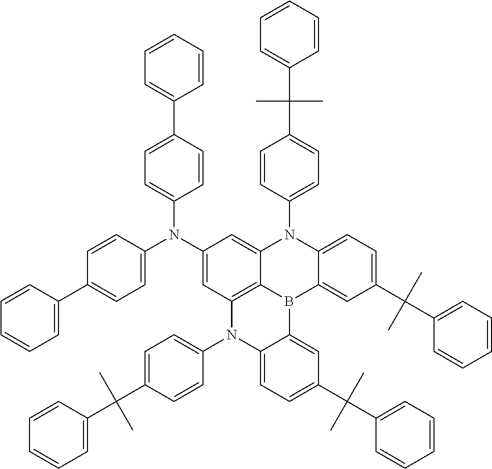 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccc(-c6ccccc6)cc5)c5ccc(-c6ccccc6)cc5)cc2c43)cc1]

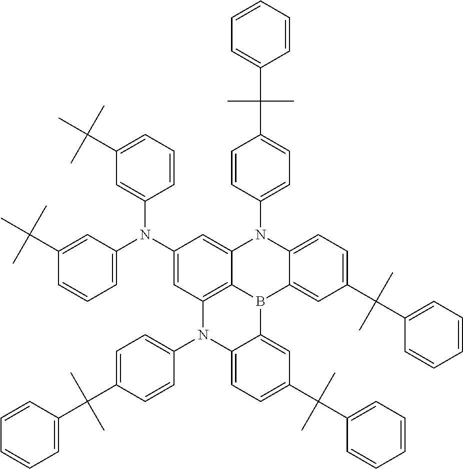 [SMILES: CC(C)(C)c1cccc(N(c2cccc(C(C)(C)C)c2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c1]

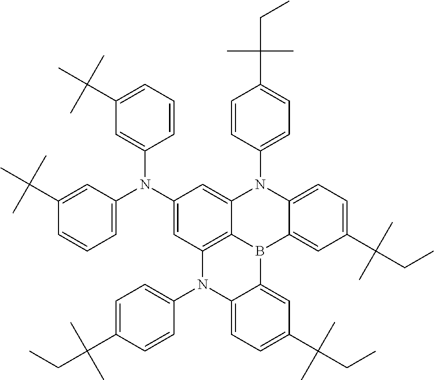 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5cccc(C(C)(C)C)c5)c5cccc(C(C)(C)C)c5)cc2c43)cc1]

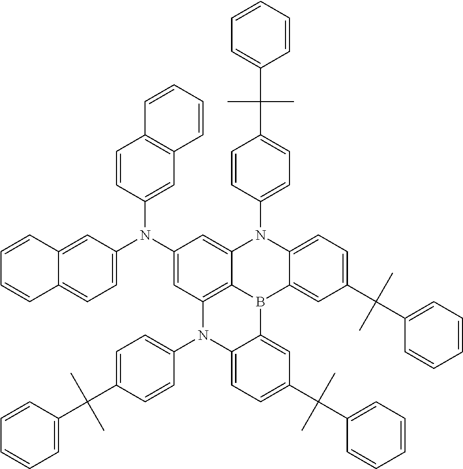 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccc6ccccc6c5)c5ccc6ccccc6c5)cc2c43)cc1]

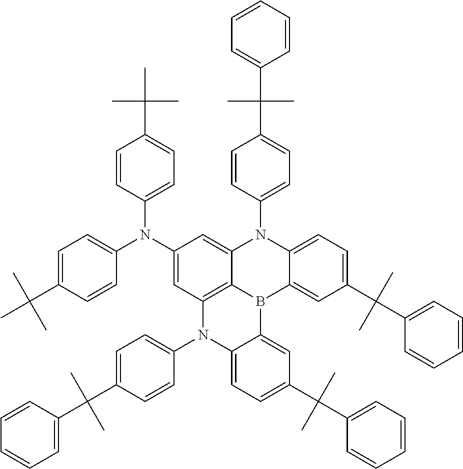 [SMILES: CC(C)(C)c1ccc(N(c2ccc(C(C)(C)C)cc2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)cc1]

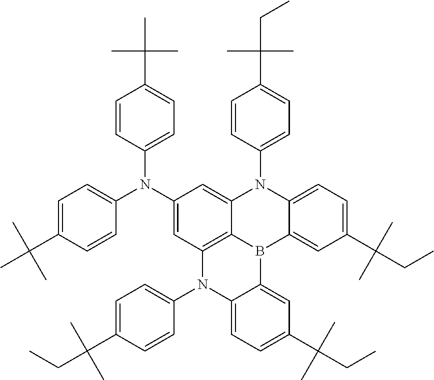 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(C(C)(C)C)cc5)c5ccc(C(C)(C)C)cc5)cc2c43)cc1]

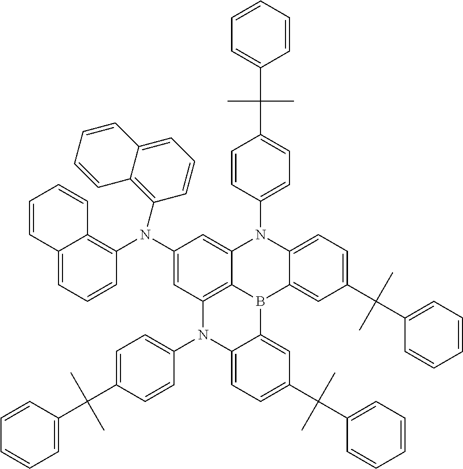 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5cccc6ccccc56)c5cccc6ccccc56)cc2c43)cc1]

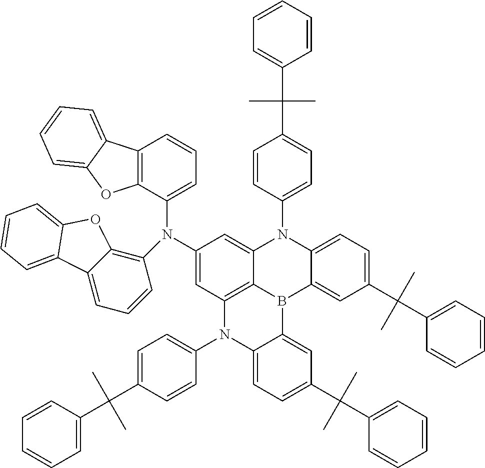 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5cccc6c5oc5ccccc56)c5cccc6c5oc5ccccc56)cc2c43)cc1]

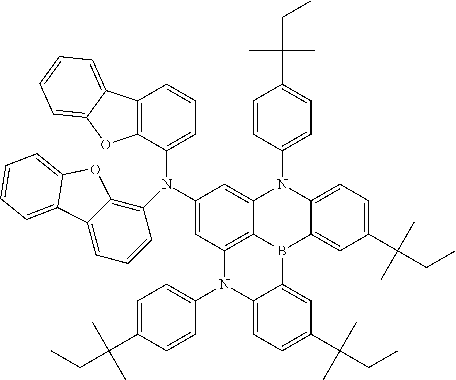 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5cccc6c5oc5ccccc56)c5cccc6c5oc5ccccc56)cc2c43)cc1]

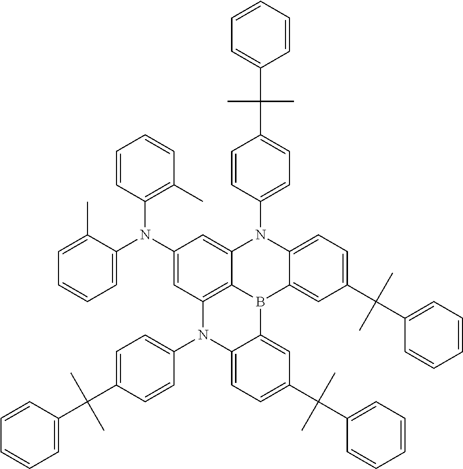 [SMILES: Cc1ccccc1N(c1cc2c3c(c1)N(c1ccc(C(C)(C)c4ccccc4)cc1)c1ccc(C(C)(C)c4ccccc4)cc1B3c1cc(C(C)(C)c3ccccc3)ccc1N2c1ccc(C(C)(C)c2ccccc2)cc1)c1ccccc1C]

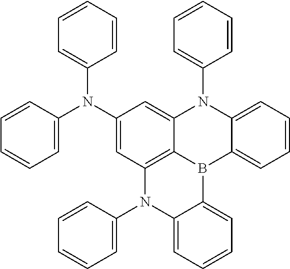 [SMILES: c1ccc(N(c2ccccc2)c2cc3c4c(c2)N(c2ccccc2)c2ccccc2B4c2ccccc2N3c2ccccc2)cc1]

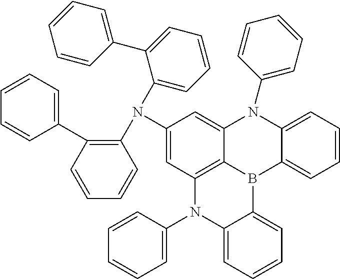 [SMILES: c1ccc(-c2ccccc2N(c2cc3c4c(c2)N(c2ccccc2)c2ccccc2B4c2ccccc2N3c2ccccc2)c2ccccc2-c2ccccc2)cc1]

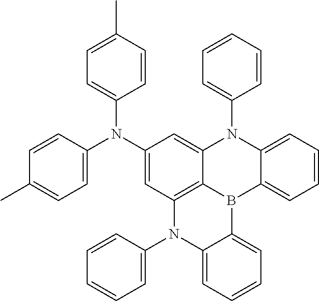 [SMILES: Cc1ccc(N(c2ccc(C)cc2)c2cc3c4c(c2)N(c2ccccc2)c2ccccc2B4c2ccccc2N3c2ccccc2)cc1]

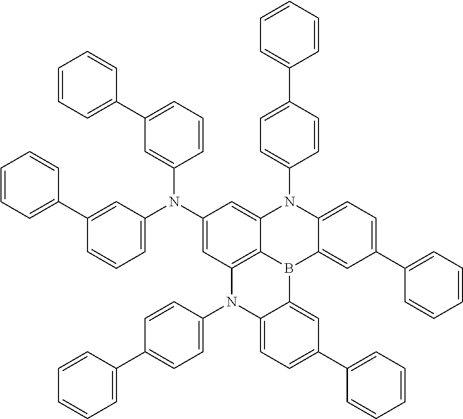 [SMILES: c1ccc(-c2ccc(N3c4ccc(-c5ccccc5)cc4B4c5cc(-c6ccccc6)ccc5N(c5ccc(-c6ccccc6)cc5)c5cc(N(c6cccc(-c7ccccc7)c6)c6cccc(-c7ccccc7)c6)cc3c54)cc2)cc1]

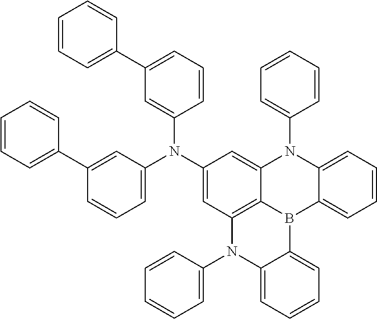 [SMILES: c1ccc(-c2cccc(N(c3cccc(-c4ccccc4)c3)c3cc4c5c(c3)N(c3ccccc3)c3ccccc3B5c3ccccc3N4c3ccccc3)c2)cc1]

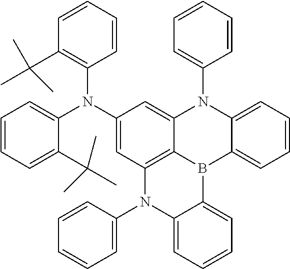 [SMILES: CC(C)(C)c1ccccc1N(c1cc2c3c(c1)N(c1ccccc1)c1ccccc1B3c1ccccc1N2c1ccccc1)c1ccccc1C(C)(C)C]

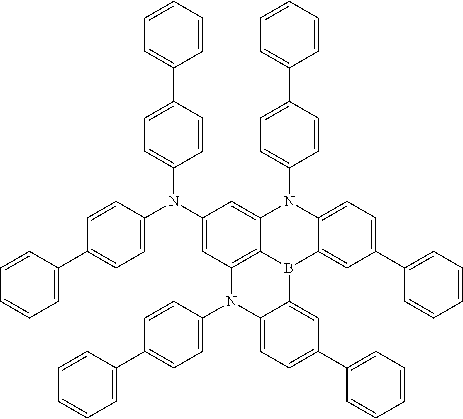 [SMILES: c1ccc(-c2ccc(N(c3ccc(-c4ccccc4)cc3)c3cc4c5c(c3)N(c3ccc(-c6ccccc6)cc3)c3ccc(-c6ccccc6)cc3B5c3cc(-c5ccccc5)ccc3N4c3ccc(-c4ccccc4)cc3)cc2)cc1]

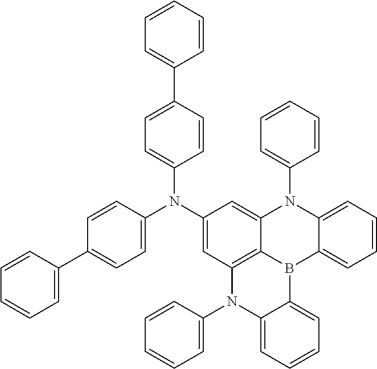 [SMILES: c1ccc(-c2ccc(N(c3ccc(-c4ccccc4)cc3)c3cc4c5c(c3)N(c3ccccc3)c3ccccc3B5c3ccccc3N4c3ccccc3)cc2)cc1]

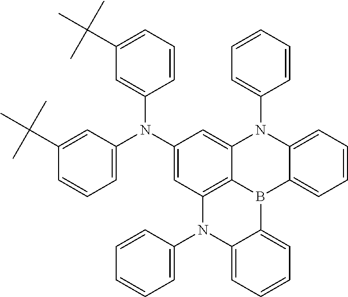 [SMILES: CC(C)(C)c1cccc(N(c2cccc(C(C)(C)C)c2)c2cc3c4c(c2)N(c2ccccc2)c2ccccc2B4c2ccccc2N3c2ccccc2)c1]

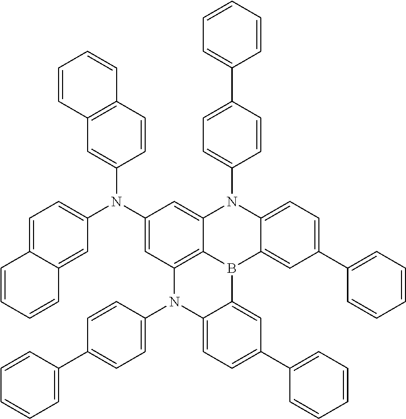 [SMILES: c1ccc(-c2ccc(N3c4ccc(-c5ccccc5)cc4B4c5cc(-c6ccccc6)ccc5N(c5ccc(-c6ccccc6)cc5)c5cc(N(c6ccc7ccccc7c6)c6ccc7ccccc7c6)cc3c54)cc2)cc1]

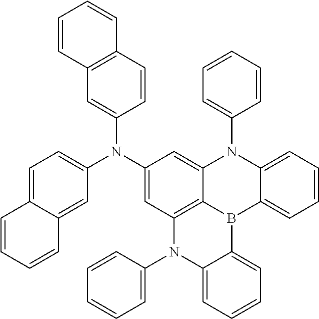 [SMILES: c1ccc(N2c3ccccc3B3c4ccccc4N(c4ccccc4)c4cc(N(c5ccc6ccccc6c5)c5ccc6ccccc6c5)cc2c43)cc1]

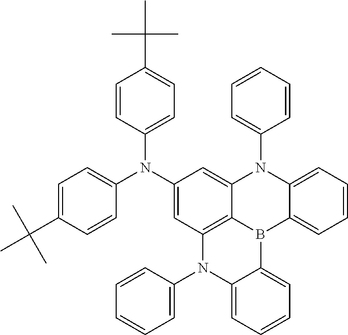 [SMILES: CC(C)(C)c1ccc(N(c2ccc(C(C)(C)C)cc2)c2cc3c4c(c2)N(c2ccccc2)c2ccccc2B4c2ccccc2N3c2ccccc2)cc1]

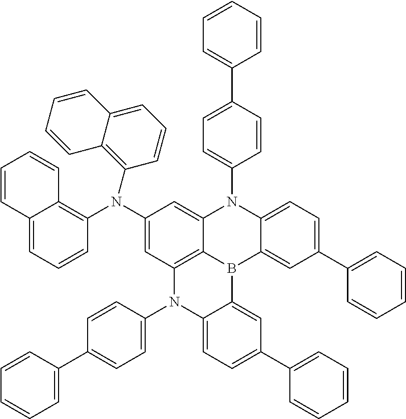 [SMILES: c1ccc(-c2ccc(N3c4ccc(-c5ccccc5)cc4B4c5cc(-c6ccccc6)ccc5N(c5ccc(-c6ccccc6)cc5)c5cc(N(c6cccc7ccccc67)c6cccc7ccccc67)cc3c54)cc2)cc1]

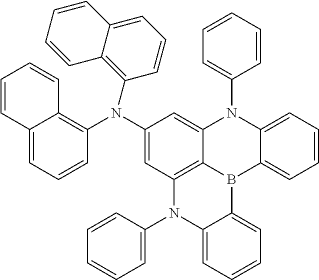 [SMILES: c1ccc(N2c3ccccc3B3c4ccccc4N(c4ccccc4)c4cc(N(c5cccc6ccccc56)c5cccc6ccccc56)cc2c43)cc1]

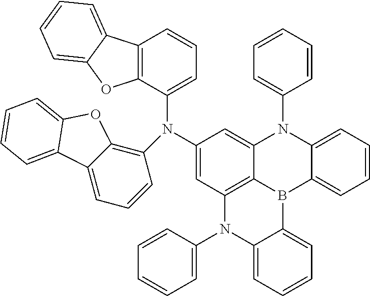 [SMILES: c1ccc(N2c3ccccc3B3c4ccccc4N(c4ccccc4)c4cc(N(c5cccc6c5oc5ccccc56)c5cccc6c5oc5ccccc56)cc2c43)cc1]

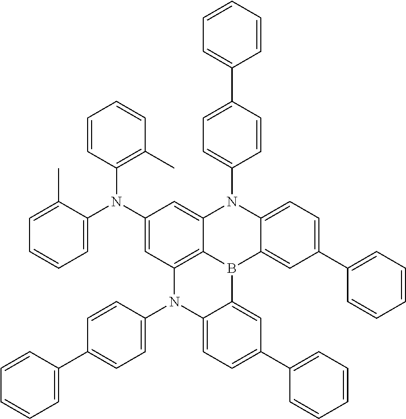 [SMILES: Cc1ccccc1N(c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1)c1ccccc1C]

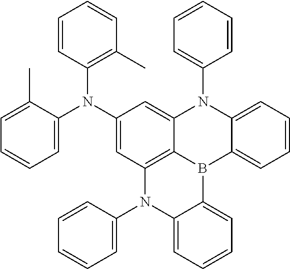 [SMILES: Cc1ccccc1N(c1cc2c3c(c1)N(c1ccccc1)c1ccccc1B3c1ccccc1N2c1ccccc1)c1ccccc1C]

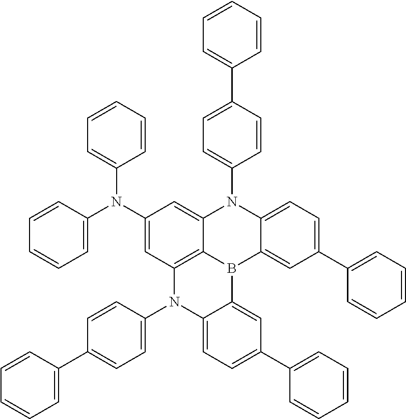 [SMILES: c1ccc(-c2ccc(N3c4ccc(-c5ccccc5)cc4B4c5cc(-c6ccccc6)ccc5N(c5ccc(-c6ccccc6)cc5)c5cc(N(c6ccccc6)c6ccccc6)cc3c54)cc2)cc1]

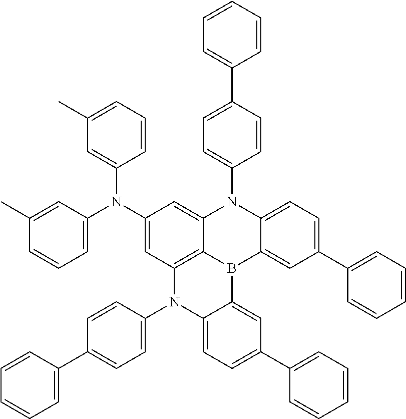 [SMILES: Cc1cccc(N(c2cccc(C)c2)c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)c1]

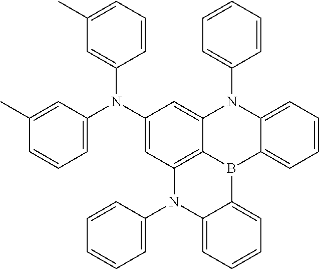 [SMILES: Cc1cccc(N(c2cccc(C)c2)c2cc3c4c(c2)N(c2ccccc2)c2ccccc2B4c2ccccc2N3c2ccccc2)c1]

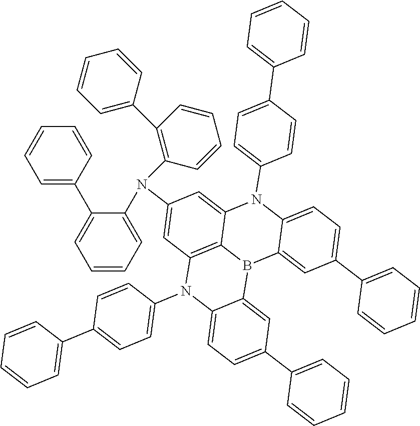 [SMILES: c1ccc(-c2ccc(N3c4ccc(-c5ccccc5)cc4B4c5cc(-c6ccccc6)ccc5N(c5ccc(-c6ccccc6)cc5)c5cc(N(c6ccccc6-c6ccccc6)c6ccccc6-c6ccccc6)cc3c54)cc2)cc1]

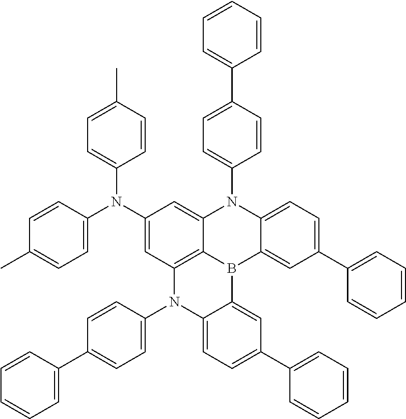 [SMILES: Cc1ccc(N(c2ccc(C)cc2)c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)cc1]

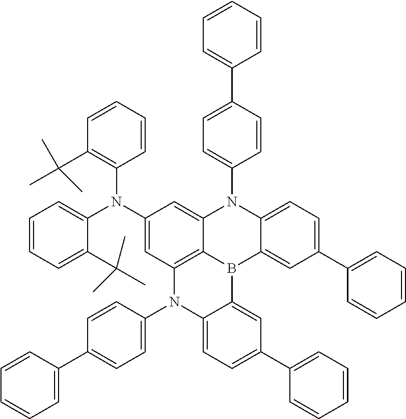 [SMILES: CC(C)(C)c1ccccc1N(c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1)c1ccccc1C(C)(C)C]

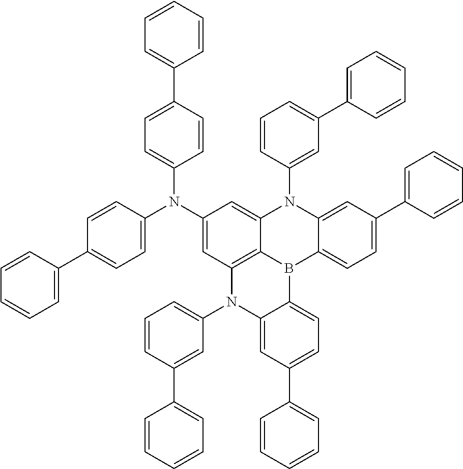 [SMILES: c1ccc(-c2ccc(N(c3ccc(-c4ccccc4)cc3)c3cc4c5c(c3)N(c3cccc(-c6ccccc6)c3)c3cc(-c6ccccc6)ccc3B5c3ccc(-c5ccccc5)cc3N4c3cccc(-c4ccccc4)c3)cc2)cc1]

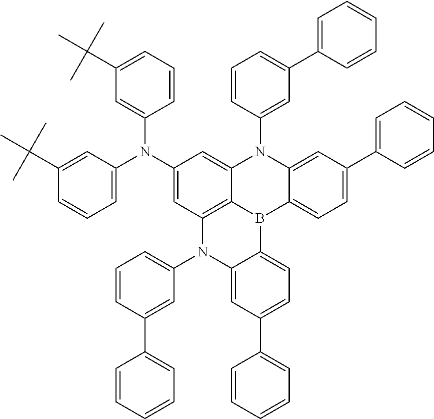 [SMILES: CC(C)(C)c1cccc(N(c2cccc(C(C)(C)C)c2)c2cc3c4c(c2)N(c2cccc(-c5ccccc5)c2)c2cc(-c5ccccc5)ccc2B4c2ccc(-c4ccccc4)cc2N3c2cccc(-c3ccccc3)c2)c1]

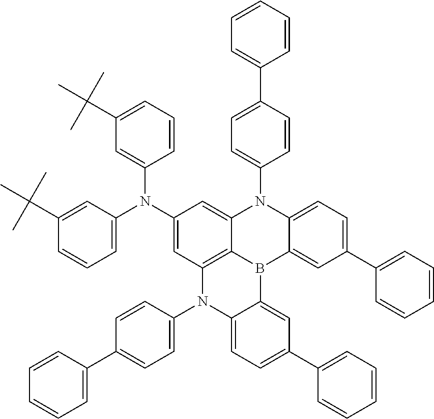 [SMILES: CC(C)(C)c1cccc(N(c2cccc(C(C)(C)C)c2)c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)c1]

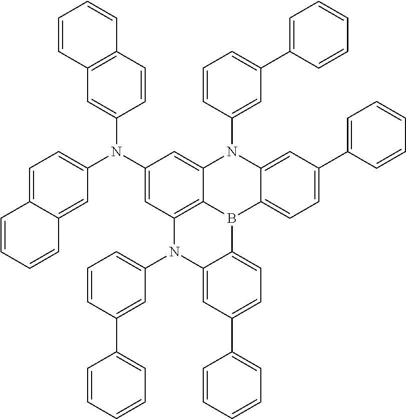 [SMILES: c1ccc(-c2cccc(N3c4cc(-c5ccccc5)ccc4B4c5ccc(-c6ccccc6)cc5N(c5cccc(-c6ccccc6)c5)c5cc(N(c6ccc7ccccc7c6)c6ccc7ccccc7c6)cc3c54)c2)cc1]

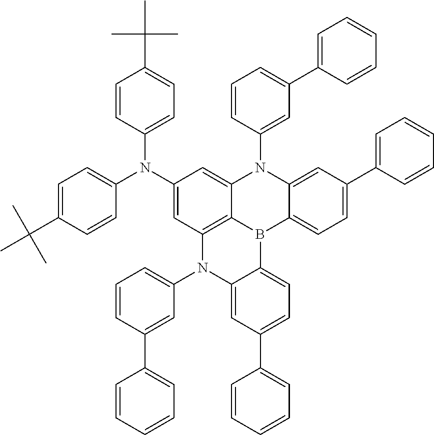 [SMILES: CC(C)(C)c1ccc(N(c2ccc(C(C)(C)C)cc2)c2cc3c4c(c2)N(c2cccc(-c5ccccc5)c2)c2cc(-c5ccccc5)ccc2B4c2ccc(-c4ccccc4)cc2N3c2cccc(-c3ccccc3)c2)cc1]

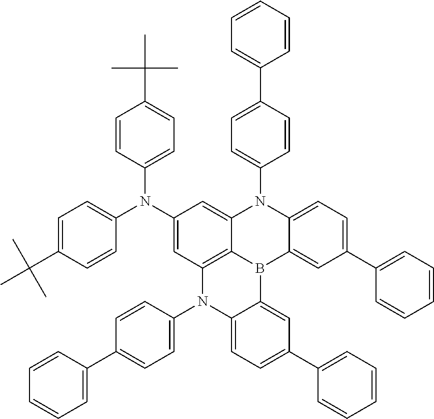 [SMILES: CC(C)(C)c1ccc(N(c2ccc(C(C)(C)C)cc2)c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)cc1]

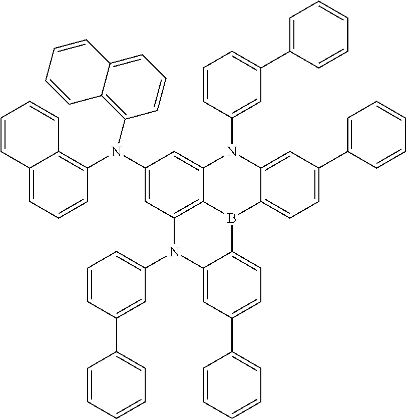 [SMILES: c1ccc(-c2cccc(N3c4cc(-c5ccccc5)ccc4B4c5ccc(-c6ccccc6)cc5N(c5cccc(-c6ccccc6)c5)c5cc(N(c6cccc7ccccc67)c6cccc7ccccc67)cc3c54)c2)cc1]

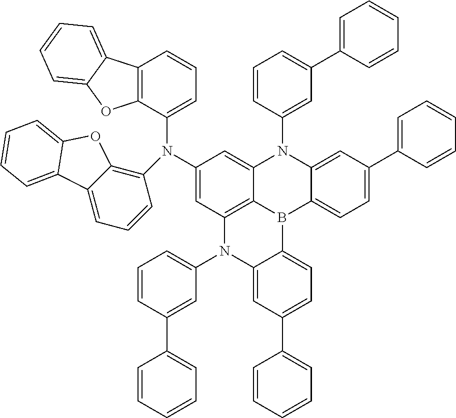 [SMILES: c1ccc(-c2cccc(N3c4cc(-c5ccccc5)ccc4B4c5ccc(-c6ccccc6)cc5N(c5cccc(-c6ccccc6)c5)c5cc(N(c6cccc7c6oc6ccccc67)c6cccc7c6oc6ccccc67)cc3c54)c2)cc1]

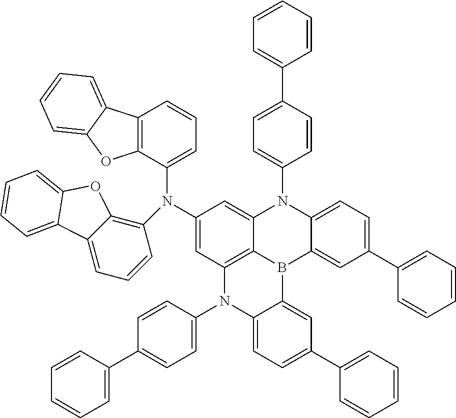 [SMILES: c1ccc(-c2ccc(N3c4ccc(-c5ccccc5)cc4B4c5cc(-c6ccccc6)ccc5N(c5ccc(-c6ccccc6)cc5)c5cc(N(c6cccc7c6oc6ccccc67)c6cccc7c6oc6ccccc67)cc3c54)cc2)cc1]

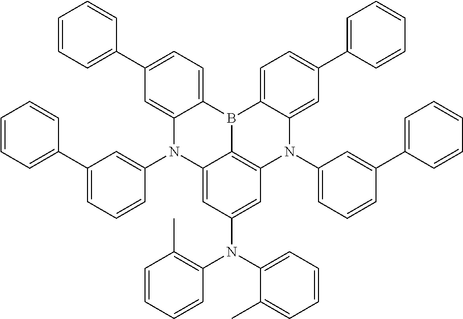 [SMILES: Cc1ccccc1N(c1cc2c3c(c1)N(c1cccc(-c4ccccc4)c1)c1cc(-c4ccccc4)ccc1B3c1ccc(-c3ccccc3)cc1N2c1cccc(-c2ccccc2)c1)c1ccccc1C]

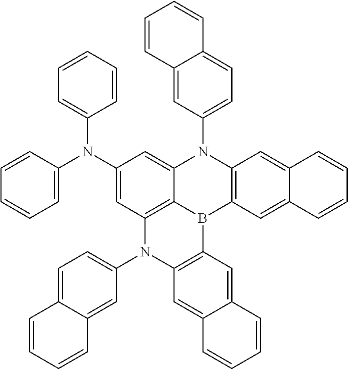 [SMILES: c1ccc(N(c2ccccc2)c2cc3c4c(c2)N(c2ccc5ccccc5c2)c2cc5ccccc5cc2B4c2cc4ccccc4cc2N3c2ccc3ccccc3c2)cc1]

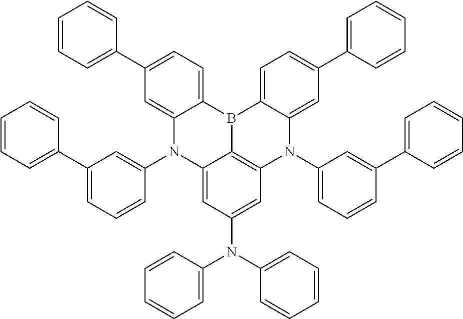 [SMILES: c1ccc(-c2cccc(N3c4cc(-c5ccccc5)ccc4B4c5ccc(-c6ccccc6)cc5N(c5cccc(-c6ccccc6)c5)c5cc(N(c6ccccc6)c6ccccc6)cc3c54)c2)cc1]

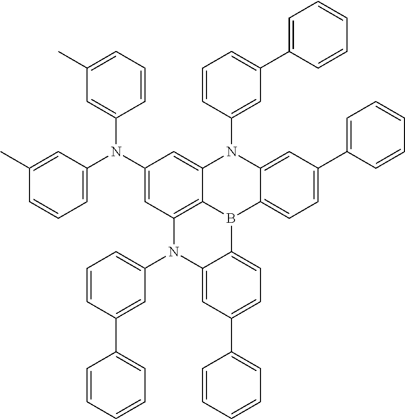 [SMILES: Cc1cccc(N(c2cccc(C)c2)c2cc3c4c(c2)N(c2cccc(-c5ccccc5)c2)c2cc(-c5ccccc5)ccc2B4c2ccc(-c4ccccc4)cc2N3c2cccc(-c3ccccc3)c2)c1]

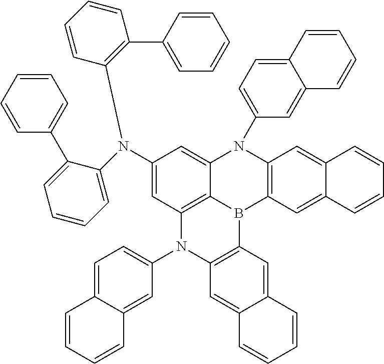 [SMILES: c1ccc(-c2ccccc2N(c2cc3c4c(c2)N(c2ccc5ccccc5c2)c2cc5ccccc5cc2B4c2cc4ccccc4cc2N3c2ccc3ccccc3c2)c2ccccc2-c2ccccc2)cc1]

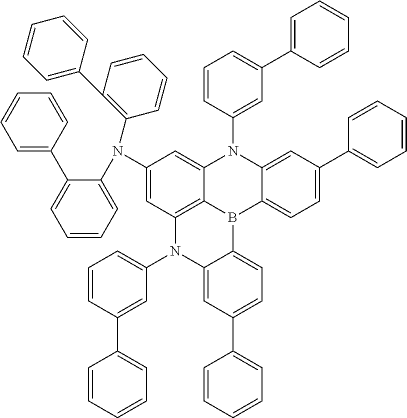 [SMILES: c1ccc(-c2cccc(N3c4cc(-c5ccccc5)ccc4B4c5ccc(-c6ccccc6)cc5N(c5cccc(-c6ccccc6)c5)c5cc(N(c6ccccc6-c6ccccc6)c6ccccc6-c6ccccc6)cc3c54)c2)cc1]

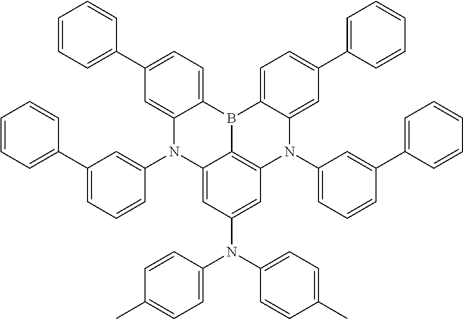 [SMILES: Cc1ccc(N(c2ccc(C)cc2)c2cc3c4c(c2)N(c2cccc(-c5ccccc5)c2)c2cc(-c5ccccc5)ccc2B4c2ccc(-c4ccccc4)cc2N3c2cccc(-c3ccccc3)c2)cc1]

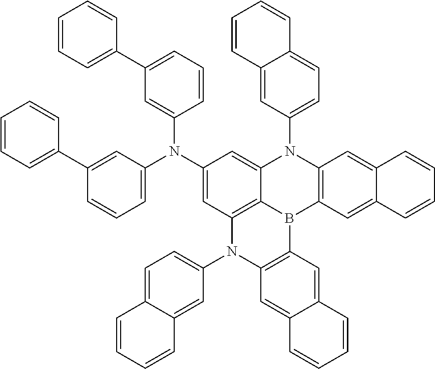 [SMILES: c1ccc(-c2cccc(N(c3cccc(-c4ccccc4)c3)c3cc4c5c(c3)N(c3ccc6ccccc6c3)c3cc6ccccc6cc3B5c3cc5ccccc5cc3N4c3ccc4ccccc4c3)c2)cc1]

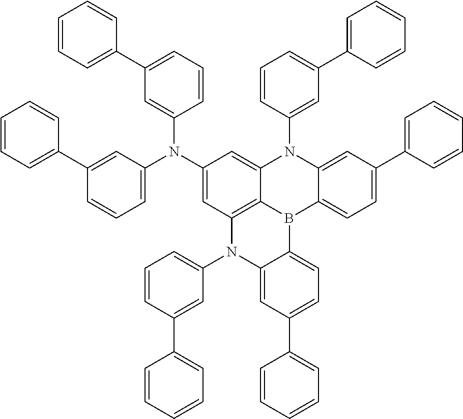 [SMILES: c1ccc(-c2cccc(N(c3cccc(-c4ccccc4)c3)c3cc4c5c(c3)N(c3cccc(-c6ccccc6)c3)c3cc(-c6ccccc6)ccc3B5c3ccc(-c5ccccc5)cc3N4c3cccc(-c4ccccc4)c3)c2)cc1]

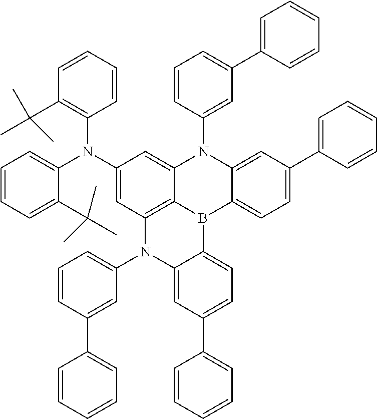 [SMILES: CC(C)(C)c1ccccc1N(c1cc2c3c(c1)N(c1cccc(-c4ccccc4)c1)c1cc(-c4ccccc4)ccc1B3c1ccc(-c3ccccc3)cc1N2c1cccc(-c2ccccc2)c1)c1ccccc1C(C)(C)C]

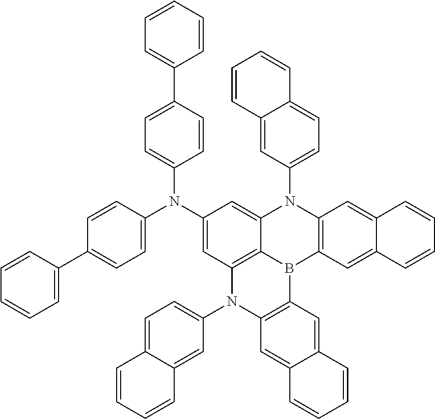 [SMILES: c1ccc(-c2ccc(N(c3ccc(-c4ccccc4)cc3)c3cc4c5c(c3)N(c3ccc6ccccc6c3)c3cc6ccccc6cc3B5c3cc5ccccc5cc3N4c3ccc4ccccc4c3)cc2)cc1]

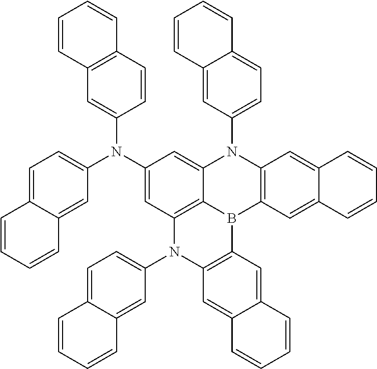 [SMILES: c1ccc2cc(N(c3cc4c5c(c3)N(c3ccc6ccccc6c3)c3cc6ccccc6cc3B5c3cc5ccccc5cc3N4c3ccc4ccccc4c3)c3ccc4ccccc4c3)ccc2c1]

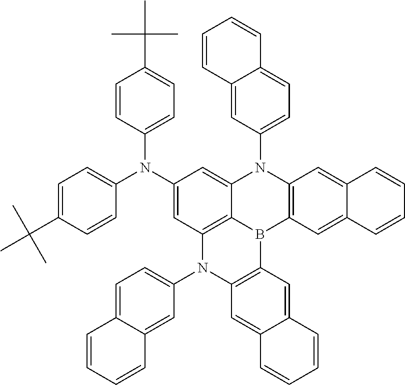 [SMILES: CC(C)(C)c1ccc(N(c2ccc(C(C)(C)C)cc2)c2cc3c4c(c2)N(c2ccc5ccccc5c2)c2cc5ccccc5cc2B4c2cc4ccccc4cc2N3c2ccc3ccccc3c2)cc1]

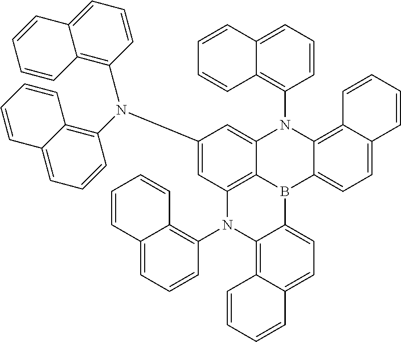 [SMILES: c1ccc2c(N(c3cc4c5c(c3)N(c3cccc6ccccc36)c3c(ccc6ccccc36)B5c3ccc5ccccc5c3N4c3cccc4ccccc34)c3cccc4ccccc34)cccc2c1]

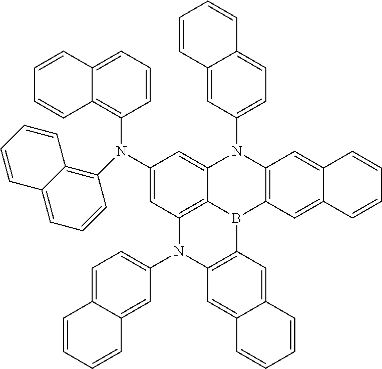 [SMILES: c1ccc2cc(N3c4cc5ccccc5cc4B4c5cc6ccccc6cc5N(c5ccc6ccccc6c5)c5cc(N(c6cccc7ccccc67)c6cccc7ccccc67)cc3c54)ccc2c1]

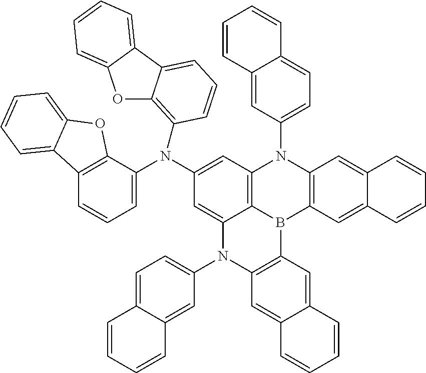 [SMILES: c1ccc2cc(N3c4cc5ccccc5cc4B4c5cc6ccccc6cc5N(c5ccc6ccccc6c5)c5cc(N(c6cccc7c6oc6ccccc67)c6cccc7c6oc6ccccc67)cc3c54)ccc2c1]

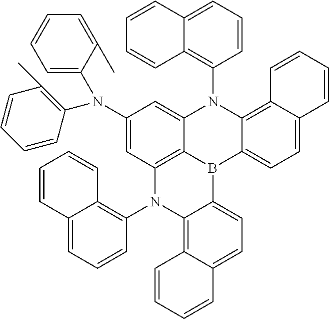 [SMILES: Cc1ccccc1N(c1cc2c3c(c1)N(c1cccc4ccccc14)c1c(ccc4ccccc14)B3c1ccc3ccccc3c1N2c1cccc2ccccc12)c1ccccc1C]

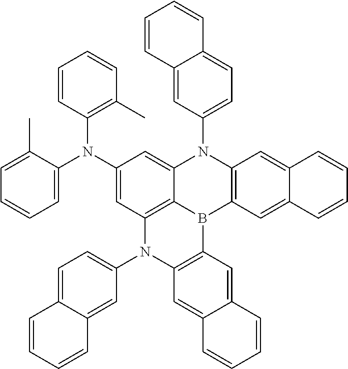 [SMILES: Cc1ccccc1N(c1cc2c3c(c1)N(c1ccc4ccccc4c1)c1cc4ccccc4cc1B3c1cc3ccccc3cc1N2c1ccc2ccccc2c1)c1ccccc1C]

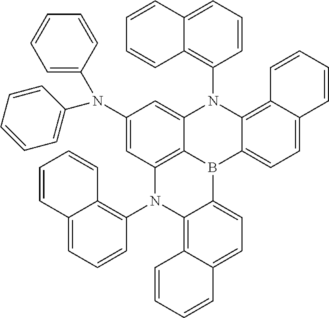 [SMILES: c1ccc(N(c2ccccc2)c2cc3c4c(c2)N(c2cccc5ccccc25)c2c(ccc5ccccc25)B4c2ccc4ccccc4c2N3c2cccc3ccccc23)cc1]

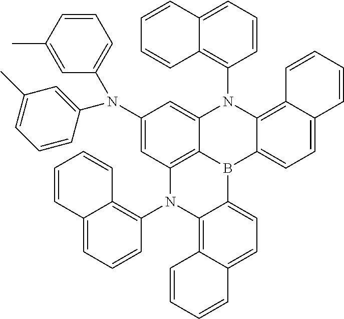 [SMILES: Cc1cccc(N(c2cccc(C)c2)c2cc3c4c(c2)N(c2cccc5ccccc25)c2c(ccc5ccccc25)B4c2ccc4ccccc4c2N3c2cccc3ccccc23)c1]

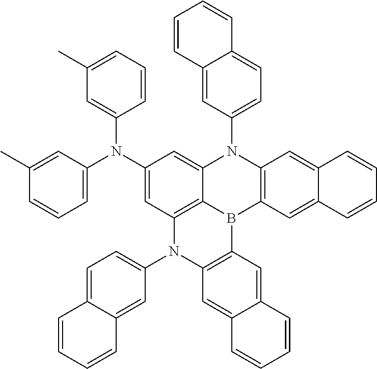 [SMILES: Cc1cccc(N(c2cccc(C)c2)c2cc3c4c(c2)N(c2ccc5ccccc5c2)c2cc5ccccc5cc2B4c2cc4ccccc4cc2N3c2ccc3ccccc3c2)c1]

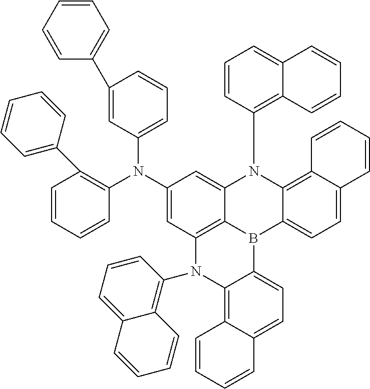 [SMILES: c1ccc(-c2cccc(N(c3cc4c5c(c3)N(c3cccc6ccccc36)c3c(ccc6ccccc36)B5c3ccc5ccccc5c3N4c3cccc4ccccc34)c3ccccc3-c3ccccc3)c2)cc1]

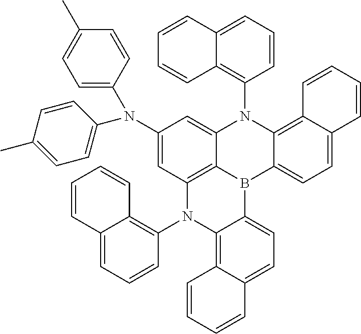 [SMILES: Cc1ccc(N(c2ccc(C)cc2)c2cc3c4c(c2)N(c2cccc5ccccc25)c2c(ccc5ccccc25)B4c2ccc4ccccc4c2N3c2cccc3ccccc23)cc1]

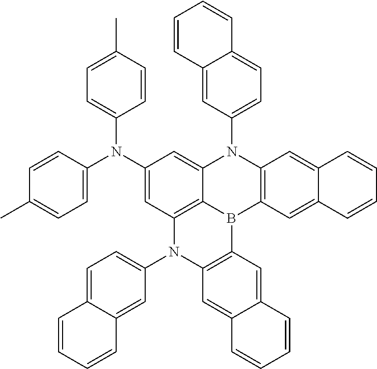 [SMILES: Cc1ccc(N(c2ccc(C)cc2)c2cc3c4c(c2)N(c2ccc5ccccc5c2)c2cc5ccccc5cc2B4c2cc4ccccc4cc2N3c2ccc3ccccc3c2)cc1]

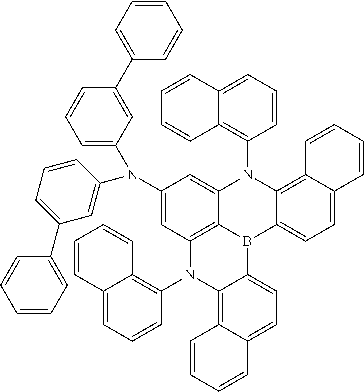 [SMILES: c1ccc(-c2cccc(N(c3cccc(-c4ccccc4)c3)c3cc4c5c(c3)N(c3cccc6ccccc36)c3c(ccc6ccccc36)B5c3ccc5ccccc5c3N4c3cccc4ccccc34)c2)cc1]

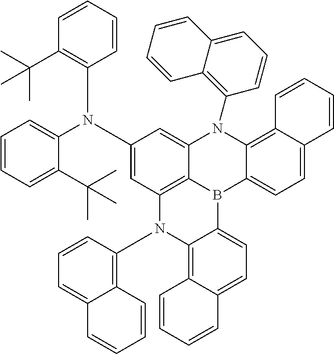 [SMILES: CC(C)(C)c1ccccc1N(c1cc2c3c(c1)N(c1cccc4ccccc14)c1c(ccc4ccccc14)B3c1ccc3ccccc3c1N2c1cccc2ccccc12)c1ccccc1C(C)(C)C]

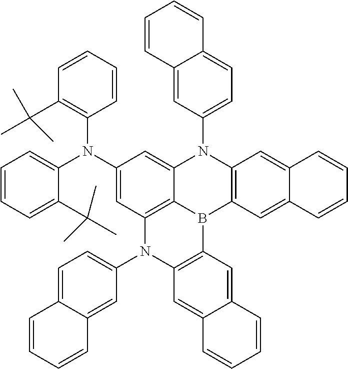 [SMILES: CC(C)(C)c1ccccc1N(c1cc2c3c(c1)N(c1ccc4ccccc4c1)c1cc4ccccc4cc1B3c1cc3ccccc3cc1N2c1ccc2ccccc2c1)c1ccccc1C(C)(C)C]

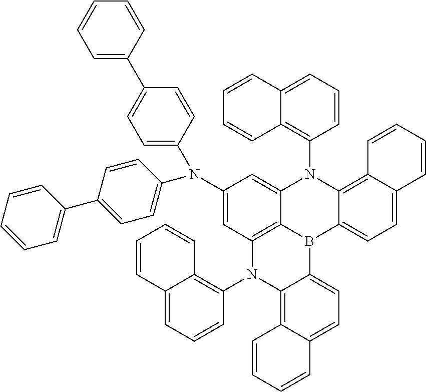 [SMILES: c1ccc(-c2ccc(N(c3ccc(-c4ccccc4)cc3)c3cc4c5c(c3)N(c3cccc6ccccc36)c3c(ccc6ccccc36)B5c3ccc5ccccc5c3N4c3cccc4ccccc34)cc2)cc1]

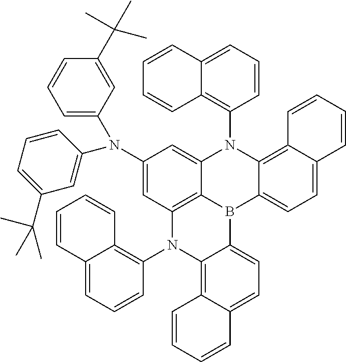 [SMILES: CC(C)(C)c1cccc(N(c2cccc(C(C)(C)C)c2)c2cc3c4c(c2)N(c2cccc5ccccc25)c2c(ccc5ccccc25)B4c2ccc4ccccc4c2N3c2cccc3ccccc23)c1]

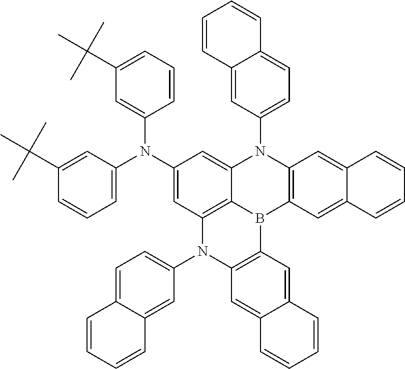 [SMILES: CC(C)(C)c1cccc(N(c2cccc(C(C)(C)C)c2)c2cc3c4c(c2)N(c2ccc5ccccc5c2)c2cc5ccccc5cc2B4c2cc4ccccc4cc2N3c2ccc3ccccc3c2)c1]

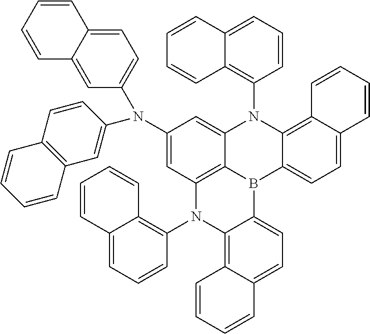 [SMILES: c1ccc2cc(N(c3cc4c5c(c3)N(c3cccc6ccccc36)c3c(ccc6ccccc36)B5c3ccc5ccccc5c3N4c3cccc4ccccc34)c3ccc4ccccc4c3)ccc2c1]

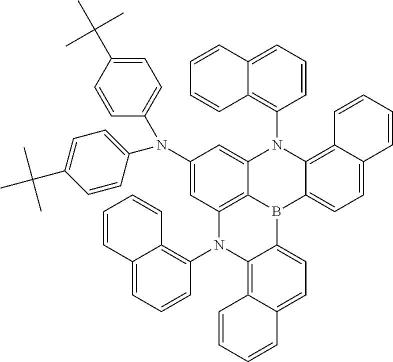 [SMILES: CC(C)(C)c1ccc(N(c2ccc(C(C)(C)C)cc2)c2cc3c4c(c2)N(c2cccc5ccccc25)c2c(ccc5ccccc25)B4c2ccc4ccccc4c2N3c2cccc3ccccc23)cc1]

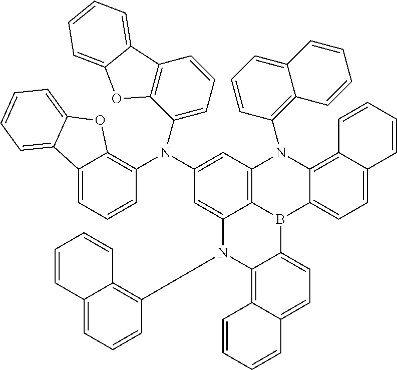 [SMILES: c1ccc2c(N3c4cc(N(c5cccc6c5oc5ccccc56)c5cccc6c5oc5ccccc56)cc5c4B(c4ccc6ccccc6c43)c3ccc4ccccc4c3N5c3cccc4ccccc34)cccc2c1]

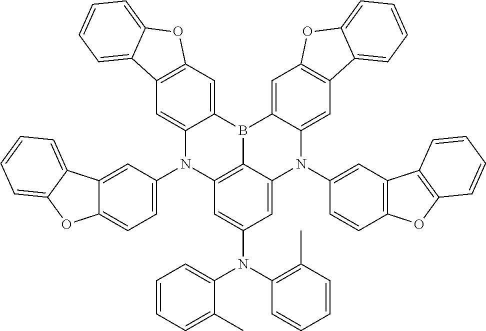 [SMILES: Cc1ccccc1N(c1cc2c3c(c1)N(c1ccc4oc5ccccc5c4c1)c1cc4c(cc1B3c1cc3oc5ccccc5c3cc1N2c1ccc2oc3ccccc3c2c1)oc1ccccc14)c1ccccc1C]

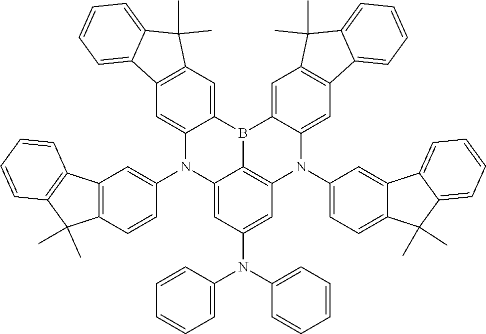 [SMILES: CC1(C)c2ccccc2-c2cc(N3c4cc5c(cc4B4c6cc7c(cc6N(c6ccc8c(c6)-c6ccccc6C8(C)C)c6cc(N(c8ccccc8)c8ccccc8)cc3c64)-c3ccccc3C7(C)C)C(C)(C)c3ccccc3-5)ccc21]

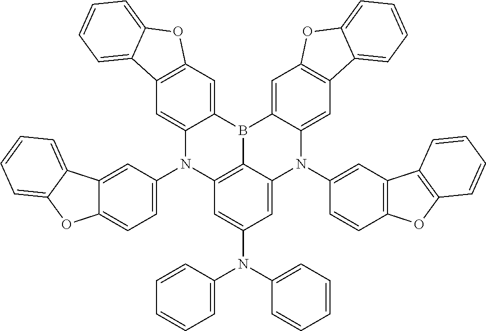 [SMILES: c1ccc(N(c2ccccc2)c2cc3c4c(c2)N(c2ccc5oc6ccccc6c5c2)c2cc5c(cc2B4c2cc4oc6ccccc6c4cc2N3c2ccc3oc4ccccc4c3c2)oc2ccccc25)cc1]

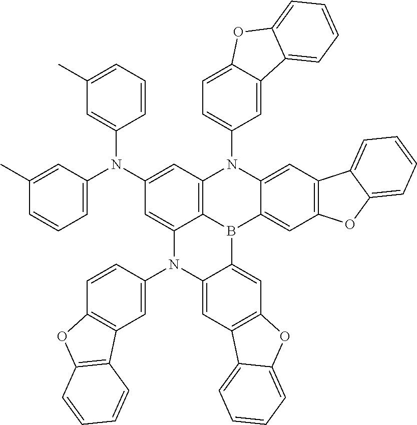 [SMILES: Cc1cccc(N(c2cccc(C)c2)c2cc3c4c(c2)N(c2ccc5oc6ccccc6c5c2)c2cc5c(cc2B4c2cc4oc6ccccc6c4cc2N3c2ccc3oc4ccccc4c3c2)oc2ccccc25)c1]

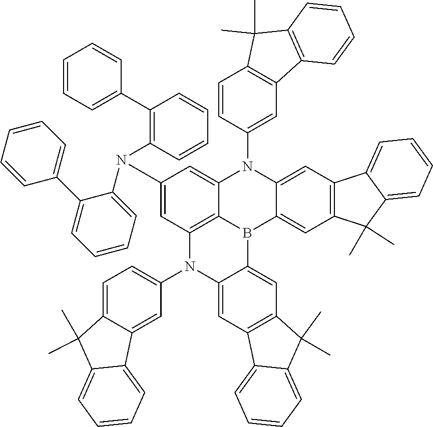 [SMILES: CC1(C)c2ccccc2-c2cc(N3c4cc5c(cc4B4c6cc7c(cc6N(c6ccc8c(c6)-c6ccccc6C8(C)C)c6cc(N(c8ccccc8-c8ccccc8)c8ccccc8-c8ccccc8)cc3c64)-c3ccccc3C7(C)C)C(C)(C)c3ccccc3-5)ccc21]

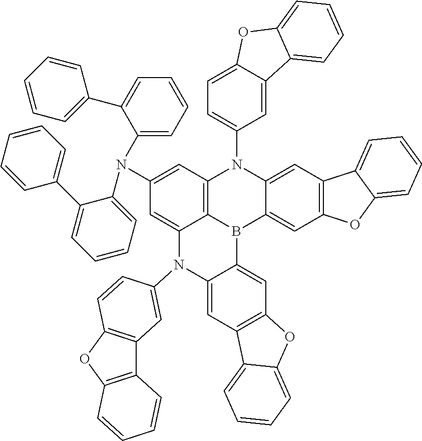 [SMILES: c1ccc(-c2ccccc2N(c2cc3c4c(c2)N(c2ccc5oc6ccccc6c5c2)c2cc5c(cc2B4c2cc4oc6ccccc6c4cc2N3c2ccc3oc4ccccc4c3c2)oc2ccccc25)c2ccccc2-c2ccccc2)cc1]

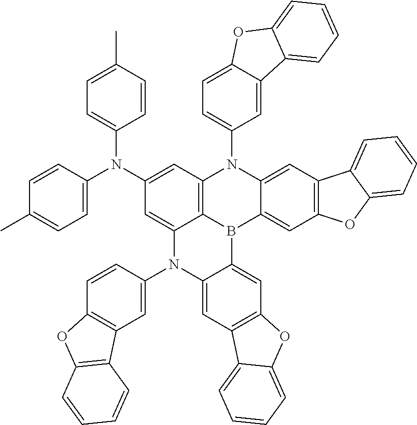 [SMILES: Cc1ccc(N(c2ccc(C)cc2)c2cc3c4c(c2)N(c2ccc5oc6ccccc6c5c2)c2cc5c(cc2B4c2cc4oc6ccccc6c4cc2N3c2ccc3oc4ccccc4c3c2)oc2ccccc25)cc1]

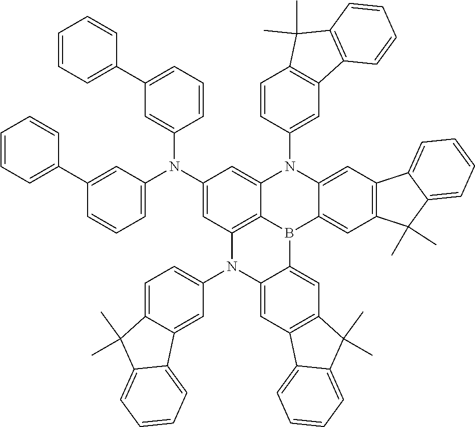 [SMILES: CC1(C)c2ccccc2-c2cc(N3c4cc5c(cc4B4c6cc7c(cc6N(c6ccc8c(c6)-c6ccccc6C8(C)C)c6cc(N(c8cccc(-c9ccccc9)c8)c8cccc(-c9ccccc9)c8)cc3c64)-c3ccccc3C7(C)C)C(C)(C)c3ccccc3-5)ccc21]

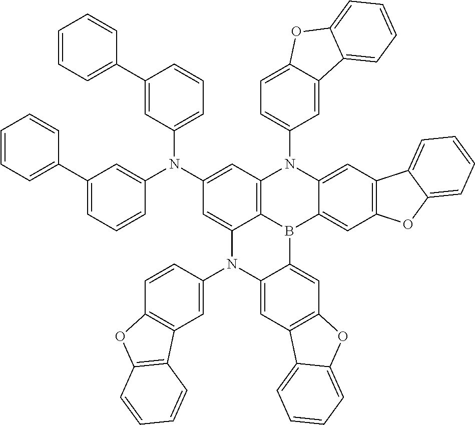 [SMILES: c1ccc(-c2cccc(N(c3cccc(-c4ccccc4)c3)c3cc4c5c(c3)N(c3ccc6oc7ccccc7c6c3)c3cc6c(cc3B5c3cc5oc7ccccc7c5cc3N4c3ccc4oc5ccccc5c4c3)oc3ccccc36)c2)cc1]

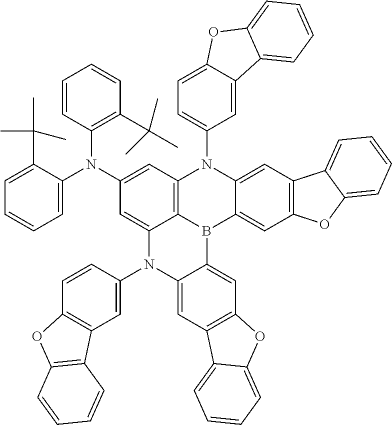 [SMILES: CC(C)(C)c1ccccc1N(c1cc2c3c(c1)N(c1ccc4oc5ccccc5c4c1)c1cc4c(cc1B3c1cc3oc5ccccc5c3cc1N2c1ccc2oc3ccccc3c2c1)oc1ccccc14)c1ccccc1C(C)(C)C]

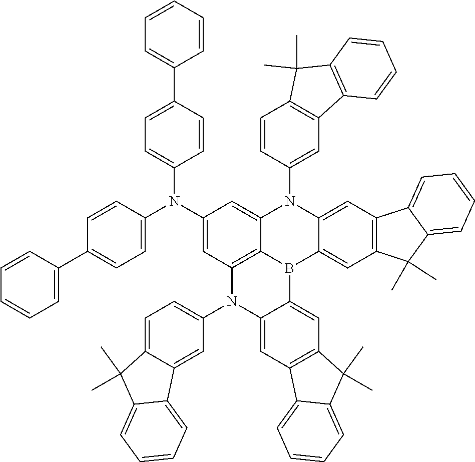 [SMILES: CC1(C)c2ccccc2-c2cc(N3c4cc5c(cc4B4c6cc7c(cc6N(c6ccc8c(c6)-c6ccccc6C8(C)C)c6cc(N(c8ccc(-c9ccccc9)cc8)c8ccc(-c9ccccc9)cc8)cc3c64)-c3ccccc3C7(C)C)C(C)(C)c3ccccc3-5)ccc21]

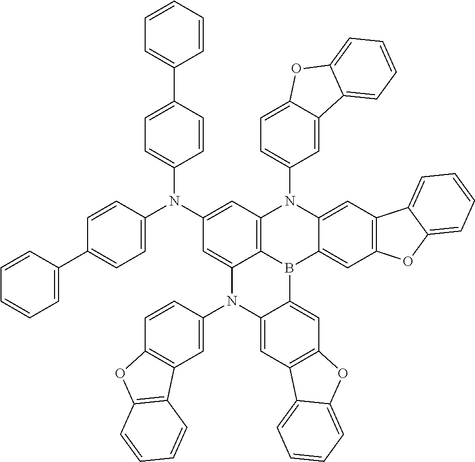 [SMILES: c1ccc(-c2ccc(N(c3ccc(-c4ccccc4)cc3)c3cc4c5c(c3)N(c3ccc6oc7ccccc7c6c3)c3cc6c(cc3B5c3cc5oc7ccccc7c5cc3N4c3ccc4oc5ccccc5c4c3)oc3ccccc36)cc2)cc1]

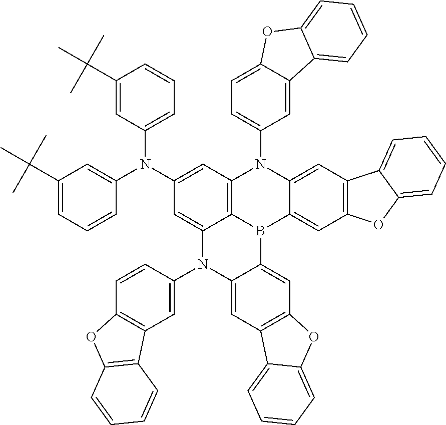 [SMILES: CC(C)(C)c1cccc(N(c2cccc(C(C)(C)C)c2)c2cc3c4c(c2)N(c2ccc5oc6ccccc6c5c2)c2cc5c(cc2B4c2cc4oc6ccccc6c4cc2N3c2ccc3oc4ccccc4c3c2)oc2ccccc25)c1]

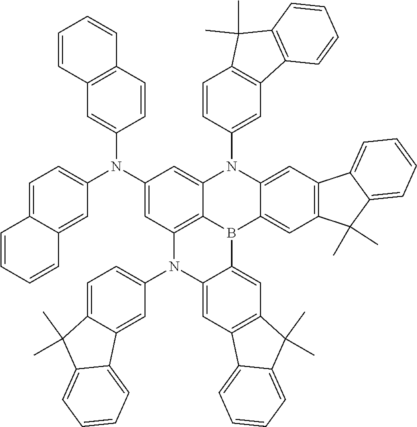 [SMILES: CC1(C)c2ccccc2-c2cc(N3c4cc5c(cc4B4c6cc7c(cc6N(c6ccc8c(c6)-c6ccccc6C8(C)C)c6cc(N(c8ccc9ccccc9c8)c8ccc9ccccc9c8)cc3c64)-c3ccccc3C7(C)C)C(C)(C)c3ccccc3-5)ccc21]

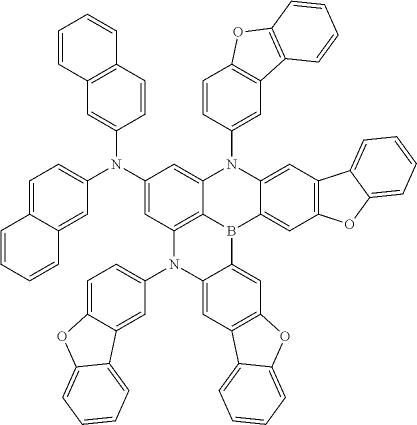 [SMILES: c1ccc2cc(N(c3cc4c5c(c3)N(c3ccc6oc7ccccc7c6c3)c3cc6c(cc3B5c3cc5oc7ccccc7c5cc3N4c3ccc4oc5ccccc5c4c3)oc3ccccc36)c3ccc4ccccc4c3)ccc2c1]

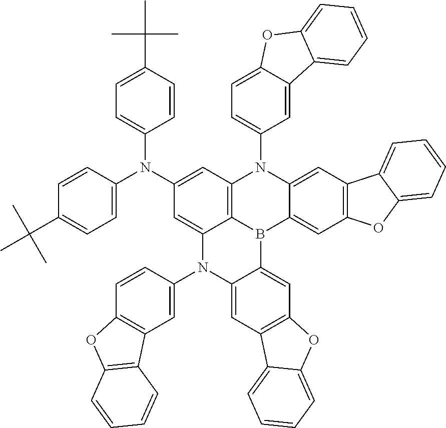 [SMILES: CC(C)(C)c1ccc(N(c2ccc(C(C)(C)C)cc2)c2cc3c4c(c2)N(c2ccc5oc6ccccc6c5c2)c2cc5c(cc2B4c2cc4oc6ccccc6c4cc2N3c2ccc3oc4ccccc4c3c2)oc2ccccc25)cc1]

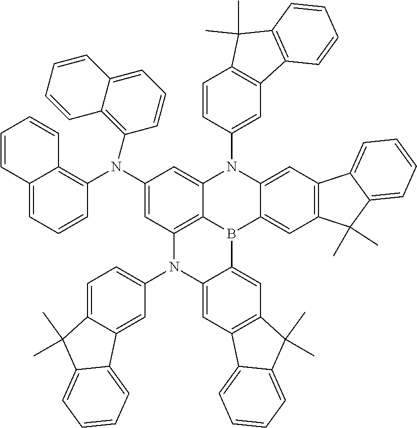 [SMILES: CC1(C)c2ccccc2-c2cc(N3c4cc5c(cc4B4c6cc7c(cc6N(c6ccc8c(c6)-c6ccccc6C8(C)C)c6cc(N(c8cccc9ccccc89)c8cccc9ccccc89)cc3c64)-c3ccccc3C7(C)C)C(C)(C)c3ccccc3-5)ccc21]

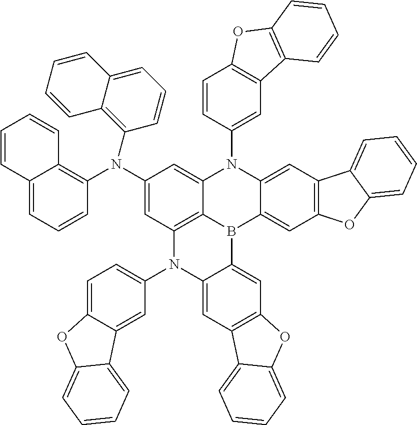 [SMILES: c1ccc2c(N(c3cc4c5c(c3)N(c3ccc6oc7ccccc7c6c3)c3cc6c(cc3B5c3cc5oc7ccccc7c5cc3N4c3ccc4oc5ccccc5c4c3)oc3ccccc36)c3cccc4ccccc34)cccc2c1]

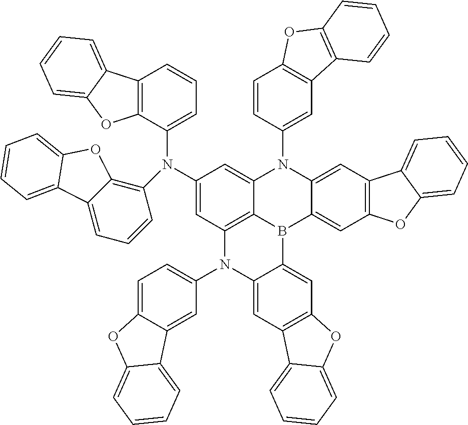 [SMILES: c1ccc2c(c1)oc1ccc(N3c4cc5c(cc4B4c6cc7oc8ccccc8c7cc6N(c6ccc7oc8ccccc8c7c6)c6cc(N(c7cccc8c7oc7ccccc78)c7cccc8c7oc7ccccc78)cc3c64)oc3ccccc35)cc12]

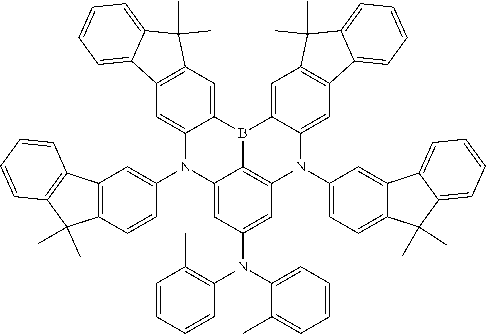 [SMILES: Cc1ccccc1N(c1cc2c3c(c1)N(c1ccc4c(c1)-c1ccccc1C4(C)C)c1cc4c(cc1B3c1cc3c(cc1N2c1ccc2c(c1)-c1ccccc1C2(C)C)-c1ccccc1C3(C)C)C(C)(C)c1ccccc1-4)c1ccccc1C]

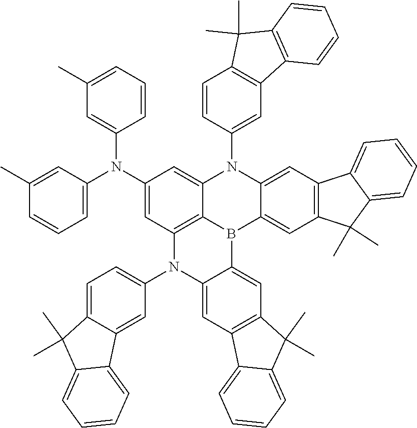 [SMILES: Cc1cccc(N(c2cccc(C)c2)c2cc3c4c(c2)N(c2ccc5c(c2)-c2ccccc2C5(C)C)c2cc5c(cc2B4c2cc4c(cc2N3c2ccc3c(c2)-c2ccccc2C3(C)C)-c2ccccc2C4(C)C)C(C)(C)c2ccccc2-5)c1]

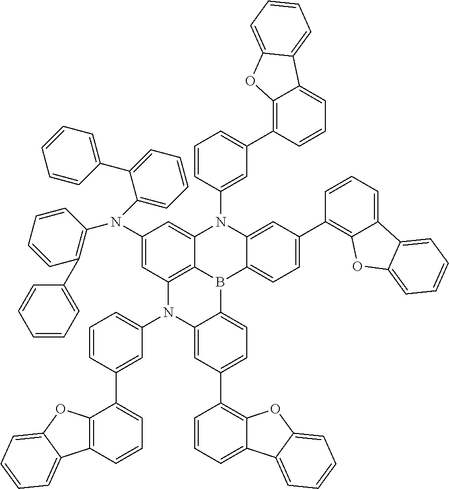 [SMILES: c1ccc(-c2ccccc2N(c2cc3c4c(c2)N(c2cccc(-c5cccc6c5oc5ccccc56)c2)c2cc(-c5cccc6c5oc5ccccc56)ccc2B4c2ccc(-c4cccc5c4oc4ccccc45)cc2N3c2cccc(-c3cccc4c3oc3ccccc34)c2)c2ccccc2-c2ccccc2)cc1]

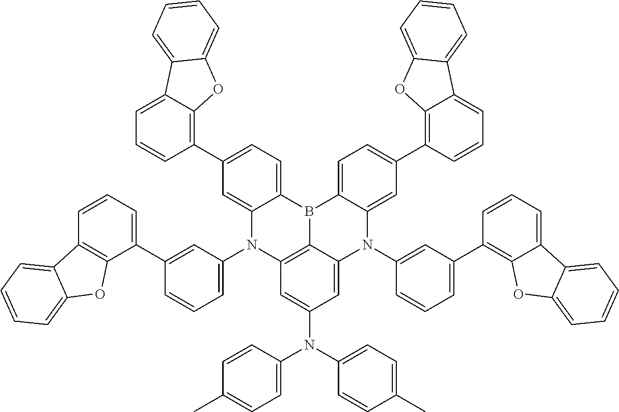 [SMILES: Cc1ccc(N(c2ccc(C)cc2)c2cc3c4c(c2)N(c2cccc(-c5cccc6c5oc5ccccc56)c2)c2cc(-c5cccc6c5oc5ccccc56)ccc2B4c2ccc(-c4cccc5c4oc4ccccc45)cc2N3c2cccc(-c3cccc4c3oc3ccccc34)c2)cc1]

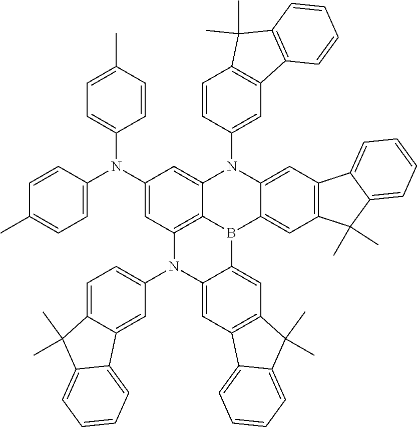 [SMILES: Cc1ccc(N(c2ccc(C)cc2)c2cc3c4c(c2)N(c2ccc5c(c2)-c2ccccc2C5(C)C)c2cc5c(cc2B4c2cc4c(cc2N3c2ccc3c(c2)-c2ccccc2C3(C)C)-c2ccccc2C4(C)C)C(C)(C)c2ccccc2-5)cc1]

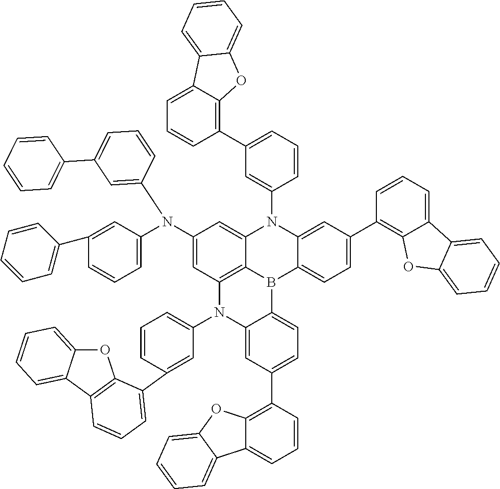 [SMILES: c1ccc(-c2cccc(N(c3cccc(-c4ccccc4)c3)c3cc4c5c(c3)N(c3cccc(-c6cccc7c6oc6ccccc67)c3)c3cc(-c6cccc7c6oc6ccccc67)ccc3B5c3ccc(-c5cccc6c5oc5ccccc56)cc3N4c3cccc(-c4cccc5c4oc4ccccc45)c3)c2)cc1]

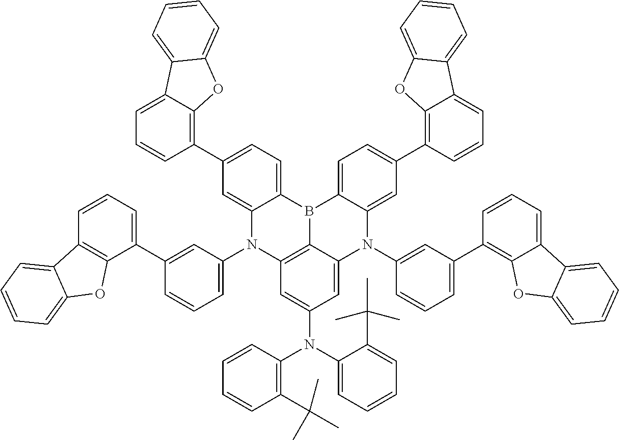 [SMILES: CC(C)(C)c1ccccc1N(c1cc2c3c(c1)N(c1cccc(-c4cccc5c4oc4ccccc45)c1)c1cc(-c4cccc5c4oc4ccccc45)ccc1B3c1ccc(-c3cccc4c3oc3ccccc34)cc1N2c1cccc(-c2cccc3c2oc2ccccc23)c1)c1ccccc1C(C)(C)C]

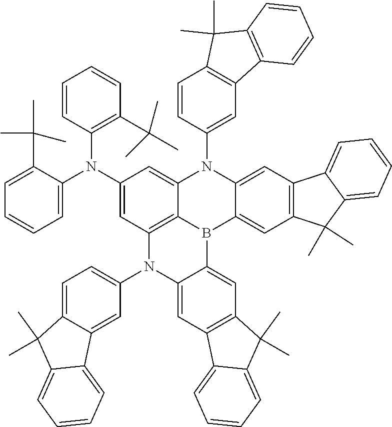 [SMILES: CC(C)(C)c1ccccc1N(c1cc2c3c(c1)N(c1ccc4c(c1)-c1ccccc1C4(C)C)c1cc4c(cc1B3c1cc3c(cc1N2c1ccc2c(c1)-c1ccccc1C2(C)C)-c1ccccc1C3(C)C)C(C)(C)c1ccccc1-4)c1ccccc1C(C)(C)C]

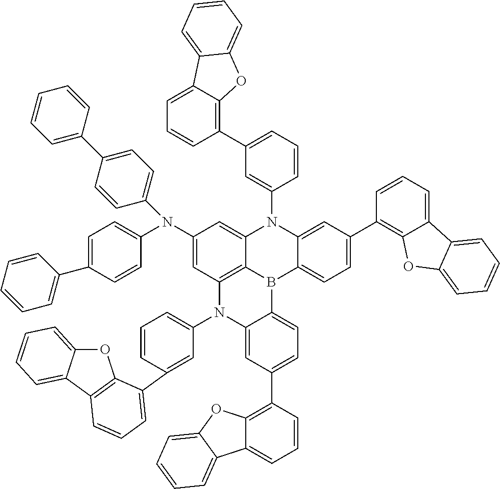 [SMILES: c1ccc(-c2ccc(N(c3ccc(-c4ccccc4)cc3)c3cc4c5c(c3)N(c3cccc(-c6cccc7c6oc6ccccc67)c3)c3cc(-c6cccc7c6oc6ccccc67)ccc3B5c3ccc(-c5cccc6c5oc5ccccc56)cc3N4c3cccc(-c4cccc5c4oc4ccccc45)c3)cc2)cc1]

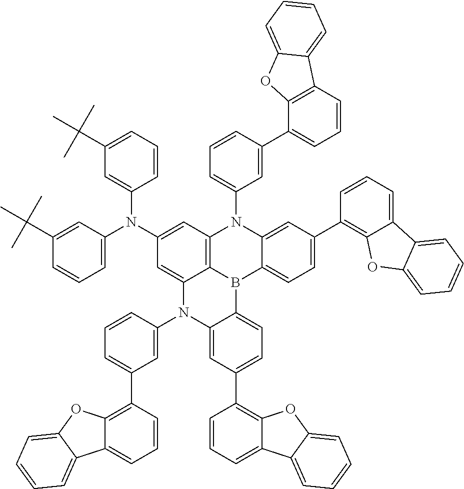 [SMILES: CC(C)(C)c1cccc(N(c2cccc(C(C)(C)C)c2)c2cc3c4c(c2)N(c2cccc(-c5cccc6c5oc5ccccc56)c2)c2cc(-c5cccc6c5oc5ccccc56)ccc2B4c2ccc(-c4cccc5c4oc4ccccc45)cc2N3c2cccc(-c3cccc4c3oc3ccccc34)c2)c1]

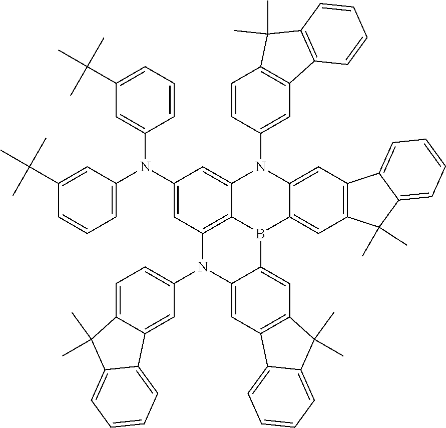 [SMILES: CC(C)(C)c1cccc(N(c2cccc(C(C)(C)C)c2)c2cc3c4c(c2)N(c2ccc5c(c2)-c2ccccc2C5(C)C)c2cc5c(cc2B4c2cc4c(cc2N3c2ccc3c(c2)-c2ccccc2C3(C)C)-c2ccccc2C4(C)C)C(C)(C)c2ccccc2-5)c1]

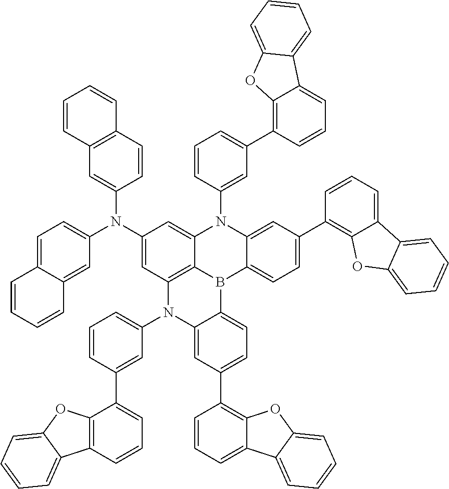 [SMILES: c1cc(-c2cccc3c2oc2ccccc23)cc(N2c3cc(-c4cccc5c4oc4ccccc45)ccc3B3c4ccc(-c5cccc6c5oc5ccccc56)cc4N(c4cccc(-c5cccc6c5oc5ccccc56)c4)c4cc(N(c5ccc6ccccc6c5)c5ccc6ccccc6c5)cc2c43)c1]

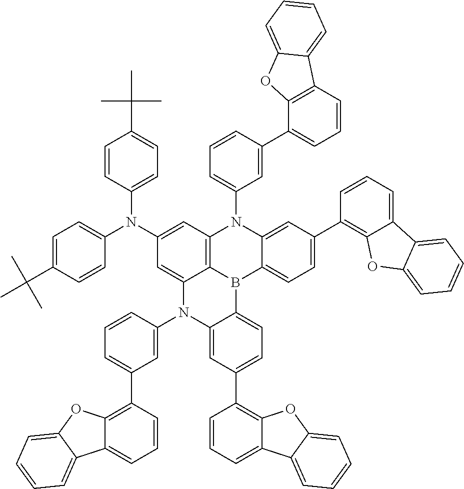 [SMILES: CC(C)(C)c1ccc(N(c2ccc(C(C)(C)C)cc2)c2cc3c4c(c2)N(c2cccc(-c5cccc6c5oc5ccccc56)c2)c2cc(-c5cccc6c5oc5ccccc56)ccc2B4c2ccc(-c4cccc5c4oc4ccccc45)cc2N3c2cccc(-c3cccc4c3oc3ccccc34)c2)cc1]

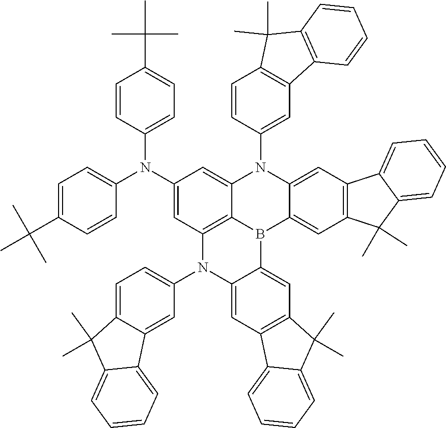 [SMILES: CC(C)(C)c1ccc(N(c2ccc(C(C)(C)C)cc2)c2cc3c4c(c2)N(c2ccc5c(c2)-c2ccccc2C5(C)C)c2cc5c(cc2B4c2cc4c(cc2N3c2ccc3c(c2)-c2ccccc2C3(C)C)-c2ccccc2C4(C)C)C(C)(C)c2ccccc2-5)cc1]

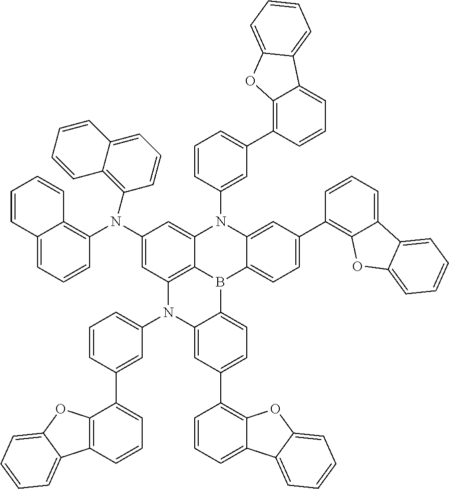 [SMILES: c1cc(-c2cccc3c2oc2ccccc23)cc(N2c3cc(-c4cccc5c4oc4ccccc45)ccc3B3c4ccc(-c5cccc6c5oc5ccccc56)cc4N(c4cccc(-c5cccc6c5oc5ccccc56)c4)c4cc(N(c5cccc6ccccc56)c5cccc6ccccc56)cc2c43)c1]

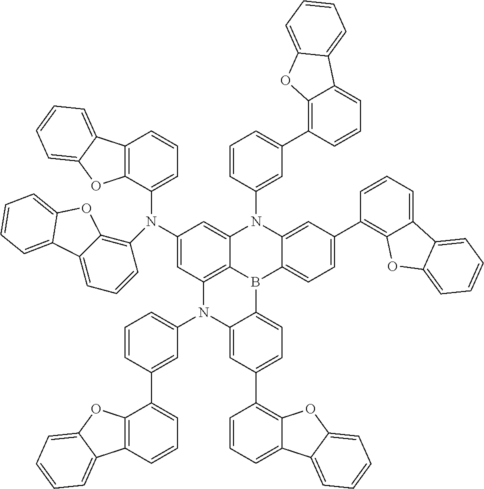 [SMILES: c1cc(-c2cccc3c2oc2ccccc23)cc(N2c3cc(-c4cccc5c4oc4ccccc45)ccc3B3c4ccc(-c5cccc6c5oc5ccccc56)cc4N(c4cccc(-c5cccc6c5oc5ccccc56)c4)c4cc(N(c5cccc6c5oc5ccccc56)c5cccc6c5oc5ccccc56)cc2c43)c1]

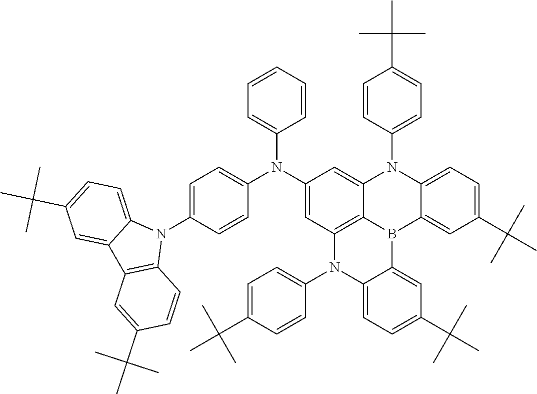 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccc(-n6c7ccc(C(C)(C)C)cc7c7cc(C(C)(C)C)ccc76)cc5)cc2c43)cc1]

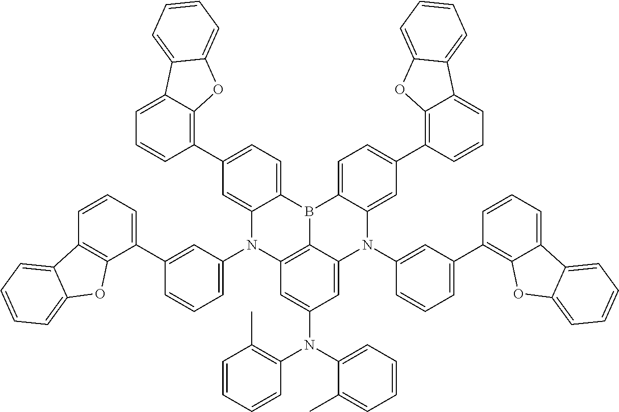 [SMILES: Cc1ccccc1N(c1cc2c3c(c1)N(c1cccc(-c4cccc5c4oc4ccccc45)c1)c1cc(-c4cccc5c4oc4ccccc45)ccc1B3c1ccc(-c3cccc4c3oc3ccccc34)cc1N2c1cccc(-c2cccc3c2oc2ccccc23)c1)c1ccccc1C]

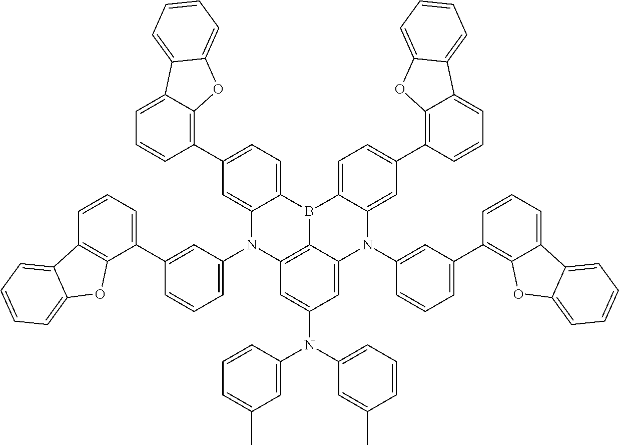 [SMILES: Cc1cccc(N(c2cccc(C)c2)c2cc3c4c(c2)N(c2cccc(-c5cccc6c5oc5ccccc56)c2)c2cc(-c5cccc6c5oc5ccccc56)ccc2B4c2ccc(-c4cccc5c4oc4ccccc45)cc2N3c2cccc(-c3cccc4c3oc3ccccc34)c2)c1]

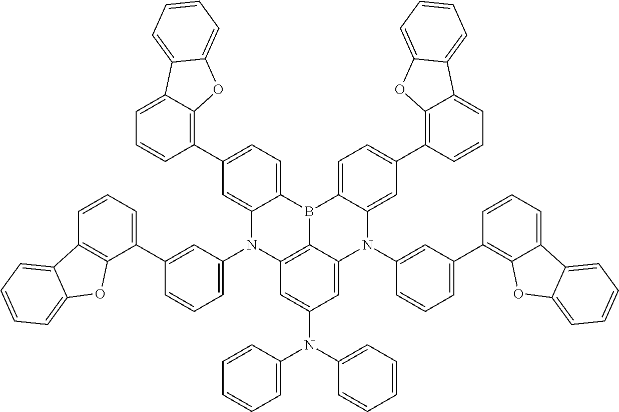 [SMILES: c1ccc(N(c2ccccc2)c2cc3c4c(c2)N(c2cccc(-c5cccc6c5oc5ccccc56)c2)c2cc(-c5cccc6c5oc5ccccc56)ccc2B4c2ccc(-c4cccc5c4oc4ccccc45)cc2N3c2cccc(-c3cccc4c3oc3ccccc34)c2)cc1]

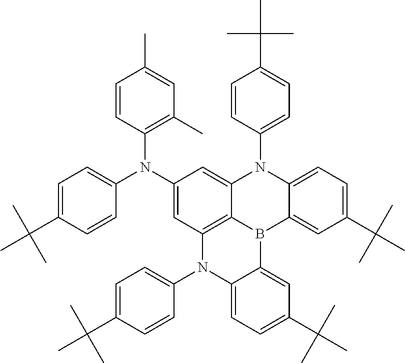 [SMILES: Cc1ccc(N(c2ccc(C(C)(C)C)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)c(C)c1]

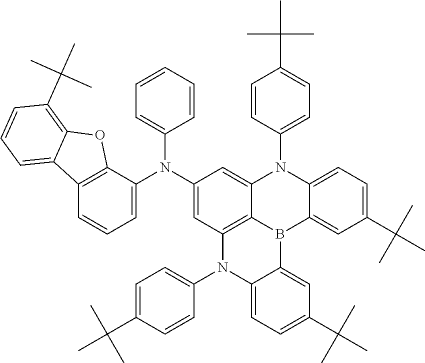 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5cccc6c5oc5c(C(C)(C)C)cccc56)cc2c43)cc1]

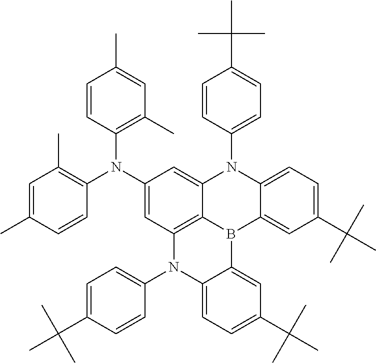 [SMILES: Cc1ccc(N(c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)c2ccc(C)cc2C)c(C)c1]

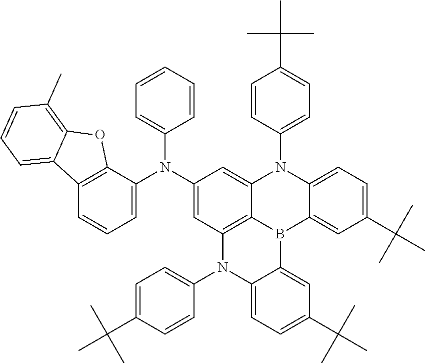 [SMILES: Cc1cccc2c1oc1c(N(c3ccccc3)c3cc4c5c(c3)N(c3ccc(C(C)(C)C)cc3)c3ccc(C(C)(C)C)cc3B5c3cc(C(C)(C)C)ccc3N4c3ccc(C(C)(C)C)cc3)cccc12]

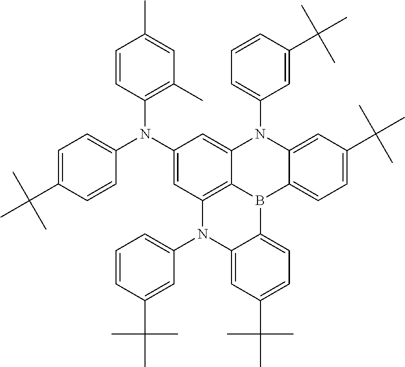 [SMILES: Cc1ccc(N(c2ccc(C(C)(C)C)cc2)c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c(C)c1]

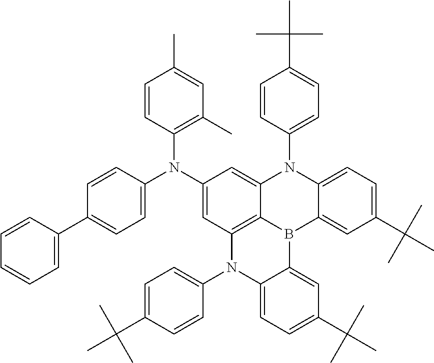 [SMILES: Cc1ccc(N(c2ccc(-c3ccccc3)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)c(C)c1]

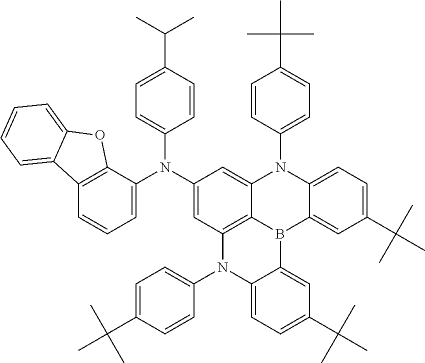 [SMILES: CC(C)c1ccc(N(c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)c2cccc3c2oc2ccccc23)cc1]

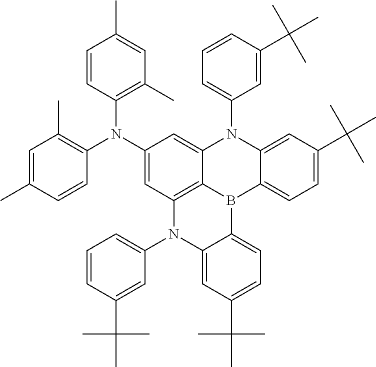 [SMILES: Cc1ccc(N(c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c2ccc(C)cc2C)c(C)c1]

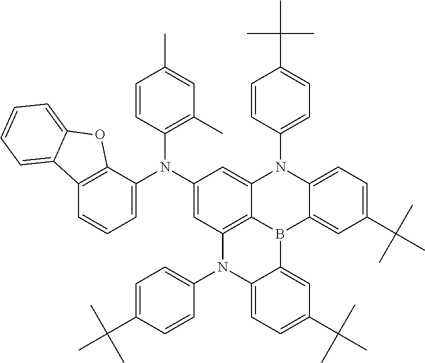 [SMILES: Cc1ccc(N(c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)c2cccc3c2oc2ccccc23)c(C)c1]

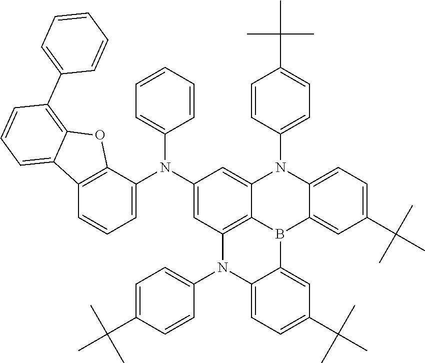 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5cccc6c5oc5c(-c7ccccc7)cccc56)cc2c43)cc1]

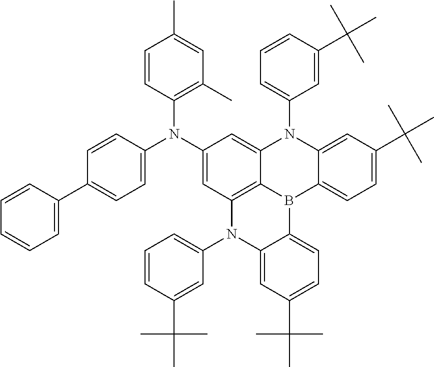 [SMILES: Cc1ccc(N(c2ccc(-c3ccccc3)cc2)c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c(C)c1]

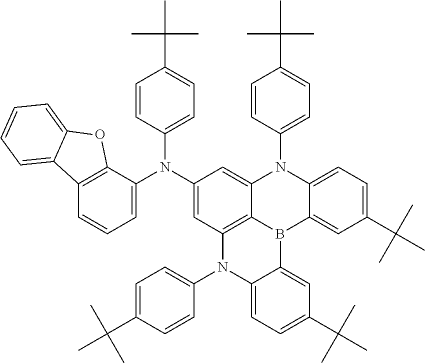 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccc(C(C)(C)C)cc5)c5cccc6c5oc5ccccc56)cc2c43)cc1]

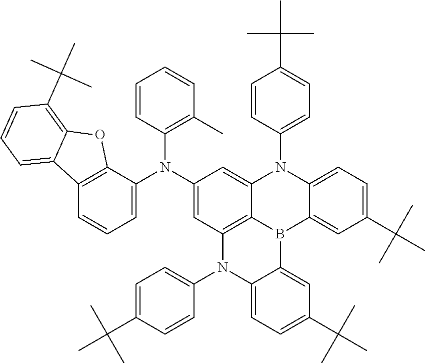 [SMILES: Cc1ccccc1N(c1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1)c1cccc2c1oc1c(C(C)(C)C)cccc12]

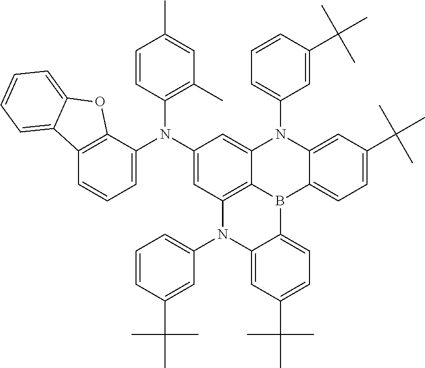 [SMILES: Cc1ccc(N(c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c2cccc3c2oc2ccccc23)c(C)c1]

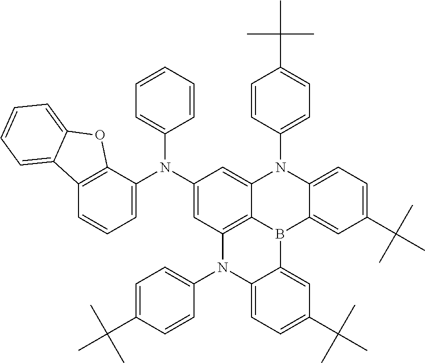 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5cccc6c5oc5ccccc56)cc2c43)cc1]

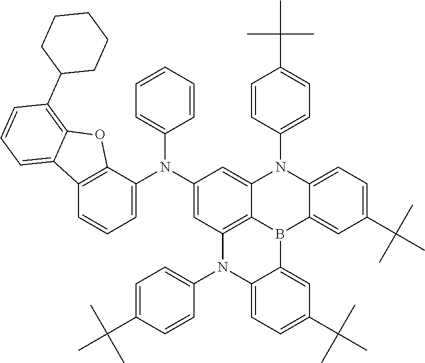 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5cccc6c5oc5c(C7CCCCC7)cccc56)cc2c43)cc1]

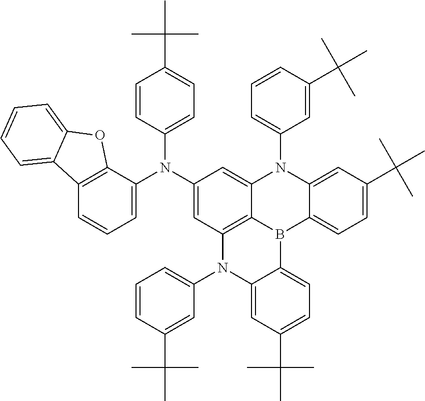 [SMILES: CC(C)(C)c1ccc(N(c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c2cccc3c2oc2ccccc23)cc1]

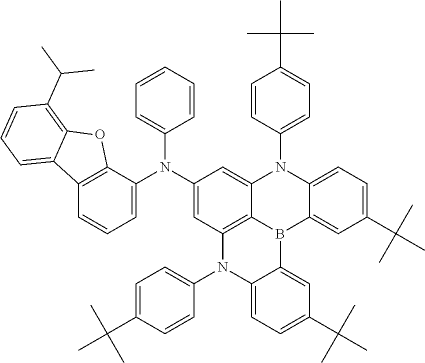 [SMILES: CC(C)c1cccc2c1oc1c(N(c3ccccc3)c3cc4c5c(c3)N(c3ccc(C(C)(C)C)cc3)c3ccc(C(C)(C)C)cc3B5c3cc(C(C)(C)C)ccc3N4c3ccc(C(C)(C)C)cc3)cccc12]

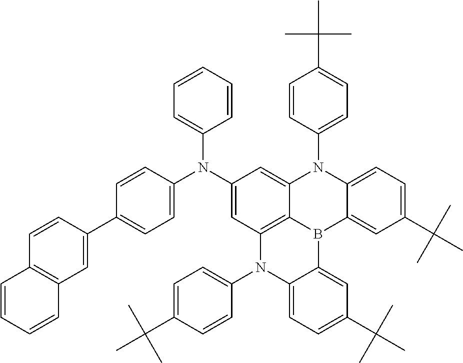 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccc(-c6ccc7ccccc7c6)cc5)cc2c43)cc1]

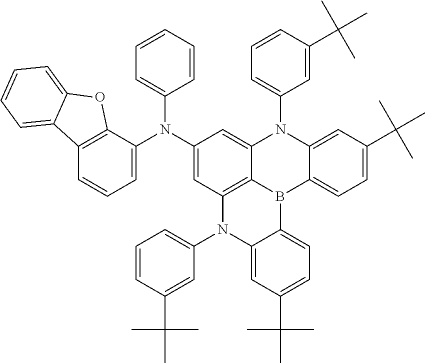 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5cccc6c5oc5ccccc56)cc2c43)c1]

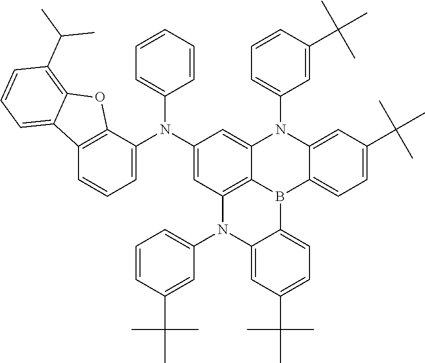 [SMILES: CC(C)c1cccc2c1oc1c(N(c3ccccc3)c3cc4c5c(c3)N(c3cccc(C(C)(C)C)c3)c3cc(C(C)(C)C)ccc3B5c3ccc(C(C)(C)C)cc3N4c3cccc(C(C)(C)C)c3)cccc12]

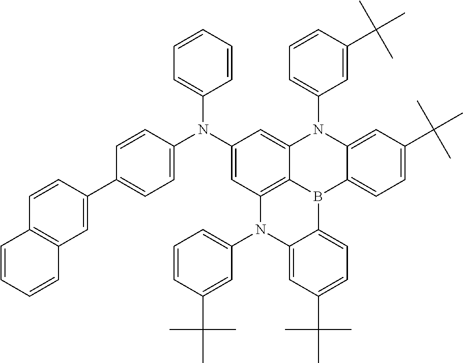 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5ccc(-c6ccc7ccccc7c6)cc5)cc2c43)c1]

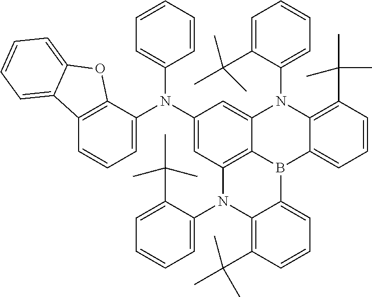 [SMILES: CC(C)(C)c1ccccc1N1c2cc(N(c3ccccc3)c3cccc4c3oc3ccccc34)cc3c2B(c2cccc(C(C)(C)C)c21)c1cccc(C(C)(C)C)c1N3c1ccccc1C(C)(C)C]

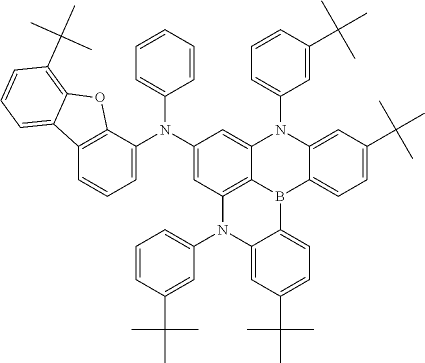 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5cccc6c5oc5c(C(C)(C)C)cccc56)cc2c43)c1]

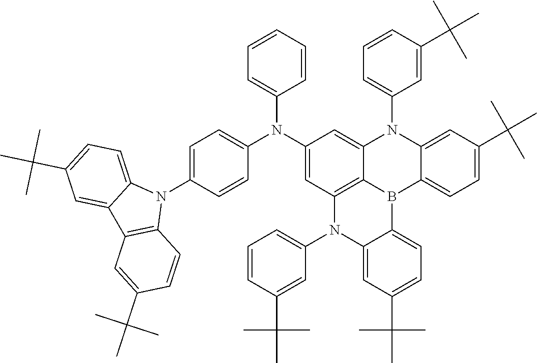 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5ccc(-n6c7ccc(C(C)(C)C)cc7c7cc(C(C)(C)C)ccc76)cc5)cc2c43)c1]

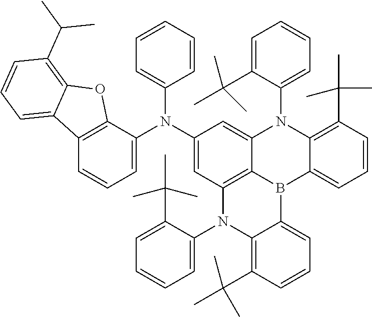 [SMILES: CC(C)c1cccc2c1oc1c(N(c3ccccc3)c3cc4c5c(c3)N(c3ccccc3C(C)(C)C)c3c(cccc3C(C)(C)C)B5c3cccc(C(C)(C)C)c3N4c3ccccc3C(C)(C)C)cccc12]

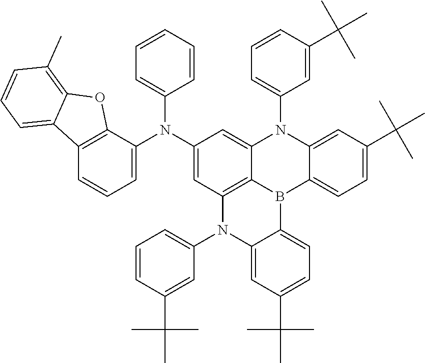 [SMILES: Cc1cccc2c1oc1c(N(c3ccccc3)c3cc4c5c(c3)N(c3cccc(C(C)(C)C)c3)c3cc(C(C)(C)C)ccc3B5c3ccc(C(C)(C)C)cc3N4c3cccc(C(C)(C)C)c3)cccc12]

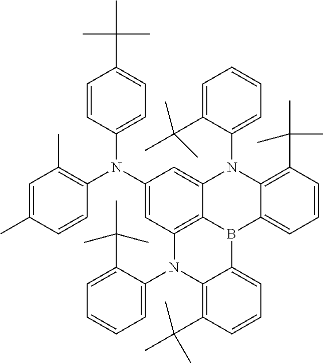 [SMILES: Cc1ccc(N(c2ccc(C(C)(C)C)cc2)c2cc3c4c(c2)N(c2ccccc2C(C)(C)C)c2c(cccc2C(C)(C)C)B4c2cccc(C(C)(C)C)c2N3c2ccccc2C(C)(C)C)c(C)c1]

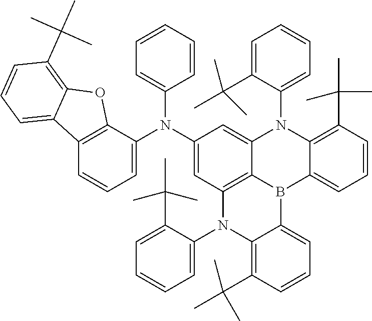 [SMILES: CC(C)(C)c1ccccc1N1c2cc(N(c3ccccc3)c3cccc4c3oc3c(C(C)(C)C)cccc34)cc3c2B(c2cccc(C(C)(C)C)c21)c1cccc(C(C)(C)C)c1N3c1ccccc1C(C)(C)C]

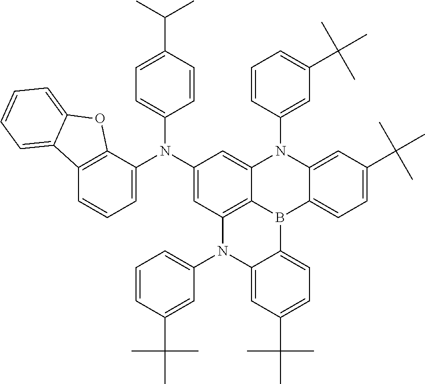 [SMILES: CC(C)c1ccc(N(c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c2cccc3c2oc2ccccc23)cc1]

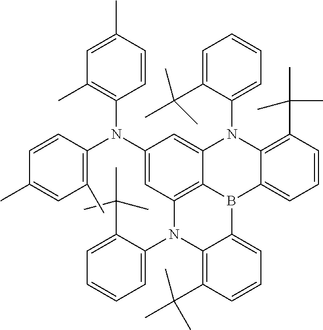 [SMILES: Cc1ccc(N(c2cc3c4c(c2)N(c2ccccc2C(C)(C)C)c2c(cccc2C(C)(C)C)B4c2cccc(C(C)(C)C)c2N3c2ccccc2C(C)(C)C)c2ccc(C)cc2C)c(C)c1]

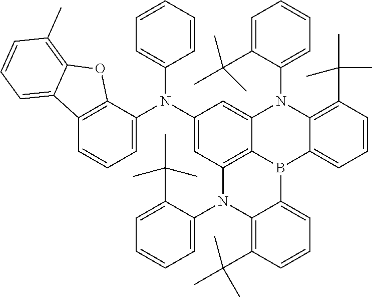 [SMILES: Cc1cccc2c1oc1c(N(c3ccccc3)c3cc4c5c(c3)N(c3ccccc3C(C)(C)C)c3c(cccc3C(C)(C)C)B5c3cccc(C(C)(C)C)c3N4c3ccccc3C(C)(C)C)cccc12]

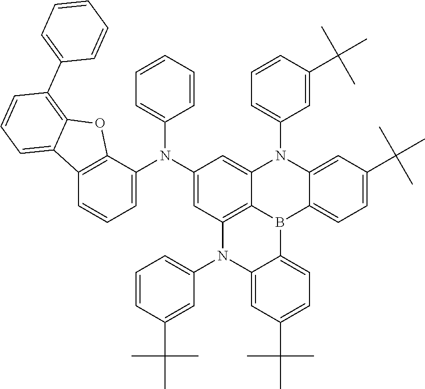 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5cccc6c5oc5c(-c7ccccc7)cccc56)cc2c43)c1]

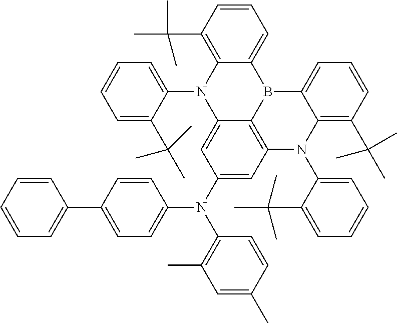 [SMILES: Cc1ccc(N(c2ccc(-c3ccccc3)cc2)c2cc3c4c(c2)N(c2ccccc2C(C)(C)C)c2c(cccc2C(C)(C)C)B4c2cccc(C(C)(C)C)c2N3c2ccccc2C(C)(C)C)c(C)c1]

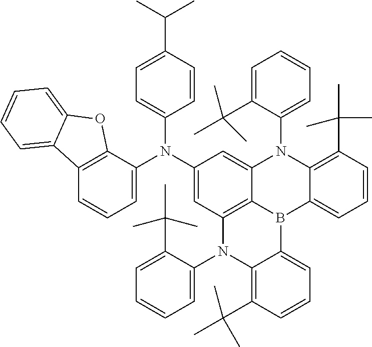 [SMILES: CC(C)c1ccc(N(c2cc3c4c(c2)N(c2ccccc2C(C)(C)C)c2c(cccc2C(C)(C)C)B4c2cccc(C(C)(C)C)c2N3c2ccccc2C(C)(C)C)c2cccc3c2oc2ccccc23)cc1]

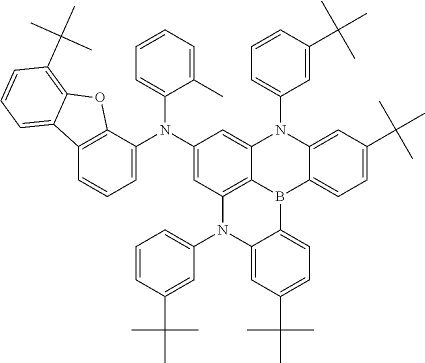 [SMILES: Cc1ccccc1N(c1cc2c3c(c1)N(c1cccc(C(C)(C)C)c1)c1cc(C(C)(C)C)ccc1B3c1ccc(C(C)(C)C)cc1N2c1cccc(C(C)(C)C)c1)c1cccc2c1oc1c(C(C)(C)C)cccc12]

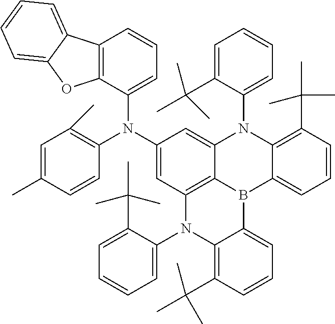 [SMILES: Cc1ccc(N(c2cc3c4c(c2)N(c2ccccc2C(C)(C)C)c2c(cccc2C(C)(C)C)B4c2cccc(C(C)(C)C)c2N3c2ccccc2C(C)(C)C)c2cccc3c2oc2ccccc23)c(C)c1]

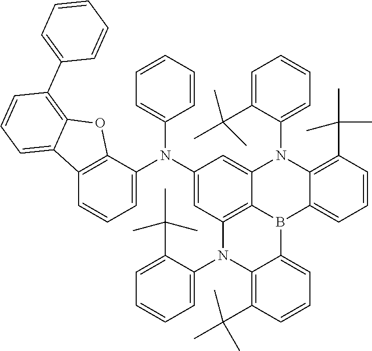 [SMILES: CC(C)(C)c1ccccc1N1c2cc(N(c3ccccc3)c3cccc4c3oc3c(-c5ccccc5)cccc34)cc3c2B(c2cccc(C(C)(C)C)c21)c1cccc(C(C)(C)C)c1N3c1ccccc1C(C)(C)C]

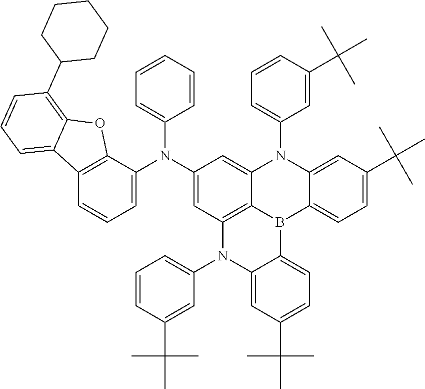 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5cccc6c5oc5c(C7CCCCC7)cccc56)cc2c43)c1]

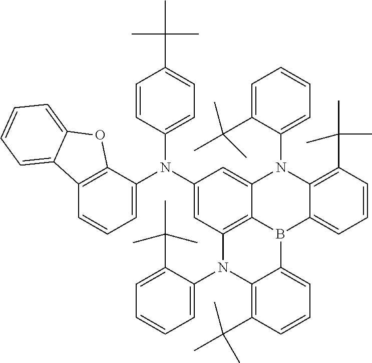 [SMILES: CC(C)(C)c1ccc(N(c2cc3c4c(c2)N(c2ccccc2C(C)(C)C)c2c(cccc2C(C)(C)C)B4c2cccc(C(C)(C)C)c2N3c2ccccc2C(C)(C)C)c2cccc3c2oc2ccccc23)cc1]

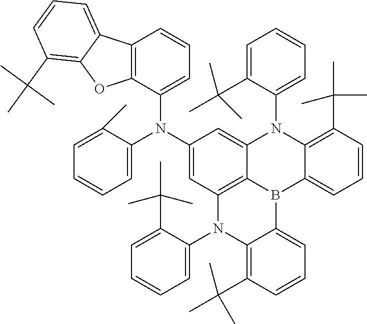 [SMILES: Cc1ccccc1N(c1cc2c3c(c1)N(c1ccccc1C(C)(C)C)c1c(cccc1C(C)(C)C)B3c1cccc(C(C)(C)C)c1N2c1ccccc1C(C)(C)C)c1cccc2c1oc1c(C(C)(C)C)cccc12]

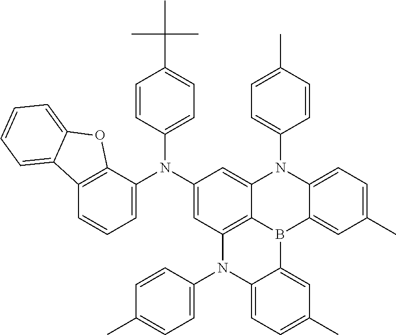 [SMILES: Cc1ccc(N2c3ccc(C)cc3B3c4cc(C)ccc4N(c4ccc(C)cc4)c4cc(N(c5ccc(C(C)(C)C)cc5)c5cccc6c5oc5ccccc56)cc2c43)cc1]

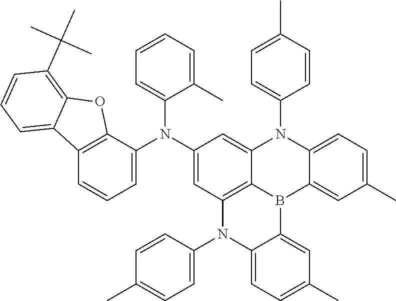 [SMILES: Cc1ccc(N2c3ccc(C)cc3B3c4cc(C)ccc4N(c4ccc(C)cc4)c4cc(N(c5ccccc5C)c5cccc6c5oc5c(C(C)(C)C)cccc56)cc2c43)cc1]

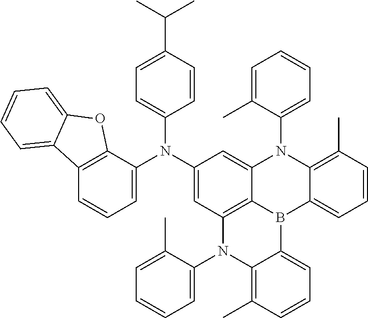 [SMILES: Cc1ccccc1N1c2cc(N(c3ccc(C(C)C)cc3)c3cccc4c3oc3ccccc34)cc3c2B(c2cccc(C)c21)c1cccc(C)c1N3c1ccccc1C]

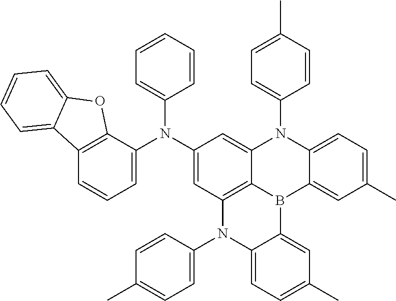 [SMILES: Cc1ccc(N2c3ccc(C)cc3B3c4cc(C)ccc4N(c4ccc(C)cc4)c4cc(N(c5ccccc5)c5cccc6c5oc5ccccc56)cc2c43)cc1]

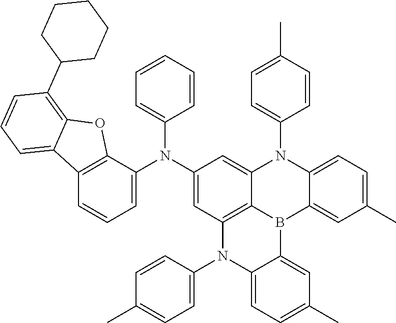 [SMILES: Cc1ccc(N2c3ccc(C)cc3B3c4cc(C)ccc4N(c4ccc(C)cc4)c4cc(N(c5ccccc5)c5cccc6c5oc5c(C7CCCCC7)cccc56)cc2c43)cc1]

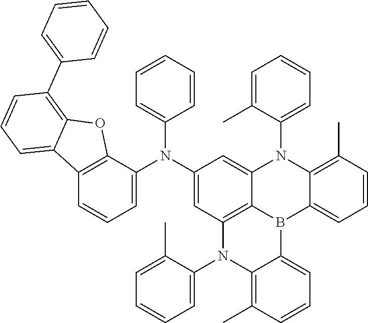 [SMILES: Cc1ccccc1N1c2cc(N(c3ccccc3)c3cccc4c3oc3c(-c5ccccc5)cccc34)cc3c2B(c2cccc(C)c21)c1cccc(C)c1N3c1ccccc1C]

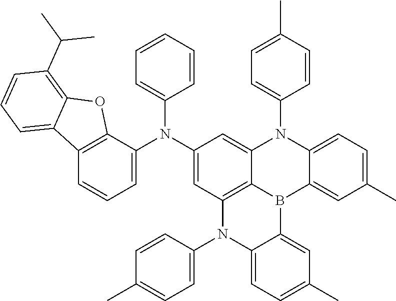 [SMILES: Cc1ccc(N2c3ccc(C)cc3B3c4cc(C)ccc4N(c4ccc(C)cc4)c4cc(N(c5ccccc5)c5cccc6c5oc5c(C(C)C)cccc56)cc2c43)cc1]

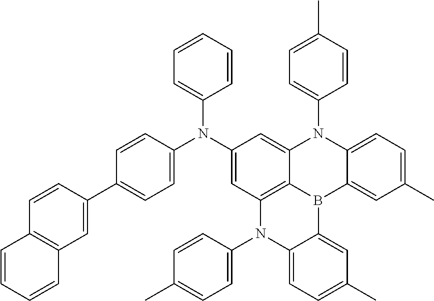 [SMILES: Cc1ccc(N2c3ccc(C)cc3B3c4cc(C)ccc4N(c4ccc(C)cc4)c4cc(N(c5ccccc5)c5ccc(-c6ccc7ccccc7c6)cc5)cc2c43)cc1]

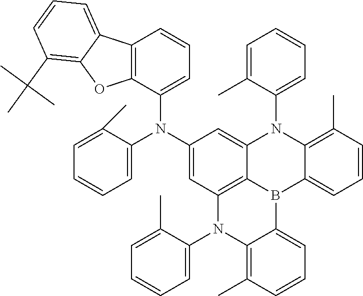 [SMILES: Cc1ccccc1N1c2cc(N(c3ccccc3C)c3cccc4c3oc3c(C(C)(C)C)cccc34)cc3c2B(c2cccc(C)c21)c1cccc(C)c1N3c1ccccc1C]

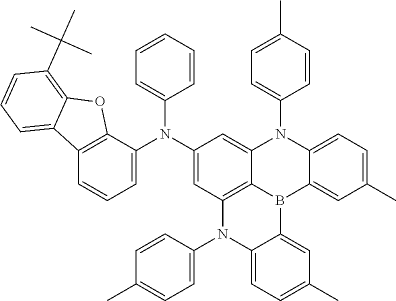 [SMILES: Cc1ccc(N2c3ccc(C)cc3B3c4cc(C)ccc4N(c4ccc(C)cc4)c4cc(N(c5ccccc5)c5cccc6c5oc5c(C(C)(C)C)cccc56)cc2c43)cc1]

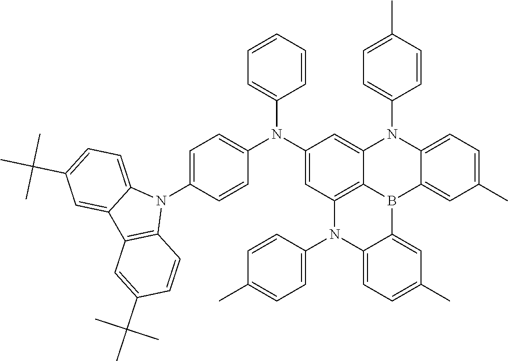 [SMILES: Cc1ccc(N2c3ccc(C)cc3B3c4cc(C)ccc4N(c4ccc(C)cc4)c4cc(N(c5ccccc5)c5ccc(-n6c7ccc(C(C)(C)C)cc7c7cc(C(C)(C)C)ccc76)cc5)cc2c43)cc1]

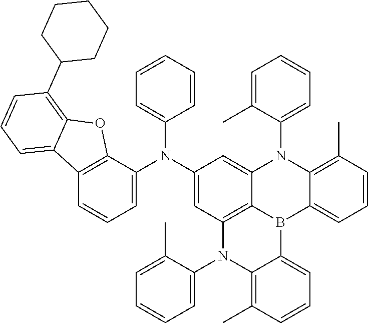 [SMILES: Cc1ccccc1N1c2cc(N(c3ccccc3)c3cccc4c3oc3c(C5CCCCC5)cccc34)cc3c2B(c2cccc(C)c21)c1cccc(C)c1N3c1ccccc1C]

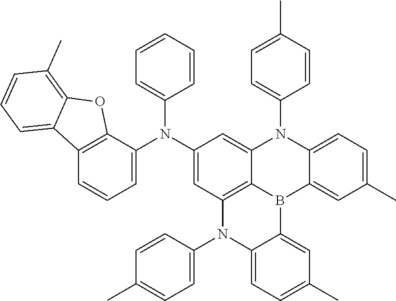 [SMILES: Cc1ccc(N2c3ccc(C)cc3B3c4cc(C)ccc4N(c4ccc(C)cc4)c4cc(N(c5ccccc5)c5cccc6c5oc5c(C)cccc56)cc2c43)cc1]

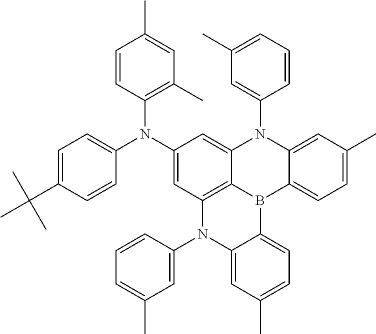 [SMILES: Cc1cccc(N2c3cc(C)ccc3B3c4ccc(C)cc4N(c4cccc(C)c4)c4cc(N(c5ccc(C(C)(C)C)cc5)c5ccc(C)cc5C)cc2c43)c1]

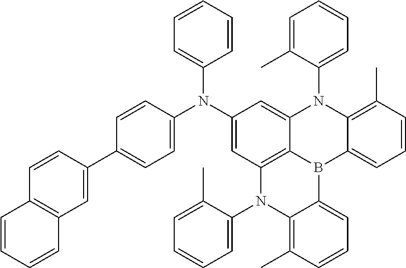 [SMILES: Cc1ccccc1N1c2cc(N(c3ccccc3)c3ccc(-c4ccc5ccccc5c4)cc3)cc3c2B(c2cccc(C)c21)c1cccc(C)c1N3c1ccccc1C]

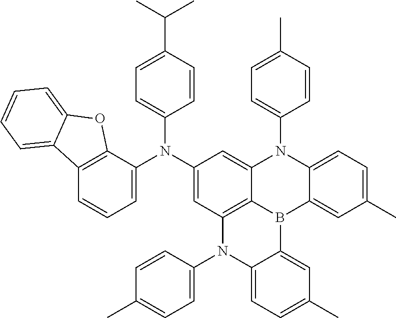 [SMILES: Cc1ccc(N2c3ccc(C)cc3B3c4cc(C)ccc4N(c4ccc(C)cc4)c4cc(N(c5ccc(C(C)C)cc5)c5cccc6c5oc5ccccc56)cc2c43)cc1]

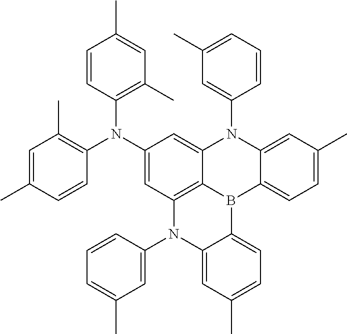

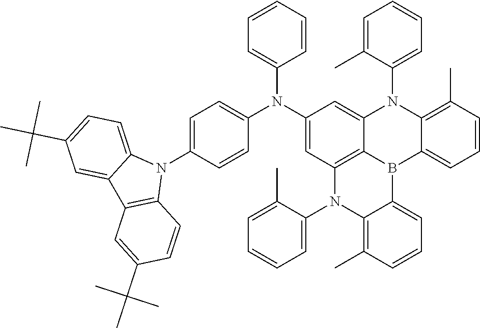 [SMILES: Cc1ccccc1N1c2cc(N(c3ccccc3)c3ccc(-n4c5ccc(C(C)(C)C)cc5c5cc(C(C)(C)C)ccc54)cc3)cc3c2B(c2cccc(C)c21)c1cccc(C)c1N3c1ccccc1C]

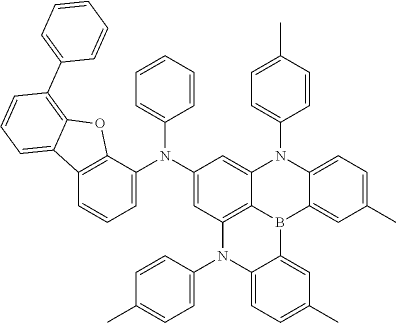 [SMILES: Cc1ccc(N2c3ccc(C)cc3B3c4cc(C)ccc4N(c4ccc(C)cc4)c4cc(N(c5ccccc5)c5cccc6c5oc5c(-c7ccccc7)cccc56)cc2c43)cc1]

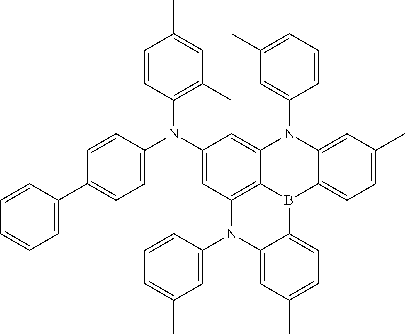 [SMILES: Cc1cccc(N2c3cc(C)ccc3B3c4ccc(C)cc4N(c4cccc(C)c4)c4cc(N(c5ccc(-c6ccccc6)cc5)c5ccc(C)cc5C)cc2c43)c1]

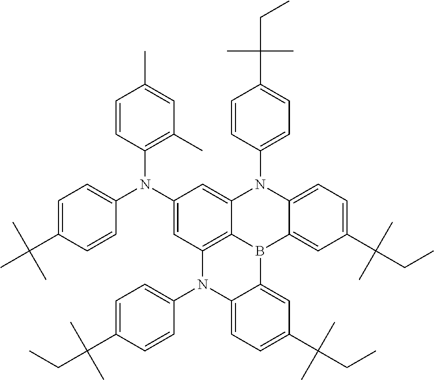 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(C(C)(C)C)cc5)c5ccc(C)cc5C)cc2c43)cc1]

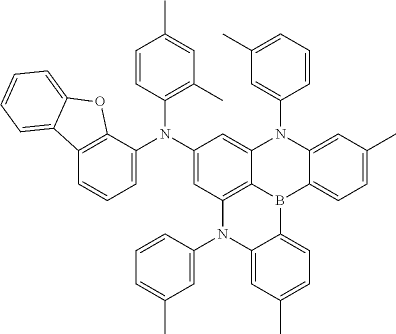 [SMILES: Cc1cccc(N2c3cc(C)ccc3B3c4ccc(C)cc4N(c4cccc(C)c4)c4cc(N(c5ccc(C)cc5C)c5cccc6c5oc5ccccc56)cc2c43)c1]

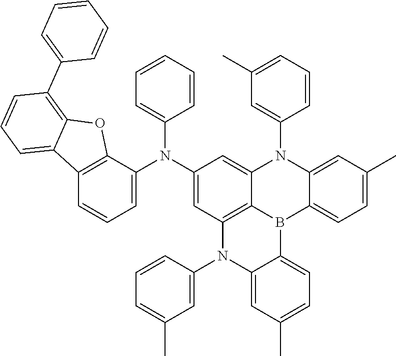 [SMILES: Cc1cccc(N2c3cc(C)ccc3B3c4ccc(C)cc4N(c4cccc(C)c4)c4cc(N(c5ccccc5)c5cccc6c5oc5c(-c7ccccc7)cccc56)cc2c43)c1]

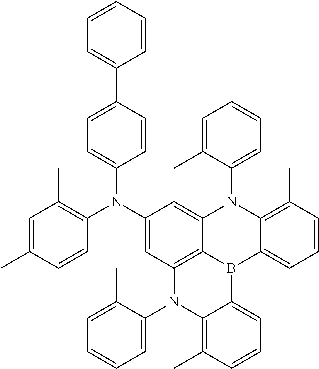 [SMILES: Cc1ccc(N(c2ccc(-c3ccccc3)cc2)c2cc3c4c(c2)N(c2ccccc2C)c2c(C)cccc2B4c2cccc(C)c2N3c2ccccc2C)c(C)c1]

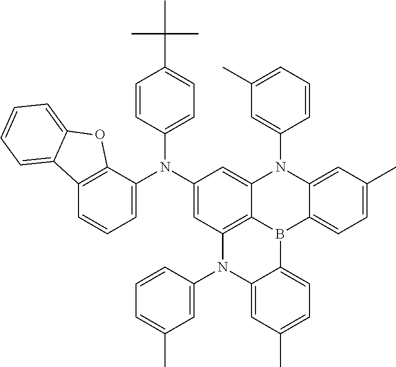 [SMILES: Cc1cccc(N2c3cc(C)ccc3B3c4ccc(C)cc4N(c4cccc(C)c4)c4cc(N(c5ccc(C(C)(C)C)cc5)c5cccc6c5oc5ccccc56)cc2c43)c1]

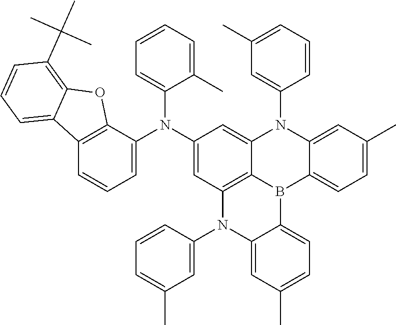 [SMILES: Cc1cccc(N2c3cc(C)ccc3B3c4ccc(C)cc4N(c4cccc(C)c4)c4cc(N(c5ccccc5C)c5cccc6c5oc5c(C(C)(C)C)cccc56)cc2c43)c1]

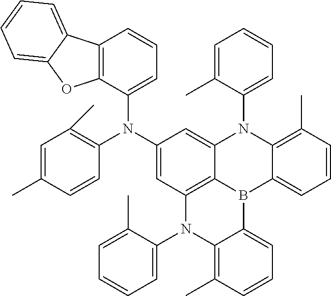 [SMILES: Cc1ccc(N(c2cc3c4c(c2)N(c2ccccc2C)c2c(C)cccc2B4c2cccc(C)c2N3c2ccccc2C)c2cccc3c2oc2ccccc23)c(C)c1]

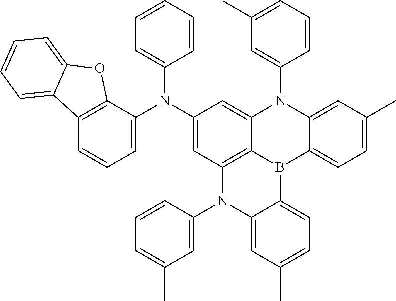 [SMILES: Cc1cccc(N2c3cc(C)ccc3B3c4ccc(C)cc4N(c4cccc(C)c4)c4cc(N(c5ccccc5)c5cccc6c5oc5ccccc56)cc2c43)c1]

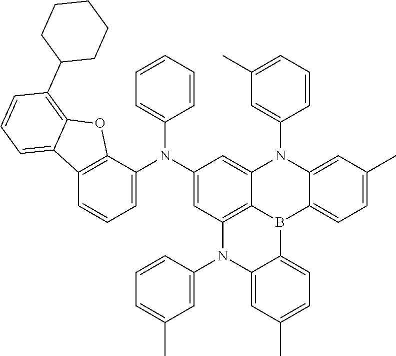 [SMILES: Cc1cccc(N2c3cc(C)ccc3B3c4ccc(C)cc4N(c4cccc(C)c4)c4cc(N(c5ccccc5)c5cccc6c5oc5c(C7CCCCC7)cccc56)cc2c43)c1]

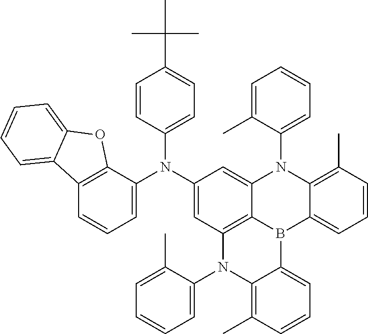 [SMILES: Cc1ccccc1N1c2cc(N(c3ccc(C(C)(C)C)cc3)c3cccc4c3oc3ccccc34)cc3c2B(c2cccc(C)c21)c1cccc(C)c1N3c1ccccc1C]

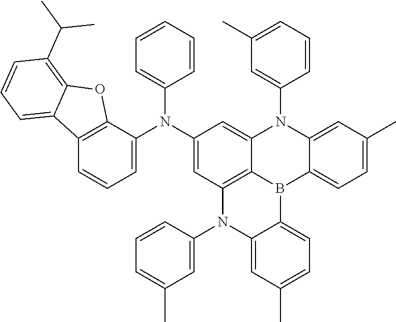 [SMILES: Cc1cccc(N2c3cc(C)ccc3B3c4ccc(C)cc4N(c4cccc(C)c4)c4cc(N(c5ccccc5)c5cccc6c5oc5c(C(C)C)cccc56)cc2c43)c1]

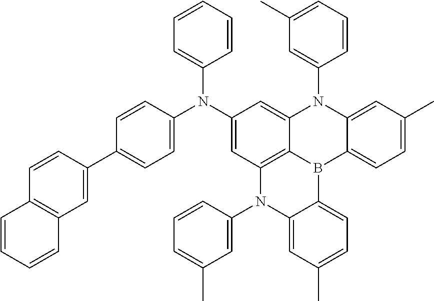 [SMILES: Cc1cccc(N2c3cc(C)ccc3B3c4ccc(C)cc4N(c4cccc(C)c4)c4cc(N(c5ccccc5)c5ccc(-c6ccc7ccccc7c6)cc5)cc2c43)c1]

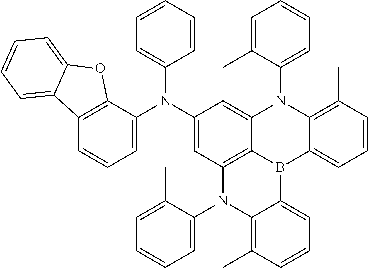 [SMILES: Cc1ccccc1N1c2cc(N(c3ccccc3)c3cccc4c3oc3ccccc34)cc3c2B(c2cccc(C)c21)c1cccc(C)c1N3c1ccccc1C]

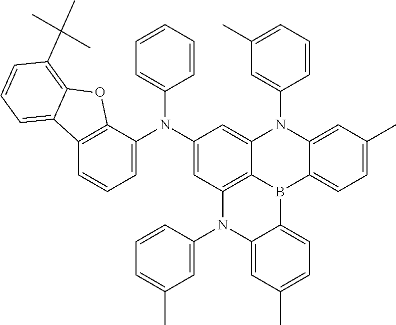 [SMILES: Cc1cccc(N2c3cc(C)ccc3B3c4ccc(C)cc4N(c4cccc(C)c4)c4cc(N(c5ccccc5)c5cccc6c5oc5c(C(C)(C)C)cccc56)cc2c43)c1]

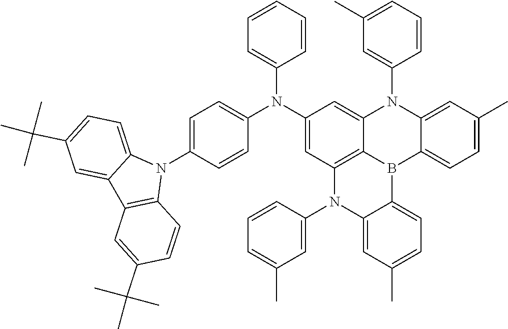 [SMILES: Cc1cccc(N2c3cc(C)ccc3B3c4ccc(C)cc4N(c4cccc(C)c4)c4cc(N(c5ccccc5)c5ccc(-n6c7ccc(C(C)(C)C)cc7c7cc(C(C)(C)C)ccc76)cc5)cc2c43)c1]

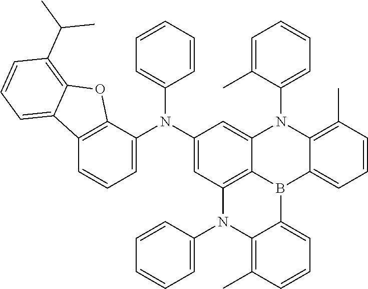 [SMILES: Cc1ccccc1N1c2cc(N(c3ccccc3)c3cccc4c3oc3c(C(C)C)cccc34)cc3c2B(c2cccc(C)c2N3c2ccccc2)c2cccc(C)c21]

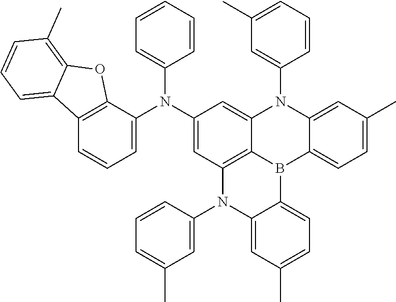 [SMILES: Cc1cccc(N2c3cc(C)ccc3B3c4ccc(C)cc4N(c4cccc(C)c4)c4cc(N(c5ccccc5)c5cccc6c5oc5c(C)cccc56)cc2c43)c1]

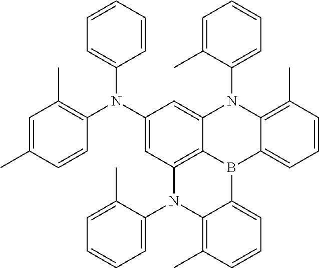 [SMILES: Cc1ccc(N(c2ccccc2)c2cc3c4c(c2)N(c2ccccc2C)c2c(C)cccc2B4c2cccc(C)c2N3c2ccccc2C)c(C)c1]

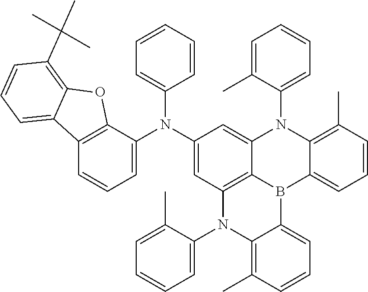 [SMILES: Cc1ccccc1N1c2cc(N(c3ccccc3)c3cccc4c3oc3c(C(C)(C)C)cccc34)cc3c2B(c2cccc(C)c21)c1cccc(C)c1N3c1ccccc1C]

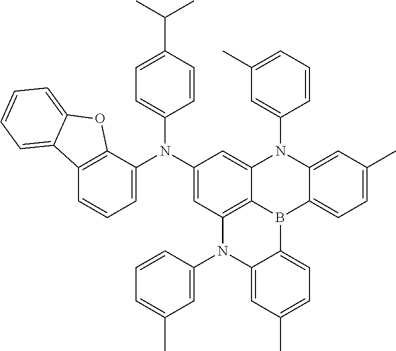 [SMILES: Cc1cccc(N2c3cc(C)ccc3B3c4ccc(C)cc4N(c4cccc(C)c4)c4cc(N(c5ccc(C(C)C)cc5)c5cccc6c5oc5ccccc56)cc2c43)c1]

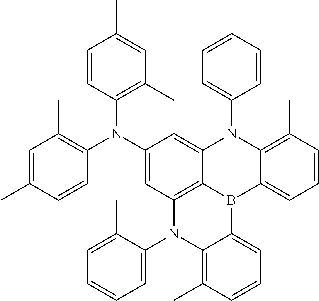 [SMILES: Cc1ccc(N(c2cc3c4c(c2)N(c2ccccc2C)c2c(C)cccc2B4c2cccc(C)c2N3c2ccccc2)c2ccc(C)cc2C)c(C)c1]

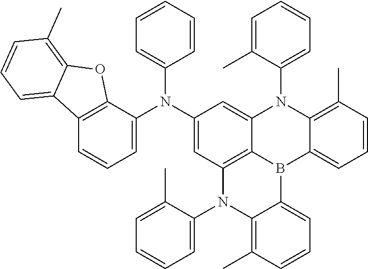 [SMILES: Cc1ccccc1N1c2cc(N(c3ccccc3)c3cccc4c3oc3c(C)cccc34)cc3c2B(c2cccc(C)c21)c1cccc(C)c1N3c1ccccc1C]

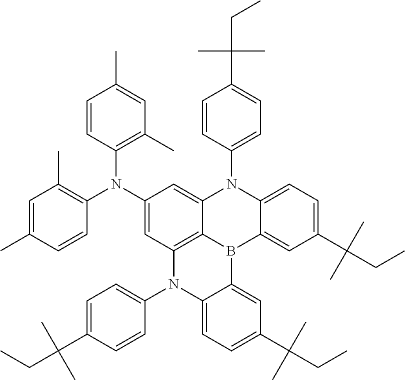 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(C)cc5C)c5ccc(C)cc5C)cc2c43)cc1]

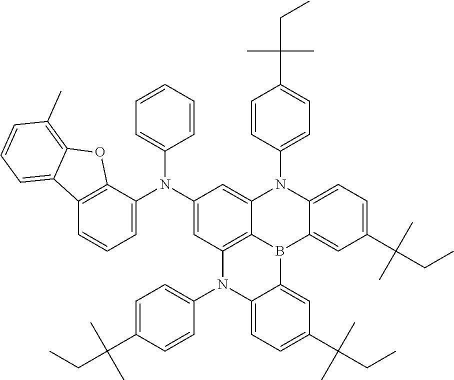 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5cccc6c5oc5c(C)cccc56)cc2c43)cc1]

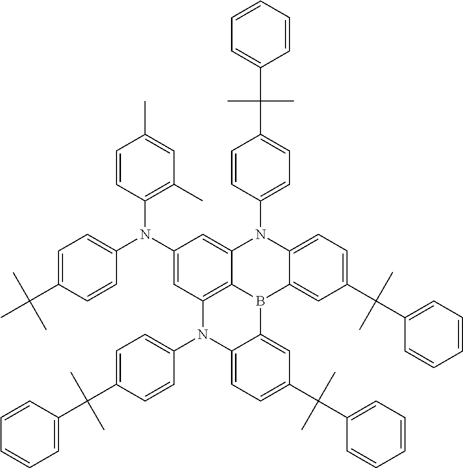 [SMILES: Cc1ccc(N(c2ccc(C(C)(C)C)cc2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c(C)c1]

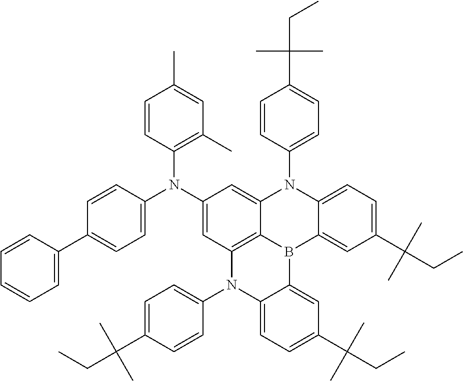 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(-c6ccccc6)cc5)c5ccc(C)cc5C)cc2c43)cc1]

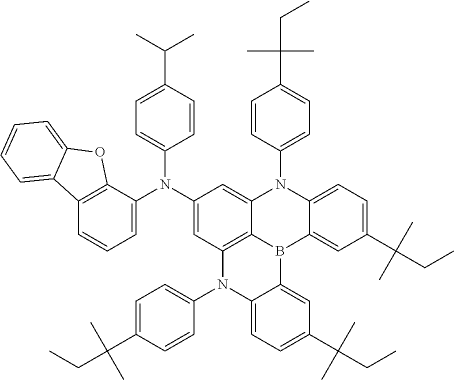 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(C(C)C)cc5)c5cccc6c5oc5ccccc56)cc2c43)cc1]

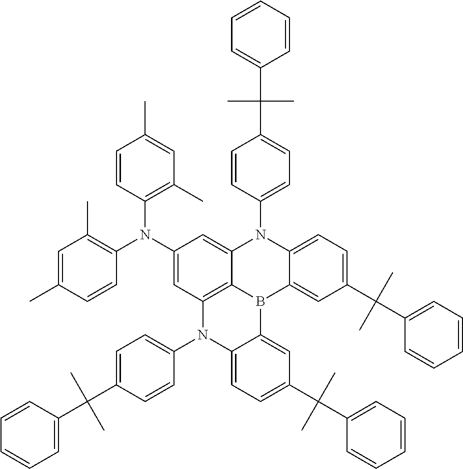 [SMILES: Cc1ccc(N(c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c2ccc(C)cc2C)c(C)c1]

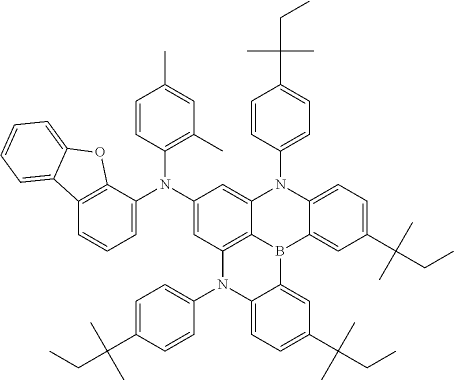 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(C)cc5C)c5cccc6c5oc5ccccc56)cc2c43)cc1]

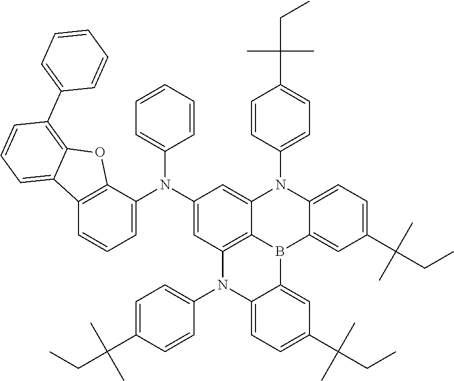 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5cccc6c5oc5c(-c7ccccc7)cccc56)cc2c43)cc1]

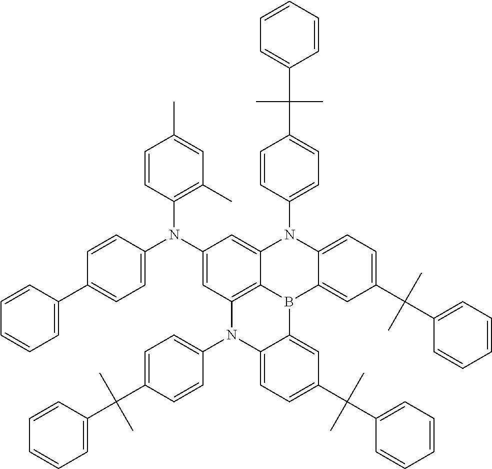 [SMILES: Cc1ccc(N(c2ccc(-c3ccccc3)cc2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c(C)c1]

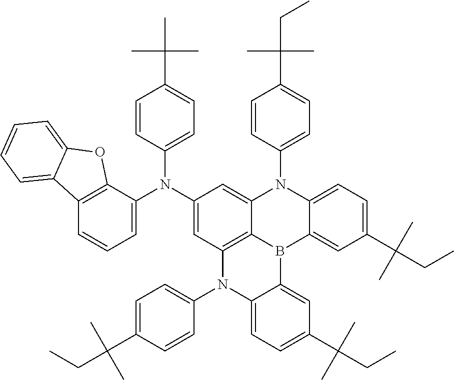 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(C(C)(C)C)cc5)c5cccc6c5oc5ccccc56)cc2c43)cc1]

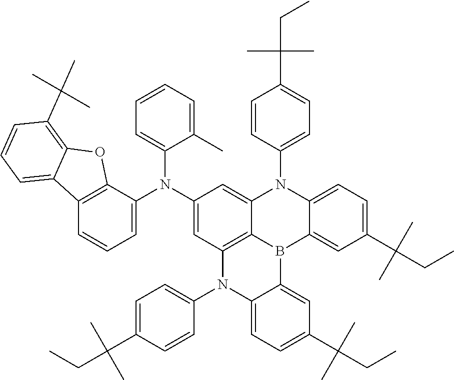 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5C)c5cccc6c5oc5c(C(C)(C)C)cccc56)cc2c43)cc1]

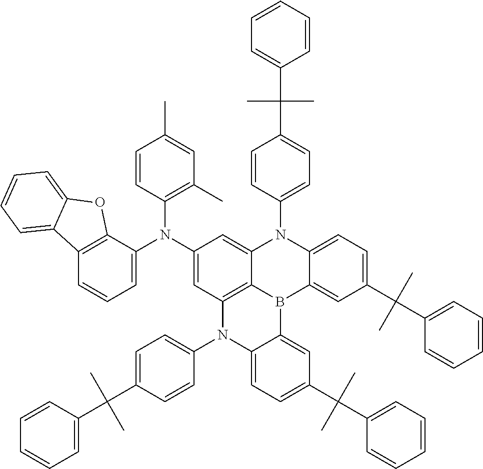 [SMILES: Cc1ccc(N(c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c2cccc3c2oc2ccccc23)c(C)c1]

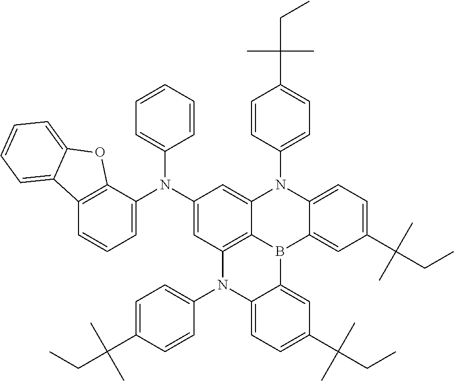 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5cccc6c5oc5ccccc56)cc2c43)cc1]

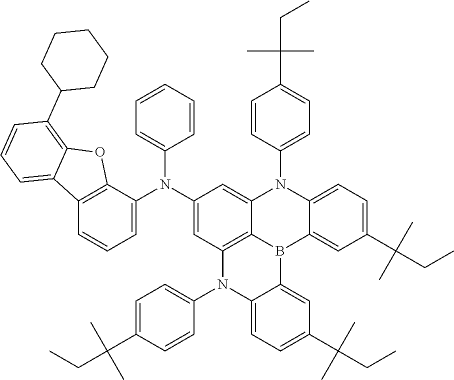 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5cccc6c5oc5c(C7CCCCC7)cccc56)cc2c43)cc1]

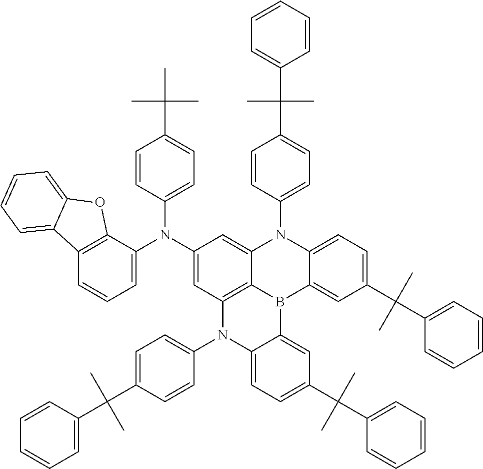 [SMILES: CC(C)(C)c1ccc(N(c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c2cccc3c2oc2ccccc23)cc1]

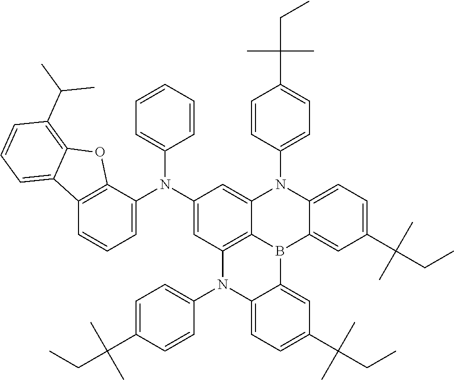 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5cccc6c5oc5c(C(C)C)cccc56)cc2c43)cc1]

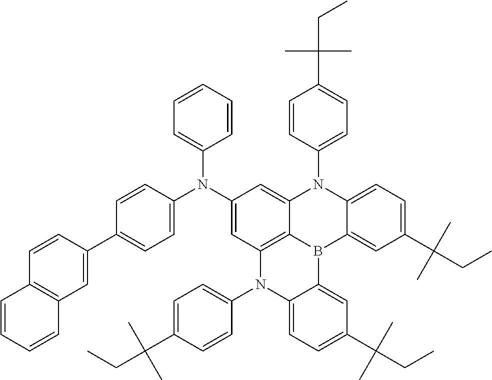 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5ccc(-c6ccc7ccccc7c6)cc5)cc2c43)cc1]

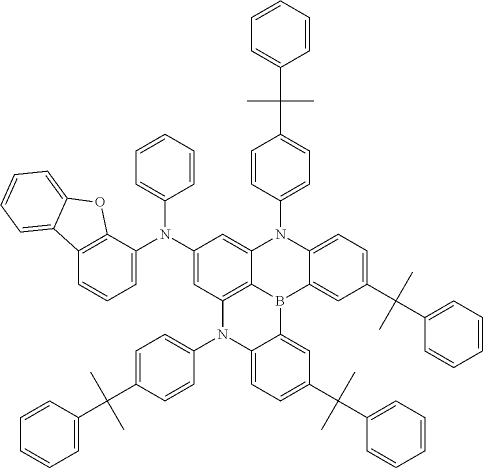 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccccc5)c5cccc6c5oc5ccccc56)cc2c43)cc1]

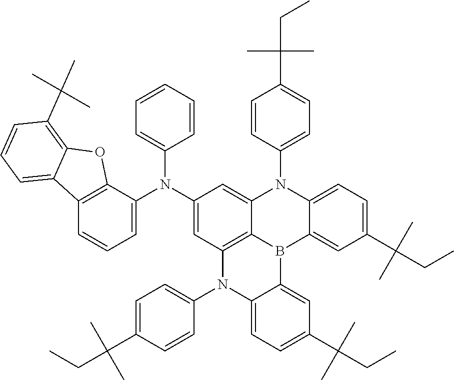 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5cccc6c5oc5c(C(C)(C)C)cccc56)cc2c43)cc1]

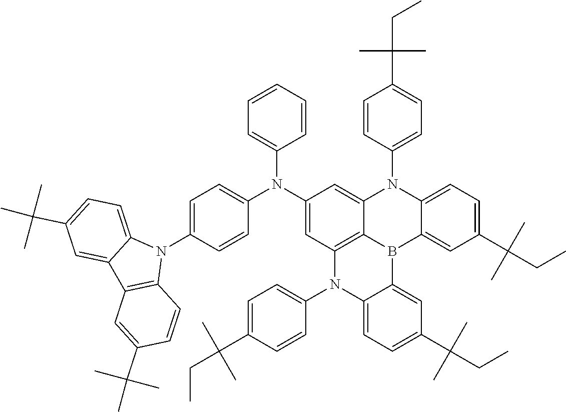 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5ccc(-n6c7ccc(C(C)(C)C)cc7c7cc(C(C)(C)C)ccc76)cc5)cc2c43)cc1]

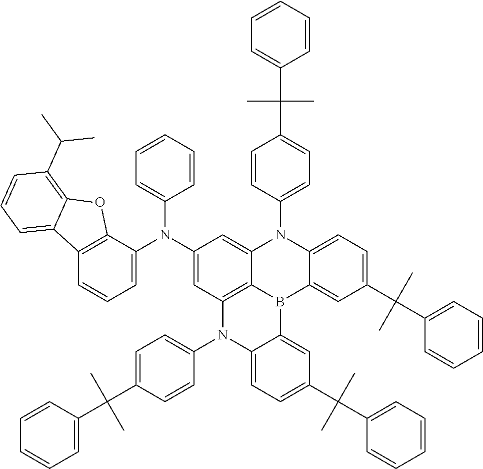 [SMILES: CC(C)c1cccc2c1oc1c(N(c3ccccc3)c3cc4c5c(c3)N(c3ccc(C(C)(C)c6ccccc6)cc3)c3ccc(C(C)(C)c6ccccc6)cc3B5c3cc(C(C)(C)c5ccccc5)ccc3N4c3ccc(C(C)(C)c4ccccc4)cc3)cccc12]

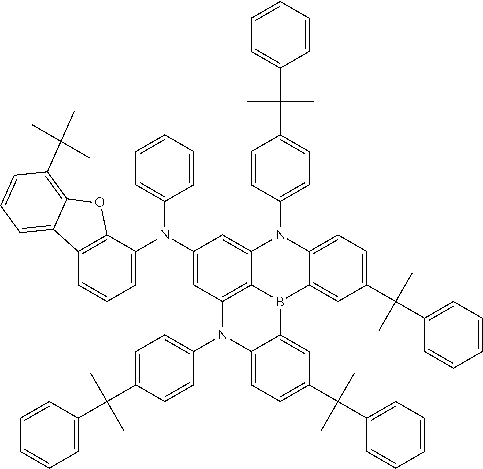 [SMILES: CC(C)(C)c1cccc2c1oc1c(N(c3ccccc3)c3cc4c5c(c3)N(c3ccc(C(C)(C)c6ccccc6)cc3)c3ccc(C(C)(C)c6ccccc6)cc3B5c3cc(C(C)(C)c5ccccc5)ccc3N4c3ccc(C(C)(C)c4ccccc4)cc3)cccc12]

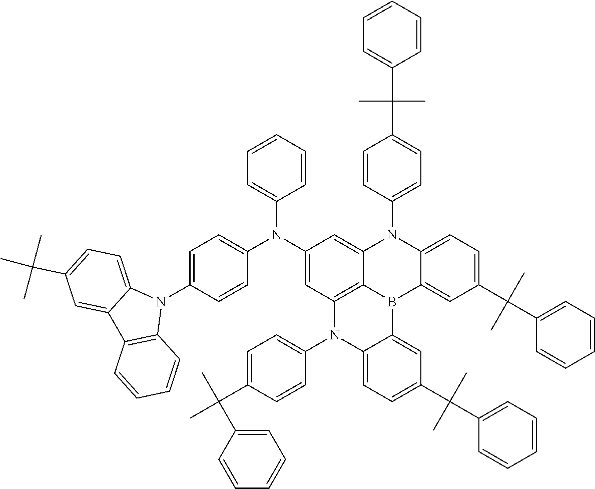 [SMILES: CC(C)(C)c1ccc2c(c1)c1ccccc1n2-c1ccc(N(c2ccccc2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)cc1]

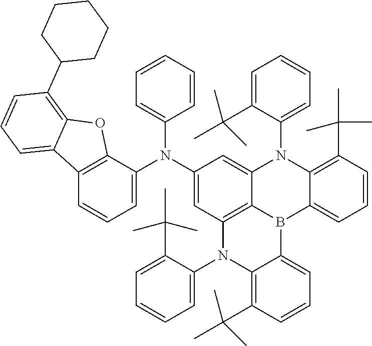 [SMILES: CC(C)(C)c1ccccc1N1c2cc(N(c3ccccc3)c3cccc4c3oc3c(C5CCCCC5)cccc34)cc3c2B(c2cccc(C(C)(C)C)c21)c1cccc(C(C)(C)C)c1N3c1ccccc1C(C)(C)C]

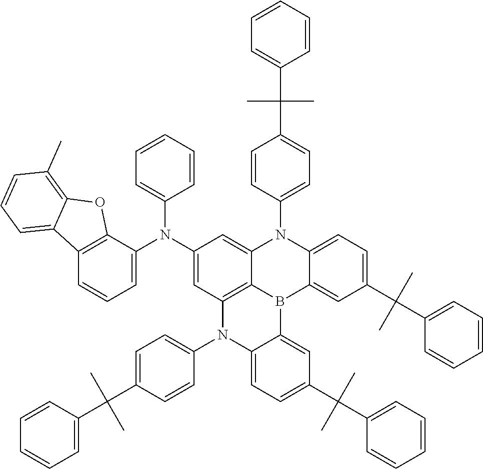 [SMILES: Cc1cccc2c1oc1c(N(c3ccccc3)c3cc4c5c(c3)N(c3ccc(C(C)(C)c6ccccc6)cc3)c3ccc(C(C)(C)c6ccccc6)cc3B5c3cc(C(C)(C)c5ccccc5)ccc3N4c3ccc(C(C)(C)c4ccccc4)cc3)cccc12]

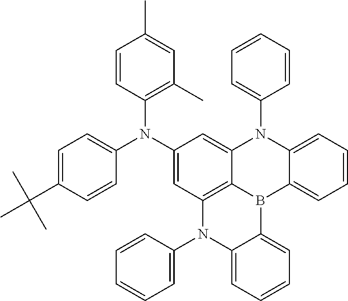 [SMILES: Cc1ccc(N(c2ccc(C(C)(C)C)cc2)c2cc3c4c(c2)N(c2ccccc2)c2ccccc2B4c2ccccc2N3c2ccccc2)c(C)c1]

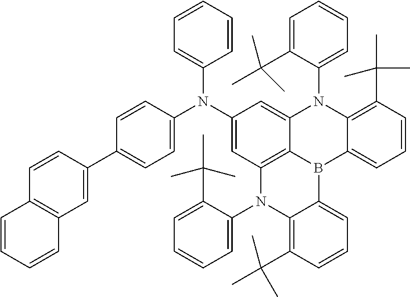 [SMILES: CC(C)(C)c1ccccc1N1c2cc(N(c3ccccc3)c3ccc(-c4ccc5ccccc5c4)cc3)cc3c2B(c2cccc(C(C)(C)C)c21)c1cccc(C(C)(C)C)c1N3c1ccccc1C(C)(C)C]

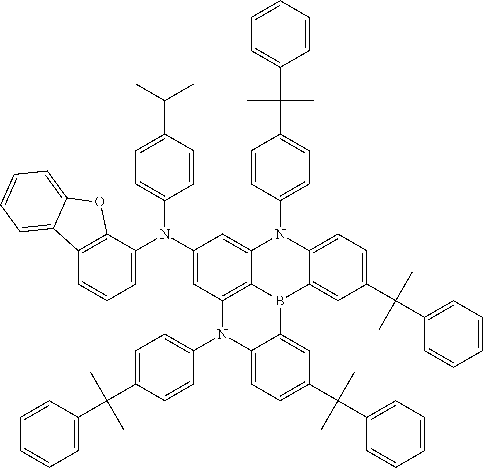 [SMILES: CC(C)c1ccc(N(c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c2cccc3c2oc2ccccc23)cc1]

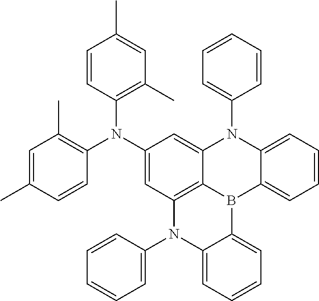 [SMILES: Cc1ccc(N(c2cc3c4c(c2)N(c2ccccc2)c2ccccc2B4c2ccccc2N3c2ccccc2)c2ccc(C)cc2C)c(C)c1]

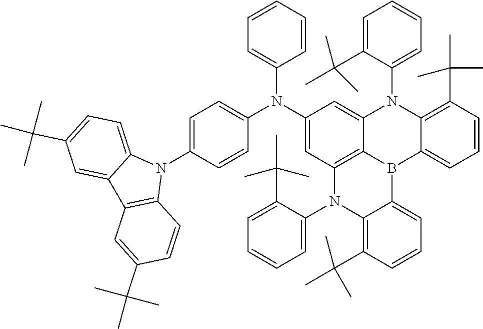 [SMILES: CC(C)(C)c1ccc2c(c1)c1cc(C(C)(C)C)ccc1n2-c1ccc(N(c2ccccc2)c2cc3c4c(c2)N(c2ccccc2C(C)(C)C)c2c(cccc2C(C)(C)C)B4c2cccc(C(C)(C)C)c2N3c2ccccc2C(C)(C)C)cc1]

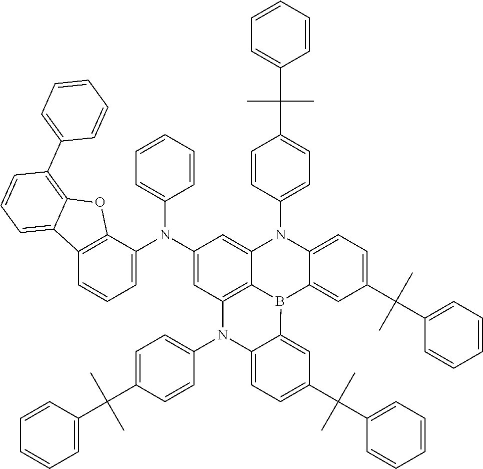 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccccc5)c5cccc6c5oc5c(-c7ccccc7)cccc56)cc2c43)cc1]

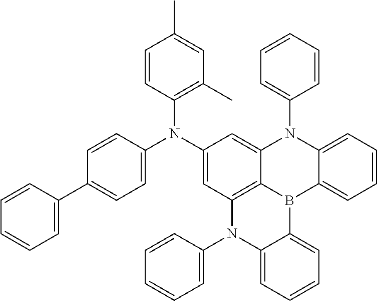 [SMILES: Cc1ccc(N(c2ccc(-c3ccccc3)cc2)c2cc3c4c(c2)N(c2ccccc2)c2ccccc2B4c2ccccc2N3c2ccccc2)c(C)c1]

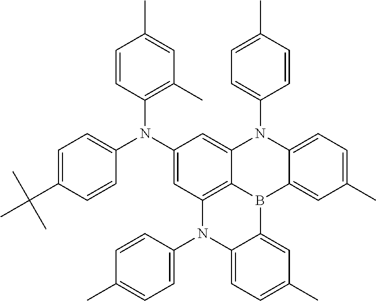 [SMILES: Cc1ccc(N2c3ccc(C)cc3B3c4cc(C)ccc4N(c4ccc(C)cc4)c4cc(N(c5ccc(C(C)(C)C)cc5)c5ccc(C)cc5C)cc2c43)cc1]

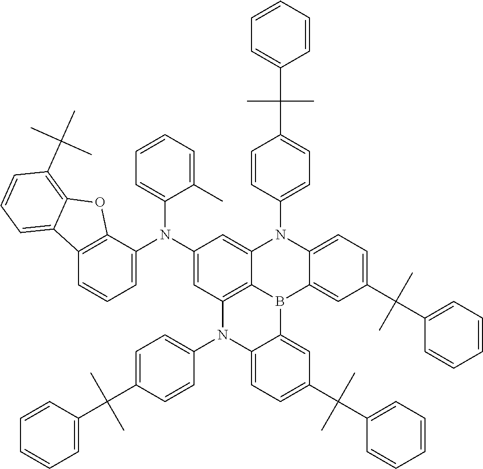 [SMILES: Cc1ccccc1N(c1cc2c3c(c1)N(c1ccc(C(C)(C)c4ccccc4)cc1)c1ccc(C(C)(C)c4ccccc4)cc1B3c1cc(C(C)(C)c3ccccc3)ccc1N2c1ccc(C(C)(C)c2ccccc2)cc1)c1cccc2c1oc1c(C(C)(C)C)cccc12]

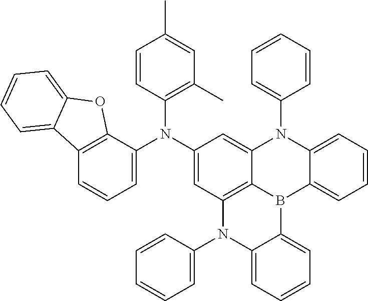 [SMILES: Cc1ccc(N(c2cc3c4c(c2)N(c2ccccc2)c2ccccc2B4c2ccccc2N3c2ccccc2)c2cccc3c2oc2ccccc23)c(C)c1]

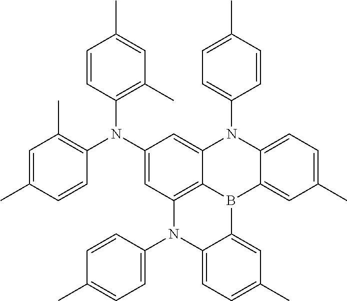

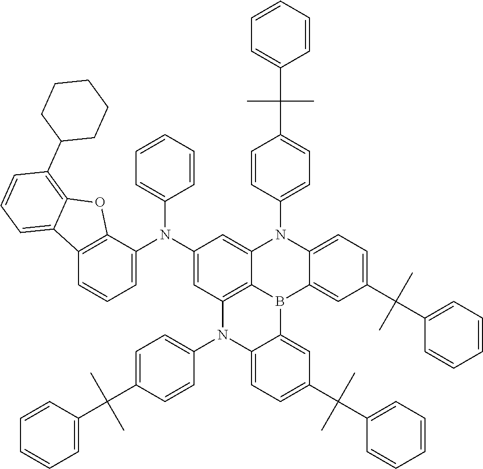 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccccc5)c5cccc6c5oc5c(C7CCCCC7)cccc56)cc2c43)cc1]

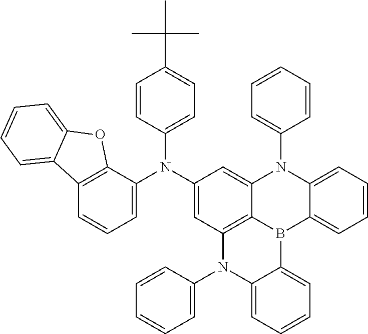 [SMILES: CC(C)(C)c1ccc(N(c2cc3c4c(c2)N(c2ccccc2)c2ccccc2B4c2ccccc2N3c2ccccc2)c2cccc3c2oc2ccccc23)cc1]

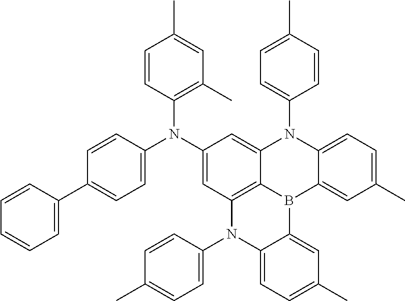 [SMILES: Cc1ccc(N2c3ccc(C)cc3B3c4cc(C)ccc4N(c4ccc(C)cc4)c4cc(N(c5ccc(-c6ccccc6)cc5)c5ccc(C)cc5C)cc2c43)cc1]

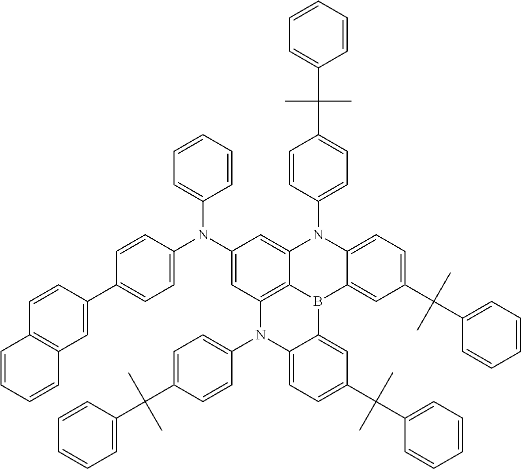 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccccc5)c5ccc(-c6ccc7ccccc7c6)cc5)cc2c43)cc1]

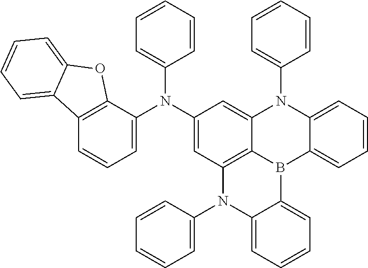 [SMILES: c1ccc(N2c3ccccc3B3c4ccccc4N(c4ccccc4)c4cc(N(c5ccccc5)c5cccc6c5oc5ccccc56)cc2c43)cc1]

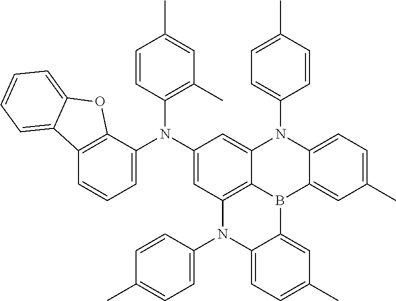 [SMILES: Cc1ccc(N2c3ccc(C)cc3B3c4cc(C)ccc4N(c4ccc(C)cc4)c4cc(N(c5ccc(C)cc5C)c5cccc6c5oc5ccccc56)cc2c43)cc1]

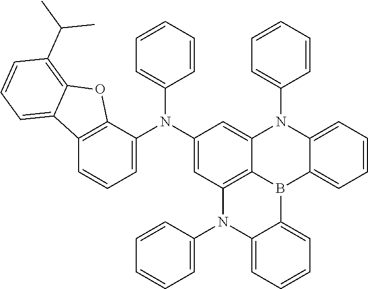 [SMILES: CC(C)c1cccc2c1oc1c(N(c3ccccc3)c3cc4c5c(c3)N(c3ccccc3)c3ccccc3B5c3ccccc3N4c3ccccc3)cccc12]

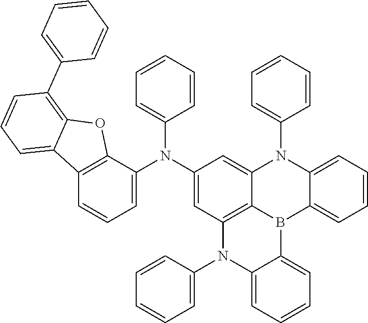 [SMILES: c1ccc(-c2cccc3c2oc2c(N(c4ccccc4)c4cc5c6c(c4)N(c4ccccc4)c4ccccc4B6c4ccccc4N5c4ccccc4)cccc23)cc1]

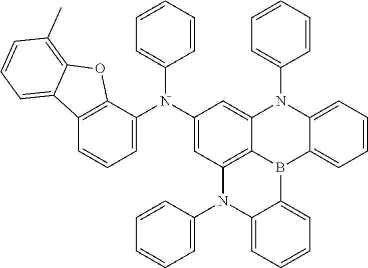 [SMILES: Cc1cccc2c1oc1c(N(c3ccccc3)c3cc4c5c(c3)N(c3ccccc3)c3ccccc3B5c3ccccc3N4c3ccccc3)cccc12]

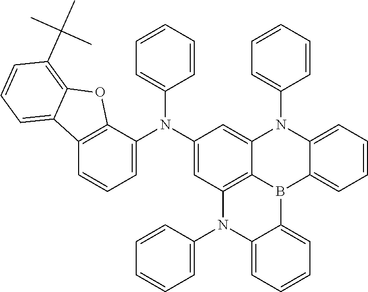 [SMILES: CC(C)(C)c1cccc2c1oc1c(N(c3ccccc3)c3cc4c5c(c3)N(c3ccccc3)c3ccccc3B5c3ccccc3N4c3ccccc3)cccc12]

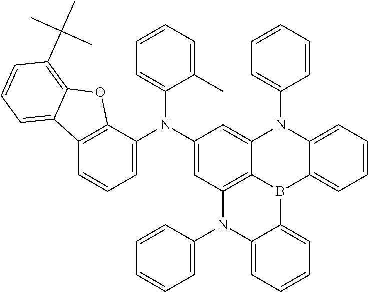 [SMILES: Cc1ccccc1N(c1cc2c3c(c1)N(c1ccccc1)c1ccccc1B3c1ccccc1N2c1ccccc1)c1cccc2c1oc1c(C(C)(C)C)cccc12]

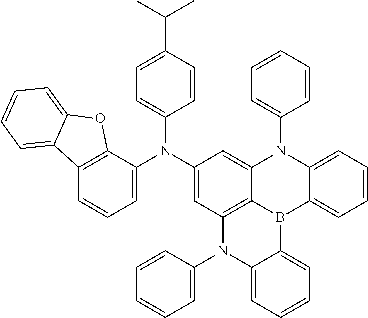 [SMILES: CC(C)c1ccc(N(c2cc3c4c(c2)N(c2ccccc2)c2ccccc2B4c2ccccc2N3c2ccccc2)c2cccc3c2oc2ccccc23)cc1]

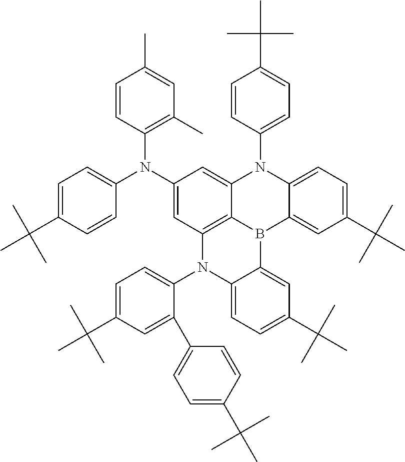 [SMILES: Cc1ccc(N(c2ccc(C(C)(C)C)cc2)c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)c(C)c1]

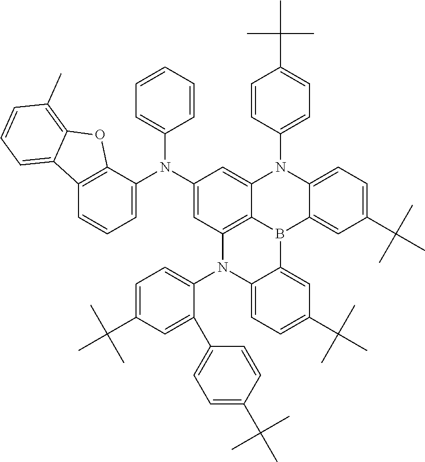 [SMILES: Cc1cccc2c1oc1c(N(c3ccccc3)c3cc4c5c(c3)N(c3ccc(C(C)(C)C)cc3-c3ccc(C(C)(C)C)cc3)c3ccc(C(C)(C)C)cc3B5c3cc(C(C)(C)C)ccc3N4c3ccc(C(C)(C)C)cc3)cccc12]

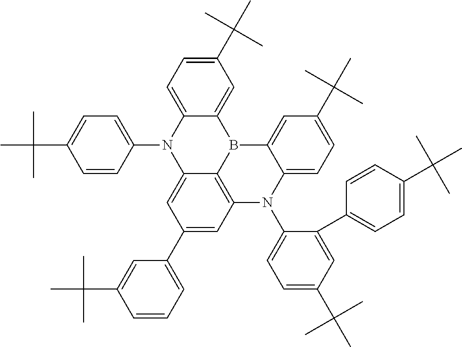 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(-c5cccc(C(C)(C)C)c5)cc2c43)cc1]

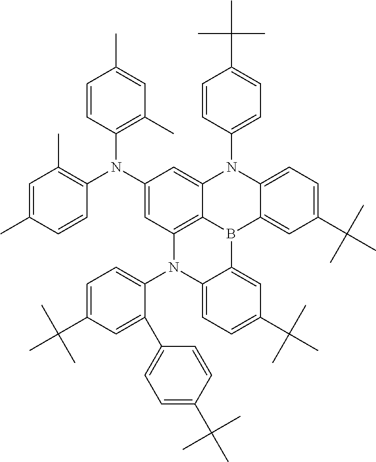 [SMILES: Cc1ccc(N(c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)c2ccc(C)cc2C)c(C)c1]

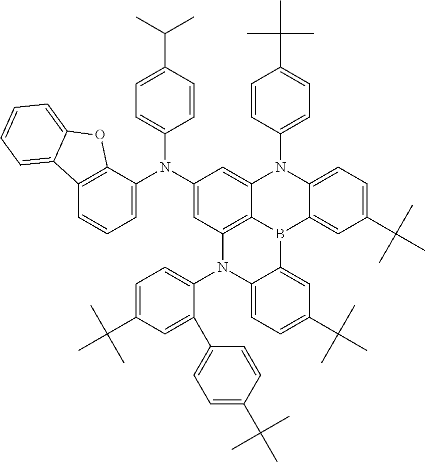 [SMILES: CC(C)c1ccc(N(c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)c2cccc3c2oc2ccccc23)cc1]

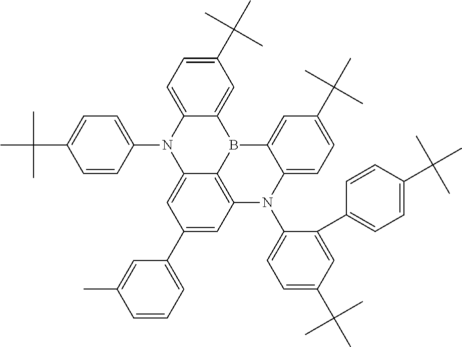 [SMILES: Cc1cccc(-c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)c1]

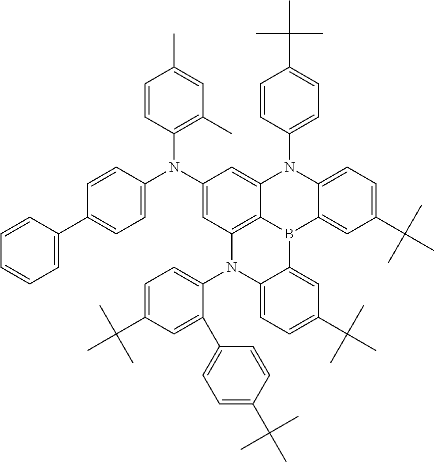 [SMILES: Cc1ccc(N(c2ccc(-c3ccccc3)cc2)c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)c(C)c1]

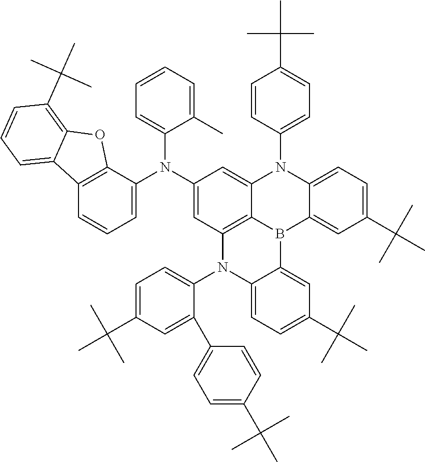 [SMILES: Cc1ccccc1N(c1cc2c3c(c1)N(c1ccc(C(C)(C)C)cc1-c1ccc(C(C)(C)C)cc1)c1ccc(C(C)(C)C)cc1B3c1cc(C(C)(C)C)ccc1N2c1ccc(C(C)(C)C)cc1)c1cccc2c1oc1c(C(C)(C)C)cccc12]

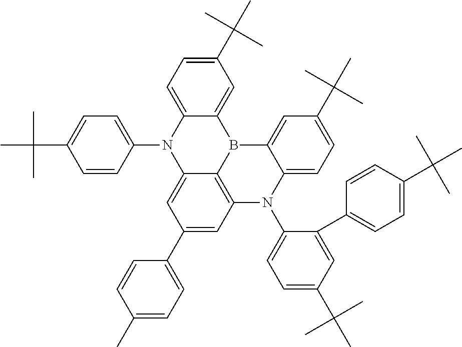 [SMILES: Cc1ccc(-c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)cc1]

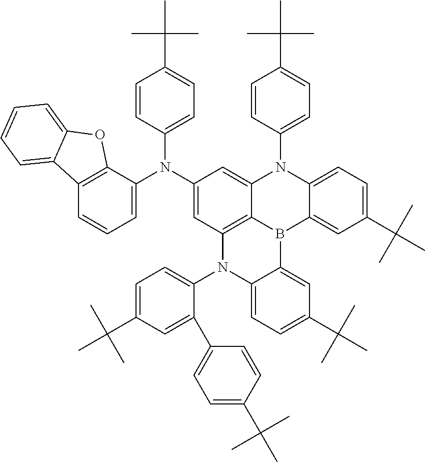 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccc(C(C)(C)C)cc5)c5cccc6c5oc5ccccc56)cc2c43)cc1]

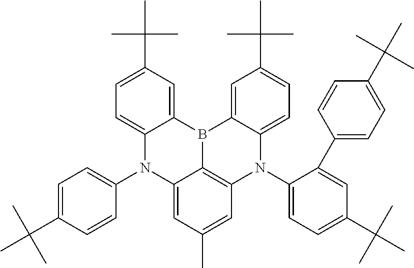 [SMILES: Cc1cc2c3c(c1)N(c1ccc(C(C)(C)C)cc1-c1ccc(C(C)(C)C)cc1)c1ccc(C(C)(C)C)cc1B3c1cc(C(C)(C)C)ccc1N2c1ccc(C(C)(C)C)cc1]

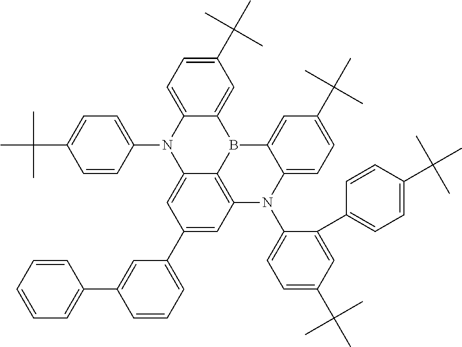 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(-c5cccc(-c6ccccc6)c5)cc2c43)cc1]

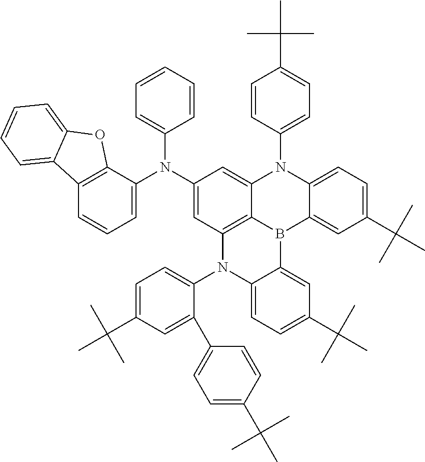 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccccc5)c5cccc6c5oc5ccccc56)cc2c43)cc1]

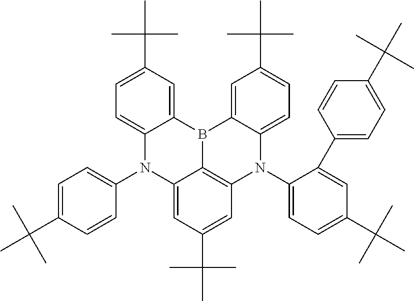 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(C(C)(C)C)cc2c43)cc1]

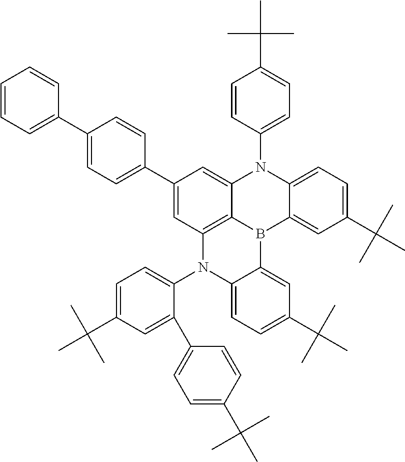 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(-c5ccc(-c6ccccc6)cc5)cc2c43)cc1]

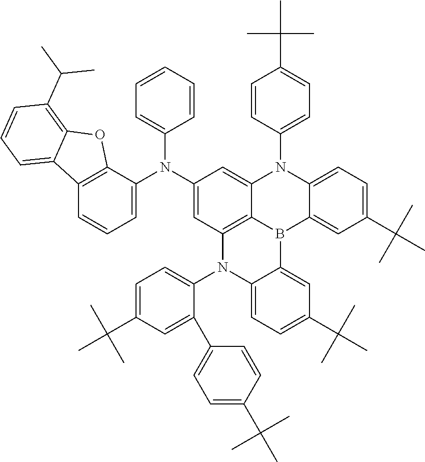 [SMILES: CC(C)c1cccc2c1oc1c(N(c3ccccc3)c3cc4c5c(c3)N(c3ccc(C(C)(C)C)cc3-c3ccc(C(C)(C)C)cc3)c3ccc(C(C)(C)C)cc3B5c3cc(C(C)(C)C)ccc3N4c3ccc(C(C)(C)C)cc3)cccc12]

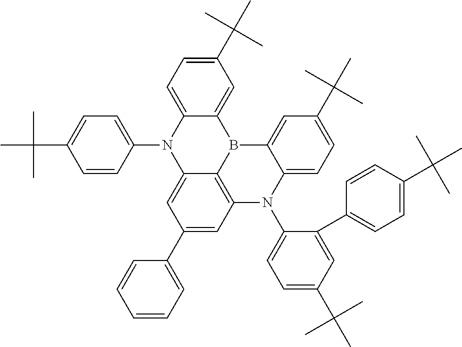 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(-c5ccccc5)cc2c43)cc1]

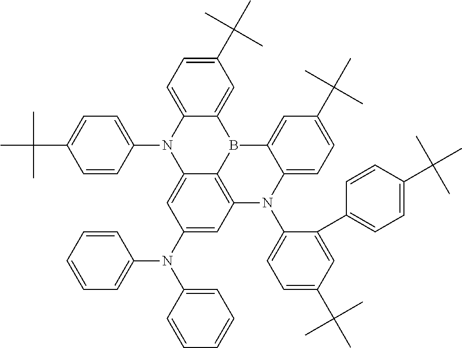 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1]

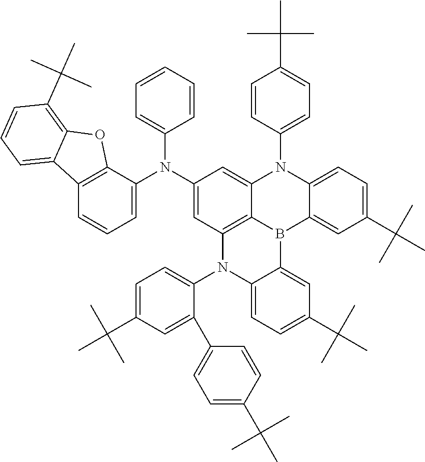 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccccc5)c5cccc6c5oc5c(C(C)(C)C)cccc56)cc2c43)cc1]

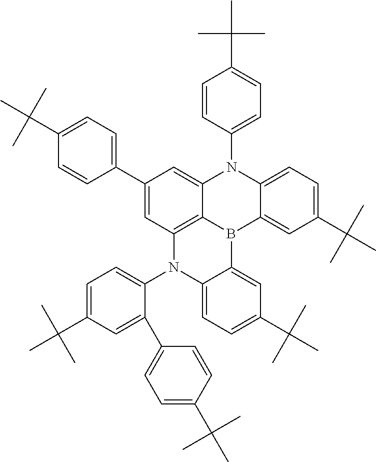 [SMILES: CC(C)(C)c1ccc(-c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)cc1]

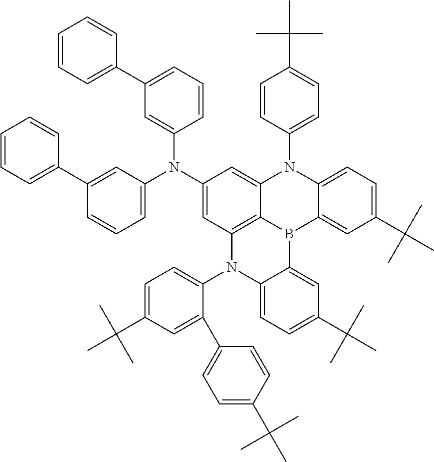 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5cccc(-c6ccccc6)c5)c5cccc(-c6ccccc6)c5)cc2c43)cc1]

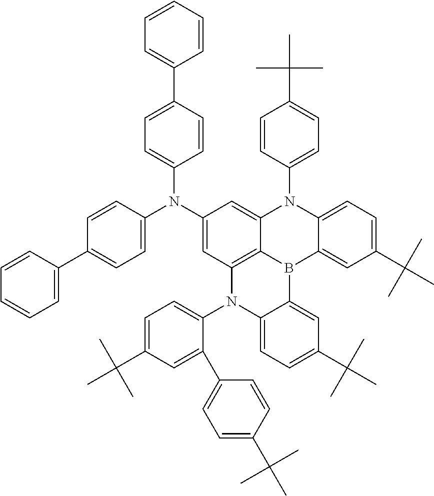 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccc(-c6ccccc6)cc5)c5ccc(-c6ccccc6)cc5)cc2c43)cc1]

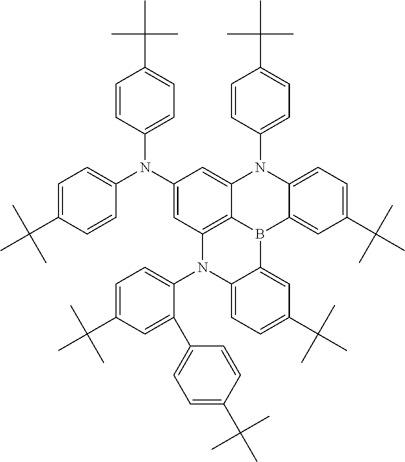 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccc(C(C)(C)C)cc5)c5ccc(C(C)(C)C)cc5)cc2c43)cc1]

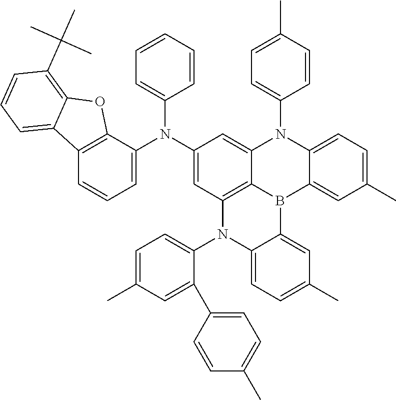 [SMILES: Cc1ccc(-c2cc(C)ccc2N2c3ccc(C)cc3B3c4cc(C)ccc4N(c4ccc(C)cc4)c4cc(N(c5ccccc5)c5cccc6c5oc5c(C(C)(C)C)cccc56)cc2c43)cc1]

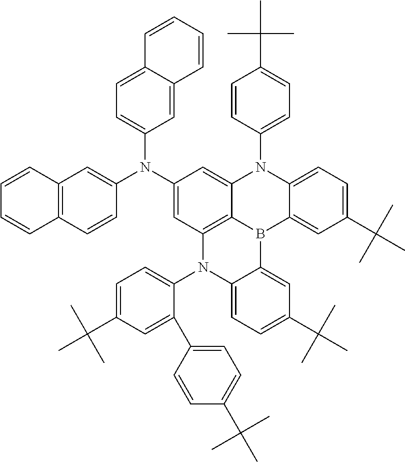 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccc6ccccc6c5)c5ccc6ccccc6c5)cc2c43)cc1]

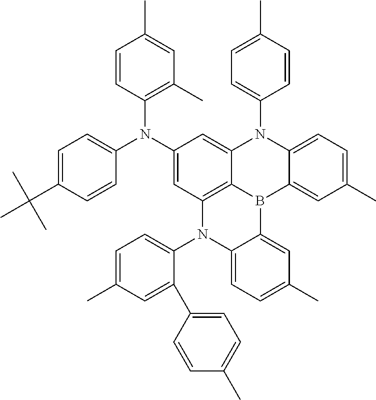 [SMILES: Cc1ccc(-c2cc(C)ccc2N2c3ccc(C)cc3B3c4cc(C)ccc4N(c4ccc(C)cc4)c4cc(N(c5ccc(C(C)(C)C)cc5)c5ccc(C)cc5C)cc2c43)cc1]

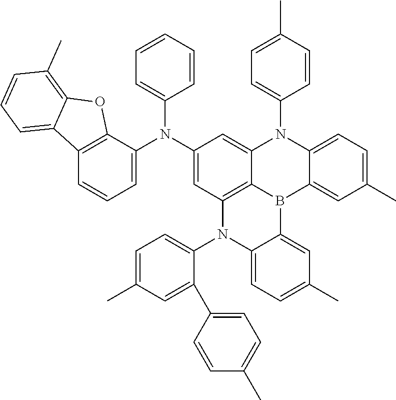 [SMILES: Cc1ccc(-c2cc(C)ccc2N2c3ccc(C)cc3B3c4cc(C)ccc4N(c4ccc(C)cc4)c4cc(N(c5ccccc5)c5cccc6c5oc5c(C)cccc56)cc2c43)cc1]

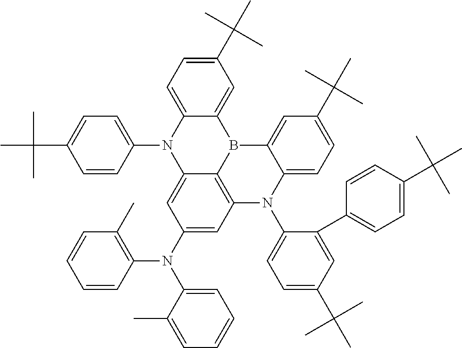 [SMILES: Cc1ccccc1N(c1cc2c3c(c1)N(c1ccc(C(C)(C)C)cc1-c1ccc(C(C)(C)C)cc1)c1ccc(C(C)(C)C)cc1B3c1cc(C(C)(C)C)ccc1N2c1ccc(C(C)(C)C)cc1)c1ccccc1C]

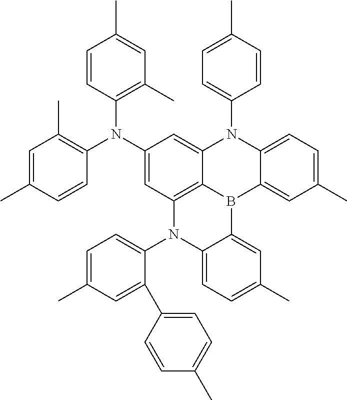

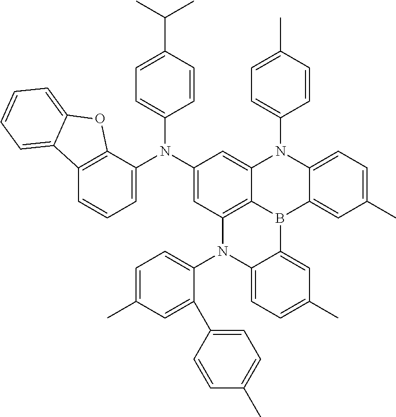 [SMILES: Cc1ccc(-c2cc(C)ccc2N2c3ccc(C)cc3B3c4cc(C)ccc4N(c4ccc(C)cc4)c4cc(N(c5ccc(C(C)C)cc5)c5cccc6c5oc5ccccc56)cc2c43)cc1]

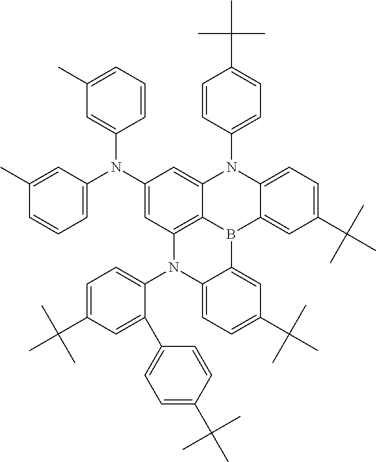 [SMILES: Cc1cccc(N(c2cccc(C)c2)c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)c1]

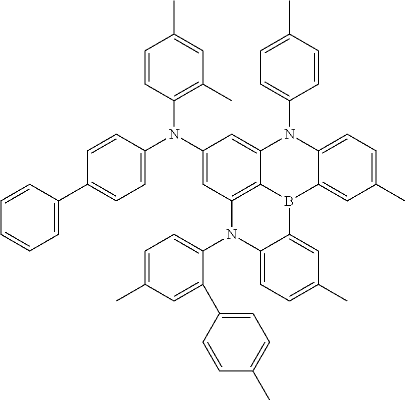 [SMILES: Cc1ccc(-c2cc(C)ccc2N2c3ccc(C)cc3B3c4cc(C)ccc4N(c4ccc(C)cc4)c4cc(N(c5ccc(-c6ccccc6)cc5)c5ccc(C)cc5C)cc2c43)cc1]

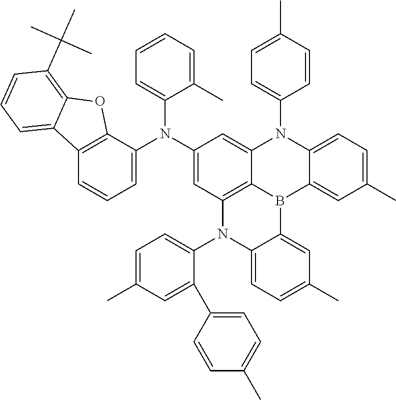 [SMILES: Cc1ccc(-c2cc(C)ccc2N2c3ccc(C)cc3B3c4cc(C)ccc4N(c4ccc(C)cc4)c4cc(N(c5ccccc5C)c5cccc6c5oc5c(C(C)(C)C)cccc56)cc2c43)cc1]

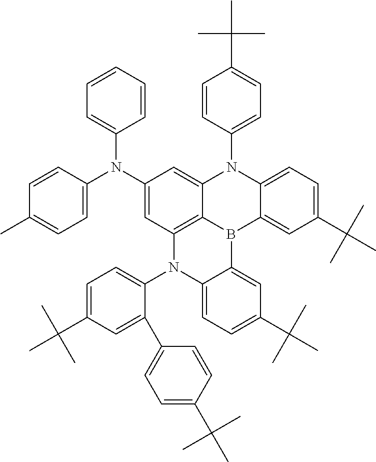 [SMILES: Cc1ccc(N(c2ccccc2)c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)cc1]

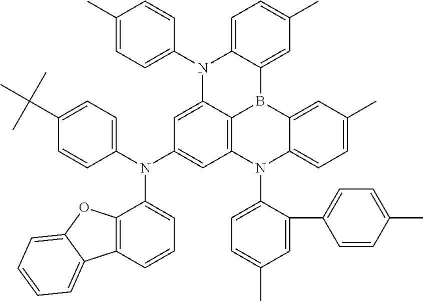 [SMILES: Cc1ccc(-c2cc(C)ccc2N2c3ccc(C)cc3B3c4cc(C)ccc4N(c4ccc(C)cc4)c4cc(N(c5ccc(C(C)(C)C)cc5)c5cccc6c5oc5ccccc56)cc2c43)cc1]

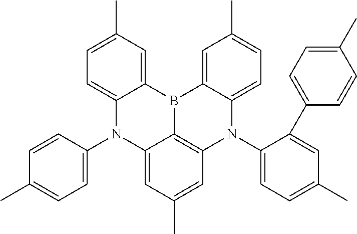

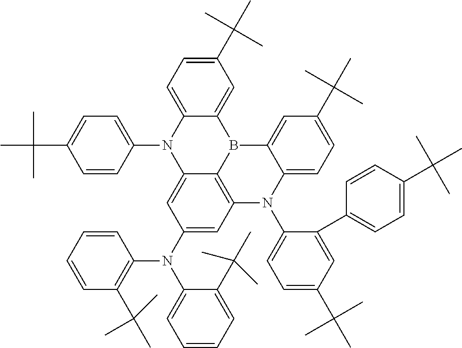 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccccc5C(C)(C)C)c5ccccc5C(C)(C)C)cc2c43)cc1]

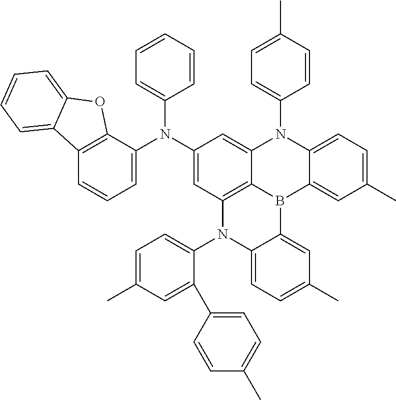 [SMILES: Cc1ccc(-c2cc(C)ccc2N2c3ccc(C)cc3B3c4cc(C)ccc4N(c4ccc(C)cc4)c4cc(N(c5ccccc5)c5cccc6c5oc5ccccc56)cc2c43)cc1]

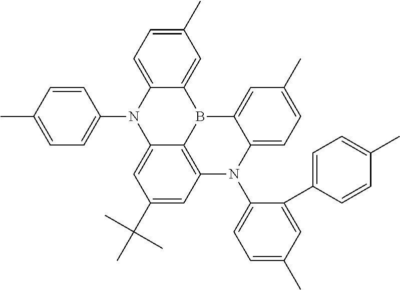

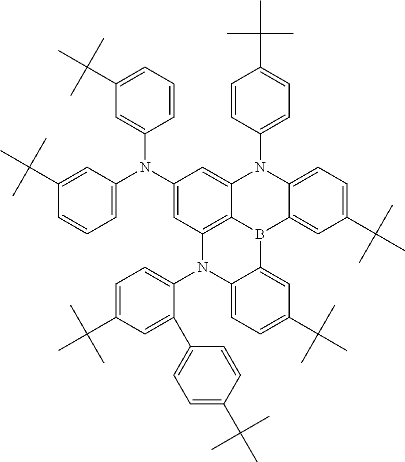 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5cccc(C(C)(C)C)c5)c5cccc(C(C)(C)C)c5)cc2c43)cc1]

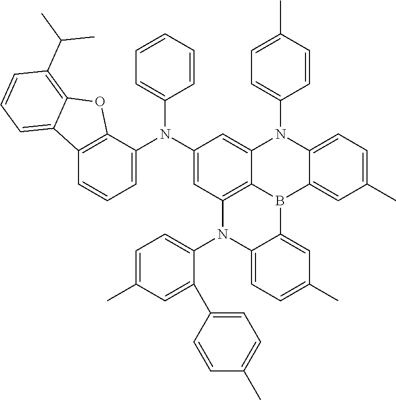 [SMILES: Cc1ccc(-c2cc(C)ccc2N2c3ccc(C)cc3B3c4cc(C)ccc4N(c4ccc(C)cc4)c4cc(N(c5ccccc5)c5cccc6c5oc5c(C(C)C)cccc56)cc2c43)cc1]

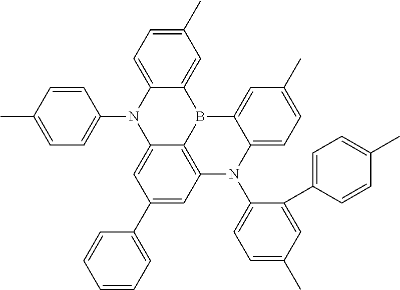

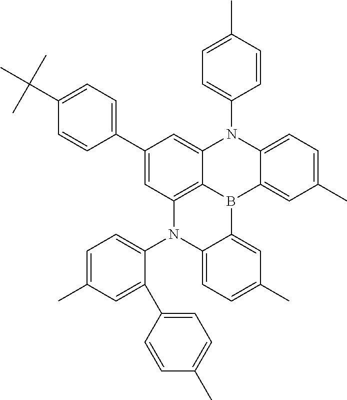 [SMILES: Cc1ccc(-c2cc(C)ccc2N2c3ccc(C)cc3B3c4cc(C)ccc4N(c4ccc(C)cc4)c4cc(-c5ccc(C(C)(C)C)cc5)cc2c43)cc1]

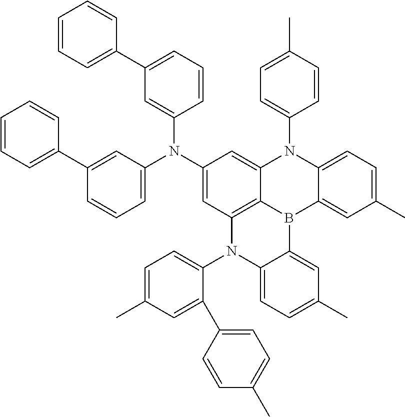 [SMILES: Cc1ccc(-c2cc(C)ccc2N2c3ccc(C)cc3B3c4cc(C)ccc4N(c4ccc(C)cc4)c4cc(N(c5cccc(-c6ccccc6)c5)c5cccc(-c6ccccc6)c5)cc2c43)cc1]

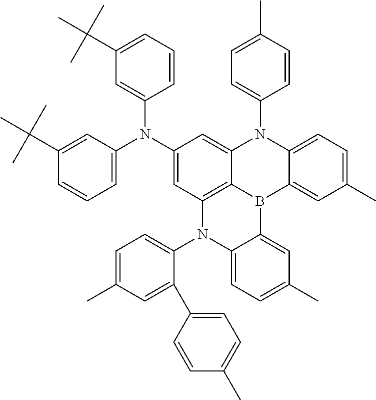 [SMILES: Cc1ccc(-c2cc(C)ccc2N2c3ccc(C)cc3B3c4cc(C)ccc4N(c4ccc(C)cc4)c4cc(N(c5cccc(C(C)(C)C)c5)c5cccc(C(C)(C)C)c5)cc2c43)cc1]

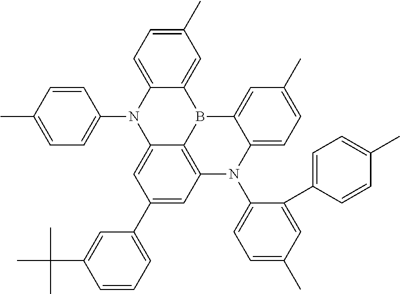

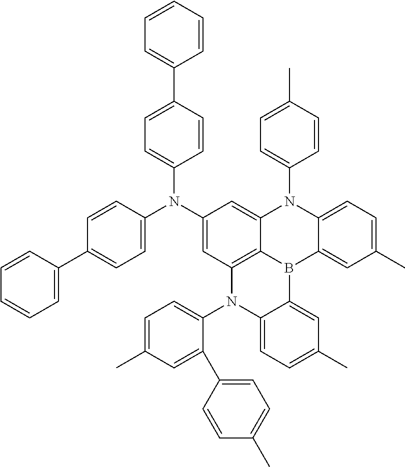 [SMILES: Cc1ccc(-c2cc(C)ccc2N2c3ccc(C)cc3B3c4cc(C)ccc4N(c4ccc(C)cc4)c4cc(N(c5ccc(-c6ccccc6)cc5)c5ccc(-c6ccccc6)cc5)cc2c43)cc1]

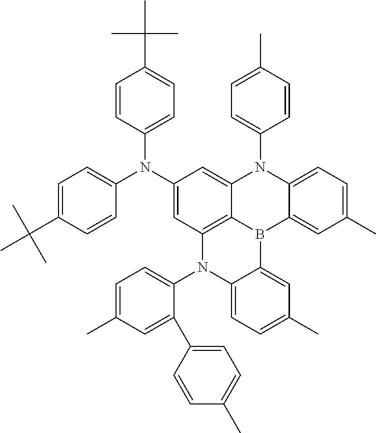 [SMILES: Cc1ccc(-c2cc(C)ccc2N2c3ccc(C)cc3B3c4cc(C)ccc4N(c4ccc(C)cc4)c4cc(N(c5ccc(C(C)(C)C)cc5)c5ccc(C(C)(C)C)cc5)cc2c43)cc1]

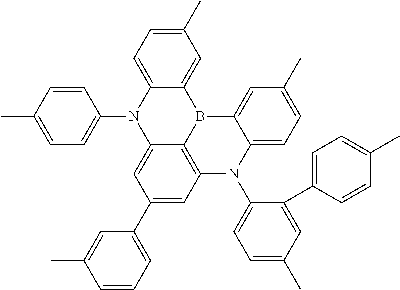

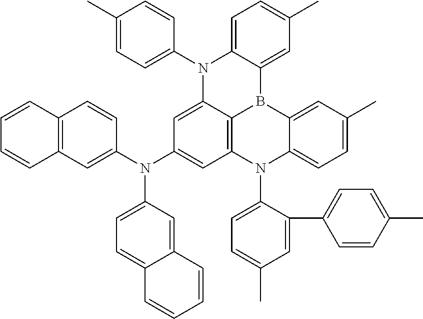 [SMILES: Cc1ccc(-c2cc(C)ccc2N2c3ccc(C)cc3B3c4cc(C)ccc4N(c4ccc(C)cc4)c4cc(N(c5ccc6ccccc6c5)c5ccc6ccccc6c5)cc2c43)cc1]

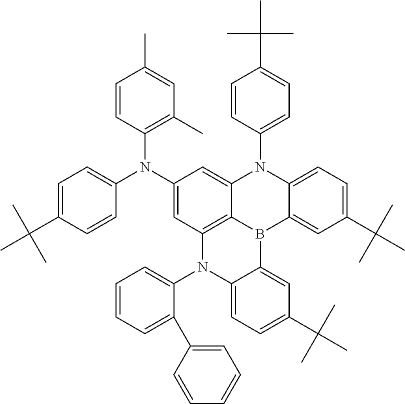 [SMILES: Cc1ccc(N(c2ccc(C(C)(C)C)cc2)c2cc3c4c(c2)N(c2ccccc2-c2ccccc2)c2ccc(C(C)(C)C)cc2B4c2cc(C(C)(C)C)ccc2N3c2ccc(C(C)(C)C)cc2)c(C)c1]

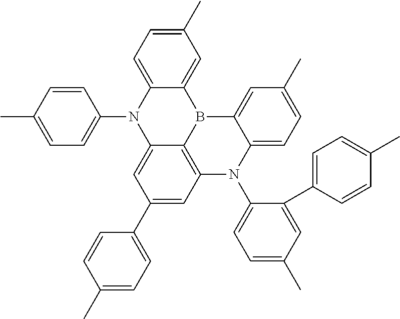

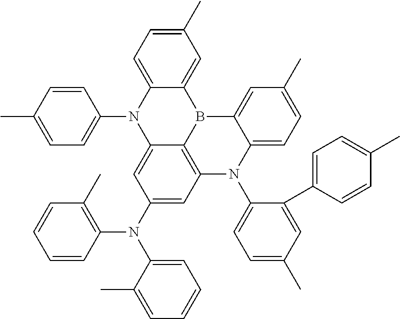

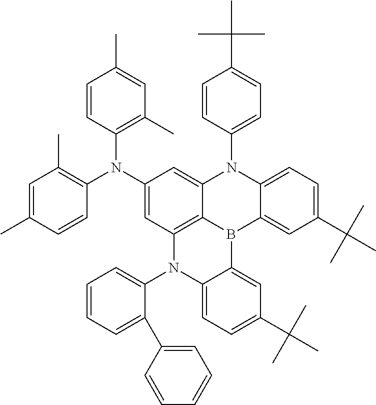 [SMILES: Cc1ccc(N(c2cc3c4c(c2)N(c2ccccc2-c2ccccc2)c2ccc(C(C)(C)C)cc2B4c2cc(C(C)(C)C)ccc2N3c2ccc(C(C)(C)C)cc2)c2ccc(C)cc2C)c(C)c1]

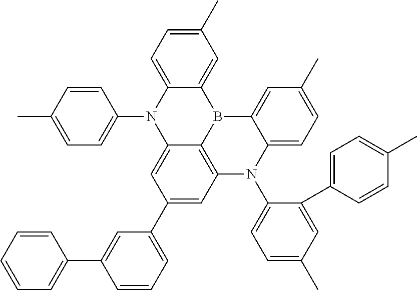 [SMILES: Cc1ccc(-c2cc(C)ccc2N2c3ccc(C)cc3B3c4cc(C)ccc4N(c4ccc(C)cc4)c4cc(-c5cccc(-c6ccccc6)c5)cc2c43)cc1]

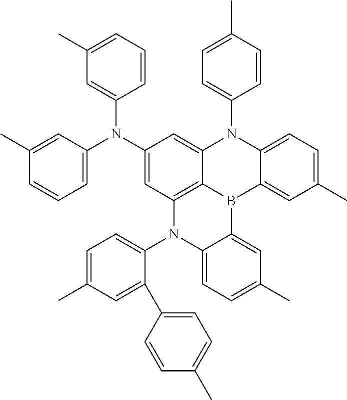

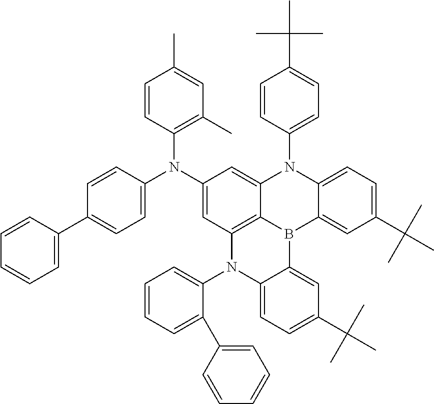 [SMILES: Cc1ccc(N(c2ccc(-c3ccccc3)cc2)c2cc3c4c(c2)N(c2ccccc2-c2ccccc2)c2ccc(C(C)(C)C)cc2B4c2cc(C(C)(C)C)ccc2N3c2ccc(C(C)(C)C)cc2)c(C)c1]

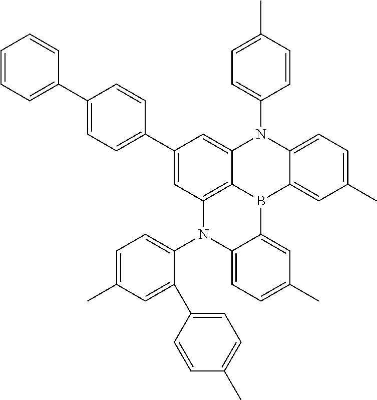 [SMILES: Cc1ccc(-c2cc(C)ccc2N2c3ccc(C)cc3B3c4cc(C)ccc4N(c4ccc(C)cc4)c4cc(-c5ccc(-c6ccccc6)cc5)cc2c43)cc1]

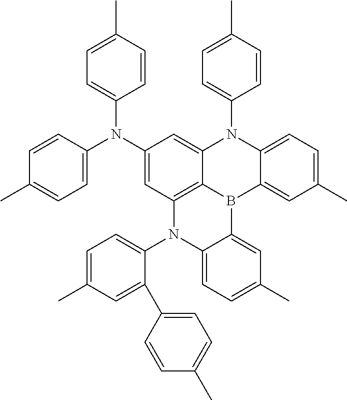

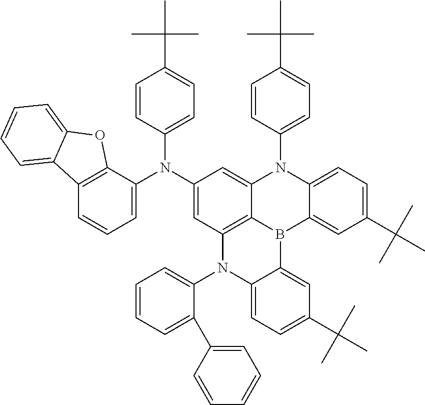 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccc(C(C)(C)C)cc5)c5cccc6c5oc5ccccc56)cc2c43)cc1]

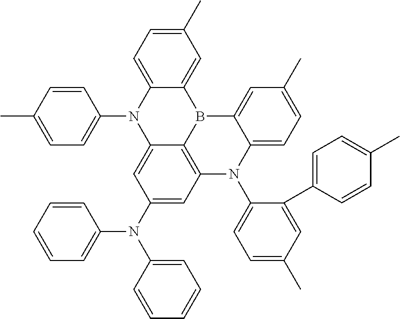

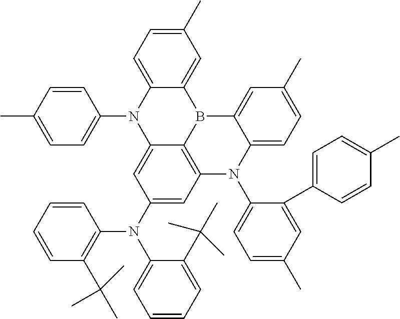

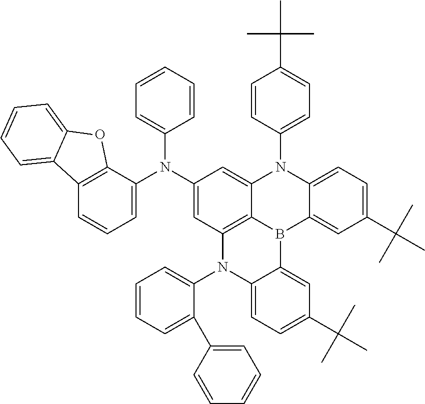 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccccc5)c5cccc6c5oc5ccccc56)cc2c43)cc1]

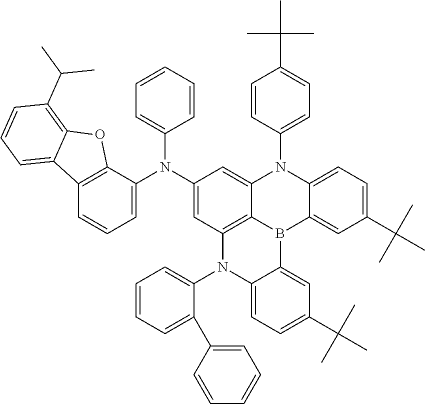 [SMILES: CC(C)c1cccc2c1oc1c(N(c3ccccc3)c3cc4c5c(c3)N(c3ccccc3-c3ccccc3)c3ccc(C(C)(C)C)cc3B5c3cc(C(C)(C)C)ccc3N4c3ccc(C(C)(C)C)cc3)cccc12]

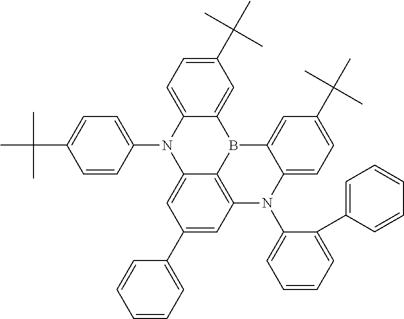 [SMILES: CC(C)(C)c1ccc(N2c3ccc(C(C)(C)C)cc3B3c4cc(C(C)(C)C)ccc4N(c4ccccc4-c4ccccc4)c4cc(-c5ccccc5)cc2c43)cc1]

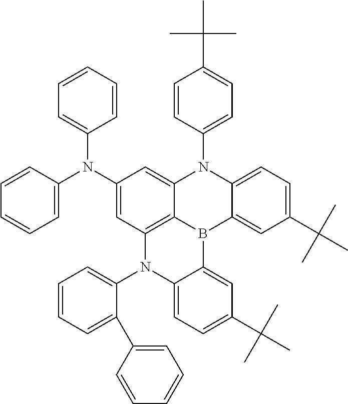 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccccc5)c5ccccc5)cc2c43)cc1]

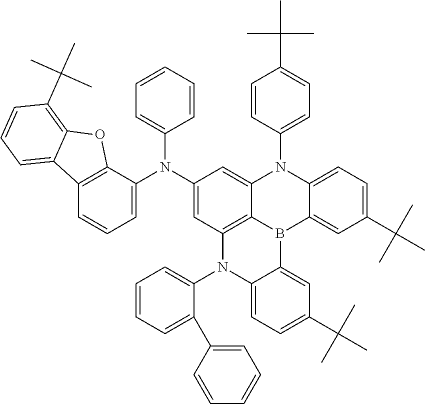 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccccc5)c5cccc6c5oc5c(C(C)(C)C)cccc56)cc2c43)cc1]

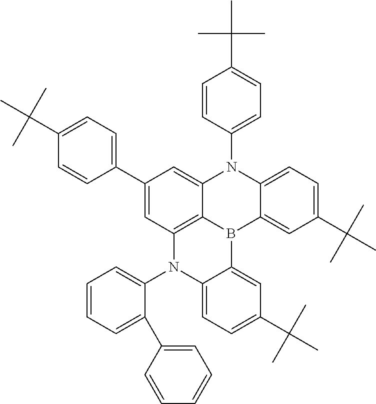 [SMILES: CC(C)(C)c1ccc(-c2cc3c4c(c2)N(c2ccccc2-c2ccccc2)c2ccc(C(C)(C)C)cc2B4c2cc(C(C)(C)C)ccc2N3c2ccc(C(C)(C)C)cc2)cc1]

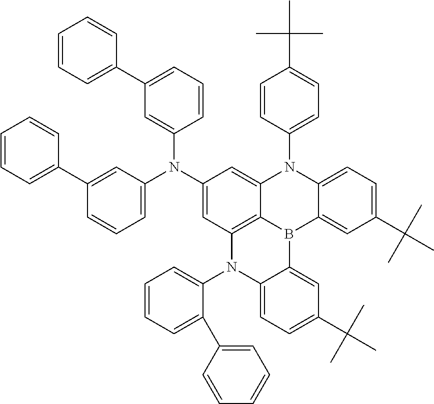 [SMILES: CC(C)(C)c1ccc(N2c3ccc(C(C)(C)C)cc3B3c4cc(C(C)(C)C)ccc4N(c4ccccc4-c4ccccc4)c4cc(N(c5cccc(-c6ccccc6)c5)c5cccc(-c6ccccc6)c5)cc2c43)cc1]

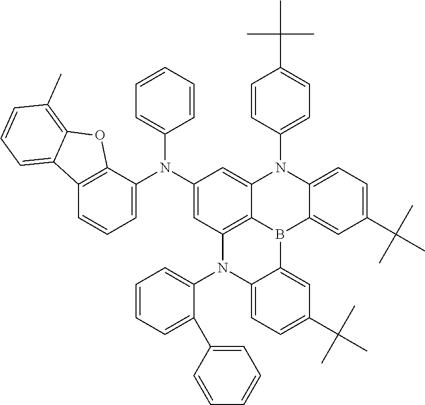 [SMILES: Cc1cccc2c1oc1c(N(c3ccccc3)c3cc4c5c(c3)N(c3ccccc3-c3ccccc3)c3ccc(C(C)(C)C)cc3B5c3cc(C(C)(C)C)ccc3N4c3ccc(C(C)(C)C)cc3)cccc12]

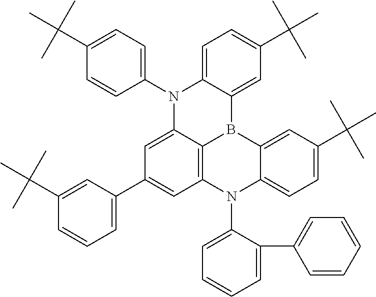 [SMILES: CC(C)(C)c1ccc(N2c3ccc(C(C)(C)C)cc3B3c4cc(C(C)(C)C)ccc4N(c4ccccc4-c4ccccc4)c4cc(-c5cccc(C(C)(C)C)c5)cc2c43)cc1]

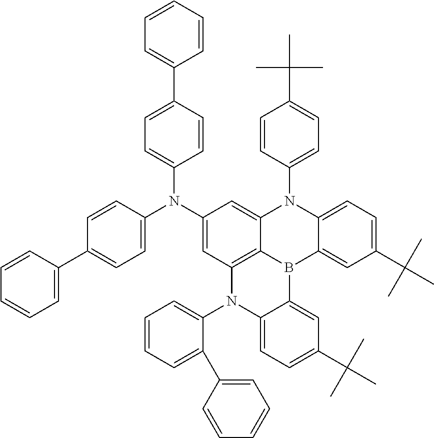 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccc(-c6ccccc6)cc5)c5ccc(-c6ccccc6)cc5)cc2c43)cc1]

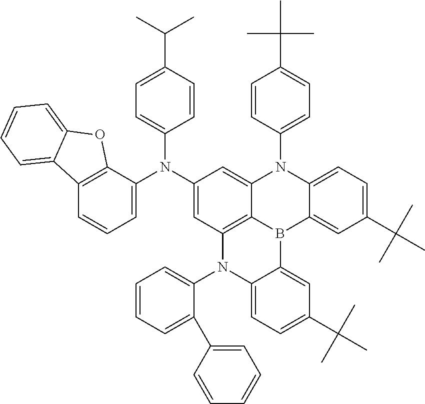 [SMILES: CC(C)c1ccc(N(c2cc3c4c(c2)N(c2ccccc2-c2ccccc2)c2ccc(C(C)(C)C)cc2B4c2cc(C(C)(C)C)ccc2N3c2ccc(C(C)(C)C)cc2)c2cccc3c2oc2ccccc23)cc1]

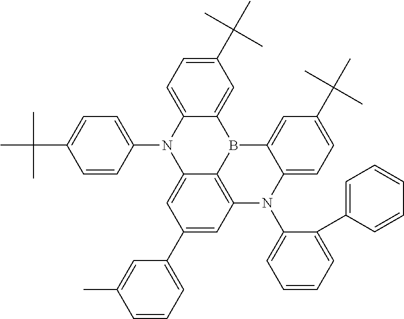 [SMILES: Cc1cccc(-c2cc3c4c(c2)N(c2ccccc2-c2ccccc2)c2ccc(C(C)(C)C)cc2B4c2cc(C(C)(C)C)ccc2N3c2ccc(C(C)(C)C)cc2)c1]

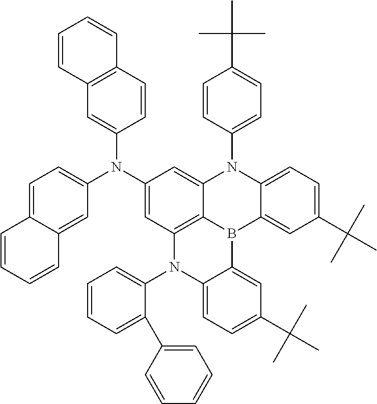 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccc6ccccc6c5)c5ccc6ccccc6c5)cc2c43)cc1]

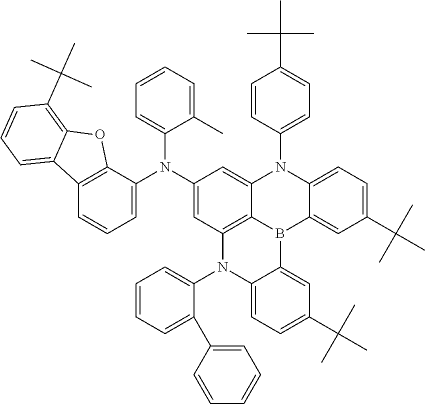 [SMILES: Cc1ccccc1N(c1cc2c3c(c1)N(c1ccccc1-c1ccccc1)c1ccc(C(C)(C)C)cc1B3c1cc(C(C)(C)C)ccc1N2c1ccc(C(C)(C)C)cc1)c1cccc2c1oc1c(C(C)(C)C)cccc12]

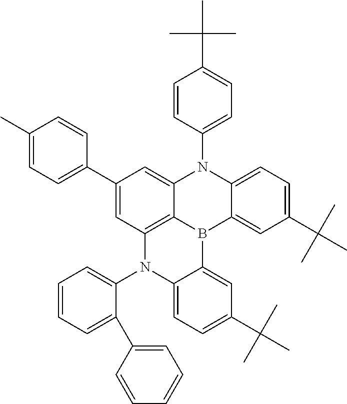 [SMILES: Cc1ccc(-c2cc3c4c(c2)N(c2ccccc2-c2ccccc2)c2ccc(C(C)(C)C)cc2B4c2cc(C(C)(C)C)ccc2N3c2ccc(C(C)(C)C)cc2)cc1]

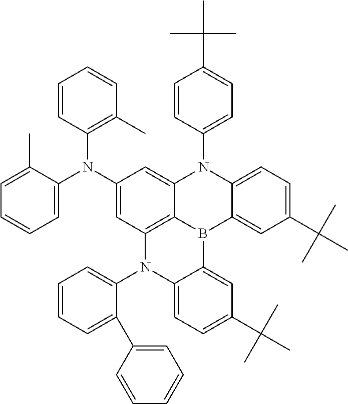 [SMILES: Cc1ccccc1N(c1cc2c3c(c1)N(c1ccccc1-c1ccccc1)c1ccc(C(C)(C)C)cc1B3c1cc(C(C)(C)C)ccc1N2c1ccc(C(C)(C)C)cc1)c1ccccc1C]

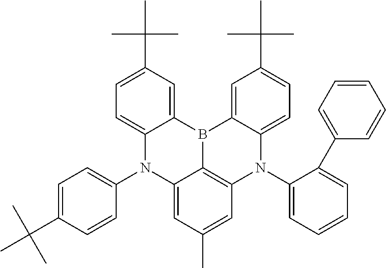 [SMILES: Cc1cc2c3c(c1)N(c1ccccc1-c1ccccc1)c1ccc(C(C)(C)C)cc1B3c1cc(C(C)(C)C)ccc1N2c1ccc(C(C)(C)C)cc1]

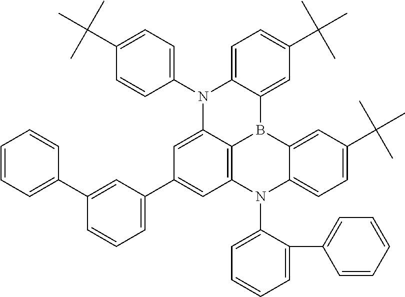 [SMILES: CC(C)(C)c1ccc(N2c3ccc(C(C)(C)C)cc3B3c4cc(C(C)(C)C)ccc4N(c4ccccc4-c4ccccc4)c4cc(-c5cccc(-c6ccccc6)c5)cc2c43)cc1]

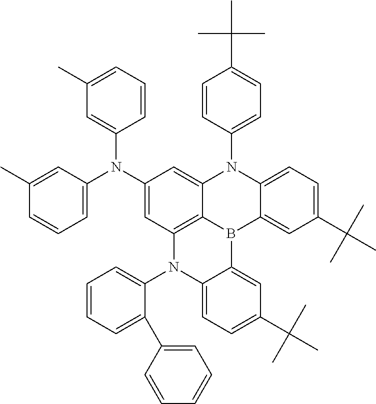 [SMILES: Cc1cccc(N(c2cccc(C)c2)c2cc3c4c(c2)N(c2ccccc2-c2ccccc2)c2ccc(C(C)(C)C)cc2B4c2cc(C(C)(C)C)ccc2N3c2ccc(C(C)(C)C)cc2)c1]

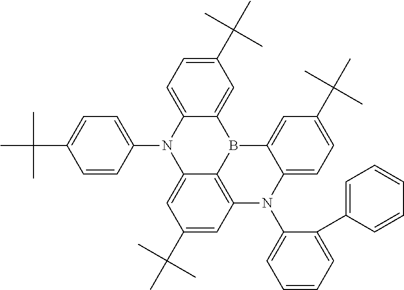 [SMILES: CC(C)(C)c1ccc(N2c3ccc(C(C)(C)C)cc3B3c4cc(C(C)(C)C)ccc4N(c4ccccc4-c4ccccc4)c4cc(C(C)(C)C)cc2c43)cc1]

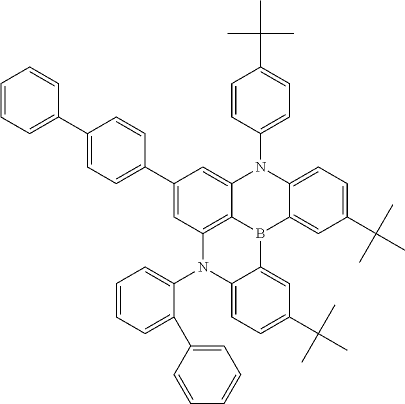 [SMILES: CC(C)(C)c1ccc(N2c3ccc(C(C)(C)C)cc3B3c4cc(C(C)(C)C)ccc4N(c4ccccc4-c4ccccc4)c4cc(-c5ccc(-c6ccccc6)cc5)cc2c43)cc1]

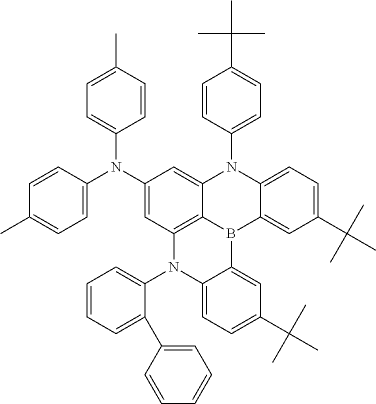 [SMILES: Cc1ccc(N(c2ccc(C)cc2)c2cc3c4c(c2)N(c2ccccc2-c2ccccc2)c2ccc(C(C)(C)C)cc2B4c2cc(C(C)(C)C)ccc2N3c2ccc(C(C)(C)C)cc2)cc1]

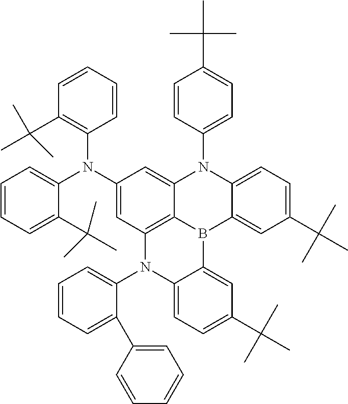 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccccc5C(C)(C)C)c5ccccc5C(C)(C)C)cc2c43)cc1]

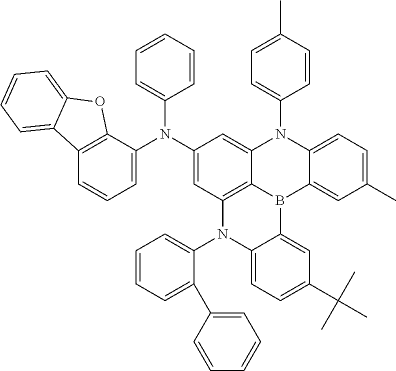 [SMILES: Cc1ccc(N2c3ccc(C)cc3B3c4cc(C(C)(C)C)ccc4N(c4ccccc4-c4ccccc4)c4cc(N(c5ccccc5)c5cccc6c5oc5ccccc56)cc2c43)cc1]

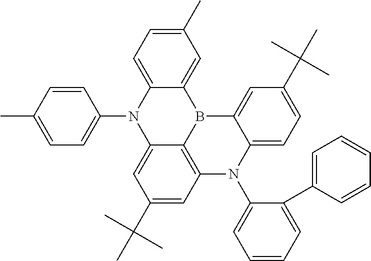 [SMILES: Cc1ccc(N2c3ccc(C)cc3B3c4cc(C(C)(C)C)ccc4N(c4ccccc4-c4ccccc4)c4cc(C(C)(C)C)cc2c43)cc1]

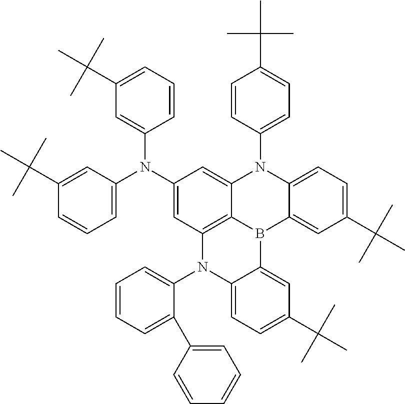 [SMILES: CC(C)(C)c1ccc(N2c3ccc(C(C)(C)C)cc3B3c4cc(C(C)(C)C)ccc4N(c4ccccc4-c4ccccc4)c4cc(N(c5cccc(C(C)(C)C)c5)c5cccc(C(C)(C)C)c5)cc2c43)cc1]

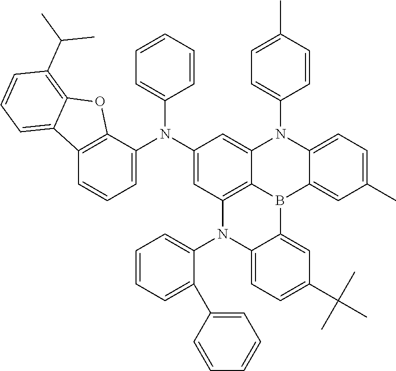 [SMILES: Cc1ccc(N2c3ccc(C)cc3B3c4cc(C(C)(C)C)ccc4N(c4ccccc4-c4ccccc4)c4cc(N(c5ccccc5)c5cccc6c5oc5c(C(C)C)cccc56)cc2c43)cc1]

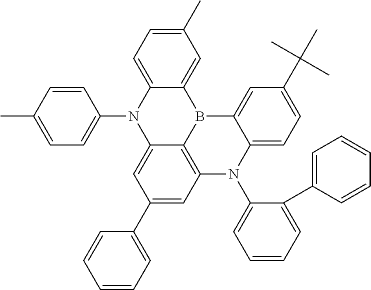 [SMILES: Cc1ccc(N2c3ccc(C)cc3B3c4cc(C(C)(C)C)ccc4N(c4ccccc4-c4ccccc4)c4cc(-c5ccccc5)cc2c43)cc1]

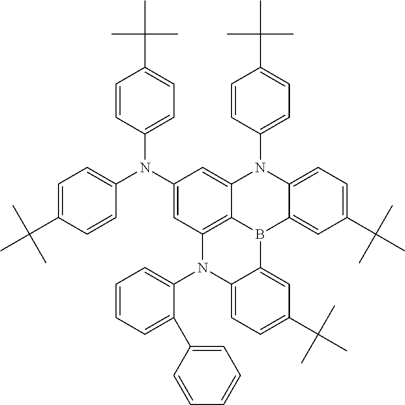 [SMILES: CC(C)(C)c1ccc(N(c2ccc(C(C)(C)C)cc2)c2cc3c4c(c2)N(c2ccccc2-c2ccccc2)c2ccc(C(C)(C)C)cc2B4c2cc(C(C)(C)C)ccc2N3c2ccc(C(C)(C)C)cc2)cc1]

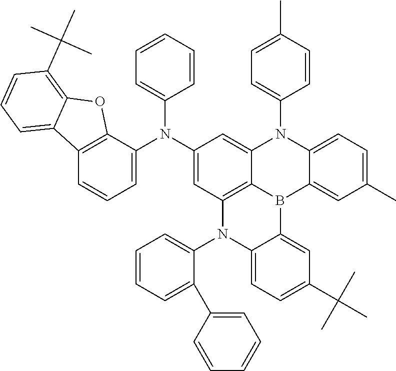 [SMILES: Cc1ccc(N2c3ccc(C)cc3B3c4cc(C(C)(C)C)ccc4N(c4ccccc4-c4ccccc4)c4cc(N(c5ccccc5)c5cccc6c5oc5c(C(C)(C)C)cccc56)cc2c43)cc1]

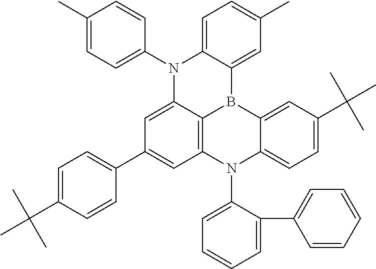 [SMILES: Cc1ccc(N2c3ccc(C)cc3B3c4cc(C(C)(C)C)ccc4N(c4ccccc4-c4ccccc4)c4cc(-c5ccc(C(C)(C)C)cc5)cc2c43)cc1]

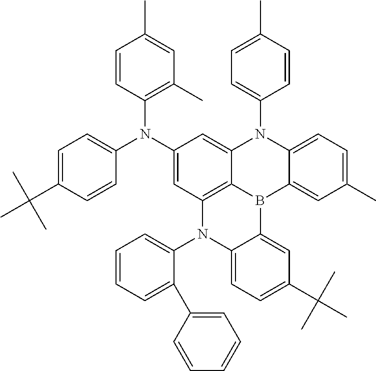 [SMILES: Cc1ccc(N2c3ccc(C)cc3B3c4cc(C(C)(C)C)ccc4N(c4ccccc4-c4ccccc4)c4cc(N(c5ccc(C(C)(C)C)cc5)c5ccc(C)cc5C)cc2c43)cc1]

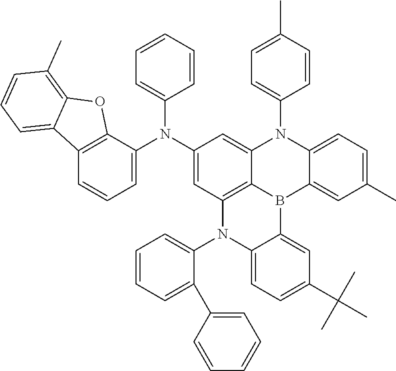 [SMILES: Cc1ccc(N2c3ccc(C)cc3B3c4cc(C(C)(C)C)ccc4N(c4ccccc4-c4ccccc4)c4cc(N(c5ccccc5)c5cccc6c5oc5c(C)cccc56)cc2c43)cc1]

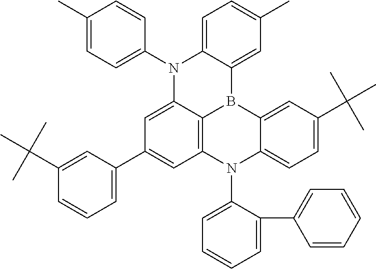 [SMILES: Cc1ccc(N2c3ccc(C)cc3B3c4cc(C(C)(C)C)ccc4N(c4ccccc4-c4ccccc4)c4cc(-c5cccc(C(C)(C)C)c5)cc2c43)cc1]

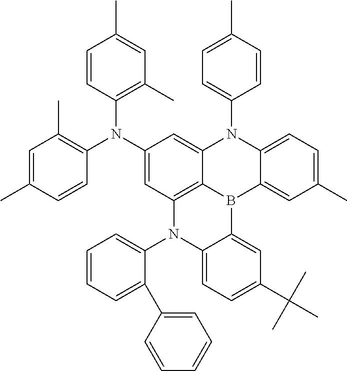

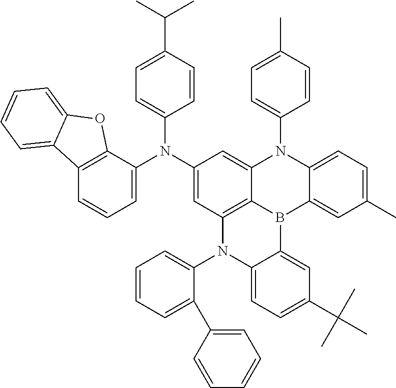 [SMILES: Cc1ccc(N2c3ccc(C)cc3B3c4cc(C(C)(C)C)ccc4N(c4ccccc4-c4ccccc4)c4cc(N(c5ccc(C(C)C)cc5)c5cccc6c5oc5ccccc56)cc2c43)cc1]

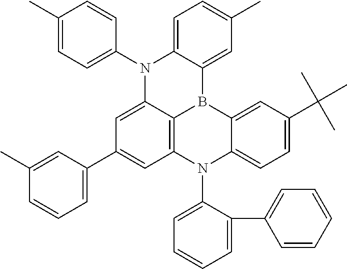 [SMILES: Cc1ccc(N2c3ccc(C)cc3B3c4cc(C(C)(C)C)ccc4N(c4ccccc4-c4ccccc4)c4cc(-c5cccc(C)c5)cc2c43)cc1]

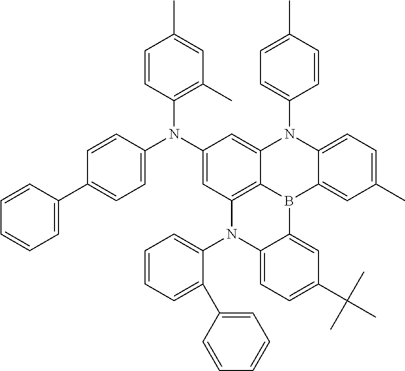 [SMILES: Cc1ccc(N2c3ccc(C)cc3B3c4cc(C(C)(C)C)ccc4N(c4ccccc4-c4ccccc4)c4cc(N(c5ccc(-c6ccccc6)cc5)c5ccc(C)cc5C)cc2c43)cc1]

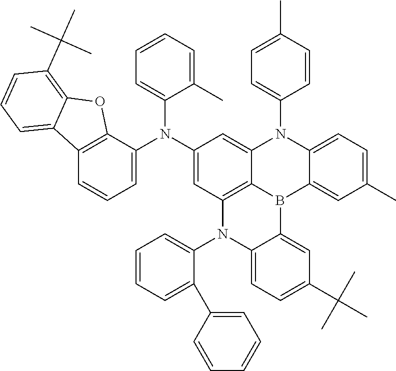 [SMILES: Cc1ccc(N2c3ccc(C)cc3B3c4cc(C(C)(C)C)ccc4N(c4ccccc4-c4ccccc4)c4cc(N(c5ccccc5C)c5cccc6c5oc5c(C(C)(C)C)cccc56)cc2c43)cc1]

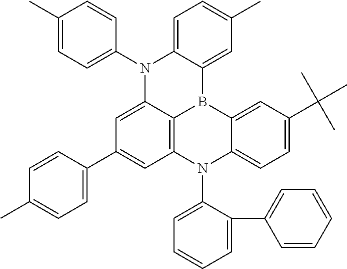 [SMILES: Cc1ccc(-c2cc3c4c(c2)N(c2ccccc2-c2ccccc2)c2ccc(C(C)(C)C)cc2B4c2cc(C)ccc2N3c2ccc(C)cc2)cc1]

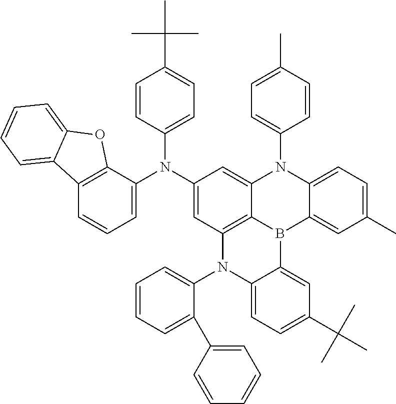 [SMILES: Cc1ccc(N2c3ccc(C)cc3B3c4cc(C(C)(C)C)ccc4N(c4ccccc4-c4ccccc4)c4cc(N(c5ccc(C(C)(C)C)cc5)c5cccc6c5oc5ccccc56)cc2c43)cc1]

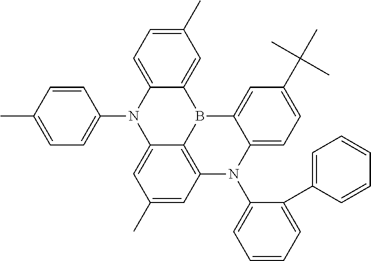 [SMILES: Cc1ccc(N2c3ccc(C)cc3B3c4cc(C(C)(C)C)ccc4N(c4ccccc4-c4ccccc4)c4cc(C)cc2c43)cc1]

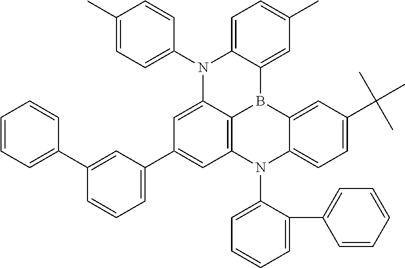 [SMILES: Cc1ccc(N2c3ccc(C)cc3B3c4cc(C(C)(C)C)ccc4N(c4ccccc4-c4ccccc4)c4cc(-c5cccc(-c6ccccc6)c5)cc2c43)cc1]

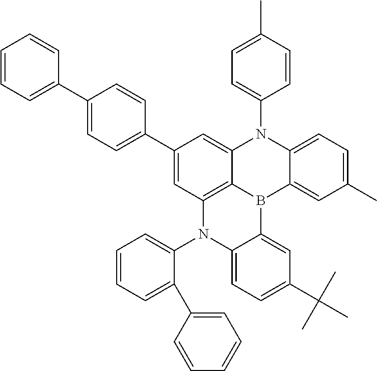 [SMILES: Cc1ccc(N2c3ccc(C)cc3B3c4cc(C(C)(C)C)ccc4N(c4ccccc4-c4ccccc4)c4cc(-c5ccc(-c6ccccc6)cc5)cc2c43)cc1]

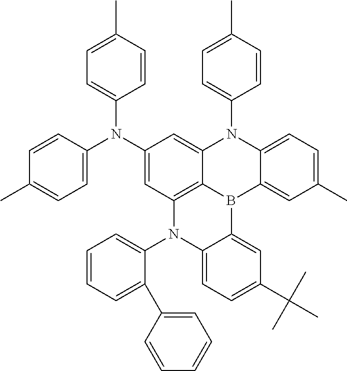

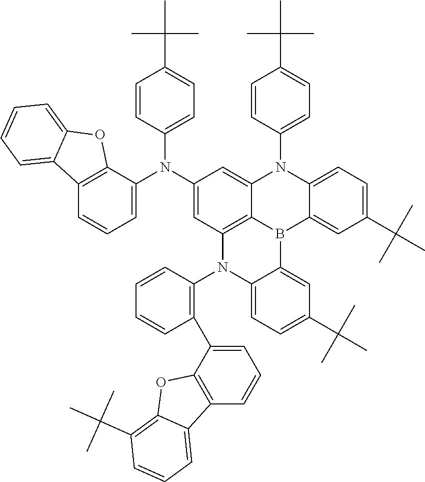 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccc(C(C)(C)C)cc5)c5cccc6c5oc5ccccc56)cc2c43)cc1]

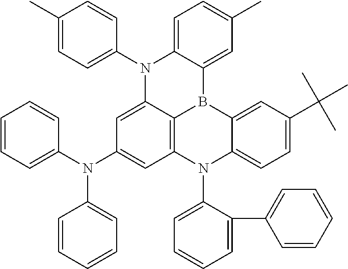 [SMILES: Cc1ccc(N2c3ccc(C)cc3B3c4cc(C(C)(C)C)ccc4N(c4ccccc4-c4ccccc4)c4cc(N(c5ccccc5)c5ccccc5)cc2c43)cc1]

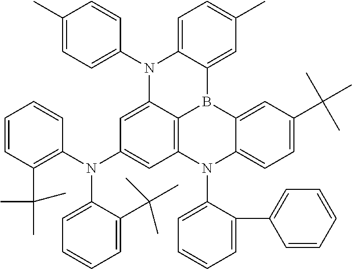 [SMILES: Cc1ccc(N2c3ccc(C)cc3B3c4cc(C(C)(C)C)ccc4N(c4ccccc4-c4ccccc4)c4cc(N(c5ccccc5C(C)(C)C)c5ccccc5C(C)(C)C)cc2c43)cc1]

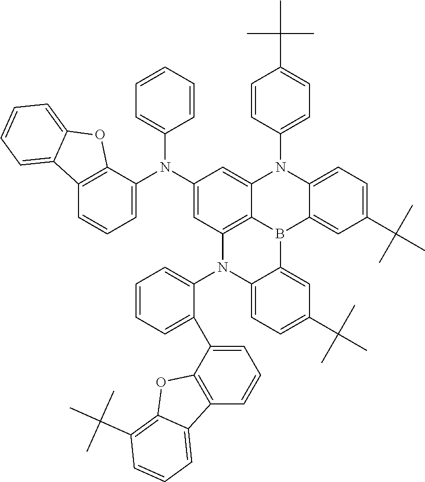 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccccc5)c5cccc6c5oc5ccccc56)cc2c43)cc1]

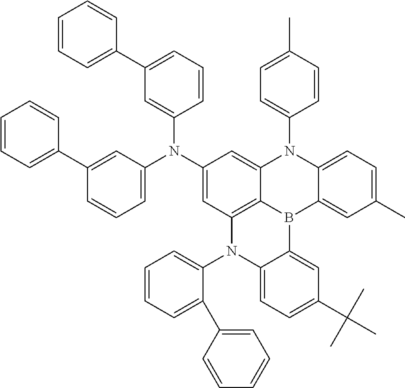 [SMILES: Cc1ccc(N2c3ccc(C)cc3B3c4cc(C(C)(C)C)ccc4N(c4ccccc4-c4ccccc4)c4cc(N(c5cccc(-c6ccccc6)c5)c5cccc(-c6ccccc6)c5)cc2c43)cc1]

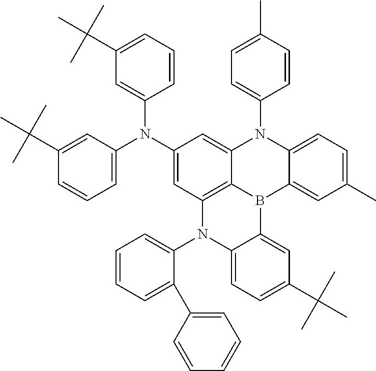 [SMILES: Cc1ccc(N2c3ccc(C)cc3B3c4cc(C(C)(C)C)ccc4N(c4ccccc4-c4ccccc4)c4cc(N(c5cccc(C(C)(C)C)c5)c5cccc(C(C)(C)C)c5)cc2c43)cc1]

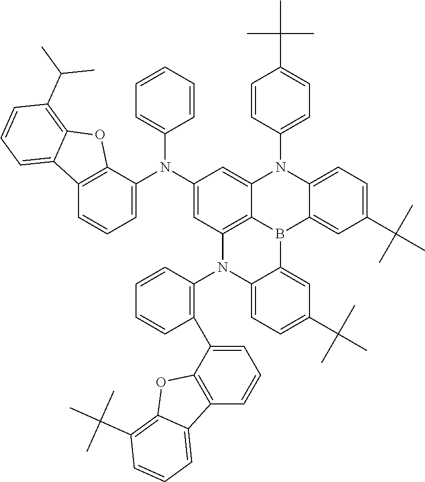 [SMILES: CC(C)c1cccc2c1oc1c(N(c3ccccc3)c3cc4c5c(c3)N(c3ccccc3-c3cccc6c3oc3c(C(C)(C)C)cccc36)c3ccc(C(C)(C)C)cc3B5c3cc(C(C)(C)C)ccc3N4c3ccc(C(C)(C)C)cc3)cccc12]

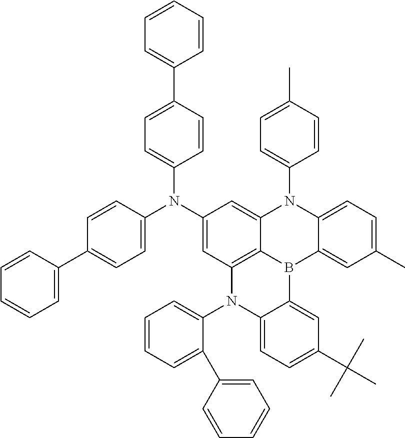 [SMILES: Cc1ccc(N2c3ccc(C)cc3B3c4cc(C(C)(C)C)ccc4N(c4ccccc4-c4ccccc4)c4cc(N(c5ccc(-c6ccccc6)cc5)c5ccc(-c6ccccc6)cc5)cc2c43)cc1]

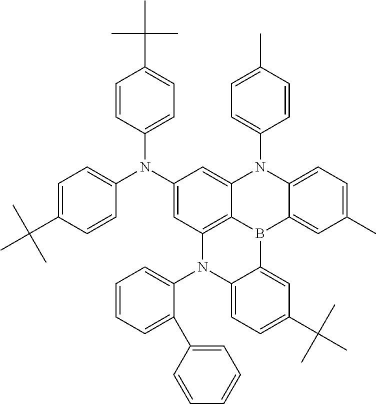 [SMILES: Cc1ccc(N2c3ccc(C)cc3B3c4cc(C(C)(C)C)ccc4N(c4ccccc4-c4ccccc4)c4cc(N(c5ccc(C(C)(C)C)cc5)c5ccc(C(C)(C)C)cc5)cc2c43)cc1]

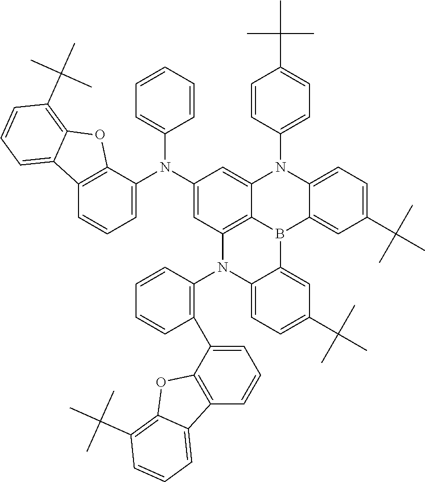 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccccc5)c5cccc6c5oc5c(C(C)(C)C)cccc56)cc2c43)cc1]

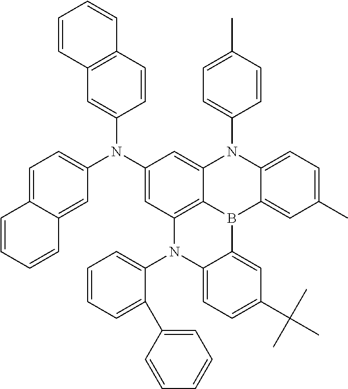 [SMILES: Cc1ccc(N2c3ccc(C)cc3B3c4cc(C(C)(C)C)ccc4N(c4ccccc4-c4ccccc4)c4cc(N(c5ccc6ccccc6c5)c5ccc6ccccc6c5)cc2c43)cc1]

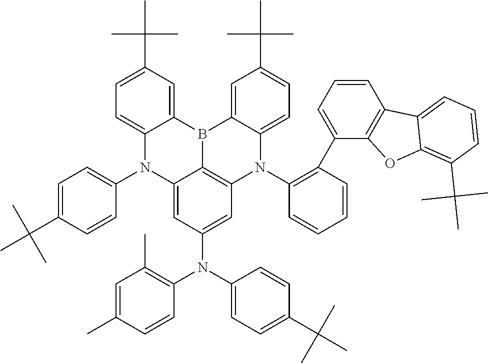 [SMILES: Cc1ccc(N(c2ccc(C(C)(C)C)cc2)c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)c(C)c1]

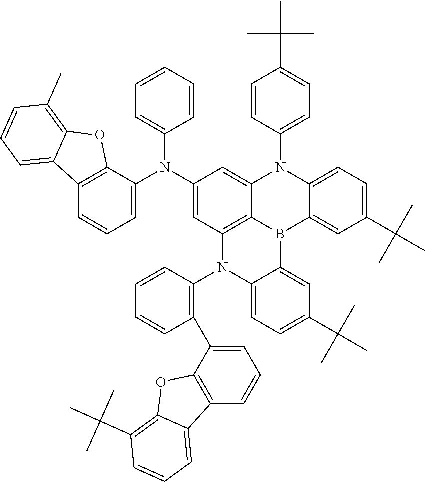 [SMILES: Cc1cccc2c1oc1c(N(c3ccccc3)c3cc4c5c(c3)N(c3ccccc3-c3cccc6c3oc3c(C(C)(C)C)cccc36)c3ccc(C(C)(C)C)cc3B5c3cc(C(C)(C)C)ccc3N4c3ccc(C(C)(C)C)cc3)cccc12]

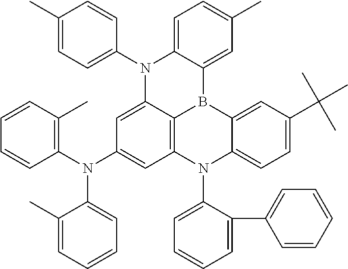 [SMILES: Cc1ccc(N2c3ccc(C)cc3B3c4cc(C(C)(C)C)ccc4N(c4ccccc4-c4ccccc4)c4cc(N(c5ccccc5C)c5ccccc5C)cc2c43)cc1]

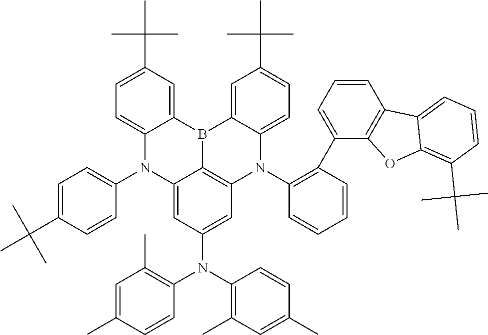 [SMILES: Cc1ccc(N(c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)c2ccc(C)cc2C)c(C)c1]

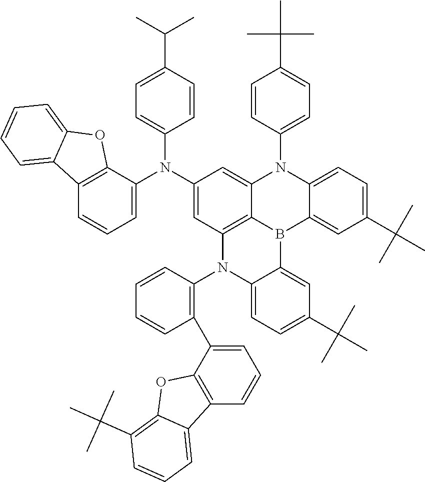 [SMILES: CC(C)c1ccc(N(c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)c2cccc3c2oc2ccccc23)cc1]

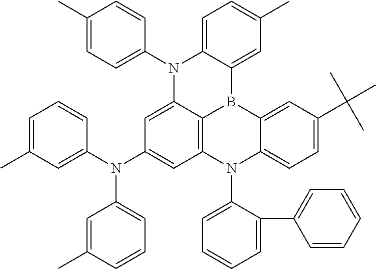 [SMILES: Cc1ccc(N2c3ccc(C)cc3B3c4cc(C(C)(C)C)ccc4N(c4ccccc4-c4ccccc4)c4cc(N(c5cccc(C)c5)c5cccc(C)c5)cc2c43)cc1]

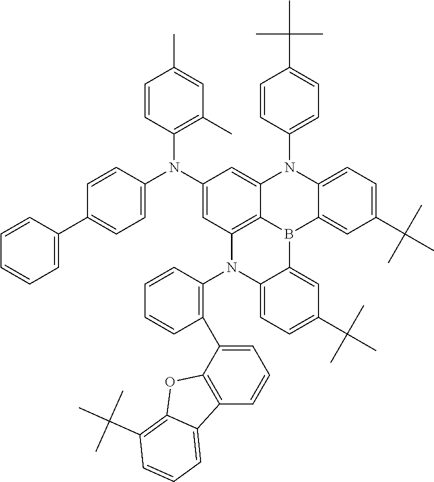 [SMILES: Cc1ccc(N(c2ccc(-c3ccccc3)cc2)c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)c(C)c1]

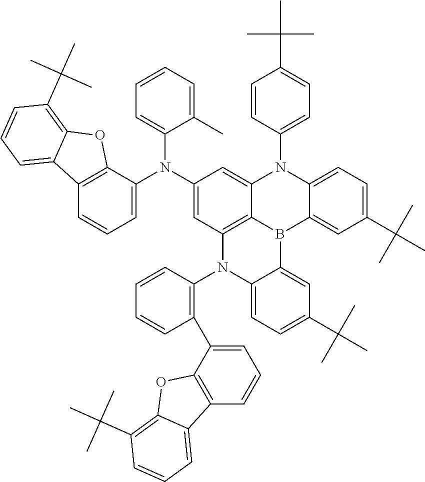 [SMILES: Cc1ccccc1N(c1cc2c3c(c1)N(c1ccccc1-c1cccc4c1oc1c(C(C)(C)C)cccc14)c1ccc(C(C)(C)C)cc1B3c1cc(C(C)(C)C)ccc1N2c1ccc(C(C)(C)C)cc1)c1cccc2c1oc1c(C(C)(C)C)cccc12]

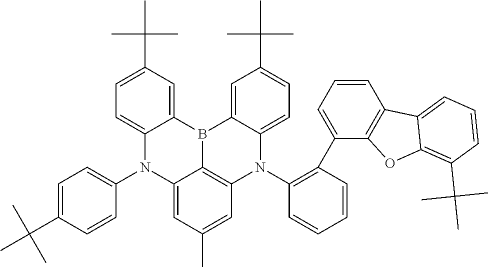 [SMILES: Cc1cc2c3c(c1)N(c1ccccc1-c1cccc4c1oc1c(C(C)(C)C)cccc14)c1ccc(C(C)(C)C)cc1B3c1cc(C(C)(C)C)ccc1N2c1ccc(C(C)(C)C)cc1]

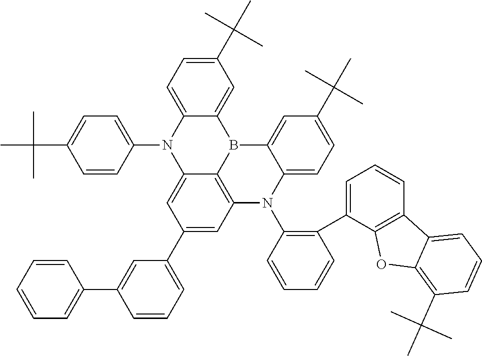 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(-c5cccc(-c6ccccc6)c5)cc2c43)cc1]

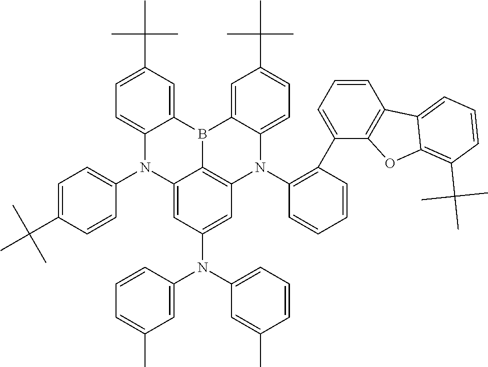 [SMILES: Cc1cccc(N(c2cccc(C)c2)c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)c1]

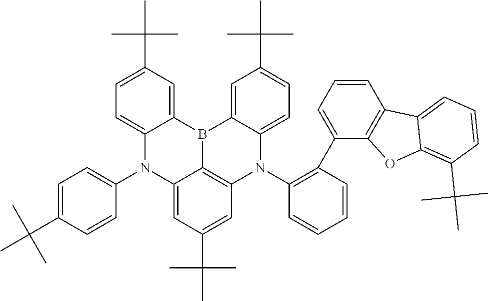 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(C(C)(C)C)cc2c43)cc1]

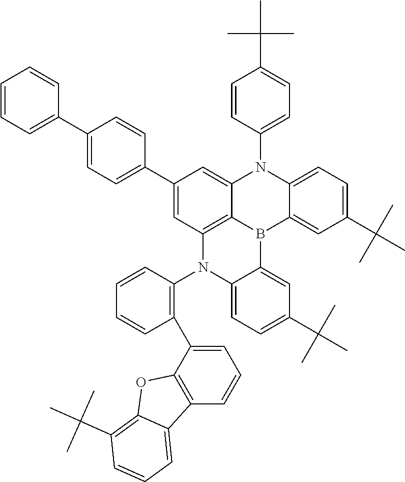 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(-c5ccc(-c6ccccc6)cc5)cc2c43)cc1]

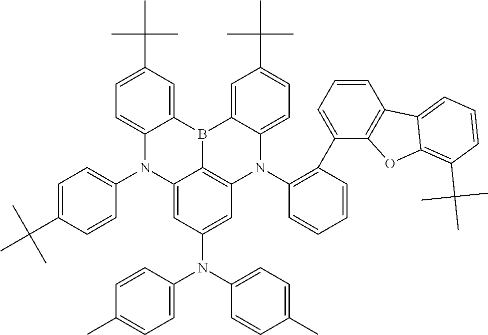 [SMILES: Cc1ccc(N(c2ccc(C)cc2)c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)cc1]

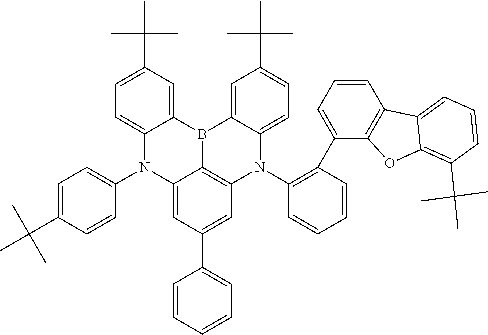 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(-c5ccccc5)cc2c43)cc1]

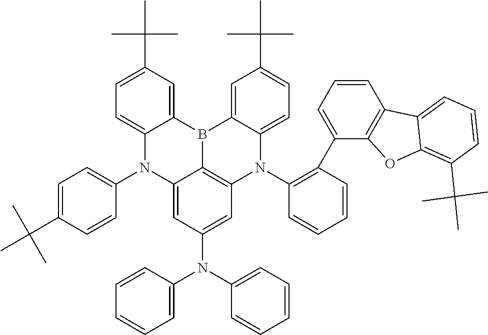 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccccc5)c5ccccc5)cc2c43)cc1]

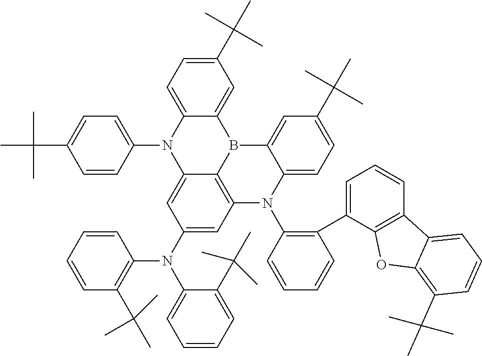 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccccc5C(C)(C)C)c5ccccc5C(C)(C)C)cc2c43)cc1]

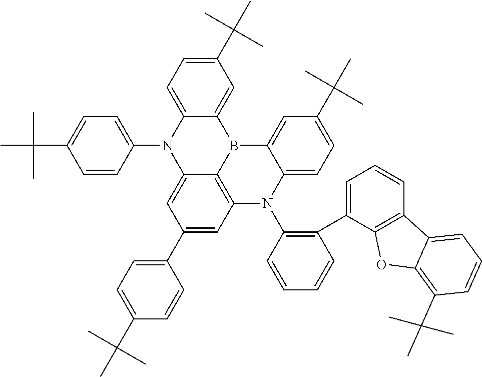 [SMILES: CC(C)(C)c1ccc(-c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)cc1]

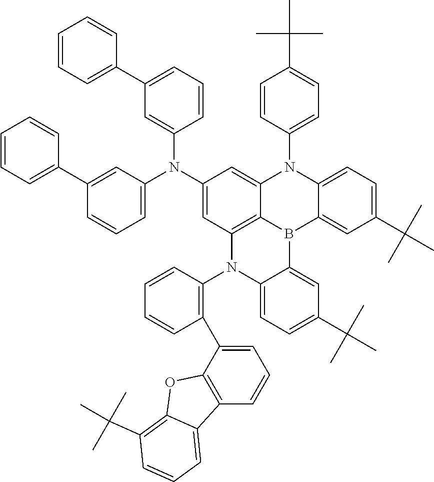 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5cccc(-c6ccccc6)c5)c5cccc(-c6ccccc6)c5)cc2c43)cc1]

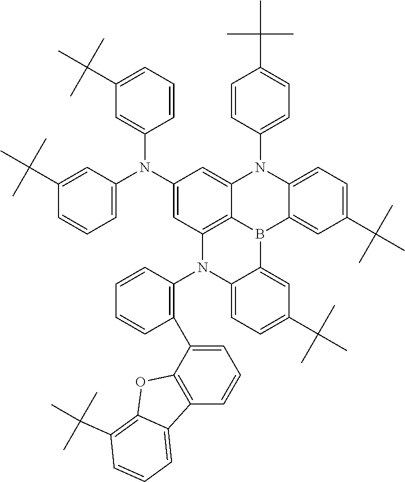 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5cccc(C(C)(C)C)c5)c5cccc(C(C)(C)C)c5)cc2c43)cc1]

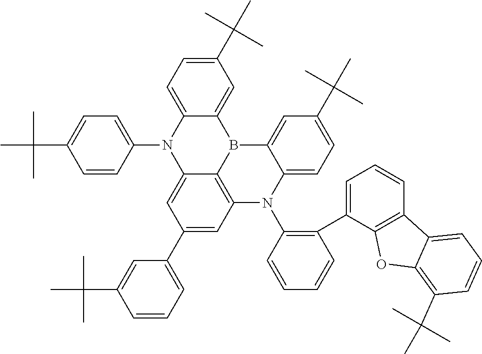 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(-c5cccc(C(C)(C)C)c5)cc2c43)cc1]

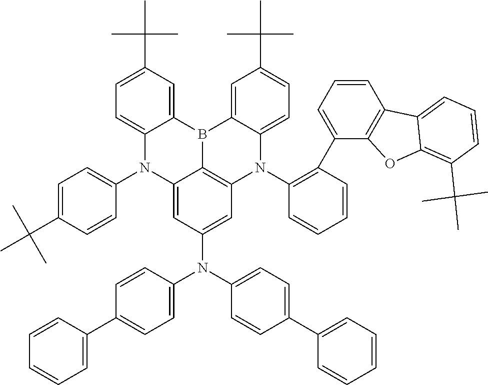 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccc(-c6ccccc6)cc5)c5ccc(-c6ccccc6)cc5)cc2c43)cc1]

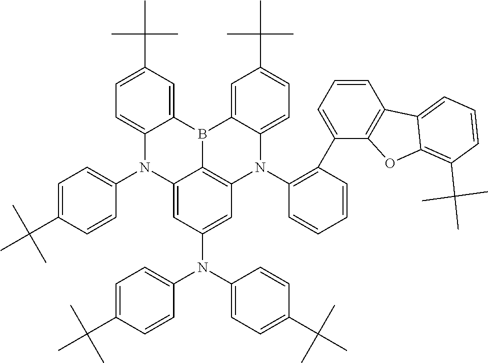 [SMILES: CC(C)(C)c1ccc(N(c2ccc(C(C)(C)C)cc2)c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)cc1]

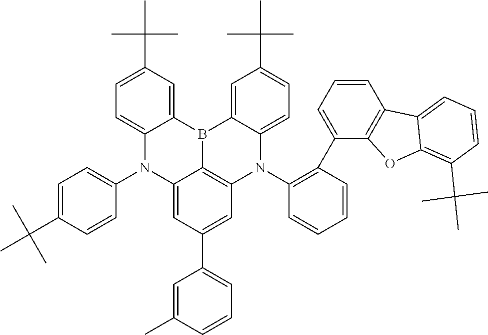 [SMILES: Cc1cccc(-c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)c1]

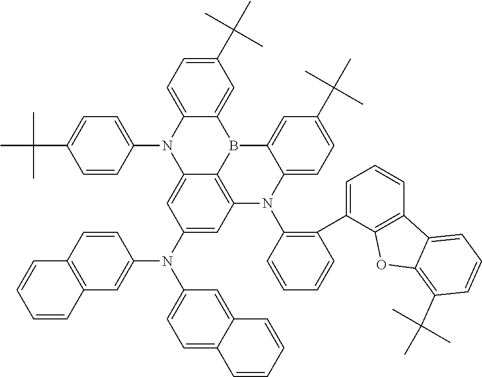 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccc6ccccc6c5)c5ccc6ccccc6c5)cc2c43)cc1]

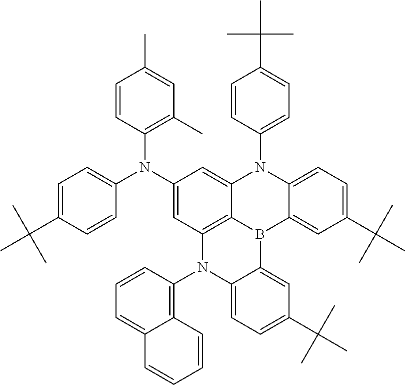 [SMILES: Cc1ccc(N(c2ccc(C(C)(C)C)cc2)c2cc3c4c(c2)N(c2cccc5ccccc25)c2ccc(C(C)(C)C)cc2B4c2cc(C(C)(C)C)ccc2N3c2ccc(C(C)(C)C)cc2)c(C)c1]

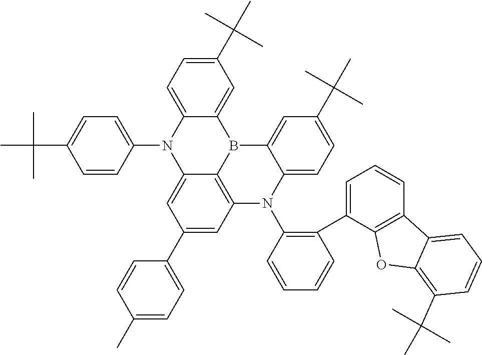 [SMILES: Cc1ccc(-c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)cc1]

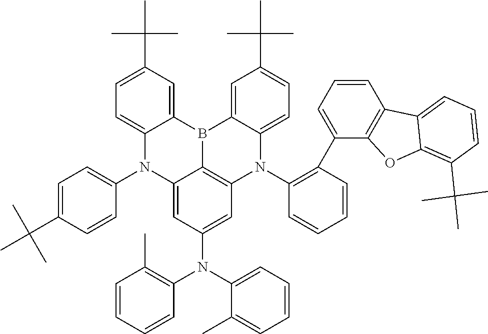 [SMILES: Cc1ccccc1N(c1cc2c3c(c1)N(c1ccccc1-c1cccc4c1oc1c(C(C)(C)C)cccc14)c1ccc(C(C)(C)C)cc1B3c1cc(C(C)(C)C)ccc1N2c1ccc(C(C)(C)C)cc1)c1ccccc1C]

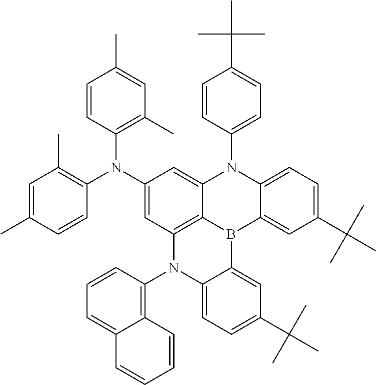 [SMILES: Cc1ccc(N(c2cc3c4c(c2)N(c2cccc5ccccc25)c2ccc(C(C)(C)C)cc2B4c2cc(C(C)(C)C)ccc2N3c2ccc(C(C)(C)C)cc2)c2ccc(C)cc2C)c(C)c1]

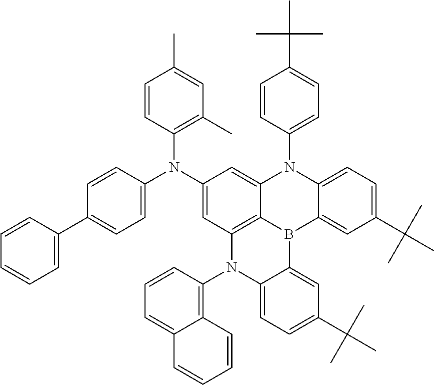 [SMILES: Cc1ccc(N(c2ccc(-c3ccccc3)cc2)c2cc3c4c(c2)N(c2cccc5ccccc25)c2ccc(C(C)(C)C)cc2B4c2cc(C(C)(C)C)ccc2N3c2ccc(C(C)(C)C)cc2)c(C)c1]

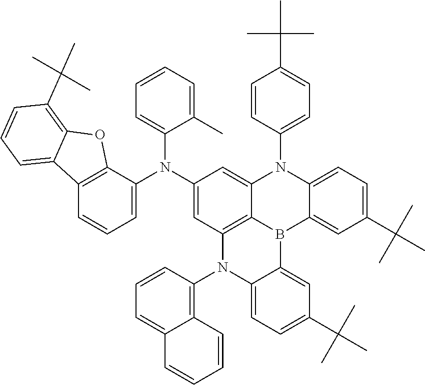 [SMILES: Cc1ccccc1N(c1cc2c3c(c1)N(c1cccc4ccccc14)c1ccc(C(C)(C)C)cc1B3c1cc(C(C)(C)C)ccc1N2c1ccc(C(C)(C)C)cc1)c1cccc2c1oc1c(C(C)(C)C)cccc12]

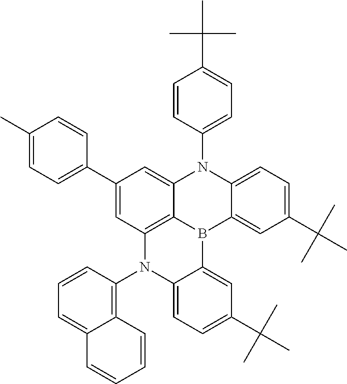 [SMILES: Cc1ccc(-c2cc3c4c(c2)N(c2cccc5ccccc25)c2ccc(C(C)(C)C)cc2B4c2cc(C(C)(C)C)ccc2N3c2ccc(C(C)(C)C)cc2)cc1]

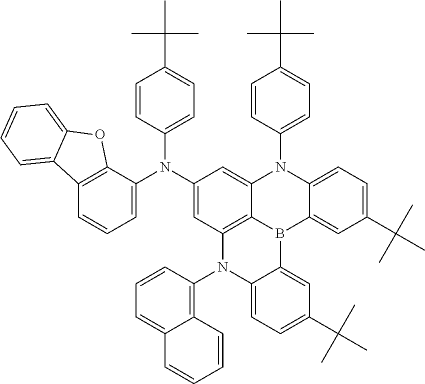 [SMILES: CC(C)(C)c1ccc(N2c3ccc(C(C)(C)C)cc3B3c4cc(C(C)(C)C)ccc4N(c4cccc5ccccc45)c4cc(N(c5ccc(C(C)(C)C)cc5)c5cccc6c5oc5ccccc56)cc2c43)cc1]

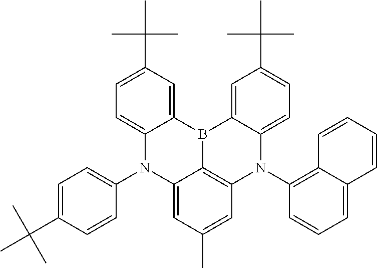 [SMILES: Cc1cc2c3c(c1)N(c1cccc4ccccc14)c1ccc(C(C)(C)C)cc1B3c1cc(C(C)(C)C)ccc1N2c1ccc(C(C)(C)C)cc1]

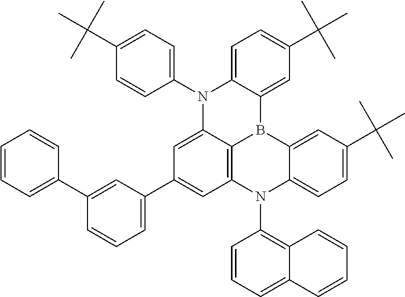 [SMILES: CC(C)(C)c1ccc(N2c3ccc(C(C)(C)C)cc3B3c4cc(C(C)(C)C)ccc4N(c4cccc5ccccc45)c4cc(-c5cccc(-c6ccccc6)c5)cc2c43)cc1]

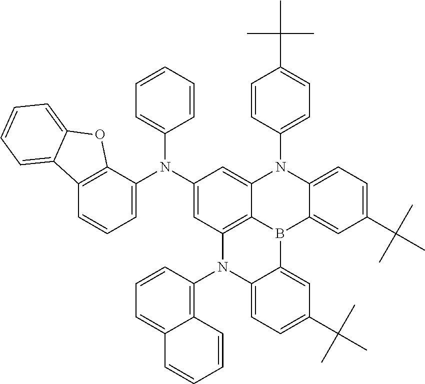 [SMILES: CC(C)(C)c1ccc(N2c3ccc(C(C)(C)C)cc3B3c4cc(C(C)(C)C)ccc4N(c4cccc5ccccc45)c4cc(N(c5ccccc5)c5cccc6c5oc5ccccc56)cc2c43)cc1]

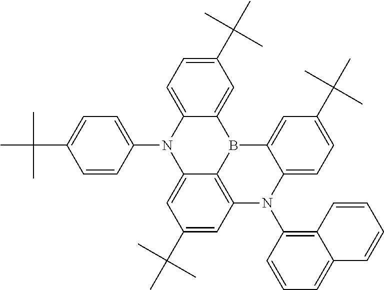 [SMILES: CC(C)(C)c1ccc(N2c3ccc(C(C)(C)C)cc3B3c4cc(C(C)(C)C)ccc4N(c4cccc5ccccc45)c4cc(C(C)(C)C)cc2c43)cc1]

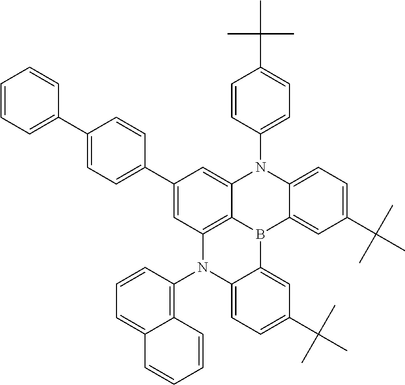 [SMILES: CC(C)(C)c1ccc(N2c3ccc(C(C)(C)C)cc3B3c4cc(C(C)(C)C)ccc4N(c4cccc5ccccc45)c4cc(-c5ccc(-c6ccccc6)cc5)cc2c43)cc1]

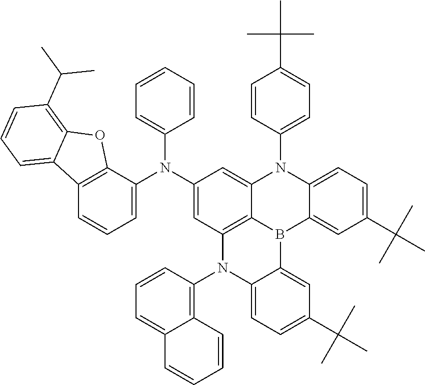 [SMILES: CC(C)c1cccc2c1oc1c(N(c3ccccc3)c3cc4c5c(c3)N(c3cccc6ccccc36)c3ccc(C(C)(C)C)cc3B5c3cc(C(C)(C)C)ccc3N4c3ccc(C(C)(C)C)cc3)cccc12]

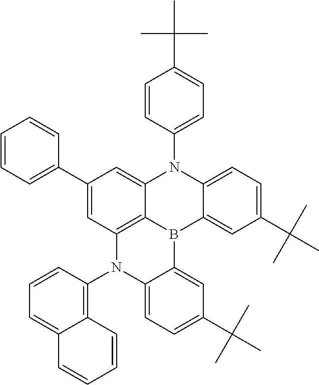 [SMILES: CC(C)(C)c1ccc(N2c3ccc(C(C)(C)C)cc3B3c4cc(C(C)(C)C)ccc4N(c4cccc5ccccc45)c4cc(-c5ccccc5)cc2c43)cc1]

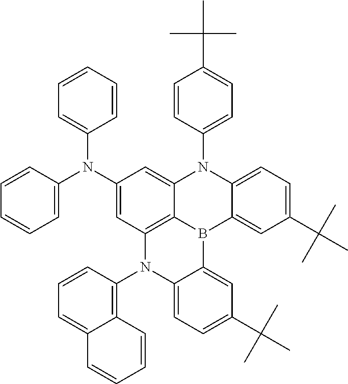 [SMILES: CC(C)(C)c1ccc(N2c3ccc(C(C)(C)C)cc3B3c4cc(C(C)(C)C)ccc4N(c4cccc5ccccc45)c4cc(N(c5ccccc5)c5ccccc5)cc2c43)cc1]

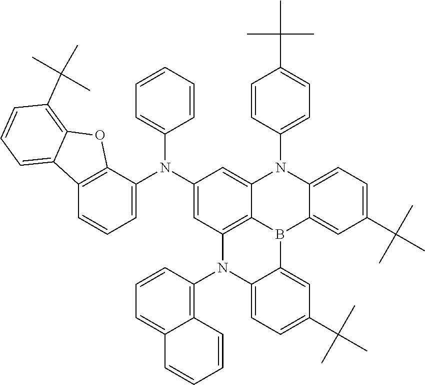 [SMILES: CC(C)(C)c1ccc(N2c3ccc(C(C)(C)C)cc3B3c4cc(C(C)(C)C)ccc4N(c4cccc5ccccc45)c4cc(N(c5ccccc5)c5cccc6c5oc5c(C(C)(C)C)cccc56)cc2c43)cc1]

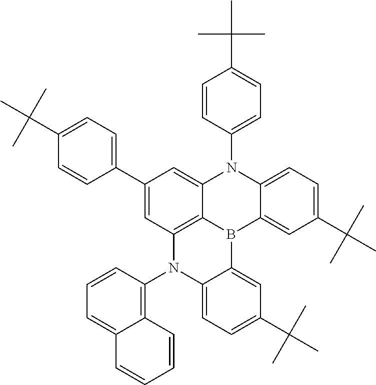 [SMILES: CC(C)(C)c1ccc(-c2cc3c4c(c2)N(c2cccc5ccccc25)c2ccc(C(C)(C)C)cc2B4c2cc(C(C)(C)C)ccc2N3c2ccc(C(C)(C)C)cc2)cc1]

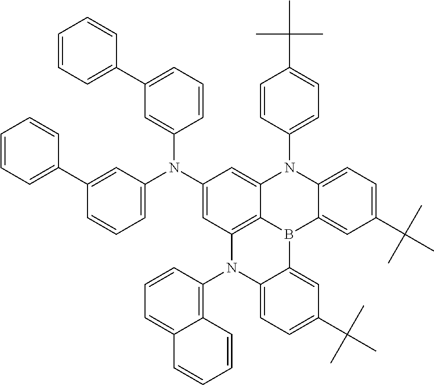 [SMILES: CC(C)(C)c1ccc(N2c3ccc(C(C)(C)C)cc3B3c4cc(C(C)(C)C)ccc4N(c4cccc5ccccc45)c4cc(N(c5cccc(-c6ccccc6)c5)c5cccc(-c6ccccc6)c5)cc2c43)cc1]

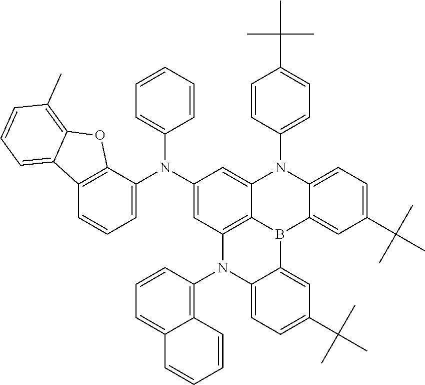 [SMILES: Cc1cccc2c1oc1c(N(c3ccccc3)c3cc4c5c(c3)N(c3cccc6ccccc36)c3ccc(C(C)(C)C)cc3B5c3cc(C(C)(C)C)ccc3N4c3ccc(C(C)(C)C)cc3)cccc12]

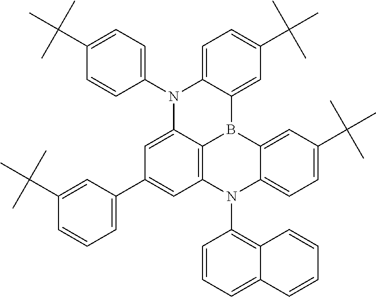 [SMILES: CC(C)(C)c1ccc(N2c3ccc(C(C)(C)C)cc3B3c4cc(C(C)(C)C)ccc4N(c4cccc5ccccc45)c4cc(-c5cccc(C(C)(C)C)c5)cc2c43)cc1]

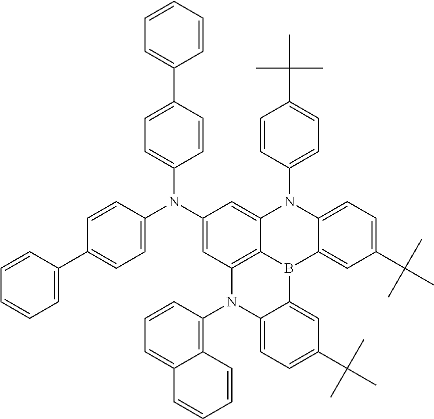 [SMILES: CC(C)(C)c1ccc(N2c3ccc(C(C)(C)C)cc3B3c4cc(C(C)(C)C)ccc4N(c4cccc5ccccc45)c4cc(N(c5ccc(-c6ccccc6)cc5)c5ccc(-c6ccccc6)cc5)cc2c43)cc1]

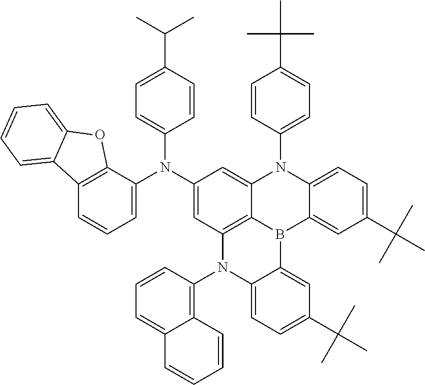 [SMILES: CC(C)c1ccc(N(c2cc3c4c(c2)N(c2cccc5ccccc25)c2ccc(C(C)(C)C)cc2B4c2cc(C(C)(C)C)ccc2N3c2ccc(C(C)(C)C)cc2)c2cccc3c2oc2ccccc23)cc1]

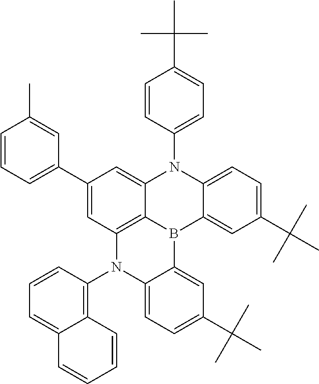 [SMILES: Cc1cccc(-c2cc3c4c(c2)N(c2cccc5ccccc25)c2ccc(C(C)(C)C)cc2B4c2cc(C(C)(C)C)ccc2N3c2ccc(C(C)(C)C)cc2)c1]

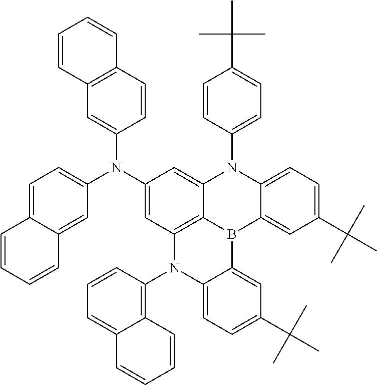 [SMILES: CC(C)(C)c1ccc(N2c3ccc(C(C)(C)C)cc3B3c4cc(C(C)(C)C)ccc4N(c4cccc5ccccc45)c4cc(N(c5ccc6ccccc6c5)c5ccc6ccccc6c5)cc2c43)cc1]

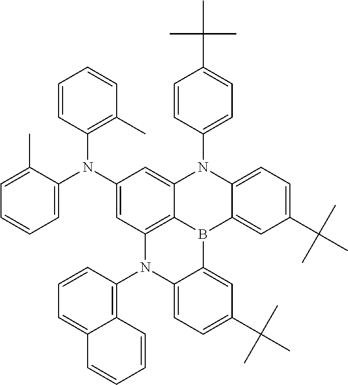 [SMILES: Cc1ccccc1N(c1cc2c3c(c1)N(c1cccc4ccccc14)c1ccc(C(C)(C)C)cc1B3c1cc(C(C)(C)C)ccc1N2c1ccc(C(C)(C)C)cc1)c1ccccc1C]

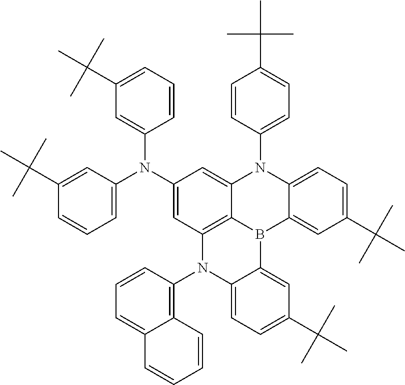 [SMILES: CC(C)(C)c1ccc(N2c3ccc(C(C)(C)C)cc3B3c4cc(C(C)(C)C)ccc4N(c4cccc5ccccc45)c4cc(N(c5cccc(C(C)(C)C)c5)c5cccc(C(C)(C)C)c5)cc2c43)cc1]

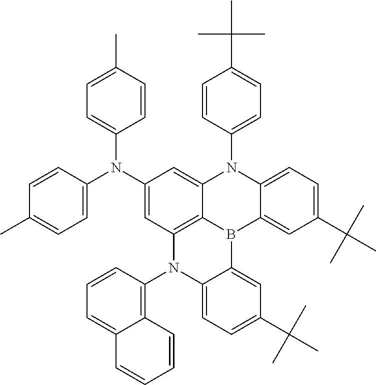 [SMILES: Cc1ccc(N(c2ccc(C)cc2)c2cc3c4c(c2)N(c2cccc5ccccc25)c2ccc(C(C)(C)C)cc2B4c2cc(C(C)(C)C)ccc2N3c2ccc(C(C)(C)C)cc2)cc1]

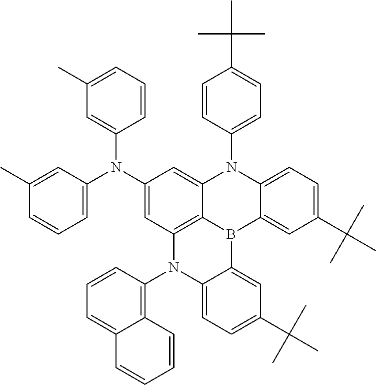 [SMILES: Cc1cccc(N(c2cccc(C)c2)c2cc3c4c(c2)N(c2cccc5ccccc25)c2ccc(C(C)(C)C)cc2B4c2cc(C(C)(C)C)ccc2N3c2ccc(C(C)(C)C)cc2)c1]

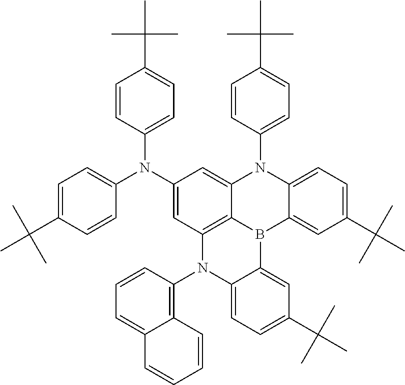 [SMILES: CC(C)(C)c1ccc(N(c2ccc(C(C)(C)C)cc2)c2cc3c4c(c2)N(c2cccc5ccccc25)c2ccc(C(C)(C)C)cc2B4c2cc(C(C)(C)C)ccc2N3c2ccc(C(C)(C)C)cc2)cc1]

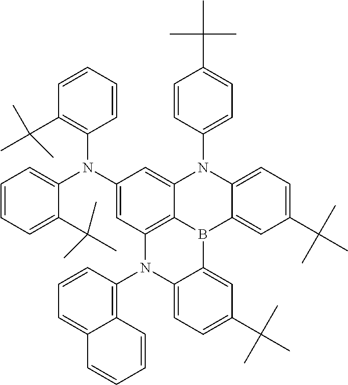 [SMILES: CC(C)(C)c1ccc(N2c3ccc(C(C)(C)C)cc3B3c4cc(C(C)(C)C)ccc4N(c4cccc5ccccc45)c4cc(N(c5ccccc5C(C)(C)C)c5ccccc5C(C)(C)C)cc2c43)cc1]

Layer H1 preferably comprises a compound of the formula (L-1).

A preferred embodiment of the formula (L-1) is the formula (L-1-1)

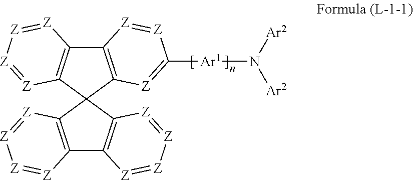

where N at each instance is CR¹, and where the other variables are as defined above.

Preferably, the index n is 0, and so the amino group is bonded directly to the spirobifluorenyl group. Preferably, at least one R¹ group selected from alkyl groups having 1 to 10 carbon atoms and aromatic ring systems having 6 to 40 aromatic ring atoms, each of which are substituted by R⁴ radicals, is additionally present.

Preferred embodiments of formula (L-1-1) are formulae (L-1-1-1), (L-1-1-2) and (L-1-1-3)

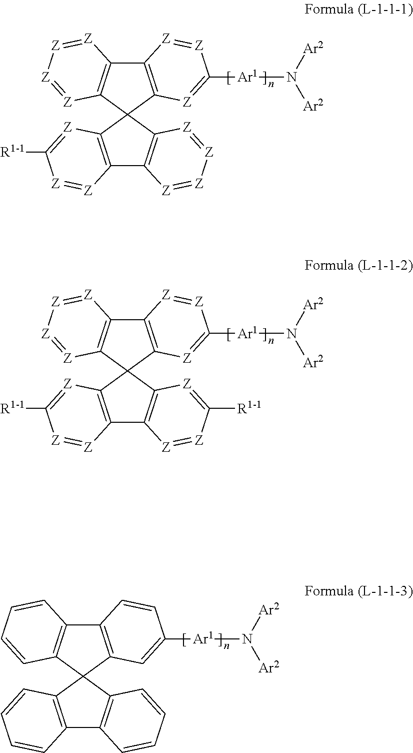

where R¹⁻¹ is the same or different, preferably the same, at each instance and is selected from alkyl groups having 1 to 10 carbon atoms, preferably methyl and tert-butyl, and aromatic ring systems having 6 to 40 aromatic ring atoms, each of which are substituted by R⁴ radicals, preferably phenyl substituted by R⁴ radicals, preferably unsubstituted phenyl. In addition, Z is CR¹. The other variables are as defined above. Preferably, in formulae (L-1-1-1) and (L-1-1-2), Z is CH. The spirobifluorenyl base skeleton in formula (L-1-1-3) does not bear any further substituents apart from the amino group.

The compound present in layer H1 is more preferably a compound of the formula (L-1-1-1), especially a compound of the formula (L-1-1-1) in which n is 0, and R¹⁻¹ is an aromatic ring system substituted by R⁴ radicals. It is particularly preferable that n is 0, Z is CH, and R¹⁻¹ is phenyl substituted by R⁴ radicals.

Preferred embodiments of formula (L-2) conform to the formula (L-2-1)

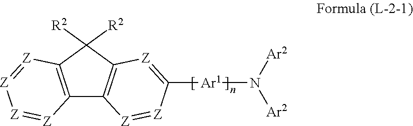

where Z is CR¹ and the other variables are as defined above. Preferably, in the formula, index n is 0. It is further preferable that at least one R¹ group as part of a Z group is selected from alkyl groups having 1 to 10 carbon atoms, preferably methyl and tert-butyl, and aromatic ring systems having 6 to 40 aromatic ring atoms, each of which are substituted by R⁴ radicals, preferably phenyl substituted by R⁴ radicals, preferably unsubstituted phenyl.

Preferred embodiments of the formula (L-3) conform to one of the formulae (L-3-1) and (L-3-2)

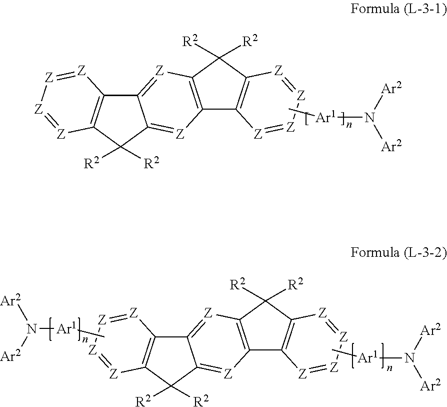

where Z is CR¹ and the other variables are as defined above. Preferably, in the formulae, index n is 0.

Index n is preferably 0 or 1, more preferably 0.

R¹ is preferably the same or different at each instance and is selected from H, D, F, CN, Si(R⁴)₃, N(R⁴)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁴ radicals; and where one or more CH₂ groups in the alkyl or alkoxy groups mentioned may be replaced by —C≡C—, —R⁴C═CR⁴—, Si(R⁴)₂, C═O, C═NR⁴, —NR⁴—, —O—, —S—, —C(═O)O— or —C(═O)NR⁴—.

R² is preferably the same or different at each instance and is selected from alkyl groups having 1 to 10 carbon atoms, aromatic ring systems which have 6 to 40 aromatic ring atoms and are substituted by R⁴ radicals, and heteroaromatic ring systems substituted by R⁴ radicals. More preferably, R² is the same or different at each instance and is selected from methyl and phenyl substituted by R⁴ radicals.

R³ is preferably the same or different at each instance and is selected from H, D, F, CN, Si(R⁴)₃, N(R⁴)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁴ radicals; and where one or more CH₂ groups in the alkyl or alkoxy groups mentioned may be replaced by —C≡C—, —R⁴C═CR⁴—, Si(R⁴)₂, C═O, C═NR⁴, —NR⁴—, —O—, —S—, —C(═O)O— or —C(═O)NR⁴—.

R⁴ is preferably the same or different at each instance and is selected from H, D, F, CN, Si(R⁵)₃, N(R⁵)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁵ radicals; and where one or more CH₂ groups in the alkyl or alkoxy groups mentioned may be replaced by —C≡C—, —R⁵C═CR⁵—, Si(R⁵)₂, C═O, C═NR⁵, —NR⁵—, —O—, —S—, —C(═O)O— or —C(═O)NR⁵—.

Ar¹ groups in formula (L-1), (L-2) and (L-3) and in the preferred embodiments of these formulae are the same or different and are selected from divalent groups derived from benzene, biphenyl, terphenyl, naphthalene, fluorene, indenofluorene, indenocarbazole, spirobifluorene, dibenzofuran, dibenzothiophene, and carbazole, each of which may be substituted by one or more R³ radicals. Most preferably, Ar¹ is a divalent group derived from benzene that may be substituted in each case by one or more R³ radicals. Ar¹ groups may be the same or different at each instance.

Preferred —(Ar¹)ₙ— groups conform to the following formulae:

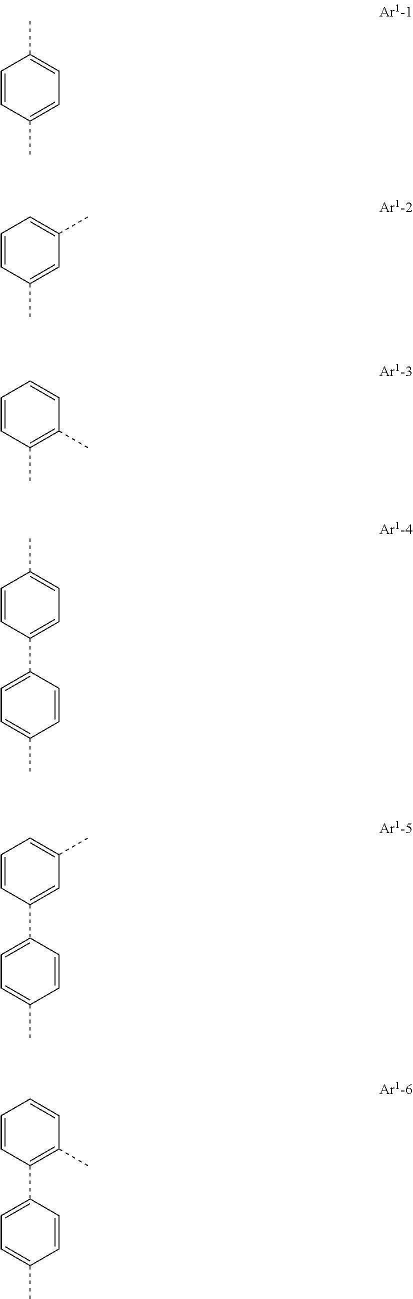

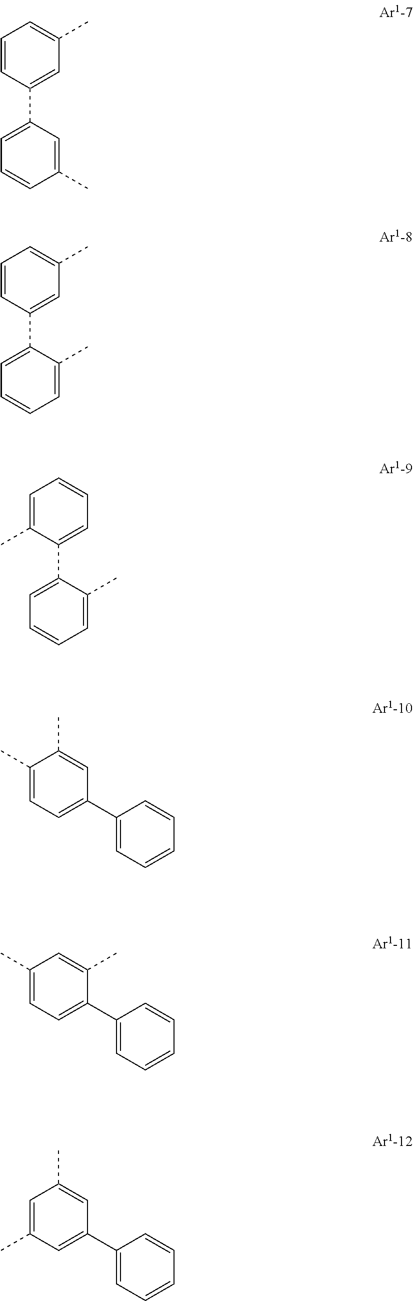

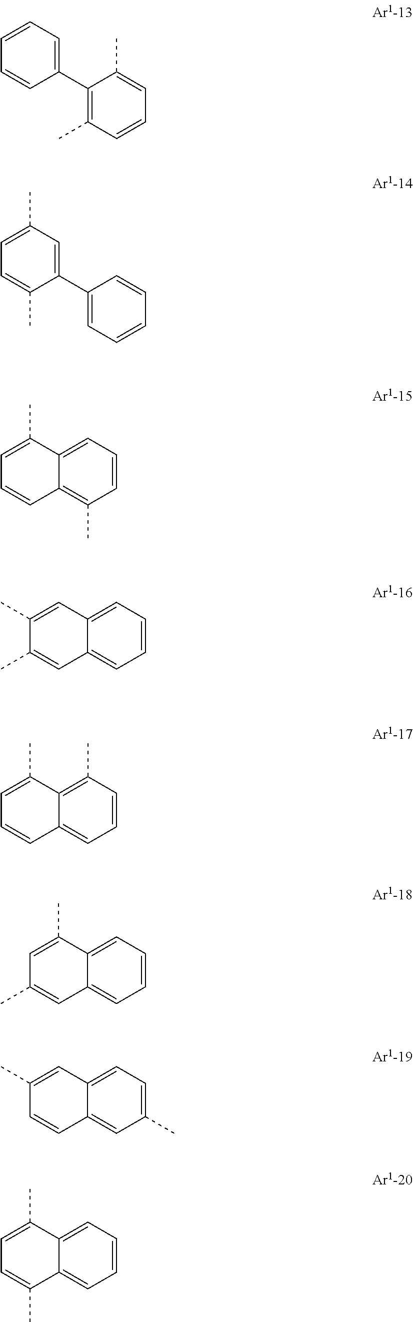

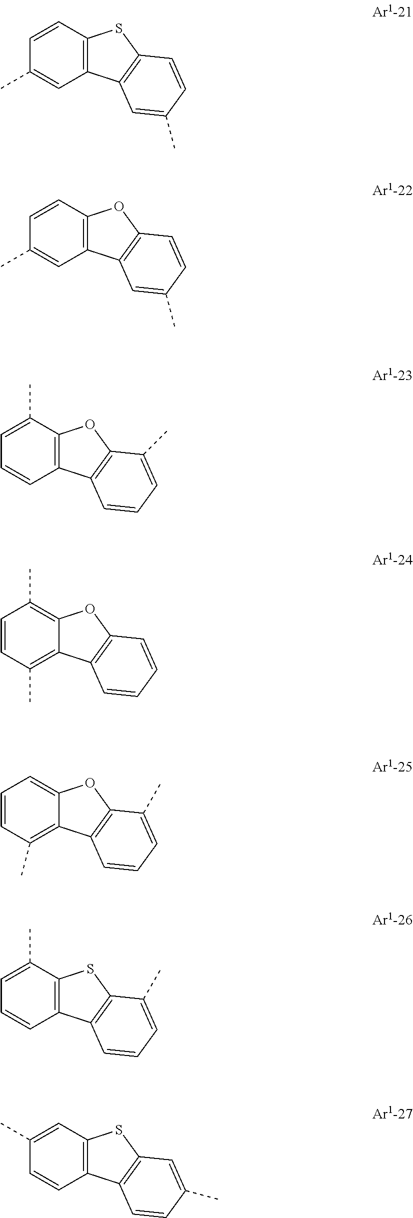

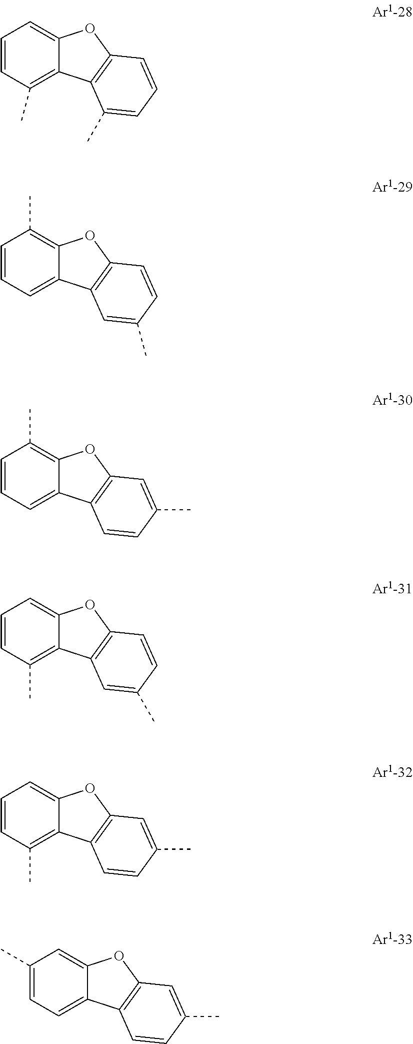

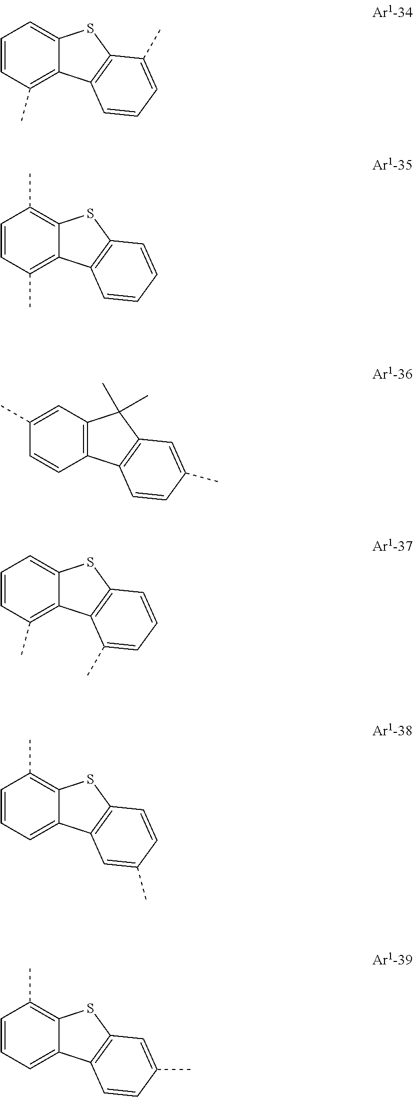

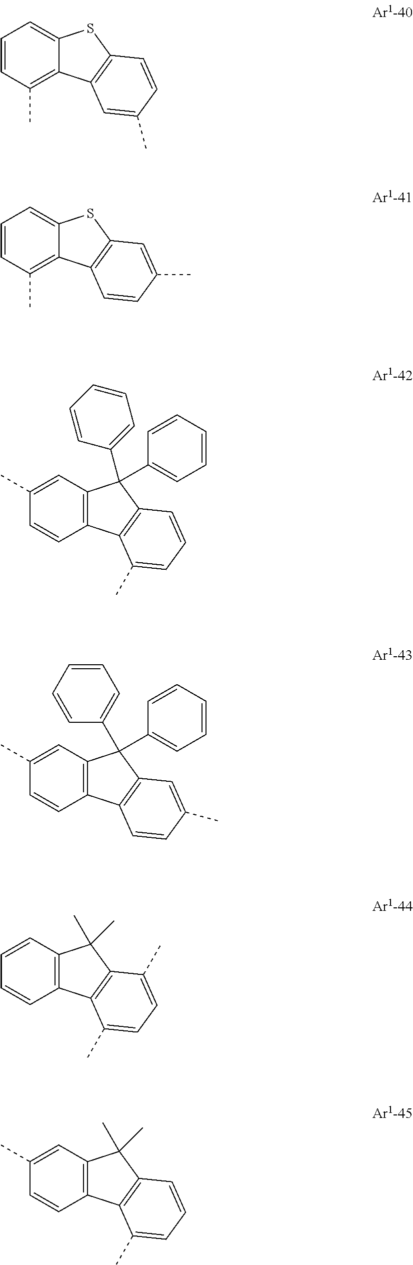

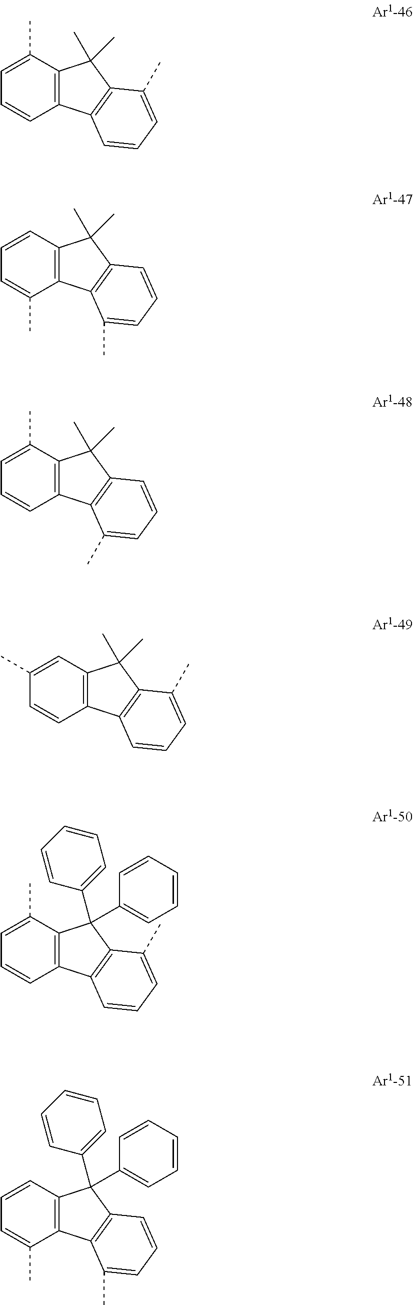

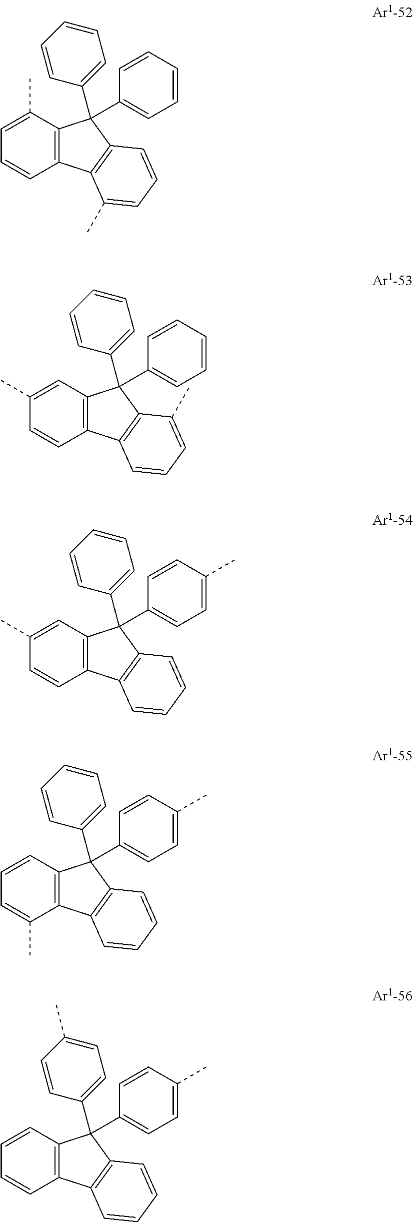

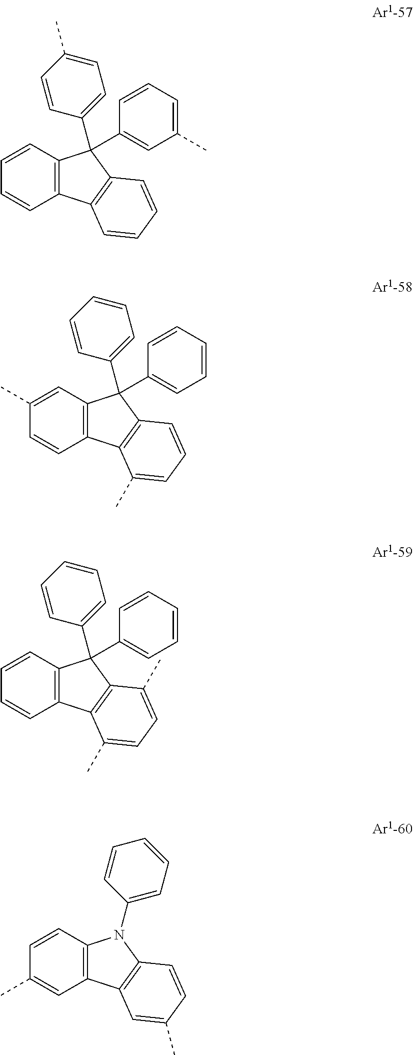

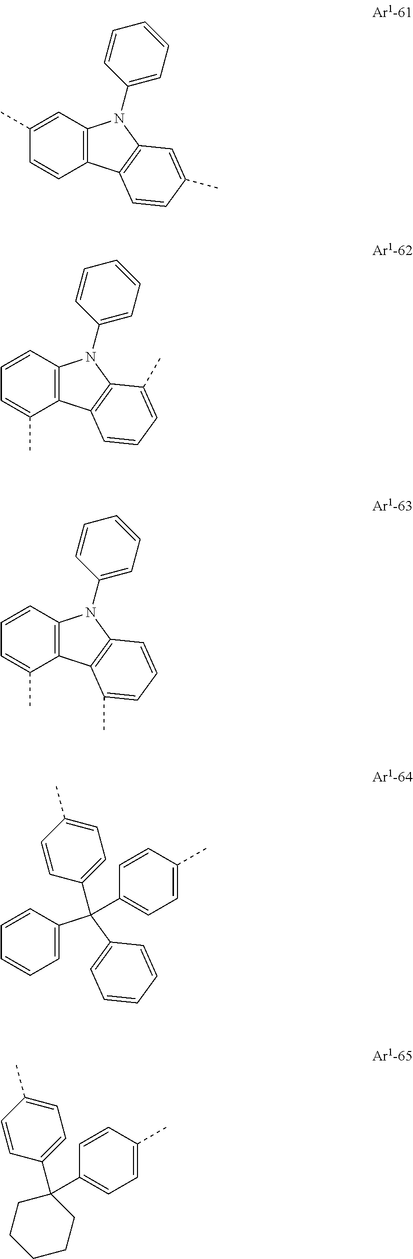

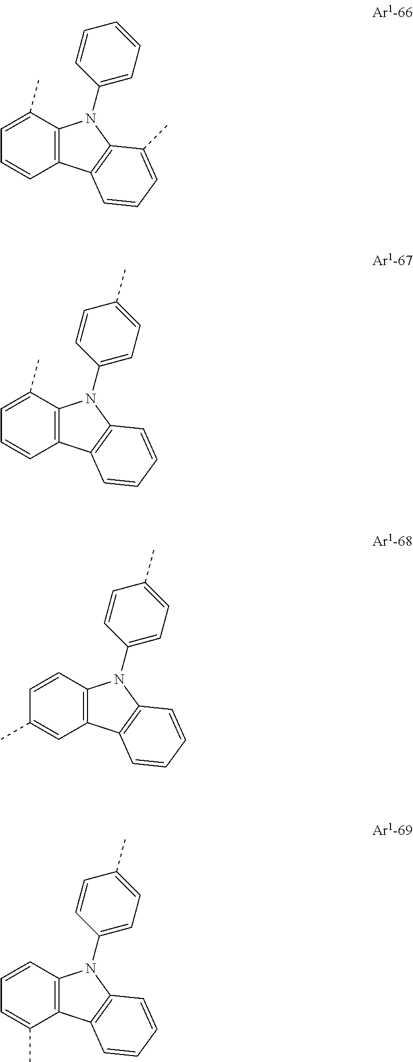

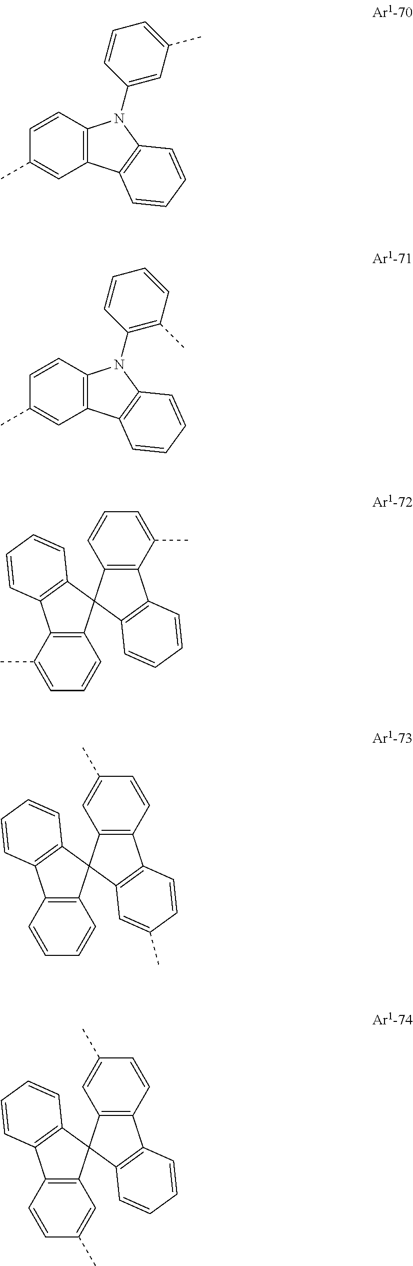

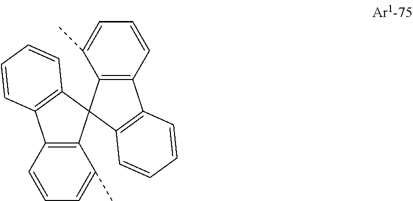

where the dotted lines represent the bonds to the rest of the formula.

Ar² groups in formula (L-1), (L-2) and (L-3) and in the preferred embodiments of these formulae are preferably the same or different at each instance and are selected from monovalent groups derived from benzene, biphenyl, terphenyl, quaterphenyl, naphthalene, fluorene, especially 9,9′-dimethylfluorene and 9,9′-diphenylfluorene, benzofluorene, spirobifluorene, indenofluorene, indenocarbazole, dibenzofuran, dibenzothiophene, benzocarbazole, carbazole, benzofuran, benzothiophene, indole, quinoline, pyridine, pyrimidine, pyrazine, pyridazine and triazine, where the monovalent groups may each be substituted by one or more R³ radicals. Alternatively, Ar² groups may preferably be the same or different at each instance and be selected from combinations of groups derived from benzene, biphenyl, terphenyl, quaterphenyl, naphthalene, fluorene, especially 9,9′-dimethylfluorene and 9,9′-diphenylfluorene, benzofluorene, spirobifluorene, indenofluorene, indenocarbazole, dibenzofuran, dibenzothiophene, carbazole, benzofuran, benzothiophene, indole, quinoline, pyridine, pyrimidine, pyrazine, pyridazine and triazine, where the groups may each be substituted by one or more R³ radicals.

Particularly preferred Ar² groups are the same or different at each instance and are selected from phenyl, biphenyl, terphenyl, quaterphenyl, naphthyl, fluorenyl, especially 9,9′-dimethylfluorenyl and 9,9′-diphenylfluorenyl, benzofluorenyl, spirobifluorenyl, indenofluorenyl, indenocarbazolyl, dibenzofuranyl, dibenzothiophenyl, carbazolyl, benzofuranyl, benzothiophenyl, benzofused dibenzofuranyl, benzofused dibenzothiophenyl, naphthyl-substituted phenyl, fluorenyl-substituted phenyl, spirobifluorenyl-substituted phenyl, dibenzofuranyl-substituted phenyl, dibenzothiophenyl-substituted phenyl, carbazolyl-substituted phenyl, pyridyl-substituted phenyl, pyrimidyl-substituted phenyl, and triazinyl-substituted phenyl, where the groups mentioned may each be substituted by one or more R³ radicals.

Preferred Ar² groups are shown below:

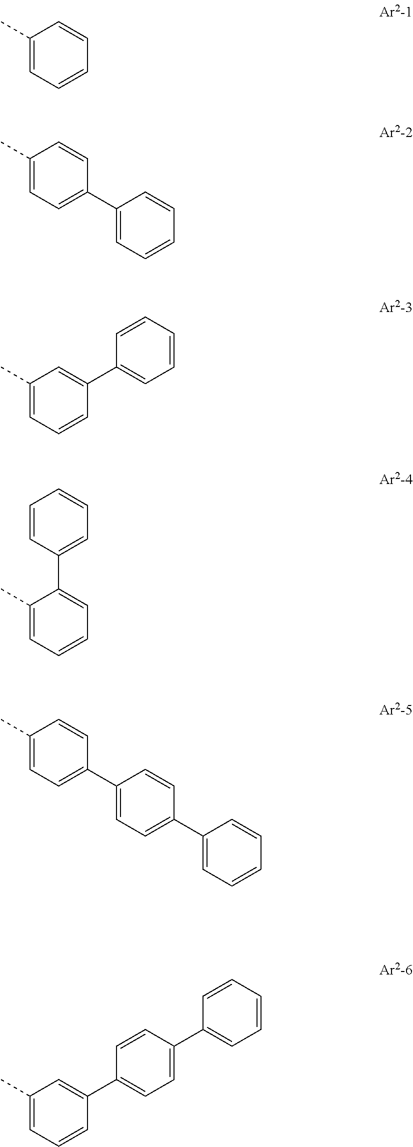

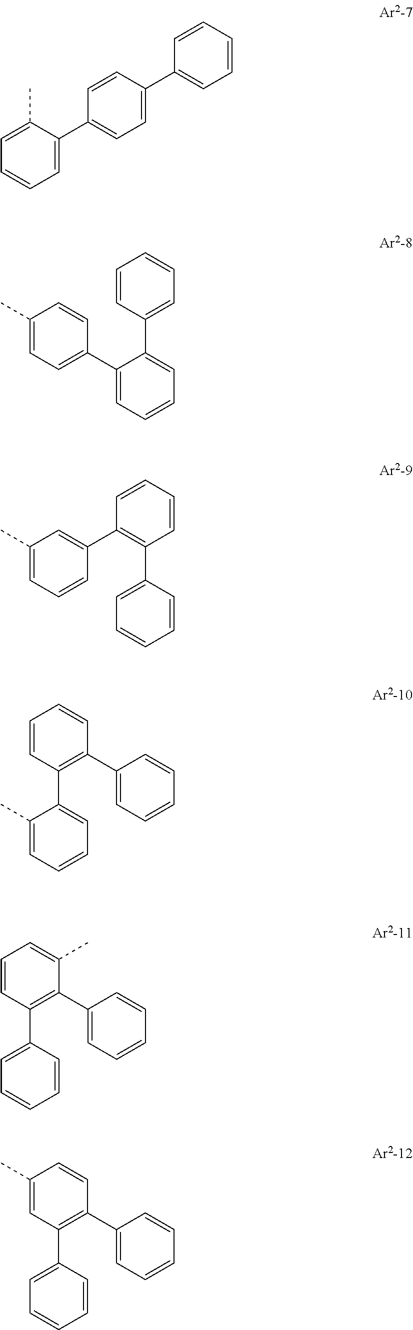

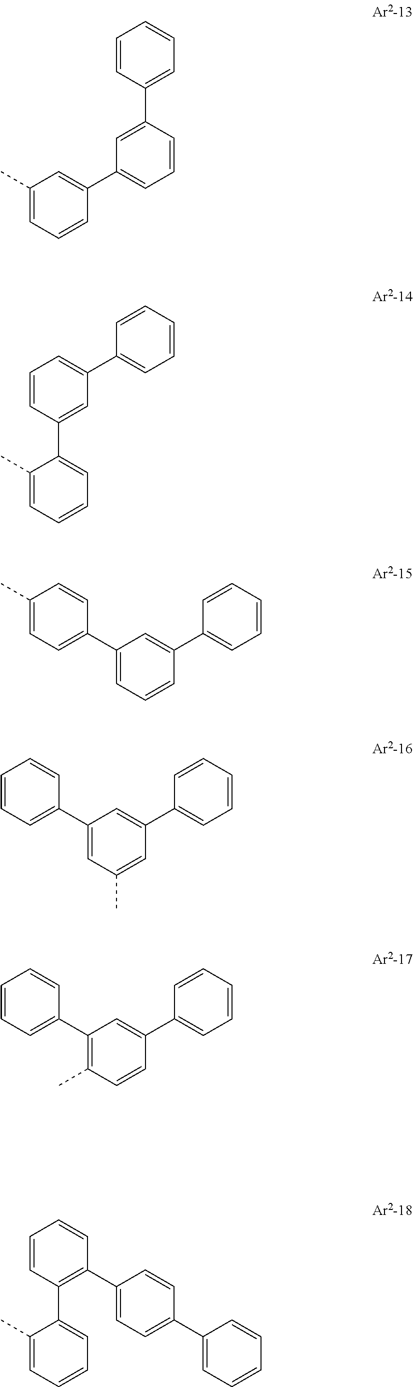

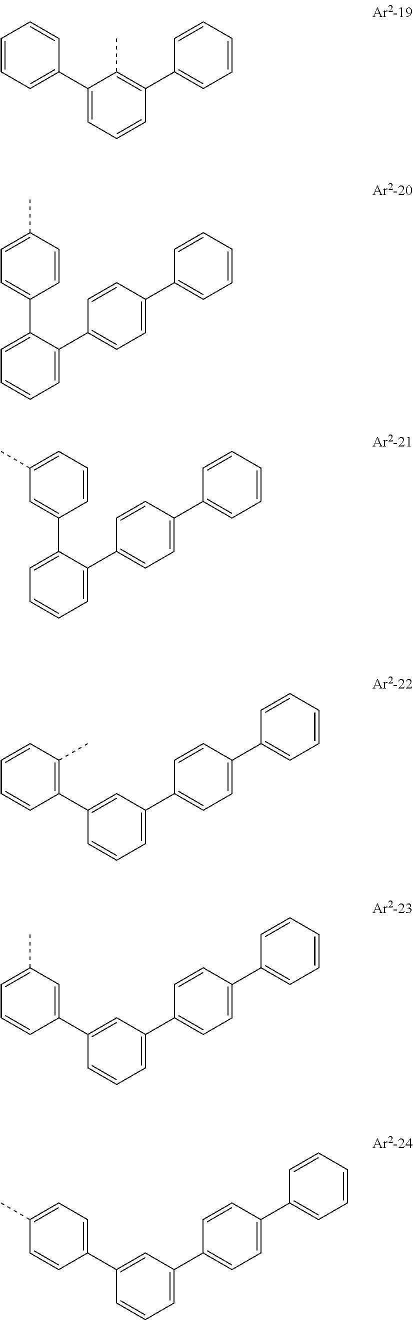

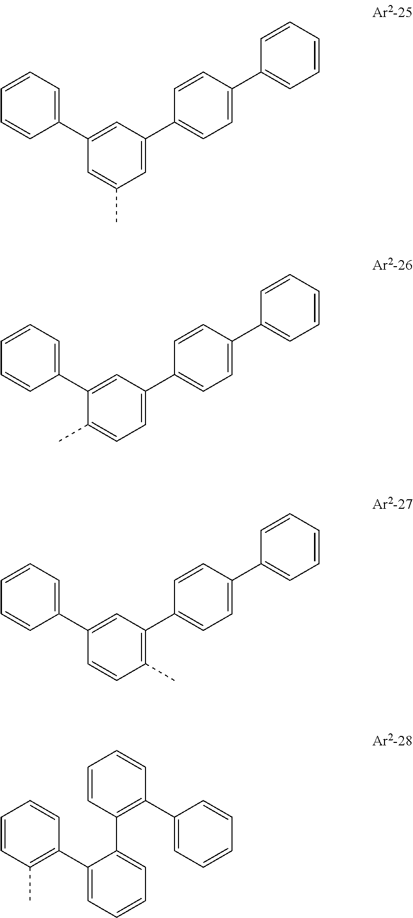

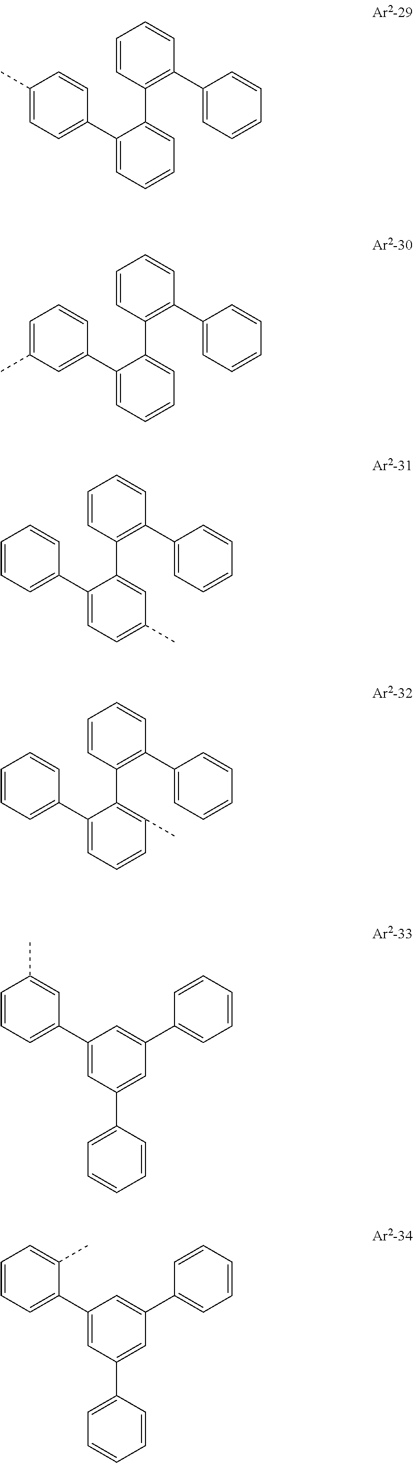

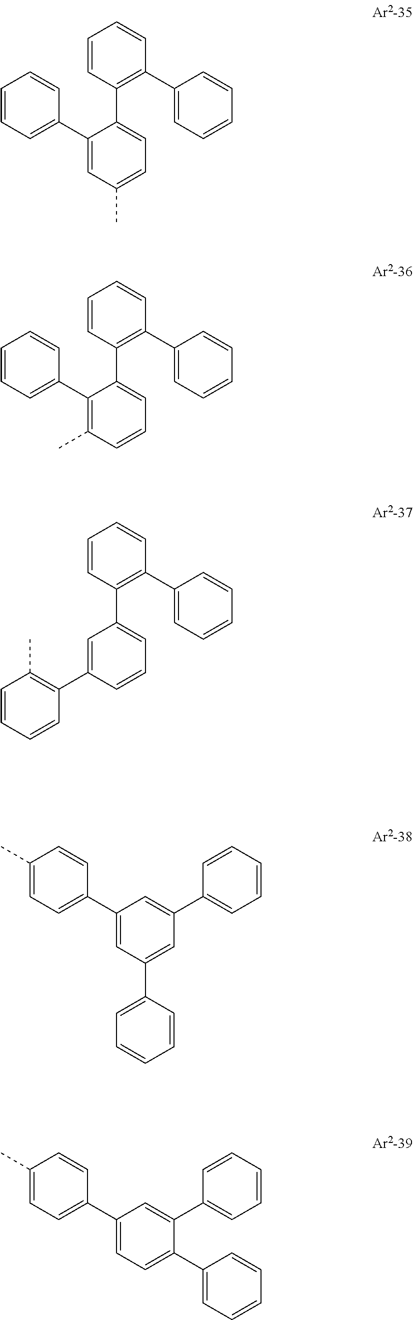

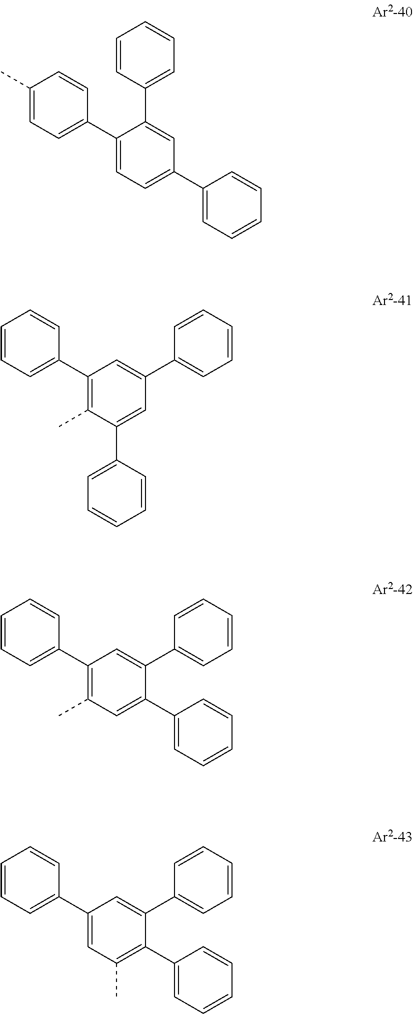

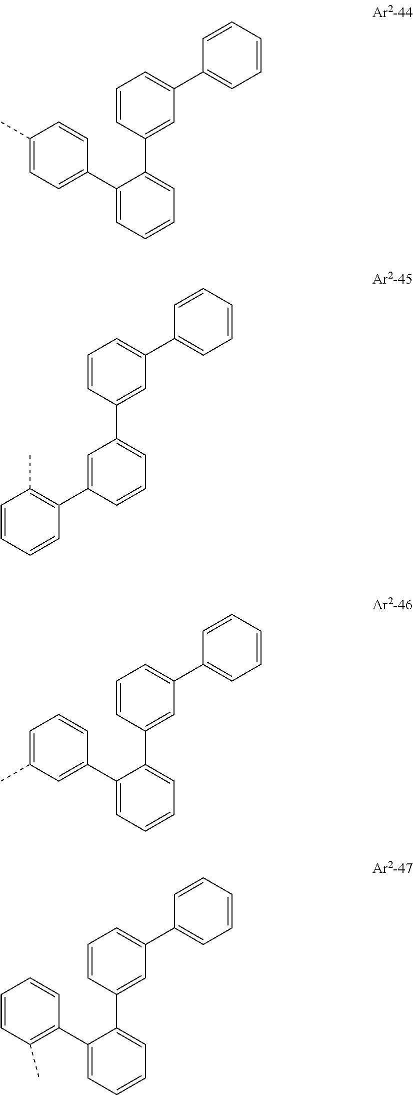

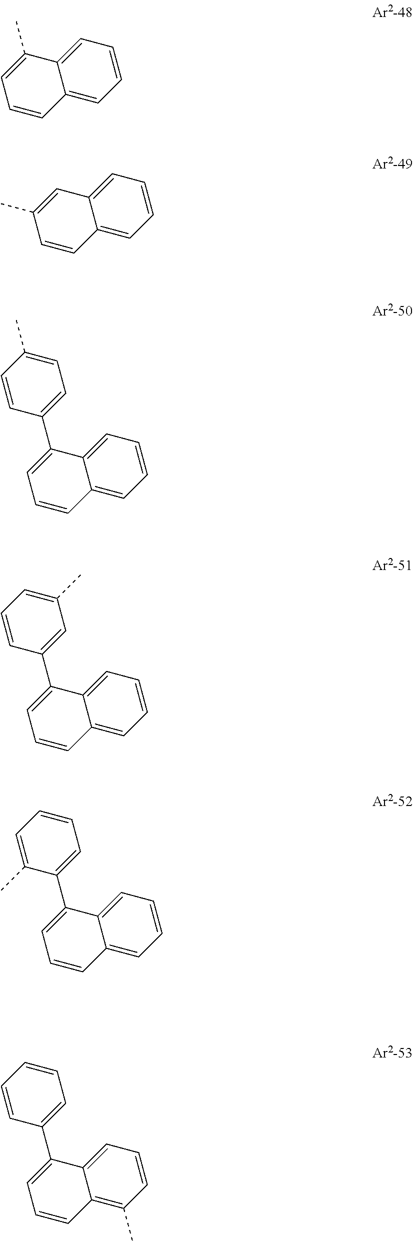

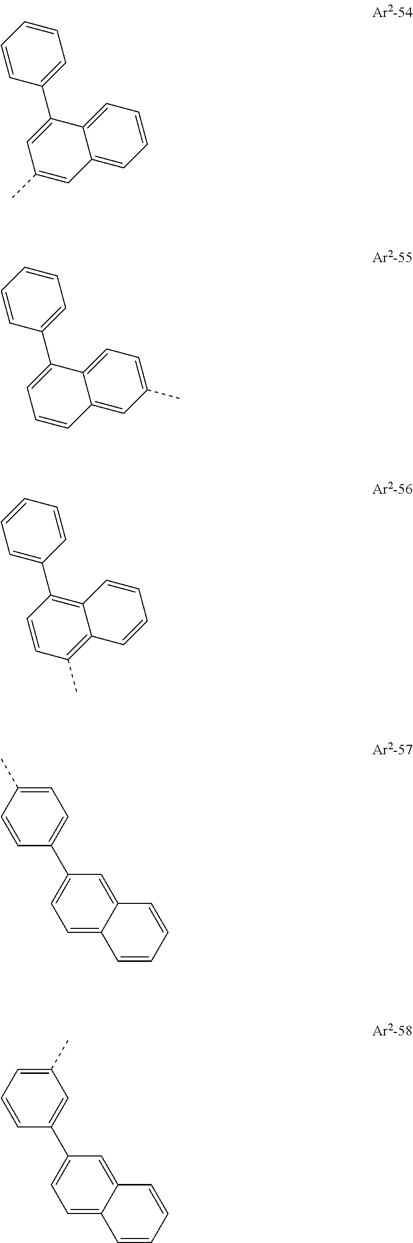

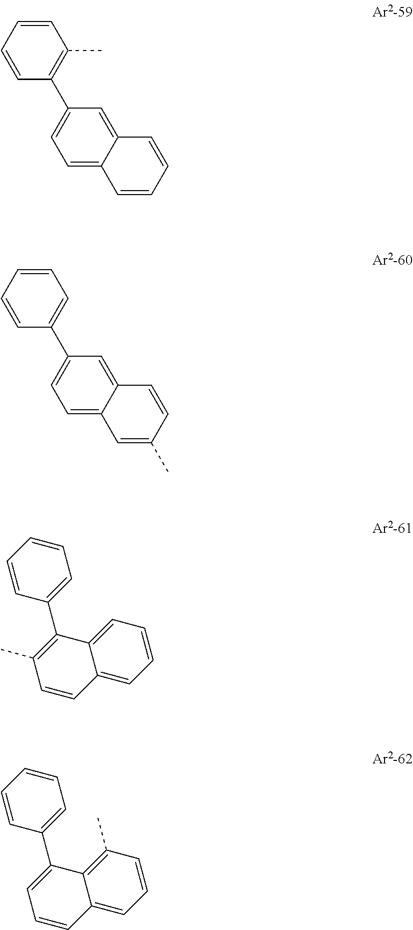

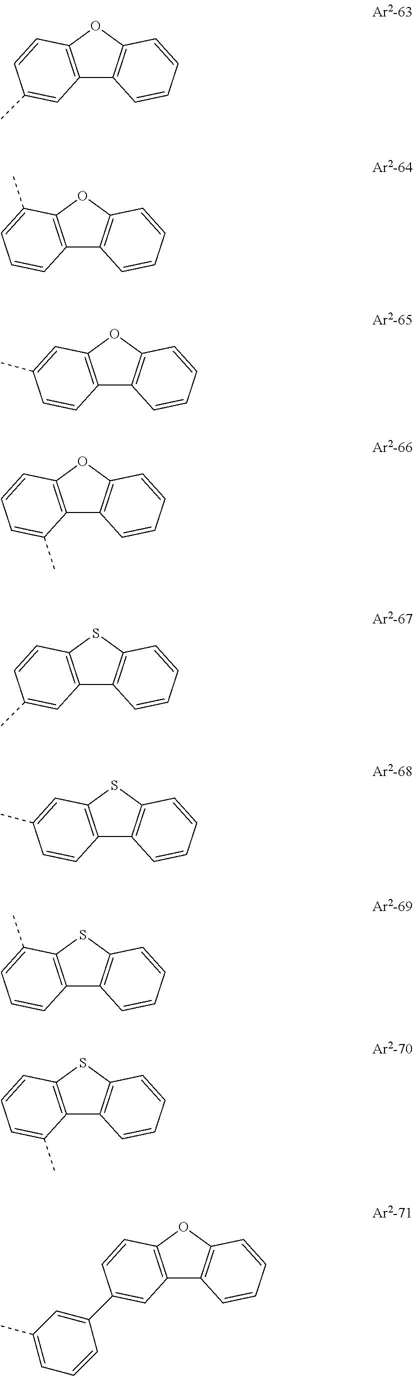

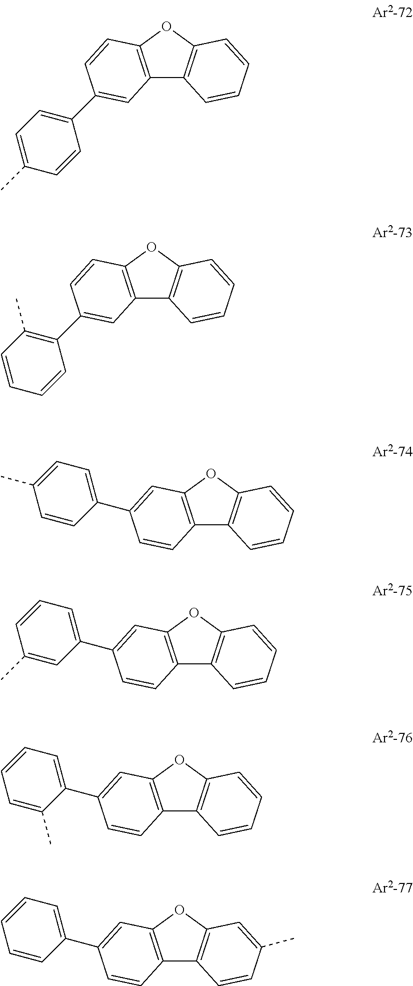

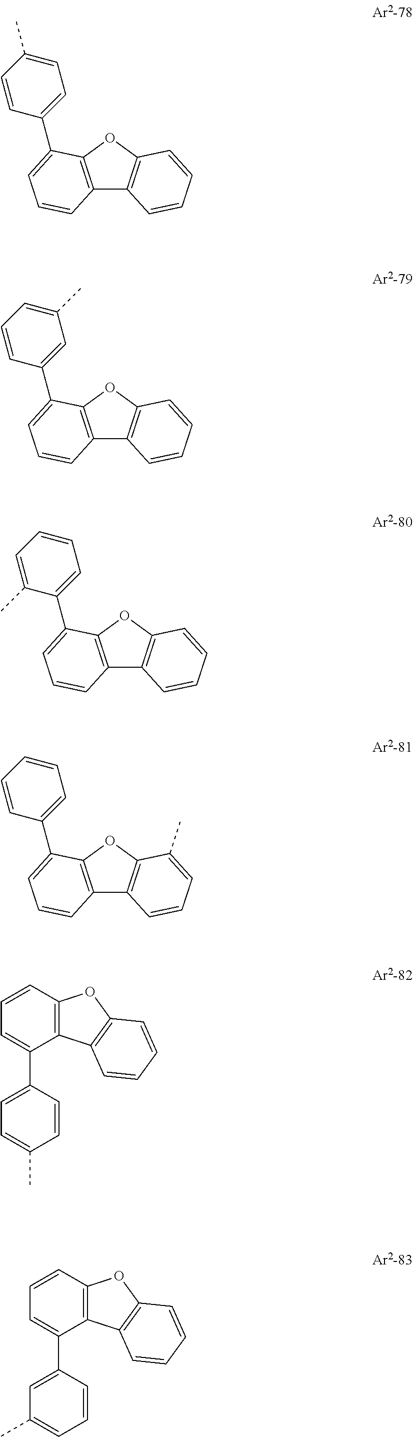

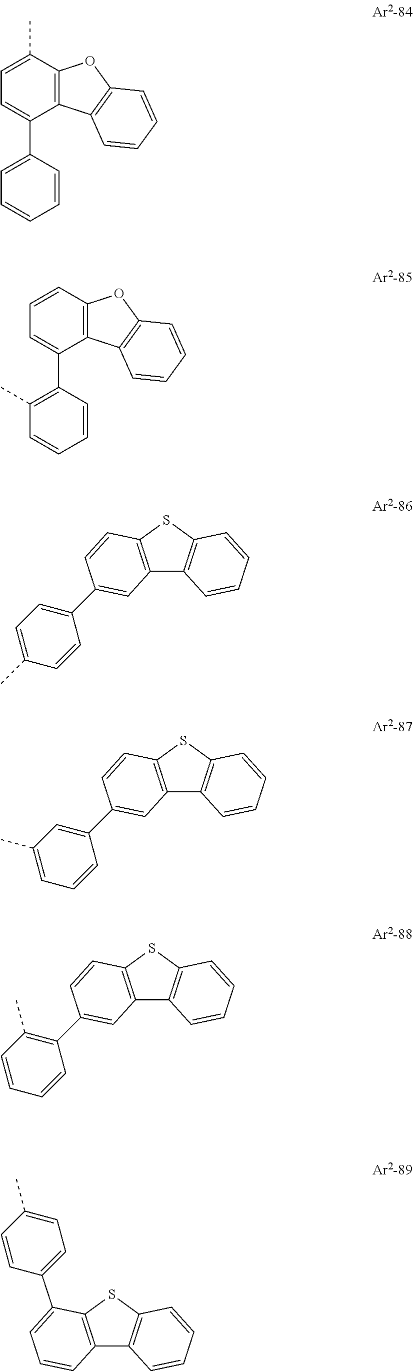

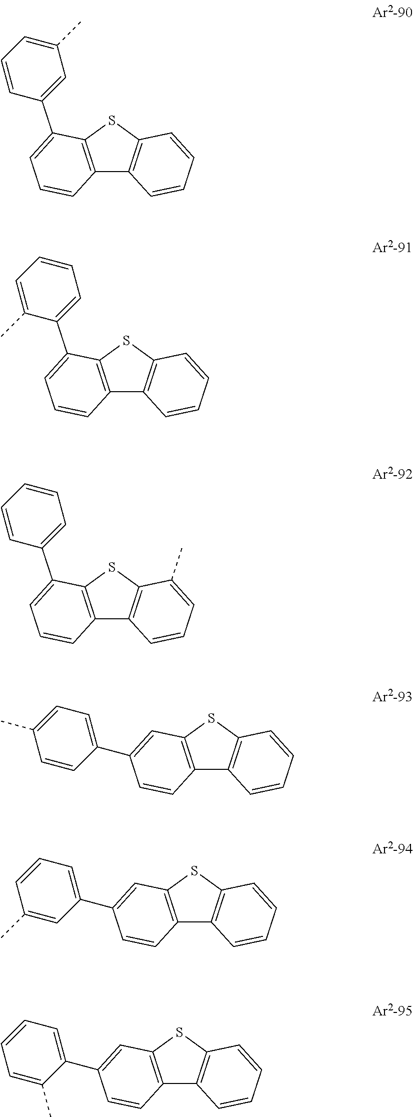

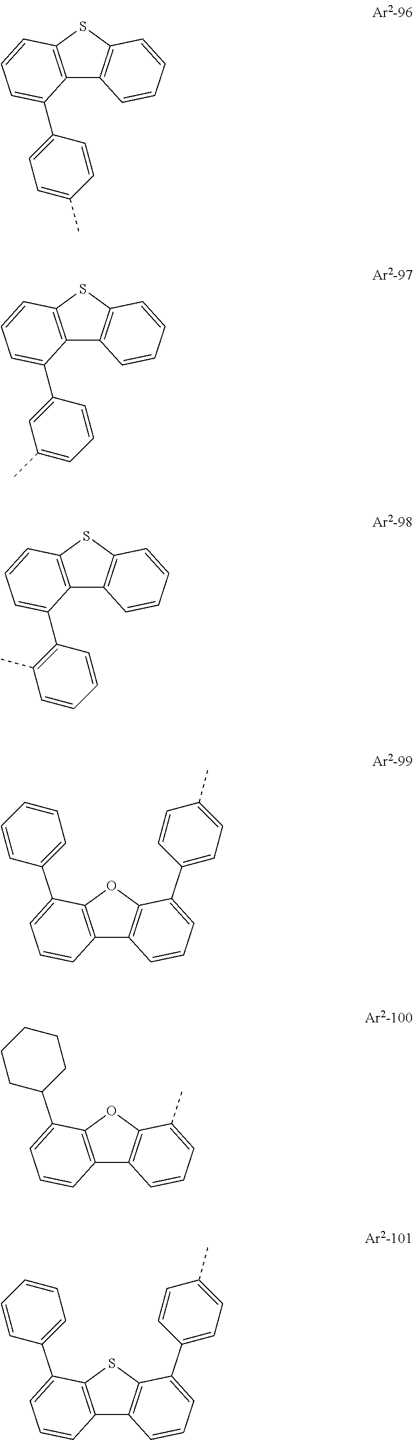

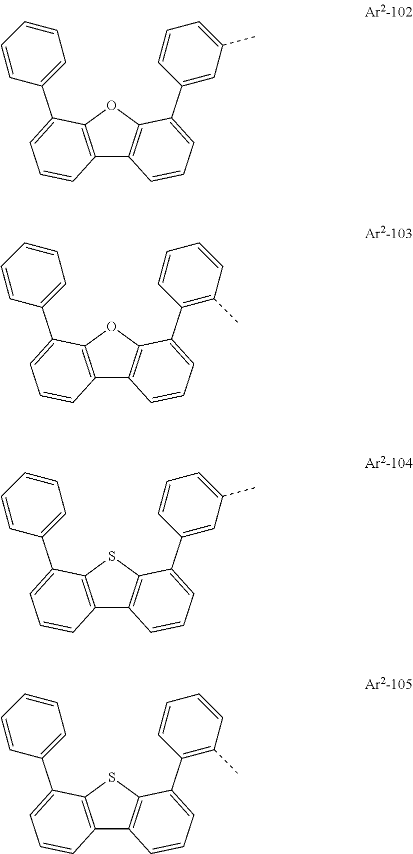

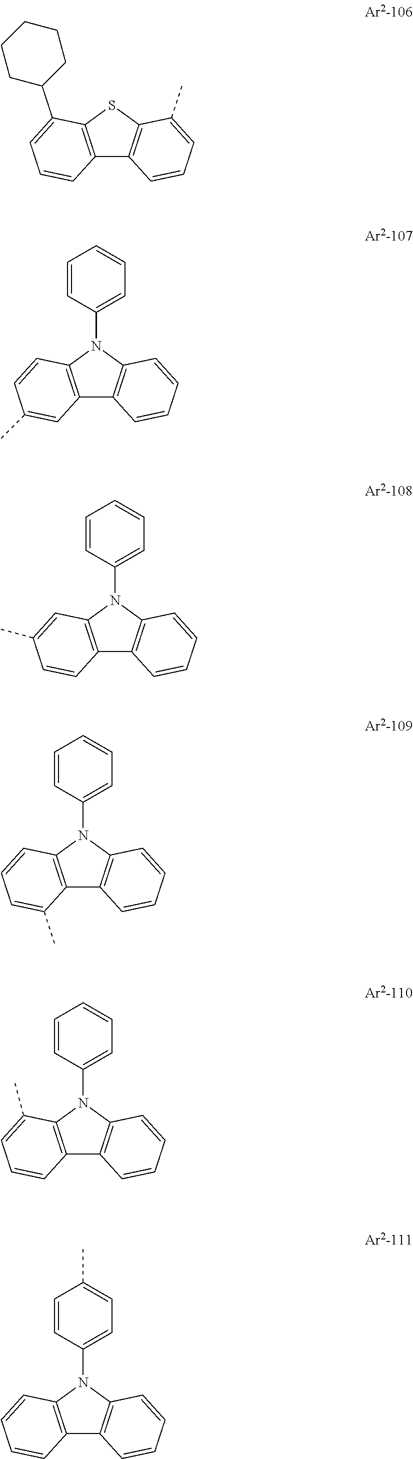

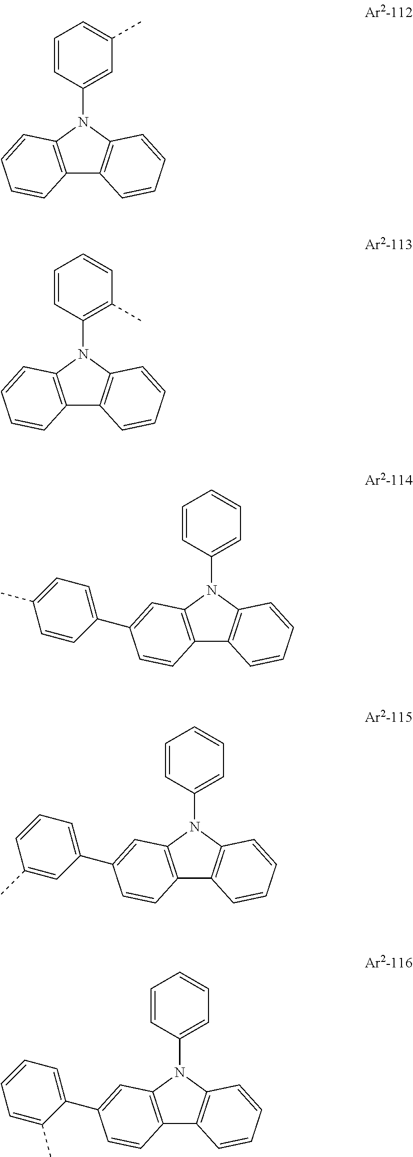

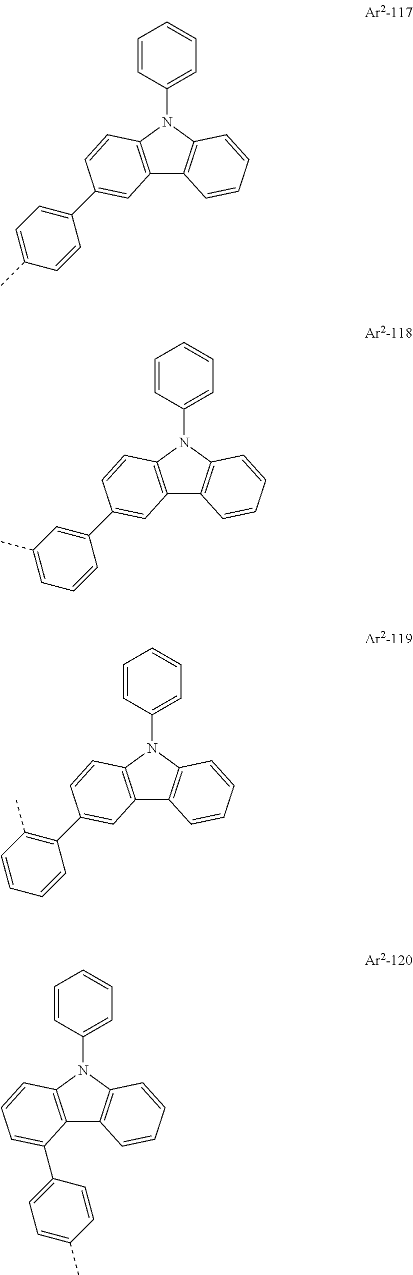

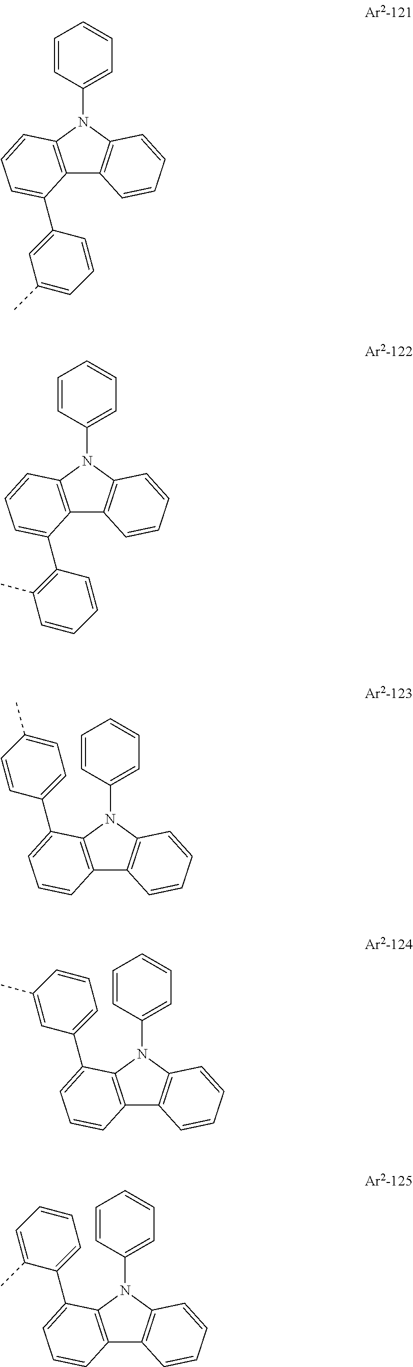

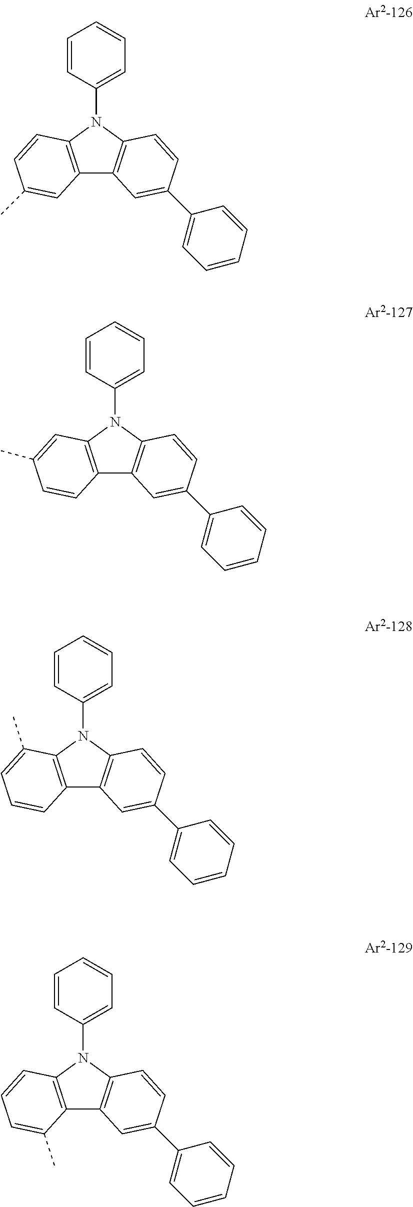

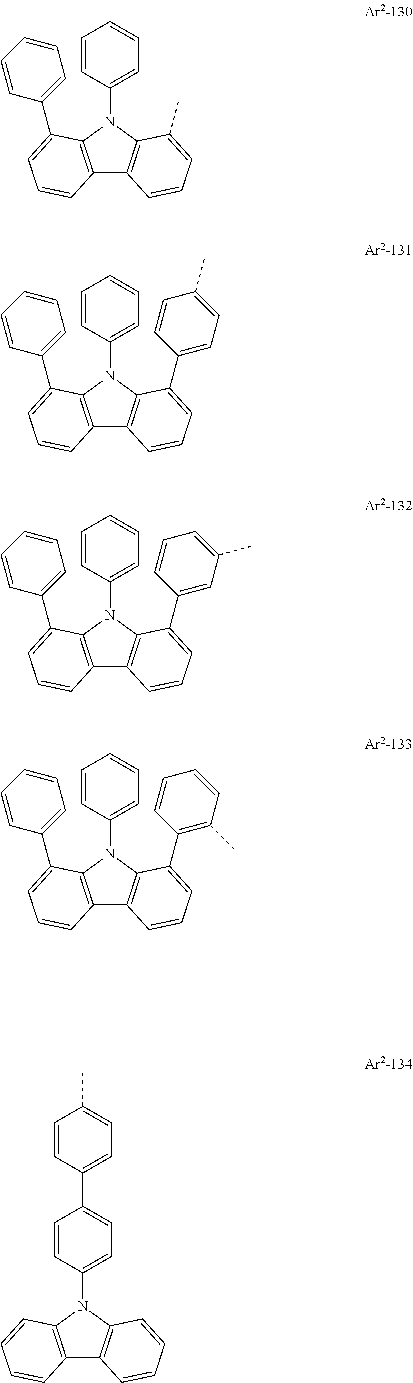

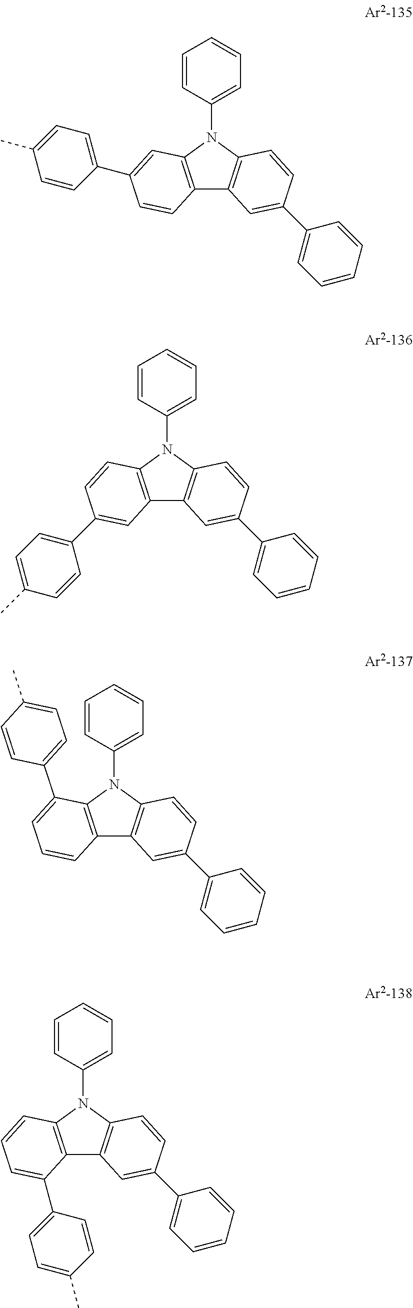

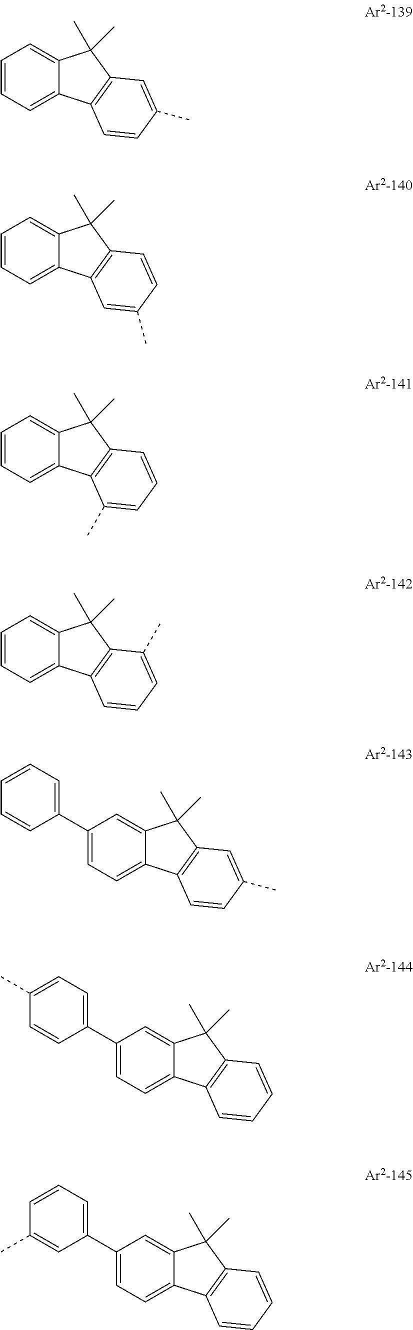

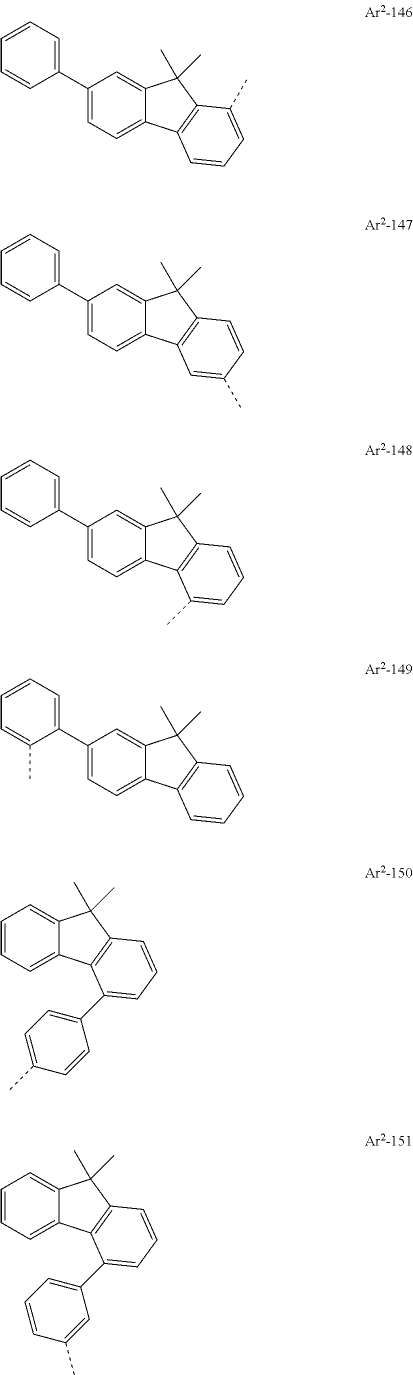

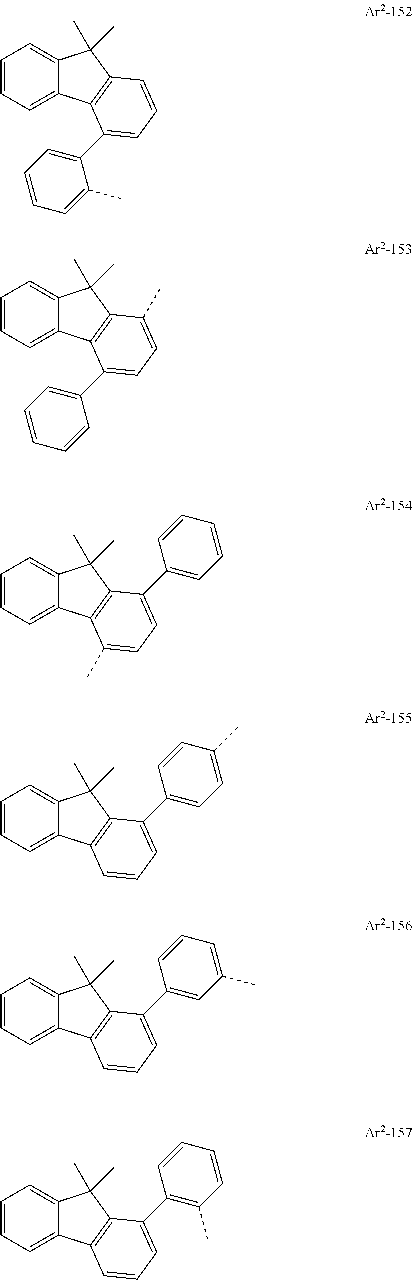

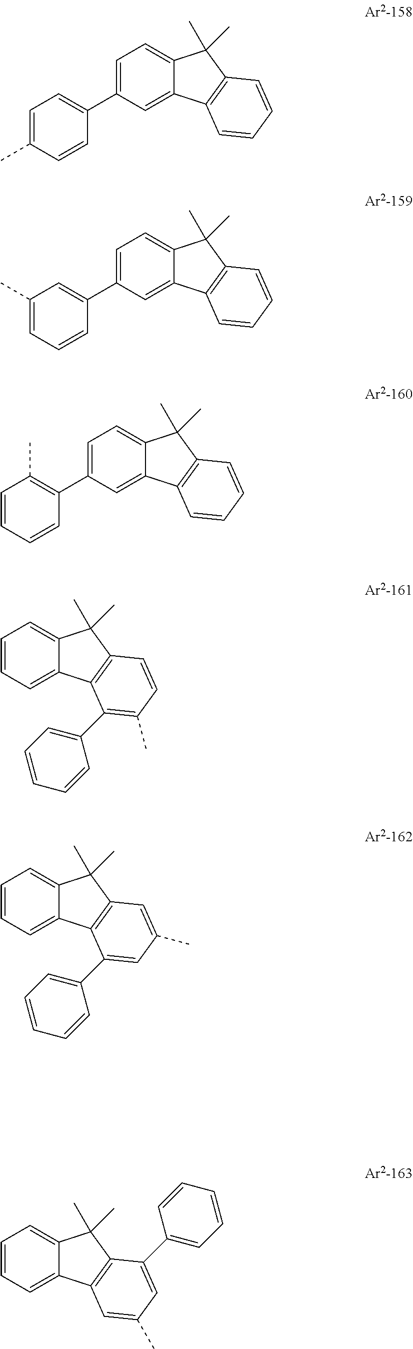

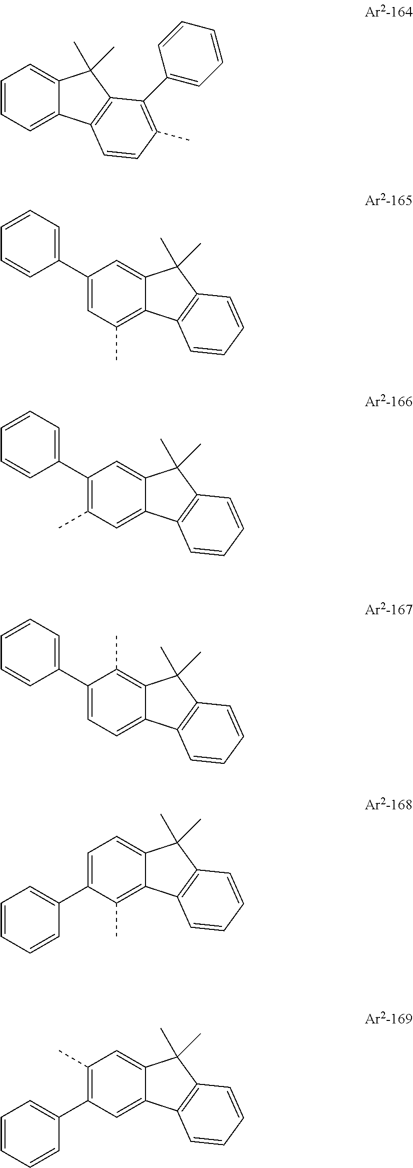

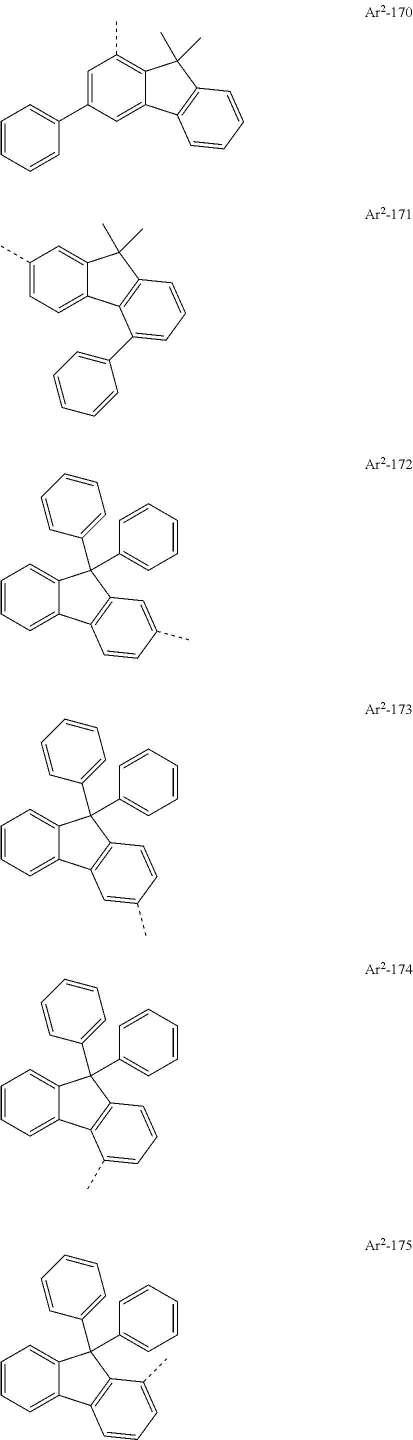

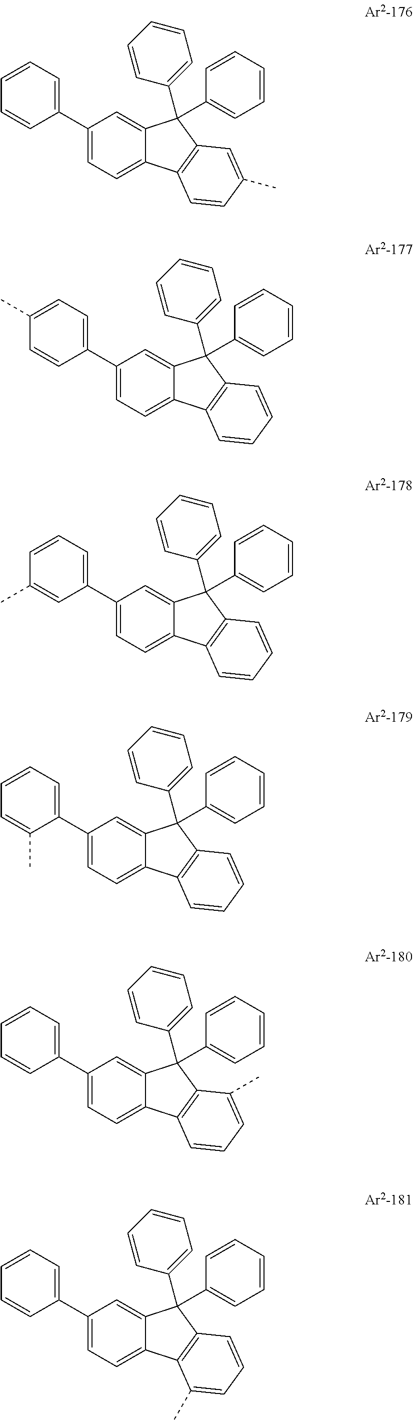

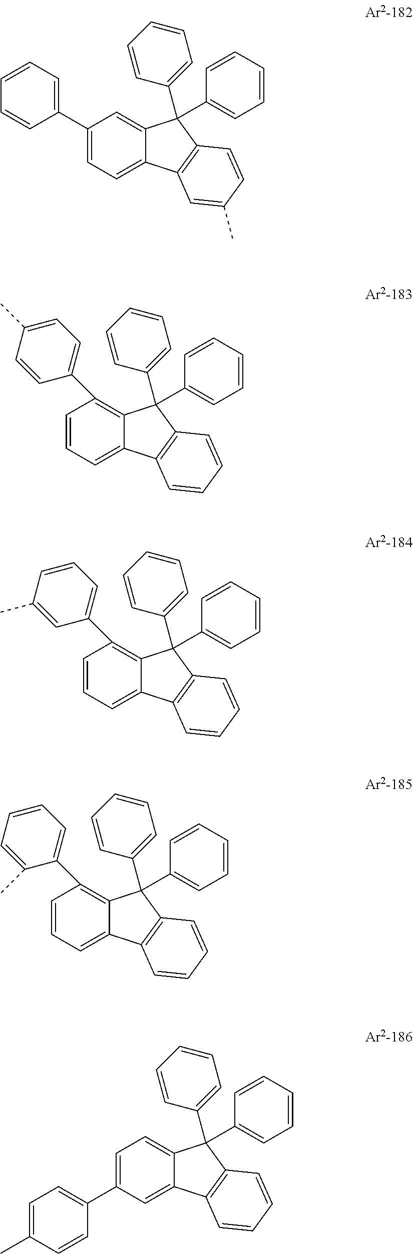

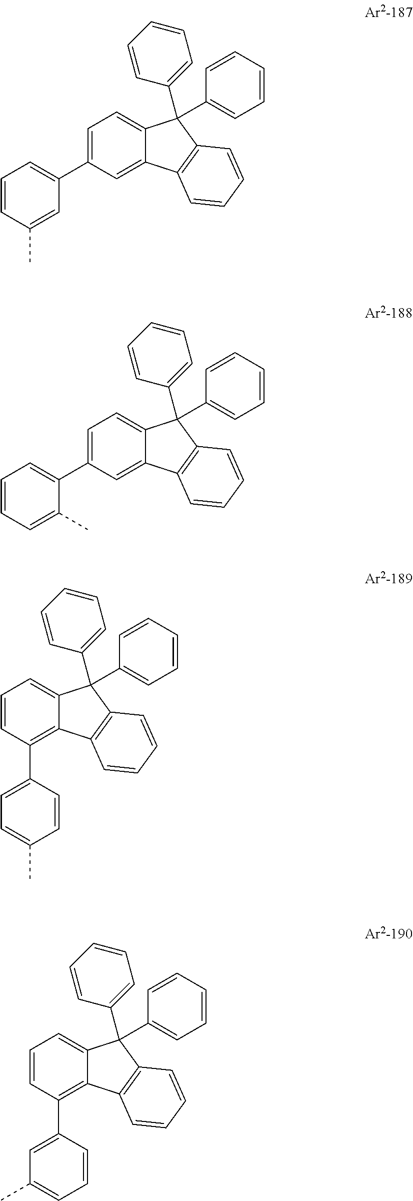

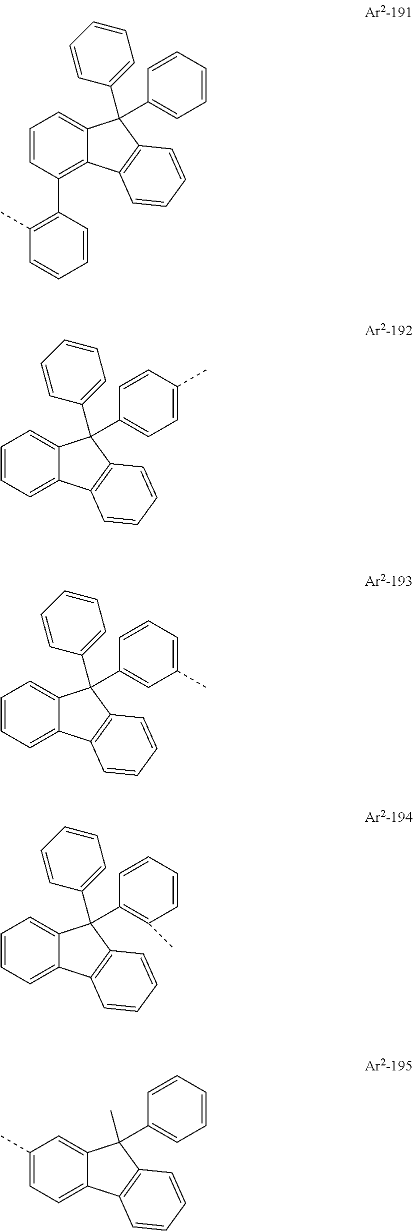

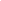

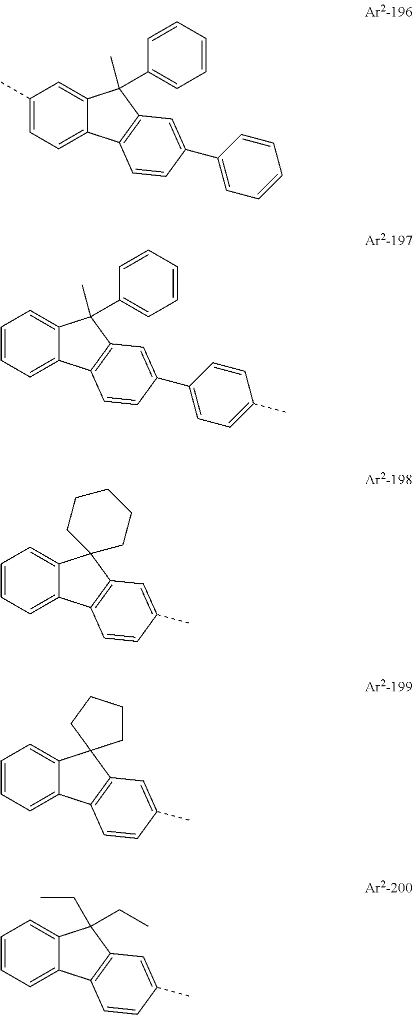

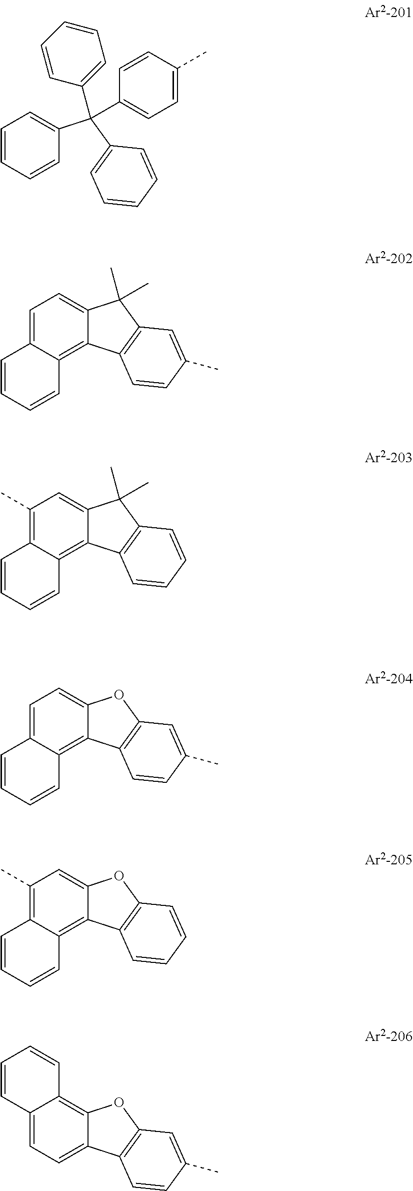

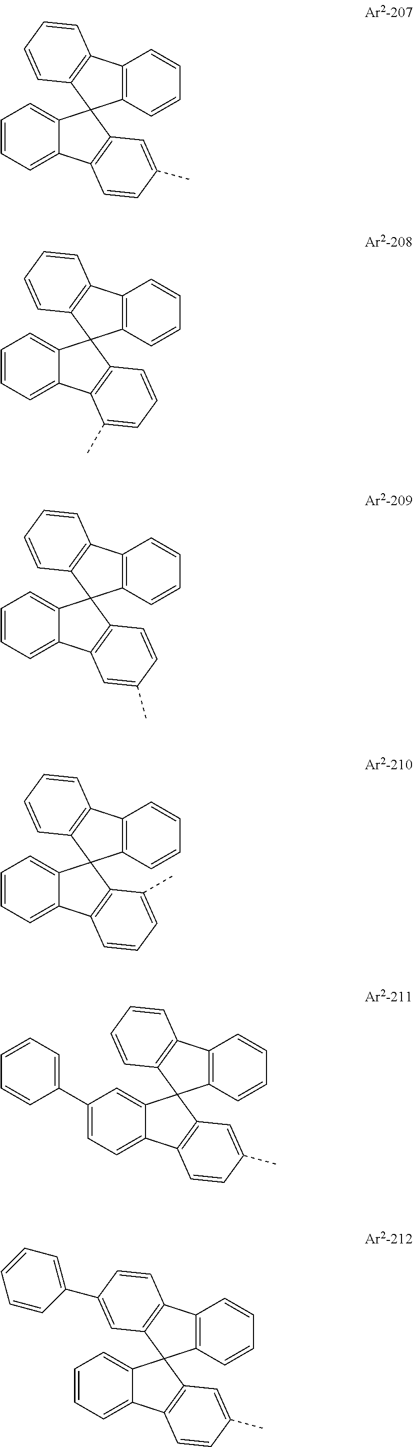

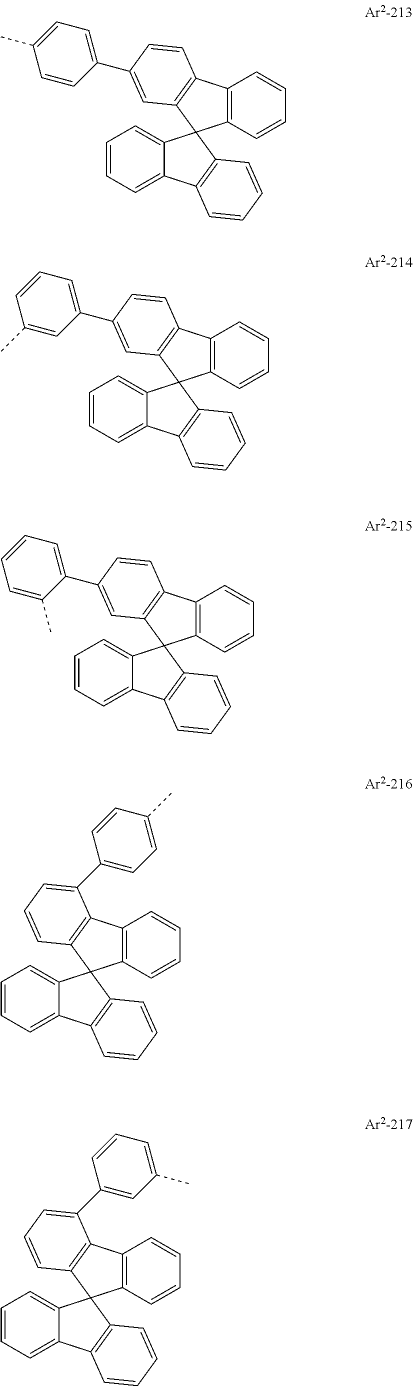

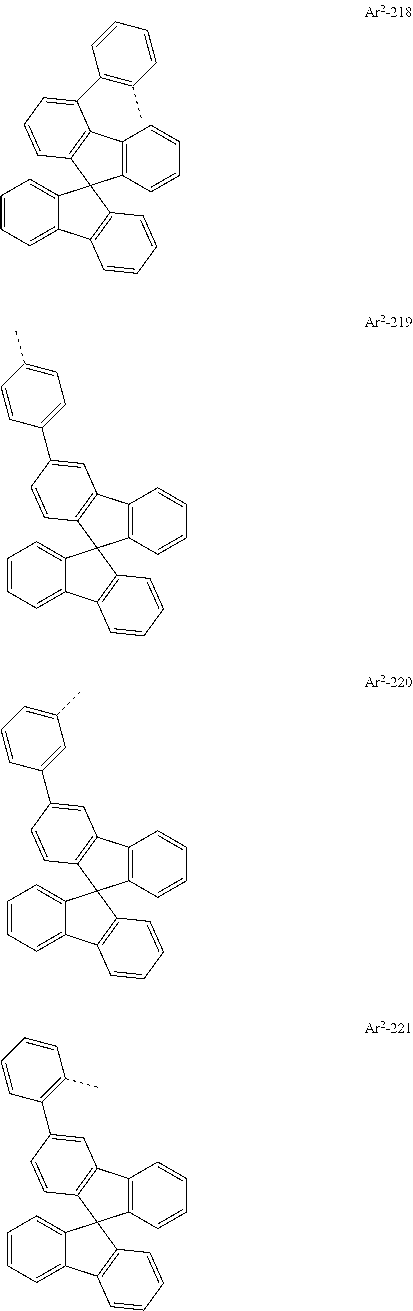

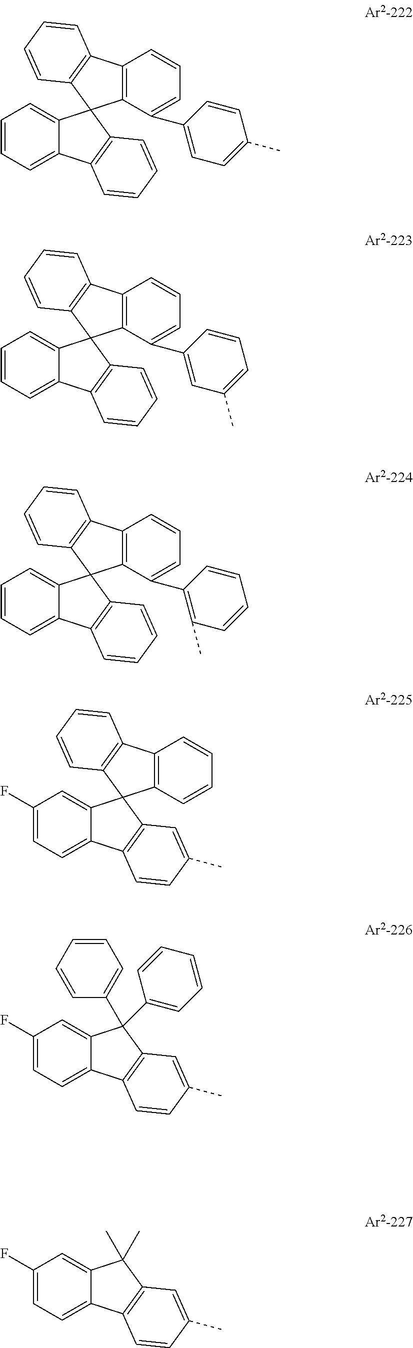

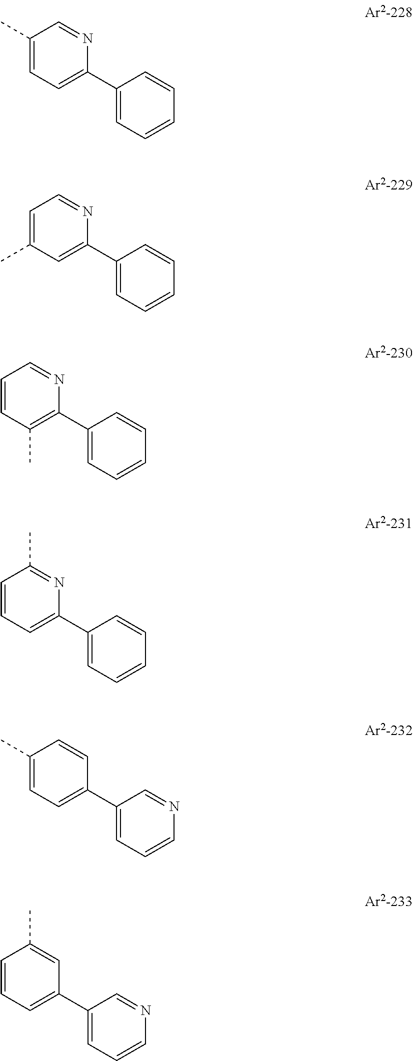

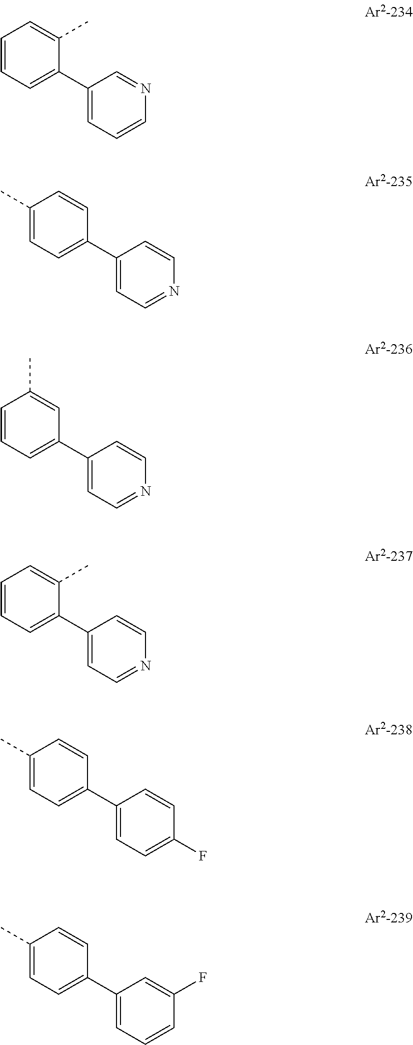

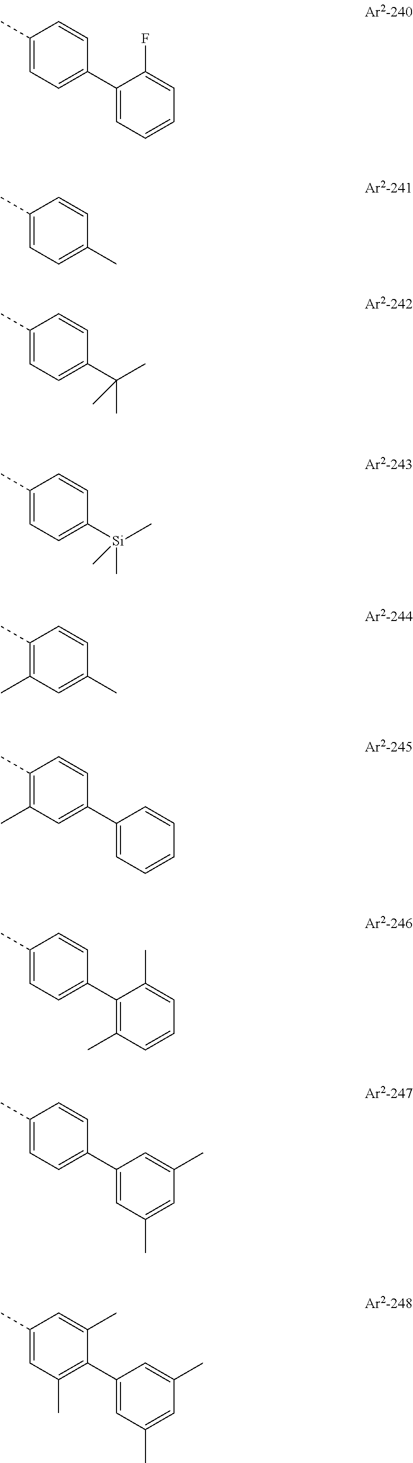

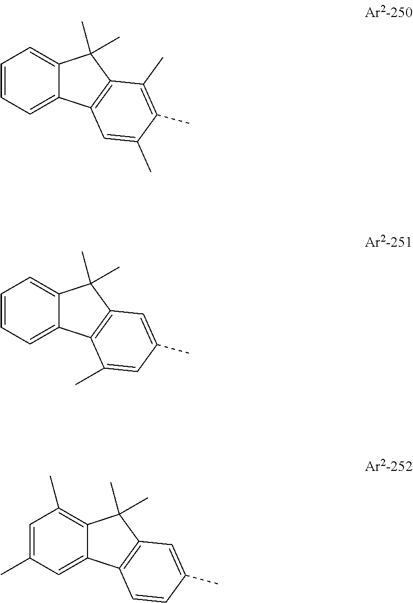

where the groups may each be substituted by an R³ radical at all unoccupied positions, and are preferably unsubstituted in these positions, and where the dashed bond represents the bond to the amine nitrogen atom.

Preferred compounds of the formulae (L-1), (L-2) and (L-3) are shown in the following table:

| | |
|---|---|
| 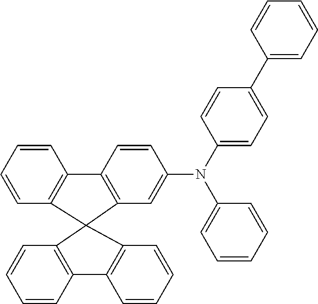 [SMILES: c1ccc(-c2ccc(N(c3ccccc3)c3ccc4c(c3)C3(c5ccccc5-c5ccccc53)c3ccccc3-4)cc2)cc1] | (1) |
| 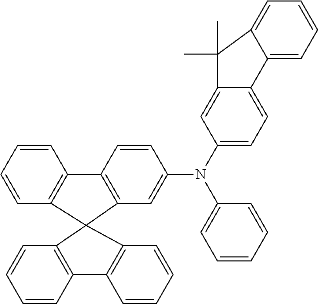 [SMILES: CC1(C)c2ccccc2-c2ccc(N(c3ccccc3)c3ccc4c(c3)C3(c5ccccc5-c5ccccc53)c3ccccc3-4)cc21] | (2) |
| 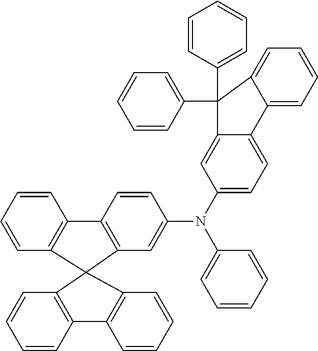 [SMILES: c1ccc(N(c2ccc3c(c2)C(c2ccccc2)(c2ccccc2)c2ccccc2-3)c2ccc3c(c2)C2(c4ccccc4-c4ccccc42)c2ccccc2-3)cc1] | (3) |
| 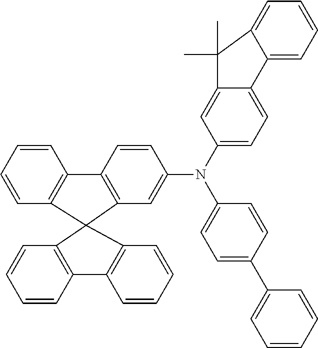 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21] | (4) |
| 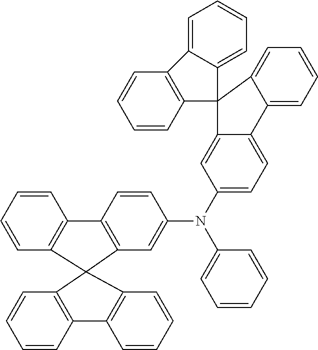 [SMILES: c1ccc(N(c2ccc3c(c2)C2(c4ccccc4-c4ccccc42)c2ccccc2-3)c2ccc3c(c2)C2(c4ccccc4-c4ccccc42)c2ccccc2-3)cc1] | (5) |
| 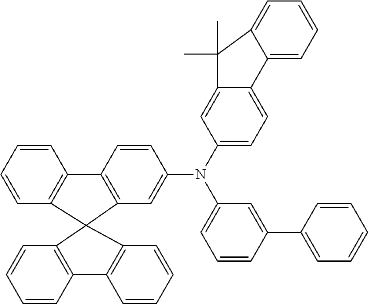 [SMILES: CC1(C)c2ccccc2-c2ccc(N(c3cccc(-c4ccccc4)c3)c3ccc4c(c3)C3(c5ccccc5-c5ccccc53)c3ccccc3-4)cc21] | (6) |
| 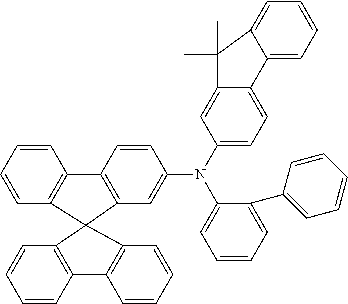 [SMILES: CC1(C)c2ccccc2-c2ccc(N(c3ccc4c(c3)C3(c5ccccc5-c5ccccc53)c3ccccc3-4)c3ccccc3-c3ccccc3)cc21] | (7) |
| 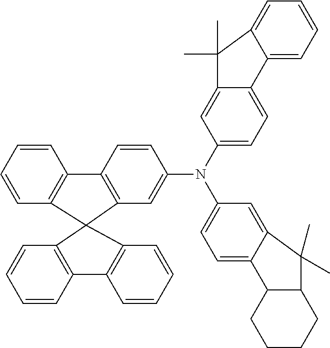 [SMILES: CC1(C)c2ccccc2-c2ccc(N(c3ccc4c(c3)C3(c5ccccc5-c5ccccc53)c3ccccc3-4)c3ccc4c(c3)C(C)(C)C3CCCCC43)cc21] | (8) |
| 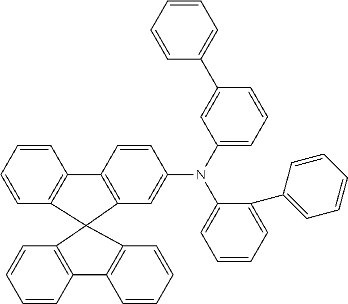 [SMILES: c1ccc(-c2cccc(N(c3ccc4c(c3)C3(c5ccccc5-c5ccccc53)c3ccccc3-4)c3ccccc3-c3ccccc3)c2)cc1] | (9) |
| 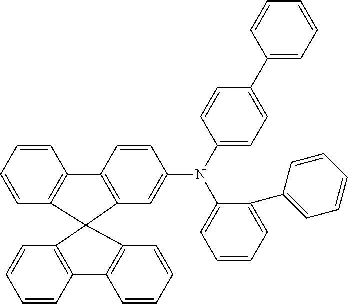 [SMILES: c1ccc(-c2ccc(N(c3ccc4c(c3)C3(c5ccccc5-c5ccccc53)c3ccccc3-4)c3ccccc3-c3ccccc3)cc2)cc1] | (10) |
| 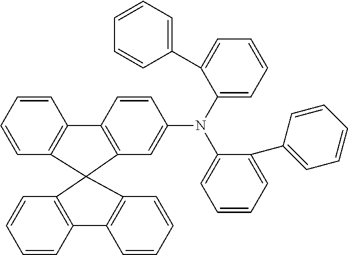 [SMILES: c1ccc(-c2ccccc2N(c2ccc3c(c2)C2(c4ccccc4-c4ccccc42)c2ccccc2-3)c2ccccc2-c2ccccc2)cc1] | (11) |
| 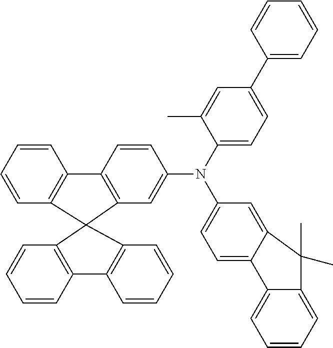 [SMILES: Cc1cc(-c2ccccc2)ccc1N(c1ccc2c(c1)C(C)(C)c1ccccc1-2)c1ccc2c(c1)C1(c3ccccc3-c3ccccc31)c1ccccc1-2] | (12) |
| 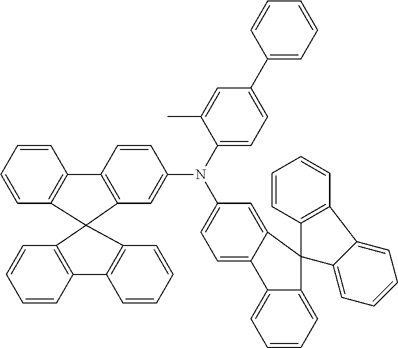 [SMILES: Cc1cc(-c2ccccc2)ccc1N(c1ccc2c(c1)C1(c3ccccc3-c3ccccc31)c1ccccc1-2)c1ccc2c(c1)C1(c3ccccc3-c3ccccc31)c1ccccc1-2] | (13) |
| 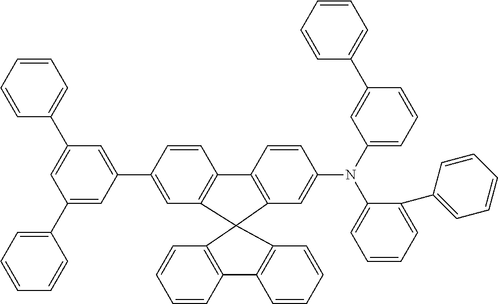 [SMILES: c1ccc(-c2cc(-c3ccccc3)cc(-c3ccc4c(c3)C3(c5ccccc5-c5ccccc53)c3cc(N(c5cccc(-c6ccccc6)c5)c5ccccc5-c5ccccc5)ccc3-4)c2)cc1] | (14) |
| 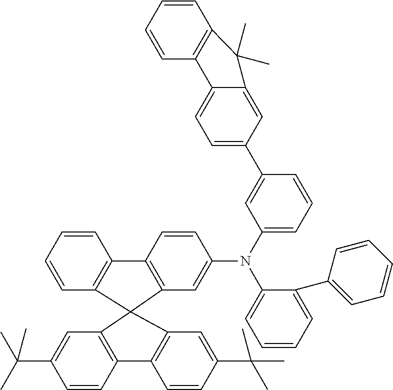 [SMILES: CC(C)(C)c1ccc2c(c1)C1(c3ccccc3-c3ccc(N(c4cccc(-c5ccc6c(c5)C(C)(C)c5ccccc5-6)c4)c4ccccc4-c4ccccc4)cc31)c1cc(C(C)(C)C)ccc1-2] | (15) |
| 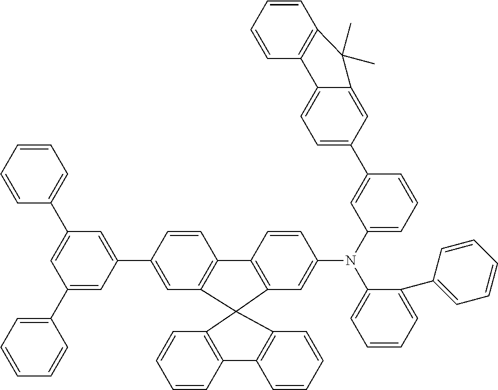 [SMILES: CC1(C)c2ccccc2-c2ccc(-c3cccc(N(c4ccc5c(c4)C4(c6ccccc6-c6ccccc64)c4cc(-c6cc(-c7ccccc7)cc(-c7ccccc7)c6)ccc4-5)c4ccccc4-c4ccccc4)c3)cc21] | (16) |
| 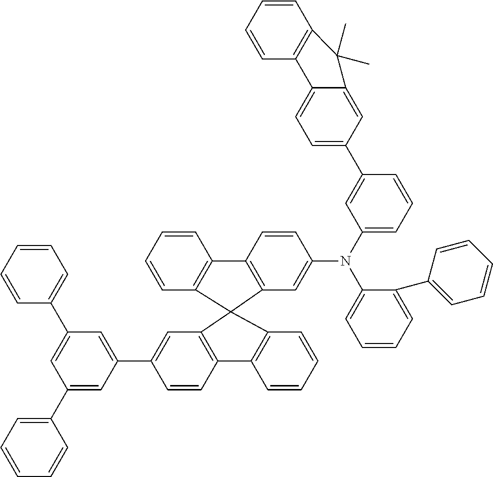 [SMILES: CC1(C)c2ccccc2-c2ccc(-c3cccc(N(c4ccc5c(c4)C4(c6ccccc6-c6ccc(-c7cc(-c8ccccc8)cc(-c8ccccc8)c7)cc64)c4ccccc4-5)c4ccccc4-c4ccccc4)c3)cc21] | (17) |
| 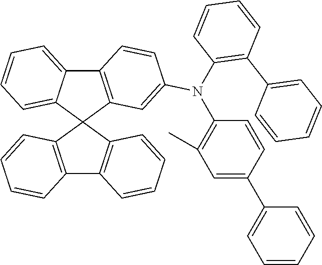 [SMILES: Cc1cc(-c2ccccc2)ccc1N(c1ccc2c(c1)C1(c3ccccc3-c3ccccc31)c1ccccc1-2)c1ccccc1-c1ccccc1] | (18) |
| 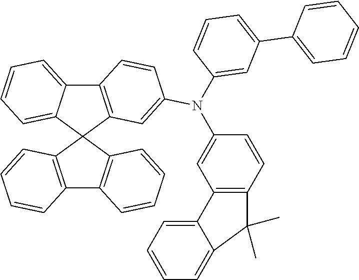 [SMILES: CC1(C)c2ccccc2-c2cc(N(c3cccc(-c4ccccc4)c3)c3ccc4c(c3)C3(c5ccccc5-c5ccccc53)c3ccccc3-4)ccc21] | (19) |
| 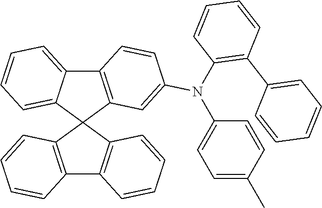 [SMILES: Cc1ccc(N(c2ccc3c(c2)C2(c4ccccc4-c4ccccc42)c2ccccc2-3)c2ccccc2-c2ccccc2)cc1] | (20) |
| 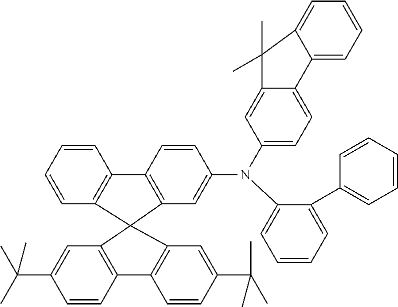 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2] | (21) |
| 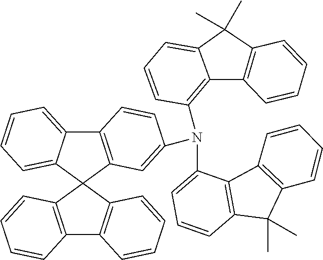 [SMILES: CC1(C)c2ccccc2-c2c(N(c3ccc4c(c3)C3(c5ccccc5-c5ccccc53)c3ccccc3-4)c3cccc4c3-c3ccccc3C4(C)C)cccc21] | (22) |
| 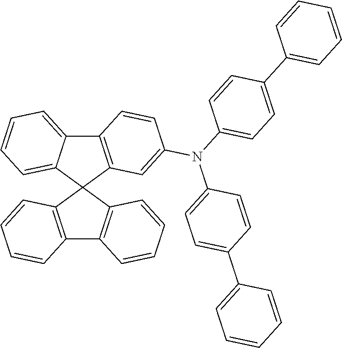 [SMILES: c1ccc(-c2ccc(N(c3ccc(-c4ccccc4)cc3)c3ccc4c(c3)C3(c5ccccc5-c5ccccc53)c3ccccc3-4)cc2)cc1] | (23) |
| 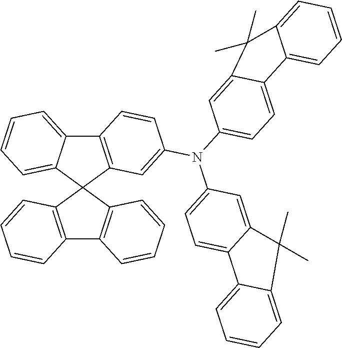 [SMILES: CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21] | (24) |
| 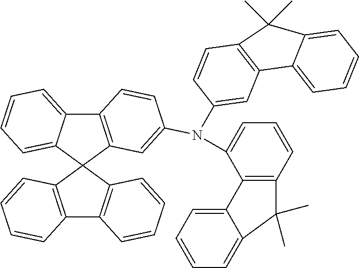 [SMILES: CC1(C)c2ccccc2-c2cc(N(c3ccc4c(c3)C3(c5ccccc5-c5ccccc53)c3ccccc3-4)c3cccc4c3-c3ccccc3C4(C)C)ccc21] | (25) |
| 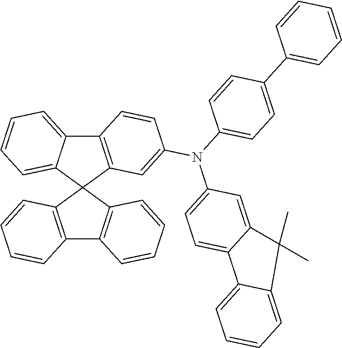 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21] | (26) |
| 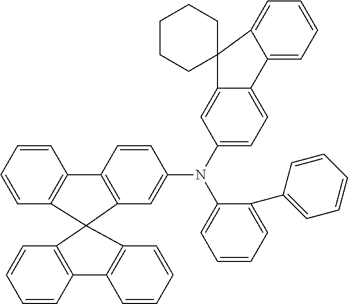 [SMILES: c1ccc(-c2ccccc2N(c2ccc3c(c2)C2(CCCCC2)c2ccccc2-3)c2ccc3c(c2)C2(c4ccccc4-c4ccccc42)c2ccccc2-3)cc1] | (27) |
| 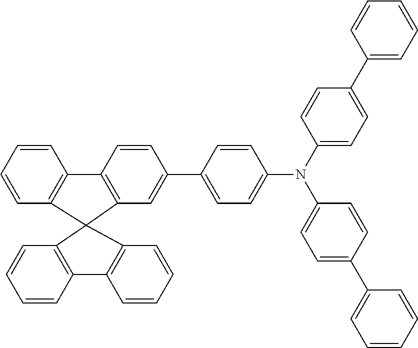 [SMILES: c1ccc(-c2ccc(N(c3ccc(-c4ccccc4)cc3)c3ccc(-c4ccc5c(c4)C4(c6ccccc6-c6ccccc64)c4ccccc4-5)cc3)cc2)cc1] | (28) |
| 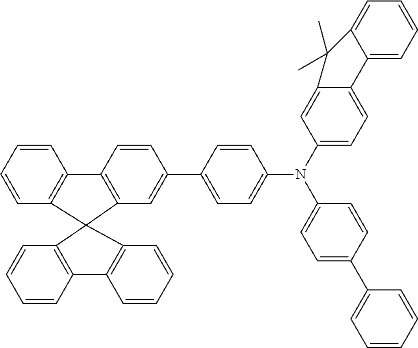 [SMILES: CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21] | (29) |
| 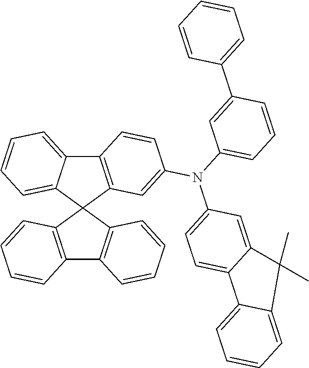 [SMILES: CC1(C)c2ccccc2-c2ccc(N(c3cccc(-c4ccccc4)c3)c3ccc4c(c3)C3(c5ccccc5-c5ccccc53)c3ccccc3-4)cc21] | (30) |
| 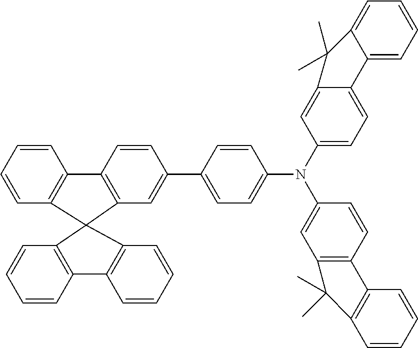 [SMILES: CC1(C)c2ccccc2-c2ccc(N(c3ccc(-c4ccc5c(c4)C4(c6ccccc6-c6ccccc64)c4ccccc4-5)cc3)c3ccc4c(c3)C(C)(C)c3ccccc3-4)cc21] | (31) |
| 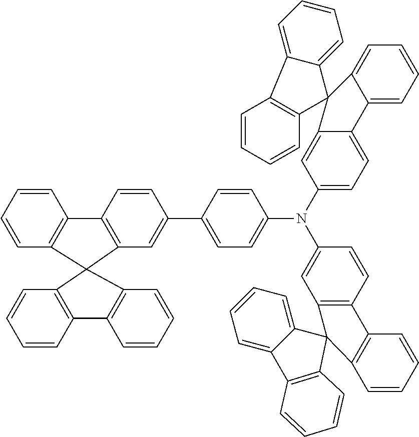 [SMILES: c1ccc2c(c1)-c1ccccc1C21c2ccccc2-c2ccc(-c3ccc(N(c4ccc5c(c4)C4(c6ccccc6-c6ccccc64)c4ccccc4-5)c4ccc5c(c4)C4(c6ccccc6-c6ccccc64)c4ccccc4-5)cc3)cc21] | (32) |
| 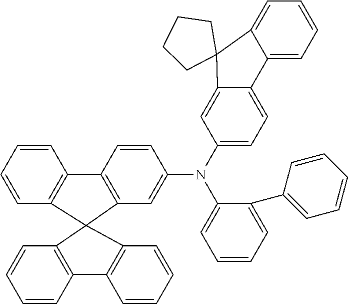 [SMILES: c1ccc(-c2ccccc2N(c2ccc3c(c2)C2(CCCC2)c2ccccc2-3)c2ccc3c(c2)C2(c4ccccc4-c4ccccc42)c2ccccc2-3)cc1] | (33) |
| 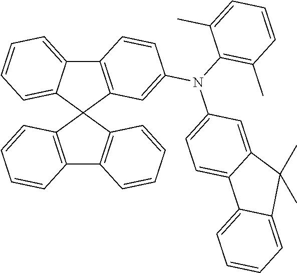 [SMILES: Cc1cccc(C)c1N(c1ccc2c(c1)C(C)(C)c1ccccc1-2)c1ccc2c(c1)C1(c3ccccc3-c3ccccc31)c1ccccc1-2] | (34) |
| 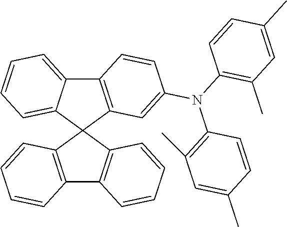 [SMILES: Cc1ccc(N(c2ccc3c(c2)C2(c4ccccc4-c4ccccc42)c2ccccc2-3)c2ccc(C)cc2C)c(C)c1] | (35) |
| 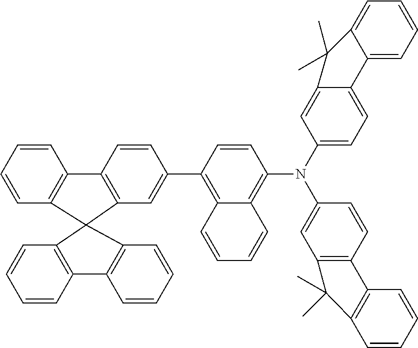 [SMILES: CC1(C)c2ccccc2-c2ccc(N(c3ccc4c(c3)C(C)(C)c3ccccc3-4)c3ccc(-c4ccc5c(c4)C4(c6ccccc6-c6ccccc64)c4ccccc4-5)c4ccccc34)cc21] | (36) |
| 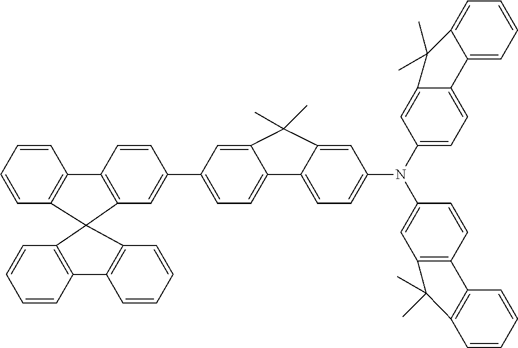 [SMILES: CC1(C)c2ccccc2-c2ccc(N(c3ccc4c(c3)C(C)(C)c3ccccc3-4)c3ccc4c(c3)C(C)(C)c3cc(-c5ccc6c(c5)C5(c7ccccc7-c7ccccc75)c5ccccc5-6)ccc3-4)cc21] | (37) |
| 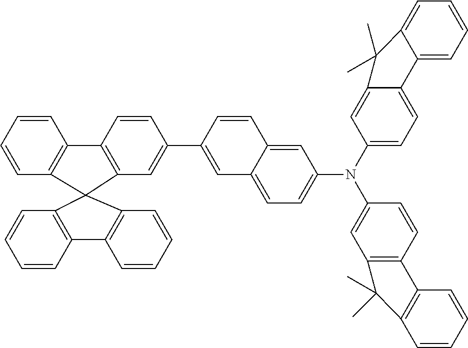 [SMILES: CC1(C)c2ccccc2-c2ccc(N(c3ccc4c(c3)C(C)(C)c3ccccc3-4)c3ccc4cc(-c5ccc6c(c5)C5(c7ccccc7-c7ccccc75)c5ccccc5-6)ccc4c3)cc21] | (38) |
| 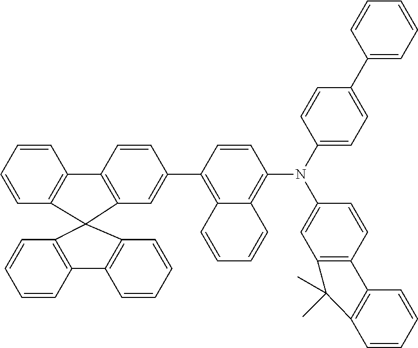 [SMILES: CC1(C)c2ccccc2-c2ccc(N(c3ccc(-c4ccccc4)cc3)c3ccc(-c4ccc5c(c4)C4(c6ccccc6-c6ccccc64)c4ccccc4-5)c4ccccc34)cc21] | (39) |
| 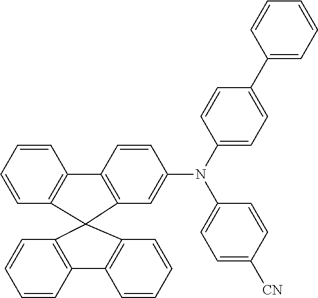 [SMILES: N#Cc1ccc(N(c2ccc(-c3ccccc3)cc2)c2ccc3c(c2)C2(c4ccccc4-c4ccccc42)c2ccccc2-3)cc1] | (40) |
| 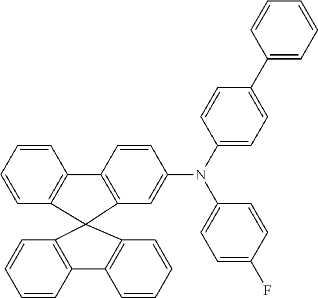 [SMILES: Fc1ccc(N(c2ccc(-c3ccccc3)cc2)c2ccc3c(c2)C2(c4ccccc4-c4ccccc42)c2ccccc2-3)cc1] | (41) |
| 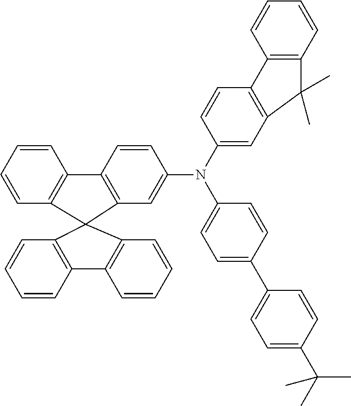 [SMILES: CC(C)(C)c1ccc(-c2ccc(N(c3ccc4c(c3)C(C)(C)c3ccccc3-4)c3ccc4c(c3)C3(c5ccccc5-c5ccccc53)c3ccccc3-4)cc2)cc1] | (42) |
| 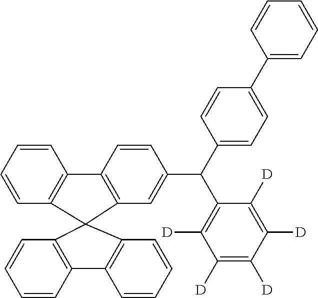 [SMILES: [2H]c1c([2H])c([2H])c(C(c2ccc(-c3ccccc3)cc2)c2ccc3c(c2)C2(c4ccccc4-c4ccccc42)c2ccccc2-3)c([2H])c1[2H]] | (43) |
| 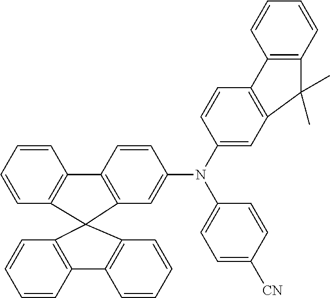 [SMILES: CC1(C)c2ccccc2-c2ccc(N(c3ccc(C#N)cc3)c3ccc4c(c3)C3(c5ccccc5-c5ccccc53)c3ccccc3-4)cc21] | (44) |
| 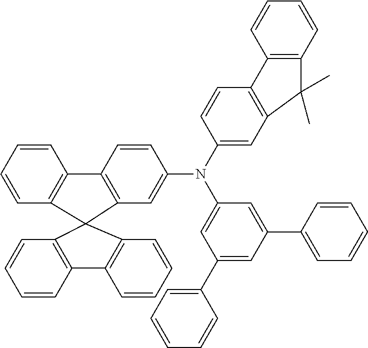 [SMILES: CC1(C)c2ccccc2-c2ccc(N(c3cc(-c4ccccc4)cc(-c4ccccc4)c3)c3ccc4c(c3)C3(c5ccccc5-c5ccccc53)c3ccccc3-4)cc21] | (45) |
| 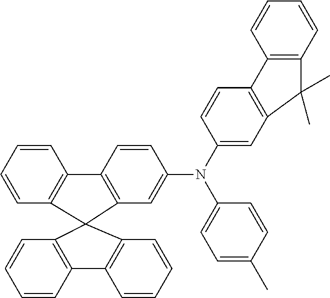 [SMILES: Cc1ccc(N(c2ccc3c(c2)C(C)(C)c2ccccc2-3)c2ccc3c(c2)C2(c4ccccc4-c4ccccc42)c2ccccc2-3)cc1] | (46) |
| 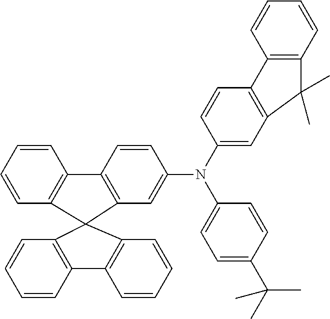 [SMILES: CC(C)(C)c1ccc(N(c2ccc3c(c2)C(C)(C)c2ccccc2-3)c2ccc3c(c2)C2(c4ccccc4-c4ccccc42)c2ccccc2-3)cc1] | (47) |
| 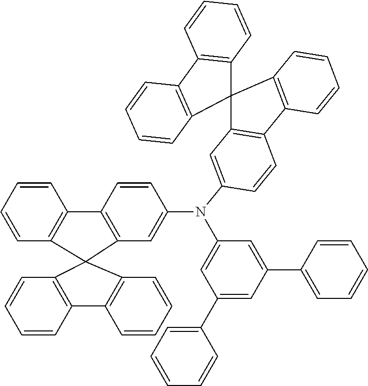 [SMILES: c1ccc(-c2cc(-c3ccccc3)cc(N(c3ccc4c(c3)C3(c5ccccc5-c5ccccc53)c3ccccc3-4)c3ccc4c(c3)C3(c5ccccc5-c5ccccc53)c3ccccc3-4)c2)cc1] | (48) |
| 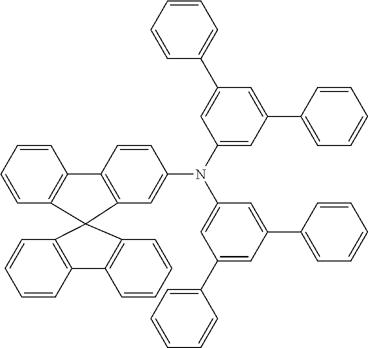 [SMILES: c1ccc(-c2cc(-c3ccccc3)cc(N(c3cc(-c4ccccc4)cc(-c4ccccc4)c3)c3ccc4c(c3)C3(c5ccccc5-c5ccccc53)c3ccccc3-4)c2)cc1] | (49) |
| 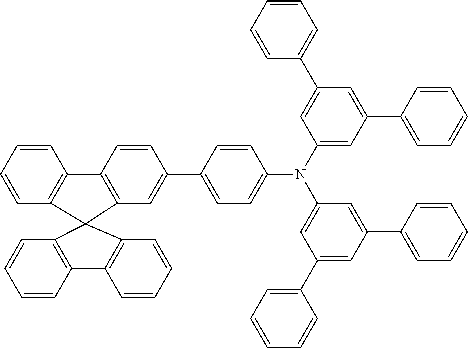 [SMILES: c1ccc(-c2cc(-c3ccccc3)cc(N(c3ccc(-c4ccc5c(c4)C4(c6ccccc6-c6ccccc64)c4ccccc4-5)cc3)c3cc(-c4ccccc4)cc(-c4ccccc4)c3)c2)cc1] | (50) |
| 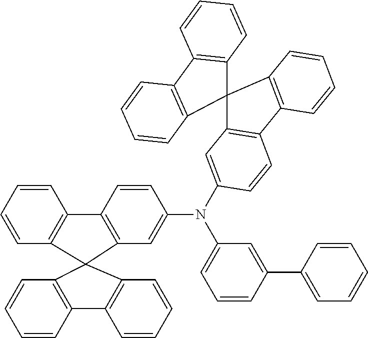 [SMILES: c1ccc(-c2cccc(N(c3ccc4c(c3)C3(c5ccccc5-c5ccccc53)c3ccccc3-4)c3ccc4c(c3)C3(c5ccccc5-c5ccccc53)c3ccccc3-4)c2)cc1] | (51) |
| 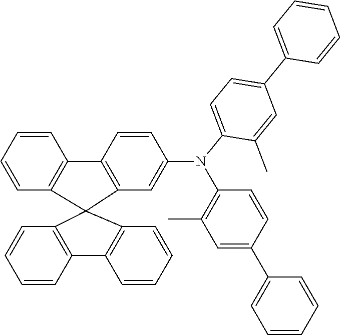 [SMILES: Cc1cc(-c2ccccc2)ccc1N(c1ccc2c(c1)C1(c3ccccc3-c3ccccc31)c1ccccc1-2)c1ccc(-c2ccccc2)cc1C] | (52) |
| 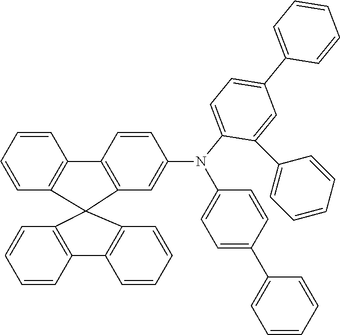 [SMILES: c1ccc(-c2ccc(N(c3ccc4c(c3)C3(c5ccccc5-c5ccccc53)c3ccccc3-4)c3ccc(-c4ccccc4)cc3-c3ccccc3)cc2)cc1] | (53) |
| 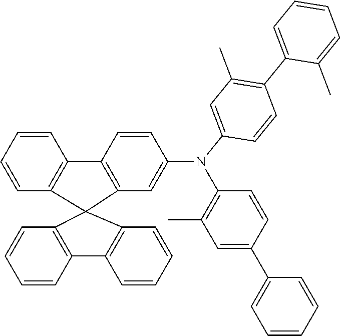 [SMILES: Cc1ccccc1-c1ccc(N(c2ccc3c(c2)C2(c4ccccc4-c4ccccc42)c2ccccc2-3)c2ccc(-c3ccccc3)cc2C)cc1C] | (54) |
| 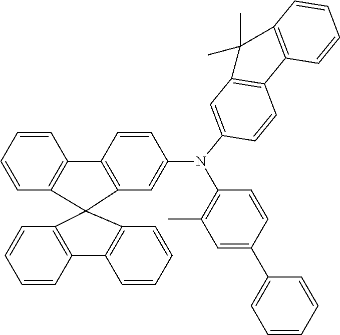 [SMILES: Cc1cc(-c2ccccc2)ccc1N(c1ccc2c(c1)C(C)(C)c1ccccc1-2)c1ccc2c(c1)C1(c3ccccc3-c3ccccc31)c1ccccc1-2] | (55) |
| 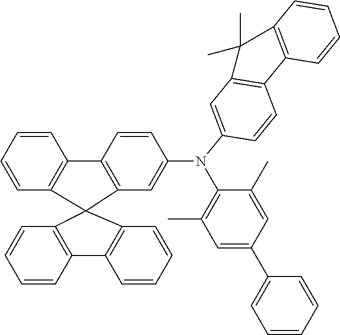 [SMILES: Cc1cc(-c2ccccc2)cc(C)c1N(c1ccc2c(c1)C(C)(C)c1ccccc1-2)c1ccc2c(c1)C1(c3ccccc3-c3ccccc31)c1ccccc1-2] | (56) |
| 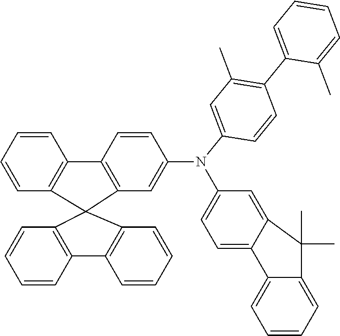 [SMILES: Cc1ccccc1-c1ccc(N(c2ccc3c(c2)C(C)(C)c2ccccc2-3)c2ccc3c(c2)C2(c4ccccc4-c4ccccc42)c2ccccc2-3)cc1C] | (57) |
| 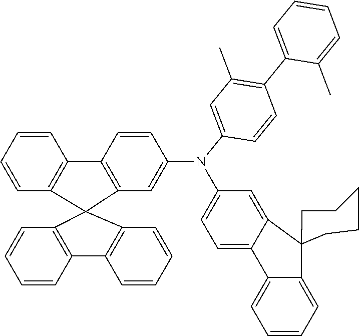 [SMILES: Cc1ccccc1-c1ccc(N(c2ccc3c(c2)C2(CCCCC2)c2ccccc2-3)c2ccc3c(c2)C2(c4ccccc4-c4ccccc42)c2ccccc2-3)cc1C] | (58) |
| 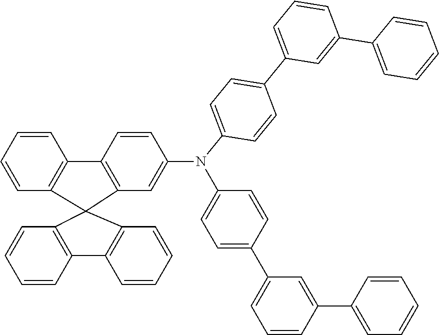 [SMILES: c1ccc(-c2cccc(-c3ccc(N(c4ccc(-c5cccc(-c6ccccc6)c5)cc4)c4ccc5c(c4)C4(c6ccccc6-c6ccccc64)c4ccccc4-5)cc3)c2)cc1] | (59) |
| 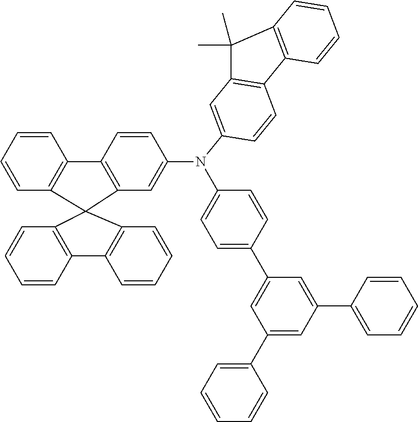 [SMILES: CC1(C)c2ccccc2-c2ccc(N(c3ccc(-c4cc(-c5ccccc5)cc(-c5ccccc5)c4)cc3)c3ccc4c(c3)C3(c5ccccc5-c5ccccc53)c3ccccc3-4)cc21] | (60) |
| 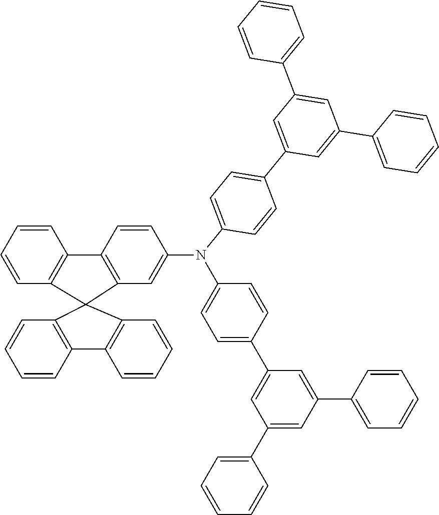 [SMILES: c1ccc(-c2cc(-c3ccccc3)cc(-c3ccc(N(c4ccc(-c5cc(-c6ccccc6)cc(-c6ccccc6)c5)cc4)c4ccc5c(c4)C4(c6ccccc6-c6ccccc64)c4ccccc4-5)cc3)c2)cc1] | (61) |
| 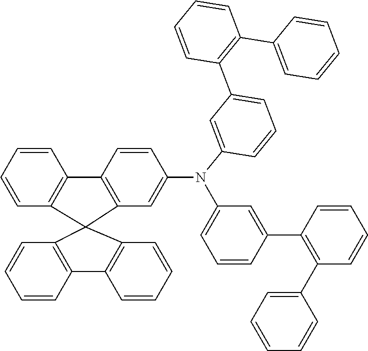 [SMILES: c1ccc(-c2ccccc2-c2cccc(N(c3cccc(-c4ccccc4-c4ccccc4)c3)c3ccc4c(c3)C3(c5ccccc5-c5ccccc53)c3ccccc3-4)c2)cc1] | (62) |
| 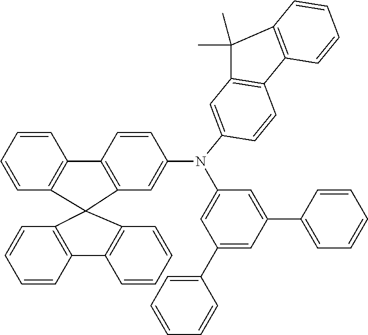 [SMILES: CC1(C)c2ccccc2-c2ccc(N(c3cc(-c4ccccc4)cc(-c4ccccc4)c3)c3ccc4c(c3)C3(c5ccccc5-c5ccccc53)c3ccccc3-4)cc21] | (63) |
| 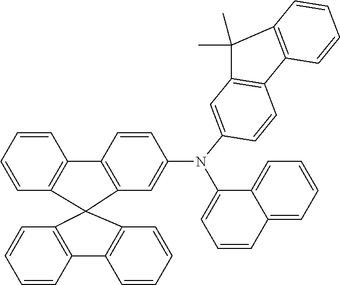 [SMILES: CC1(C)c2ccccc2-c2ccc(N(c3ccc4c(c3)C3(c5ccccc5-c5ccccc53)c3ccccc3-4)c3cccc4ccccc34)cc21] | (64) |
| 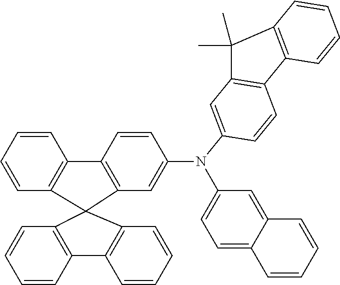 [SMILES: CC1(C)c2ccccc2-c2ccc(N(c3ccc4c(c3)C3(c5ccccc5-c5ccccc53)c3ccccc3-4)c3ccc4ccccc4c3)cc21] | (65) |
| 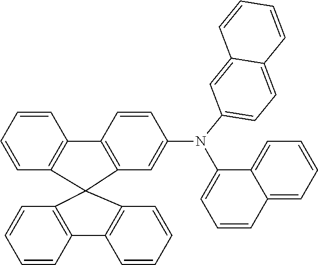 [SMILES: c1ccc2c(c1)-c1ccccc1C21c2ccccc2-c2ccc(N(c3ccc4ccccc4c3)c3cccc4ccccc34)cc21] | (66) |
| 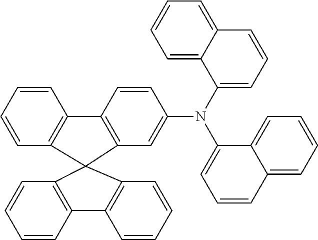 [SMILES: c1ccc2c(c1)-c1ccccc1C21c2ccccc2-c2ccc(N(c3cccc4ccccc34)c3cccc4ccccc34)cc21] | (67) |
| 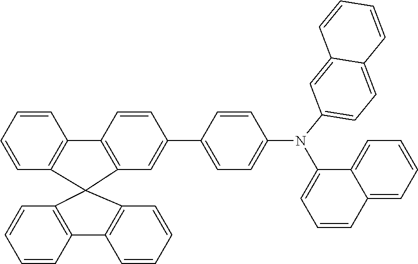 [SMILES: c1ccc2c(c1)-c1ccccc1C21c2ccccc2-c2ccc(-c3ccc(N(c4ccc5ccccc5c4)c4cccc5ccccc45)cc3)cc21] | (68) |
| 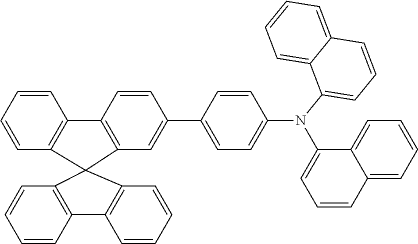 [SMILES: c1ccc2c(c1)-c1ccccc1C21c2ccccc2-c2ccc(-c3ccc(N(c4cccc5ccccc45)c4cccc5ccccc45)cc3)cc21] | (69) |
| 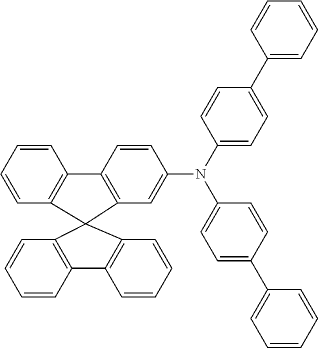 [SMILES: c1ccc(-c2ccc(N(c3ccc(-c4ccccc4)cc3)c3ccc4c(c3)C3(c5ccccc5-c5ccccc53)c3ccccc3-4)cc2)cc1] | (70) |
| 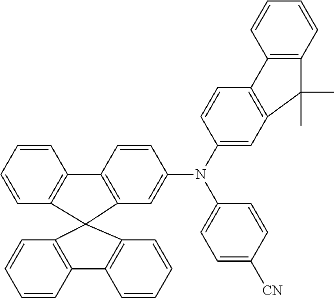 [SMILES: CC1(C)c2ccccc2-c2ccc(N(c3ccc(C#N)cc3)c3ccc4c(c3)C3(c5ccccc5-c5ccccc53)c3ccccc3-4)cc21] | (71) |
| 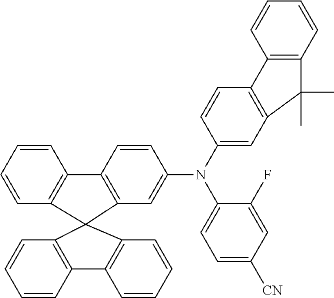 [SMILES: CC1(C)c2ccccc2-c2ccc(N(c3ccc4c(c3)C3(c5ccccc5-c5ccccc53)c3ccccc3-4)c3ccc(C#N)cc3F)cc21] | (72) |
| 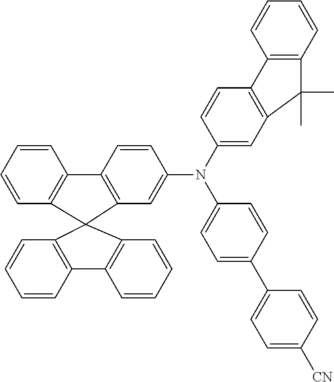 [SMILES: CC1(C)c2ccccc2-c2ccc(N(c3ccc(-c4ccc(C#N)cc4)cc3)c3ccc4c(c3)C3(c5ccccc5-c5ccccc53)c3ccccc3-4)cc21] | (73) |
| 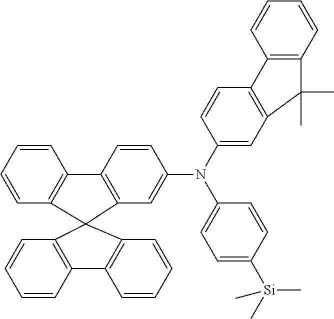 [SMILES: CC1(C)c2ccccc2-c2ccc(N(c3ccc([Si](C)(C)C)cc3)c3ccc4c(c3)C3(c5ccccc5-c5ccccc53)c3ccccc3-4)cc21] | (74) |
| 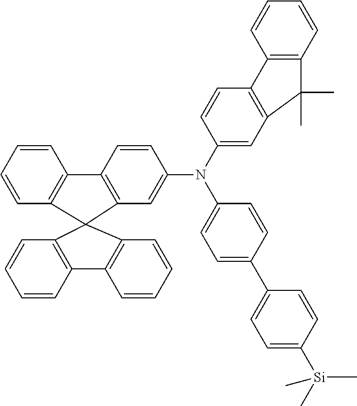 [SMILES: CC1(C)c2ccccc2-c2ccc(N(c3ccc(-c4ccc([Si](C)(C)C)cc4)cc3)c3ccc4c(c3)C3(c5ccccc5-c5ccccc53)c3ccccc3-4)cc21] | (75) |
| 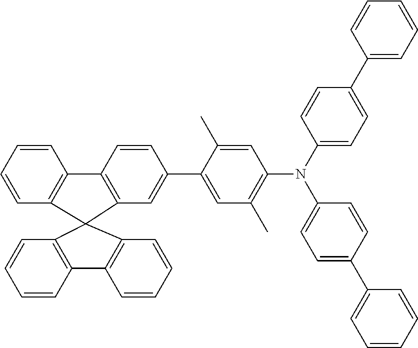 [SMILES: Cc1cc(N(c2ccc(-c3ccccc3)cc2)c2ccc(-c3ccccc3)cc2)c(C)cc1-c1ccc2c(c1)C1(c3ccccc3-c3ccccc31)c1ccccc1-2] | (76) |
| 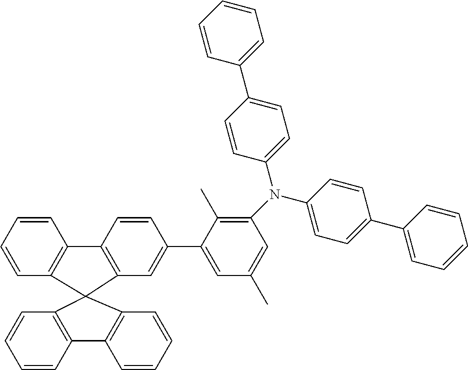 [SMILES: Cc1cc(-c2ccc3c(c2)C2(c4ccccc4-c4ccccc42)c2ccccc2-3)c(C)c(N(c2ccc(-c3ccccc3)cc2)c2ccc(-c3ccccc3)cc2)c1] | (77) |
| 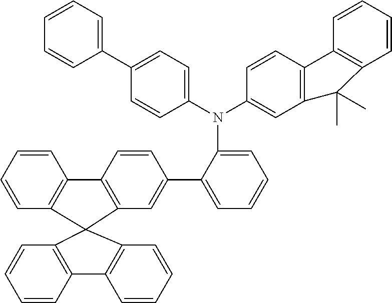 [SMILES: CC1(C)c2ccccc2-c2ccc(N(c3ccc(-c4ccccc4)cc3)c3ccccc3-c3ccc4c(c3)C3(c5ccccc5-c5ccccc53)c3ccccc3-4)cc21] | (78) |
| 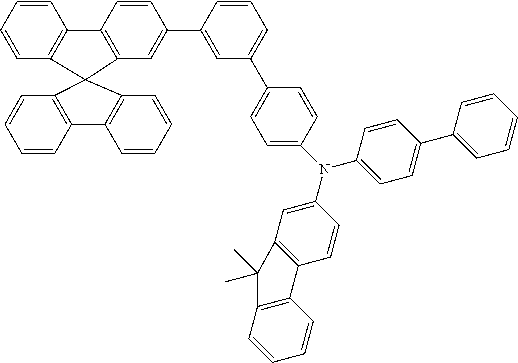 [SMILES: CC1(C)c2ccccc2-c2ccc(N(c3ccc(-c4ccccc4)cc3)c3ccc(-c4cccc(-c5ccc6c(c5)C5(c7ccccc7-c7ccccc75)c5ccccc5-6)c4)cc3)cc21] | (79) |
| 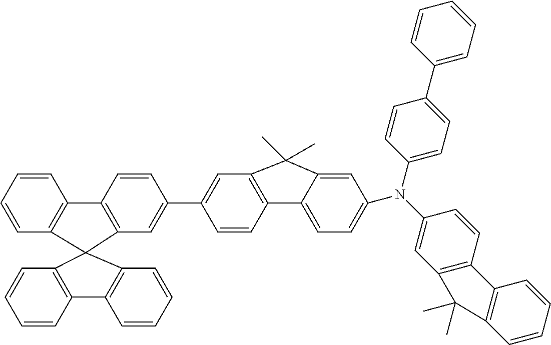 [SMILES: CC1(C)c2ccccc2-c2ccc(N(c3ccc(-c4ccccc4)cc3)c3ccc4c(c3)C(C)(C)c3cc(-c5ccc6c(c5)C5(c7ccccc7-c7ccccc75)c5ccccc5-6)ccc3-4)cc21] | (80) |
| 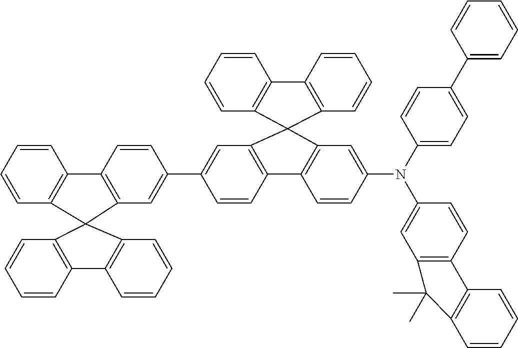 [SMILES: CC1(C)c2ccccc2-c2ccc(N(c3ccc(-c4ccccc4)cc3)c3ccc4c(c3)C3(c5ccccc5-c5ccccc53)c3cc(-c5ccc6c(c5)C5(c7ccccc7-c7ccccc75)c5ccccc5-6)ccc3-4)cc21] | (81) |
| 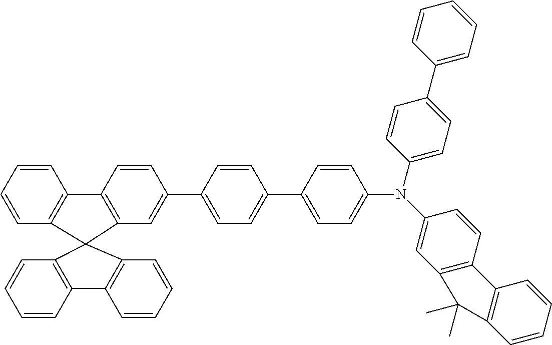 [SMILES: CC1(C)c2ccccc2-c2ccc(N(c3ccc(-c4ccccc4)cc3)c3ccc(-c4ccc(-c5ccc6c(c5)C5(c7ccccc7-c7ccccc75)c5ccccc5-6)cc4)cc3)cc21] | (82) |
| 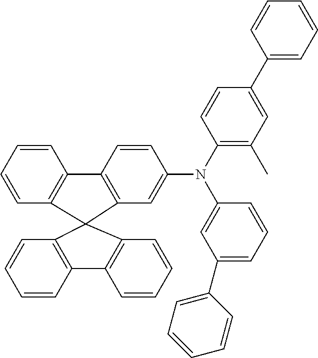 [SMILES: Cc1cc(-c2ccccc2)ccc1N(c1cccc(-c2ccccc2)c1)c1ccc2c(c1)C1(c3ccccc3-c3ccccc31)c1ccccc1-2] | (83) |
| 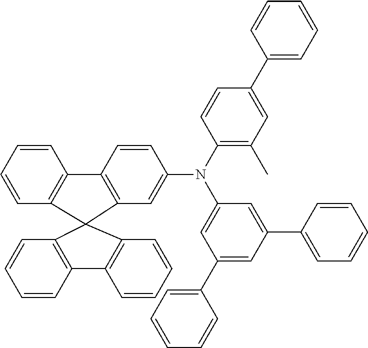 [SMILES: Cc1cc(-c2ccccc2)ccc1N(c1cc(-c2ccccc2)cc(-c2ccccc2)c1)c1ccc2c(c1)C1(c3ccccc3-c3ccccc31)c1ccccc1-2] | (84) |
| 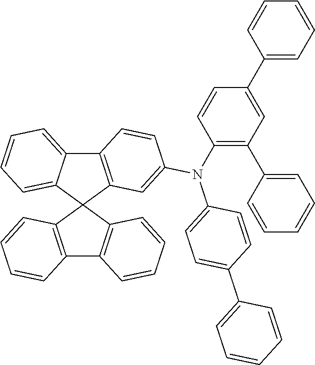 [SMILES: c1ccc(-c2ccc(N(c3ccc4c(c3)C3(c5ccccc5-c5ccccc53)c3ccccc3-4)c3ccc(-c4ccccc4)cc3-c3ccccc3)cc2)cc1] | (85) |
| 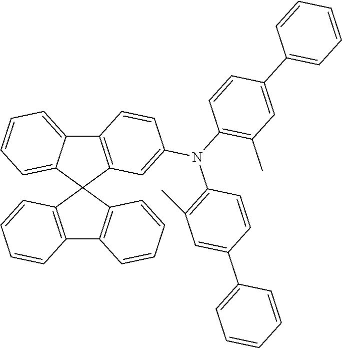 [SMILES: Cc1cc(-c2ccccc2)ccc1N(c1ccc2c(c1)C1(c3ccccc3-c3ccccc31)c1ccccc1-2)c1ccc(-c2ccccc2)cc1C] | (86) |
| 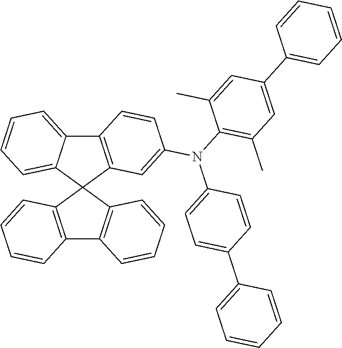 [SMILES: Cc1cc(-c2ccccc2)cc(C)c1N(c1ccc(-c2ccccc2)cc1)c1ccc2c(c1)C1(c3ccccc3-c3ccccc31)c1ccccc1-2] | (87) |
| 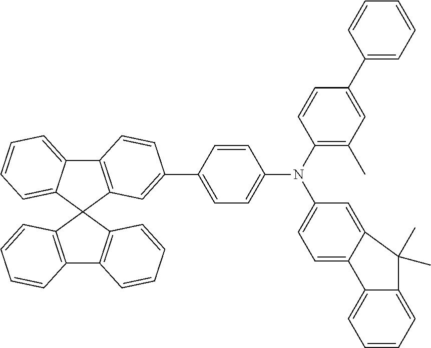 [SMILES: Cc1cc(-c2ccccc2)ccc1N(c1ccc(-c2ccc3c(c2)C2(c4ccccc4-c4ccccc42)c2ccccc2-3)cc1)c1ccc2c(c1)C(C)(C)c1ccccc1-2] | (88) |
| 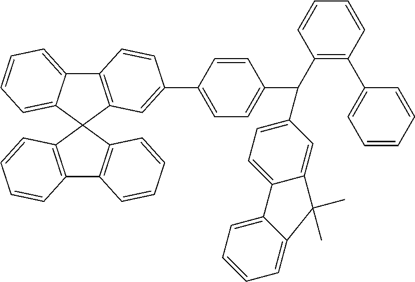 [SMILES: CC1(C)c2ccccc2-c2ccc(C(c3ccc(-c4ccc5c(c4)C4(c6ccccc6-c6ccccc64)c4ccccc4-5)cc3)c3ccccc3-c3ccccc3)cc21] | (89) |
| 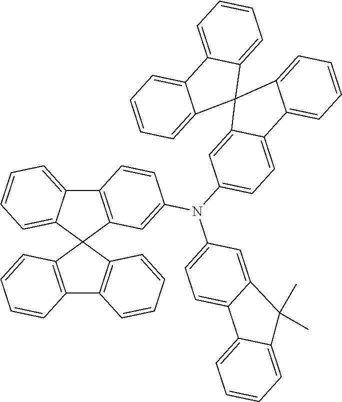 [SMILES: CC1(C)c2ccccc2-c2ccc(N(c3ccc4c(c3)C3(c5ccccc5-c5ccccc53)c3ccccc3-4)c3ccc4c(c3)C3(c5ccccc5-c5ccccc53)c3ccccc3-4)cc21] | (90) |
| 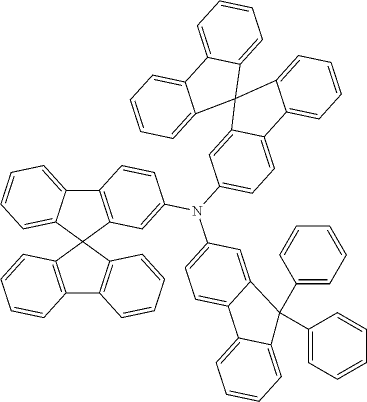 [SMILES: c1ccc(C2(c3ccccc3)c3ccccc3-c3ccc(N(c4ccc5c(c4)C4(c6ccccc6-c6ccccc64)c4ccccc4-5)c4ccc5c(c4)C4(c6ccccc6-c6ccccc64)c4ccccc4-5)cc32)cc1] | (91) |
| 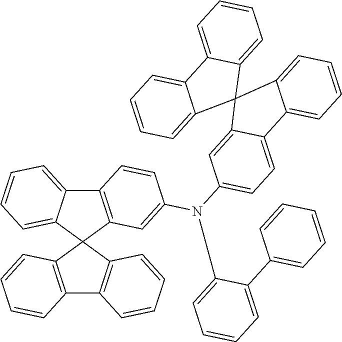 [SMILES: c1ccc(-c2ccccc2N(c2ccc3c(c2)C2(c4ccccc4-c4ccccc42)c2ccccc2-3)c2ccc3c(c2)C2(c4ccccc4-c4ccccc42)c2ccccc2-3)cc1] | (92) |
| 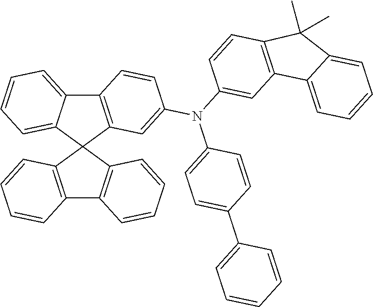 [SMILES: CC1(C)c2ccccc2-c2cc(N(c3ccc(-c4ccccc4)cc3)c3ccc4c(c3)C3(c5ccccc5-c5ccccc53)c3ccccc3-4)ccc21] | (93) |
| 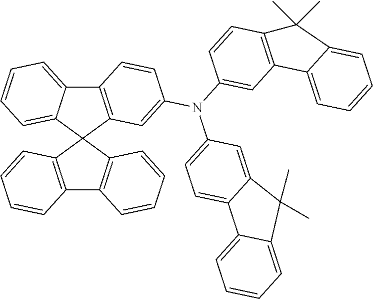 [SMILES: CC1(C)c2ccccc2-c2cc(N(c3ccc4c(c3)C(C)(C)c3ccccc3-4)c3ccc4c(c3)C3(c5ccccc5-c5ccccc53)c3ccccc3-4)ccc21] | (94) |
| 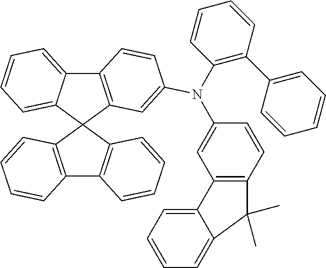 [SMILES: CC1(C)c2ccccc2-c2cc(N(c3ccc4c(c3)C3(c5ccccc5-c5ccccc53)c3ccccc3-4)c3ccccc3-c3ccccc3)ccc21] | (95) |
| 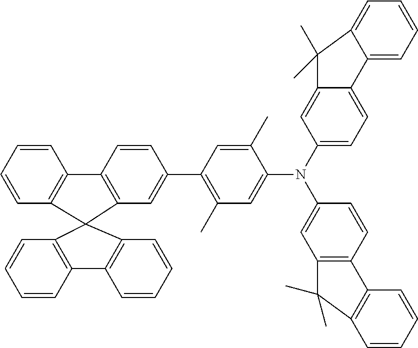 [SMILES: Cc1cc(N(c2ccc3c(c2)C(C)(C)c2ccccc2-3)c2ccc3c(c2)C(C)(C)c2ccccc2-3)c(C)cc1-c1ccc2c(c1)C1(c3ccccc3-c3ccccc31)c1ccccc1-2] | (96) |
| 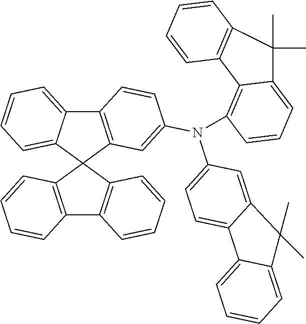 [SMILES: CC1(C)c2ccccc2-c2ccc(N(c3ccc4c(c3)C3(c5ccccc5-c5ccccc53)c3ccccc3-4)c3cccc4c3-c3ccccc3C4(C)C)cc21] | (97) |
| 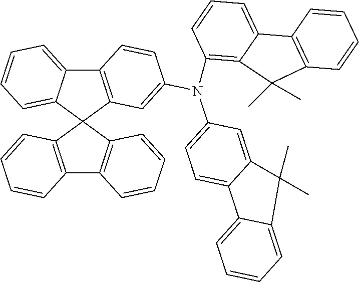 [SMILES: CC1(C)c2ccccc2-c2ccc(N(c3ccc4c(c3)C3(c5ccccc5-c5ccccc53)c3ccccc3-4)c3cccc4c3C(C)(C)c3ccccc3-4)cc21] | (98) |
| 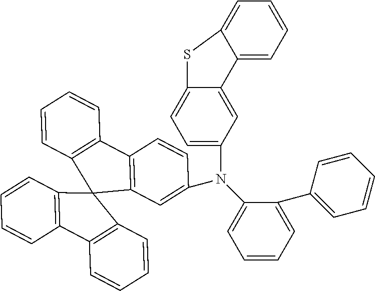 [SMILES: c1ccc(-c2ccccc2N(c2ccc3c(c2)C2(c4ccccc4-c4ccccc42)c2ccccc2-3)c2ccc3sc4ccccc4c3c2)cc1] | (99) |
| 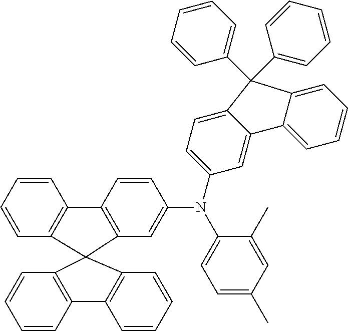 [SMILES: Cc1ccc(N(c2ccc3c(c2)-c2ccccc2C3(c2ccccc2)c2ccccc2)c2ccc3c(c2)C2(c4ccccc4-c4ccccc42)c2ccccc2-3)c(C)c1] | (100) |
| 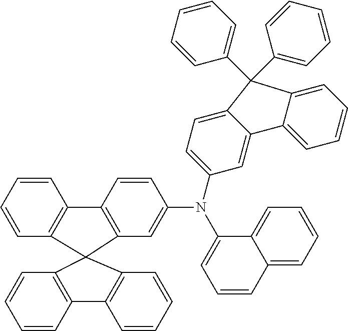 [SMILES: c1ccc(C2(c3ccccc3)c3ccccc3-c3cc(N(c4ccc5c(c4)C4(c6ccccc6-c6ccccc64)c4ccccc4-5)c4cccc5ccccc45)ccc32)cc1] | (101) |
| 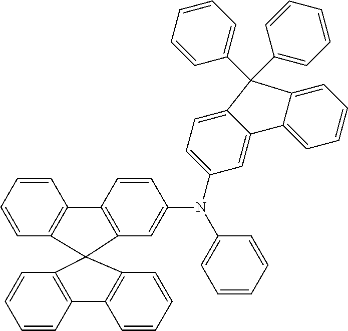 [SMILES: c1ccc(N(c2ccc3c(c2)-c2ccccc2C3(c2ccccc2)c2ccccc2)c2ccc3c(c2)C2(c4ccccc4-c4ccccc42)c2ccccc2-3)cc1] | (102) |
| 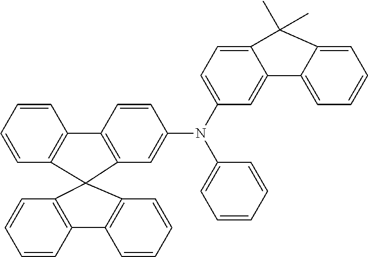 [SMILES: CC1(C)c2ccccc2-c2cc(N(c3ccccc3)c3ccc4c(c3)C3(c5ccccc5-c5ccccc53)c3ccccc3-4)ccc21] | (103) |
| 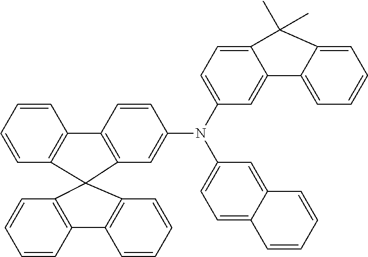 [SMILES: CC1(C)c2ccccc2-c2cc(N(c3ccc4c(c3)C3(c5ccccc5-c5ccccc53)c3ccccc3-4)c3ccc4ccccc4c3)ccc21] | (104) |
| 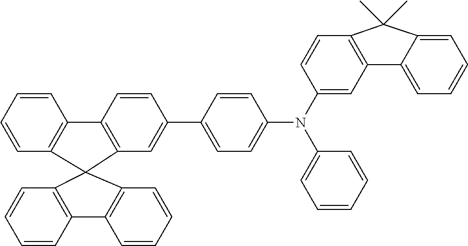 [SMILES: CC1(C)c2ccccc2-c2cc(N(c3ccccc3)c3ccc(-c4ccc5c(c4)C4(c6ccccc6-c6ccccc64)c4ccccc4-5)cc3)ccc21] | (105) |
| 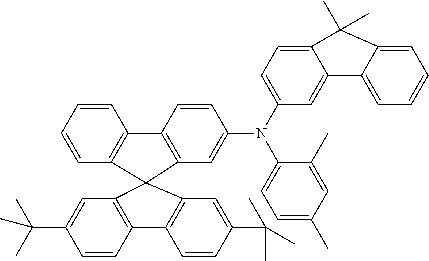 [SMILES: Cc1ccc(N(c2ccc3c(c2)-c2ccccc2C3(C)C)c2ccc3c(c2)C2(c4ccccc4-3)c3cc(C(C)(C)C)ccc3-c3ccc(C(C)(C)C)cc32)c(C)c1] | (106) |
| 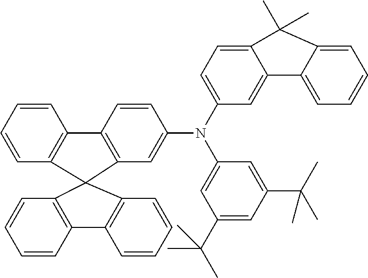 [SMILES: CC(C)(C)c1cc(N(c2ccc3c(c2)-c2ccccc2C3(C)C)c2ccc3c(c2)C2(c4ccccc4-c4ccccc42)c2ccccc2-3)cc(C(C)(C)C)c1] | (107) |
| 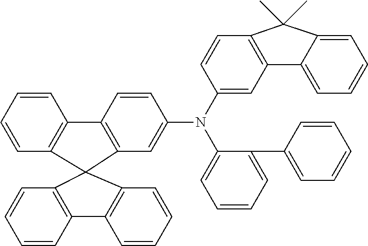 [SMILES: CC1(C)c2ccccc2-c2cc(N(c3ccc4c(c3)C3(c5ccccc5-c5ccccc53)c3ccccc3-4)c3ccccc3-c3ccccc3)ccc21] | (108) |
| 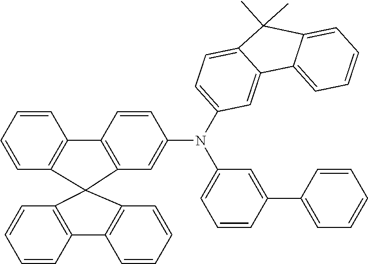 [SMILES: CC1(C)c2ccccc2-c2cc(N(c3cccc(-c4ccccc4)c3)c3ccc4c(c3)C3(c5ccccc5-c5ccccc53)c3ccccc3-4)ccc21] | (109) |
| 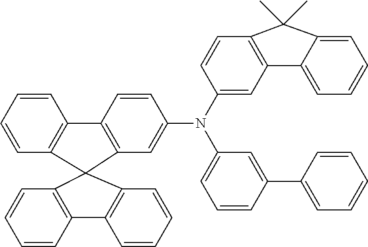 [SMILES: CC1(C)c2ccccc2-c2cc(N(c3cccc(-c4ccccc4)c3)c3ccc4c(c3)C3(c5ccccc5-c5ccccc53)c3ccccc3-4)ccc21] | (110) |
| 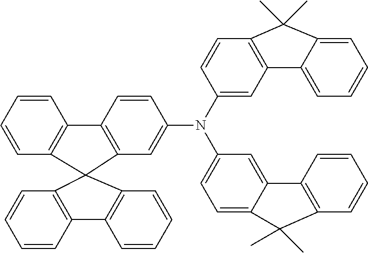 [SMILES: CC1(C)c2ccccc2-c2cc(N(c3ccc4c(c3)-c3ccccc3C4(C)C)c3ccc4c(c3)C3(c5ccccc5-c5ccccc53)c3ccccc3-4)ccc21] | (111) |
| 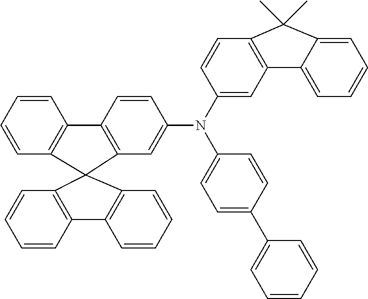 [SMILES: CC1(C)c2ccccc2-c2cc(N(c3ccc(-c4ccccc4)cc3)c3ccc4c(c3)C3(c5ccccc5-c5ccccc53)c3ccccc3-4)ccc21] | (112) |
| 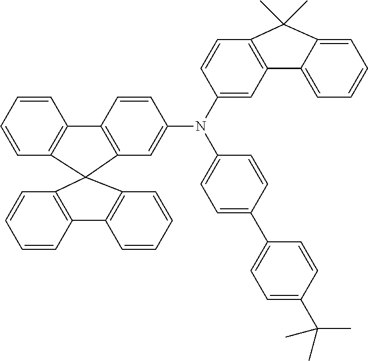 [SMILES: CC(C)(C)c1ccc(-c2ccc(N(c3ccc4c(c3)-c3ccccc3C4(C)C)c3ccc4c(c3)C3(c5ccccc5-c5ccccc53)c3ccccc3-4)cc2)cc1] | (113) |
| 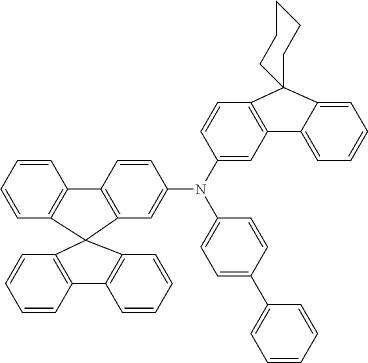 [SMILES: c1ccc(-c2ccc(N(c3ccc4c(c3)-c3ccccc3C43CCCCC3)c3ccc4c(c3)C3(c5ccccc5-c5ccccc53)c3ccccc3-4)cc2)cc1] | (114) |
| 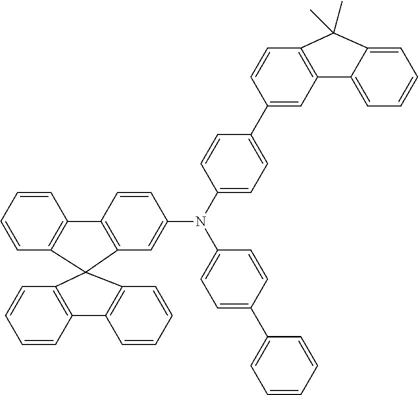 [SMILES: CC1(C)c2ccccc2-c2cc(-c3ccc(N(c4ccc(-c5ccccc5)cc4)c4ccc5c(c4)C4(c6ccccc6-c6ccccc64)c4ccccc4-5)cc3)ccc21] | (115) |
| 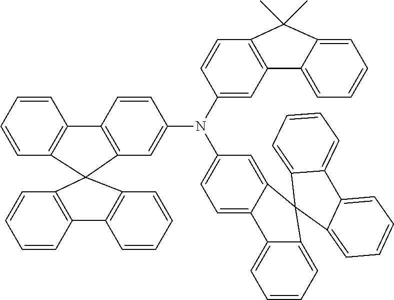 [SMILES: CC1(C)c2ccccc2-c2cc(N(c3ccc4c(c3)C3(c5ccccc5-c5ccccc53)c3ccccc3-4)c3ccc4c(c3)C3(c5ccccc5-c5ccccc53)c3ccccc3-4)ccc21] | (116) |
| 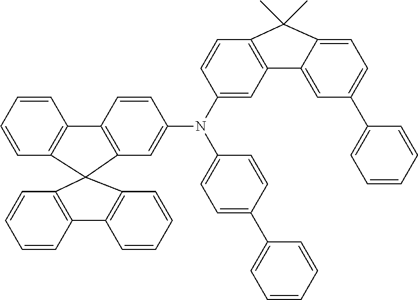 [SMILES: CC1(C)c2ccc(-c3ccccc3)cc2-c2cc(N(c3ccc(-c4ccccc4)cc3)c3ccc4c(c3)C3(c5ccccc5-c5ccccc53)c3ccccc3-4)ccc21] | (117) |
| 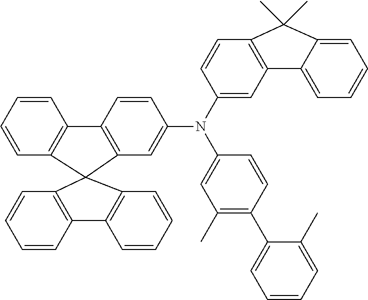 [SMILES: Cc1ccccc1-c1ccc(N(c2ccc3c(c2)-c2ccccc2C3(C)C)c2ccc3c(c2)C2(c4ccccc4-c4ccccc42)c2ccccc2-3)cc1C] | (118) |
| 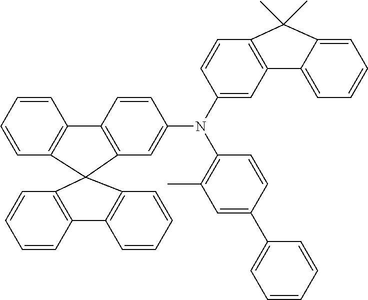 [SMILES: Cc1cc(-c2ccccc2)ccc1N(c1ccc2c(c1)-c1ccccc1C2(C)C)c1ccc2c(c1)C1(c3ccccc3-c3ccccc31)c1ccccc1-2] | (119) |
| 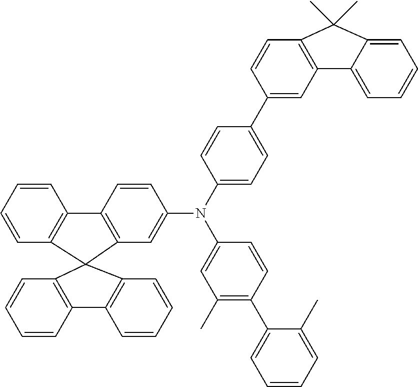 [SMILES: Cc1ccccc1-c1ccc(N(c2ccc(-c3ccc4c(c3)-c3ccccc3C4(C)C)cc2)c2ccc3c(c2)C2(c4ccccc4-c4ccccc42)c2ccccc2-3)cc1C] | (120) |
| 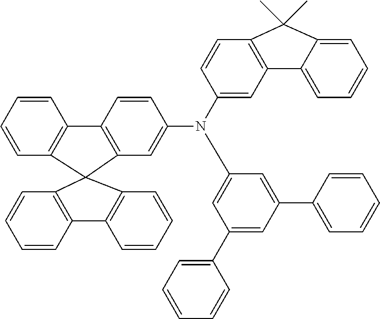 [SMILES: CC1(C)c2ccccc2-c2cc(N(c3cc(-c4ccccc4)cc(-c4ccccc4)c3)c3ccc4c(c3)C3(c5ccccc5-c5ccccc53)c3ccccc3-4)ccc21] | (121) |
| 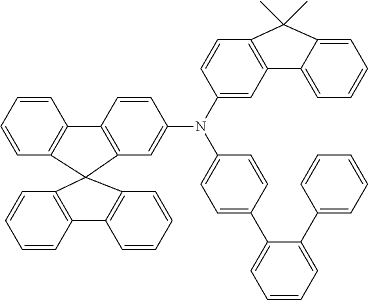 [SMILES: CC1(C)c2ccccc2-c2cc(N(c3ccc(-c4ccccc4-c4ccccc4)cc3)c3ccc4c(c3)C3(c5ccccc5-c5ccccc53)c3ccccc3-4)ccc21] | (122) |
| 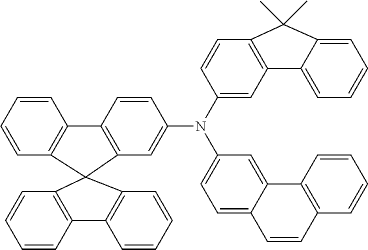 [SMILES: CC1(C)c2ccccc2-c2cc(N(c3ccc4c(c3)C3(c5ccccc5-c5ccccc53)c3ccccc3-4)c3ccc4ccc5ccccc5c4c3)ccc21] | (123) |
| 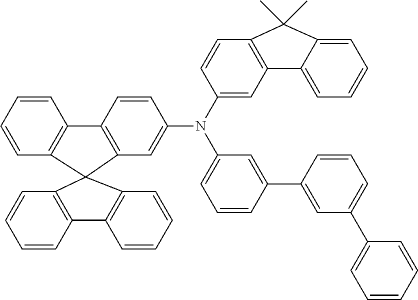 [SMILES: CC1(C)c2ccccc2-c2cc(N(c3cccc(-c4cccc(-c5ccccc5)c4)c3)c3ccc4c(c3)C3(c5ccccc5-c5ccccc53)c3ccccc3-4)ccc21] | (124) |
| 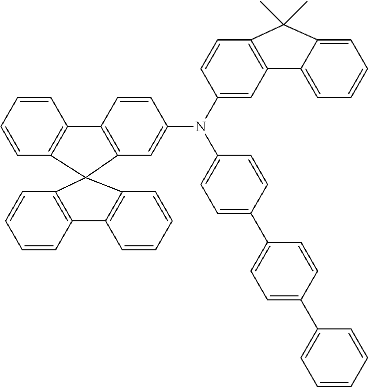 [SMILES: CC1(C)c2ccccc2-c2cc(N(c3ccc(-c4ccc(-c5ccccc5)cc4)cc3)c3ccc4c(c3)C3(c5ccccc5-c5ccccc53)c3ccccc3-4)ccc21] | (125) |
| 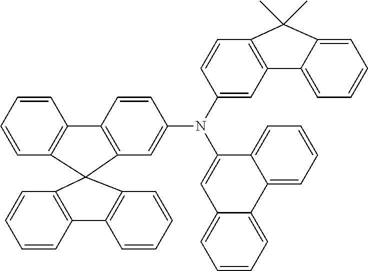 [SMILES: CC1(C)c2ccccc2-c2cc(N(c3ccc4c(c3)C3(c5ccccc5-c5ccccc53)c3ccccc3-4)c3cc4ccccc4c4ccccc34)ccc21] | (126) |
| 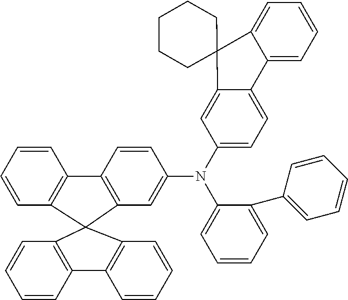 [SMILES: c1ccc(-c2ccccc2N(c2ccc3c(c2)C2(CCCCC2)c2ccccc2-3)c2ccc3c(c2)C2(c4ccccc4-c4ccccc42)c2ccccc2-3)cc1] | (127) |
| 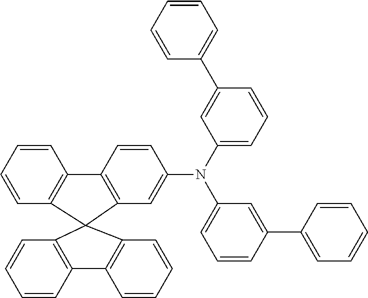 [SMILES: c1ccc(-c2cccc(N(c3cccc(-c4ccccc4)c3)c3ccc4c(c3)C3(c5ccccc5-c5ccccc53)c3ccccc3-4)c2)cc1] | (128) |
| 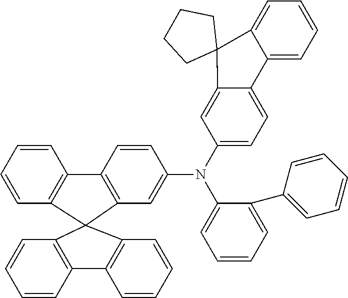 [SMILES: c1ccc(-c2ccccc2N(c2ccc3c(c2)C2(CCCC2)c2ccccc2-3)c2ccc3c(c2)C2(c4ccccc4-c4ccccc42)c2ccccc2-3)cc1] | (129) |
| 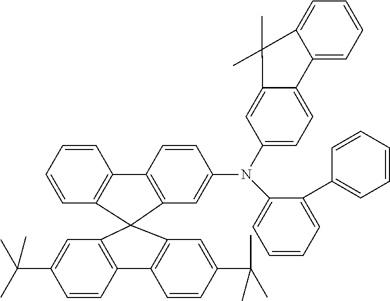 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2] | (130) |
| 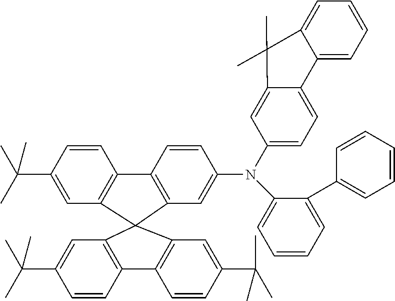 [SMILES: CC(C)(C)c1ccc2c(c1)C1(c3cc(N(c4ccc5c(c4)C(C)(C)c4ccccc4-5)c4ccccc4-c4ccccc4)ccc3-2)c2cc(C(C)(C)C)ccc2-c2ccc(C(C)(C)C)cc21] | (131) |
| 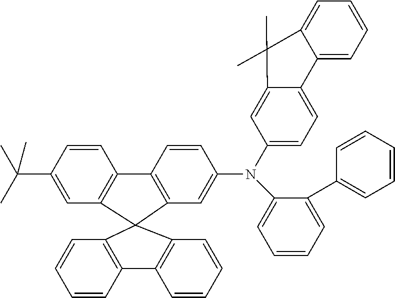 [SMILES: CC(C)(C)c1ccc2c(c1)C1(c3ccccc3-c3ccccc31)c1cc(N(c3ccc4c(c3)C(C)(C)c3ccccc3-4)c3ccccc3-c3ccccc3)ccc1-2] | (132) |
| 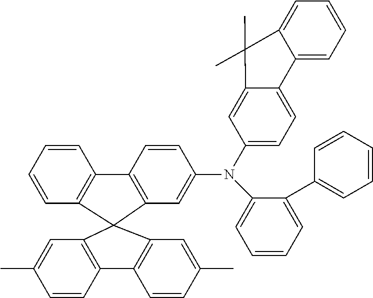 [SMILES: Cc1ccc2c(c1)C1(c3ccccc3-c3ccc(N(c4ccc5c(c4)C(C)(C)c4ccccc4-5)c4ccccc4-c4ccccc4)cc31)c1cc(C)ccc1-2] | (133) |
| 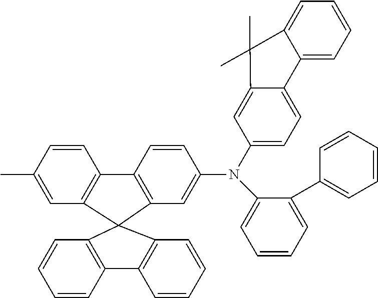 [SMILES: Cc1ccc2c(c1)C1(c3ccccc3-c3ccccc31)c1cc(N(c3ccc4c(c3)C(C)(C)c3ccccc3-4)c3ccccc3-c3ccccc3)ccc1-2] | (134) |
| 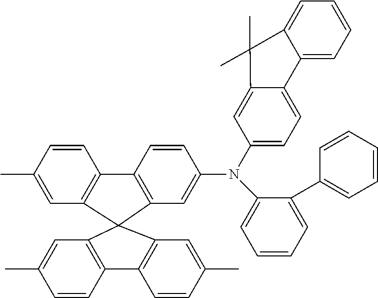 [SMILES: Cc1ccc2c(c1)C1(c3cc(C)ccc3-2)c2cc(C)ccc2-c2ccc(N(c3ccc4c(c3)C(C)(C)c3ccccc3-4)c3ccccc3-c3ccccc3)cc21] | (135) |
| 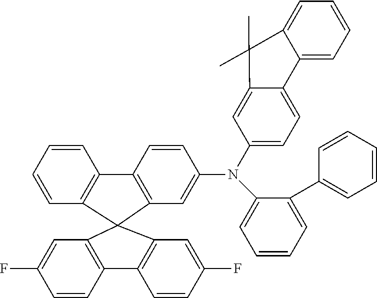 [SMILES: CC1(C)c2ccccc2-c2ccc(N(c3ccc4c(c3)C3(c5ccccc5-4)c4cc(F)ccc4-c4ccc(F)cc43)c3ccccc3-c3ccccc3)cc21] | (136) |
| 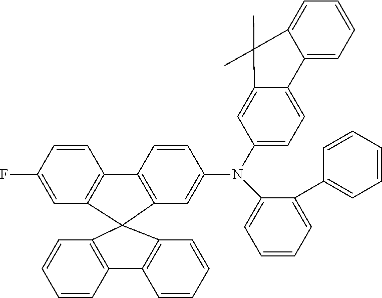 [SMILES: CC1(C)c2ccccc2-c2ccc(N(c3ccc4c(c3)C3(c5ccccc5-c5ccccc53)c3cc(F)ccc3-4)c3ccccc3-c3ccccc3)cc21] | (137) |
| 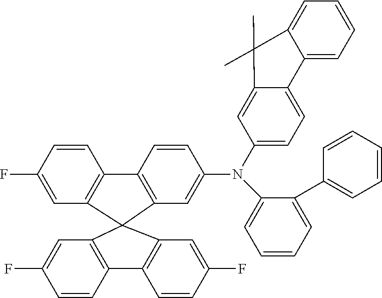 [SMILES: CC1(C)c2ccccc2-c2ccc(N(c3ccc4c(c3)C3(c5cc(F)ccc5-c5ccc(F)cc53)c3cc(F)ccc3-4)c3ccccc3-c3ccccc3)cc21] | (138) |
| 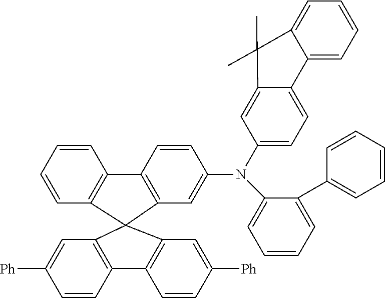 [SMILES: CC1(C)c2ccccc2-c2ccc(N(c3ccc4c(c3)C3(c5ccccc5-4)c4cc(-c5ccccc5)ccc4-c4ccc(-c5ccccc5)cc43)c3ccccc3-c3ccccc3)cc21] | (139) |
| 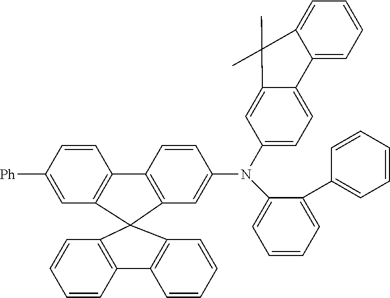 [SMILES: CC1(C)c2ccccc2-c2ccc(N(c3ccc4c(c3)C3(c5ccccc5-c5ccccc53)c3cc(-c5ccccc5)ccc3-4)c3ccccc3-c3ccccc3)cc21] | (140) |
| 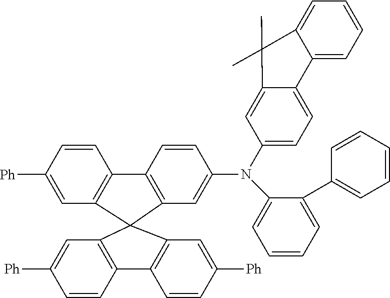 [SMILES: CC1(C)c2ccccc2-c2ccc(N(c3ccc4c(c3)C3(c5cc(-c6ccccc6)ccc5-c5ccc(-c6ccccc6)cc53)c3cc(-c5ccccc5)ccc3-4)c3ccccc3-c3ccccc3)cc21] | (141) |
| 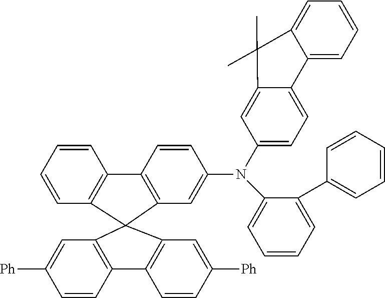 [SMILES: CC1(C)c2ccccc2-c2ccc(N(c3ccc4c(c3)C3(c5ccccc5-4)c4cc(-c5ccccc5)ccc4-c4ccc(-c5ccccc5)cc43)c3ccccc3-c3ccccc3)cc21] | (142) |
| 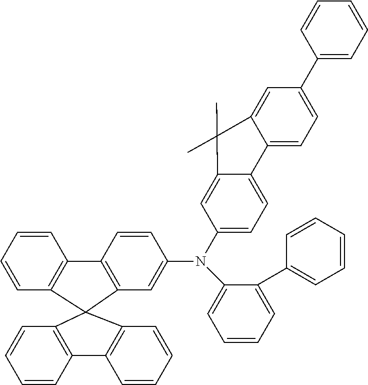 [SMILES: CC1(C)c2cc(-c3ccccc3)ccc2-c2ccc(N(c3ccc4c(c3)C3(c5ccccc5-c5ccccc53)c3ccccc3-4)c3ccccc3-c3ccccc3)cc21] | (143) |
| 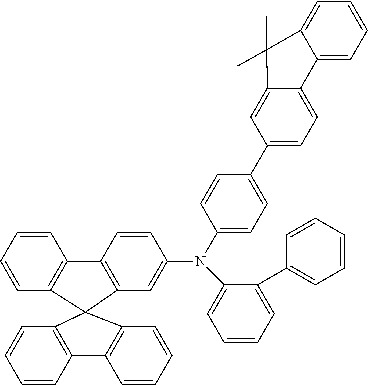 [SMILES: CC1(C)c2ccccc2-c2ccc(-c3ccc(N(c4ccc5c(c4)C4(c6ccccc6-c6ccccc64)c4ccccc4-5)c4ccccc4-c4ccccc4)cc3)cc21] | (144) |
| 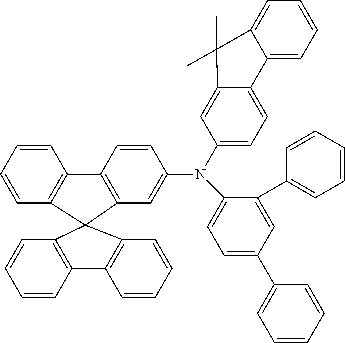 [SMILES: CC1(C)c2ccccc2-c2ccc(N(c3ccc4c(c3)C3(c5ccccc5-c5ccccc53)c3ccccc3-4)c3ccc(-c4ccccc4)cc3-c3ccccc3)cc21] | (145) |
| 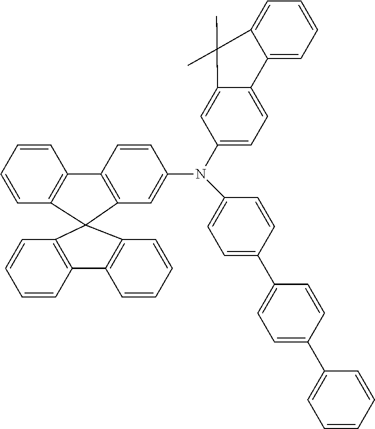 [SMILES: CC1(C)c2ccccc2-c2ccc(N(c3ccc(-c4ccc(-c5ccccc5)cc4)cc3)c3ccc4c(c3)C3(c5ccccc5-c5ccccc53)c3ccccc3-4)cc21] | (146) |
| 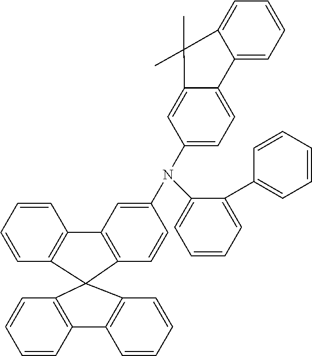 [SMILES: CC1(C)c2ccccc2-c2ccc(N(c3ccc4c(c3)-c3ccccc3C43c4ccccc4-c4ccccc43)c3ccccc3-c3ccccc3)cc21] | (147) |
| 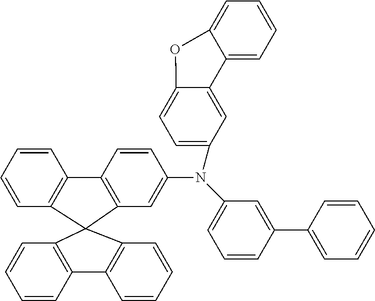 [SMILES: c1ccc(-c2cccc(N(c3ccc4c(c3)C3(c5ccccc5-c5ccccc53)c3ccccc3-4)c3ccc4oc5ccccc5c4c3)c2)cc1] | (148) |
| 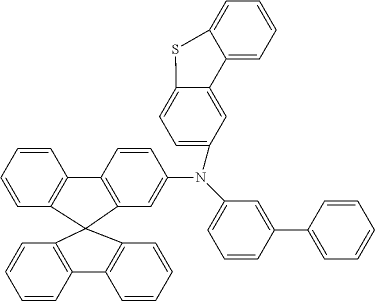 [SMILES: c1ccc(-c2cccc(N(c3ccc4c(c3)C3(c5ccccc5-c5ccccc53)c3ccccc3-4)c3ccc4sc5ccccc5c4c3)c2)cc1] | (149) |
| 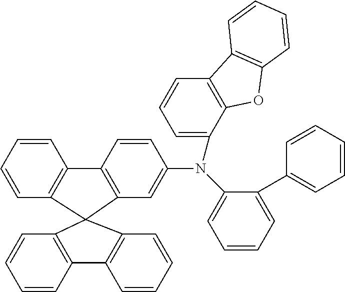 [SMILES: c1ccc(-c2ccccc2N(c2ccc3c(c2)C2(c4ccccc4-c4ccccc42)c2ccccc2-3)c2cccc3c2oc2ccccc23)cc1] | (150) |
| 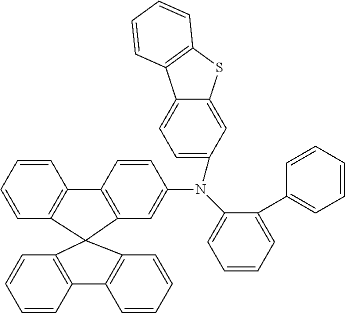 [SMILES: c1ccc(-c2ccccc2N(c2ccc3c(c2)C2(c4ccccc4-c4ccccc42)c2ccccc2-3)c2ccc3c(c2)sc2ccccc23)cc1] | (151) |
| 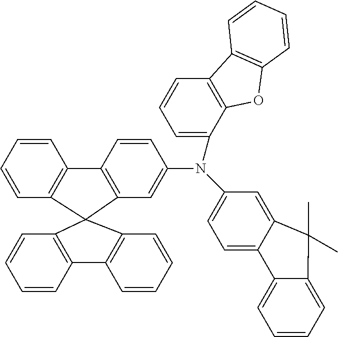 [SMILES: CC1(C)c2ccccc2-c2ccc(N(c3ccc4c(c3)C3(c5ccccc5-c5ccccc53)c3ccccc3-4)c3cccc4c3oc3ccccc34)cc21] | (152) |
| 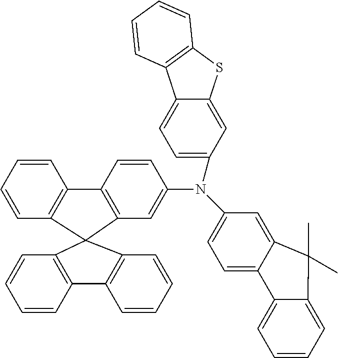 [SMILES: CC1(C)c2ccccc2-c2ccc(N(c3ccc4c(c3)C3(c5ccccc5-c5ccccc53)c3ccccc3-4)c3ccc4c(c3)sc3ccccc34)cc21] | (153) |
| 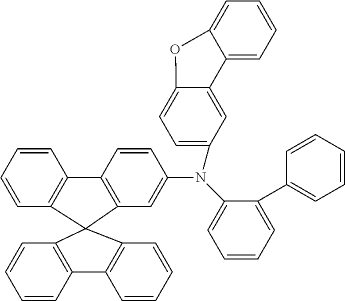 [SMILES: c1ccc(-c2ccccc2N(c2ccc3c(c2)C2(c4ccccc4-c4ccccc42)c2ccccc2-3)c2ccc3oc4ccccc4c3c2)cc1] | (154) |
| 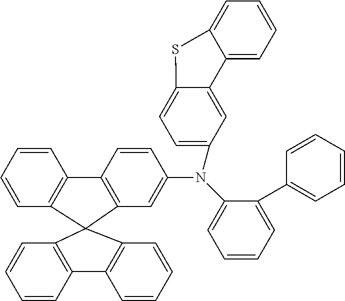 [SMILES: c1ccc(-c2ccccc2N(c2ccc3c(c2)C2(c4ccccc4-c4ccccc42)c2ccccc2-3)c2ccc3sc4ccccc4c3c2)cc1] | (155) |
| 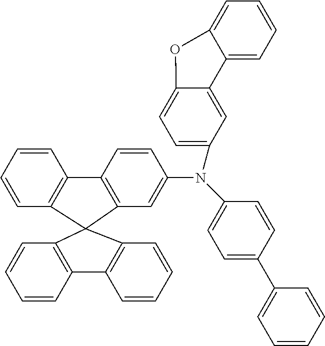 [SMILES: c1ccc(-c2ccc(N(c3ccc4c(c3)C3(c5ccccc5-c5ccccc53)c3ccccc3-4)c3ccc4oc5ccccc5c4c3)cc2)cc1] | (156) |
| 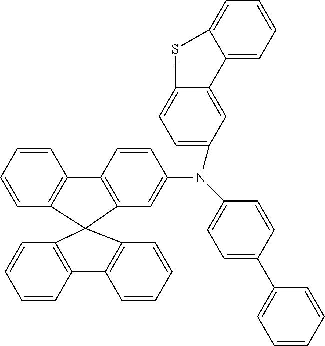 [SMILES: c1ccc(-c2ccc(N(c3ccc4c(c3)C3(c5ccccc5-c5ccccc53)c3ccccc3-4)c3ccc4sc5ccccc5c4c3)cc2)cc1] | (157) |
| 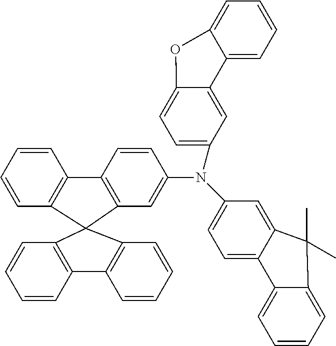 [SMILES: CC1(C)c2ccccc2-c2ccc(N(c3ccc4c(c3)C3(c5ccccc5-c5ccccc53)c3ccccc3-4)c3ccc4oc5ccccc5c4c3)cc21] | (158) |
| 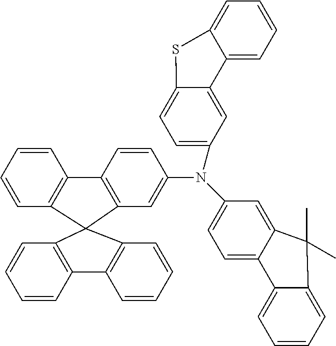 [SMILES: CC1(C)c2ccccc2-c2ccc(N(c3ccc4c(c3)C3(c5ccccc5-c5ccccc53)c3ccccc3-4)c3ccc4sc5ccccc5c4c3)cc21] | (159) |
| 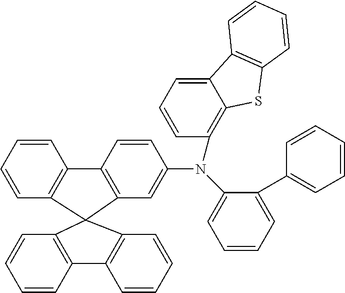 [SMILES: c1ccc(-c2ccccc2N(c2ccc3c(c2)C2(c4ccccc4-c4ccccc42)c2ccccc2-3)c2cccc3c2sc2ccccc23)cc1] | (160) |
| 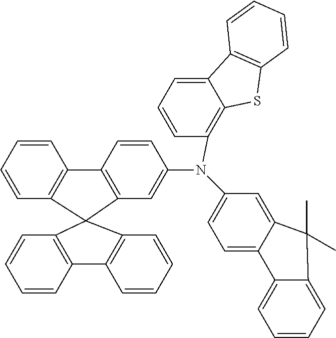 [SMILES: CC1(C)c2ccccc2-c2ccc(N(c3ccc4c(c3)C3(c5ccccc5-c5ccccc53)c3ccccc3-4)c3cccc4c3sc3ccccc34)cc21] | (161) |
| 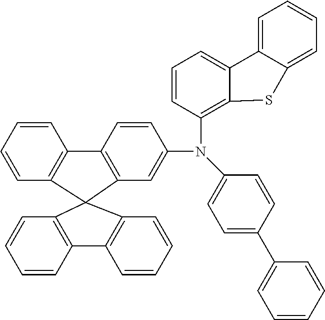 [SMILES: c1ccc(-c2ccc(N(c3ccc4c(c3)C3(c5ccccc5-c5ccccc53)c3ccccc3-4)c3cccc4c3sc3ccccc34)cc2)cc1] | (162) |
| 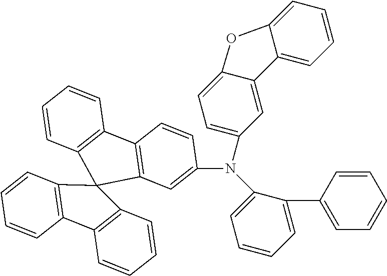 [SMILES: c1ccc(-c2ccccc2N(c2ccc3c(c2)C2(c4ccccc4-c4ccccc42)c2ccccc2-3)c2ccc3oc4ccccc4c3c2)cc1] | (163) |
| 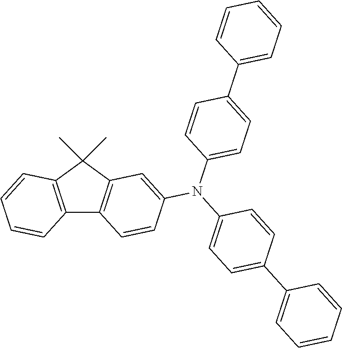 [SMILES: CC1(C)c2ccccc2-c2ccc(N(c3ccc(-c4ccccc4)cc3)c3ccc(-c4ccccc4)cc3)cc21] | (164) |
| 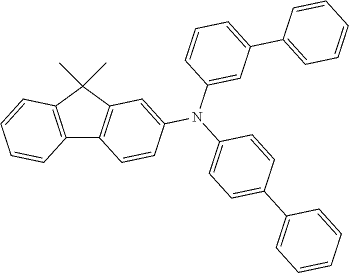 [SMILES: CC1(C)c2ccccc2-c2ccc(N(c3ccc(-c4ccccc4)cc3)c3cccc(-c4ccccc4)c3)cc21] | (165) |
| 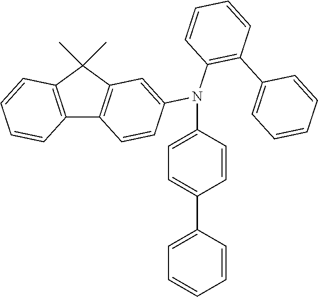 [SMILES: CC1(C)c2ccccc2-c2ccc(N(c3ccc(-c4ccccc4)cc3)c3ccccc3-c3ccccc3)cc21] | (166) |
| 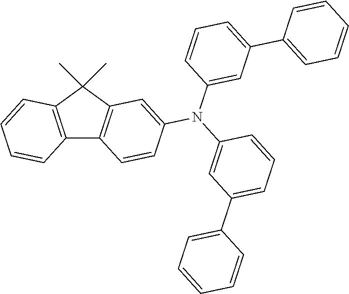 [SMILES: CC1(C)c2ccccc2-c2ccc(N(c3cccc(-c4ccccc4)c3)c3cccc(-c4ccccc4)c3)cc21] | (167) |
| 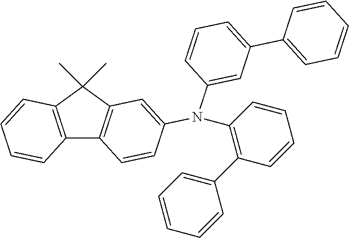 [SMILES: CC1(C)c2ccccc2-c2ccc(N(c3cccc(-c4ccccc4)c3)c3ccccc3-c3ccccc3)cc21] | (168) |
| 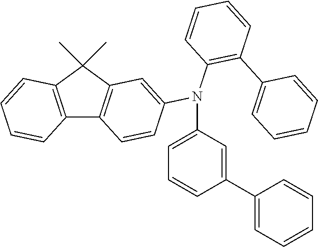 [SMILES: CC1(C)c2ccccc2-c2ccc(N(c3cccc(-c4ccccc4)c3)c3ccccc3-c3ccccc3)cc21] | (169) |
| 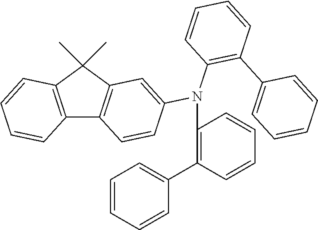 [SMILES: CC1(C)c2ccccc2-c2ccc(N(c3ccccc3-c3ccccc3)c3ccccc3-c3ccccc3)cc21] | (170) |
| 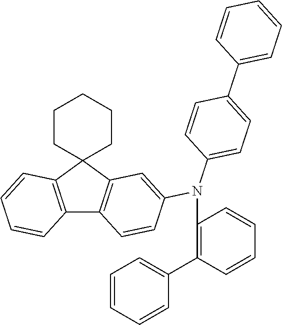 [SMILES: c1ccc(-c2ccc(N(c3ccc4c(c3)C3(CCCCC3)c3ccccc3-4)c3ccccc3-c3ccccc3)cc2)cc1] | (171) |
| 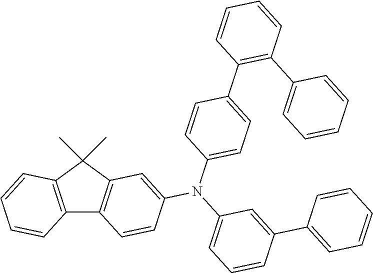 [SMILES: CC1(C)c2ccccc2-c2ccc(N(c3ccc(-c4ccccc4-c4ccccc4)cc3)c3cccc(-c4ccccc4)c3)cc21] | (172) |
| 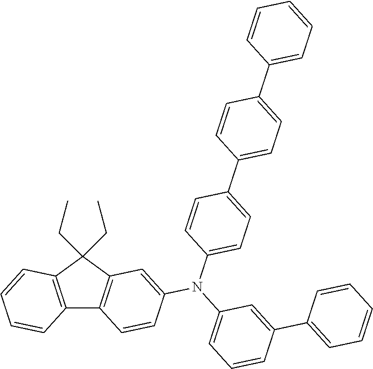 [SMILES: CCC1(CC)c2ccccc2-c2ccc(N(c3ccc(-c4ccc(-c5ccccc5)cc4)cc3)c3cccc(-c4ccccc4)c3)cc21] | (173) |
| 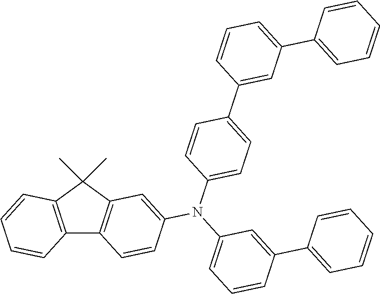 [SMILES: CC1(C)c2ccccc2-c2ccc(N(c3ccc(-c4cccc(-c5ccccc5)c4)cc3)c3cccc(-c4ccccc4)c3)cc21] | (174) |
| 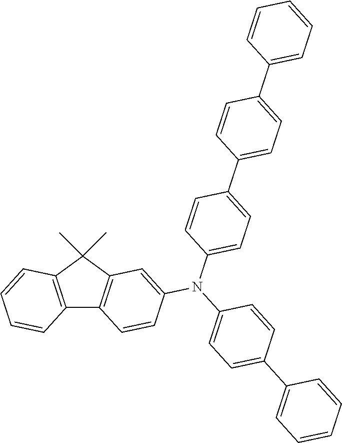 [SMILES: CC1(C)c2ccccc2-c2ccc(N(c3ccc(-c4ccccc4)cc3)c3ccc(-c4ccc(-c5ccccc5)cc4)cc3)cc21] | (175) |
| 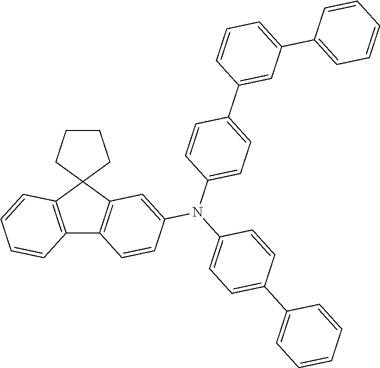 [SMILES: c1ccc(-c2ccc(N(c3ccc(-c4cccc(-c5ccccc5)c4)cc3)c3ccc4c(c3)C3(CCCC3)c3ccccc3-4)cc2)cc1] | (176) |
| 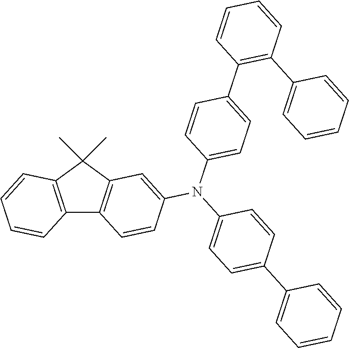 [SMILES: CC1(C)c2ccccc2-c2ccc(N(c3ccc(-c4ccccc4)cc3)c3ccc(-c4ccccc4-c4ccccc4)cc3)cc21] | (177) |
| 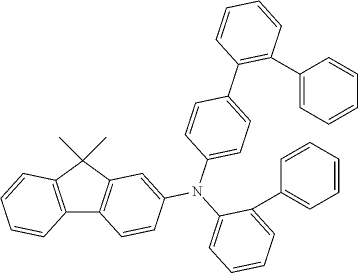 [SMILES: CC1(C)c2ccccc2-c2ccc(N(c3ccc(-c4ccccc4-c4ccccc4)cc3)c3ccccc3-c3ccccc3)cc21] | (178) |
| 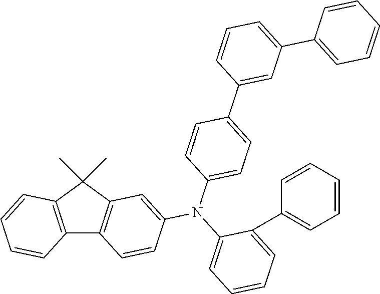 [SMILES: CC1(C)c2ccccc2-c2ccc(N(c3ccc(-c4cccc(-c5ccccc5)c4)cc3)c3ccccc3-c3ccccc3)cc21] | (179) |
| 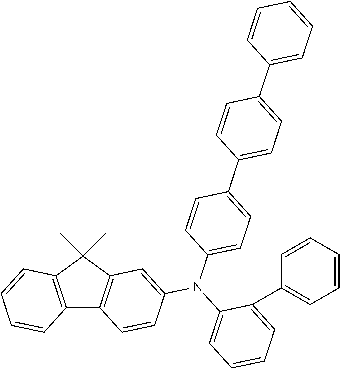 [SMILES: CC1(C)c2ccccc2-c2ccc(N(c3ccc(-c4ccc(-c5ccccc5)cc4)cc3)c3ccccc3-c3ccccc3)cc21] | (180) |
| 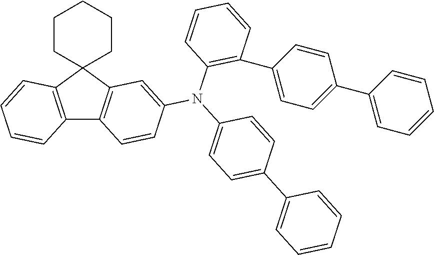 [SMILES: c1ccc(-c2ccc(-c3ccccc3N(c3ccc(-c4ccccc4)cc3)c3ccc4c(c3)C3(CCCCC3)c3ccccc3-4)cc2)cc1] | (181) |
| 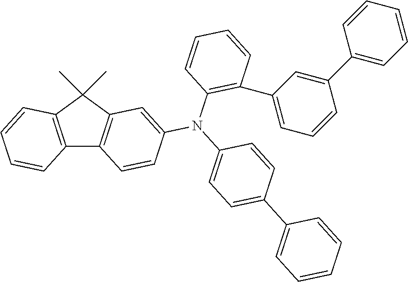 [SMILES: CC1(C)c2ccccc2-c2ccc(N(c3ccc(-c4ccccc4)cc3)c3ccccc3-c3cccc(-c4ccccc4)c3)cc21] | (182) |
| 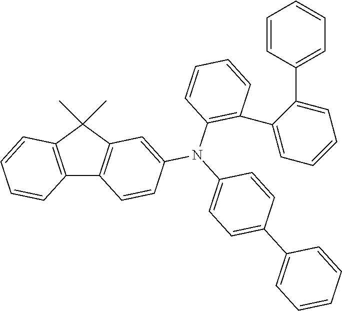 [SMILES: CC1(C)c2ccccc2-c2ccc(N(c3ccc(-c4ccccc4)cc3)c3ccccc3-c3ccccc3-c3ccccc3)cc21] | (183) |
| 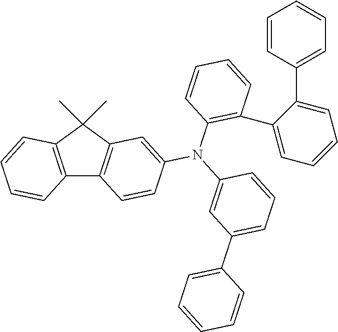 [SMILES: CC1(C)c2ccccc2-c2ccc(N(c3cccc(-c4ccccc4)c3)c3ccccc3-c3ccccc3-c3ccccc3)cc21] | (184) |
| 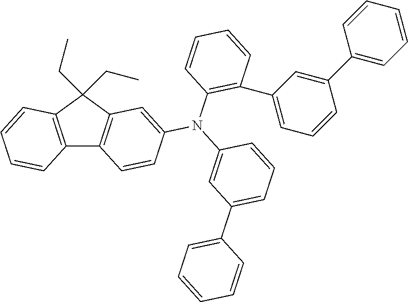 [SMILES: CCC1(CC)c2ccccc2-c2ccc(N(c3cccc(-c4ccccc4)c3)c3ccccc3-c3cccc(-c4ccccc4)c3)cc21] | (185) |
| 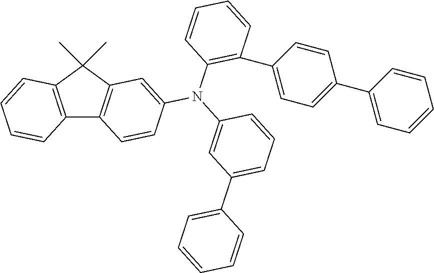 [SMILES: CC1(C)c2ccccc2-c2ccc(N(c3cccc(-c4ccccc4)c3)c3ccccc3-c3ccc(-c4ccccc4)cc3)cc21] | (186) |
| 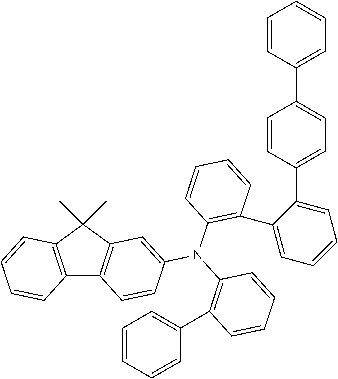 [SMILES: CC1(C)c2ccccc2-c2ccc(N(c3ccccc3-c3ccccc3)c3ccccc3-c3ccccc3-c3ccc(-c4ccccc4)cc3)cc21] | (187) |
| 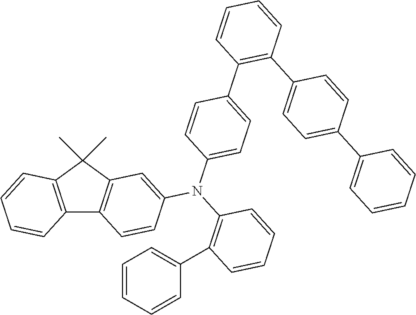 [SMILES: CC1(C)c2ccccc2-c2ccc(N(c3ccc(-c4ccccc4-c4ccc(-c5ccccc5)cc4)cc3)c3ccccc3-c3ccccc3)cc21] | (188) |
| 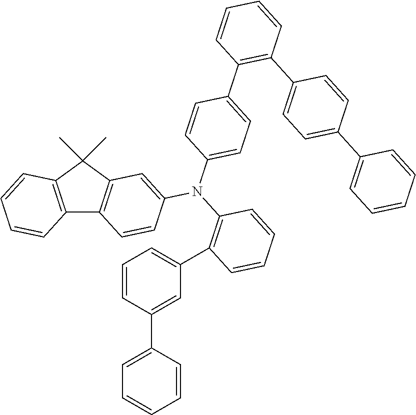 [SMILES: CC1(C)c2ccccc2-c2ccc(N(c3ccc(-c4ccccc4-c4ccc(-c5ccccc5)cc4)cc3)c3ccccc3-c3cccc(-c4ccccc4)c3)cc21] | (189) |
| 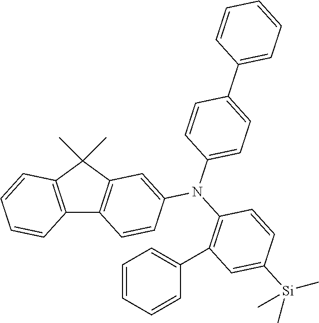 [SMILES: CC1(C)c2ccccc2-c2ccc(N(c3ccc(-c4ccccc4)cc3)c3ccc([Si](C)(C)C)cc3-c3ccccc3)cc21] | (190) |
| 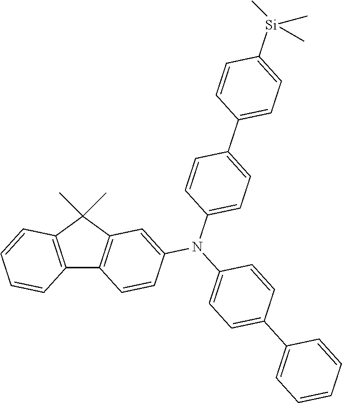 [SMILES: CC1(C)c2ccccc2-c2ccc(N(c3ccc(-c4ccccc4)cc3)c3ccc(-c4ccc([Si](C)(C)C)cc4)cc3)cc21] | (191) |
| 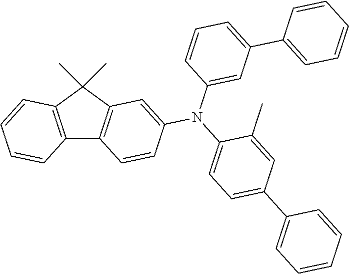 [SMILES: Cc1cc(-c2ccccc2)ccc1N(c1cccc(-c2ccccc2)c1)c1ccc2c(c1)C(C)(C)c1ccccc1-2] | (192) |
| 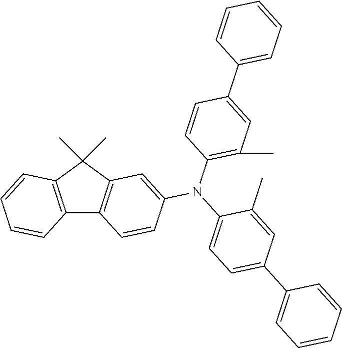 [SMILES: Cc1cc(-c2ccccc2)ccc1N(c1ccc2c(c1)C(C)(C)c1ccccc1-2)c1ccc(-c2ccccc2)cc1C] | (193) |
| 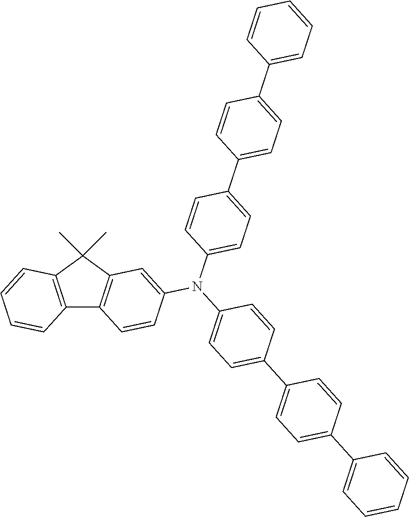 [SMILES: CC1(C)c2ccccc2-c2ccc(N(c3ccc(-c4ccc(-c5ccccc5)cc4)cc3)c3ccc(-c4ccc(-c5ccccc5)cc4)cc3)cc21] | (194) |
| 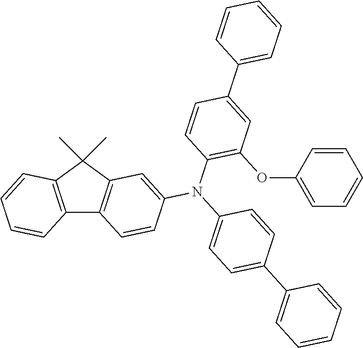 [SMILES: CC1(C)c2ccccc2-c2ccc(N(c3ccc(-c4ccccc4)cc3)c3ccc(-c4ccccc4)cc3Oc3ccccc3)cc21] | (195) |
| 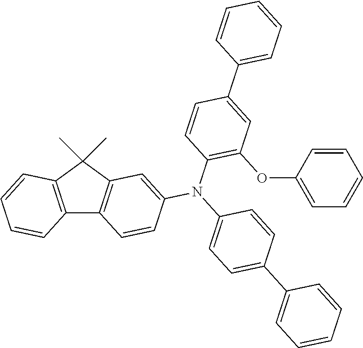 [SMILES: CC1(C)c2ccccc2-c2ccc(N(c3ccc(-c4ccccc4)cc3)c3ccc(-c4ccccc4)cc3Oc3ccccc3)cc21] | (196) |
| 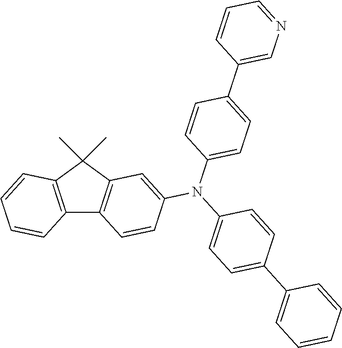 [SMILES: CC1(C)c2ccccc2-c2ccc(N(c3ccc(-c4ccccc4)cc3)c3ccc(-c4cccnc4)cc3)cc21] | (197) |
| 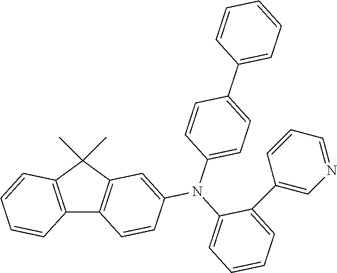 [SMILES: CC1(C)c2ccccc2-c2ccc(N(c3ccc(-c4ccccc4)cc3)c3ccccc3-c3cccnc3)cc21] | (198) |
| 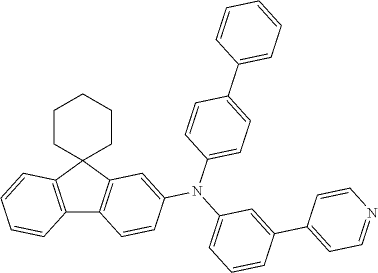 [SMILES: c1ccc(-c2ccc(N(c3cccc(-c4ccncc4)c3)c3ccc4c(c3)C3(CCCCC3)c3ccccc3-4)cc2)cc1] | (199) |
| 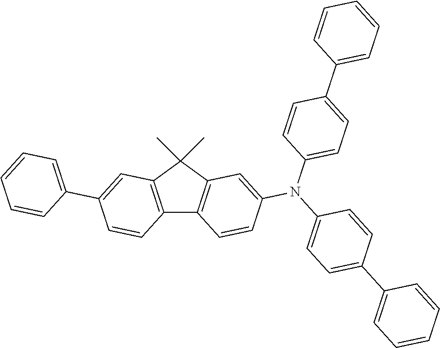 [SMILES: CC1(C)c2cc(-c3ccccc3)ccc2-c2ccc(N(c3ccc(-c4ccccc4)cc3)c3ccc(-c4ccccc4)cc3)cc21] | (200) |
| 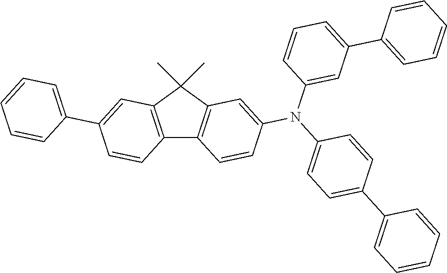 [SMILES: CC1(C)c2cc(-c3ccccc3)ccc2-c2ccc(N(c3ccc(-c4ccccc4)cc3)c3cccc(-c4ccccc4)c3)cc21] | (201) |
| 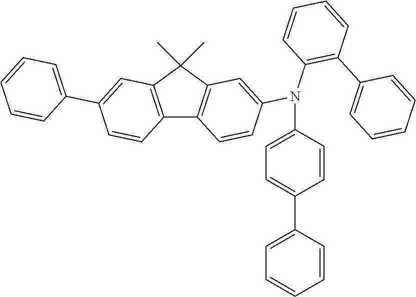 [SMILES: CC1(C)c2cc(-c3ccccc3)ccc2-c2ccc(N(c3ccc(-c4ccccc4)cc3)c3ccccc3-c3ccccc3)cc21] | (202) |
| 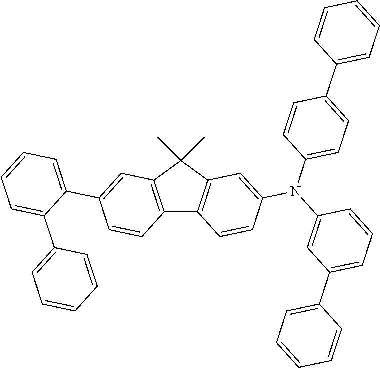 [SMILES: CC1(C)c2cc(-c3ccccc3-c3ccccc3)ccc2-c2ccc(N(c3ccc(-c4ccccc4)cc3)c3cccc(-c4ccccc4)c3)cc21] | (203) |
| 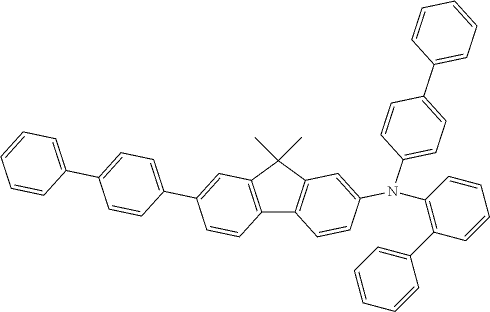 [SMILES: CC1(C)c2cc(-c3ccc(-c4ccccc4)cc3)ccc2-c2ccc(N(c3ccc(-c4ccccc4)cc3)c3ccccc3-c3ccccc3)cc21] | (204) |
| 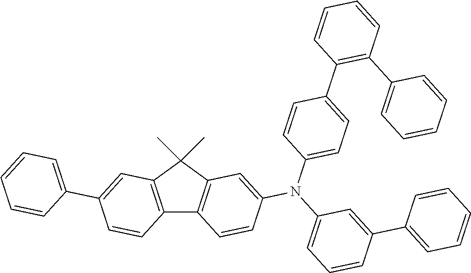 [SMILES: CC1(C)c2cc(-c3ccccc3)ccc2-c2ccc(N(c3ccc(-c4ccccc4-c4ccccc4)cc3)c3cccc(-c4ccccc4)c3)cc21] | (205) |
| 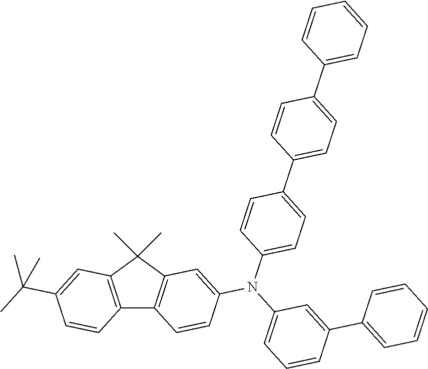 [SMILES: CC(C)(C)c1ccc2c(c1)C(C)(C)c1cc(N(c3ccc(-c4ccc(-c5ccccc5)cc4)cc3)c3cccc(-c4ccccc4)c3)ccc1-2] | (206) |
| 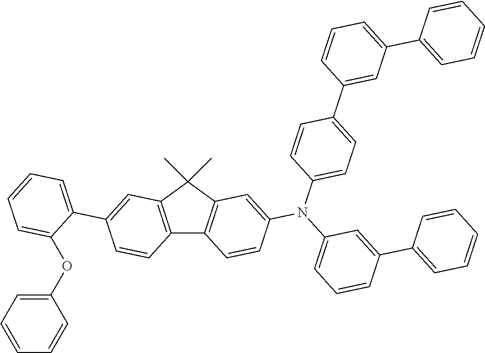 [SMILES: CC1(C)c2cc(-c3ccccc3Oc3ccccc3)ccc2-c2ccc(N(c3ccc(-c4cccc(-c5ccccc5)c4)cc3)c3cccc(-c4ccccc4)c3)cc21] | (207) |
| 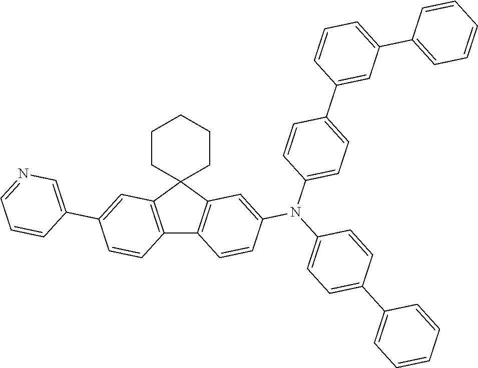 [SMILES: c1ccc(-c2ccc(N(c3ccc(-c4cccc(-c5ccccc5)c4)cc3)c3ccc4c(c3)C3(CCCCC3)c3cc(-c5cccnc5)ccc3-4)cc2)cc1] | (208) |
| 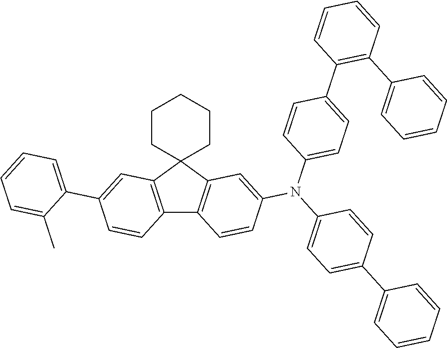 [SMILES: Cc1ccccc1-c1ccc2c(c1)C1(CCCCC1)c1cc(N(c3ccc(-c4ccccc4)cc3)c3ccc(-c4ccccc4-c4ccccc4)cc3)ccc1-2] | (209) |
| 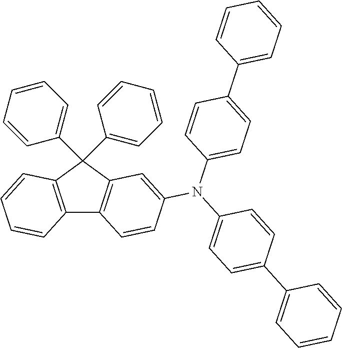 [SMILES: c1ccc(-c2ccc(N(c3ccc(-c4ccccc4)cc3)c3ccc4c(c3)C(c3ccccc3)(c3ccccc3)c3ccccc3-4)cc2)cc1] | (210) |
| 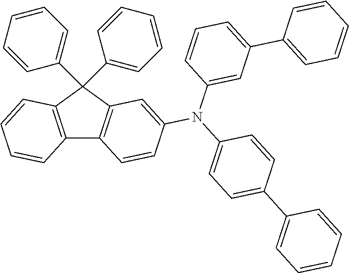 [SMILES: c1ccc(-c2ccc(N(c3cccc(-c4ccccc4)c3)c3ccc4c(c3)C(c3ccccc3)(c3ccccc3)c3ccccc3-4)cc2)cc1] | (211) |
| 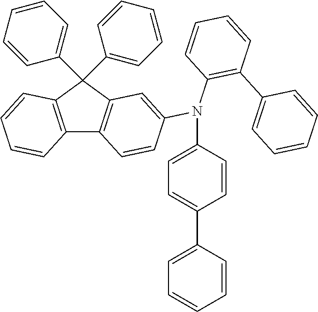 [SMILES: c1ccc(-c2ccc(N(c3ccc4c(c3)C(c3ccccc3)(c3ccccc3)c3ccccc3-4)c3ccccc3-c3ccccc3)cc2)cc1] | (212) |
| 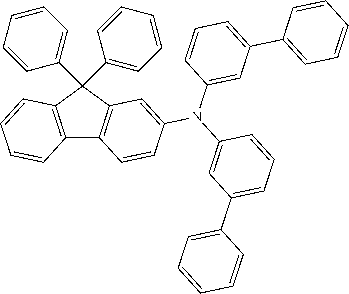 [SMILES: c1ccc(-c2cccc(N(c3cccc(-c4ccccc4)c3)c3ccc4c(c3)C(c3ccccc3)(c3ccccc3)c3ccccc3-4)c2)cc1] | (213) |
| 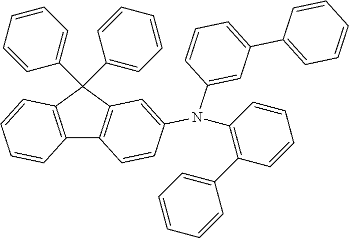 [SMILES: c1ccc(-c2cccc(N(c3ccc4c(c3)C(c3ccccc3)(c3ccccc3)c3ccccc3-4)c3ccccc3-c3ccccc3)c2)cc1] | (214) |
| 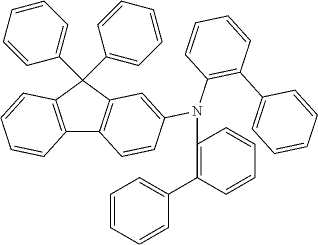 [SMILES: c1ccc(-c2ccccc2N(c2ccc3c(c2)C(c2ccccc2)(c2ccccc2)c2ccccc2-3)c2ccccc2-c2ccccc2)cc1] | (215) |
| 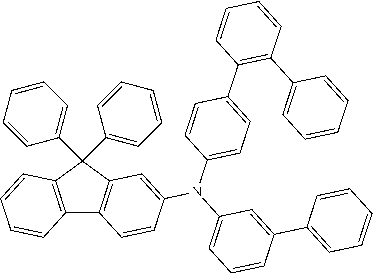 [SMILES: c1ccc(-c2cccc(N(c3ccc(-c4ccccc4-c4ccccc4)cc3)c3ccc4c(c3)C(c3ccccc3)(c3ccccc3)c3ccccc3-4)c2)cc1] | (216) |
| 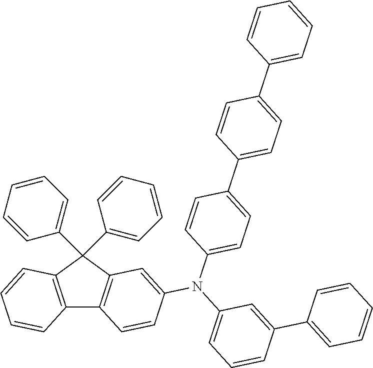 [SMILES: c1ccc(-c2ccc(-c3ccc(N(c4cccc(-c5ccccc5)c4)c4ccc5c(c4)C(c4ccccc4)(c4ccccc4)c4ccccc4-5)cc3)cc2)cc1] | (217) |
| 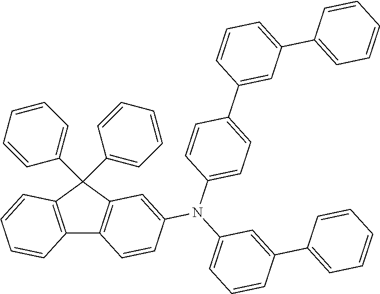 [SMILES: c1ccc(-c2cccc(-c3ccc(N(c4cccc(-c5ccccc5)c4)c4ccc5c(c4)C(c4ccccc4)(c4ccccc4)c4ccccc4-5)cc3)c2)cc1] | (218) |
| 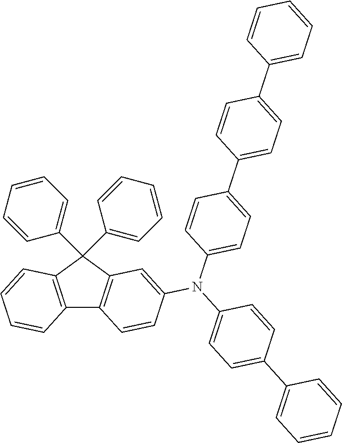 [SMILES: c1ccc(-c2ccc(-c3ccc(N(c4ccc(-c5ccccc5)cc4)c4ccc5c(c4)C(c4ccccc4)(c4ccccc4)c4ccccc4-5)cc3)cc2)cc1] | (219) |
| 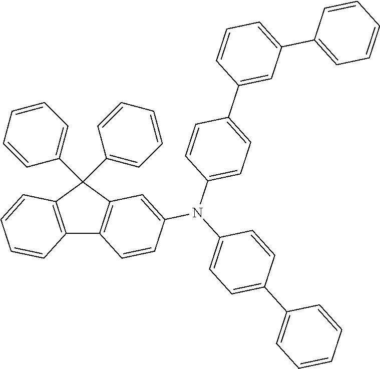 [SMILES: c1ccc(-c2ccc(N(c3ccc(-c4cccc(-c5ccccc5)c4)cc3)c3ccc4c(c3)C(c3ccccc3)(c3ccccc3)c3ccccc3-4)cc2)cc1] | (220) |
| 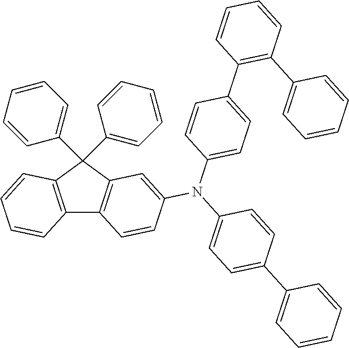 [SMILES: c1ccc(-c2ccc(N(c3ccc(-c4ccccc4-c4ccccc4)cc3)c3ccc4c(c3)C(c3ccccc3)(c3ccccc3)c3ccccc3-4)cc2)cc1] | (221) |
| 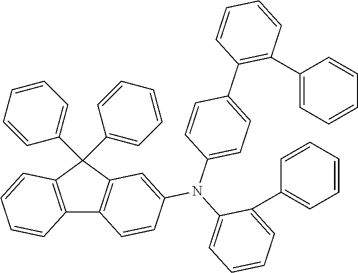 [SMILES: c1ccc(-c2ccccc2-c2ccc(N(c3ccc4c(c3)C(c3ccccc3)(c3ccccc3)c3ccccc3-4)c3ccccc3-c3ccccc3)cc2)cc1] | (222) |
| 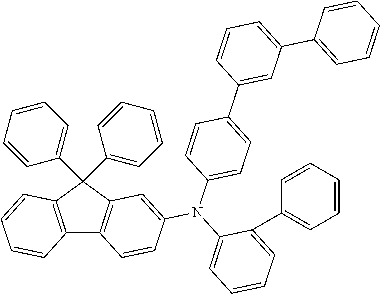 [SMILES: c1ccc(-c2cccc(-c3ccc(N(c4ccc5c(c4)C(c4ccccc4)(c4ccccc4)c4ccccc4-5)c4ccccc4-c4ccccc4)cc3)c2)cc1] | (223) |
| 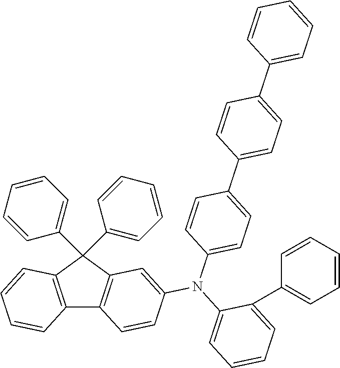 [SMILES: c1ccc(-c2ccc(-c3ccc(N(c4ccc5c(c4)C(c4ccccc4)(c4ccccc4)c4ccccc4-5)c4ccccc4-c4ccccc4)cc3)cc2)cc1] | (224) |
| 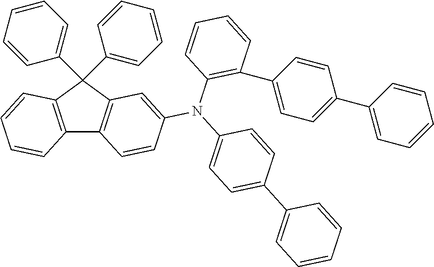 [SMILES: c1ccc(-c2ccc(-c3ccccc3N(c3ccc(-c4ccccc4)cc3)c3ccc4c(c3)C(c3ccccc3)(c3ccccc3)c3ccccc3-4)cc2)cc1] | (225) |
| 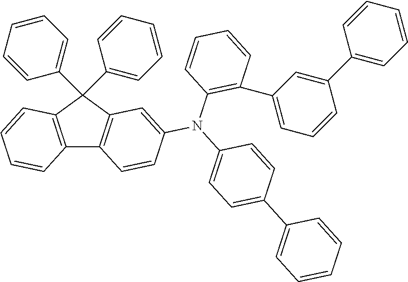 [SMILES: c1ccc(-c2ccc(N(c3ccc4c(c3)C(c3ccccc3)(c3ccccc3)c3ccccc3-4)c3ccccc3-c3cccc(-c4ccccc4)c3)cc2)cc1] | (226) |
| 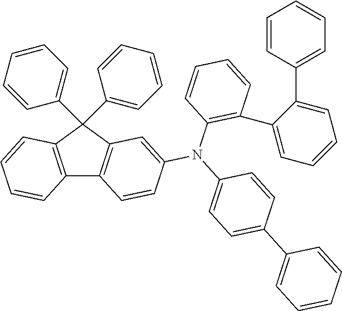 [SMILES: c1ccc(-c2ccc(N(c3ccc4c(c3)C(c3ccccc3)(c3ccccc3)c3ccccc3-4)c3ccccc3-c3ccccc3-c3ccccc3)cc2)cc1] | (227) |
| 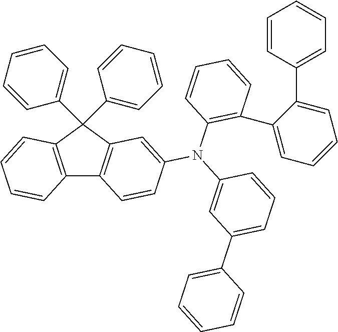 [SMILES: c1ccc(-c2cccc(N(c3ccc4c(c3)C(c3ccccc3)(c3ccccc3)c3ccccc3-4)c3ccccc3-c3ccccc3-c3ccccc3)c2)cc1] | (228) |
| 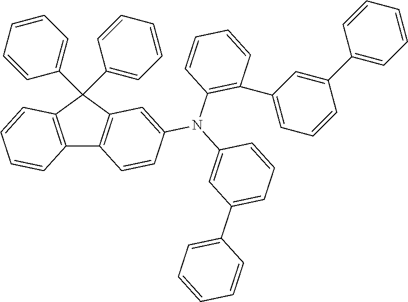 [SMILES: c1ccc(-c2cccc(-c3ccccc3N(c3cccc(-c4ccccc4)c3)c3ccc4c(c3)C(c3ccccc3)(c3ccccc3)c3ccccc3-4)c2)cc1] | (229) |
| 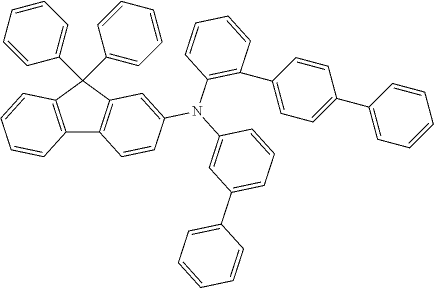 [SMILES: c1ccc(-c2ccc(-c3ccccc3N(c3cccc(-c4ccccc4)c3)c3ccc4c(c3)C(c3ccccc3)(c3ccccc3)c3ccccc3-4)cc2)cc1] | (230) |
| 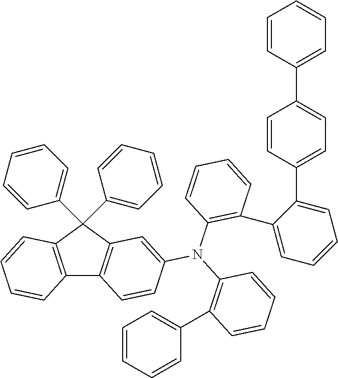 [SMILES: c1ccc(-c2ccc(-c3ccccc3-c3ccccc3N(c3ccc4c(c3)C(c3ccccc3)(c3ccccc3)c3ccccc3-4)c3ccccc3-c3ccccc3)cc2)cc1] | (231) |
| 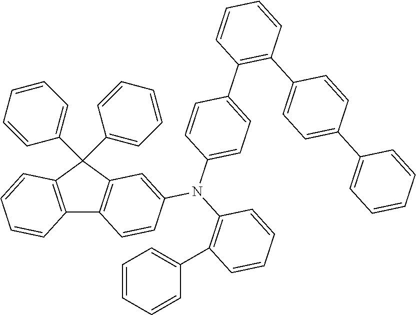 [SMILES: c1ccc(-c2ccc(-c3ccccc3-c3ccc(N(c4ccc5c(c4)C(c4ccccc4)(c4ccccc4)c4ccccc4-5)c4ccccc4-c4ccccc4)cc3)cc2)cc1] | (232) |
| 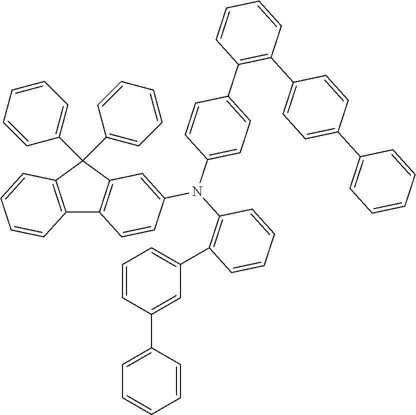 [SMILES: c1ccc(-c2ccc(-c3ccccc3-c3ccc(N(c4ccc5c(c4)C(c4ccccc4)(c4ccccc4)c4ccccc4-5)c4ccccc4-c4cccc(-c5ccccc5)c4)cc3)cc2)cc1] | (233) |
| 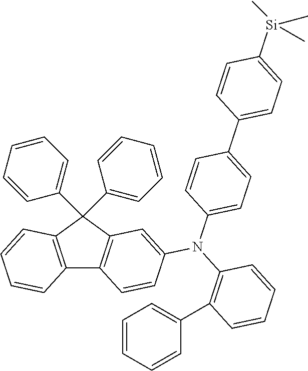 [SMILES: C[Si](C)(C)c1ccc(-c2ccc(N(c3ccc4c(c3)C(c3ccccc3)(c3ccccc3)c3ccccc3-4)c3ccccc3-c3ccccc3)cc2)cc1] | (234) |
| 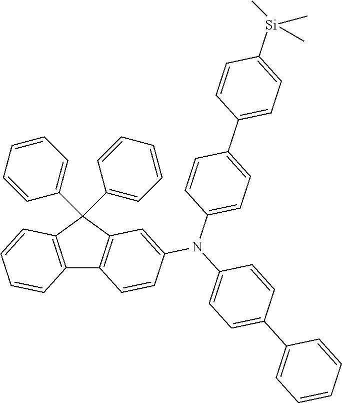 [SMILES: C[Si](C)(C)c1ccc(-c2ccc(N(c3ccc(-c4ccccc4)cc3)c3ccc4c(c3)C(c3ccccc3)(c3ccccc3)c3ccccc3-4)cc2)cc1] | (235) |
| 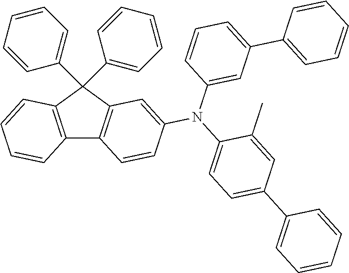 [SMILES: Cc1cc(-c2ccccc2)ccc1N(c1cccc(-c2ccccc2)c1)c1ccc2c(c1)C(c1ccccc1)(c1ccccc1)c1ccccc1-2] | (236) |
| 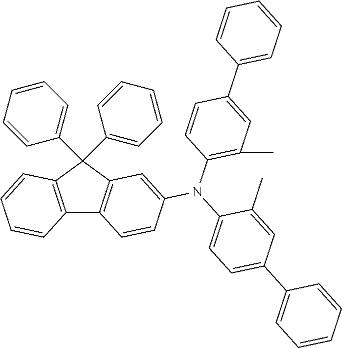 [SMILES: Cc1cc(-c2ccccc2)ccc1N(c1ccc2c(c1)C(c1ccccc1)(c1ccccc1)c1ccccc1-2)c1ccc(-c2ccccc2)cc1C] | (237) |
| 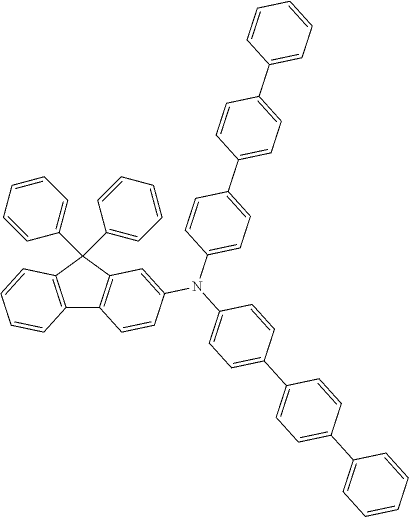 [SMILES: c1ccc(-c2ccc(-c3ccc(N(c4ccc(-c5ccc(-c6ccccc6)cc5)cc4)c4ccc5c(c4)C(c4ccccc4)(c4ccccc4)c4ccccc4-5)cc3)cc2)cc1] | (238) |
| 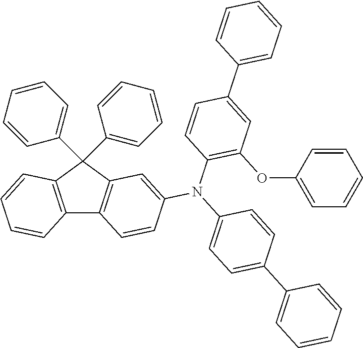 [SMILES: c1ccc(Oc2cc(-c3ccccc3)ccc2N(c2ccc(-c3ccccc3)cc2)c2ccc3c(c2)C(c2ccccc2)(c2ccccc2)c2ccccc2-3)cc1] | (239) |
| 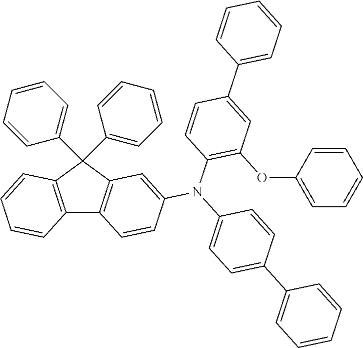 [SMILES: c1ccc(Oc2cc(-c3ccccc3)ccc2N(c2ccc(-c3ccccc3)cc2)c2ccc3c(c2)C(c2ccccc2)(c2ccccc2)c2ccccc2-3)cc1] | (240) |
| 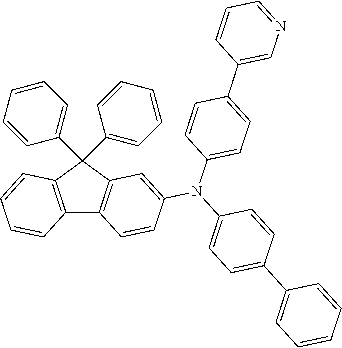 [SMILES: c1ccc(-c2ccc(N(c3ccc(-c4cccnc4)cc3)c3ccc4c(c3)C(c3ccccc3)(c3ccccc3)c3ccccc3-4)cc2)cc1] | (241) |
| 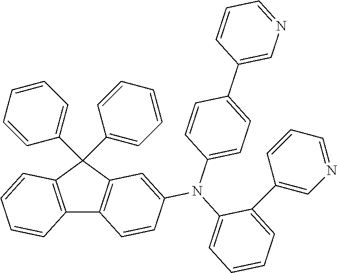 [SMILES: c1ccc(C2(c3ccccc3)c3ccccc3-c3ccc(N(c4ccc(-c5cccnc5)cc4)c4ccccc4-c4cccnc4)cc32)cc1] | (242) |
| 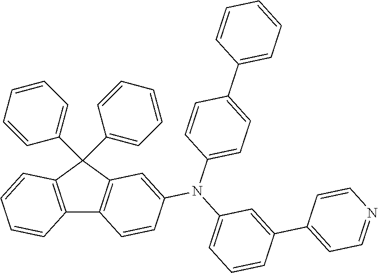 [SMILES: c1ccc(-c2ccc(N(c3cccc(-c4ccncc4)c3)c3ccc4c(c3)C(c3ccccc3)(c3ccccc3)c3ccccc3-4)cc2)cc1] | (243) |
| 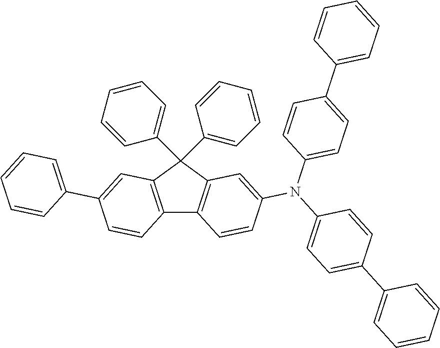 [SMILES: c1ccc(-c2ccc(N(c3ccc(-c4ccccc4)cc3)c3ccc4c(c3)C(c3ccccc3)(c3ccccc3)c3cc(-c5ccccc5)ccc3-4)cc2)cc1] | (244) |
| 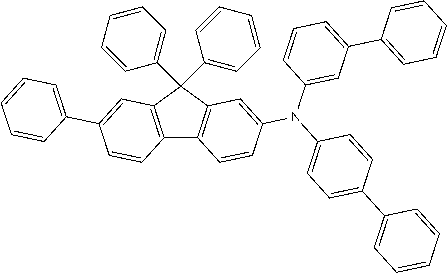 [SMILES: c1ccc(-c2ccc(N(c3cccc(-c4ccccc4)c3)c3ccc4c(c3)C(c3ccccc3)(c3ccccc3)c3cc(-c5ccccc5)ccc3-4)cc2)cc1] | (245) |
| 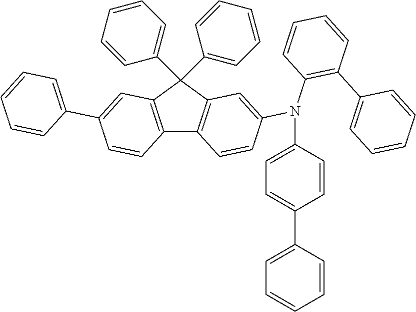 [SMILES: c1ccc(-c2ccc(N(c3ccc4c(c3)C(c3ccccc3)(c3ccccc3)c3cc(-c5ccccc5)ccc3-4)c3ccccc3-c3ccccc3)cc2)cc1] | (246) |
| 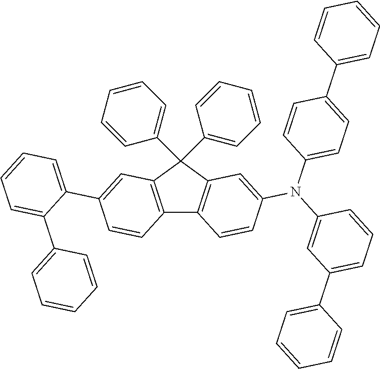 [SMILES: c1ccc(-c2ccc(N(c3cccc(-c4ccccc4)c3)c3ccc4c(c3)C(c3ccccc3)(c3ccccc3)c3cc(-c5ccccc5-c5ccccc5)ccc3-4)cc2)cc1] | (247) |
| 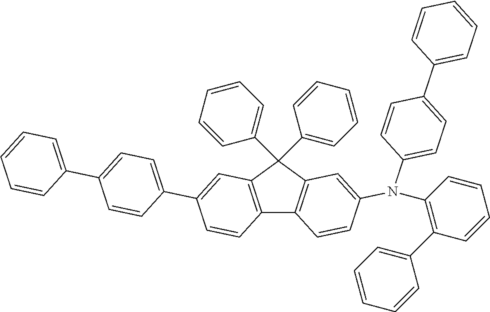 [SMILES: c1ccc(-c2ccc(-c3ccc4c(c3)C(c3ccccc3)(c3ccccc3)c3cc(N(c5ccc(-c6ccccc6)cc5)c5ccccc5-c5ccccc5)ccc3-4)cc2)cc1] | (248) |
| 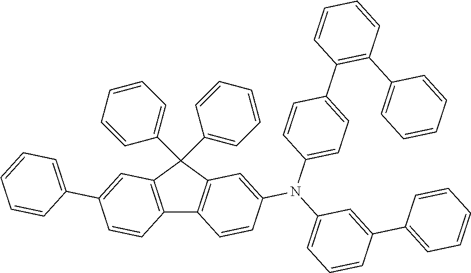 [SMILES: c1ccc(-c2cccc(N(c3ccc(-c4ccccc4-c4ccccc4)cc3)c3ccc4c(c3)C(c3ccccc3)(c3ccccc3)c3cc(-c5ccccc5)ccc3-4)c2)cc1] | (249) |
| 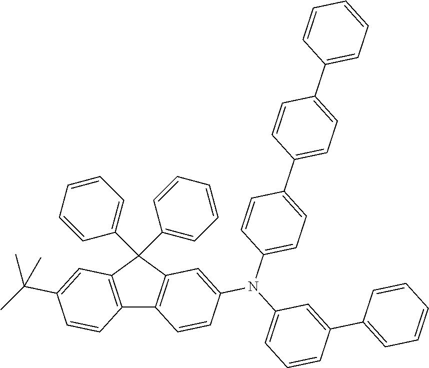 [SMILES: CC(C)(C)c1ccc2c(c1)C(c1ccccc1)(c1ccccc1)c1cc(N(c3ccc(-c4ccc(-c5ccccc5)cc4)cc3)c3cccc(-c4ccccc4)c3)ccc1-2] | (250) |
| 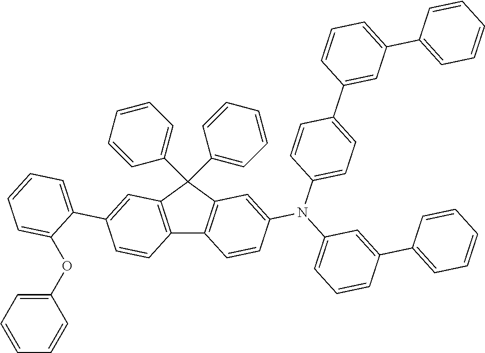 [SMILES: c1ccc(Oc2ccccc2-c2ccc3c(c2)C(c2ccccc2)(c2ccccc2)c2cc(N(c4ccc(-c5cccc(-c6ccccc6)c5)cc4)c4cccc(-c5ccccc5)c4)ccc2-3)cc1] | (251) |
| 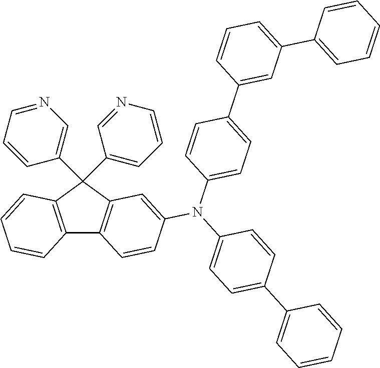 [SMILES: c1ccc(-c2ccc(N(c3ccc(-c4cccc(-c5ccccc5)c4)cc3)c3ccc4c(c3)C(c3cccnc3)(c3cccnc3)c3ccccc3-4)cc2)cc1] | (252) |
| 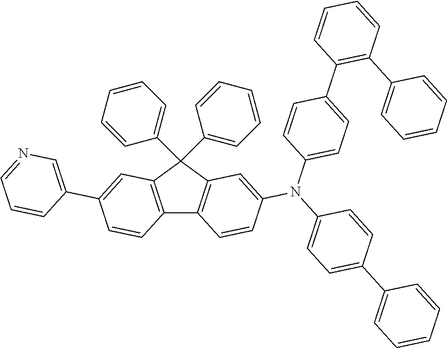 [SMILES: c1ccc(-c2ccc(N(c3ccc(-c4ccccc4-c4ccccc4)cc3)c3ccc4c(c3)C(c3ccccc3)(c3ccccc3)c3cc(-c5cccnc5)ccc3-4)cc2)cc1] | (253) |
| 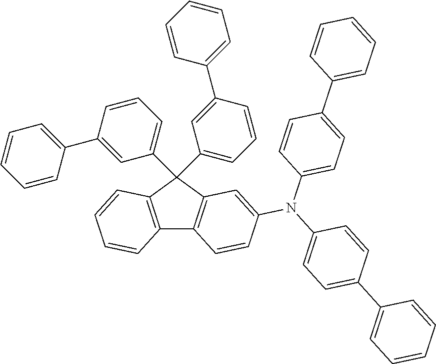 [SMILES: c1ccc(-c2ccc(N(c3ccc(-c4ccccc4)cc3)c3ccc4c(c3)C(c3cccc(-c5ccccc5)c3)(c3cccc(-c5ccccc5)c3)c3ccccc3-4)cc2)cc1] | (254) |
| 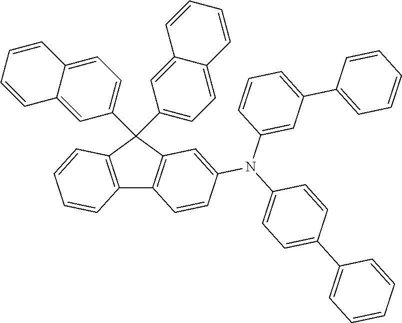 [SMILES: c1ccc(-c2ccc(N(c3cccc(-c4ccccc4)c3)c3ccc4c(c3)C(c3ccc5ccccc5c3)(c3ccc5ccccc5c3)c3ccccc3-4)cc2)cc1] | (255) |
| 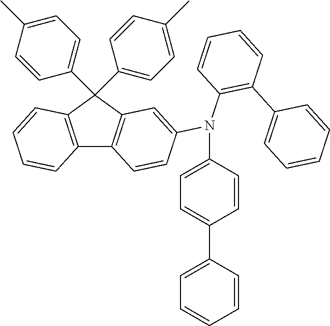 [SMILES: Cc1ccc(C2(c3ccc(C)cc3)c3ccccc3-c3ccc(N(c4ccc(-c5ccccc5)cc4)c4ccccc4-c4ccccc4)cc32)cc1] | (256) |
| 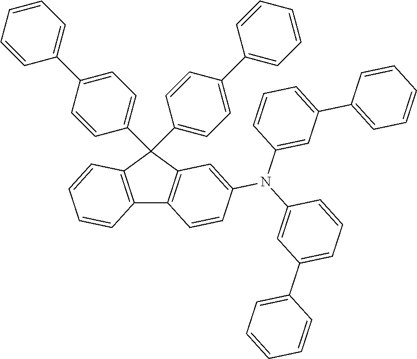 [SMILES: c1ccc(-c2ccc(C3(c4ccc(-c5ccccc5)cc4)c4ccccc4-c4ccc(N(c5cccc(-c6ccccc6)c5)c5cccc(-c6ccccc6)c5)cc43)cc2)cc1] | (257) |
| 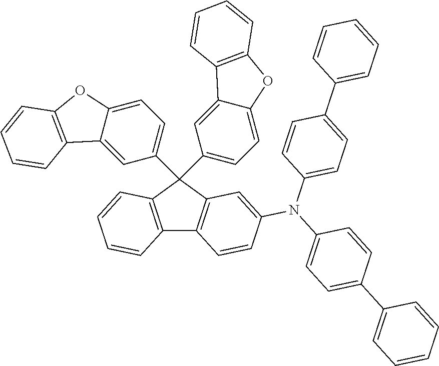 [SMILES: c1ccc(-c2ccc(N(c3ccc(-c4ccccc4)cc3)c3ccc4c(c3)C(c3ccc5oc6ccccc6c5c3)(c3ccc5oc6ccccc6c5c3)c3ccccc3-4)cc2)cc1] | (258) |
| 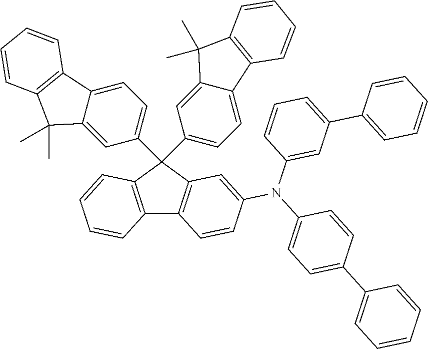 [SMILES: CC1(C)c2ccccc2-c2ccc(C3(c4ccc5c(c4)C(C)(C)c4ccccc4-5)c4ccccc4-c4ccc(N(c5ccc(-c6ccccc6)cc5)c5cccc(-c6ccccc6)c5)cc43)cc21] | (259) |
| 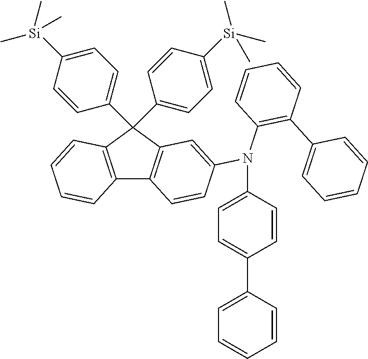 [SMILES: C[Si](C)(C)c1ccc(C2(c3ccc([Si](C)(C)C)cc3)c3ccccc3-c3ccc(N(c4ccc(-c5ccccc5)cc4)c4ccccc4-c4ccccc4)cc32)cc1] | (260) |
| 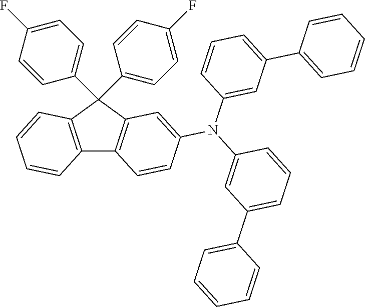 [SMILES: Fc1ccc(C2(c3ccc(F)cc3)c3ccccc3-c3ccc(N(c4cccc(-c5ccccc5)c4)c4cccc(-c5ccccc5)c4)cc32)cc1] | (261) |
| 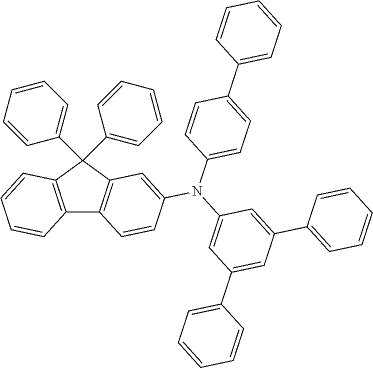 [SMILES: c1ccc(-c2ccc(N(c3cc(-c4ccccc4)cc(-c4ccccc4)c3)c3ccc4c(c3)C(c3ccccc3)(c3ccccc3)c3ccccc3-4)cc2)cc1] | (262) |
| 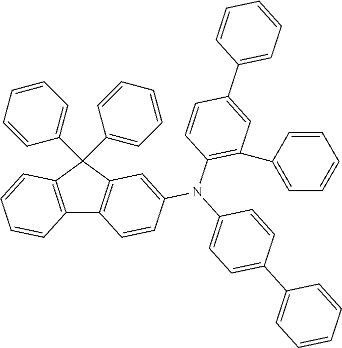 [SMILES: c1ccc(-c2ccc(N(c3ccc4c(c3)C(c3ccccc3)(c3ccccc3)c3ccccc3-4)c3ccc(-c4ccccc4)cc3-c3ccccc3)cc2)cc1] | (263) |
| 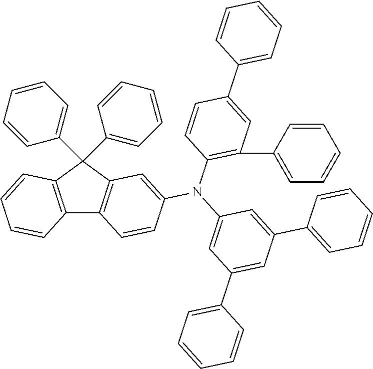 [SMILES: c1ccc(-c2cc(-c3ccccc3)cc(N(c3ccc4c(c3)C(c3ccccc3)(c3ccccc3)c3ccccc3-4)c3ccc(-c4ccccc4)cc3-c3ccccc3)c2)cc1] | (264) |
| 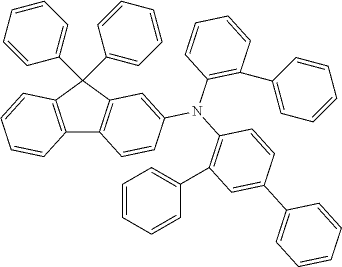 [SMILES: c1ccc(-c2ccc(N(c3ccc4c(c3)C(c3ccccc3)(c3ccccc3)c3ccccc3-4)c3ccccc3-c3ccccc3)c(-c3ccccc3)c2)cc1] | (265) |
| 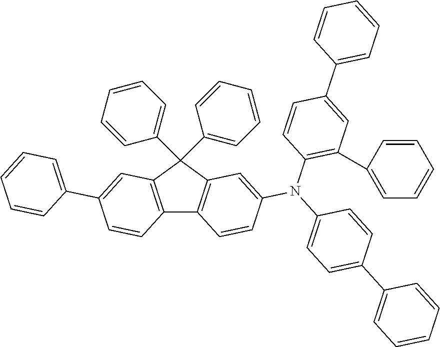 [SMILES: c1ccc(-c2ccc(N(c3ccc4c(c3)C(c3ccccc3)(c3ccccc3)c3cc(-c5ccccc5)ccc3-4)c3ccc(-c4ccccc4)cc3-c3ccccc3)cc2)cc1] | (266) |
| 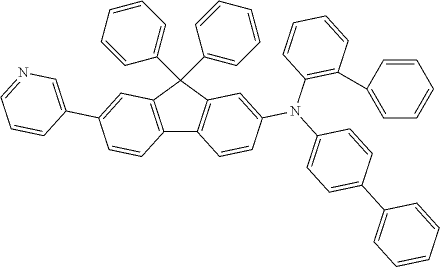 [SMILES: c1ccc(-c2ccc(N(c3ccc4c(c3)C(c3ccccc3)(c3ccccc3)c3cc(-c5cccnc5)ccc3-4)c3ccccc3-c3ccccc3)cc2)cc1] | (267) |
| 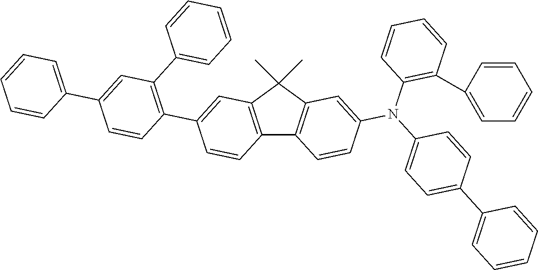 [SMILES: CC1(C)c2cc(-c3ccc(-c4ccccc4)cc3-c3ccccc3)ccc2-c2ccc(N(c3ccc(-c4ccccc4)cc3)c3ccccc3-c3ccccc3)cc21] | (268) |
| 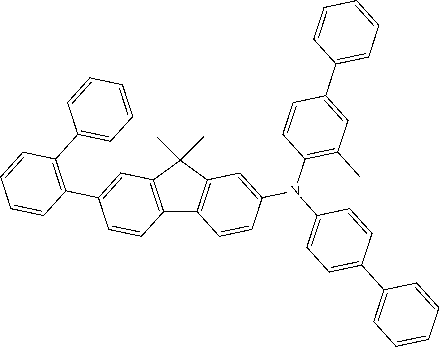 [SMILES: Cc1cc(-c2ccccc2)ccc1N(c1ccc(-c2ccccc2)cc1)c1ccc2c(c1)C(C)(C)c1cc(-c3ccccc3-c3ccccc3)ccc1-2] | (269) |
| 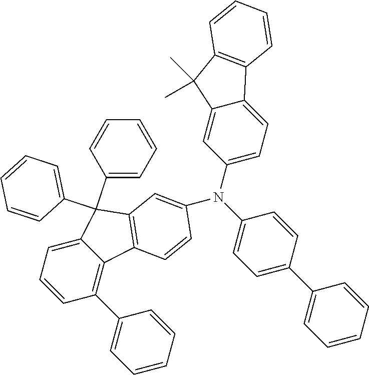 [SMILES: CC1(C)c2ccccc2-c2ccc(N(c3ccc(-c4ccccc4)cc3)c3ccc4c(c3)C(c3ccccc3)(c3ccccc3)c3cccc(-c5ccccc5)c3-4)cc21] | (270) |
| 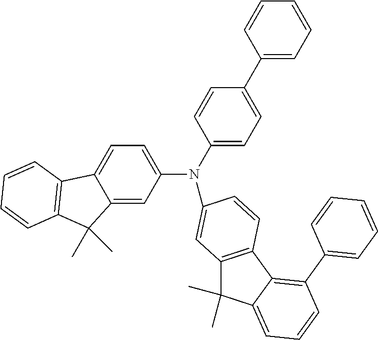 [SMILES: CC1(C)c2ccccc2-c2ccc(N(c3ccc(-c4ccccc4)cc3)c3ccc4c(c3)C(C)(C)c3cccc(-c5ccccc5)c3-4)cc21] | (271) |
| 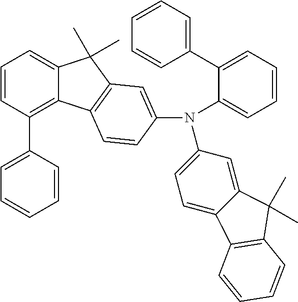 [SMILES: CC1(C)c2ccccc2-c2ccc(N(c3ccc4c(c3)C(C)(C)c3cccc(-c5ccccc5)c3-4)c3ccccc3-c3ccccc3)cc21] | (272) |
| 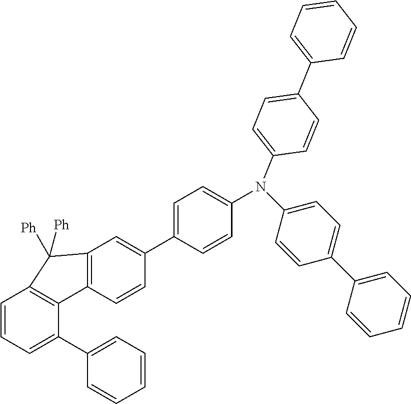 [SMILES: c1ccc(-c2ccc(N(c3ccc(-c4ccccc4)cc3)c3ccc(-c4ccc5c(c4)C(c4ccccc4)(c4ccccc4)c4cccc(-c6ccccc6)c4-5)cc3)cc2)cc1] | (273) |
| 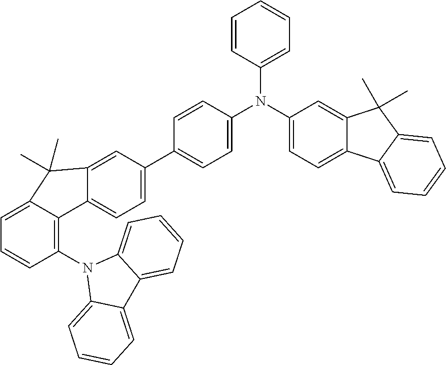 [SMILES: CC1(C)c2ccccc2-c2ccc(N(c3ccccc3)c3ccc(-c4ccc5c(c4)C(C)(C)c4cccc(-n6c7ccccc7c7ccccc76)c4-5)cc3)cc21] | (274) |
| 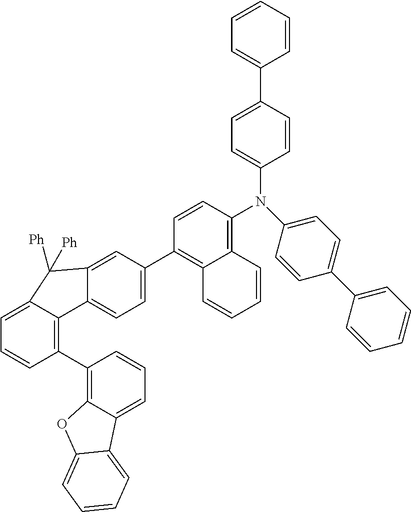 [SMILES: c1ccc(-c2ccc(N(c3ccc(-c4ccccc4)cc3)c3ccc(-c4ccc5c(c4)C(c4ccccc4)(c4ccccc4)c4cccc(-c6cccc7c6oc6ccccc67)c4-5)c4ccccc34)cc2)cc1] | (275) |
| 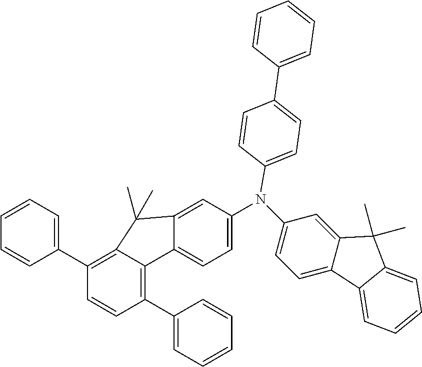 [SMILES: CC1(C)c2ccccc2-c2ccc(N(c3ccc(-c4ccccc4)cc3)c3ccc4c(c3)C(C)(C)c3c(-c5ccccc5)ccc(-c5ccccc5)c3-4)cc21] | (276) |
| 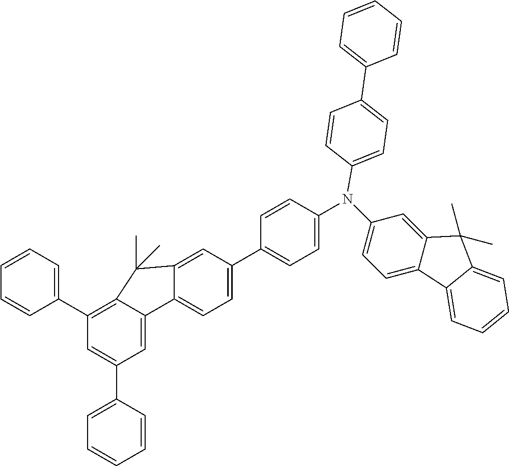 [SMILES: CC1(C)c2ccccc2-c2ccc(N(c3ccc(-c4ccccc4)cc3)c3ccc(-c4ccc5c(c4)C(C)(C)c4c(-c6ccccc6)cc(-c6ccccc6)cc4-5)cc3)cc21] | (277) |
| 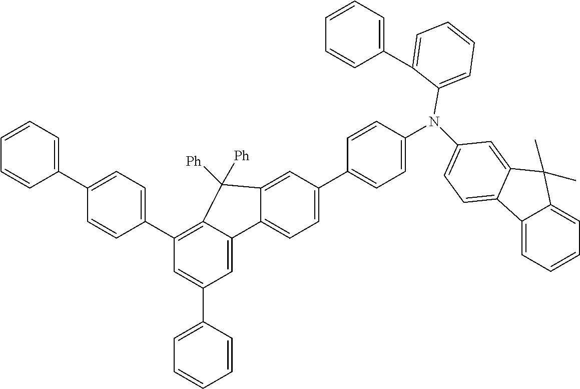 [SMILES: CC1(C)c2ccccc2-c2ccc(N(c3ccc(-c4ccc5c(c4)C(c4ccccc4)(c4ccccc4)c4c(-c6ccc(-c7ccccc7)cc6)cc(-c6ccccc6)cc4-5)cc3)c3ccccc3-c3ccccc3)cc21] | (278) |
| 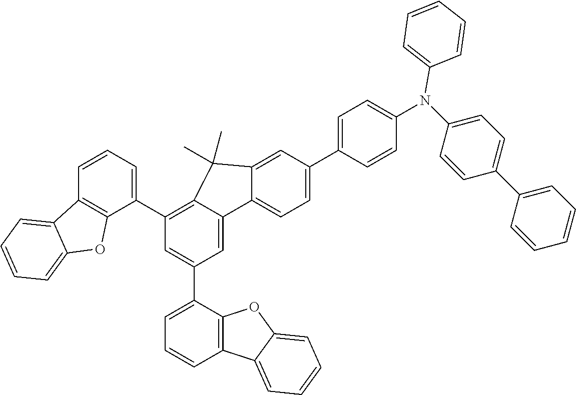 [SMILES: CC1(C)c2cc(-c3ccc(N(c4ccccc4)c4ccc(-c5ccccc5)cc4)cc3)ccc2-c2cc(-c3cccc4c3oc3ccccc34)cc(-c3cccc4c3oc3ccccc34)c21] | (279) |
| 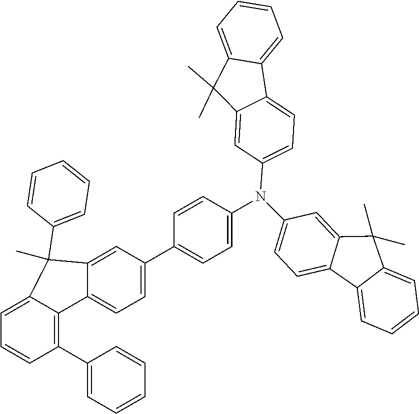 [SMILES: CC1(C)c2ccccc2-c2ccc(N(c3ccc(-c4ccc5c(c4)C(C)(c4ccccc4)c4cccc(-c6ccccc6)c4-5)cc3)c3ccc4c(c3)C(C)(C)c3ccccc3-4)cc21] | (280) |
| 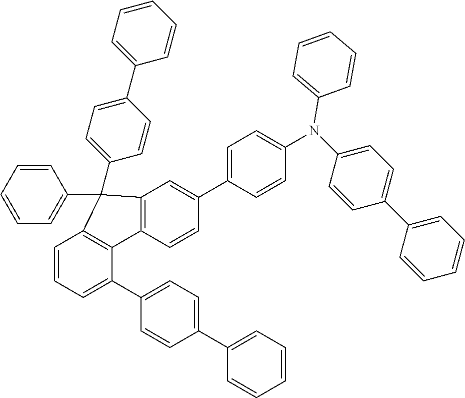 [SMILES: c1ccc(-c2ccc(-c3cccc4c3-c3ccc(-c5ccc(N(c6ccccc6)c6ccc(-c7ccccc7)cc6)cc5)cc3C4(c3ccccc3)c3ccc(-c4ccccc4)cc3)cc2)cc1] | (281) |
| 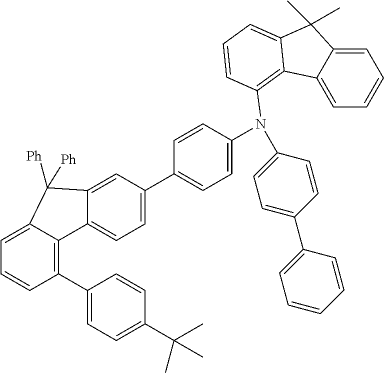 [SMILES: CC(C)(C)c1ccc(-c2cccc3c2-c2ccc(-c4ccc(N(c5ccc(-c6ccccc6)cc5)c5cccc6c5-c5ccccc5C6(C)C)cc4)cc2C3(c2ccccc2)c2ccccc2)cc1] | (282) |
| 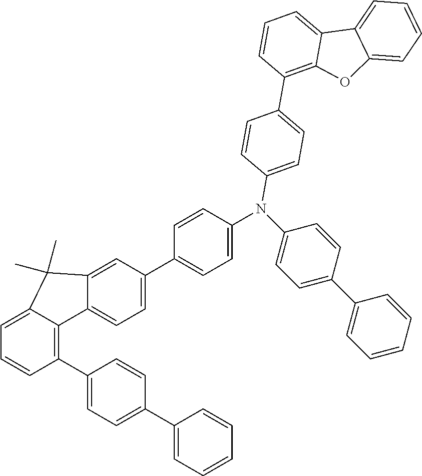 [SMILES: CC1(C)c2cc(-c3ccc(N(c4ccc(-c5ccccc5)cc4)c4ccc(-c5cccc6c5oc5ccccc56)cc4)cc3)ccc2-c2c(-c3ccc(-c4ccccc4)cc3)cccc21] | (283) |
| 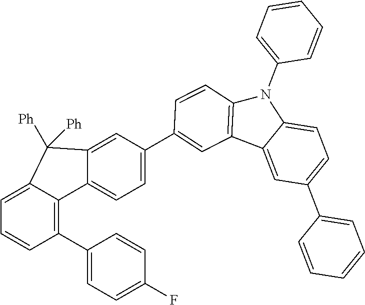 [SMILES: Fc1ccc(-c2cccc3c2-c2ccc(-c4ccc5c(c4)c4cc(-c6ccccc6)ccc4n5-c4ccccc4)cc2C3(c2ccccc2)c2ccccc2)cc1] | (284) |
| 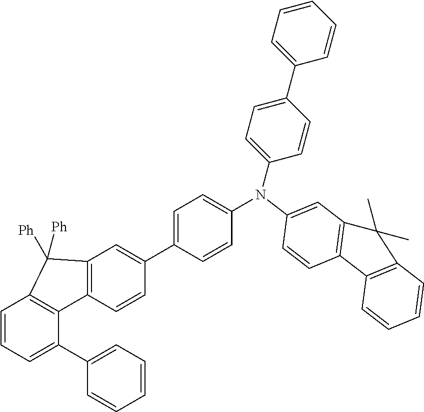 [SMILES: CC1(C)c2ccccc2-c2ccc(N(c3ccc(-c4ccccc4)cc3)c3ccc(-c4ccc5c(c4)C(c4ccccc4)(c4ccccc4)c4cccc(-c6ccccc6)c4-5)cc3)cc21] | (285) |
| 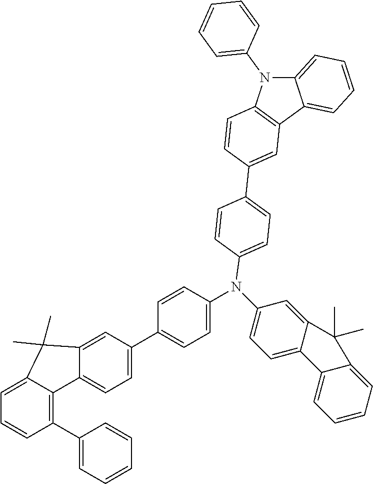 [SMILES: CC1(C)c2ccccc2-c2ccc(N(c3ccc(-c4ccc5c(c4)C(C)(C)c4cccc(-c6ccccc6)c4-5)cc3)c3ccc(-c4ccc5c(c4)c4ccccc4n5-c4ccccc4)cc3)cc21] | (286) |
| 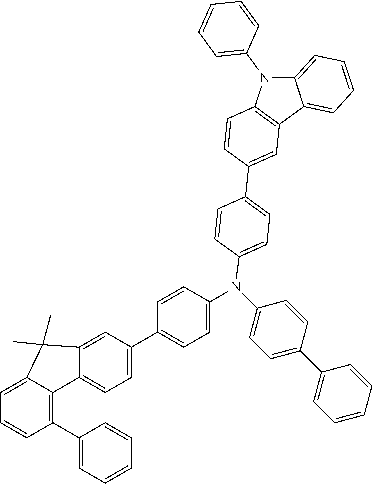 [SMILES: CC1(C)c2cc(-c3ccc(N(c4ccc(-c5ccccc5)cc4)c4ccc(-c5ccc6c(c5)c5ccccc5n6-c5ccccc5)cc4)cc3)ccc2-c2c(-c3ccccc3)cccc21] | (287) |
| 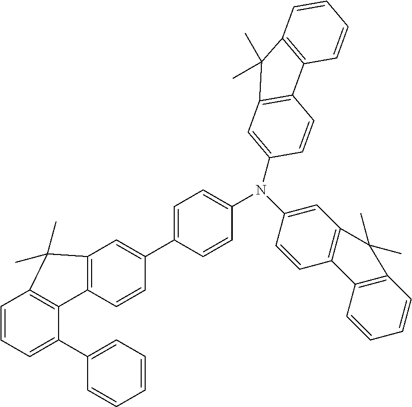 [SMILES: CC1(C)c2ccccc2-c2ccc(N(c3ccc(-c4ccc5c(c4)C(C)(C)c4cccc(-c6ccccc6)c4-5)cc3)c3ccc4c(c3)C(C)(C)c3ccccc3-4)cc21] | (288) |
| 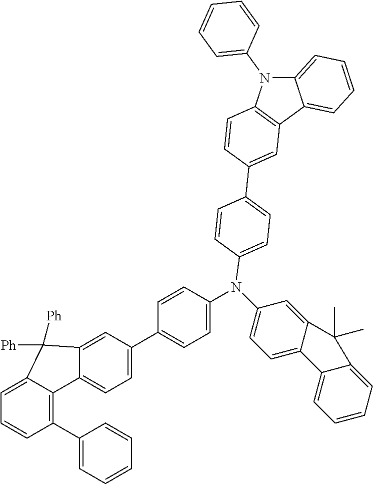 [SMILES: CC1(C)c2ccccc2-c2ccc(N(c3ccc(-c4ccc5c(c4)C(c4ccccc4)(c4ccccc4)c4cccc(-c6ccccc6)c4-5)cc3)c3ccc(-c4ccc5c(c4)c4ccccc4n5-c4ccccc4)cc3)cc21] | (289) |
| 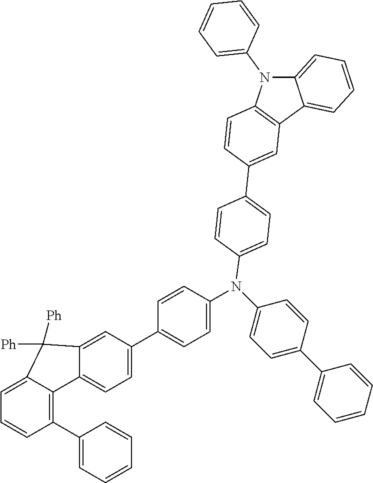 [SMILES: c1ccc(-c2ccc(N(c3ccc(-c4ccc5c(c4)C(c4ccccc4)(c4ccccc4)c4cccc(-c6ccccc6)c4-5)cc3)c3ccc(-c4ccc5c(c4)c4ccccc4n5-c4ccccc4)cc3)cc2)cc1] | (290) |
| 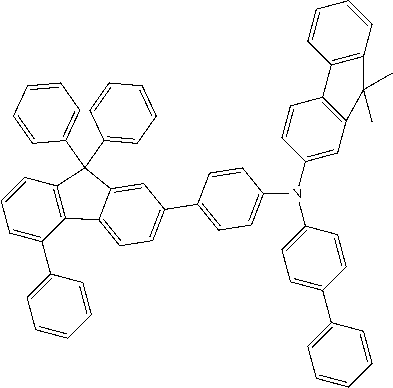 [SMILES: CC1(C)c2ccccc2-c2ccc(N(c3ccc(-c4ccccc4)cc3)c3ccc(-c4ccc5c(c4)C(c4ccccc4)(c4ccccc4)c4cccc(-c6ccccc6)c4-5)cc3)cc21] | (291) |
| 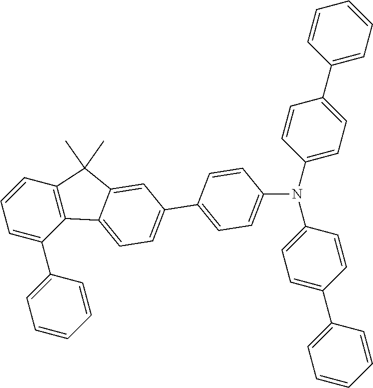 [SMILES: CC1(C)c2cc(-c3ccc(N(c4ccc(-c5ccccc5)cc4)c4ccc(-c5ccccc5)cc4)cc3)ccc2-c2c(-c3ccccc3)cccc21] | (292) |
| 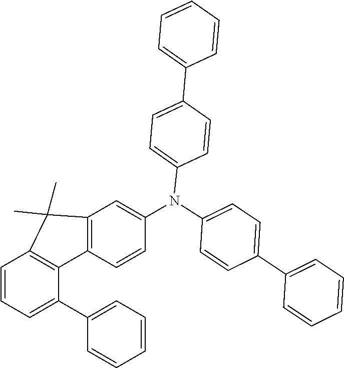 [SMILES: CC1(C)c2cc(N(c3ccc(-c4ccccc4)cc3)c3ccc(-c4ccccc4)cc3)ccc2-c2c(-c3ccccc3)cccc21] | (293) |
| 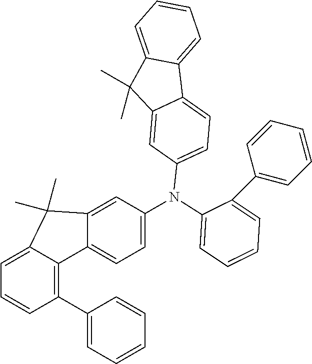 [SMILES: CC1(C)c2ccccc2-c2ccc(N(c3ccc4c(c3)C(C)(C)c3cccc(-c5ccccc5)c3-4)c3ccccc3-c3ccccc3)cc21] | (294) |
| 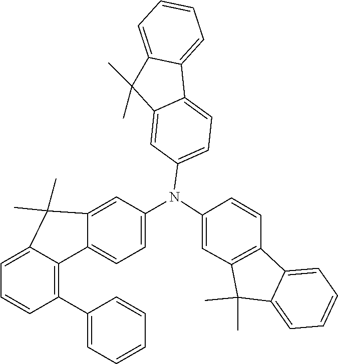 [SMILES: CC1(C)c2ccccc2-c2ccc(N(c3ccc4c(c3)C(C)(C)c3ccccc3-4)c3ccc4c(c3)C(C)(C)c3cccc(-c5ccccc5)c3-4)cc21] | (295) |
| 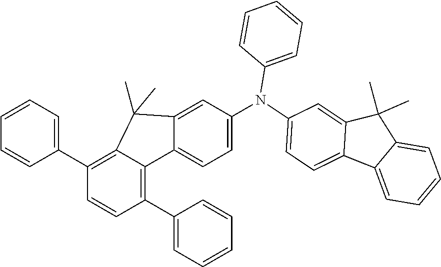 [SMILES: CC1(C)c2ccccc2-c2ccc(N(c3ccccc3)c3ccc4c(c3)C(C)(C)c3c(-c5ccccc5)ccc(-c5ccccc5)c3-4)cc21] | (296) |
| 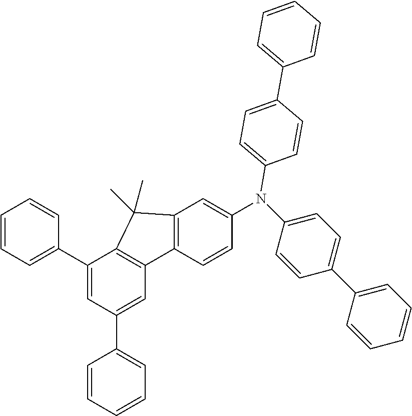 [SMILES: CC1(C)c2cc(N(c3ccc(-c4ccccc4)cc3)c3ccc(-c4ccccc4)cc3)ccc2-c2cc(-c3ccccc3)cc(-c3ccccc3)c21] | (297) |
| 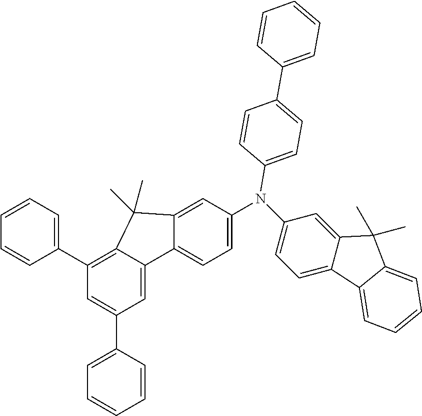 [SMILES: CC1(C)c2ccccc2-c2ccc(N(c3ccc(-c4ccccc4)cc3)c3ccc4c(c3)C(C)(C)c3c(-c5ccccc5)cc(-c5ccccc5)cc3-4)cc21] | (298) |
| 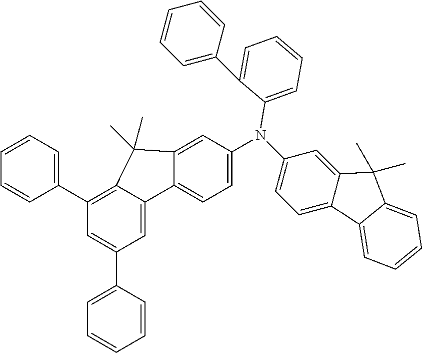 [SMILES: CC1(C)c2ccccc2-c2ccc(N(c3ccc4c(c3)C(C)(C)c3c(-c5ccccc5)cc(-c5ccccc5)cc3-4)c3ccccc3-c3ccccc3)cc21] | (299) |
| 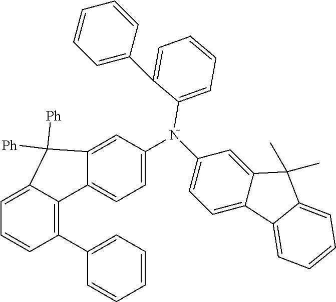 [SMILES: CC1(C)c2ccccc2-c2ccc(N(c3ccc4c(c3)C(c3ccccc3)(c3ccccc3)c3cccc(-c5ccccc5)c3-4)c3ccccc3-c3ccccc3)cc21] | (300) |
| 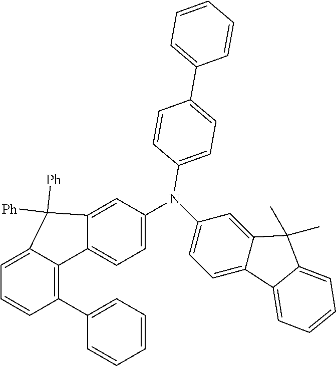 [SMILES: CC1(C)c2ccccc2-c2ccc(N(c3ccc(-c4ccccc4)cc3)c3ccc4c(c3)C(c3ccccc3)(c3ccccc3)c3cccc(-c5ccccc5)c3-4)cc21] | (301) |
| 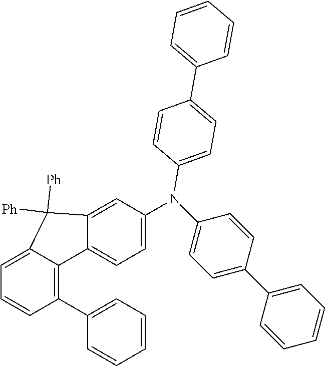 [SMILES: c1ccc(-c2ccc(N(c3ccc(-c4ccccc4)cc3)c3ccc4c(c3)C(c3ccccc3)(c3ccccc3)c3cccc(-c5ccccc5)c3-4)cc2)cc1] | (302) |
| 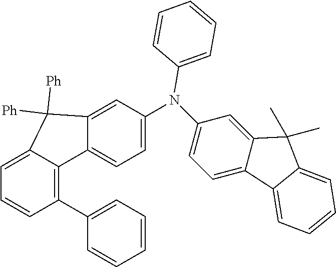 [SMILES: CC1(C)c2ccccc2-c2ccc(N(c3ccccc3)c3ccc4c(c3)C(c3ccccc3)(c3ccccc3)c3cccc(-c5ccccc5)c3-4)cc21] | (303) |
| 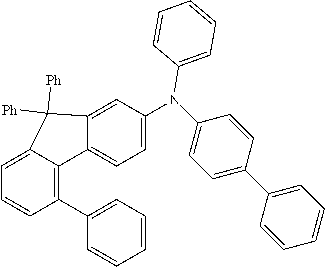 [SMILES: c1ccc(-c2ccc(N(c3ccccc3)c3ccc4c(c3)C(c3ccccc3)(c3ccccc3)c3cccc(-c5ccccc5)c3-4)cc2)cc1] | (304) |
| 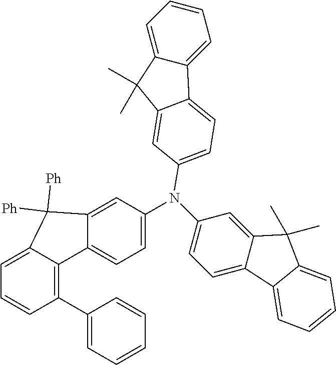 [SMILES: CC1(C)c2ccccc2-c2ccc(N(c3ccc4c(c3)C(C)(C)c3ccccc3-4)c3ccc4c(c3)C(c3ccccc3)(c3ccccc3)c3cccc(-c5ccccc5)c3-4)cc21] | (305) |
| 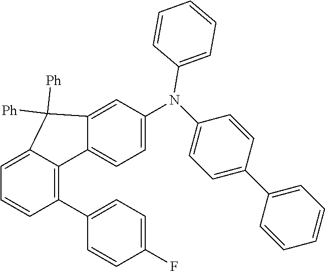 [SMILES: Fc1ccc(-c2cccc3c2-c2ccc(N(c4ccccc4)c4ccc(-c5ccccc5)cc4)cc2C3(c2ccccc2)c2ccccc2)cc1] | (306) |
| 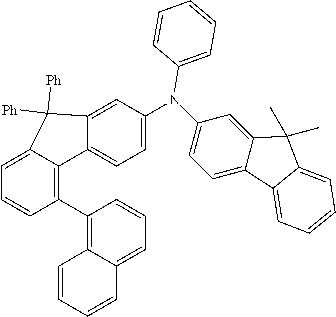 [SMILES: CC1(C)c2ccccc2-c2ccc(N(c3ccccc3)c3ccc4c(c3)C(c3ccccc3)(c3ccccc3)c3cccc(-c5cccc6ccccc56)c3-4)cc21] | (307) |
| 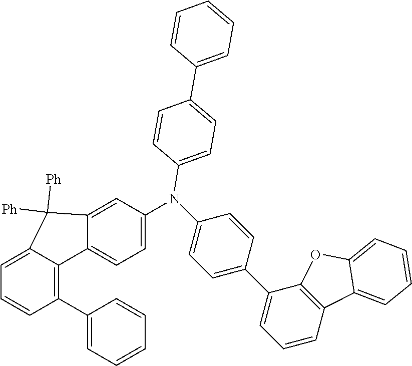 [SMILES: c1ccc(-c2ccc(N(c3ccc(-c4cccc5c4oc4ccccc45)cc3)c3ccc4c(c3)C(c3ccccc3)(c3ccccc3)c3cccc(-c5ccccc5)c3-4)cc2)cc1] | (308) |
| 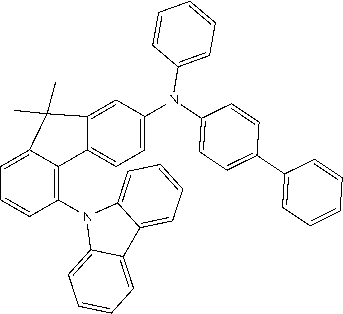 [SMILES: CC1(C)c2cc(N(c3ccccc3)c3ccc(-c4ccccc4)cc3)ccc2-c2c(-n3c4ccccc4c4ccccc43)cccc21] | (309) |
| 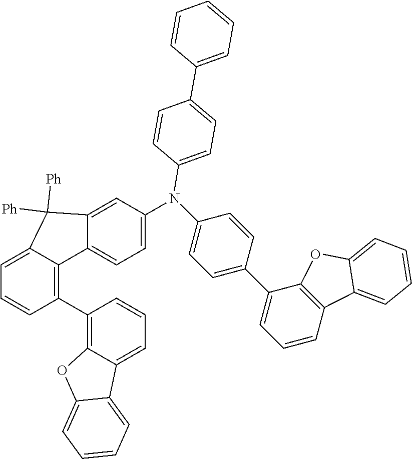 [SMILES: c1ccc(-c2ccc(N(c3ccc(-c4cccc5c4oc4ccccc45)cc3)c3ccc4c(c3)C(c3ccccc3)(c3ccccc3)c3cccc(-c5cccc6c5oc5ccccc56)c3-4)cc2)cc1] | (310) |
| 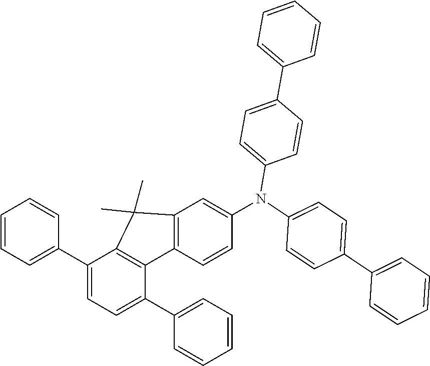 [SMILES: CC1(C)c2cc(N(c3ccc(-c4ccccc4)cc3)c3ccc(-c4ccccc4)cc3)ccc2-c2c(-c3ccccc3)ccc(-c3ccccc3)c21] | (311) |
| 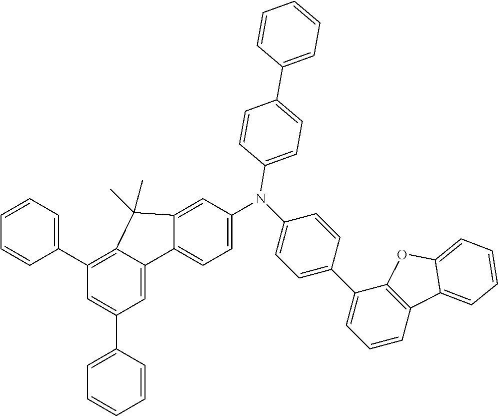 [SMILES: CC1(C)c2cc(N(c3ccc(-c4ccccc4)cc3)c3ccc(-c4cccc5c4oc4ccccc45)cc3)ccc2-c2cc(-c3ccccc3)cc(-c3ccccc3)c21] | (312) |
| 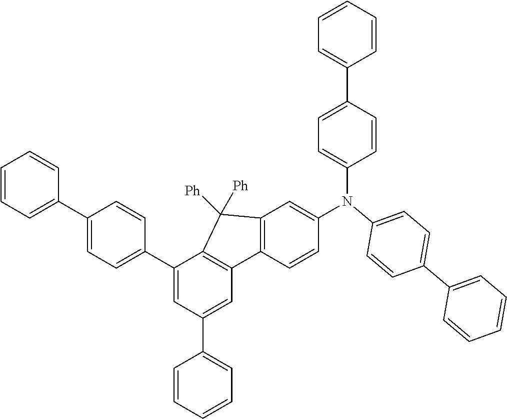 [SMILES: c1ccc(-c2ccc(-c3cc(-c4ccccc4)cc4c3C(c3ccccc3)(c3ccccc3)c3cc(N(c5ccc(-c6ccccc6)cc5)c5ccc(-c6ccccc6)cc5)ccc3-4)cc2)cc1] | (313) |
| 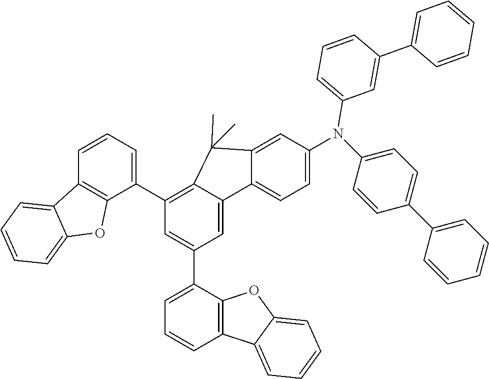 [SMILES: CC1(C)c2cc(N(c3ccc(-c4ccccc4)cc3)c3cccc(-c4ccccc4)c3)ccc2-c2cc(-c3cccc4c3oc3ccccc34)cc(-c3cccc4c3oc3ccccc34)c21] | (314) |
| 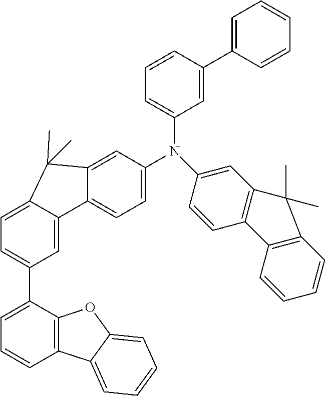 [SMILES: CC1(C)c2ccccc2-c2ccc(N(c3cccc(-c4ccccc4)c3)c3ccc4c(c3)C(C)(C)c3ccc(-c5cccc6c5oc5ccccc56)cc3-4)cc21] | (315) |
| 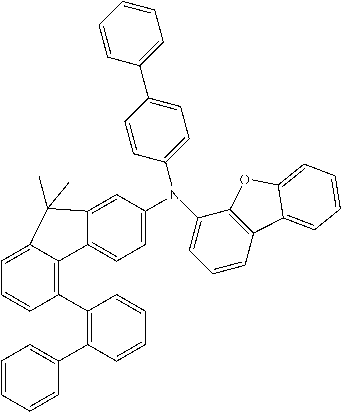 [SMILES: CC1(C)c2cc(N(c3ccc(-c4ccccc4)cc3)c3cccc4c3oc3ccccc34)ccc2-c2c(-c3ccccc3-c3ccccc3)cccc21] | (316) |
| 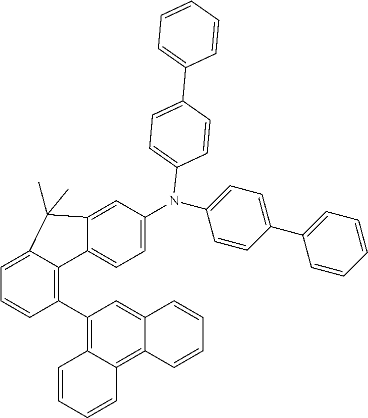 [SMILES: CC1(C)c2cc(N(c3ccc(-c4ccccc4)cc3)c3ccc(-c4ccccc4)cc3)ccc2-c2c(-c3cc4ccccc4c4ccccc34)cccc21] | (317) |
| 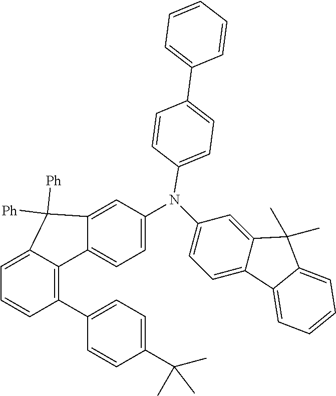 [SMILES: CC(C)(C)c1ccc(-c2cccc3c2-c2ccc(N(c4ccc(-c5ccccc5)cc4)c4ccc5c(c4)C(C)(C)c4ccccc4-5)cc2C3(c2ccccc2)c2ccccc2)cc1] | (318) |
| 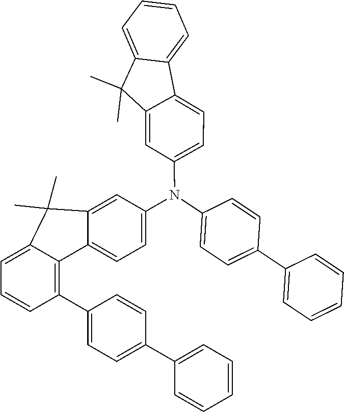 [SMILES: CC1(C)c2ccccc2-c2ccc(N(c3ccc(-c4ccccc4)cc3)c3ccc4c(c3)C(C)(C)c3cccc(-c5ccc(-c6ccccc6)cc5)c3-4)cc21] | (319) |
| 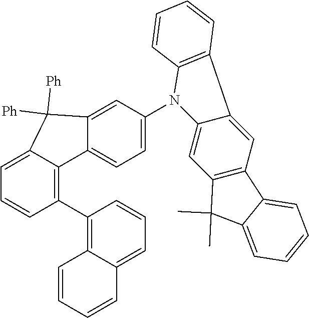 [SMILES: CC1(C)c2ccccc2-c2cc3c4ccccc4n(-c4ccc5c(c4)C(c4ccccc4)(c4ccccc4)c4cccc(-c6cccc7ccccc67)c4-5)c3cc21] | (320) |
| 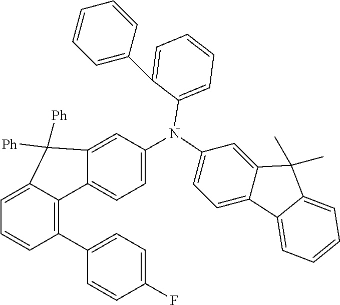 [SMILES: CC1(C)c2ccccc2-c2ccc(N(c3ccc4c(c3)C(c3ccccc3)(c3ccccc3)c3cccc(-c5ccc(F)cc5)c3-4)c3ccccc3-c3ccccc3)cc21] | (321) |
| 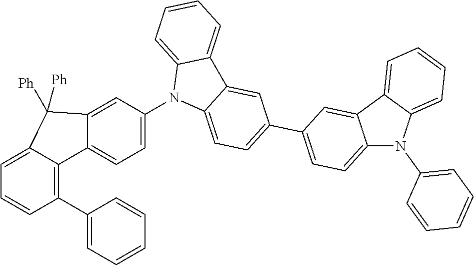 [SMILES: c1ccc(-c2cccc3c2-c2ccc(-n4c5ccccc5c5cc(-c6ccc7c(c6)c6ccccc6n7-c6ccccc6)ccc54)cc2C3(c2ccccc2)c2ccccc2)cc1] | (322) |
| 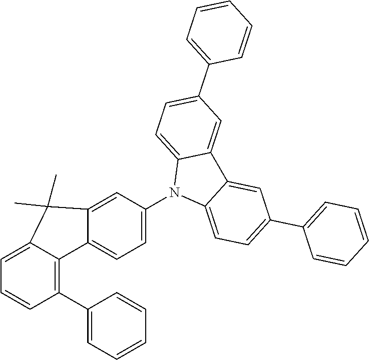 [SMILES: CC1(C)c2cc(-n3c4ccc(-c5ccccc5)cc4c4cc(-c5ccccc5)ccc43)ccc2-c2c(-c3ccccc3)cccc21] | (323) |
| 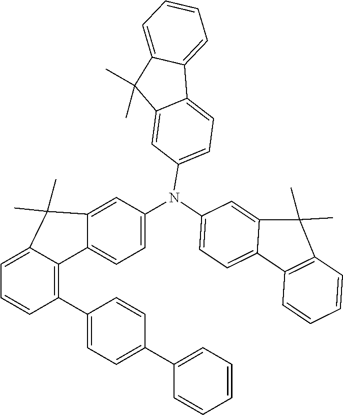 [SMILES: CC1(C)c2ccccc2-c2ccc(N(c3ccc4c(c3)C(C)(C)c3ccccc3-4)c3ccc4c(c3)C(C)(C)c3cccc(-c5ccc(-c6ccccc6)cc5)c3-4)cc21] | (324) |
| 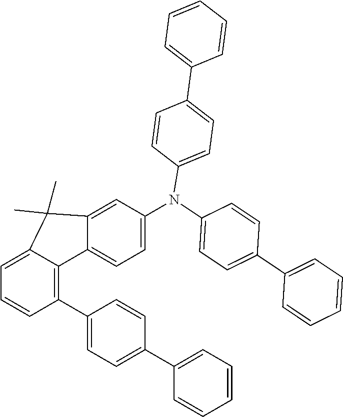 [SMILES: CC1(C)c2cc(N(c3ccc(-c4ccccc4)cc3)c3ccc(-c4ccccc4)cc3)ccc2-c2c(-c3ccc(-c4ccccc4)cc3)cccc21] | (325) |
| 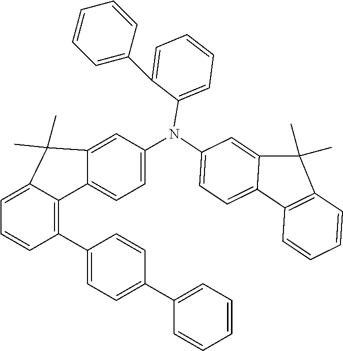 [SMILES: CC1(C)c2ccccc2-c2ccc(N(c3ccc4c(c3)C(C)(C)c3cccc(-c5ccc(-c6ccccc6)cc5)c3-4)c3ccccc3-c3ccccc3)cc21] | (326) |
| 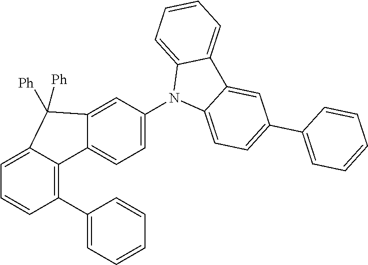 [SMILES: c1ccc(-c2ccc3c(c2)c2ccccc2n3-c2ccc3c(c2)C(c2ccccc2)(c2ccccc2)c2cccc(-c4ccccc4)c2-3)cc1] | (327) |
| 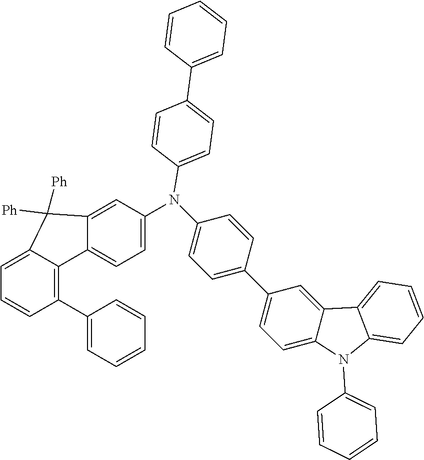 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3cccc(-c5ccccc5)c3-4)cc2)cc1] | (328) |
| 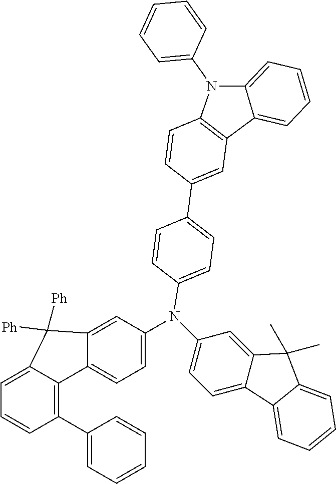 [SMILES: CC1(C)c2ccccc2-c2ccc(N(c3ccc(-c4ccc5c(c4)c4ccccc4n5-c4ccccc4)cc3)c3ccc4c(c3)C(c3ccccc3)(c3ccccc3)c3cccc(-c5ccccc5)c3-4)cc21] | (329) |
| 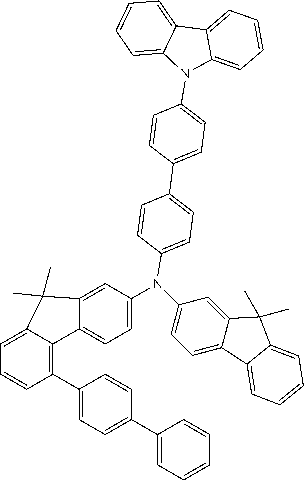 [SMILES: CC1(C)c2ccccc2-c2ccc(N(c3ccc(-c4ccc(-n5c6ccccc6c6ccccc65)cc4)cc3)c3ccc4c(c3)C(C)(C)c3cccc(-c5ccc(-c6ccccc6)cc5)c3-4)cc21] | (330) |
| 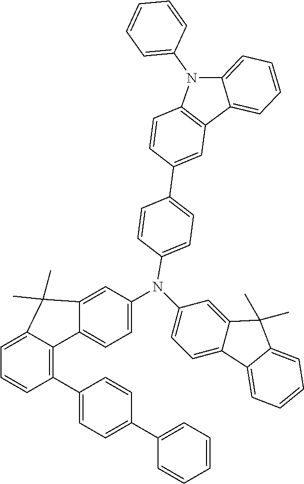 [SMILES: CC1(C)c2ccccc2-c2ccc(N(c3ccc(-c4ccc5c(c4)c4ccccc4n5-c4ccccc4)cc3)c3ccc4c(c3)C(C)(C)c3cccc(-c5ccc(-c6ccccc6)cc5)c3-4)cc21] | (331) |
| 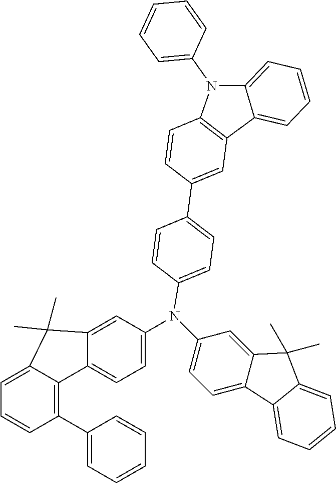 [SMILES: CC1(C)c2ccccc2-c2ccc(N(c3ccc(-c4ccc5c(c4)c4ccccc4n5-c4ccccc4)cc3)c3ccc4c(c3)C(C)(C)c3cccc(-c5ccccc5)c3-4)cc21] | (332) |
| 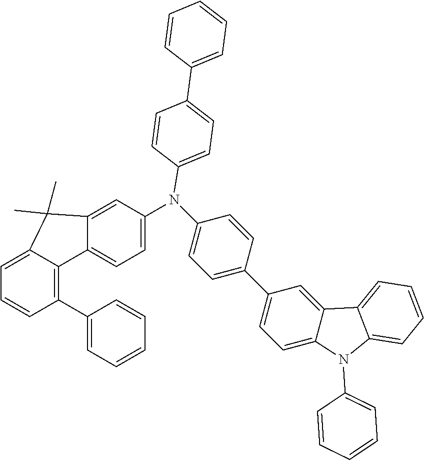 [SMILES: CC1(C)c2cc(N(c3ccc(-c4ccccc4)cc3)c3ccc(-c4ccc5c(c4)c4ccccc4n5-c4ccccc4)cc3)ccc2-c2c(-c3ccccc3)cccc21] | (333) |
| 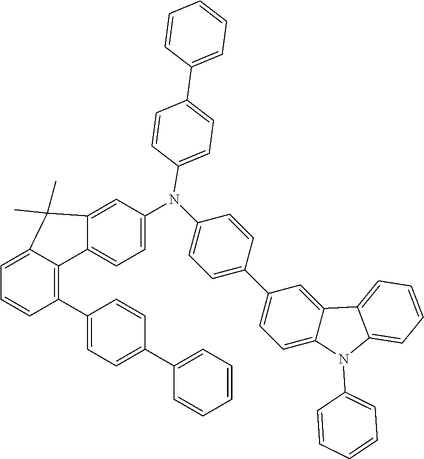 [SMILES: CC1(C)c2cc(N(c3ccc(-c4ccccc4)cc3)c3ccc(-c4ccc5c(c4)c4ccccc4n5-c4ccccc4)cc3)ccc2-c2c(-c3ccc(-c4ccccc4)cc3)cccc21] | (334) |
| 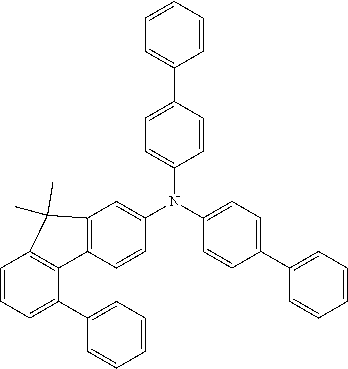 [SMILES: CC1(C)c2cc(N(c3ccc(-c4ccccc4)cc3)c3ccc(-c4ccccc4)cc3)ccc2-c2c(-c3ccccc3)cccc21] | (335) |
| 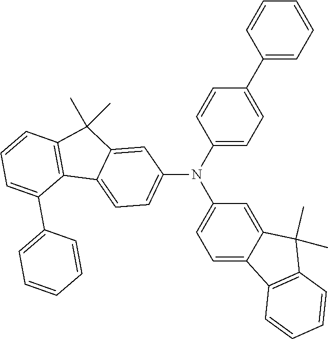 [SMILES: CC1(C)c2ccccc2-c2ccc(N(c3ccc(-c4ccccc4)cc3)c3ccc4c(c3)C(C)(C)c3cccc(-c5ccccc5)c3-4)cc21] | (336) |
| 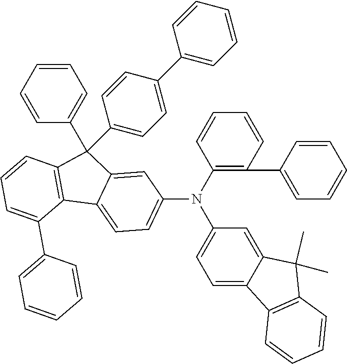 [SMILES: CC1(C)c2ccccc2-c2ccc(N(c3ccc4c(c3)C(c3ccccc3)(c3ccc(-c5ccccc5)cc3)c3cccc(-c5ccccc5)c3-4)c3ccccc3-c3ccccc3)cc21] | (337) |
| 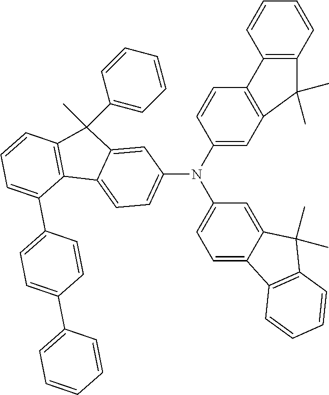 [SMILES: CC1(C)c2ccccc2-c2ccc(N(c3ccc4c(c3)C(C)(C)c3ccccc3-4)c3ccc4c(c3)C(C)(c3ccccc3)c3cccc(-c5ccc(-c6ccccc6)cc5)c3-4)cc21] | (338) |
| 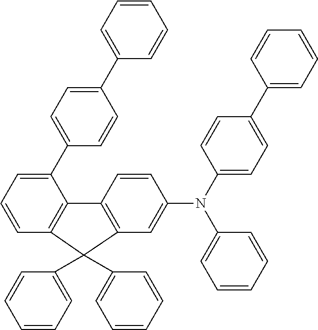 [SMILES: c1ccc(-c2ccc(-c3cccc4c3-c3ccc(N(c5ccccc5)c5ccc(-c6ccccc6)cc5)cc3C4(c3ccccc3)c3ccccc3)cc2)cc1] | (339) |
| 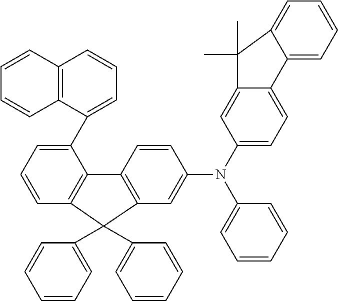 [SMILES: CC1(C)c2ccccc2-c2ccc(N(c3ccccc3)c3ccc4c(c3)C(c3ccccc3)(c3ccccc3)c3cccc(-c5cccc6ccccc56)c3-4)cc21] | (340) |
| 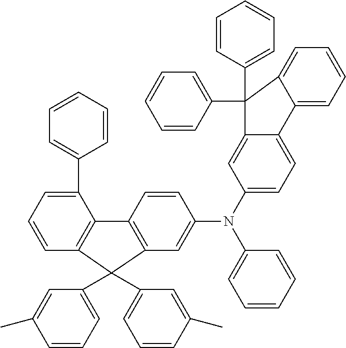 [SMILES: Cc1cccc(C2(c3cccc(C)c3)c3cc(N(c4ccccc4)c4ccc5c(c4)C(c4ccccc4)(c4ccccc4)c4ccccc4-5)ccc3-c3c(-c4ccccc4)cccc32)c1] | (341) |
| 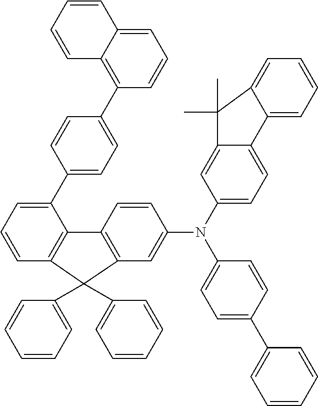 [SMILES: CC1(C)c2ccccc2-c2ccc(N(c3ccc(-c4ccccc4)cc3)c3ccc4c(c3)C(c3ccccc3)(c3ccccc3)c3cccc(-c5ccc(-c6cccc7ccccc67)cc5)c3-4)cc21] | (342) |
| 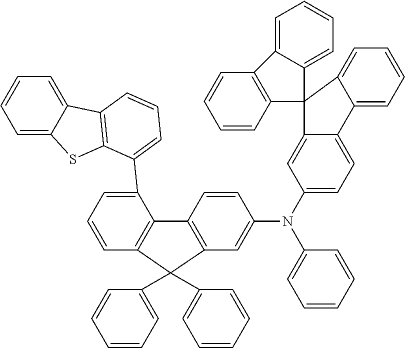 [SMILES: c1ccc(N(c2ccc3c(c2)C(c2ccccc2)(c2ccccc2)c2cccc(-c4cccc5c4sc4ccccc45)c2-3)c2ccc3c(c2)C2(c4ccccc4-c4ccccc42)c2ccccc2-3)cc1] | (343) |
| 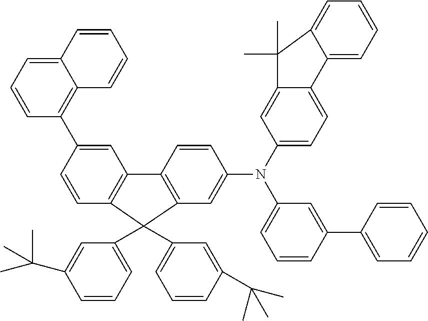 [SMILES: CC(C)(C)c1cccc(C2(c3cccc(C(C)(C)C)c3)c3ccc(-c4cccc5ccccc45)cc3-c3ccc(N(c4cccc(-c5ccccc5)c4)c4ccc5c(c4)C(C)(C)c4ccccc4-5)cc32)c1] | (344) |
| 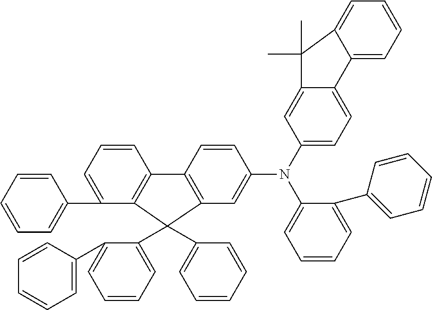 [SMILES: CC1(C)c2ccccc2-c2ccc(N(c3ccc4c(c3)C(c3ccccc3)(c3ccccc3-c3ccccc3)c3c(-c5ccccc5)cccc3-4)c3ccccc3-c3ccccc3)cc21] | (345) |
| 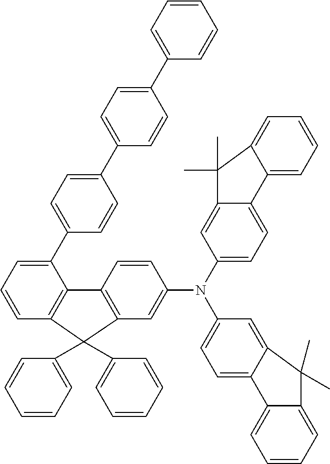 [SMILES: CC1(C)c2ccccc2-c2ccc(N(c3ccc4c(c3)C(C)(C)c3ccccc3-4)c3ccc4c(c3)C(c3ccccc3)(c3ccccc3)c3cccc(-c5ccc(-c6ccc(-c7ccccc7)cc6)cc5)c3-4)cc21] | (346) |
| 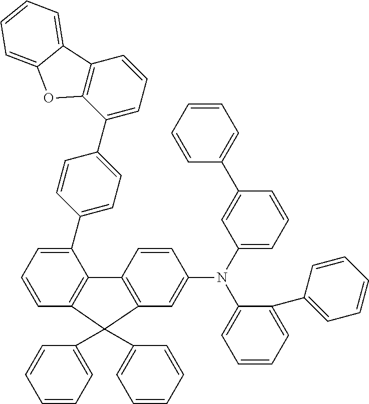 [SMILES: c1ccc(-c2cccc(N(c3ccc4c(c3)C(c3ccccc3)(c3ccccc3)c3cccc(-c5ccc(-c6cccc7c6oc6ccccc67)cc5)c3-4)c3ccccc3-c3ccccc3)c2)cc1] | (347) |
| 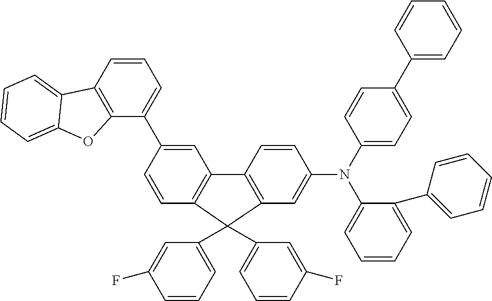 [SMILES: Fc1cccc(C2(c3cccc(F)c3)c3ccc(-c4cccc5c4oc4ccccc45)cc3-c3ccc(N(c4ccc(-c5ccccc5)cc4)c4ccccc4-c4ccccc4)cc32)c1] | (348) |
| 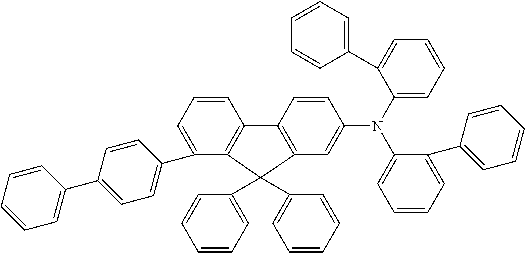 [SMILES: c1ccc(-c2ccc(-c3cccc4c3C(c3ccccc3)(c3ccccc3)c3cc(N(c5ccccc5-c5ccccc5)c5ccccc5-c5ccccc5)ccc3-4)cc2)cc1] | (349) |
| 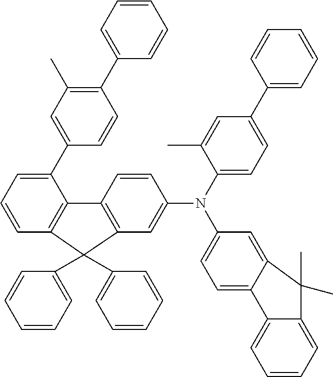 [SMILES: Cc1cc(-c2cccc3c2-c2ccc(N(c4ccc5c(c4)C(C)(C)c4ccccc4-5)c4ccc(-c5ccccc5)cc4C)cc2C3(c2ccccc2)c2ccccc2)ccc1-c1ccccc1] | (350) |
| 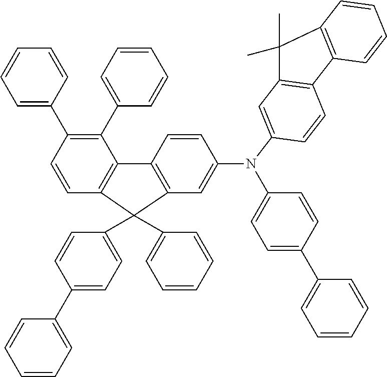 [SMILES: CC1(C)c2ccccc2-c2ccc(N(c3ccc(-c4ccccc4)cc3)c3ccc4c(c3)C(c3ccccc3)(c3ccc(-c5ccccc5)cc3)c3ccc(-c5ccccc5)c(-c5ccccc5)c3-4)cc21] | (351) |
| 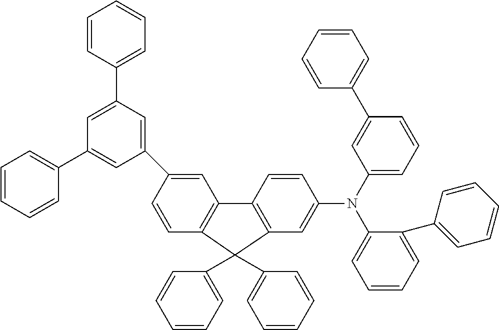 [SMILES: c1ccc(-c2cc(-c3ccccc3)cc(-c3ccc4c(c3)-c3ccc(N(c5cccc(-c6ccccc6)c5)c5ccccc5-c5ccccc5)cc3C4(c3ccccc3)c3ccccc3)c2)cc1] | (352) |
| 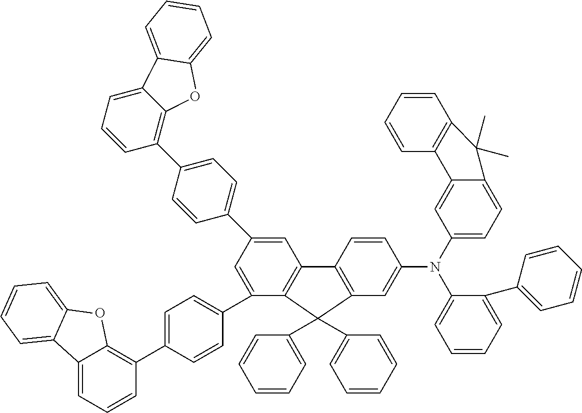 [SMILES: CC1(C)c2ccccc2-c2cc(N(c3ccc4c(c3)C(c3ccccc3)(c3ccccc3)c3c(-c5ccc(-c6cccc7c6oc6ccccc67)cc5)cc(-c5ccc(-c6cccc7c6oc6ccccc67)cc5)cc3-4)c3ccccc3-c3ccccc3)ccc21] | (353) |
| 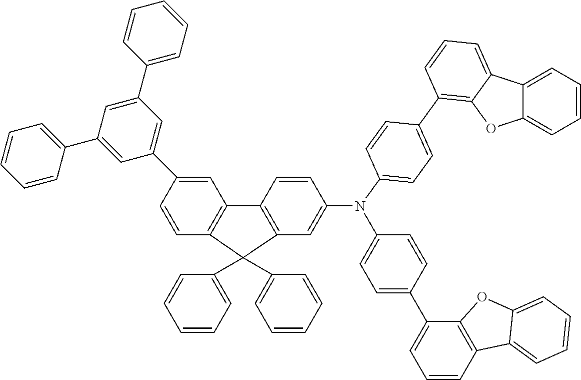 [SMILES: c1ccc(-c2cc(-c3ccccc3)cc(-c3ccc4c(c3)-c3ccc(N(c5ccc(-c6cccc7c6oc6ccccc67)cc5)c5ccc(-c6cccc7c6oc6ccccc67)cc5)cc3C4(c3ccccc3)c3ccccc3)c2)cc1] | (354) |
| 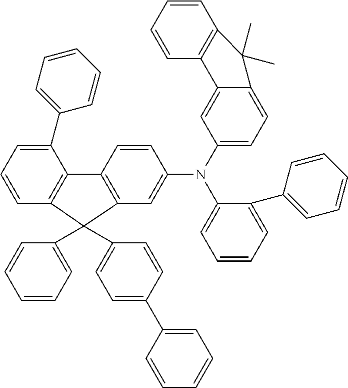 [SMILES: CC1(C)c2ccccc2-c2cc(N(c3ccc4c(c3)C(c3ccccc3)(c3ccc(-c5ccccc5)cc3)c3cccc(-c5ccccc5)c3-4)c3ccccc3-c3ccccc3)ccc21] | (355) |
| 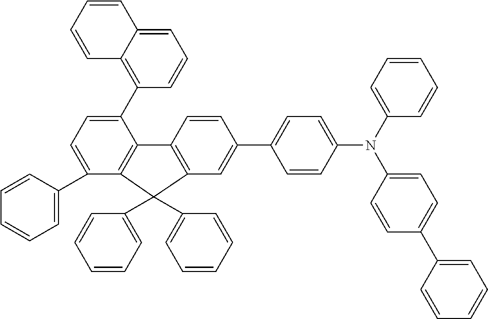 [SMILES: c1ccc(-c2ccc(N(c3ccccc3)c3ccc(-c4ccc5c(c4)C(c4ccccc4)(c4ccccc4)c4c(-c6ccccc6)ccc(-c6cccc7ccccc67)c4-5)cc3)cc2)cc1] | (356) |
| 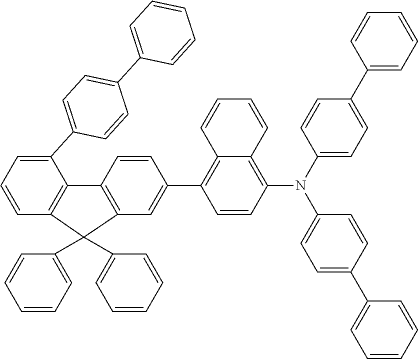 [SMILES: c1ccc(-c2ccc(-c3cccc4c3-c3ccc(-c5ccc(N(c6ccc(-c7ccccc7)cc6)c6ccc(-c7ccccc7)cc6)c6ccccc56)cc3C4(c3ccccc3)c3ccccc3)cc2)cc1] | (357) |
| 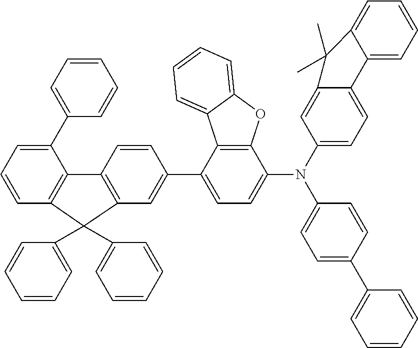 [SMILES: CC1(C)c2ccccc2-c2ccc(N(c3ccc(-c4ccccc4)cc3)c3ccc(-c4ccc5c(c4)C(c4ccccc4)(c4ccccc4)c4cccc(-c6ccccc6)c4-5)c4c3oc3ccccc34)cc21] | (358) |
| 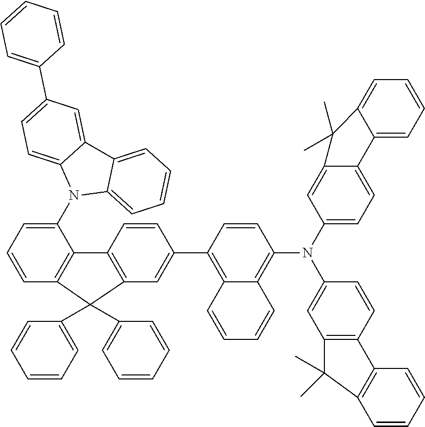 [SMILES: CC1(C)c2ccccc2-c2ccc(N(c3ccc4c(c3)C(C)(C)c3ccccc3-4)c3ccc(-c4ccc5c(c4)C(c4ccccc4)(c4ccccc4)c4cccc(-n6c7ccccc7c7cc(-c8ccccc8)ccc76)c4-5)c4ccccc34)cc21] | (359) |
| 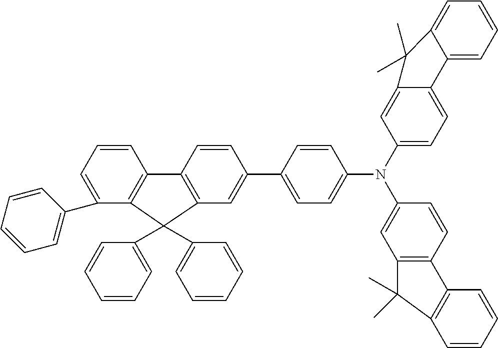 [SMILES: CC1(C)c2ccccc2-c2ccc(N(c3ccc(-c4ccc5c(c4)C(c4ccccc4)(c4ccccc4)c4c(-c6ccccc6)cccc4-5)cc3)c3ccc4c(c3)C(C)(C)c3ccccc3-4)cc21] | (360) |
| 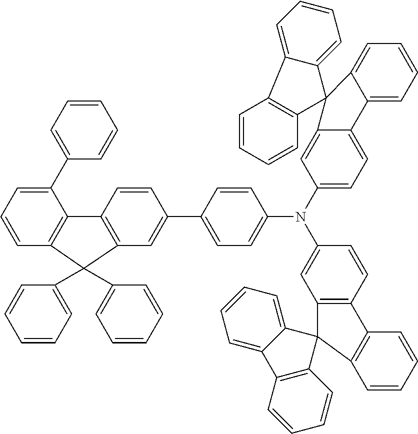 [SMILES: c1ccc(-c2cccc3c2-c2ccc(-c4ccc(N(c5ccc6c(c5)C5(c7ccccc7-c7ccccc75)c5ccccc5-6)c5ccc6c(c5)C5(c7ccccc7-c7ccccc75)c5ccccc5-6)cc4)cc2C3(c2ccccc2)c2ccccc2)cc1] | (361) |
| 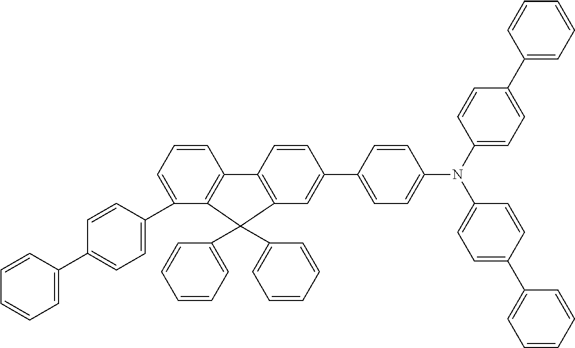 [SMILES: c1ccc(-c2ccc(-c3cccc4c3C(c3ccccc3)(c3ccccc3)c3cc(-c5ccc(N(c6ccc(-c7ccccc7)cc6)c6ccc(-c7ccccc7)cc6)cc5)ccc3-4)cc2)cc1] | (362) |
| 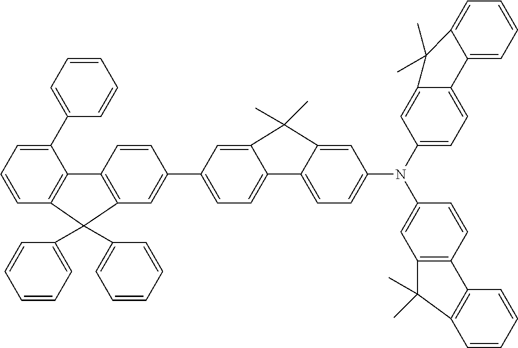 [SMILES: CC1(C)c2ccccc2-c2ccc(N(c3ccc4c(c3)C(C)(C)c3ccccc3-4)c3ccc4c(c3)C(C)(C)c3cc(-c5ccc6c(c5)C(c5ccccc5)(c5ccccc5)c5cccc(-c7ccccc7)c5-6)ccc3-4)cc21] | (363) |
| 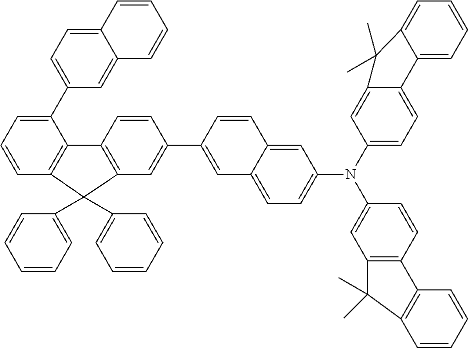 [SMILES: CC1(C)c2ccccc2-c2ccc(N(c3ccc4c(c3)C(C)(C)c3ccccc3-4)c3ccc4cc(-c5ccc6c(c5)C(c5ccccc5)(c5ccccc5)c5cccc(-c7ccc8ccccc8c7)c5-6)ccc4c3)cc21] | (364) |
| 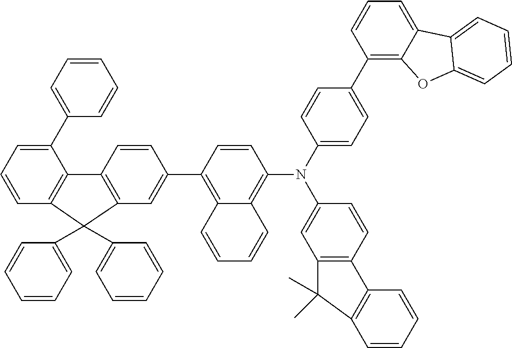 [SMILES: CC1(C)c2ccccc2-c2ccc(N(c3ccc(-c4cccc5c4oc4ccccc45)cc3)c3ccc(-c4ccc5c(c4)C(c4ccccc4)(c4ccccc4)c4cccc(-c6ccccc6)c4-5)c4ccccc34)cc21] | (365) |
| 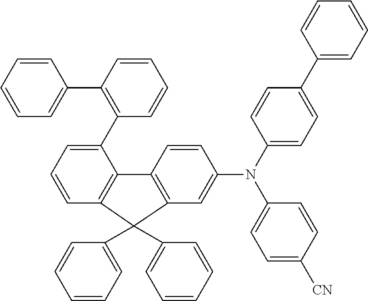 [SMILES: N#Cc1ccc(N(c2ccc(-c3ccccc3)cc2)c2ccc3c(c2)C(c2ccccc2)(c2ccccc2)c2cccc(-c4ccccc4-c4ccccc4)c2-3)cc1] | (366) |
| 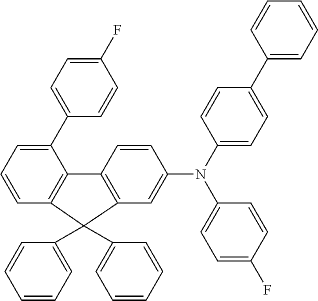 [SMILES: Fc1ccc(-c2cccc3c2-c2ccc(N(c4ccc(F)cc4)c4ccc(-c5ccccc5)cc4)cc2C3(c2ccccc2)c2ccccc2)cc1] | (367) |
| 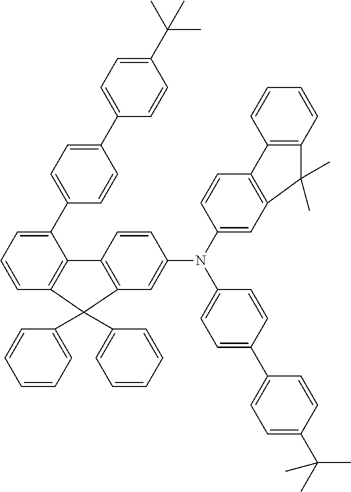 [SMILES: CC(C)(C)c1ccc(-c2ccc(-c3cccc4c3-c3ccc(N(c5ccc(-c6ccc(C(C)(C)C)cc6)cc5)c5ccc6c(c5)C(C)(C)c5ccccc5-6)cc3C4(c3ccccc3)c3ccccc3)cc2)cc1] | (368) |
| 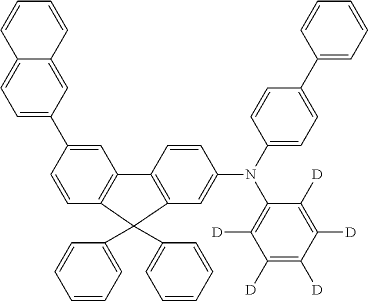 [SMILES: [2H]c1c([2H])c([2H])c(N(c2ccc(-c3ccccc3)cc2)c2ccc3c(c2)C(c2ccccc2)(c2ccccc2)c2ccc(-c4ccc5ccccc5c4)cc2-3)c([2H])c1[2H]] | (369) |
| 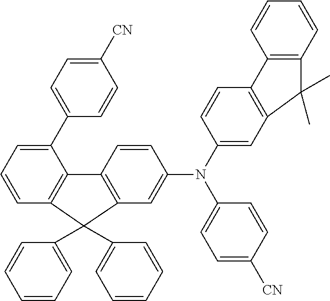 [SMILES: CC1(C)c2ccccc2-c2ccc(N(c3ccc(C#N)cc3)c3ccc4c(c3)C(c3ccccc3)(c3ccccc3)c3cccc(-c5ccc(C#N)cc5)c3-4)cc21] | (370) |
| 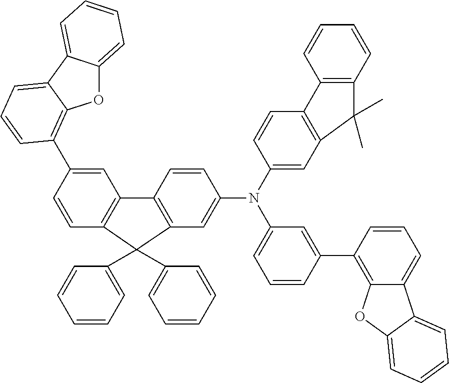 [SMILES: CC1(C)c2ccccc2-c2ccc(N(c3cccc(-c4cccc5c4oc4ccccc45)c3)c3ccc4c(c3)C(c3ccccc3)(c3ccccc3)c3ccc(-c5cccc6c5oc5ccccc56)cc3-4)cc21] | (371) |
| 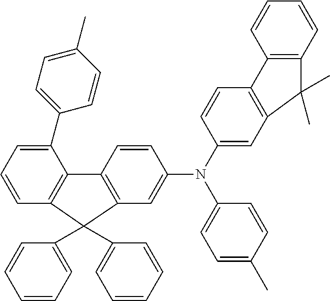 [SMILES: Cc1ccc(-c2cccc3c2-c2ccc(N(c4ccc(C)cc4)c4ccc5c(c4)C(C)(C)c4ccccc4-5)cc2C3(c2ccccc2)c2ccccc2)cc1] | (372) |
| 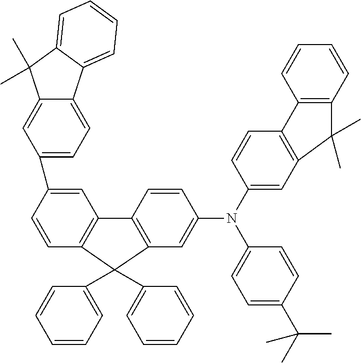 | (373) |
| 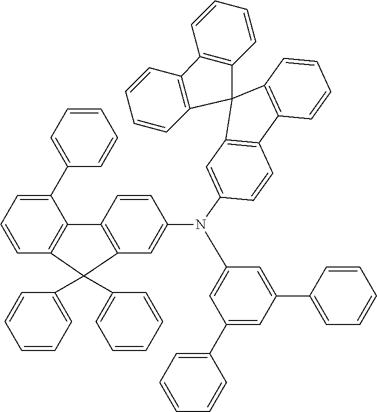 [SMILES: c1ccc(-c2cc(-c3ccccc3)cc(N(c3ccc4c(c3)C(c3ccccc3)(c3ccccc3)c3cccc(-c5ccccc5)c3-4)c3ccc4c(c3)C3(c5ccccc5-c5ccccc53)c3ccccc3-4)c2)cc1] | (374) |
| 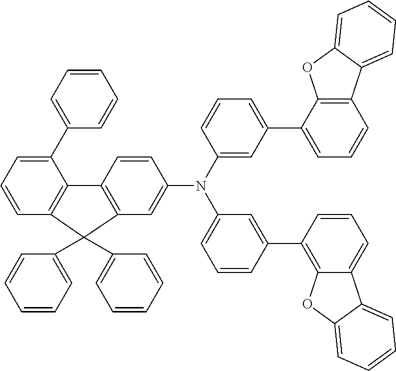 [SMILES: c1ccc(-c2cccc3c2-c2ccc(N(c4cccc(-c5cccc6c5oc5ccccc56)c4)c4cccc(-c5cccc6c5oc5ccccc56)c4)cc2C3(c2ccccc2)c2ccccc2)cc1] | (375) |
| 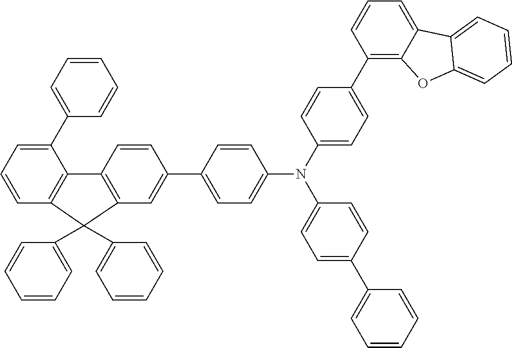 [SMILES: c1ccc(-c2ccc(N(c3ccc(-c4ccc5c(c4)C(c4ccccc4)(c4ccccc4)c4cccc(-c6ccccc6)c4-5)cc3)c3ccc(-c4cccc5c4oc4ccccc45)cc3)cc2)cc1] | (376) |
| 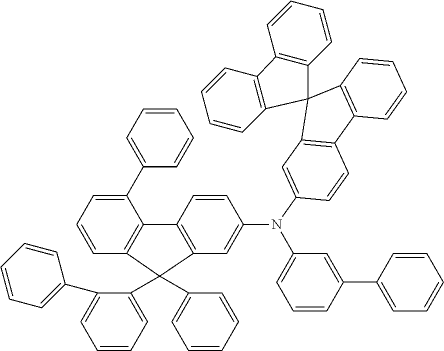 [SMILES: c1ccc(-c2cccc(N(c3ccc4c(c3)C(c3ccccc3)(c3ccccc3-c3ccccc3)c3cccc(-c5ccccc5)c3-4)c3ccc4c(c3)C3(c5ccccc5-c5ccccc53)c3ccccc3-4)c2)cc1] | (377) |
| 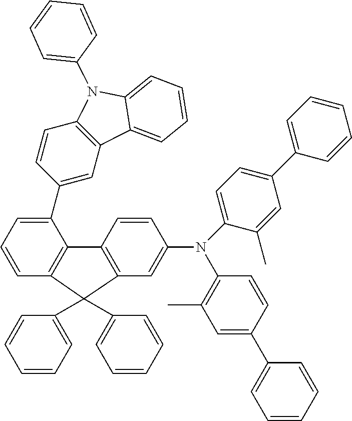 [SMILES: Cc1cc(-c2ccccc2)ccc1N(c1ccc2c(c1)C(c1ccccc1)(c1ccccc1)c1cccc(-c3ccc4c(c3)c3ccccc3n4-c3ccccc3)c1-2)c1ccc(-c2ccccc2)cc1C] | (378) |
| 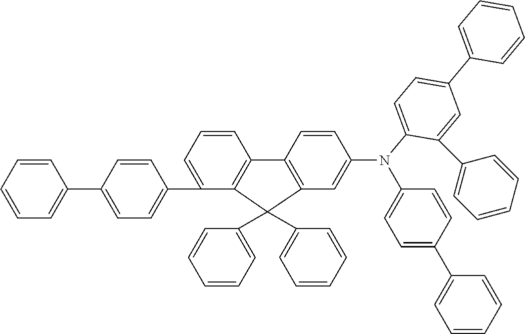 [SMILES: c1ccc(-c2ccc(-c3cccc4c3C(c3ccccc3)(c3ccccc3)c3cc(N(c5ccc(-c6ccccc6)cc5)c5ccc(-c6ccccc6)cc5-c5ccccc5)ccc3-4)cc2)cc1] | (379) |
| 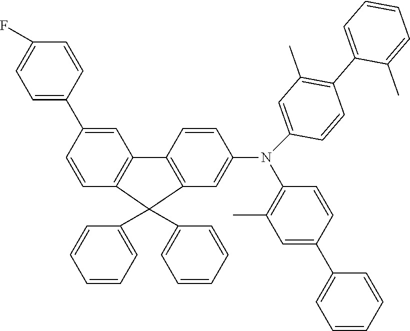 [SMILES: Cc1ccccc1-c1ccc(N(c2ccc3c(c2)C(c2ccccc2)(c2ccccc2)c2ccc(-c4ccc(F)cc4)cc2-3)c2ccc(-c3ccccc3)cc2C)cc1C] | (380) |
| 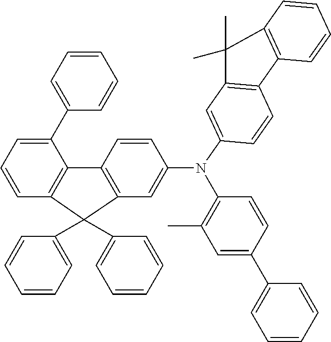 [SMILES: Cc1cc(-c2ccccc2)ccc1N(c1ccc2c(c1)C(C)(C)c1ccccc1-2)c1ccc2c(c1)C(c1ccccc1)(c1ccccc1)c1cccc(-c3ccccc3)c1-2] | (381) |
| 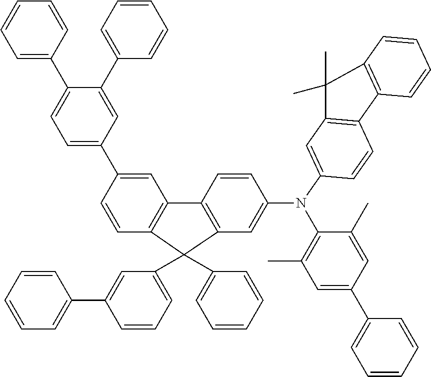 [SMILES: Cc1cc(-c2ccccc2)cc(C)c1N(c1ccc2c(c1)C(C)(C)c1ccccc1-2)c1ccc2c(c1)C(c1ccccc1)(c1cccc(-c3ccccc3)c1)c1ccc(-c3ccc(-c4ccccc4)c(-c4ccccc4)c3)cc1-2] | (382) |
| 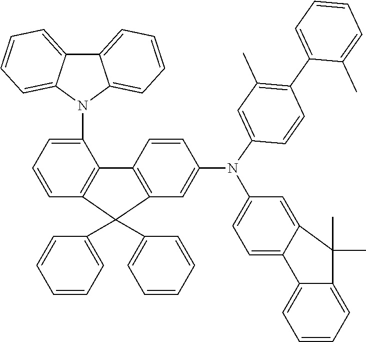 [SMILES: Cc1ccccc1-c1ccc(N(c2ccc3c(c2)C(C)(C)c2ccccc2-3)c2ccc3c(c2)C(c2ccccc2)(c2ccccc2)c2cccc(-n4c5ccccc5c5ccccc54)c2-3)cc1C] | (383) |
| 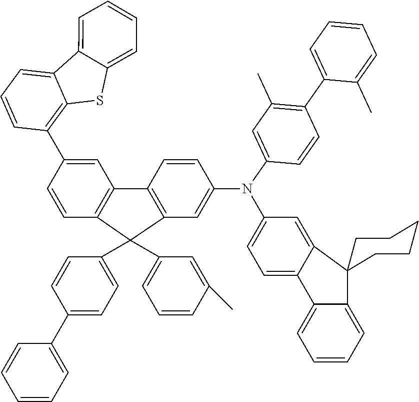 [SMILES: Cc1cccc(C2(c3ccc(-c4ccccc4)cc3)c3ccc(-c4cccc5c4sc4ccccc45)cc3-c3ccc(N(c4ccc(-c5ccccc5C)c(C)c4)c4ccc5c(c4)C4(CCCCC4)c4ccccc4-5)cc32)c1] | (384) |
| 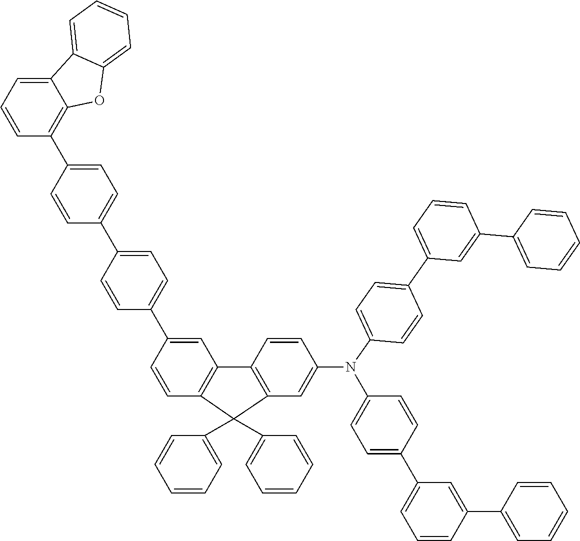 [SMILES: c1ccc(-c2cccc(-c3ccc(N(c4ccc(-c5cccc(-c6ccccc6)c5)cc4)c4ccc5c(c4)C(c4ccccc4)(c4ccccc4)c4ccc(-c6ccc(-c7ccc(-c8cccc9c8oc8ccccc89)cc7)cc6)cc4-5)cc3)c2)cc1] | (385) |
| 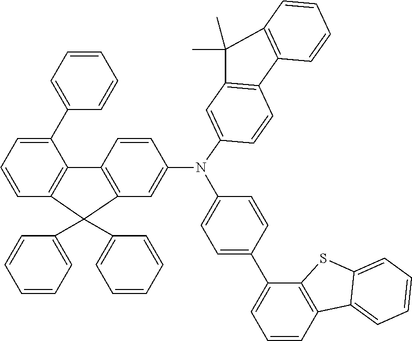 [SMILES: CC1(C)c2ccccc2-c2ccc(N(c3ccc(-c4cccc5c4sc4ccccc45)cc3)c3ccc4c(c3)C(c3ccccc3)(c3ccccc3)c3cccc(-c5ccccc5)c3-4)cc21] | (386) |
| 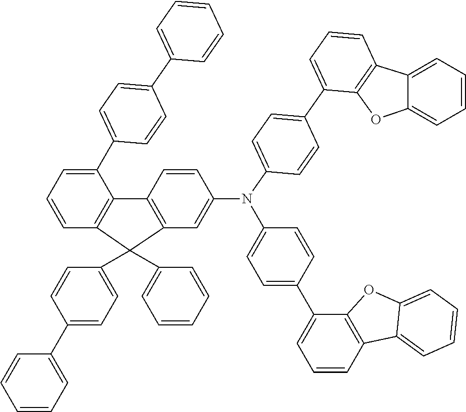 [SMILES: c1ccc(-c2ccc(-c3cccc4c3-c3ccc(N(c5ccc(-c6cccc7c6oc6ccccc67)cc5)c5ccc(-c6cccc7c6oc6ccccc67)cc5)cc3C4(c3ccccc3)c3ccc(-c4ccccc4)cc3)cc2)cc1] | (387) |
| 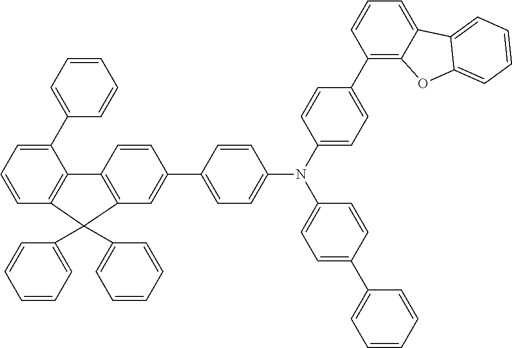 [SMILES: c1ccc(-c2ccc(N(c3ccc(-c4ccc5c(c4)C(c4ccccc4)(c4ccccc4)c4cccc(-c6ccccc6)c4-5)cc3)c3ccc(-c4cccc5c4oc4ccccc45)cc3)cc2)cc1] | (388) |
| 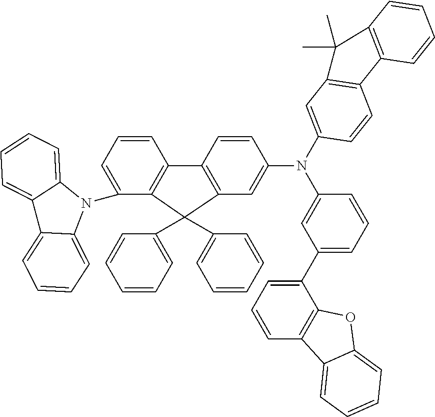 [SMILES: CC1(C)c2ccccc2-c2ccc(N(c3cccc(-c4cccc5c4oc4ccccc45)c3)c3ccc4c(c3)C(c3ccccc3)(c3ccccc3)c3c-4cccc3-n3c4ccccc4c4ccccc43)cc21] | (389) |
| 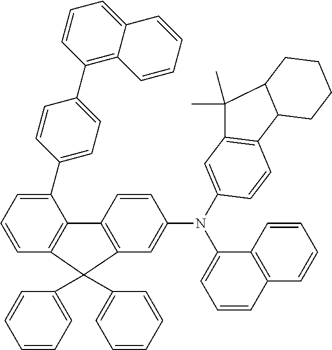 [SMILES: CC1(C)c2cc(N(c3ccc4c(c3)C(c3ccccc3)(c3ccccc3)c3cccc(-c5ccc(-c6cccc7ccccc67)cc5)c3-4)c3cccc4ccccc34)ccc2C2CCCCC21] | (390) |
| 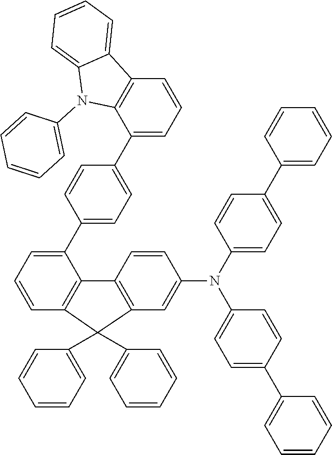 [SMILES: c1ccc(-c2ccc(N(c3ccc(-c4ccccc4)cc3)c3ccc4c(c3)C(c3ccccc3)(c3ccccc3)c3cccc(-c5ccc(-c6cccc7c8ccccc8n(-c8ccccc8)c67)cc5)c3-4)cc2)cc1] | (391) |
| 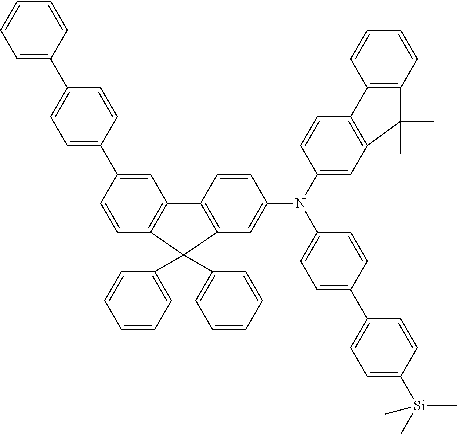 [SMILES: CC1(C)c2ccccc2-c2ccc(N(c3ccc(-c4ccc([Si](C)(C)C)cc4)cc3)c3ccc4c(c3)C(c3ccccc3)(c3ccccc3)c3ccc(-c5ccc(-c6ccccc6)cc5)cc3-4)cc21] | (392) |
| 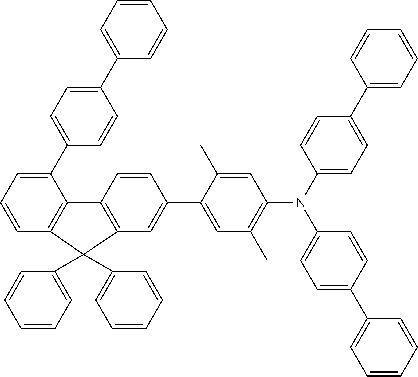 [SMILES: Cc1cc(N(c2ccc(-c3ccccc3)cc2)c2ccc(-c3ccccc3)cc2)c(C)cc1-c1ccc2c(c1)C(c1ccccc1)(c1ccccc1)c1cccc(-c3ccc(-c4ccccc4)cc3)c1-2] | (393) |
| 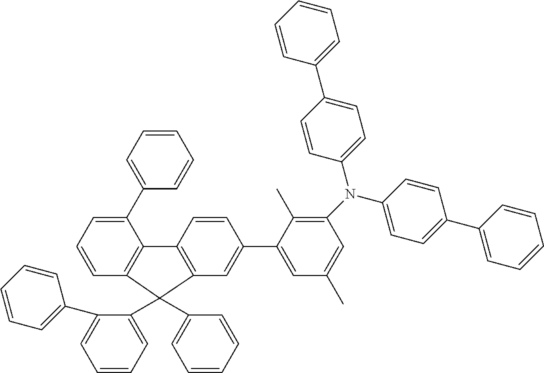 [SMILES: Cc1cc(-c2ccc3c(c2)C(c2ccccc2)(c2ccccc2-c2ccccc2)c2cccc(-c4ccccc4)c2-3)c(C)c(N(c2ccc(-c3ccccc3)cc2)c2ccc(-c3ccccc3)cc2)c1] | (394) |
| 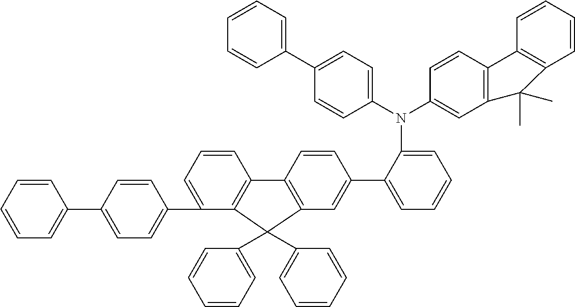 [SMILES: CC1(C)c2ccccc2-c2ccc(N(c3ccc(-c4ccccc4)cc3)c3ccccc3-c3ccc4c(c3)C(c3ccccc3)(c3ccccc3)c3c(-c5ccc(-c6ccccc6)cc5)cccc3-4)cc21] | (395) |
| 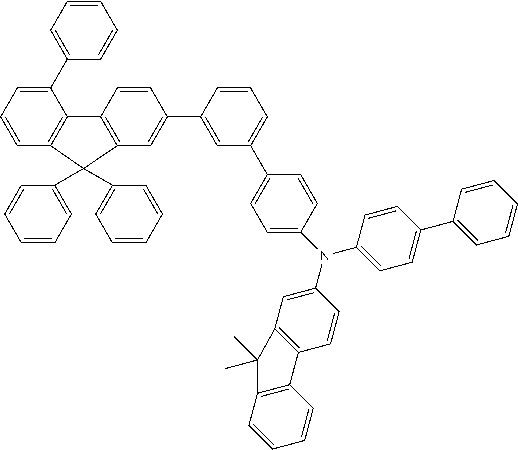 [SMILES: CC1(C)c2ccccc2-c2ccc(N(c3ccc(-c4ccccc4)cc3)c3ccc(-c4cccc(-c5ccc6c(c5)C(c5ccccc5)(c5ccccc5)c5cccc(-c7ccccc7)c5-6)c4)cc3)cc21] | (396) |
| 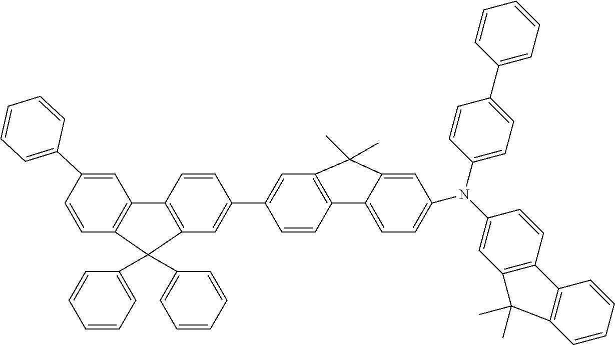 [SMILES: CC1(C)c2ccccc2-c2ccc(N(c3ccc(-c4ccccc4)cc3)c3ccc4c(c3)C(C)(C)c3cc(-c5ccc6c(c5)C(c5ccccc5)(c5ccccc5)c5ccc(-c7ccccc7)cc5-6)ccc3-4)cc21] | (397) |
| 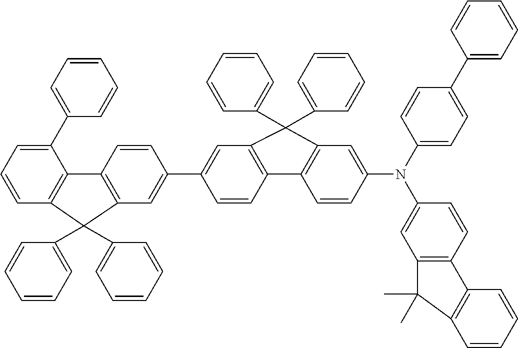 [SMILES: CC1(C)c2ccccc2-c2ccc(N(c3ccc(-c4ccccc4)cc3)c3ccc4c(c3)C(c3ccccc3)(c3ccccc3)c3cc(-c5ccc6c(c5)C(c5ccccc5)(c5ccccc5)c5cccc(-c7ccccc7)c5-6)ccc3-4)cc21] | (398) |
| 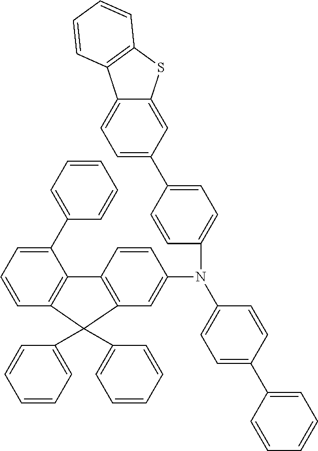 [SMILES: c1ccc(-c2ccc(N(c3ccc(-c4ccc5c(c4)sc4ccccc45)cc3)c3ccc4c(c3)C(c3ccccc3)(c3ccccc3)c3cccc(-c5ccccc5)c3-4)cc2)cc1] | (399) |
| 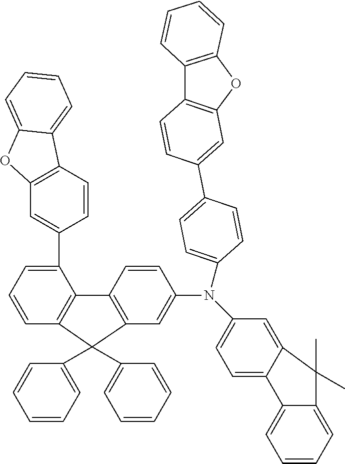 [SMILES: CC1(C)c2ccccc2-c2ccc(N(c3ccc(-c4ccc5c(c4)oc4ccccc45)cc3)c3ccc4c(c3)C(c3ccccc3)(c3ccccc3)c3cccc(-c5ccc6c(c5)oc5ccccc56)c3-4)cc21] | (400) |
| 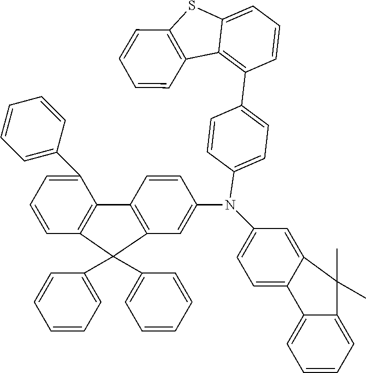 [SMILES: CC1(C)c2ccccc2-c2ccc(N(c3ccc(-c4cccc5sc6ccccc6c45)cc3)c3ccc4c(c3)C(c3ccccc3)(c3ccccc3)c3cccc(-c5ccccc5)c3-4)cc21] | (401) |
| 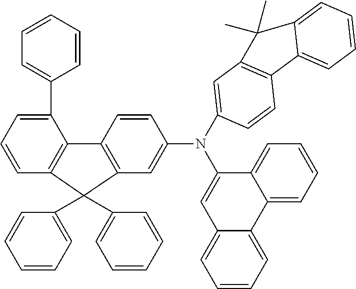 [SMILES: CC1(C)c2ccccc2-c2ccc(N(c3ccc4c(c3)C(c3ccccc3)(c3ccccc3)c3cccc(-c5ccccc5)c3-4)c3cc4ccccc4c4ccccc34)cc21] | (402) |
| 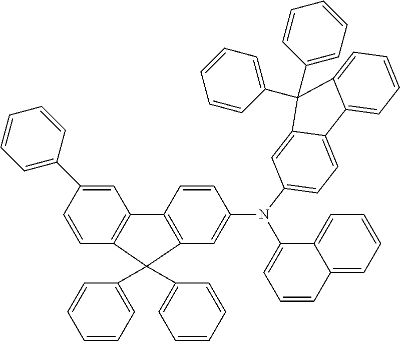 [SMILES: c1ccc(-c2ccc3c(c2)-c2ccc(N(c4ccc5c(c4)C(c4ccccc4)(c4ccccc4)c4ccccc4-5)c4cccc5ccccc45)cc2C3(c2ccccc2)c2ccccc2)cc1] | (403) |
| 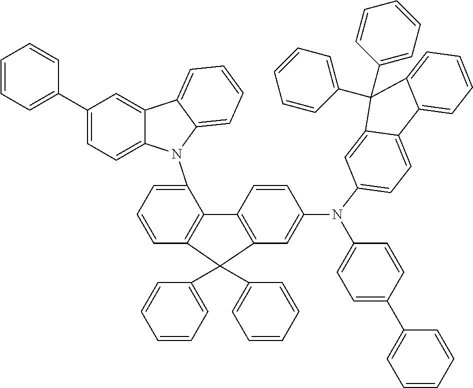 [SMILES: c1ccc(-c2ccc(N(c3ccc4c(c3)C(c3ccccc3)(c3ccccc3)c3ccccc3-4)c3ccc4c(c3)C(c3ccccc3)(c3ccccc3)c3cccc(-n5c6ccccc6c6cc(-c7ccccc7)ccc65)c3-4)cc2)cc1] | (404) |
| 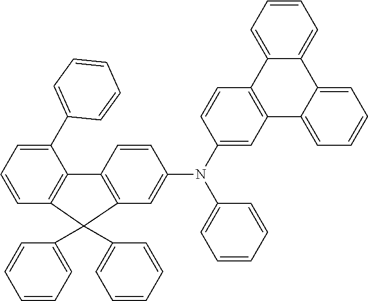 [SMILES: c1ccc(-c2cccc3c2-c2ccc(N(c4ccccc4)c4ccc5c6ccccc6c6ccccc6c5c4)cc2C3(c2ccccc2)c2ccccc2)cc1] | (405) |
| 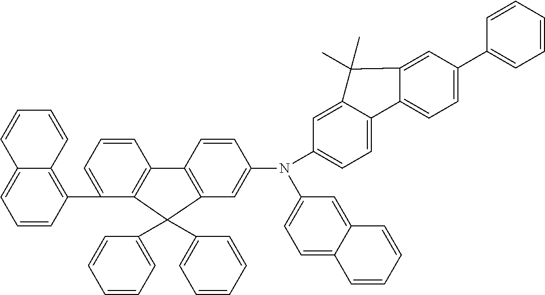 [SMILES: CC1(C)c2cc(-c3ccccc3)ccc2-c2ccc(N(c3ccc4c(c3)C(c3ccccc3)(c3ccccc3)c3c-4cccc3-c3cccc4ccccc34)c3ccc4ccccc4c3)cc21] | (406) |
| 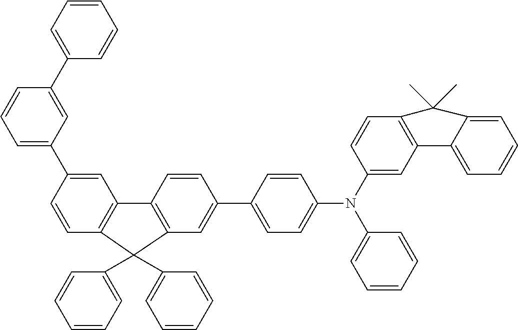 [SMILES: CC1(C)c2ccccc2-c2cc(N(c3ccccc3)c3ccc(-c4ccc5c(c4)C(c4ccccc4)(c4ccccc4)c4ccc(-c6cccc(-c7ccccc7)c6)cc4-5)cc3)ccc21] | (407) |
| 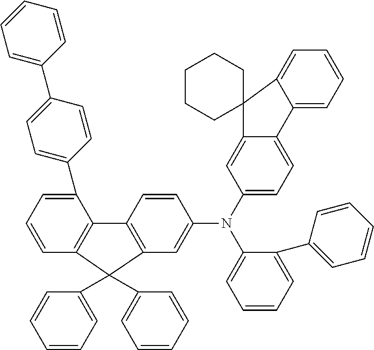 [SMILES: c1ccc(-c2ccc(-c3cccc4c3-c3ccc(N(c5ccc6c(c5)C5(CCCCC5)c5ccccc5-6)c5ccccc5-c5ccccc5)cc3C4(c3ccccc3)c3ccccc3)cc2)cc1] | (408) |
| 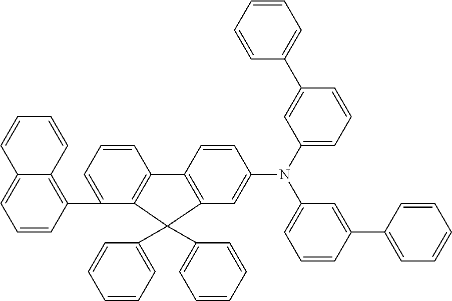 [SMILES: c1ccc(-c2cccc(N(c3cccc(-c4ccccc4)c3)c3ccc4c(c3)C(c3ccccc3)(c3ccccc3)c3c-4cccc3-c3cccc4ccccc34)c2)cc1] | (409) |
| 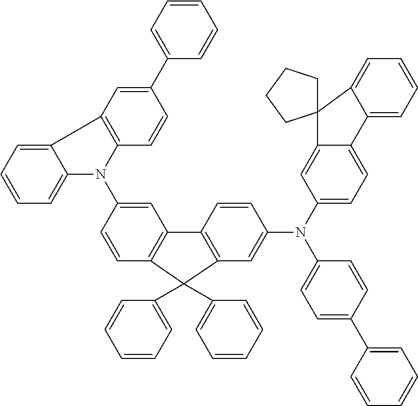 [SMILES: c1ccc(-c2ccc(N(c3ccc4c(c3)C3(CCCC3)c3ccccc3-4)c3ccc4c(c3)C(c3ccccc3)(c3ccccc3)c3ccc(-n5c6ccccc6c6cc(-c7ccccc7)ccc65)cc3-4)cc2)cc1] | (410) |
| 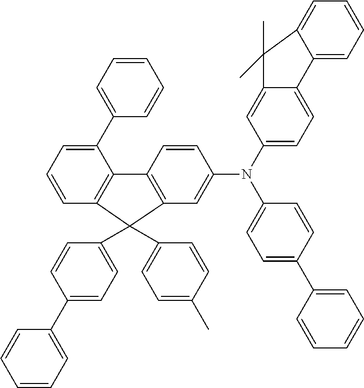 [SMILES: Cc1ccc(C2(c3ccc(-c4ccccc4)cc3)c3cc(N(c4ccc(-c5ccccc5)cc4)c4ccc5c(c4)C(C)(C)c4ccccc4-5)ccc3-c3c(-c4ccccc4)cccc32)cc1] | (411) |
| 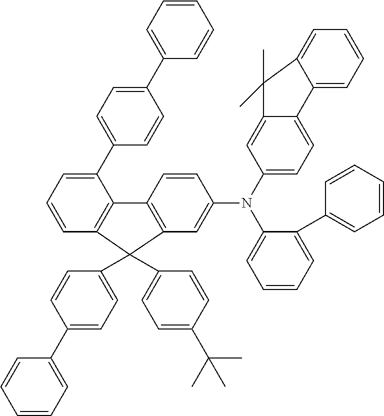 [SMILES: CC(C)(C)c1ccc(C2(c3ccc(-c4ccccc4)cc3)c3cc(N(c4ccc5c(c4)C(C)(C)c4ccccc4-5)c4ccccc4-c4ccccc4)ccc3-c3c(-c4ccc(-c5ccccc5)cc4)cccc32)cc1] | (412) |
| 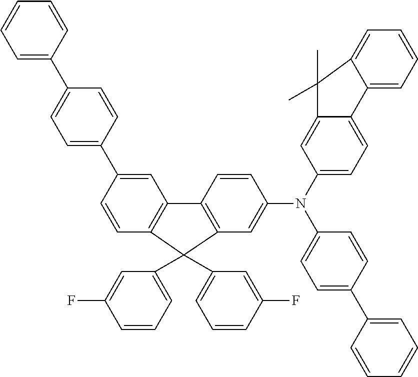 [SMILES: CC1(C)c2ccccc2-c2ccc(N(c3ccc(-c4ccccc4)cc3)c3ccc4c(c3)C(c3cccc(F)c3)(c3cccc(F)c3)c3ccc(-c5ccc(-c6ccccc6)cc5)cc3-4)cc21] | (413) |
| 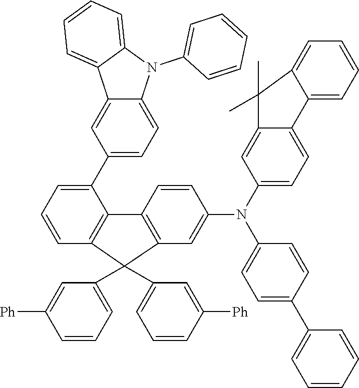 [SMILES: CC1(C)c2ccccc2-c2ccc(N(c3ccc(-c4ccccc4)cc3)c3ccc4c(c3)C(c3cccc(-c5ccccc5)c3)(c3cccc(-c5ccccc5)c3)c3cccc(-c5ccc6c(c5)c5ccccc5n6-c5ccccc5)c3-4)cc21] | (414) |
| 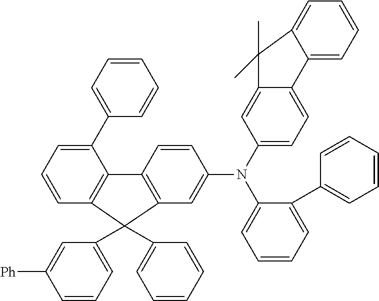 [SMILES: CC1(C)c2ccccc2-c2ccc(N(c3ccc4c(c3)C(c3ccccc3)(c3cccc(-c5ccccc5)c3)c3cccc(-c5ccccc5)c3-4)c3ccccc3-c3ccccc3)cc21] | (415) |
| 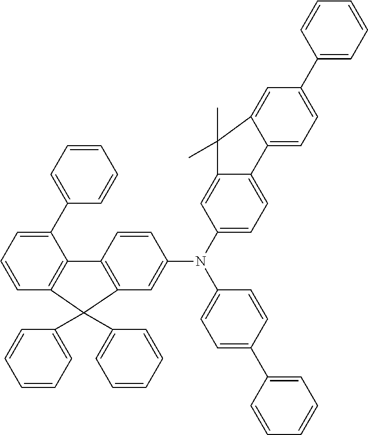 [SMILES: CC1(C)c2cc(-c3ccccc3)ccc2-c2ccc(N(c3ccc(-c4ccccc4)cc3)c3ccc4c(c3)C(c3ccccc3)(c3ccccc3)c3cccc(-c5ccccc5)c3-4)cc21] | (416) |
| 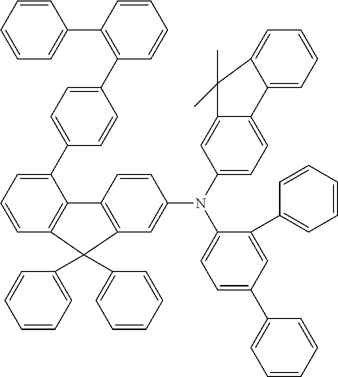 [SMILES: CC1(C)c2ccccc2-c2ccc(N(c3ccc4c(c3)C(c3ccccc3)(c3ccccc3)c3cccc(-c5ccc(-c6ccccc6-c6ccccc6)cc5)c3-4)c3ccc(-c4ccccc4)cc3-c3ccccc3)cc21] | (417) |
| 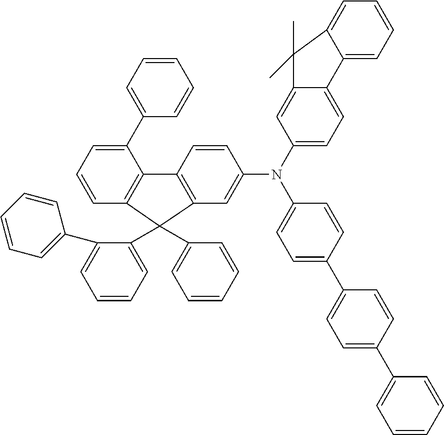 [SMILES: CC1(C)c2ccccc2-c2ccc(N(c3ccc(-c4ccc(-c5ccccc5)cc4)cc3)c3ccc4c(c3)C(c3ccccc3)(c3ccccc3-c3ccccc3)c3cccc(-c5ccccc5)c3-4)cc21] | (418) |
| 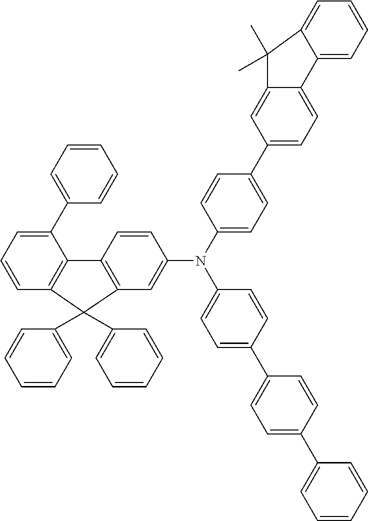 [SMILES: CC1(C)c2ccccc2-c2ccc(-c3ccc(N(c4ccc(-c5ccc(-c6ccccc6)cc5)cc4)c4ccc5c(c4)C(c4ccccc4)(c4ccccc4)c4cccc(-c6ccccc6)c4-5)cc3)cc21] | (419) |
| 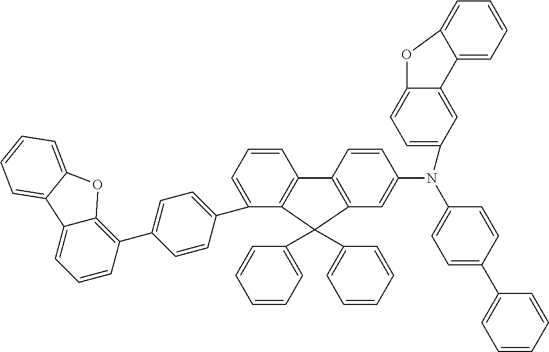 [SMILES: c1ccc(-c2ccc(N(c3ccc4c(c3)C(c3ccccc3)(c3ccccc3)c3c(-c5ccc(-c6cccc7c6oc6ccccc67)cc5)cccc3-4)c3ccc4oc5ccccc5c4c3)cc2)cc1] | (420) |
| 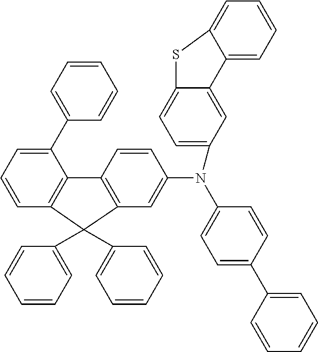 [SMILES: c1ccc(-c2ccc(N(c3ccc4c(c3)C(c3ccccc3)(c3ccccc3)c3cccc(-c5ccccc5)c3-4)c3ccc4sc5ccccc5c4c3)cc2)cc1] | (421) |
| 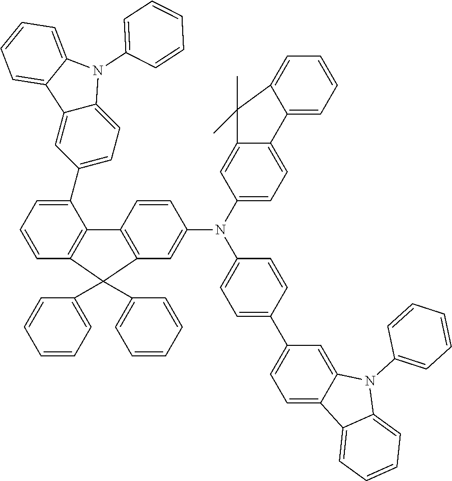 [SMILES: CC1(C)c2ccccc2-c2ccc(N(c3ccc(-c4ccc5c6ccccc6n(-c6ccccc6)c5c4)cc3)c3ccc4c(c3)C(c3ccccc3)(c3ccccc3)c3cccc(-c5ccc6c(c5)c5ccccc5n6-c5ccccc5)c3-4)cc21] | (422) |
| 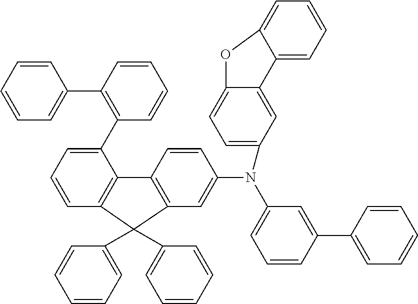 [SMILES: c1ccc(-c2cccc(N(c3ccc4c(c3)C(c3ccccc3)(c3ccccc3)c3cccc(-c5ccccc5-c5ccccc5)c3-4)c3ccc4oc5ccccc5c4c3)c2)cc1] | (423) |
| 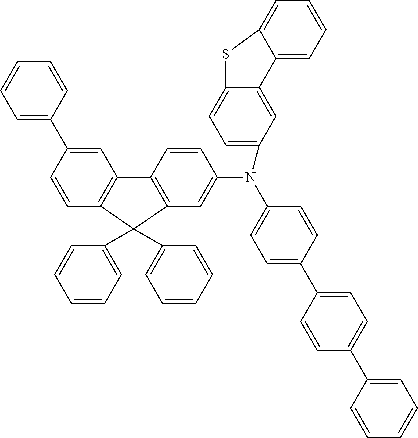 [SMILES: c1ccc(-c2ccc(-c3ccc(N(c4ccc5c(c4)C(c4ccccc4)(c4ccccc4)c4ccc(-c6ccccc6)cc4-5)c4ccc5sc6ccccc6c5c4)cc3)cc2)cc1] | (424) |
| 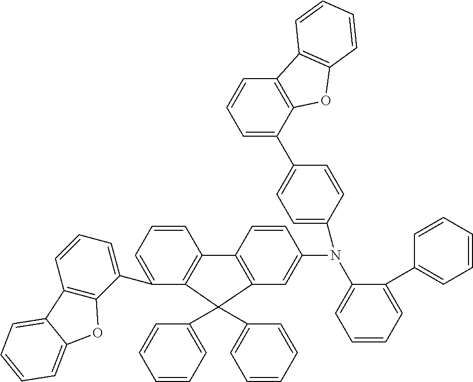 [SMILES: c1ccc(-c2ccccc2N(c2ccc(-c3cccc4c3oc3ccccc34)cc2)c2ccc3c(c2)C(c2ccccc2)(c2ccccc2)c2c-3cccc2-c2cccc3c2oc2ccccc23)cc1] | (425) |
| 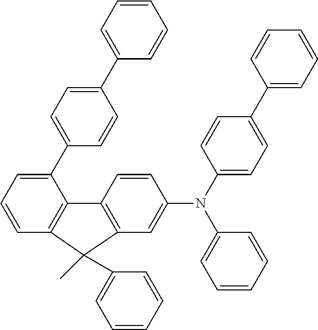 [SMILES: CC1(c2ccccc2)c2cc(N(c3ccccc3)c3ccc(-c4ccccc4)cc3)ccc2-c2c(-c3ccc(-c4ccccc4)cc3)cccc21] | (426) |
| 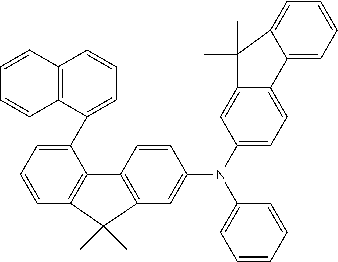 [SMILES: CC1(C)c2ccccc2-c2ccc(N(c3ccccc3)c3ccc4c(c3)C(C)(C)c3cccc(-c5cccc6ccccc56)c3-4)cc21] | (427) |
| 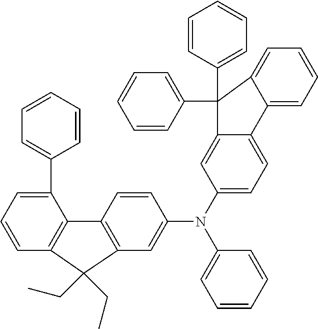 [SMILES: CCC1(CC)c2cc(N(c3ccccc3)c3ccc4c(c3)C(c3ccccc3)(c3ccccc3)c3ccccc3-4)ccc2-c2c(-c3ccccc3)cccc21] | (428) |
| 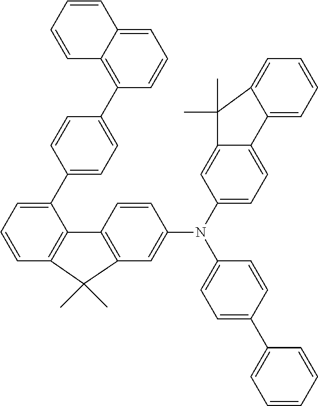 [SMILES: CC1(C)c2ccccc2-c2ccc(N(c3ccc(-c4ccccc4)cc3)c3ccc4c(c3)C(C)(C)c3cccc(-c5ccc(-c6cccc7ccccc67)cc5)c3-4)cc21] | (429) |
| 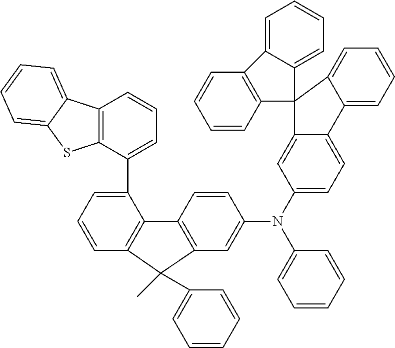 [SMILES: CC1(c2ccccc2)c2cc(N(c3ccccc3)c3ccc4c(c3)C3(c5ccccc5-c5ccccc53)c3ccccc3-4)ccc2-c2c(-c3cccc4c3sc3ccccc34)cccc21] | (430) |
| 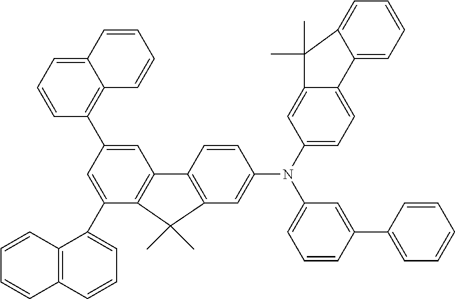 [SMILES: CC1(C)c2ccccc2-c2ccc(N(c3cccc(-c4ccccc4)c3)c3ccc4c(c3)C(C)(C)c3c-4cc(-c4cccc5ccccc45)cc3-c3cccc4ccccc34)cc21] | (431) |
| 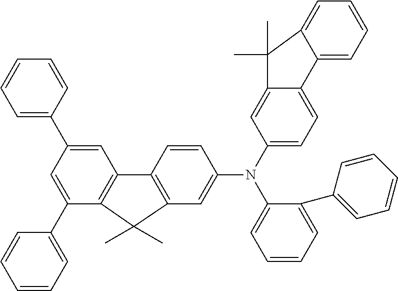 [SMILES: CC1(C)c2ccccc2-c2ccc(N(c3ccc4c(c3)C(C)(C)c3c(-c5ccccc5)cc(-c5ccccc5)cc3-4)c3ccccc3-c3ccccc3)cc21] | (432) |
| 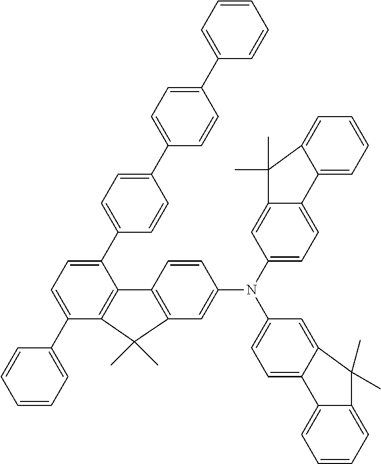 [SMILES: CC1(C)c2ccccc2-c2ccc(N(c3ccc4c(c3)C(C)(C)c3ccccc3-4)c3ccc4c(c3)C(C)(C)c3c(-c5ccccc5)ccc(-c5ccc(-c6ccc(-c7ccccc7)cc6)cc5)c3-4)cc21] | (433) |
| 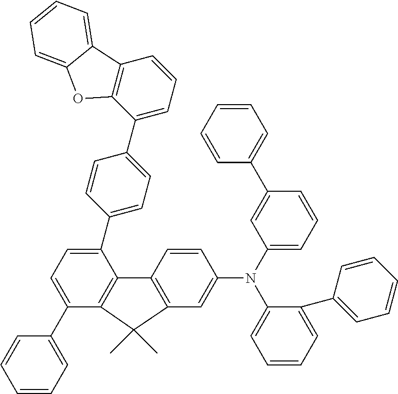 [SMILES: CC1(C)c2cc(N(c3cccc(-c4ccccc4)c3)c3ccccc3-c3ccccc3)ccc2-c2c(-c3ccc(-c4cccc5c4oc4ccccc45)cc3)ccc(-c3ccccc3)c21] | (434) |
| 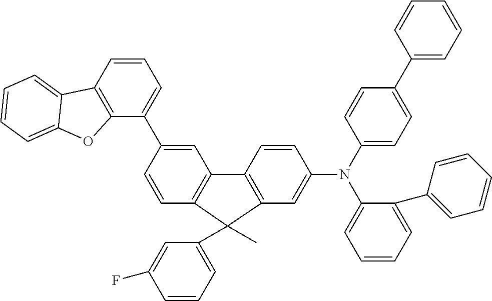 [SMILES: CC1(c2cccc(F)c2)c2ccc(-c3cccc4c3oc3ccccc34)cc2-c2ccc(N(c3ccc(-c4ccccc4)cc3)c3ccccc3-c3ccccc3)cc21] | (435) |
| 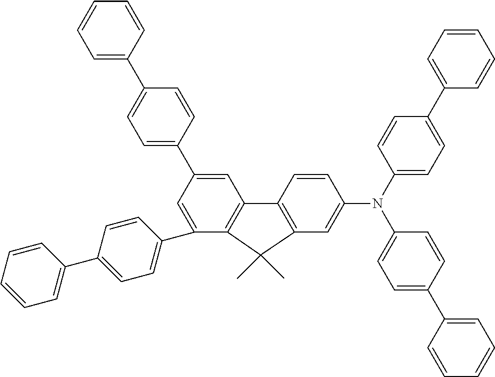 [SMILES: CC1(C)c2cc(N(c3ccc(-c4ccccc4)cc3)c3ccc(-c4ccccc4)cc3)ccc2-c2cc(-c3ccc(-c4ccccc4)cc3)cc(-c3ccc(-c4ccccc4)cc3)c21] | (436) |
| 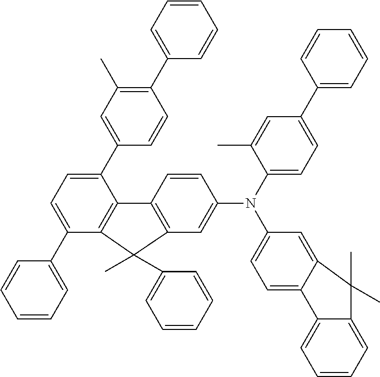 [SMILES: Cc1cc(-c2ccc(-c3ccccc3)c3c2-c2ccc(N(c4ccc5c(c4)C(C)(C)c4ccccc4-5)c4ccc(-c5ccccc5)cc4C)cc2C3(C)c2ccccc2)ccc1-c1ccccc1] | (437) |
| 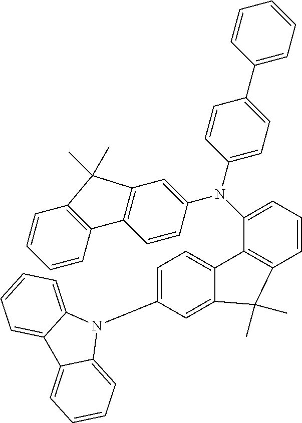 [SMILES: CC1(C)c2ccccc2-c2ccc(N(c3ccc(-c4ccccc4)cc3)c3cccc4c3-c3ccc(-n5c6ccccc6c6ccccc65)cc3C4(C)C)cc21] | (438) |
| 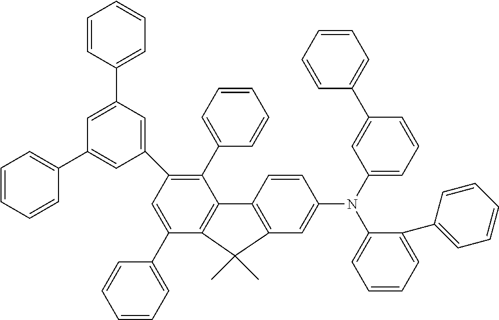 [SMILES: CC1(C)c2cc(N(c3cccc(-c4ccccc4)c3)c3ccccc3-c3ccccc3)ccc2-c2c(-c3ccccc3)c(-c3cc(-c4ccccc4)cc(-c4ccccc4)c3)cc(-c3ccccc3)c21] | (439) |
| 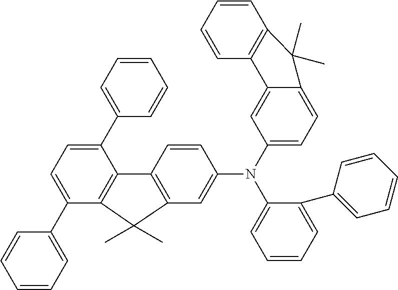 [SMILES: CC1(C)c2ccccc2-c2cc(N(c3ccc4c(c3)C(C)(C)c3c(-c5ccccc5)ccc(-c5ccccc5)c3-4)c3ccccc3-c3ccccc3)ccc21] | (440) |
| 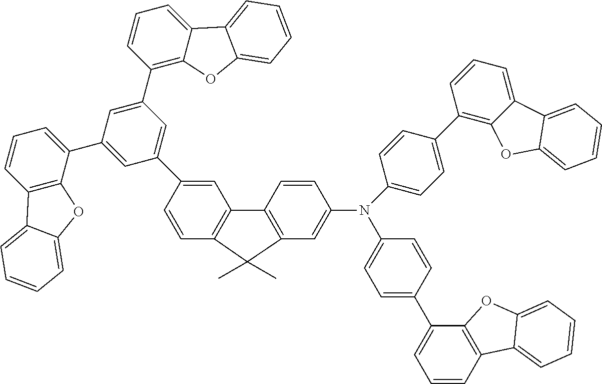 [SMILES: CC1(C)c2ccc(-c3cc(-c4cccc5c4oc4ccccc45)cc(-c4cccc5c4oc4ccccc45)c3)cc2-c2ccc(N(c3ccc(-c4cccc5c4oc4ccccc45)cc3)c3ccc(-c4cccc5c4oc4ccccc45)cc3)cc21] | (441) |
| 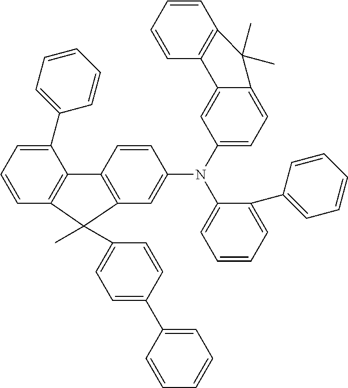 [SMILES: CC1(C)c2ccccc2-c2cc(N(c3ccc4c(c3)C(C)(c3ccc(-c5ccccc5)cc3)c3cccc(-c5ccccc5)c3-4)c3ccccc3-c3ccccc3)ccc21] | (442) |
| 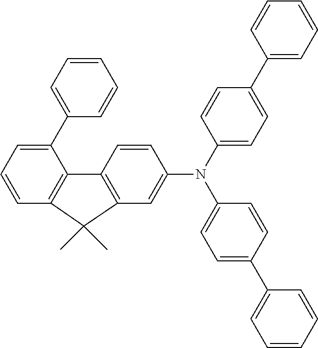 [SMILES: CC1(C)c2cc(N(c3ccc(-c4ccccc4)cc3)c3ccc(-c4ccccc4)cc3)ccc2-c2c(-c3ccccc3)cccc21] | (443) |
| 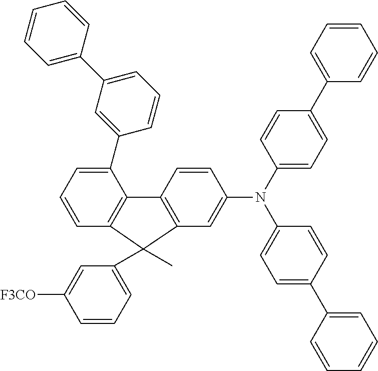 [SMILES: CC1(c2cccc(OC(F)(F)F)c2)c2cc(N(c3ccc(-c4ccccc4)cc3)c3ccc(-c4ccccc4)cc3)ccc2-c2c(-c3cccc(-c4ccccc4)c3)cccc21] | (444) |
| 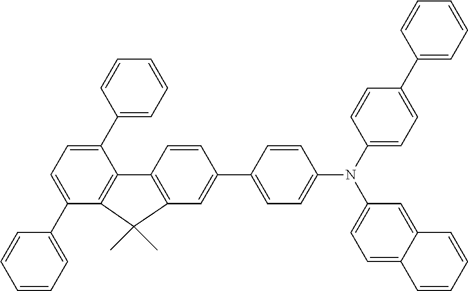 [SMILES: CC1(C)c2cc(-c3ccc(N(c4ccc(-c5ccccc5)cc4)c4ccc5ccccc5c4)cc3)ccc2-c2c(-c3ccccc3)ccc(-c3ccccc3)c21] | (445) |
| 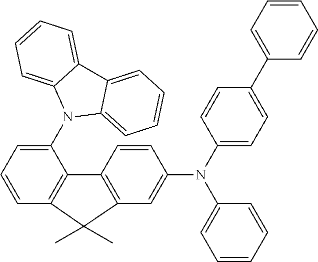 [SMILES: CC1(C)c2cc(N(c3ccccc3)c3ccc(-c4ccccc4)cc3)ccc2-c2c(-n3c4ccccc4c4ccccc43)cccc21] | (446) |
| 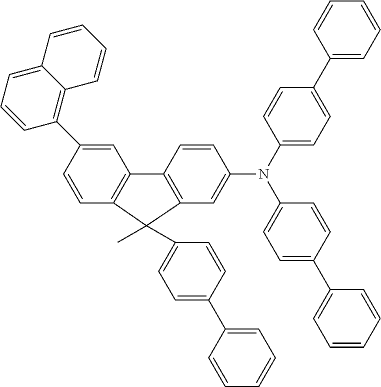 [SMILES: CC1(c2ccc(-c3ccccc3)cc2)c2ccc(-c3cccc4ccccc34)cc2-c2ccc(N(c3ccc(-c4ccccc4)cc3)c3ccc(-c4ccccc4)cc3)cc21] | (447) |
| 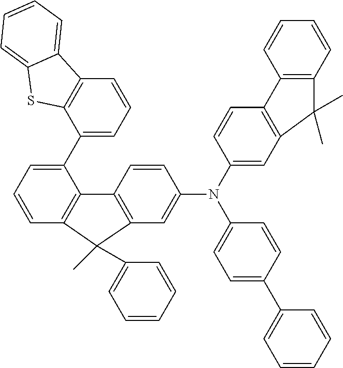 [SMILES: CC1(C)c2ccccc2-c2ccc(N(c3ccc(-c4ccccc4)cc3)c3ccc4c(c3)C(C)(c3ccccc3)c3cccc(-c5cccc6c5sc5ccccc56)c3-4)cc21] | (448) |
| 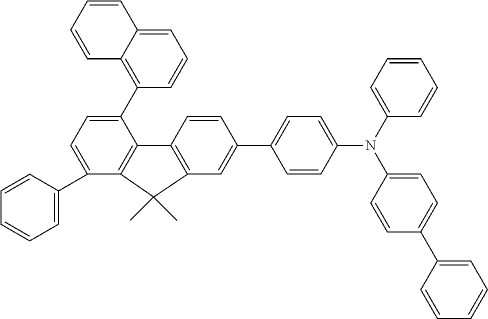 [SMILES: CC1(C)c2cc(-c3ccc(N(c4ccccc4)c4ccc(-c5ccccc5)cc4)cc3)ccc2-c2c(-c3cccc4ccccc34)ccc(-c3ccccc3)c21] | (449) |
| 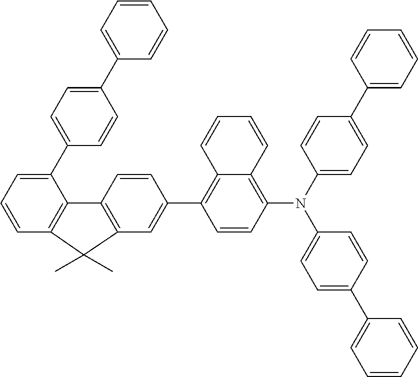 [SMILES: CC1(C)c2cc(-c3ccc(N(c4ccc(-c5ccccc5)cc4)c4ccc(-c5ccccc5)cc4)c4ccccc34)ccc2-c2c(-c3ccc(-c4ccccc4)cc3)cccc21] | (450) |
| 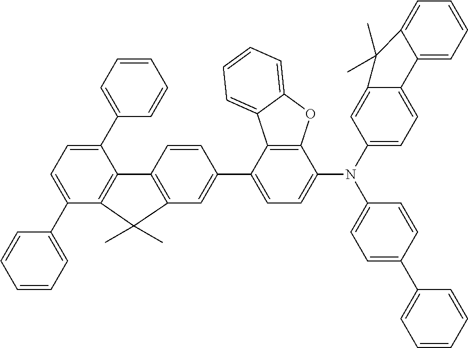 [SMILES: CC1(C)c2ccccc2-c2ccc(N(c3ccc(-c4ccccc4)cc3)c3ccc(-c4ccc5c(c4)C(C)(C)c4c(-c6ccccc6)ccc(-c6ccccc6)c4-5)c4c3oc3ccccc34)cc21] | (451) |
| 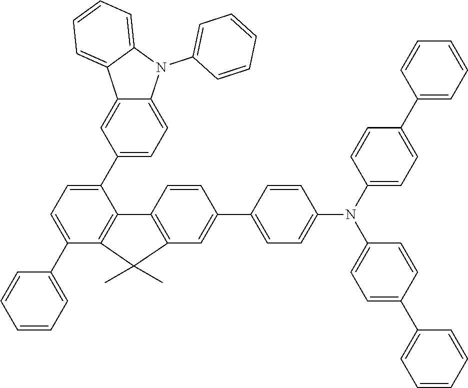 [SMILES: CC1(C)c2cc(-c3ccc(N(c4ccc(-c5ccccc5)cc4)c4ccc(-c5ccccc5)cc4)cc3)ccc2-c2c(-c3ccc4c(c3)c3ccccc3n4-c3ccccc3)ccc(-c3ccccc3)c21] | (452) |
| 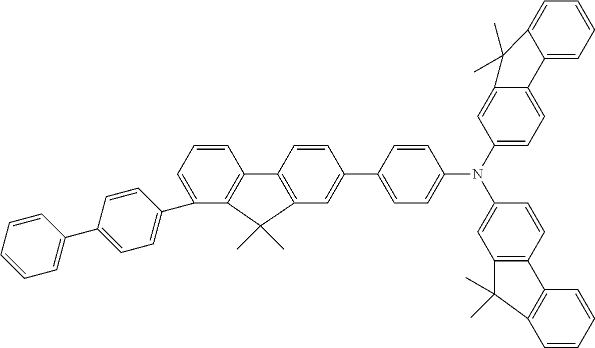 [SMILES: CC1(C)c2ccccc2-c2ccc(N(c3ccc(-c4ccc5c(c4)C(C)(C)c4c(-c6ccc(-c7ccccc7)cc6)cccc4-5)cc3)c3ccc4c(c3)C(C)(C)c3ccccc3-4)cc21] | (453) |
| 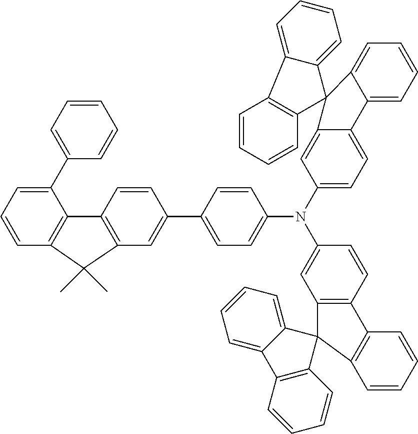 [SMILES: CC1(C)c2cc(-c3ccc(N(c4ccc5c(c4)C4(c6ccccc6-c6ccccc64)c4ccccc4-5)c4ccc5c(c4)C4(c6ccccc6-c6ccccc64)c4ccccc4-5)cc3)ccc2-c2c(-c3ccccc3)cccc21] | (454) |
| 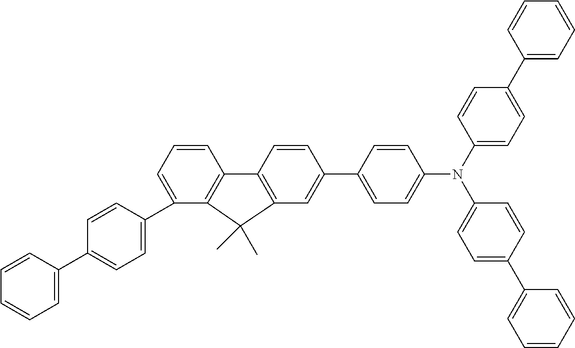 [SMILES: CC1(C)c2cc(-c3ccc(N(c4ccc(-c5ccccc5)cc4)c4ccc(-c5ccccc5)cc4)cc3)ccc2-c2cccc(-c3ccc(-c4ccccc4)cc3)c21] | (455) |
| 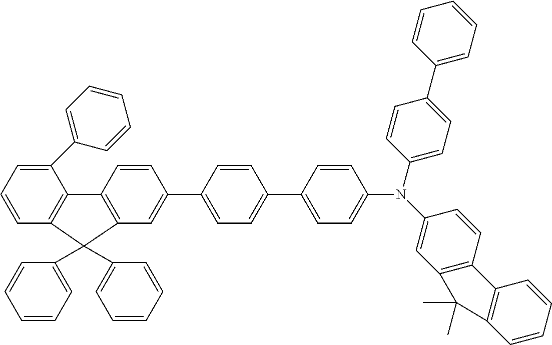 [SMILES: CC1(C)c2ccccc2-c2ccc(N(c3ccc(-c4ccccc4)cc3)c3ccc(-c4ccc(-c5ccc6c(c5)C(c5ccccc5)(c5ccccc5)c5cccc(-c7ccccc7)c5-6)cc4)cc3)cc21] | (456) |
| 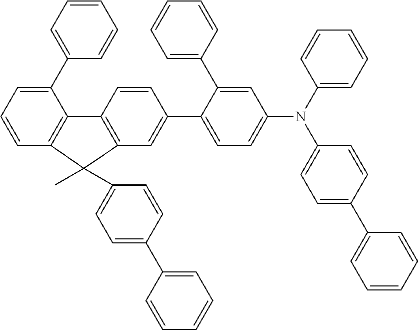 [SMILES: CC1(c2ccc(-c3ccccc3)cc2)c2cc(-c3ccc(N(c4ccccc4)c4ccc(-c5ccccc5)cc4)cc3-c3ccccc3)ccc2-c2c(-c3ccccc3)cccc21] | (457) |
| 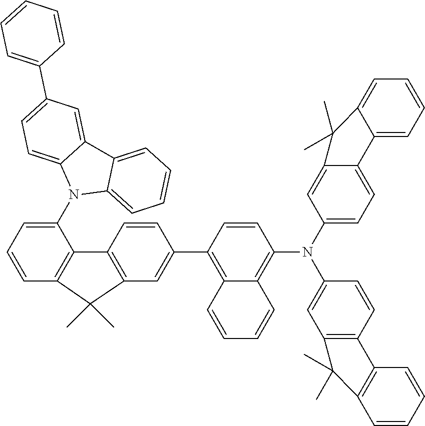 [SMILES: CC1(C)c2ccccc2-c2ccc(N(c3ccc4c(c3)C(C)(C)c3ccccc3-4)c3ccc(-c4ccc5c(c4)C(C)(C)c4cccc(-n6c7ccccc7c7cc(-c8ccccc8)ccc76)c4-5)c4ccccc34)cc21] | (458) |
| 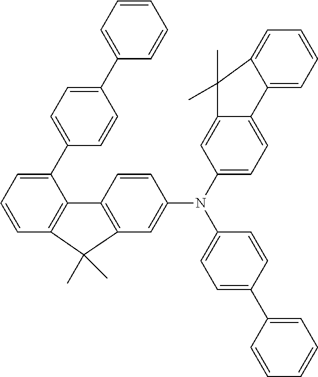 [SMILES: CC1(C)c2ccccc2-c2ccc(N(c3ccc(-c4ccccc4)cc3)c3ccc4c(c3)C(C)(C)c3cccc(-c5ccc(-c6ccccc6)cc5)c3-4)cc21] | (459) |
| 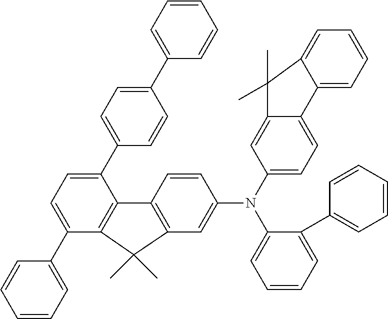 [SMILES: CC1(C)c2ccccc2-c2ccc(N(c3ccc4c(c3)C(C)(C)c3c(-c5ccccc5)ccc(-c5ccc(-c6ccccc6)cc5)c3-4)c3ccccc3-c3ccccc3)cc21] | (460) |
| 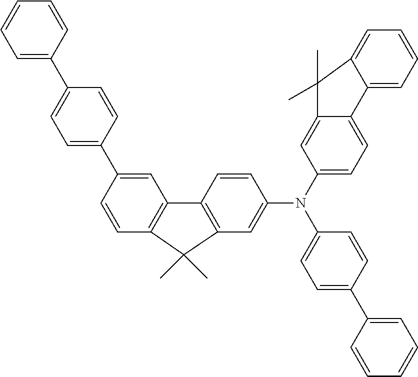 [SMILES: CC1(C)c2ccccc2-c2ccc(N(c3ccc(-c4ccccc4)cc3)c3ccc4c(c3)C(C)(C)c3ccc(-c5ccc(-c6ccccc6)cc5)cc3-4)cc21] | (461) |
| 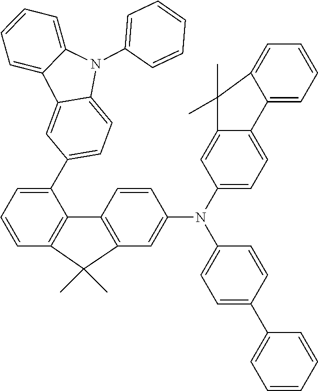 [SMILES: CC1(C)c2ccccc2-c2ccc(N(c3ccc(-c4ccccc4)cc3)c3ccc4c(c3)C(C)(C)c3cccc(-c5ccc6c(c5)c5ccccc5n6-c5ccccc5)c3-4)cc21] | (462) |
| 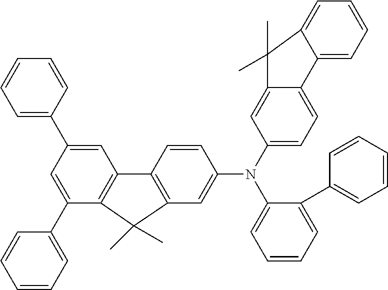 [SMILES: CC1(C)c2ccccc2-c2ccc(N(c3ccc4c(c3)C(C)(C)c3c(-c5ccccc5)cc(-c5ccccc5)cc3-4)c3ccccc3-c3ccccc3)cc21] | (463) |
| 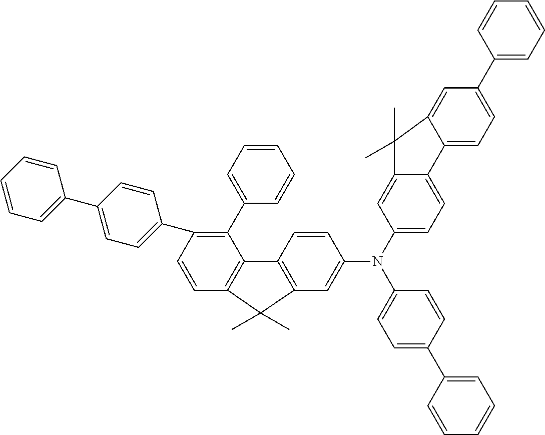 [SMILES: CC1(C)c2cc(-c3ccccc3)ccc2-c2ccc(N(c3ccc(-c4ccccc4)cc3)c3ccc4c(c3)C(C)(C)c3ccc(-c5ccc(-c6ccccc6)cc5)c(-c5ccccc5)c3-4)cc21] | (464) |
| 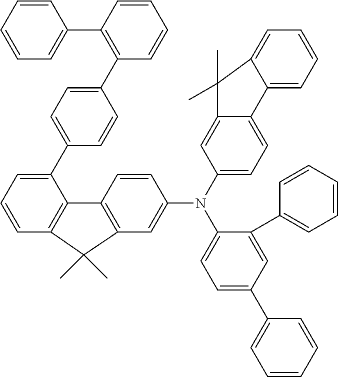 [SMILES: CC1(C)c2ccccc2-c2ccc(N(c3ccc4c(c3)C(C)(C)c3cccc(-c5ccc(-c6ccccc6-c6ccccc6)cc5)c3-4)c3ccc(-c4ccccc4)cc3-c3ccccc3)cc21] | (465) |
| 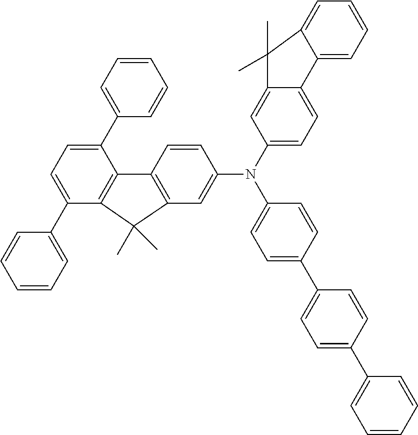 [SMILES: CC1(C)c2ccccc2-c2ccc(N(c3ccc(-c4ccc(-c5ccccc5)cc4)cc3)c3ccc4c(c3)C(C)(C)c3c(-c5ccccc5)ccc(-c5ccccc5)c3-4)cc21] | (466) |
| 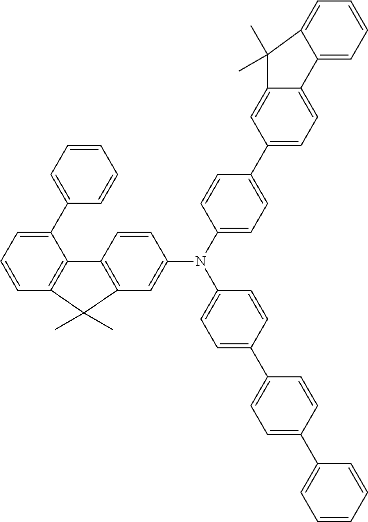 [SMILES: CC1(C)c2ccccc2-c2ccc(-c3ccc(N(c4ccc(-c5ccc(-c6ccccc6)cc5)cc4)c4ccc5c(c4)C(C)(C)c4cccc(-c6ccccc6)c4-5)cc3)cc21] | (467) |
| 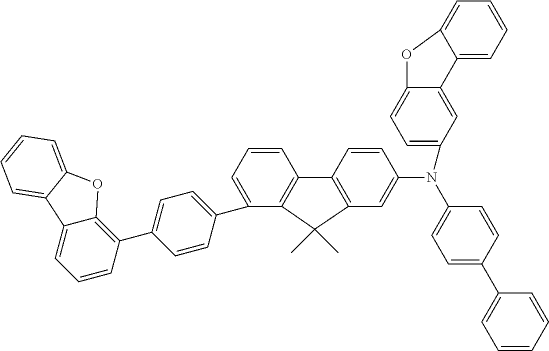 [SMILES: CC1(C)c2cc(N(c3ccc(-c4ccccc4)cc3)c3ccc4oc5ccccc5c4c3)ccc2-c2cccc(-c3ccc(-c4cccc5c4oc4ccccc45)cc3)c21] | (468) |
| 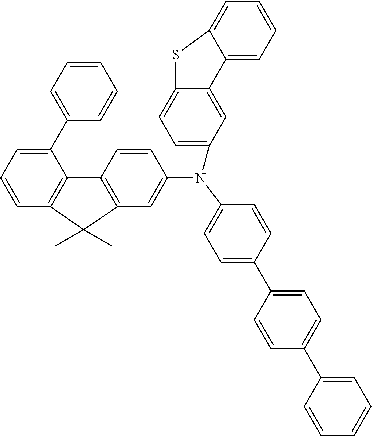 [SMILES: CC1(C)c2cc(N(c3ccc(-c4ccc(-c5ccccc5)cc4)cc3)c3ccc4sc5ccccc5c4c3)ccc2-c2c(-c3ccccc3)cccc21] | (469) |
| 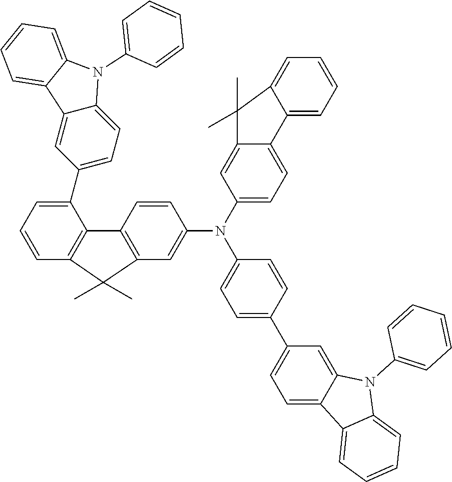 [SMILES: CC1(C)c2ccccc2-c2ccc(N(c3ccc(-c4ccc5c6ccccc6n(-c6ccccc6)c5c4)cc3)c3ccc4c(c3)C(C)(C)c3cccc(-c5ccc6c(c5)c5ccccc5n6-c5ccccc5)c3-4)cc21] | (470) |
| 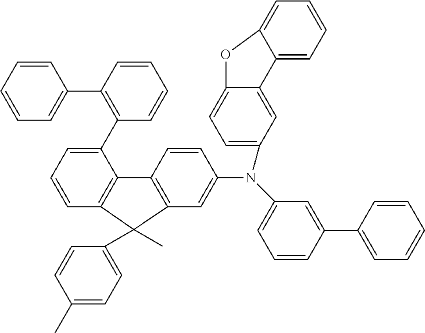 [SMILES: Cc1ccc(C2(C)c3cc(N(c4cccc(-c5ccccc5)c4)c4ccc5oc6ccccc6c5c4)ccc3-c3c(-c4ccccc4-c4ccccc4)cccc32)cc1] | (471) |
| 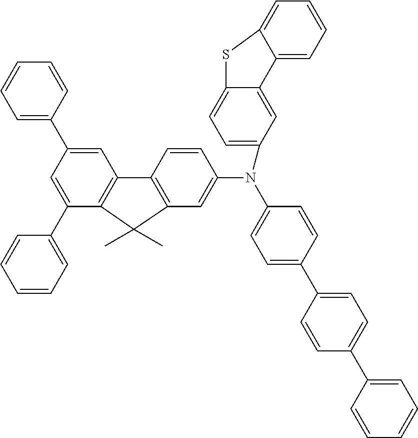 [SMILES: CC1(C)c2cc(N(c3ccc(-c4ccc(-c5ccccc5)cc4)cc3)c3ccc4sc5ccccc5c4c3)ccc2-c2cc(-c3ccccc3)cc(-c3ccccc3)c21] | (472) |
| 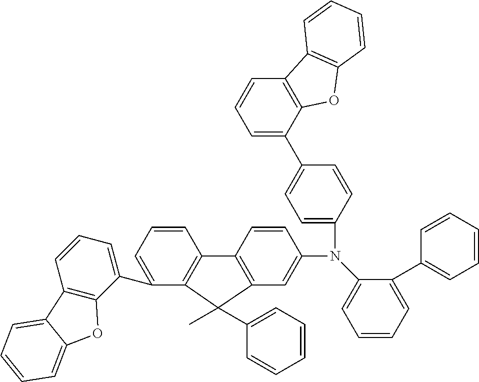 [SMILES: CC1(c2ccccc2)c2cc(N(c3ccc(-c4cccc5c4oc4ccccc45)cc3)c3ccccc3-c3ccccc3)ccc2-c2cccc(-c3cccc4c3oc3ccccc34)c21] | (473) |
| 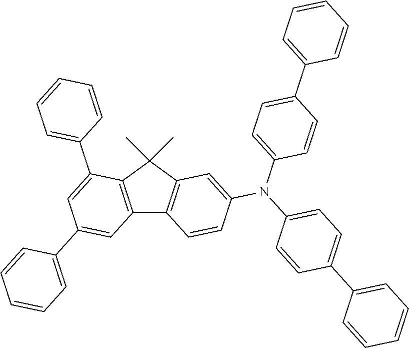 [SMILES: CC1(C)c2cc(N(c3ccc(-c4ccccc4)cc3)c3ccc(-c4ccccc4)cc3)ccc2-c2cc(-c3ccccc3)cc(-c3ccccc3)c21] | (474) |
| 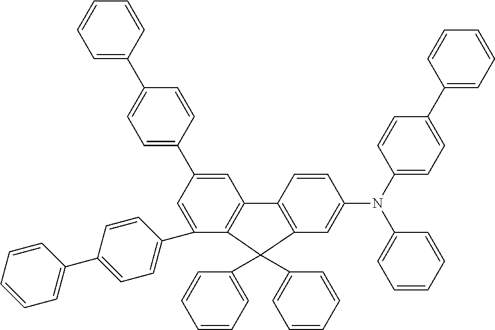 [SMILES: c1ccc(-c2ccc(-c3cc(-c4ccc(-c5ccccc5)cc4)c4c(c3)-c3ccc(N(c5ccccc5)c5ccc(-c6ccccc6)cc5)cc3C4(c3ccccc3)c3ccccc3)cc2)cc1] | (475) |
| 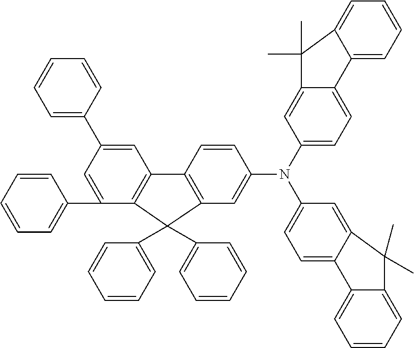 [SMILES: CC1(C)c2ccccc2-c2ccc(N(c3ccc4c(c3)C(C)(C)c3ccccc3-4)c3ccc4c(c3)C(c3ccccc3)(c3ccccc3)c3c(-c5ccccc5)cc(-c5ccccc5)cc3-4)cc21] | (476) |
| 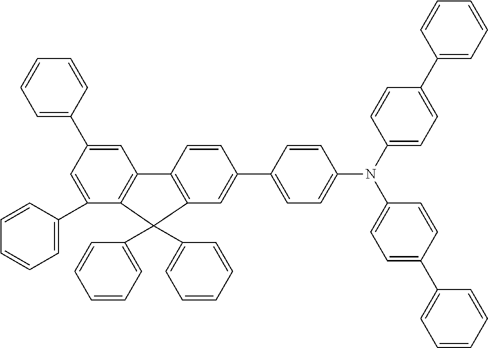 [SMILES: c1ccc(-c2ccc(N(c3ccc(-c4ccccc4)cc3)c3ccc(-c4ccc5c(c4)C(c4ccccc4)(c4ccccc4)c4c(-c6ccccc6)cc(-c6ccccc6)cc4-5)cc3)cc2)cc1] | (477) |
| 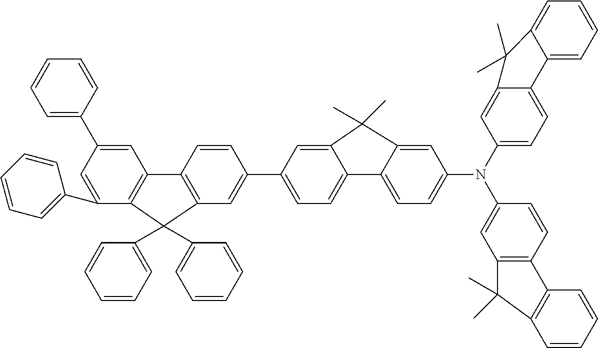 [SMILES: CC1(C)c2ccccc2-c2ccc(N(c3ccc4c(c3)C(C)(C)c3ccccc3-4)c3ccc4c(c3)C(C)(C)c3cc(-c5ccc6c(c5)C(c5ccccc5)(c5ccccc5)c5c(-c7ccccc7)cc(-c7ccccc7)cc5-6)ccc3-4)cc21] | (478) |
| 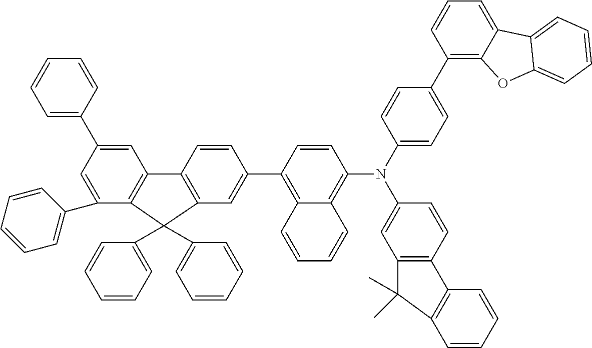 [SMILES: CC1(C)c2ccccc2-c2ccc(N(c3ccc(-c4cccc5c4oc4ccccc45)cc3)c3ccc(-c4ccc5c(c4)C(c4ccccc4)(c4ccccc4)c4c(-c6ccccc6)cc(-c6ccccc6)cc4-5)c4ccccc34)cc21] | (479) |
| 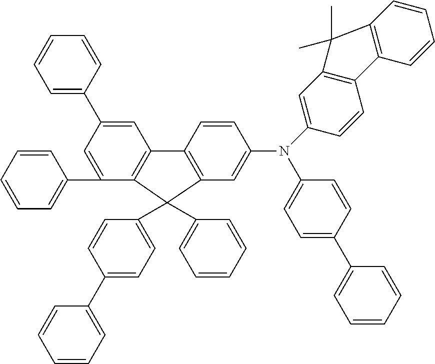 [SMILES: CC1(C)c2ccccc2-c2ccc(N(c3ccc(-c4ccccc4)cc3)c3ccc4c(c3)C(c3ccccc3)(c3ccc(-c5ccccc5)cc3)c3c(-c5ccccc5)cc(-c5ccccc5)cc3-4)cc21] | (480) |
| 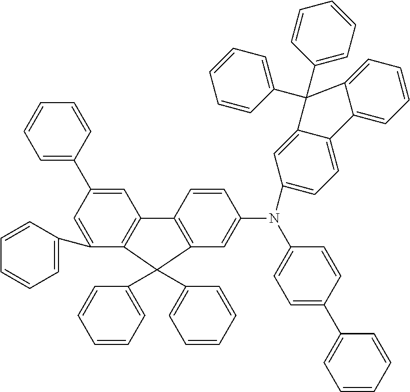 [SMILES: c1ccc(-c2ccc(N(c3ccc4c(c3)C(c3ccccc3)(c3ccccc3)c3ccccc3-4)c3ccc4c(c3)C(c3ccccc3)(c3ccccc3)c3c(-c5ccccc5)cc(-c5ccccc5)cc3-4)cc2)cc1] | (481) |
| 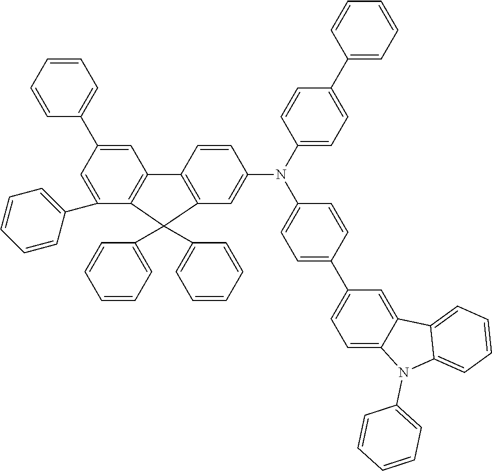 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3c(-c5ccccc5)cc(-c5ccccc5)cc3-4)cc2)cc1] | (482) |
| 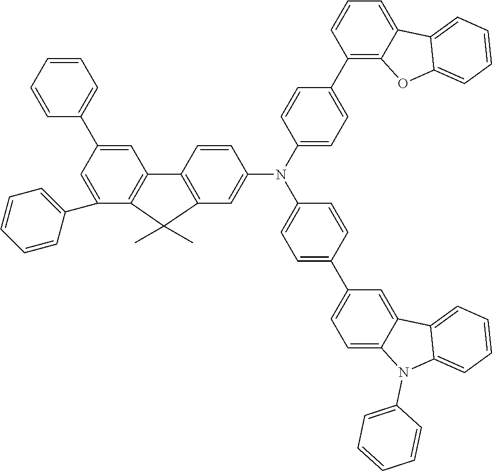 [SMILES: CC1(C)c2cc(N(c3ccc(-c4ccc5c(c4)c4ccccc4n5-c4ccccc4)cc3)c3ccc(-c4cccc5c4oc4ccccc45)cc3)ccc2-c2cc(-c3ccccc3)cc(-c3ccccc3)c21] | (483) |
| 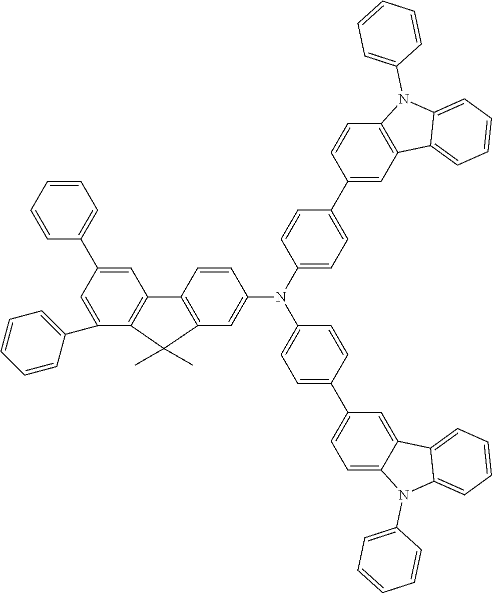 [SMILES: CC1(C)c2cc(N(c3ccc(-c4ccc5c(c4)c4ccccc4n5-c4ccccc4)cc3)c3ccc(-c4ccc5c(c4)c4ccccc4n5-c4ccccc4)cc3)ccc2-c2cc(-c3ccccc3)cc(-c3ccccc3)c21] | (484) |
| 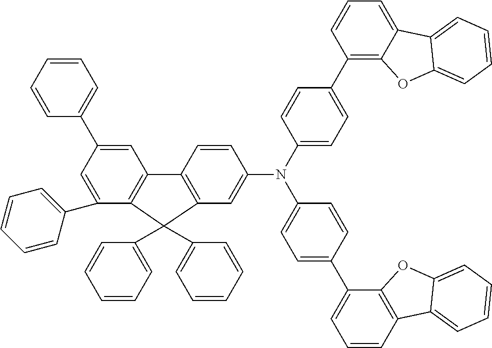 [SMILES: c1ccc(-c2cc(-c3ccccc3)c3c(c2)-c2ccc(N(c4ccc(-c5cccc6c5oc5ccccc56)cc4)c4ccc(-c5cccc6c5oc5ccccc56)cc4)cc2C3(c2ccccc2)c2ccccc2)cc1] | (485) |
| 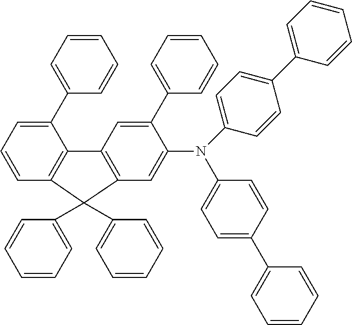 [SMILES: c1ccc(-c2ccc(N(c3ccc(-c4ccccc4)cc3)c3cc4c(cc3-c3ccccc3)-c3c(-c5ccccc5)cccc3C4(c3ccccc3)c3ccccc3)cc2)cc1] | (486) |
| 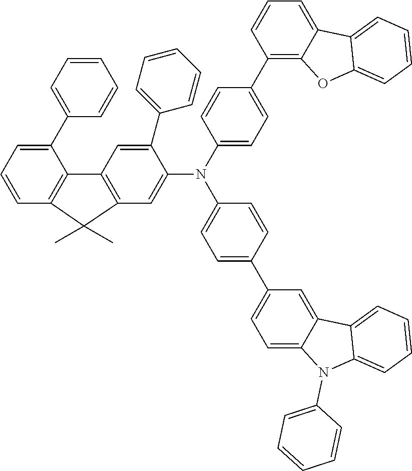 [SMILES: CC1(C)c2cc(N(c3ccc(-c4ccc5c(c4)c4ccccc4n5-c4ccccc4)cc3)c3ccc(-c4cccc5c4oc4ccccc45)cc3)c(-c3ccccc3)cc2-c2c(-c3ccccc3)cccc21] | (487) |
| 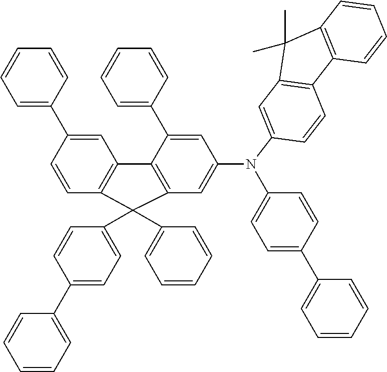 [SMILES: CC1(C)c2ccccc2-c2ccc(N(c3ccc(-c4ccccc4)cc3)c3cc(-c4ccccc4)c4c(c3)C(c3ccccc3)(c3ccc(-c5ccccc5)cc3)c3ccc(-c5ccccc5)cc3-4)cc21] | (488) |
| 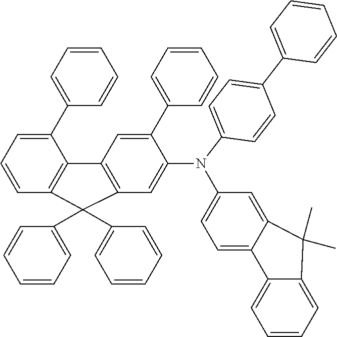 [SMILES: CC1(C)c2ccccc2-c2ccc(N(c3ccc(-c4ccccc4)cc3)c3cc4c(cc3-c3ccccc3)-c3c(-c5ccccc5)cccc3C4(c3ccccc3)c3ccccc3)cc21] | (489) |
| 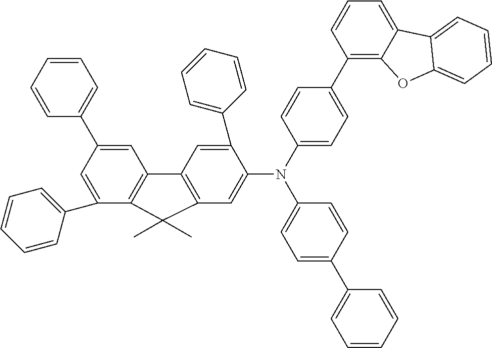 [SMILES: CC1(C)c2cc(N(c3ccc(-c4ccccc4)cc3)c3ccc(-c4cccc5c4oc4ccccc45)cc3)c(-c3ccccc3)cc2-c2cc(-c3ccccc3)cc(-c3ccccc3)c21] | (490) |
| 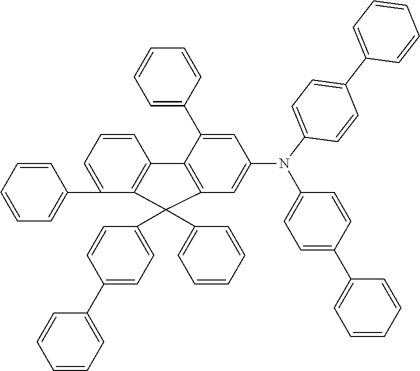 [SMILES: c1ccc(-c2ccc(N(c3ccc(-c4ccccc4)cc3)c3cc(-c4ccccc4)c4c(c3)C(c3ccccc3)(c3ccc(-c5ccccc5)cc3)c3c(-c5ccccc5)cccc3-4)cc2)cc1] | (491) |
| 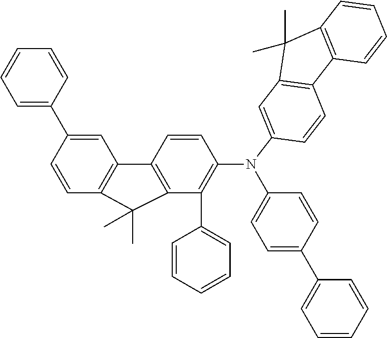 [SMILES: CC1(C)c2ccccc2-c2ccc(N(c3ccc(-c4ccccc4)cc3)c3ccc4c(c3-c3ccccc3)C(C)(C)c3ccc(-c5ccccc5)cc3-4)cc21] | (492) |
| 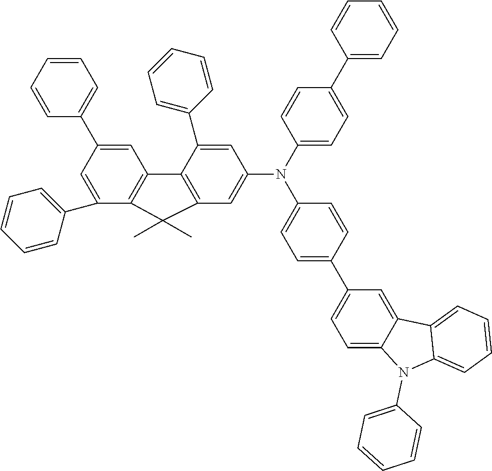 [SMILES: CC1(C)c2cc(N(c3ccc(-c4ccccc4)cc3)c3ccc(-c4ccc5c(c4)c4ccccc4n5-c4ccccc4)cc3)cc(-c3ccccc3)c2-c2cc(-c3ccccc3)cc(-c3ccccc3)c21] | (493) |
| 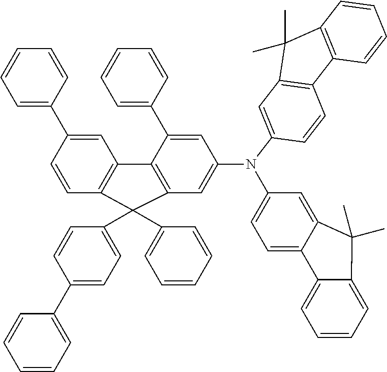 [SMILES: CC1(C)c2ccccc2-c2ccc(N(c3ccc4c(c3)C(C)(C)c3ccccc3-4)c3cc(-c4ccccc4)c4c(c3)C(c3ccccc3)(c3ccc(-c5ccccc5)cc3)c3ccc(-c5ccccc5)cc3-4)cc21] | (494) |
| 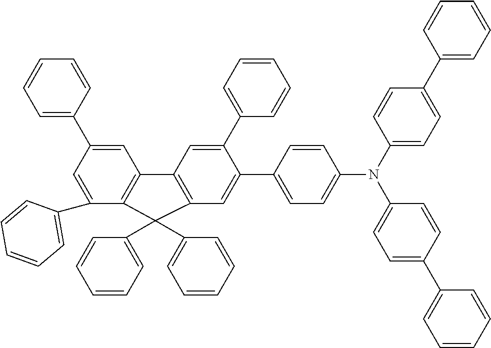 [SMILES: c1ccc(-c2ccc(N(c3ccc(-c4ccccc4)cc3)c3ccc(-c4cc5c(cc4-c4ccccc4)-c4cc(-c6ccccc6)cc(-c6ccccc6)c4C5(c4ccccc4)c4ccccc4)cc3)cc2)cc1] | (495) |
| 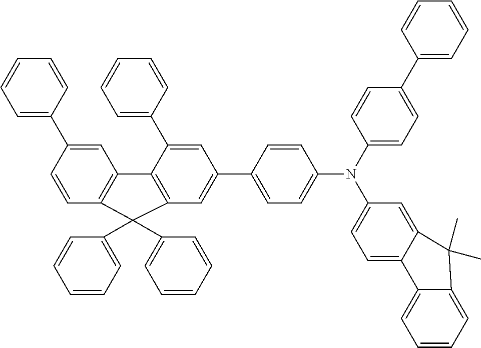 [SMILES: CC1(C)c2ccccc2-c2ccc(N(c3ccc(-c4ccccc4)cc3)c3ccc(-c4cc(-c5ccccc5)c5c(c4)C(c4ccccc4)(c4ccccc4)c4ccc(-c6ccccc6)cc4-5)cc3)cc21] | (496) |
| 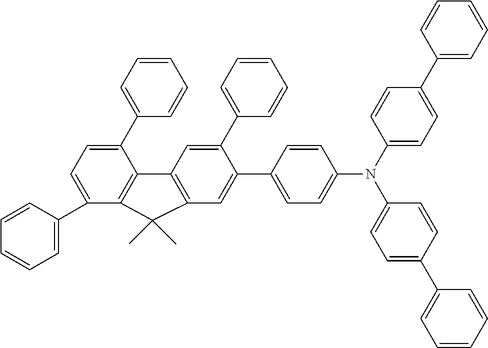 [SMILES: CC1(C)c2cc(-c3ccc(N(c4ccc(-c5ccccc5)cc4)c4ccc(-c5ccccc5)cc4)cc3)c(-c3ccccc3)cc2-c2c(-c3ccccc3)ccc(-c3ccccc3)c21] | (497) |
| 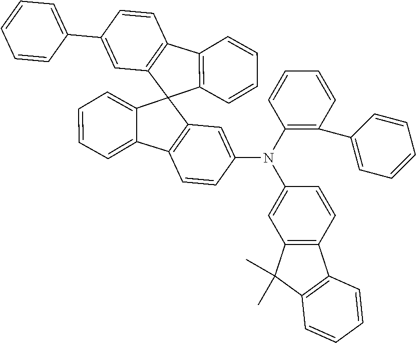 [SMILES: CC1(C)c2ccccc2-c2ccc(N(c3ccc4c(c3)C3(c5ccccc5-c5ccc(-c6ccccc6)cc53)c3ccccc3-4)c3ccccc3-c3ccccc3)cc21] | (498) |
| 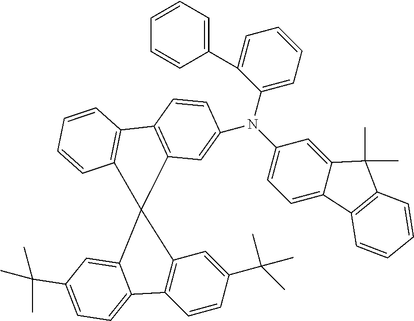 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2] | (499) |
| 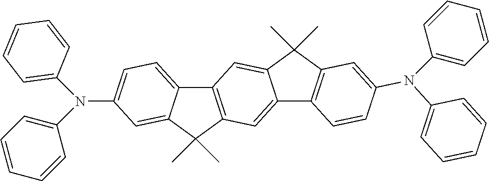 [SMILES: CC1(C)c2cc(N(c3ccccc3)c3ccccc3)ccc2-c2cc3c(cc21)-c1ccc(N(c2ccccc2)c2ccccc2)cc1C3(C)C] | (500) |
| 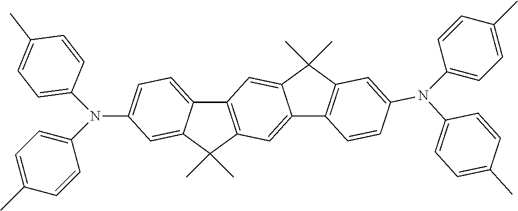 | (501) |
| 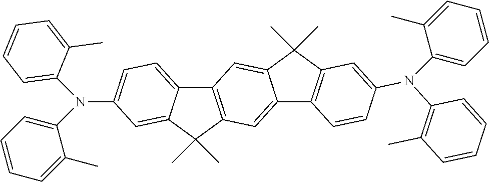 [SMILES: Cc1ccccc1N(c1ccc2c(c1)C(C)(C)c1cc3c(cc1-2)C(C)(C)c1cc(N(c2ccccc2C)c2ccccc2C)ccc1-3)c1ccccc1C] | (502) |
| 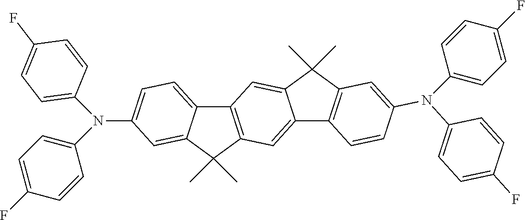 [SMILES: CC1(C)c2cc(N(c3ccc(F)cc3)c3ccc(F)cc3)ccc2-c2cc3c(cc21)-c1ccc(N(c2ccc(F)cc2)c2ccc(F)cc2)cc1C3(C)C] | (503) |
| 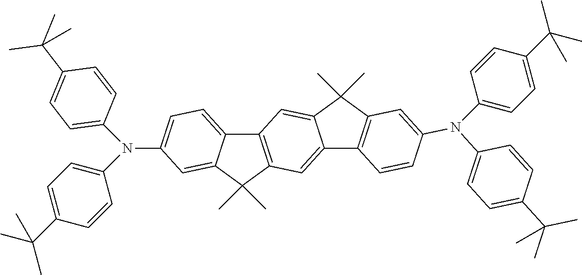 [SMILES: CC(C)(C)c1ccc(N(c2ccc(C(C)(C)C)cc2)c2ccc3c(c2)C(C)(C)c2cc4c(cc2-3)C(C)(C)c2cc(N(c3ccc(C(C)(C)C)cc3)c3ccc(C(C)(C)C)cc3)ccc2-4)cc1] | (504) |
| 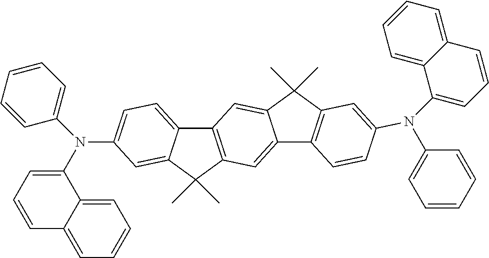 [SMILES: CC1(C)c2cc(N(c3ccccc3)c3cccc4ccccc34)ccc2-c2cc3c(cc21)-c1ccc(N(c2ccccc2)c2cccc4ccccc24)cc1C3(C)C] | (505) |
| 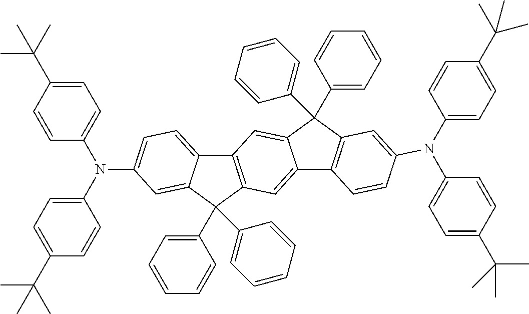 [SMILES: CC(C)(C)c1ccc(N(c2ccc(C(C)(C)C)cc2)c2ccc3c(c2)C(c2ccccc2)(c2ccccc2)c2cc4c(cc2-3)C(c2ccccc2)(c2ccccc2)c2cc(N(c3ccc(C(C)(C)C)cc3)c3ccc(C(C)(C)C)cc3)ccc2-4)cc1] | (506) |
| 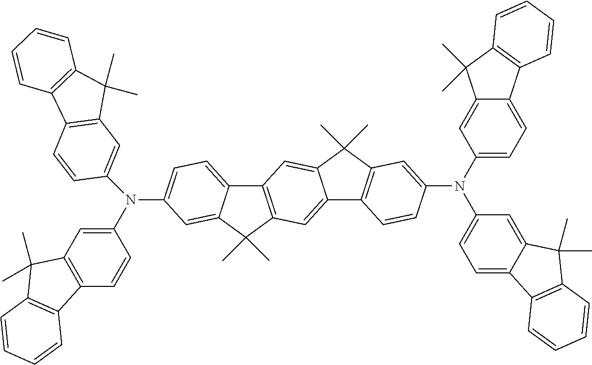 [SMILES: CC1(C)c2ccccc2-c2ccc(N(c3ccc4c(c3)C(C)(C)c3ccccc3-4)c3ccc4c(c3)C(C)(C)c3cc5c(cc3-4)C(C)(C)c3cc(N(c4ccc6c(c4)C(C)(C)c4ccccc4-6)c4ccc6c(c4)C(C)(C)c4ccccc4-6)ccc3-5)cc21] | (507) |
| 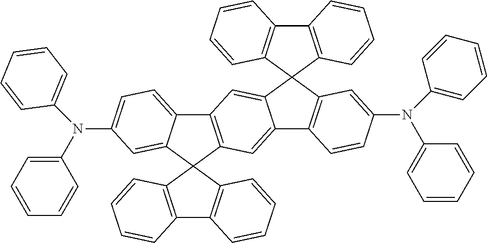 [SMILES: c1ccc(N(c2ccccc2)c2ccc3c(c2)C2(c4ccccc4-c4ccccc42)c2cc4c(cc2-3)C2(c3ccccc3-c3ccccc32)c2cc(N(c3ccccc3)c3ccccc3)ccc2-4)cc1] | (508) |
| 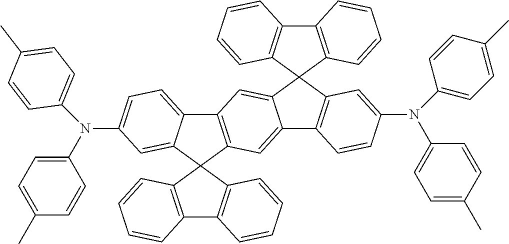 | (509) |
| 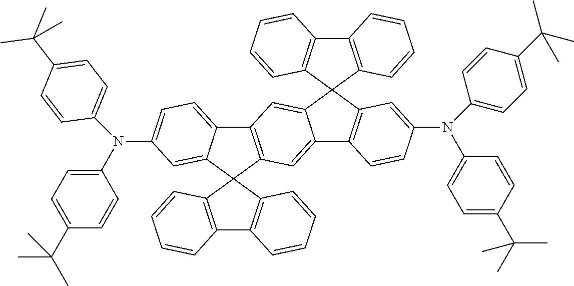 [SMILES: CC(C)(C)c1ccc(N(c2ccc(C(C)(C)C)cc2)c2ccc3c(c2)C2(c4ccccc4-c4ccccc42)c2cc4c(cc2-3)C2(c3ccccc3-c3ccccc32)c2cc(N(c3ccc(C(C)(C)C)cc3)c3ccc(C(C)(C)C)cc3)ccc2-4)cc1] | (510) |
| 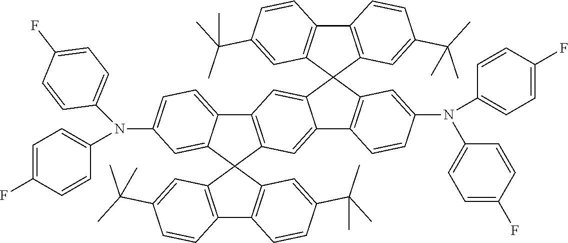 [SMILES: CC(C)(C)c1ccc2c(c1)C1(c3cc(N(c4ccc(F)cc4)c4ccc(F)cc4)ccc3-c3cc4c(cc31)-c1ccc(N(c3ccc(F)cc3)c3ccc(F)cc3)cc1C41c3cc(C(C)(C)C)ccc3-c3ccc(C(C)(C)C)cc31)c1cc(C(C)(C)C)ccc1-2] | (511) |
| 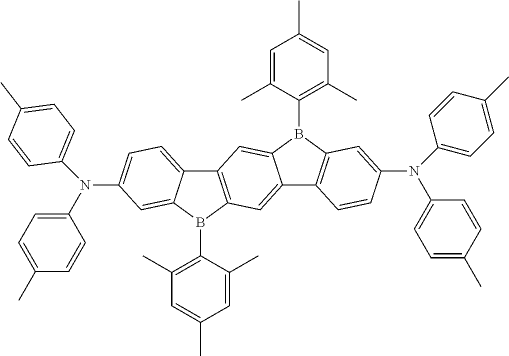 | (512) |
| 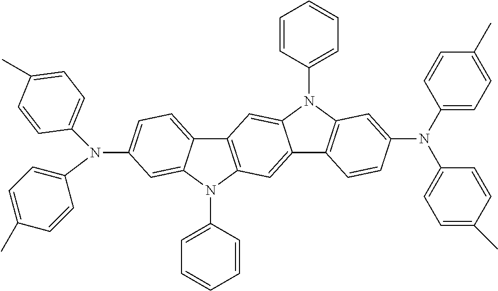 | (513) |
| 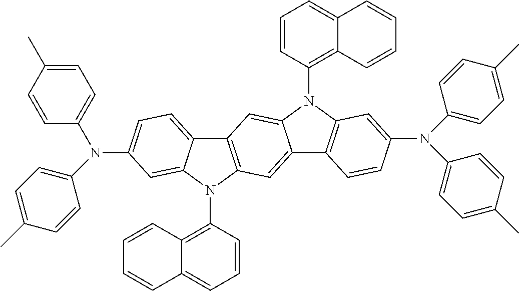 | (514) |
| 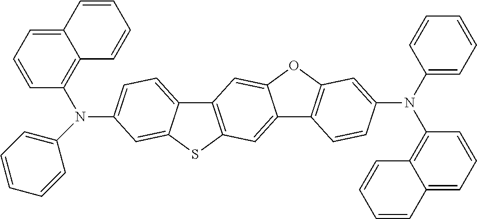 [SMILES: c1ccc(N(c2ccc3c(c2)oc2cc4c(cc23)sc2cc(N(c3ccccc3)c3cccc5ccccc35)ccc24)c2cccc3ccccc23)cc1] | (515) |
| 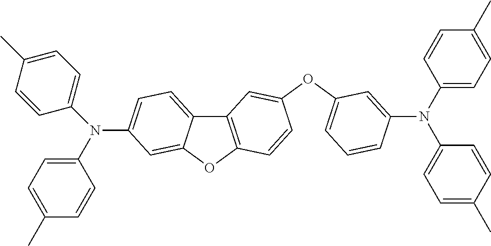 | (516) |
| 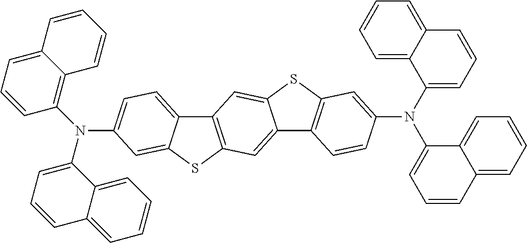 [SMILES: c1ccc2c(N(c3ccc4c(c3)sc3cc5c(cc34)sc3cc(N(c4cccc6ccccc46)c4cccc6ccccc46)ccc35)c3cccc4ccccc34)cccc2c1] | (517) |
| 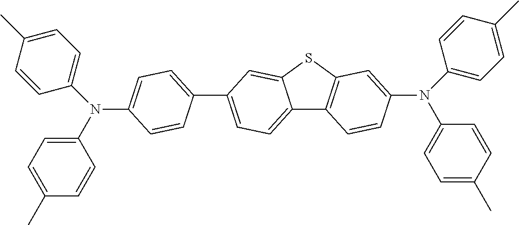 | (518) |
| 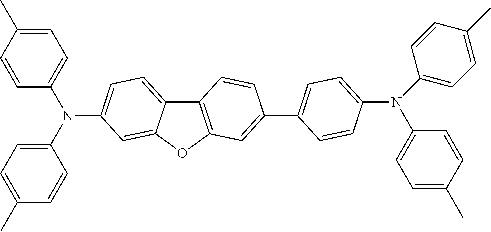 [SMILES: Cc1ccc(N(c2ccc(C)cc2)c2ccc(-c3ccc4c(c3)oc3cc(N(c5ccc(C)cc5)c5ccc(C)cc5)ccc34)cc2)cc1] | (519) |
| 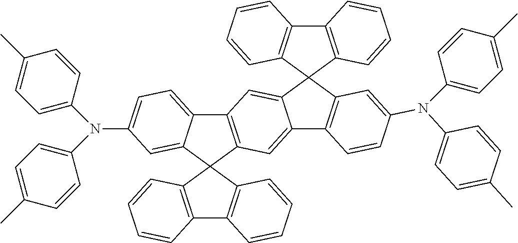 | (520) |
| 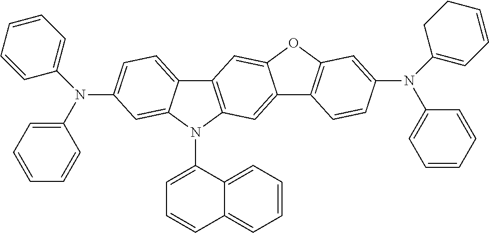 [SMILES: C1=CCCC(N(c2ccccc2)c2ccc3c(c2)oc2cc4c5ccc(N(c6ccccc6)c6ccccc6)cc5n(-c5cccc6ccccc56)c4cc23)=C1] | (521) |
| 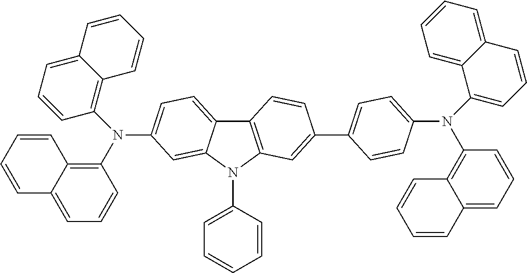 [SMILES: c1ccc(-n2c3cc(-c4ccc(N(c5cccc6ccccc56)c5cccc6ccccc56)cc4)ccc3c3ccc(N(c4cccc5ccccc45)c4cccc5ccccc45)cc32)cc1] | (522) |
| 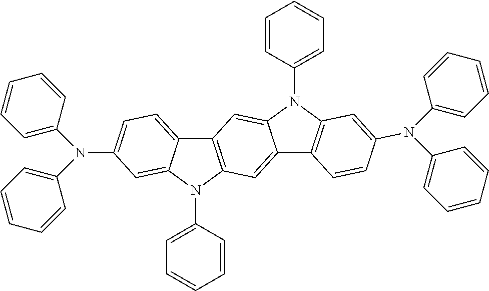 [SMILES: c1ccc(N(c2ccccc2)c2ccc3c4cc5c(cc4n(-c4ccccc4)c3c2)c2ccc(N(c3ccccc3)c3ccccc3)cc2n5-c2ccccc2)cc1] | (523) |
| 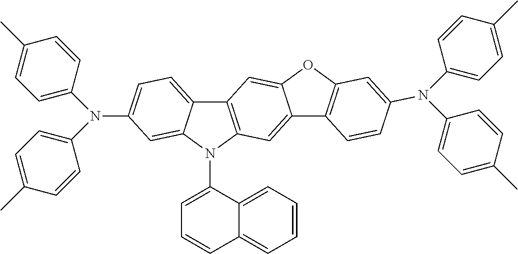 | (524) |
| 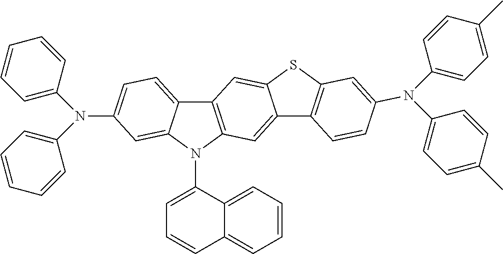 [SMILES: Cc1ccc(N(c2ccc(C)cc2)c2ccc3c(c2)sc2cc4c5ccc(N(c6ccccc6)c6ccccc6)cc5n(-c5cccc6ccccc56)c4cc23)cc1] | (525) |
| 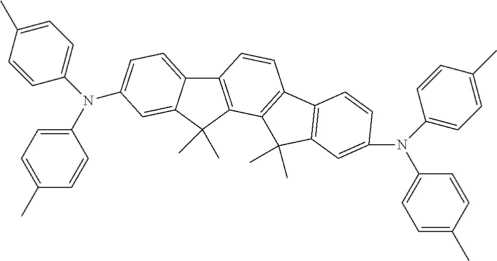 | (526) |
| 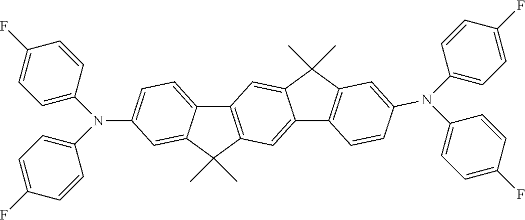 [SMILES: CC1(C)c2cc(N(c3ccc(F)cc3)c3ccc(F)cc3)ccc2-c2cc3c(cc21)-c1ccc(N(c2ccc(F)cc2)c2ccc(F)cc2)cc1C3(C)C] | (527) |
| 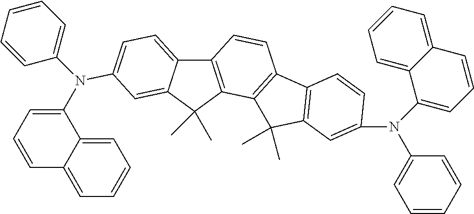 [SMILES: CC1(C)c2cc(N(c3ccccc3)c3cccc4ccccc34)ccc2-c2ccc3c(c21)C(C)(C)c1cc(N(c2ccccc2)c2cccc4ccccc24)ccc1-3] | (528) |
| 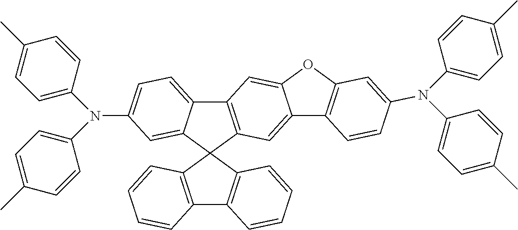 | (529) |
| 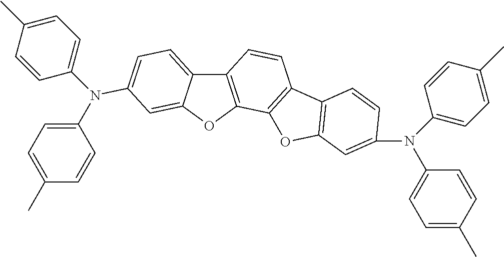 | (530) |
| 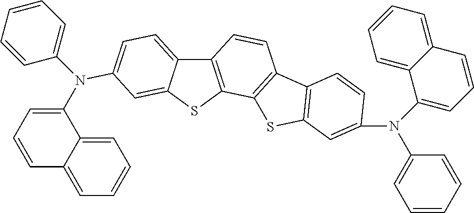 [SMILES: c1ccc(N(c2ccc3c(c2)sc2c3ccc3c4ccc(N(c5ccccc5)c5cccc6ccccc56)cc4sc32)c2cccc3ccccc23)cc1] | (531) |
| 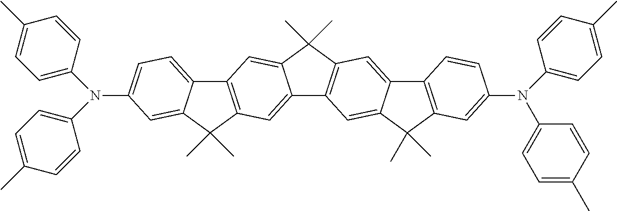 | (532) |
| 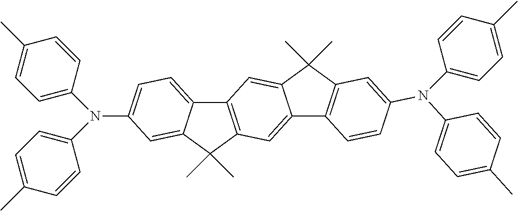 | (533) |
| 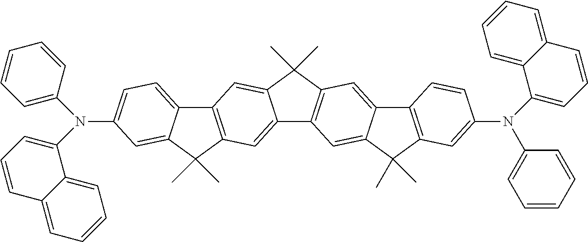 [SMILES: CC1(C)c2cc(N(c3ccccc3)c3cccc4ccccc34)ccc2-c2cc3c(cc21)-c1cc2c(cc1C3(C)C)-c1ccc(N(c3ccccc3)c3cccc4ccccc34)cc1C2(C)C] | (534) |
| 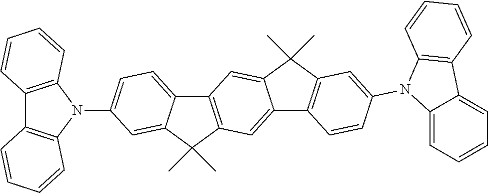 | (535) |
| 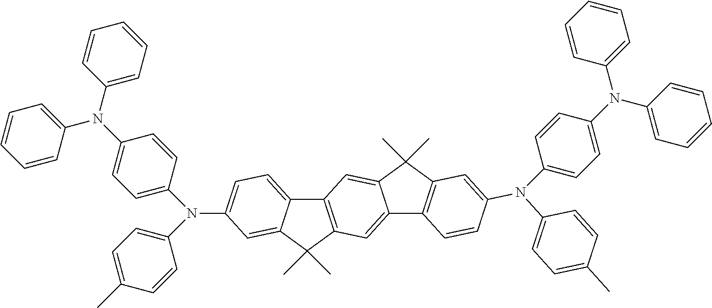 | (536) |
| 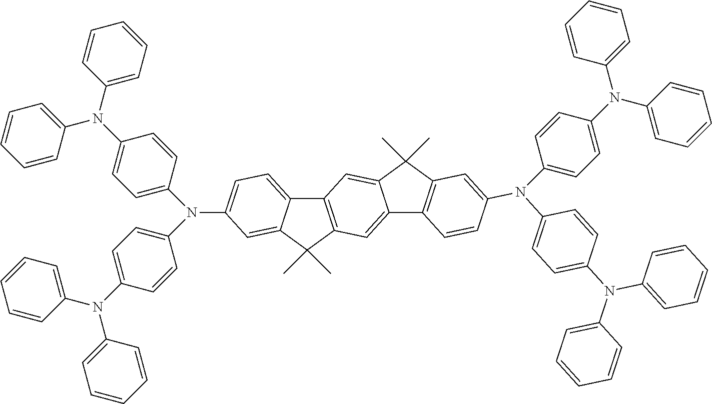 | (537) |
| 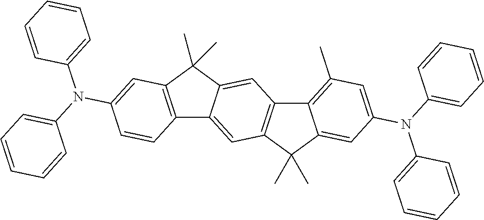 [SMILES: Cc1cc(N(c2ccccc2)c2ccccc2)cc2c1-c1cc3c(cc1C2(C)C)-c1ccc(N(c2ccccc2)c2ccccc2)cc1C3(C)C] | (538) |
| 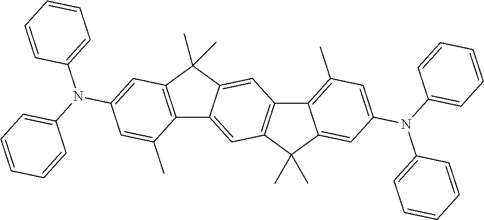 [SMILES: Cc1cc(N(c2ccccc2)c2ccccc2)cc2c1-c1cc3c(cc1C2(C)C)-c1c(C)cc(N(c2ccccc2)c2ccccc2)cc1C3(C)C] | (539) |
| 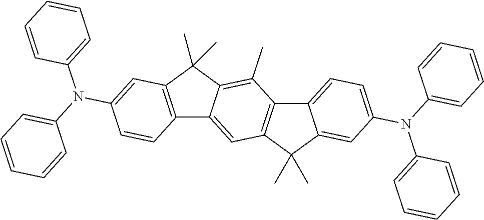 [SMILES: Cc1c2c(cc3c1C(C)(C)c1cc(N(c4ccccc4)c4ccccc4)ccc1-3)C(C)(C)c1cc(N(c3ccccc3)c3ccccc3)ccc1-2] | (540) |
| 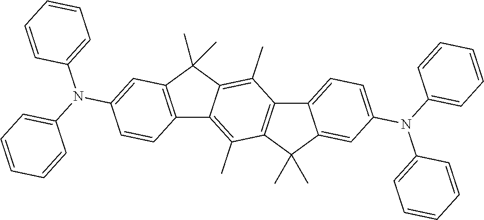 [SMILES: Cc1c2c(c(C)c3c1C(C)(C)c1cc(N(c4ccccc4)c4ccccc4)ccc1-3)C(C)(C)c1cc(N(c3ccccc3)c3ccccc3)ccc1-2] | (541) |
| 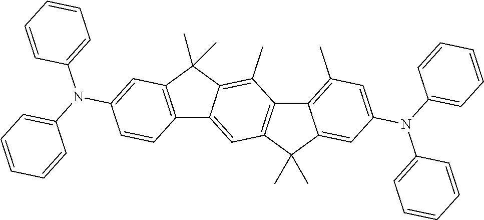 [SMILES: Cc1cc(N(c2ccccc2)c2ccccc2)cc2c1-c1c(cc3c(c1C)C(C)(C)c1cc(N(c4ccccc4)c4ccccc4)ccc1-3)C2(C)C] | (542) |
| 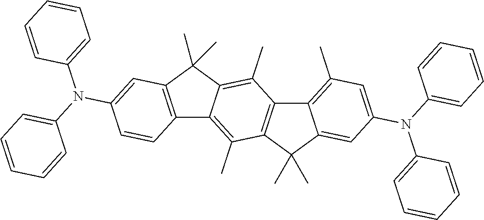 [SMILES: Cc1cc(N(c2ccccc2)c2ccccc2)cc2c1-c1c(C)c3c(c(C)c1C2(C)C)-c1ccc(N(c2ccccc2)c2ccccc2)cc1C3(C)C] | (543) |
| 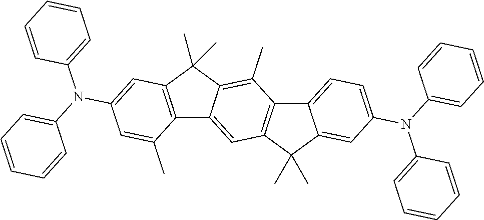 [SMILES: Cc1cc(N(c2ccccc2)c2ccccc2)cc2c1-c1cc3c(c(C)c1C2(C)C)-c1ccc(N(c2ccccc2)c2ccccc2)cc1C3(C)C] | (544) |
| 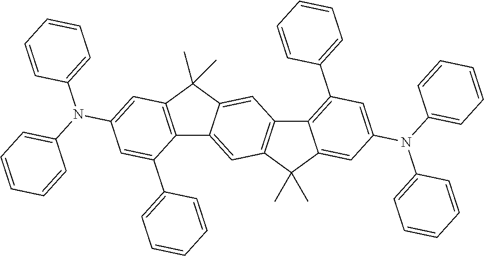 [SMILES: CC1(C)c2cc3c(cc2-c2c(-c4ccccc4)cc(N(c4ccccc4)c4ccccc4)cc21)C(C)(C)c1cc(N(c2ccccc2)c2ccccc2)cc(-c2ccccc2)c1-3] | (545) |
| 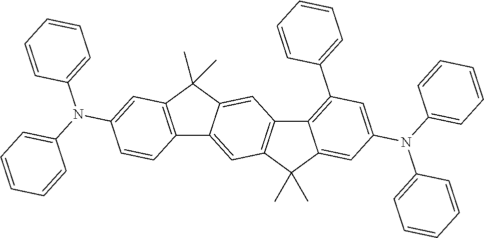 [SMILES: CC1(C)c2cc(N(c3ccccc3)c3ccccc3)ccc2-c2cc3c(cc21)-c1c(-c2ccccc2)cc(N(c2ccccc2)c2ccccc2)cc1C3(C)C] | (546) |
| 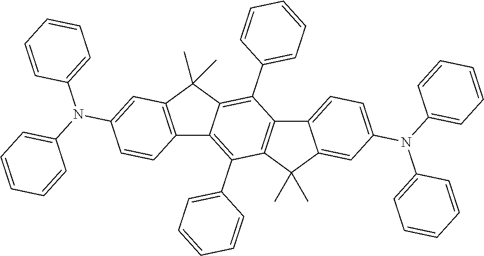 [SMILES: CC1(C)c2cc(N(c3ccccc3)c3ccccc3)ccc2-c2c(-c3ccccc3)c3c(c(-c4ccccc4)c21)-c1ccc(N(c2ccccc2)c2ccccc2)cc1C3(C)C] | (547) |
| 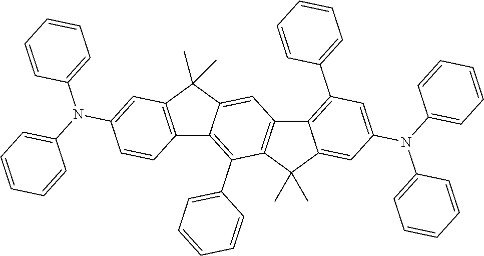 [SMILES: CC1(C)c2cc(N(c3ccccc3)c3ccccc3)ccc2-c2c1cc1c(c2-c2ccccc2)C(C)(C)c2cc(N(c3ccccc3)c3ccccc3)cc(-c3ccccc3)c2-1] | (548) |
| 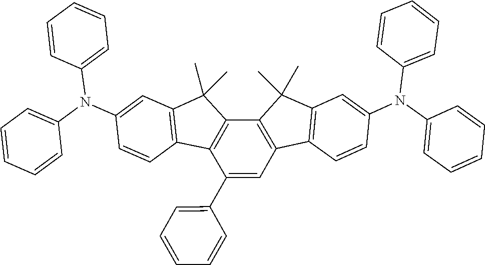 [SMILES: CC1(C)c2cc(N(c3ccccc3)c3ccccc3)ccc2-c2cc(-c3ccccc3)c3c(c21)C(C)(C)c1cc(N(c2ccccc2)c2ccccc2)ccc1-3] | (549) |
| 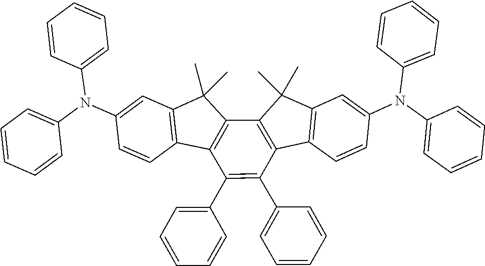 [SMILES: CC1(C)c2cc(N(c3ccccc3)c3ccccc3)ccc2-c2c(-c3ccccc3)c(-c3ccccc3)c3c(c21)C(C)(C)c1cc(N(c2ccccc2)c2ccccc2)ccc1-3] | (550) |
| 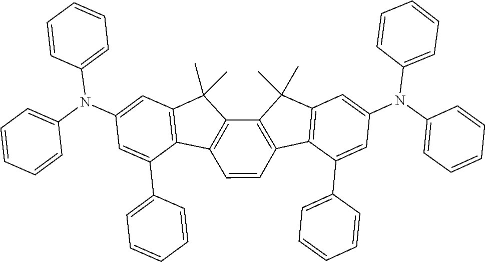 [SMILES: CC1(C)c2cc(N(c3ccccc3)c3ccccc3)cc(-c3ccccc3)c2-c2ccc3c(c21)C(C)(C)c1cc(N(c2ccccc2)c2ccccc2)cc(-c2ccccc2)c1-3] | (551) |
| 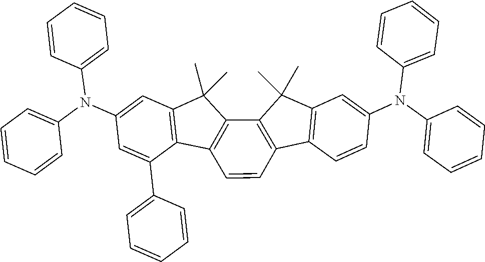 [SMILES: CC1(C)c2cc(N(c3ccccc3)c3ccccc3)ccc2-c2ccc3c(c21)C(C)(C)c1cc(N(c2ccccc2)c2ccccc2)cc(-c2ccccc2)c1-3] | (552) |
| 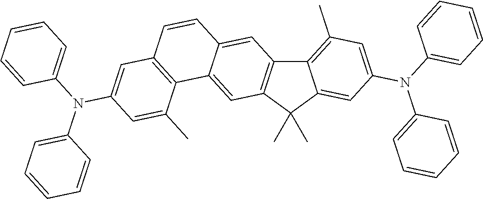 [SMILES: Cc1cc(N(c2ccccc2)c2ccccc2)cc2c1-c1cc3ccc4cc(N(c5ccccc5)c5ccccc5)cc(C)c4c3cc1C2(C)C] | (553) |
| 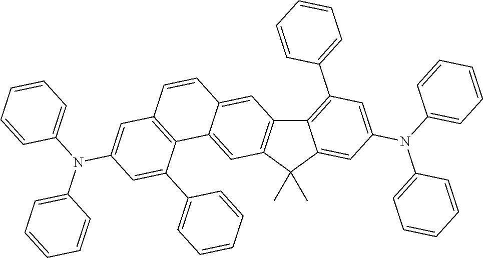 [SMILES: CC1(C)c2cc3c(ccc4cc(N(c5ccccc5)c5ccccc5)cc(-c5ccccc5)c43)cc2-c2c(-c3ccccc3)cc(N(c3ccccc3)c3ccccc3)cc21] | (554) |
| 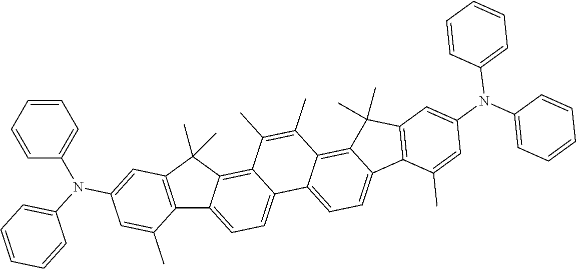 [SMILES: Cc1cc(N(c2ccccc2)c2ccccc2)cc2c1-c1ccc3c(c(C)c(C)c4c5c(ccc43)-c3c(C)cc(N(c4ccccc4)c4ccccc4)cc3C5(C)C)c1C2(C)C] | (555) |
| 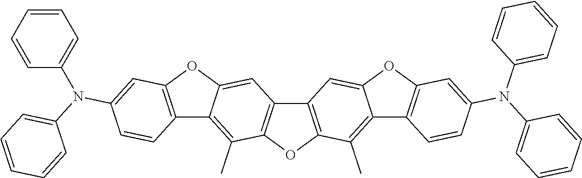 [SMILES: Cc1c2oc3c(C)c4c(cc3c2cc2oc3cc(N(c5ccccc5)c5ccccc5)ccc3c12)oc1cc(N(c2ccccc2)c2ccccc2)ccc14] | (556) |
| 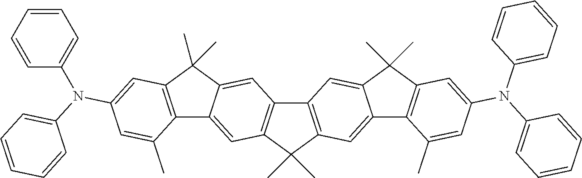 [SMILES: Cc1cc(N(c2ccccc2)c2ccccc2)cc2c1-c1cc3c(cc1C2(C)C)-c1cc2c(cc1C3(C)C)-c1c(C)cc(N(c3ccccc3)c3ccccc3)cc1C2(C)C] | (557) |
| 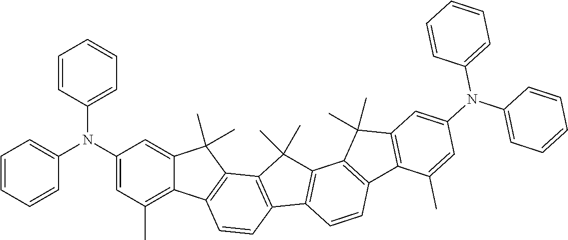 [SMILES: Cc1cc(N(c2ccccc2)c2ccccc2)cc2c1-c1ccc3c(c1C2(C)C)C(C)(C)c1c-3ccc2c1C(C)(C)c1cc(N(c3ccccc3)c3ccccc3)cc(C)c1-2] | (558) |
| 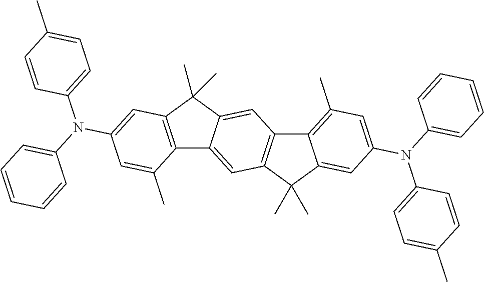 [SMILES: Cc1ccc(N(c2ccccc2)c2cc(C)c3c(c2)C(C)(C)c2cc4c(cc2-3)C(C)(C)c2cc(N(c3ccccc3)c3ccc(C)cc3)cc(C)c2-4)cc1] | (559) |
| 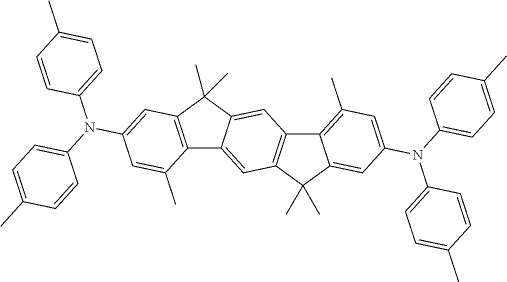 | (560) |
| 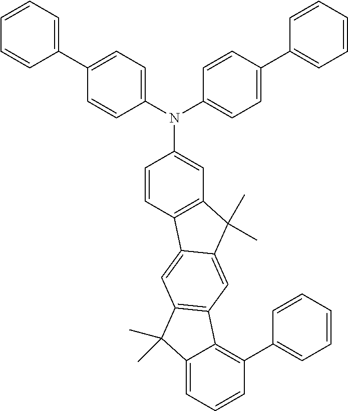 [SMILES: CC1(C)c2cc(N(c3ccc(-c4ccccc4)cc3)c3ccc(-c4ccccc4)cc3)ccc2-c2cc3c(cc21)-c1c(-c2ccccc2)cccc1C3(C)C] | (561) |
| 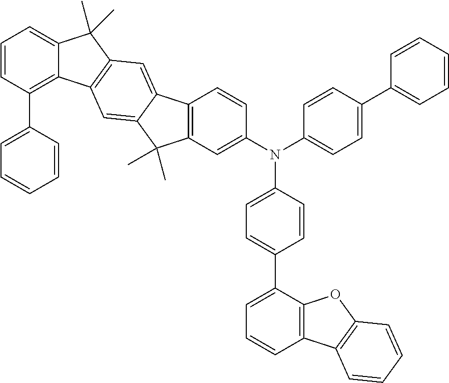 [SMILES: CC1(C)c2cc(N(c3ccc(-c4ccccc4)cc3)c3ccc(-c4cccc5c4oc4ccccc45)cc3)ccc2-c2cc3c(cc21)-c1c(-c2ccccc2)cccc1C3(C)C] | (562) |

Layer H2 is preferably an electron blocker layer and preferably directly adjoins the emitting layer on the anode side.

Layer H2 preferably comprises a triarylamine compound. More preferably, layer H2 comprises a monotriarylamine compound. A monotriarylamine compound is understood to mean a compound containing one triarylamino group and no more. It is further preferable that layer H2 comprises a triarylamine compound containing at least one group selected from spirobifluorenyl groups, fluorenyl groups, indenofluorenyl groups, dibenzofuranyl groups and dibenzothiophenyl groups. This may be bonded to the nitrogen atom of the amine directly or via an aromatic ring system, especially selected from phenylene, diphenylene and fluorenylene, as linker. More preferably, the spirobifluorenyl group is bonded in the 1, 3 or 4 position, even more preferably in the 1 or 4 position, most preferably in the 4 position. The fluorenyl group is more preferably bonded in the 1, 3 or 4 position, most preferably in the 4 position.

A preferred embodiment of the compound of the formula (L-1) for use in layer H2 conforms to a formula (L-1-2) or (L-1-3)

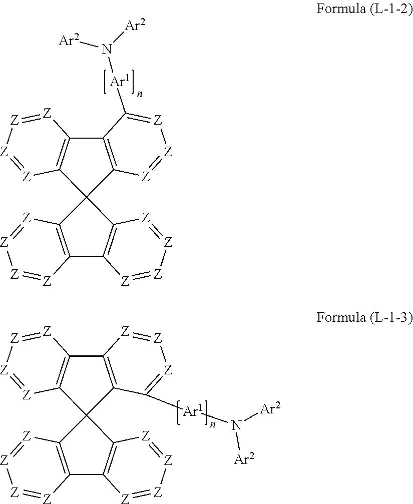

where Z is CR¹ and is preferably OH, and where the other variables that occur are as defined above.

A preferred embodiment of the compound of the formula (L-2) for use in layer H2 conforms to a formula (L-2-2)

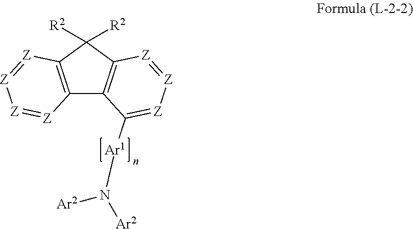

where Z is CR¹ and is preferably CH, and where the other variables that occur are as defined above.

It is especially preferable that layer H2 comprises a compound selected from compounds of the formulae (L-1), especially (L-1-2); (L-2), especially (L-2-2); (L-3), especially (L-3-1) and (L-3-2); (L-4) and (L-5), where formulae (L-4) and (L-5) are as defined below:

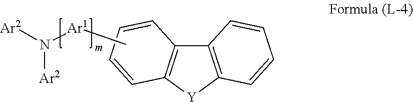

where the variables that occur are as follows:

Y is O, S or NR³;

m is 0, 1, 2 or 3; and

the unsubstituted positions on the benzene rings may each be substituted by an R³ radical; and Ar¹ and Ar² are as defined above; and

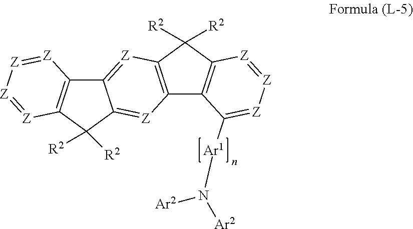

where Z is CR¹, preferably CH, and the other variables that occur are as defined above.

Layer H1 may comprise the compound of the formula (L-1), (L-2) or (L-3) as a pure material, or it may comprise the compound of the formula (L-1), (L-2) or (L-3) in combination with one or more further compounds. When such further compounds are present, they are preferably selected from p-dopants and from hole-transporting compounds. The further hole-transporting compounds are preferably selected from triarylamine compounds, more preferably from monotriarylamine compounds. With very particular preference they are selected from the preferred embodiments of hole transport materials that are indicated later on below. When the compound of the formula (L-1), (L-2) or (L-3) is present in layer H1 in combination with one or more further hole-transporting compounds, they and the further hole-transporting compounds are preferably each present in the layer in a proportion of at least 20%, more preferably each in a proportion of at least 30%.

Layer H1 may be p-doped, or it may be undoped. p-Dopants used according to the present invention are preferably those organic electron acceptor compounds capable of oxidizing one or more of the other compounds in the layer.

Particularly preferred p-dopants are quinodimethane compounds, azaindenofluorenediones, azaphenalenes, azatriphenylenes, I₂, metal halides, preferably transition metal halides, metal oxides, preferably metal oxides containing at least one transition metal or a metal of main group 3, and transition metal complexes, preferably complexes of Cu, Co, Ni, Pd and Pt with ligands containing at least one oxygen atom as bonding site. Preference is further given to transition metal oxides as dopants, preferably oxides of rhenium, molybdenum and tungsten, more preferably Re₂O₇, MoO₃, WO₃ and ReO₃. Still further preference is given to complexes of bismuth in the (III) oxidation state, more particularly bismuth(III) complexes with electron-deficient ligands, more particularly carboxylate ligands.

The p-dopants are preferably in substantially homogeneous distribution in the p-doped layers. This can be achieved, for example, by co-evaporation of the p-dopant and the hole transport material matrix. The p-dopant is preferably present in a proportion of 1% to 10% in the p-doped layer.

In the present application, figures in % are understood to mean % by volume where mixtures of compounds that are applied from the gas phase are concerned. By contrast, this is understood to mean % by mass where mixtures that are applied from solution are concerned.

Preferred p-dopants are especially the following compounds:

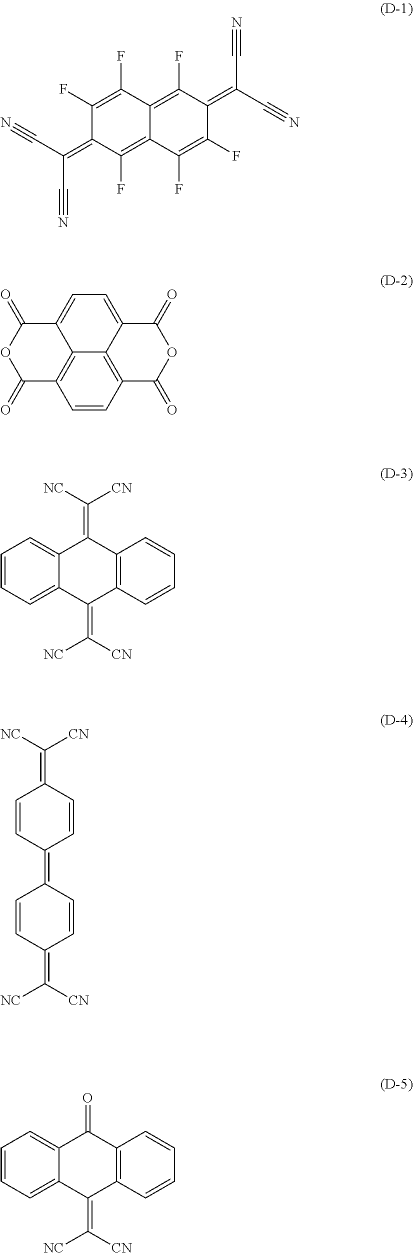 [SMILES: N#CC(C#N)=c1c(F)c(F)c2c(F)c(=C(C#N)C#N)c(F)c(F)c2c1F ; O=C1OC(=O)c2ccc3c4c(ccc1c24)C(=O)OC3=O ; N#CC(C#N)=c1c2ccccc2c(=C(C#N)C#N)c2ccccc12 ; N#CC(C#N)=c1ccc(=c2ccc(=C(C#N)C#N)cc2)cc1 ; N#CC(C#N)=C1c2ccccc2C(=O)c2ccccc21]

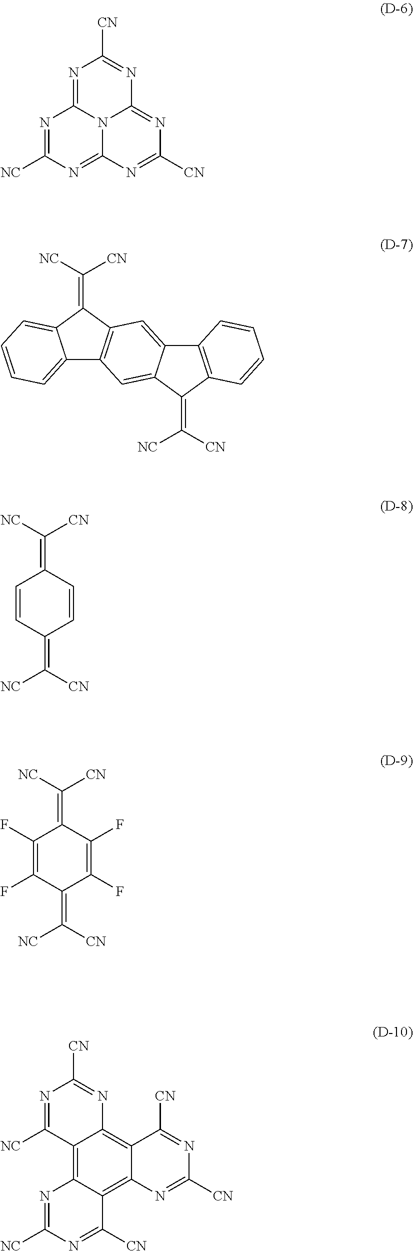 [SMILES: N#CC1=NC2=NC(C#N)=NC3=NC(C#N)=NC(=N1)N23 ; N#CC(C#N)=C1c2ccccc2-c2cc3c(cc21)-c1ccccc1C3=C(C#N)C#N ; N#CC(C#N)=c1ccc(=C(C#N)C#N)cc1 ; N#CC(C#N)=c1c(F)c(F)c(=C(C#N)C#N)c(F)c1F ; N#Cc1nc(C#N)c2c(n1)c1c(C#N)nc(C#N)nc1c1c(C#N)nc(C#N)nc21]

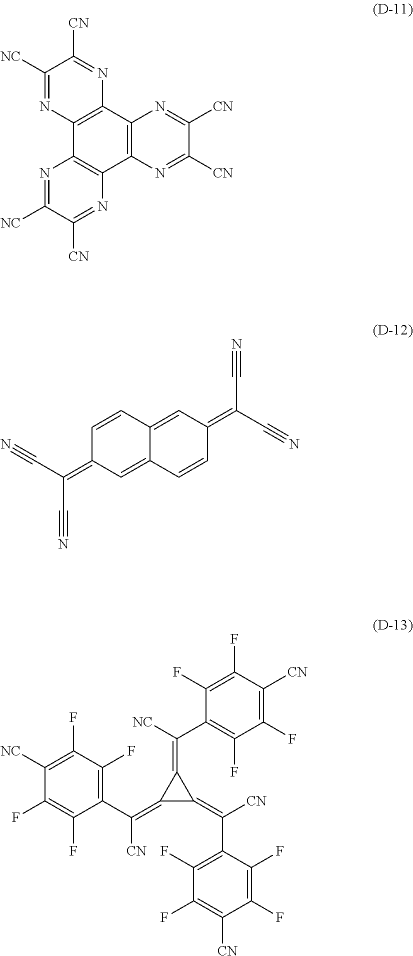 [SMILES: N#Cc1nc2c3nc(C#N)c(C#N)nc3c3nc(C#N)c(C#N)nc3c2nc1C#N ; N#CC(C#N)=c1ccc2cc(=C(C#N)C#N)ccc2c1 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

In hole-transporting layers of the device, such as hole injection layers, hole transport layers and electron blocker layers, preference is given to using indenofluoreneamine derivatives, amine derivatives, hexaazatriphenylene derivatives, amine derivatives with fused aromatic systems, monobenzoindenofluoreneamines, dibenzoindenofluoreneamines, spirobifluoreneamines, fluoreneamines, spirodibenzopyranamines, dihydroacridine derivatives, spirodibenzofurans and spirodibenzothiophenes, phenanthrenediarylamines, spirotribenzotropolones, spirobifluorenes having meta-phenyldiamine groups, spirobisacridines, xanthenediarylamines, and 9,10-dihydroanthracene spiro compounds having diarylamino groups. Explicit examples of compounds for use in hole-transporting layers are shown in the following table:

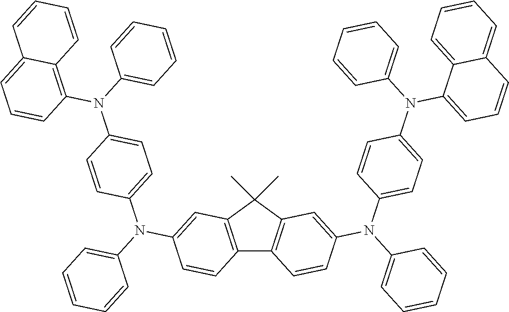 [SMILES: CC1(C)c2cc(N(c3ccccc3)c3ccc(N(c4ccccc4)c4cccc5ccccc45)cc3)ccc2-c2ccc(N(c3ccccc3)c3ccc(N(c4ccccc4)c4cccc5ccccc45)cc3)cc21]

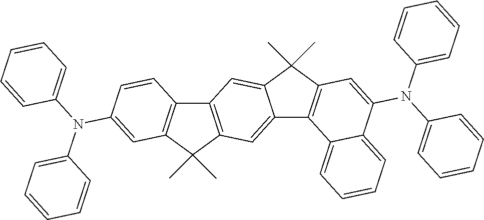 [SMILES: CC1(C)c2cc(N(c3ccccc3)c3ccccc3)ccc2-c2cc3c(cc21)-c1c(cc(N(c2ccccc2)c2ccccc2)c2ccccc12)C3(C)C]

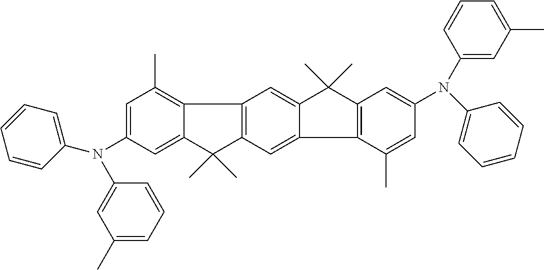 [SMILES: Cc1cccc(N(c2ccccc2)c2cc(C)c3c(c2)C(C)(C)c2cc4c(cc2-3)C(C)(C)c2cc(N(c3ccccc3)c3cccc(C)c3)cc(C)c2-4)c1]

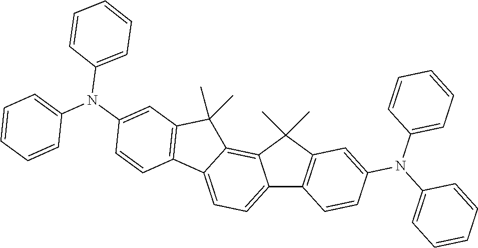 [SMILES: CC1(C)c2cc(N(c3ccccc3)c3ccccc3)ccc2-c2ccc3c(c21)C(C)(C)c1cc(N(c2ccccc2)c2ccccc2)ccc1-3]

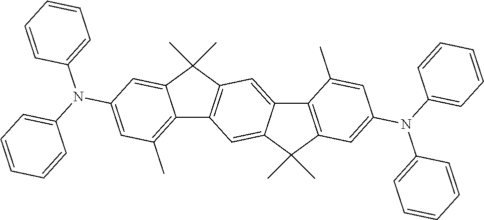 [SMILES: Cc1cc(N(c2ccccc2)c2ccccc2)cc2c1-c1cc3c(cc1C2(C)C)-c1c(C)cc(N(c2ccccc2)c2ccccc2)cc1C3(C)C]

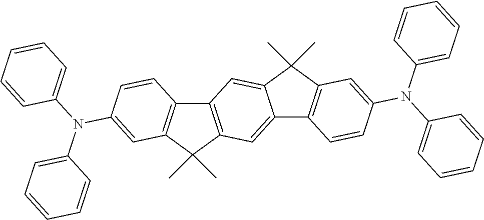 [SMILES: CC1(C)c2cc(N(c3ccccc3)c3ccccc3)ccc2-c2cc3c(cc21)-c1ccc(N(c2ccccc2)c2ccccc2)cc1C3(C)C]

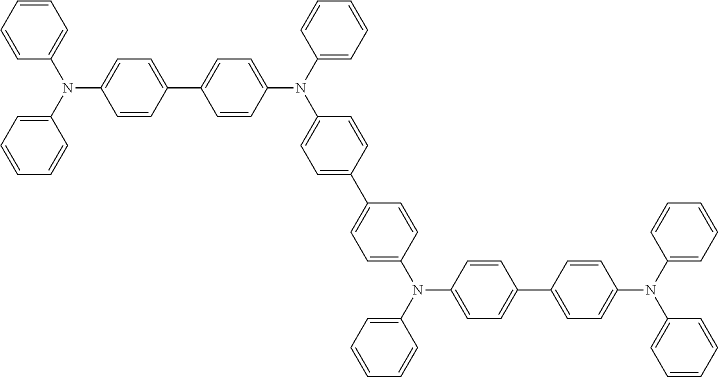 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1]

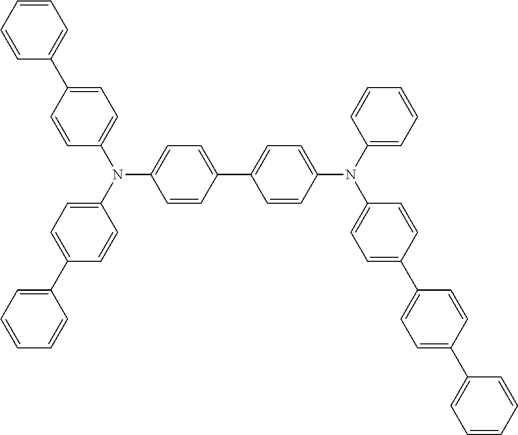 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

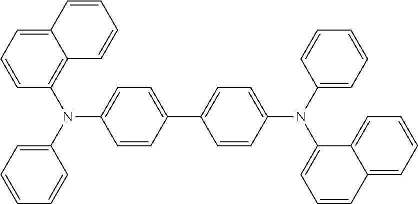 [SMILES: c1ccc(N(c2ccc(-c3ccc(N(c4ccccc4)c4cccc5ccccc45)cc3)cc2)c2cccc3ccccc23)cc1]

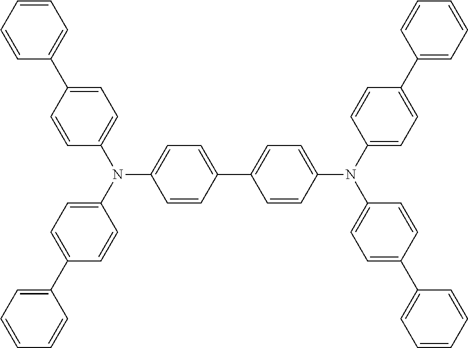 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

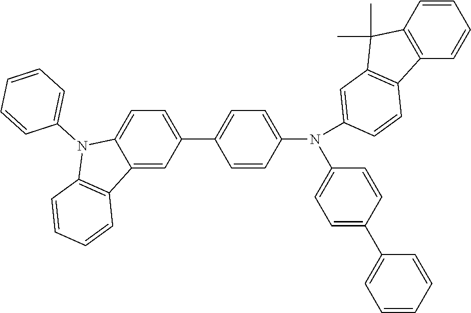 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21]

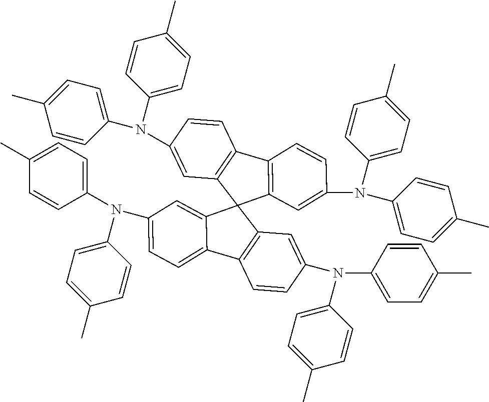

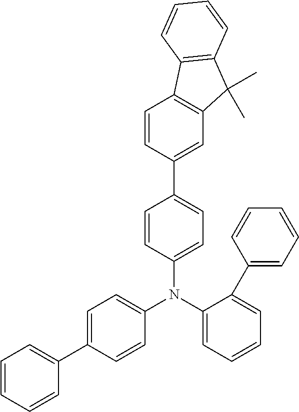 [SMILES: CC1(C)c2ccccc2-c2ccc(-c3ccc(N(c4ccc(-c5ccccc5)cc4)c4ccccc4-c4ccccc4)cc3)cc21]

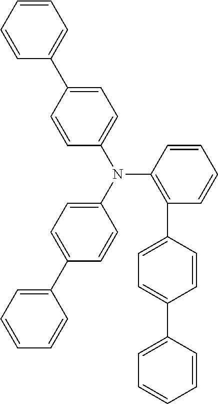 [SMILES: c1ccc(-c2ccc(-c3ccccc3N(c3ccc(-c4ccccc4)cc3)c3ccc(-c4ccccc4)cc3)cc2)cc1]

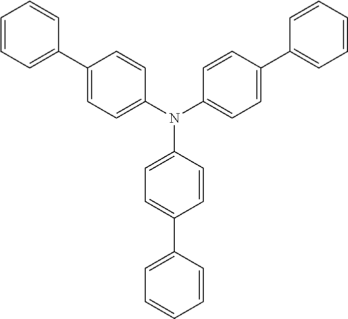 [SMILES: c1ccc(-c2ccc(N(c3ccc(-c4ccccc4)cc3)c3ccc(-c4ccccc4)cc3)cc2)cc1]

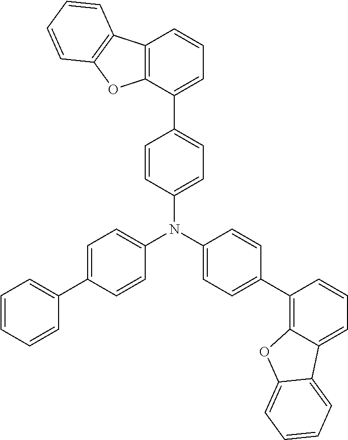 [SMILES: c1ccc(-c2ccc(N(c3ccc(-c4cccc5c4oc4ccccc45)cc3)c3ccc(-c4cccc5c4oc4ccccc45)cc3)cc2)cc1]

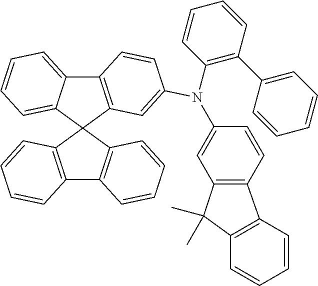 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

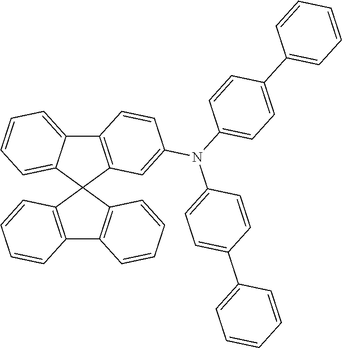 [SMILES: c1ccc(-c2ccc(N(c3ccc(-c4ccccc4)cc3)c3ccc4c(c3)C3(c5ccccc5-c5ccccc53)c3ccccc3-4)cc2)cc1]

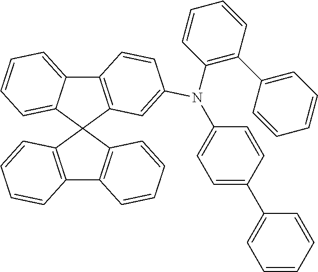 [SMILES: c1ccc(-c2ccc(N(c3ccc4c(c3)C3(c5ccccc5-c5ccccc53)c3ccccc3-4)c3ccccc3-c3ccccc3)cc2)cc1]

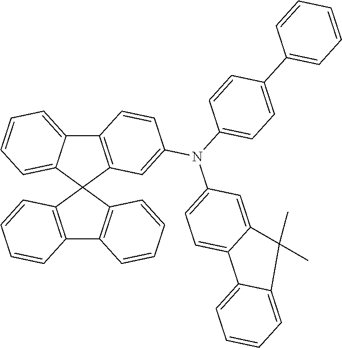 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21]

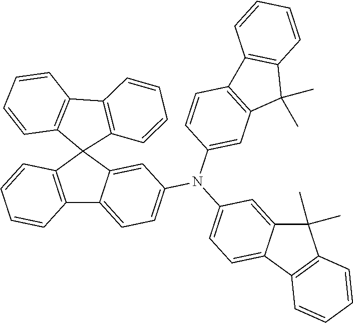 [SMILES: CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21]

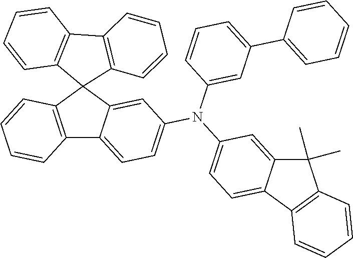 [SMILES: CC1(C)c2ccccc2-c2ccc(N(c3cccc(-c4ccccc4)c3)c3ccc4c(c3)C3(c5ccccc5-c5ccccc53)c3ccccc3-4)cc21]

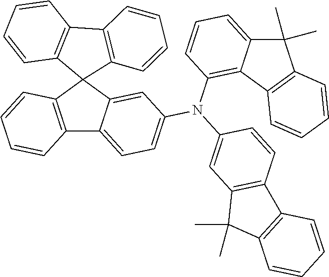 [SMILES: CC1(C)c2ccccc2-c2ccc(N(c3ccc4c(c3)C3(c5ccccc5-c5ccccc53)c3ccccc3-4)c3cccc4c3-c3ccccc3C4(C)C)cc21]

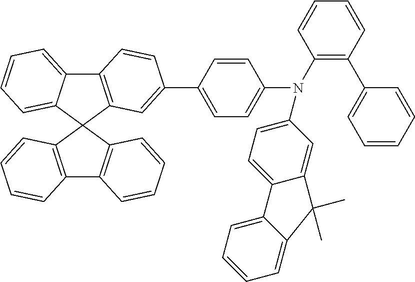 [SMILES: CC1(C)c2ccccc2-c2ccc(N(c3ccc(-c4ccc5c(c4)C4(c6ccccc6-c6ccccc64)c4ccccc4-5)cc3)c3ccccc3-c3ccccc3)cc21]

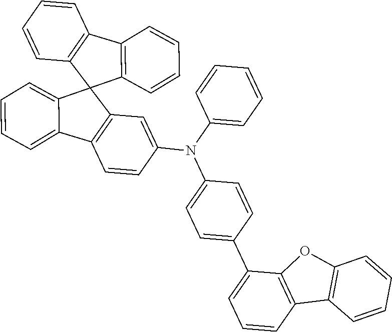 [SMILES: c1ccc(N(c2ccc(-c3cccc4c3oc3ccccc34)cc2)c2ccc3c(c2)C2(c4ccccc4-c4ccccc42)c2ccccc2-3)cc1]

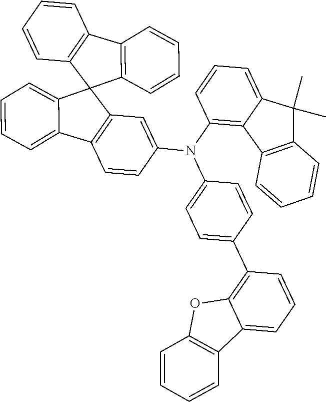 [SMILES: CC1(C)c2ccccc2-c2c(N(c3ccc(-c4cccc5c4oc4ccccc45)cc3)c3ccc4c(c3)C3(c5ccccc5-c5ccccc53)c3ccccc3-4)cccc21]

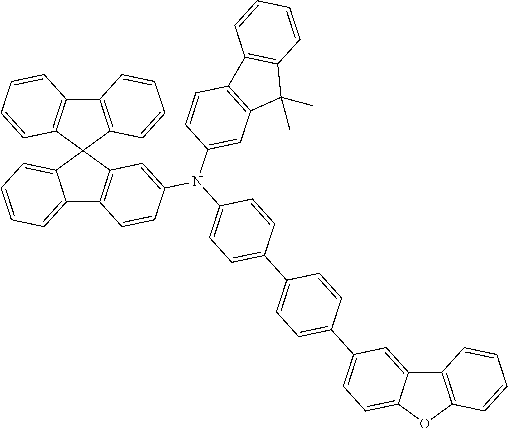 [SMILES: CC1(C)c2ccccc2-c2ccc(N(c3ccc(-c4ccc(-c5ccc6oc7ccccc7c6c5)cc4)cc3)c3ccc4c(c3)C3(c5ccccc5-c5ccccc53)c3ccccc3-4)cc21]

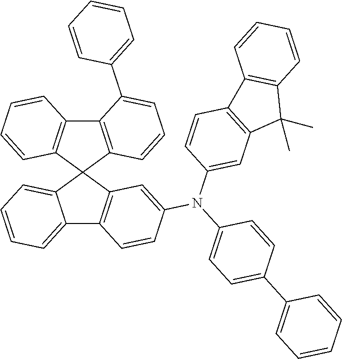 [SMILES: CC1(C)c2ccccc2-c2ccc(N(c3ccc(-c4ccccc4)cc3)c3ccc4c(c3)C3(c5ccccc5-4)c4ccccc4-c4c(-c5ccccc5)cccc43)cc21]

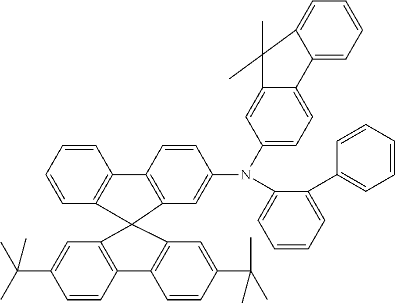 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

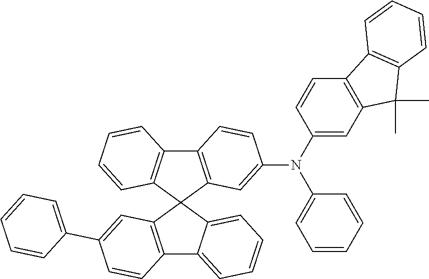 [SMILES: CC1(C)c2ccccc2-c2ccc(N(c3ccccc3)c3ccc4c(c3)C3(c5ccccc5-c5ccc(-c6ccccc6)cc53)c3ccccc3-4)cc21]

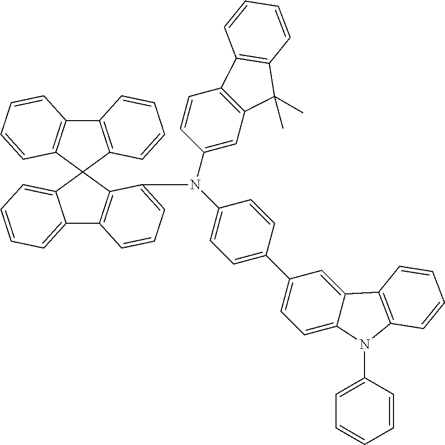 [SMILES: CC1(C)c2ccccc2-c2ccc(N(c3ccc(-c4ccc5c(c4)c4ccccc4n5-c4ccccc4)cc3)c3cccc4c3C3(c5ccccc5-c5ccccc53)c3ccccc3-4)cc21]

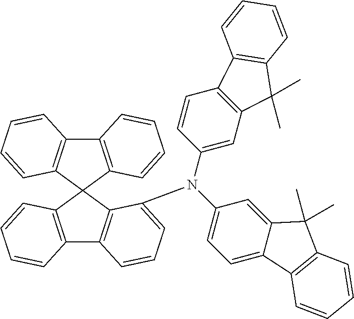 [SMILES: CC1(C)c2ccccc2-c2ccc(N(c3ccc4c(c3)C(C)(C)c3ccccc3-4)c3cccc4c3C3(c5ccccc5-c5ccccc53)c3ccccc3-4)cc21]

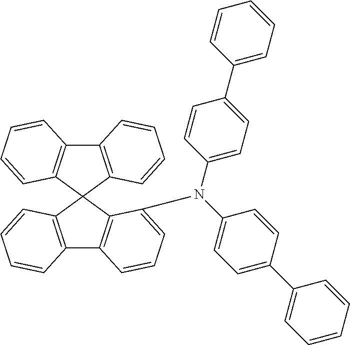 [SMILES: c1ccc(-c2ccc(N(c3ccc(-c4ccccc4)cc3)c3cccc4c3C3(c5ccccc5-c5ccccc53)c3ccccc3-4)cc2)cc1]

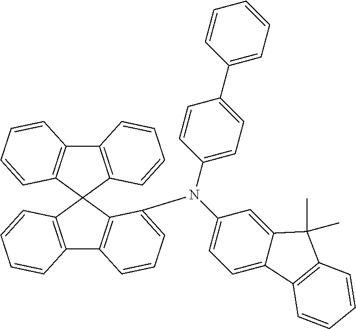 [SMILES: CC1(C)c2ccccc2-c2ccc(N(c3ccc(-c4ccccc4)cc3)c3cccc4c3C3(c5ccccc5-c5ccccc53)c3ccccc3-4)cc21]

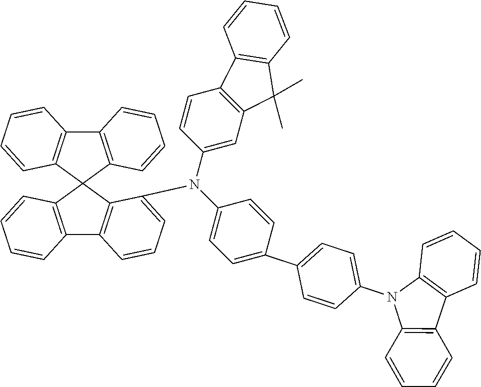 [SMILES: CC1(C)c2ccccc2-c2ccc(N(c3ccc(-c4ccc(-n5c6ccccc6c6ccccc65)cc4)cc3)c3cccc4c3C3(c5ccccc5-c5ccccc53)c3ccccc3-4)cc21]

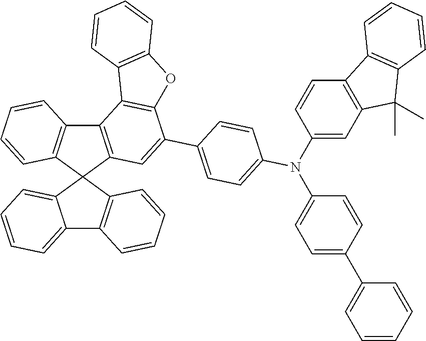 [SMILES: CC1(C)c2ccccc2-c2ccc(N(c3ccc(-c4ccccc4)cc3)c3ccc(-c4cc5c(c6c4oc4ccccc46)-c4ccccc4C54c5ccccc5-c5ccccc54)cc3)cc21]

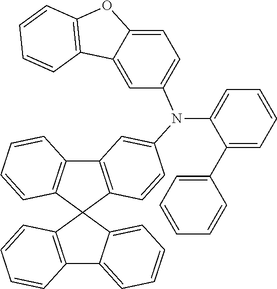 [SMILES: c1ccc(-c2ccccc2N(c2ccc3c(c2)-c2ccccc2C32c3ccccc3-c3ccccc32)c2ccc3oc4ccccc4c3c2)cc1]

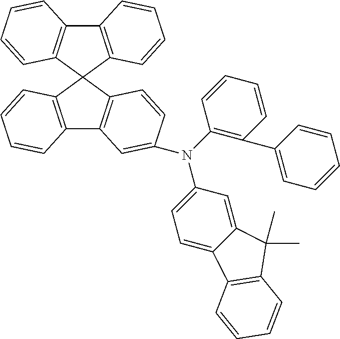 [SMILES: CC1(C)c2ccccc2-c2ccc(N(c3ccc4c(c3)-c3ccccc3C43c4ccccc4-c4ccccc43)c3ccccc3-c3ccccc3)cc21]

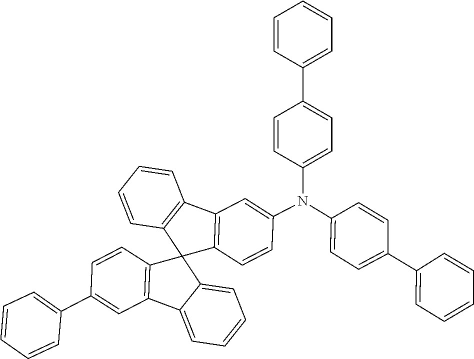 [SMILES: c1ccc(-c2ccc(N(c3ccc(-c4ccccc4)cc3)c3ccc4c(c3)-c3ccccc3C43c4ccccc4-c4cc(-c5ccccc5)ccc43)cc2)cc1]

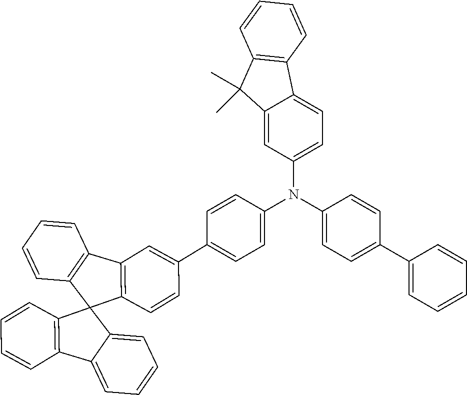 [SMILES: CC1(C)c2ccccc2-c2ccc(N(c3ccc(-c4ccccc4)cc3)c3ccc(-c4ccc5c(c4)-c4ccccc4C54c5ccccc5-c5ccccc54)cc3)cc21]

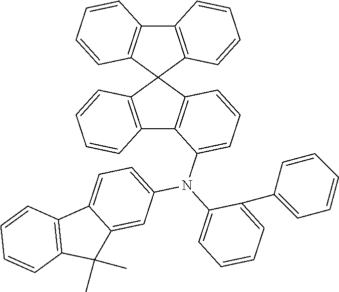 [SMILES: CC1(C)c2ccccc2-c2ccc(N(c3ccccc3-c3ccccc3)c3cccc4c3-c3ccccc3C43c4ccccc4-c4ccccc43)cc21]

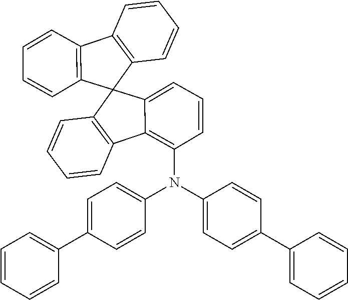 [SMILES: c1ccc(-c2ccc(N(c3ccc(-c4ccccc4)cc3)c3cccc4c3-c3ccccc3C43c4ccccc4-c4ccccc43)cc2)cc1]

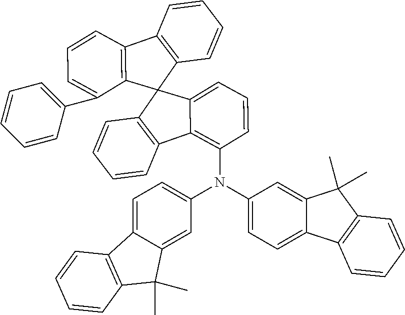 [SMILES: CC1(C)c2ccccc2-c2ccc(N(c3ccc4c(c3)C(C)(C)c3ccccc3-4)c3cccc4c3-c3ccccc3C43c4ccccc4-c4cccc(-c5ccccc5)c43)cc21]

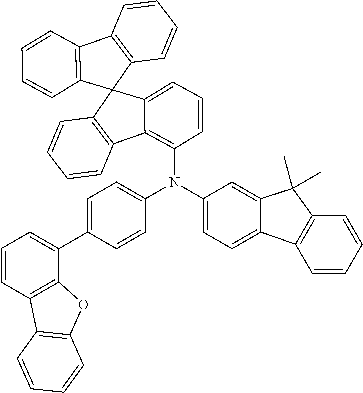 [SMILES: CC1(C)c2ccccc2-c2ccc(N(c3ccc(-c4cccc5c4oc4ccccc45)cc3)c3cccc4c3-c3ccccc3C43c4ccccc4-c4ccccc43)cc21]

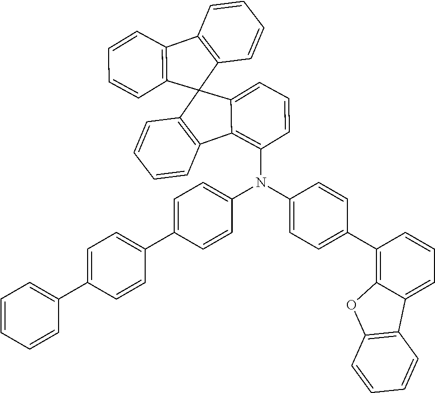 [SMILES: c1ccc(-c2ccc(-c3ccc(N(c4ccc(-c5cccc6c5oc5ccccc56)cc4)c4cccc5c4-c4ccccc4C54c5ccccc5-c5ccccc54)cc3)cc2)cc1]

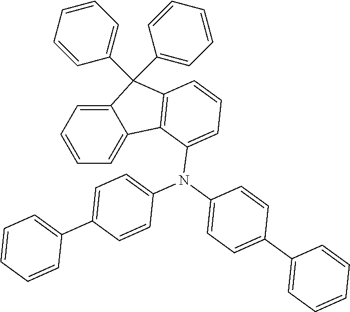 [SMILES: c1ccc(-c2ccc(N(c3ccc(-c4ccccc4)cc3)c3cccc4c3-c3ccccc3C4(c3ccccc3)c3ccccc3)cc2)cc1]

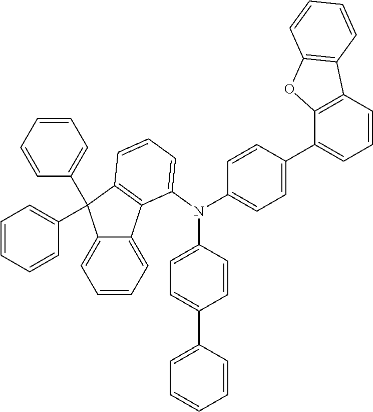 [SMILES: c1ccc(-c2ccc(N(c3ccc(-c4cccc5c4oc4ccccc45)cc3)c3cccc4c3-c3ccccc3C4(c3ccccc3)c3ccccc3)cc2)cc1]

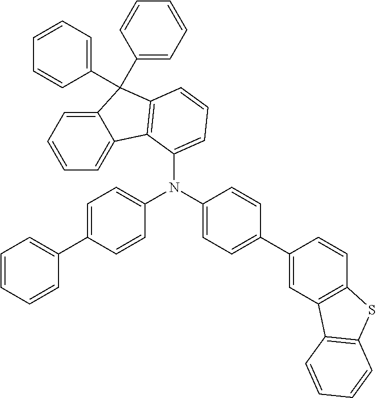 [SMILES: c1ccc(-c2ccc(N(c3ccc(-c4ccc5sc6ccccc6c5c4)cc3)c3cccc4c3-c3ccccc3C4(c3ccccc3)c3ccccc3)cc2)cc1]

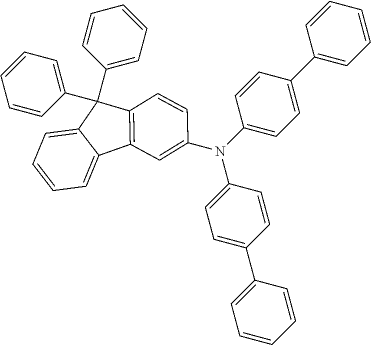 [SMILES: c1ccc(-c2ccc(N(c3ccc(-c4ccccc4)cc3)c3ccc4c(c3)-c3ccccc3C4(c3ccccc3)c3ccccc3)cc2)cc1]

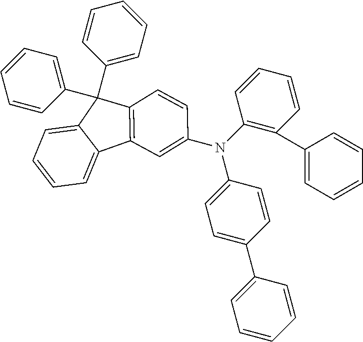 [SMILES: c1ccc(-c2ccc(N(c3ccc4c(c3)-c3ccccc3C4(c3ccccc3)c3ccccc3)c3ccccc3-c3ccccc3)cc2)cc1]

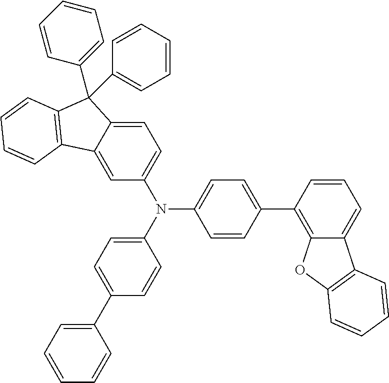 [SMILES: c1ccc(-c2ccc(N(c3ccc(-c4cccc5c4oc4ccccc45)cc3)c3ccc4c(c3)-c3ccccc3C4(c3ccccc3)c3ccccc3)cc2)cc1]

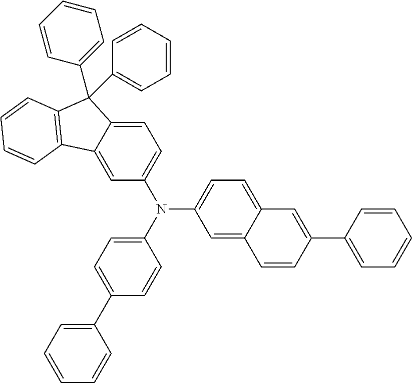 [SMILES: c1ccc(-c2ccc(N(c3ccc4c(c3)-c3ccccc3C4(c3ccccc3)c3ccccc3)c3ccc4cc(-c5ccccc5)ccc4c3)cc2)cc1]

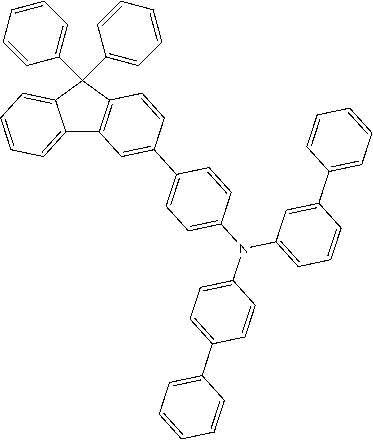 [SMILES: c1ccc(-c2ccc(N(c3ccc(-c4ccc5c(c4)-c4ccccc4C5(c4ccccc4)c4ccccc4)cc3)c3cccc(-c4ccccc4)c3)cc2)cc1]

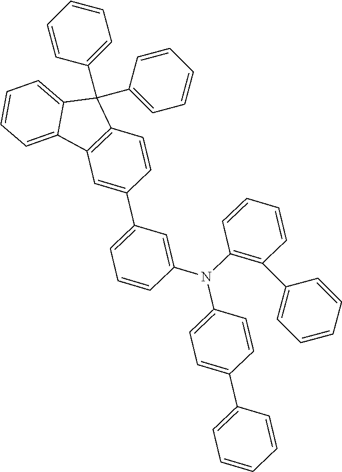 [SMILES: c1ccc(-c2ccc(N(c3cccc(-c4ccc5c(c4)-c4ccccc4C5(c4ccccc4)c4ccccc4)c3)c3ccccc3-c3ccccc3)cc2)cc1]

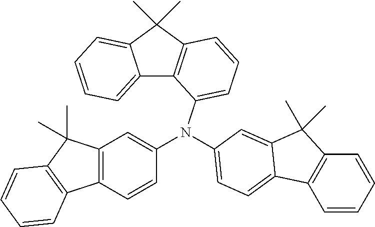 [SMILES: CC1(C)c2ccccc2-c2ccc(N(c3ccc4c(c3)C(C)(C)c3ccccc3-4)c3cccc4c3-c3ccccc3C4(C)C)cc21]

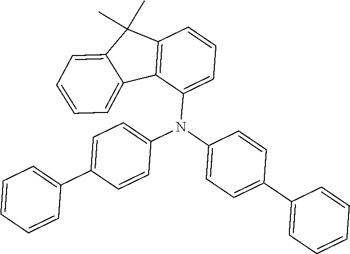

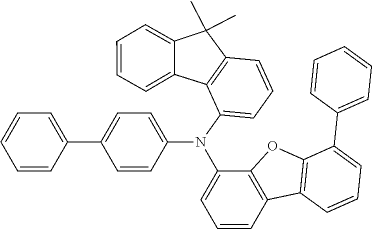

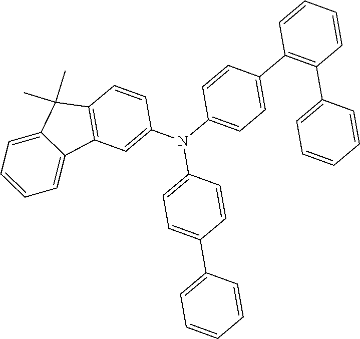

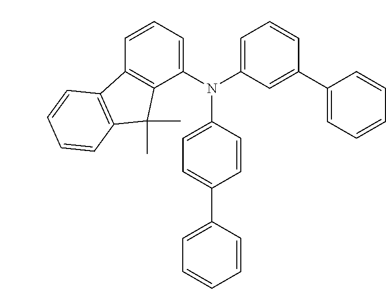

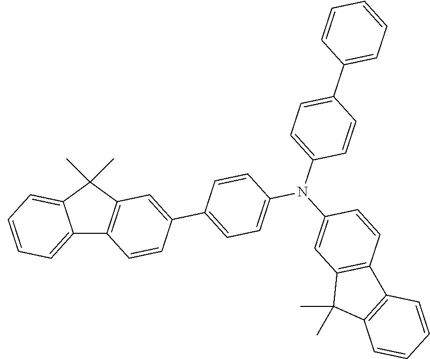

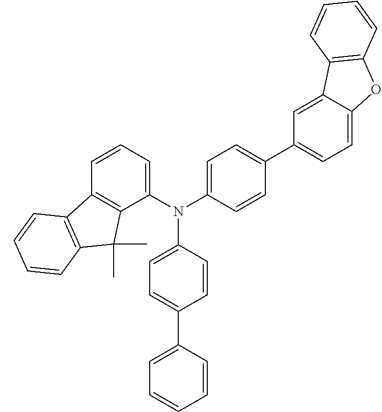

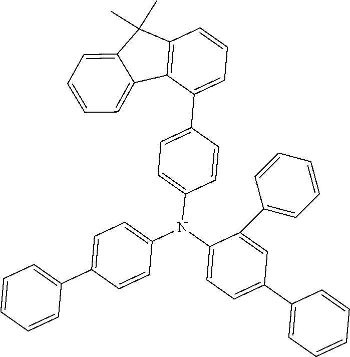

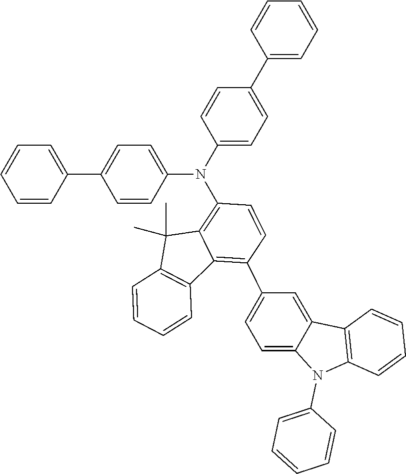 [SMILES: CC1(C)c2ccccc2-c2c(-c3ccc4c(c3)c3ccccc3n4-c3ccccc3)ccc(N(c3ccc(-c4ccccc4)cc3)c3ccc(-c4ccccc4)cc3)c21]

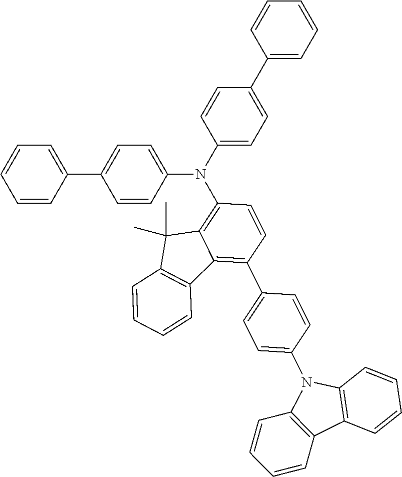 [SMILES: CC1(C)c2ccccc2-c2c(-c3ccc(-n4c5ccccc5c5ccccc54)cc3)ccc(N(c3ccc(-c4ccccc4)cc3)c3ccc(-c4ccccc4)cc3)c21]

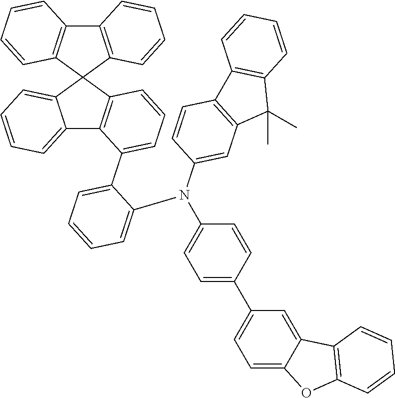 [SMILES: CC1(C)c2ccccc2-c2ccc(N(c3ccc(-c4ccc5oc6ccccc6c5c4)cc3)c3ccccc3-c3cccc4c3-c3ccccc3C43c4ccccc4-c4ccccc43)cc21]

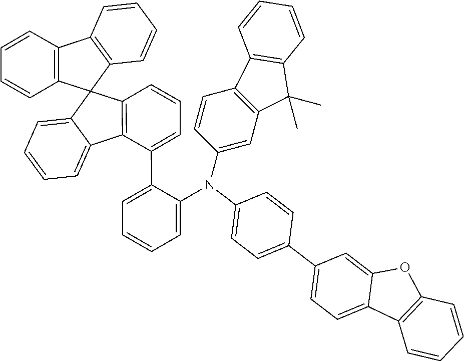 [SMILES: CC1(C)c2ccccc2-c2ccc(N(c3ccc(-c4ccc5c(c4)oc4ccccc45)cc3)c3ccccc3-c3cccc4c3-c3ccccc3C43c4ccccc4-c4ccccc43)cc21]

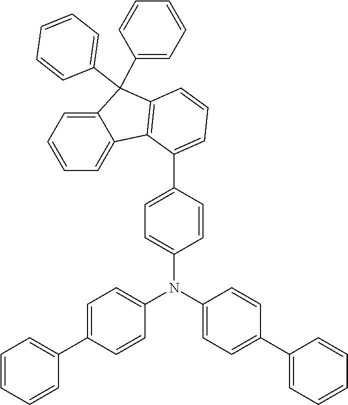 [SMILES: c1ccc(-c2ccc(N(c3ccc(-c4ccccc4)cc3)c3ccc(-c4cccc5c4-c4ccccc4C5(c4ccccc4)c4ccccc4)cc3)cc2)cc1]

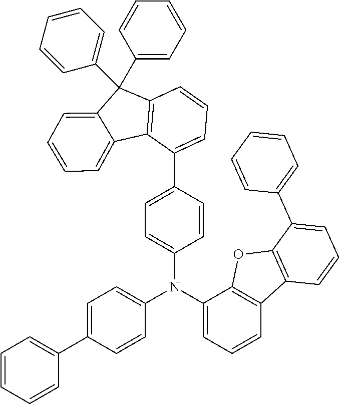 [SMILES: c1ccc(-c2ccc(N(c3ccc(-c4cccc5c4-c4ccccc4C5(c4ccccc4)c4ccccc4)cc3)c3cccc4c3oc3c(-c5ccccc5)cccc34)cc2)cc1]

In addition, the following compounds HT-1 to HT-38 are suitable for use in a layer having a hole-transporting function, especially in a hole injection layer, a hole transport layer and/or an electron blocker layer, or for use in an emitting layer as matrix material, especially as matrix material in an emitting layer comprising one or more phosphorescent emitters:

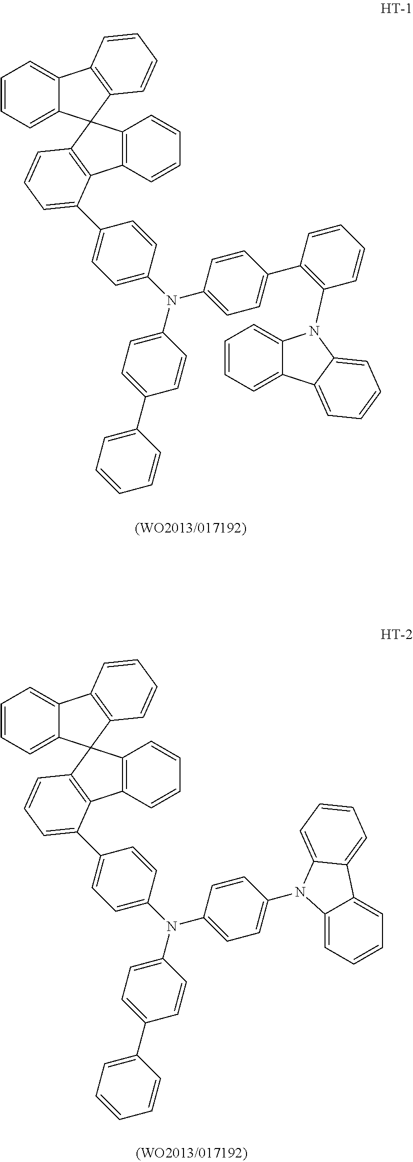 [SMILES: c1ccc(-c2ccc(N(c3ccc(-c4ccccc4-n4c5ccccc5c5ccccc54)cc3)c3ccc(-c4cccc5c4-c4ccccc4C54c5ccccc5-c5ccccc54)cc3)cc2)cc1 ; c1ccc(-c2ccc(N(c3ccc(-c4cccc5c4-c4ccccc4C54c5ccccc5-c5ccccc54)cc3)c3ccc(-n4c5ccccc5c5ccccc54)cc3)cc2)cc1]

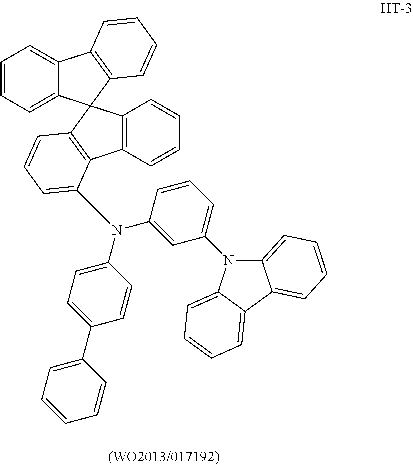 [SMILES: c1ccc(-c2ccc(N(c3cccc(-n4c5ccccc5c5ccccc54)c3)c3cccc4c3-c3ccccc3C43c4ccccc4-c4ccccc43)cc2)cc1]

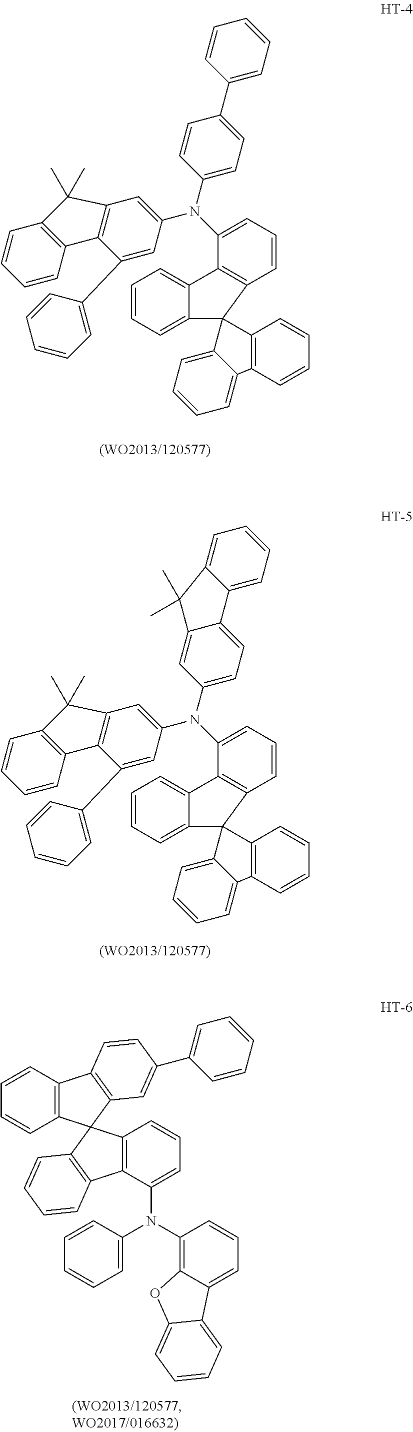 [SMILES: CC1(C)c2ccccc2-c2c(-c3ccccc3)cc(N(c3ccc(-c4ccccc4)cc3)c3cccc4c3-c3ccccc3C43c4ccccc4-c4ccccc43)cc21 ; CC1(C)c2ccccc2-c2ccc(N(c3cc(-c4ccccc4)c4c(c3)C(C)(C)c3ccccc3-4)c3cccc4c3-c3ccccc3C43c4ccccc4-c4ccccc43)cc21 ; c1ccc(-c2ccc3c(c2)C2(c4ccccc4-3)c3ccccc3-c3c(N(c4ccccc4)c4cccc5c4oc4ccccc45)cccc32)cc1]

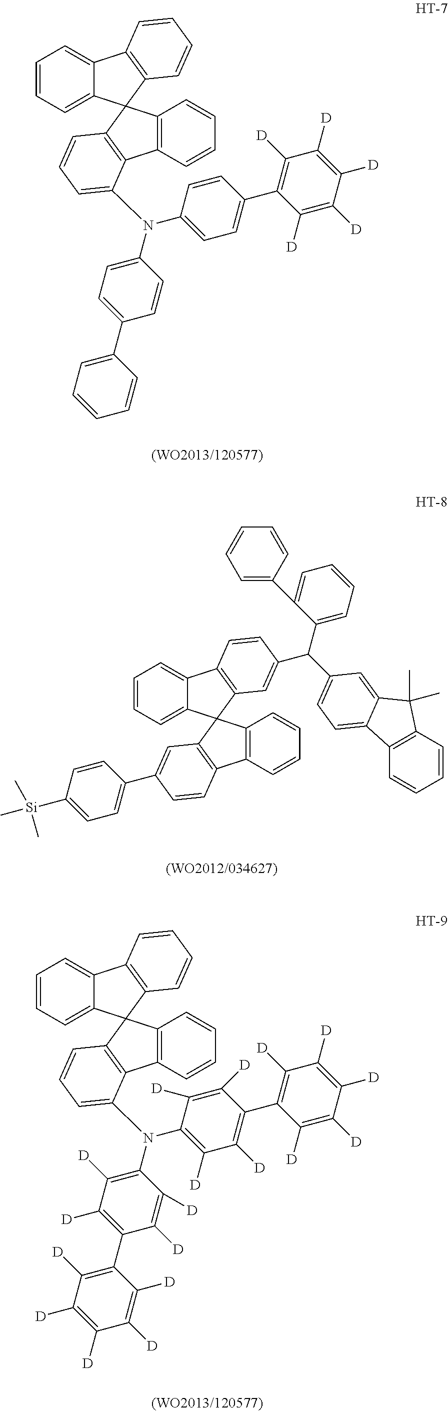 [SMILES: [2H]c1c([2H])c([2H])c(-c2ccc(N(c3ccc(-c4ccccc4)cc3)c3cccc4c3-c3ccccc3C43c4ccccc4-c4ccccc43)cc2)c([2H])c1[2H] ; CC1(C)c2ccccc2-c2ccc(C(c3ccc4c(c3)C3(c5ccccc5-c5ccc(-c6ccc([Si](C)(C)C)cc6)cc53)c3ccccc3-4)c3ccccc3-c3ccccc3)cc21 ; [2H]c1c([2H])c([2H])c(-c2c([2H])c([2H])c(N(c3cccc4c3-c3ccccc3C43c4ccccc4-c4ccccc43)c3c([2H])c([2H])c(-c4c([2H])c([2H])c([2H])c([2H])c4[2H])c([2H])c3[2H])c([2H])c2[2H])c([2H])c1[2H]]

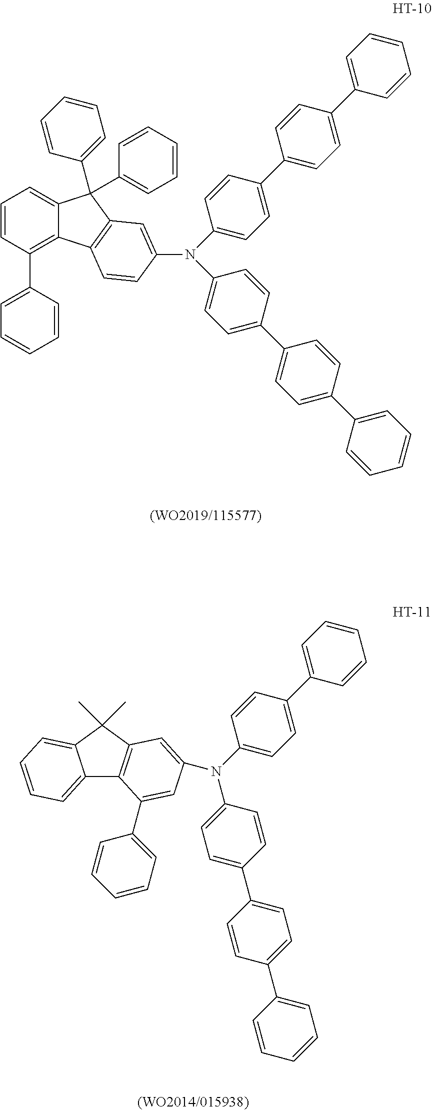 [SMILES: c1ccc(-c2ccc(-c3ccc(N(c4ccc(-c5ccc(-c6ccccc6)cc5)cc4)c4ccc5c(c4)C(c4ccccc4)(c4ccccc4)c4cccc(-c6ccccc6)c4-5)cc3)cc2)cc1 ; CC1(C)c2ccccc2-c2c(-c3ccccc3)cc(N(c3ccc(-c4ccccc4)cc3)c3ccc(-c4ccc(-c5ccccc5)cc4)cc3)cc21]

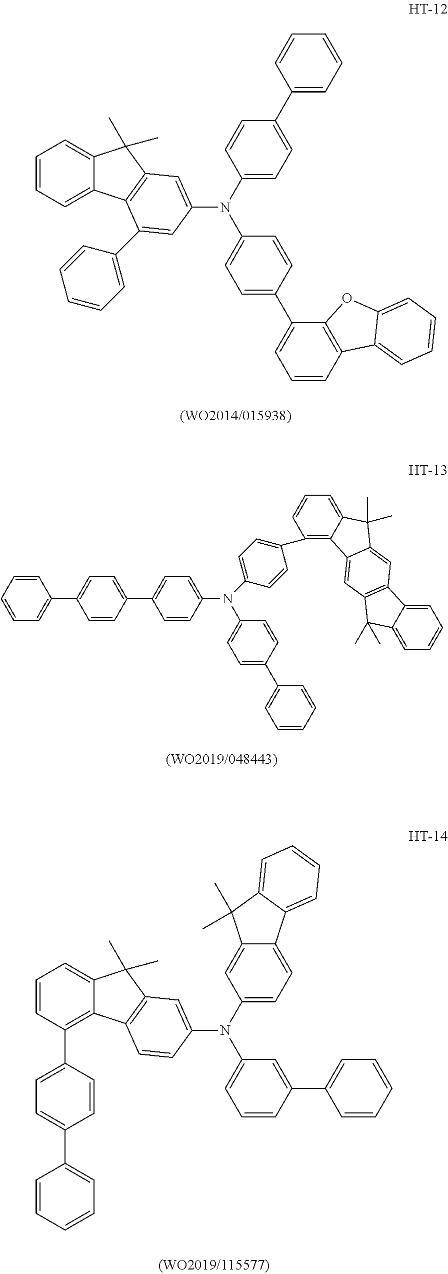 [SMILES: CC1(C)c2ccccc2-c2c(-c3ccccc3)cc(N(c3ccc(-c4ccccc4)cc3)c3ccc(-c4cccc5c4oc4ccccc45)cc3)cc21 ; CC1(C)c2ccccc2-c2cc3c(cc21)-c1c(-c2ccc(N(c4ccc(-c5ccccc5)cc4)c4ccc(-c5ccc(-c6ccccc6)cc5)cc4)cc2)cccc1C3(C)C ; CC1(C)c2ccccc2-c2ccc(N(c3cccc(-c4ccccc4)c3)c3ccc4c(c3)C(C)(C)c3cccc(-c5ccc(-c6ccccc6)cc5)c3-4)cc21]

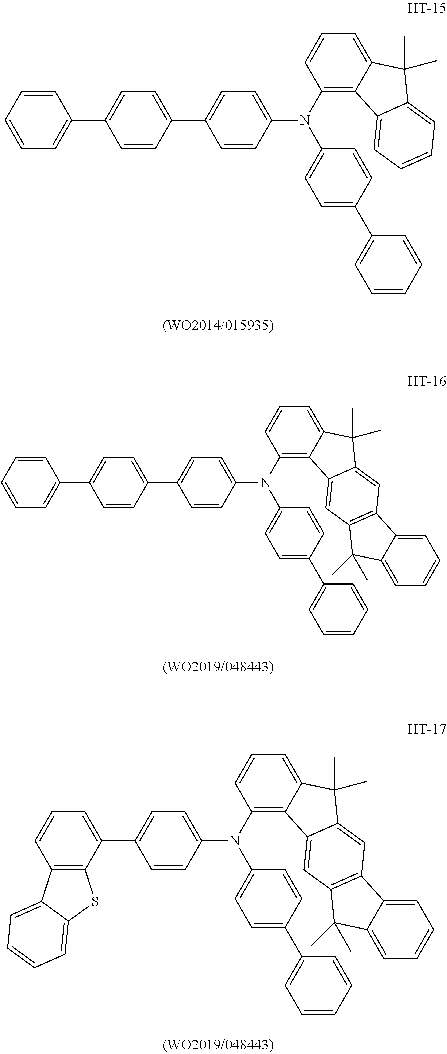 [SMILES: CC1(C)c2ccccc2-c2c(N(c3ccc(-c4ccccc4)cc3)c3ccc(-c4ccc(-c5ccccc5)cc4)cc3)cccc21 ; CC1(C)c2ccccc2-c2cc3c(cc21)-c1c(N(c2ccc(-c4ccccc4)cc2)c2ccc(-c4ccc(-c5ccccc5)cc4)cc2)cccc1C3(C)C ; CC1(C)c2ccccc2-c2cc3c(cc21)-c1c(N(c2ccc(-c4ccccc4)cc2)c2ccc(-c4cccc5c4sc4ccccc45)cc2)cccc1C3(C)C]

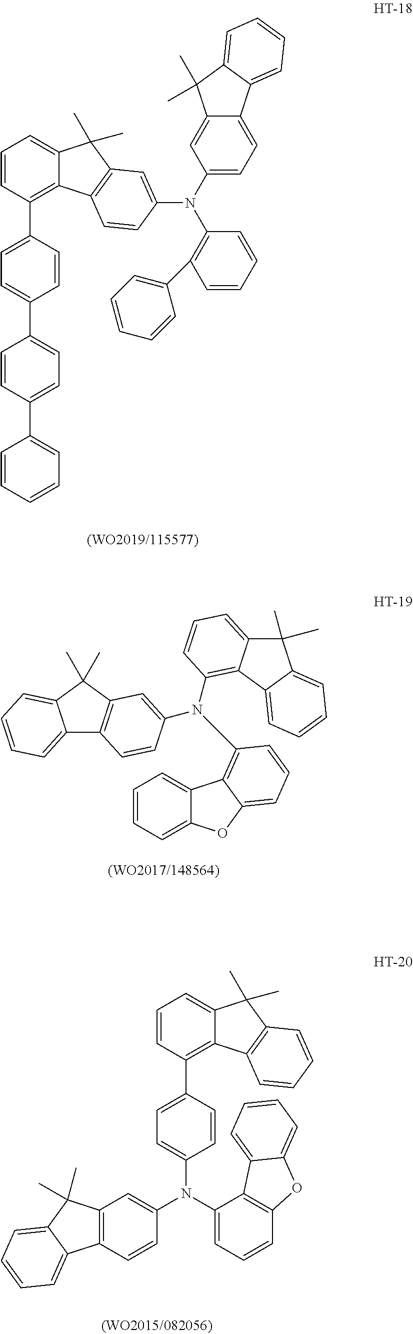 [SMILES: CC1(C)c2ccccc2-c2ccc(N(c3ccc4c(c3)C(C)(C)c3cccc(-c5ccc(-c6ccc(-c7ccccc7)cc6)cc5)c3-4)c3ccccc3-c3ccccc3)cc21 ; CC1(C)c2ccccc2-c2ccc(N(c3cccc4c3-c3ccccc3C4(C)C)c3cccc4oc5ccccc5c34)cc21 ; CC1(C)c2ccccc2-c2ccc(N(c3ccc(-c4cccc5c4-c4ccccc4C5(C)C)cc3)c3cccc4oc5ccccc5c34)cc21]

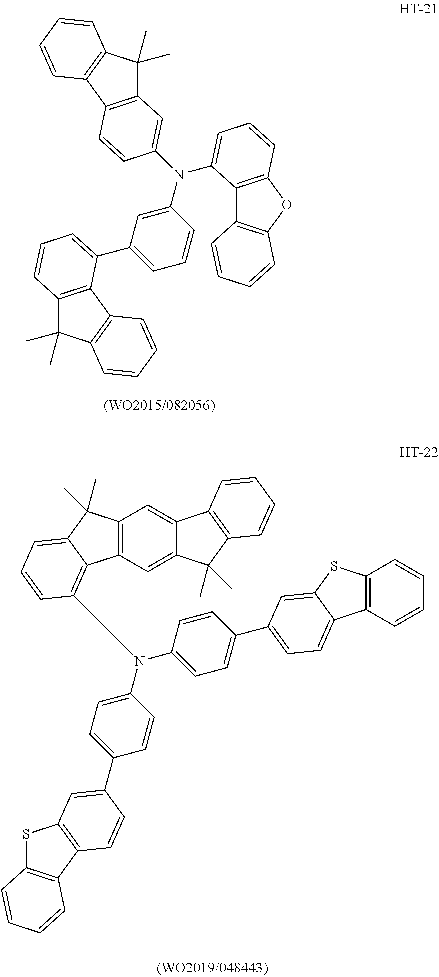 [SMILES: CC1(C)c2ccccc2-c2ccc(N(c3cccc(-c4cccc5c4-c4ccccc4C5(C)C)c3)c3cccc4oc5ccccc5c34)cc21 ; CC1(C)c2ccccc2-c2cc3c(cc21)-c1c(N(c2ccc(-c4ccc5c(c4)sc4ccccc45)cc2)c2ccc(-c4ccc5c(c4)sc4ccccc45)cc2)cccc1C3(C)C]

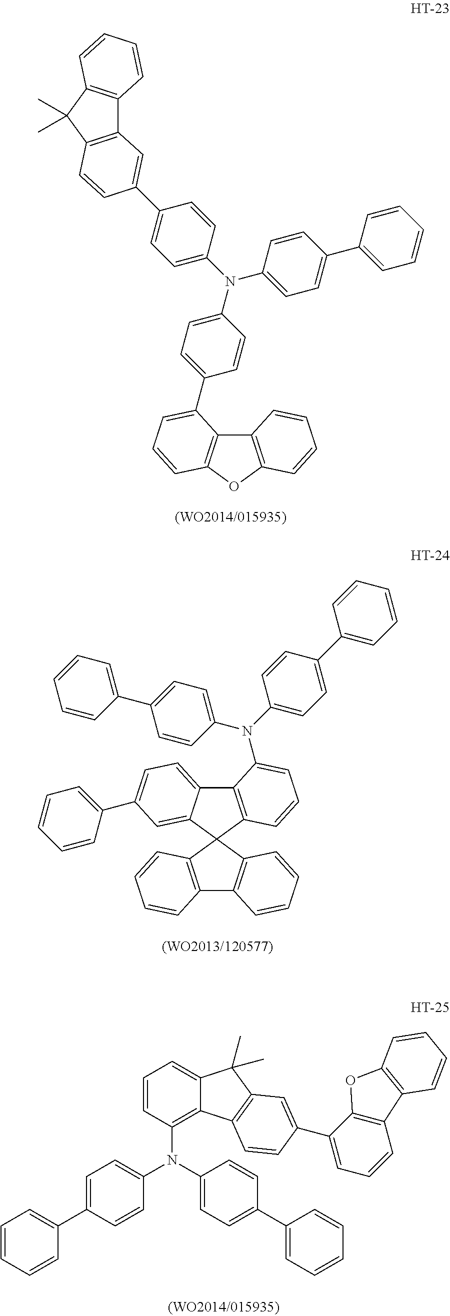 [SMILES: CC1(C)c2ccccc2-c2cc(-c3ccc(N(c4ccc(-c5ccccc5)cc4)c4ccc(-c5cccc6oc7ccccc7c56)cc4)cc3)ccc21 ; c1ccc(-c2ccc(N(c3ccc(-c4ccccc4)cc3)c3cccc4c3-c3ccc(-c5ccccc5)cc3C43c4ccccc4-c4ccccc43)cc2)cc1 ; CC1(C)c2cc(-c3cccc4c3oc3ccccc34)ccc2-c2c(N(c3ccc(-c4ccccc4)cc3)c3ccc(-c4ccccc4)cc3)cccc21]

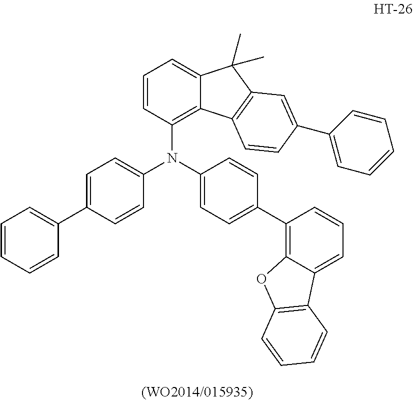 [SMILES: CC1(C)c2cc(-c3ccccc3)ccc2-c2c(N(c3ccc(-c4ccccc4)cc3)c3ccc(-c4cccc5c4oc4ccccc45)cc3)cccc21]

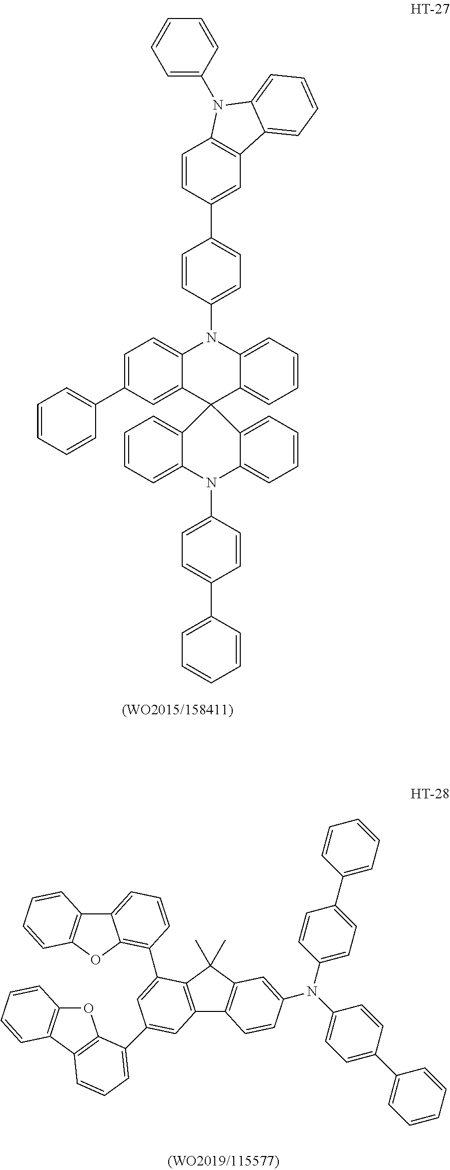 [SMILES: c1ccc(-c2ccc(N3c4ccccc4C4(c5ccccc53)c3ccccc3N(c3ccc(-c5ccc6c(c5)c5ccccc5n6-c5ccccc5)cc3)c3ccc(-c5ccccc5)cc34)cc2)cc1 ; CC1(C)c2cc(N(c3ccc(-c4ccccc4)cc3)c3ccc(-c4ccccc4)cc3)ccc2-c2cc(-c3cccc4c3oc3ccccc34)cc(-c3cccc4c3oc3ccccc34)c21]

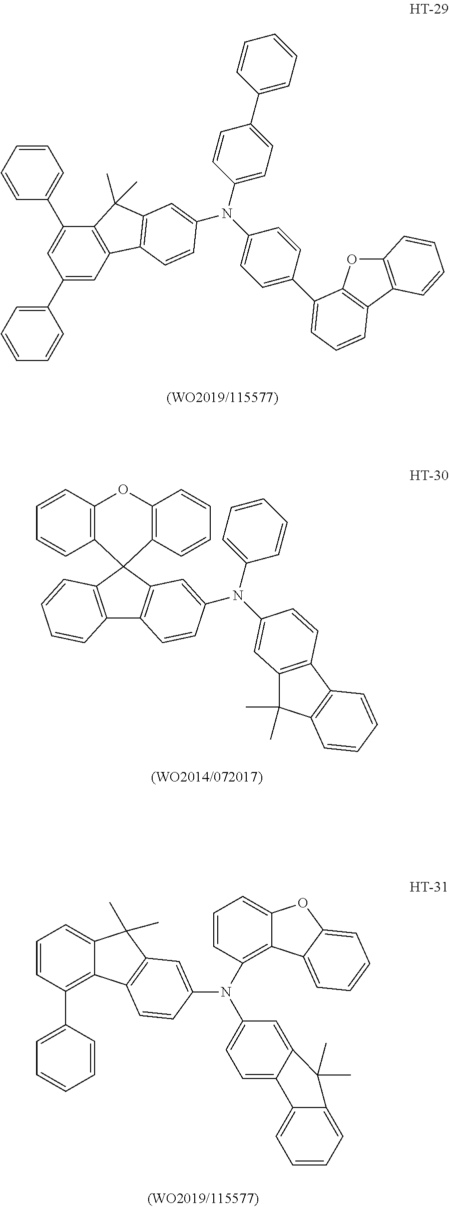 [SMILES: CC1(C)c2cc(N(c3ccc(-c4ccccc4)cc3)c3ccc(-c4cccc5c4oc4ccccc45)cc3)ccc2-c2cc(-c3ccccc3)cc(-c3ccccc3)c21 ; CC1(C)c2ccccc2-c2ccc(N(c3ccccc3)c3ccc4c(c3)C3(c5ccccc5Oc5ccccc53)c3ccccc3-4)cc21 ; CC1(C)c2ccccc2-c2ccc(N(c3ccc4c(c3)C(C)(C)c3cccc(-c5ccccc5)c3-4)c3cccc4oc5ccccc5c34)cc21]

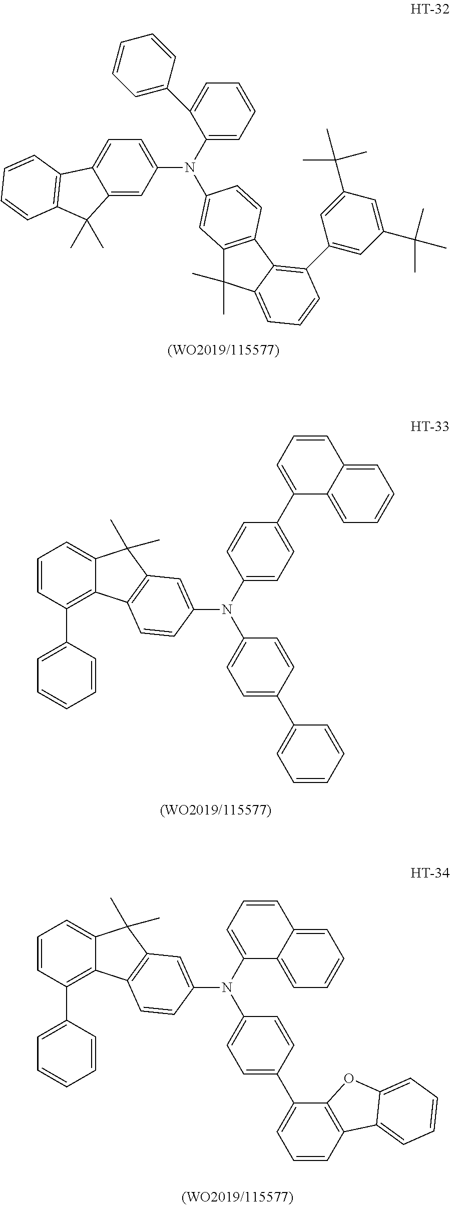 [SMILES: CC(C)(C)c1cc(-c2cccc3c2-c2ccc(N(c4ccc5c(c4)C(C)(C)c4ccccc4-5)c4ccccc4-c4ccccc4)cc2C3(C)C)cc(C(C)(C)C)c1 ; CC1(C)c2cc(N(c3ccc(-c4ccccc4)cc3)c3ccc(-c4cccc5ccccc45)cc3)ccc2-c2c(-c3ccccc3)cccc21 ; CC1(C)c2cc(N(c3ccc(-c4cccc5c4oc4ccccc45)cc3)c3cccc4ccccc34)ccc2-c2c(-c3ccccc3)cccc21]

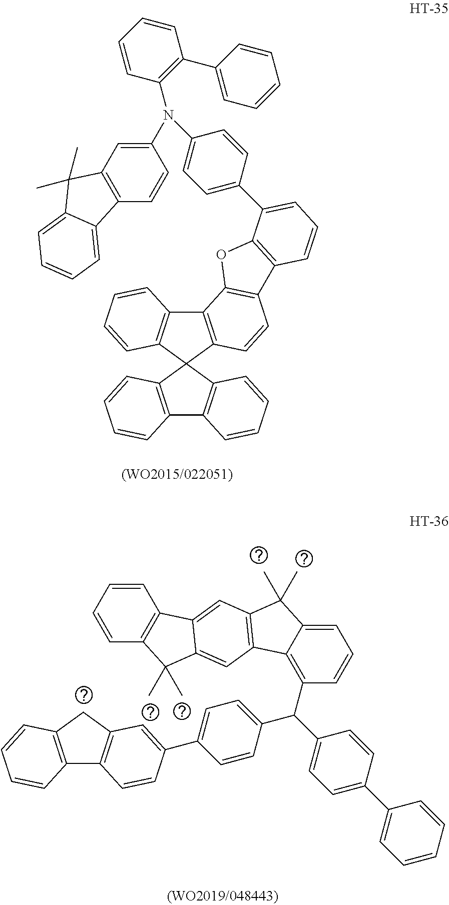

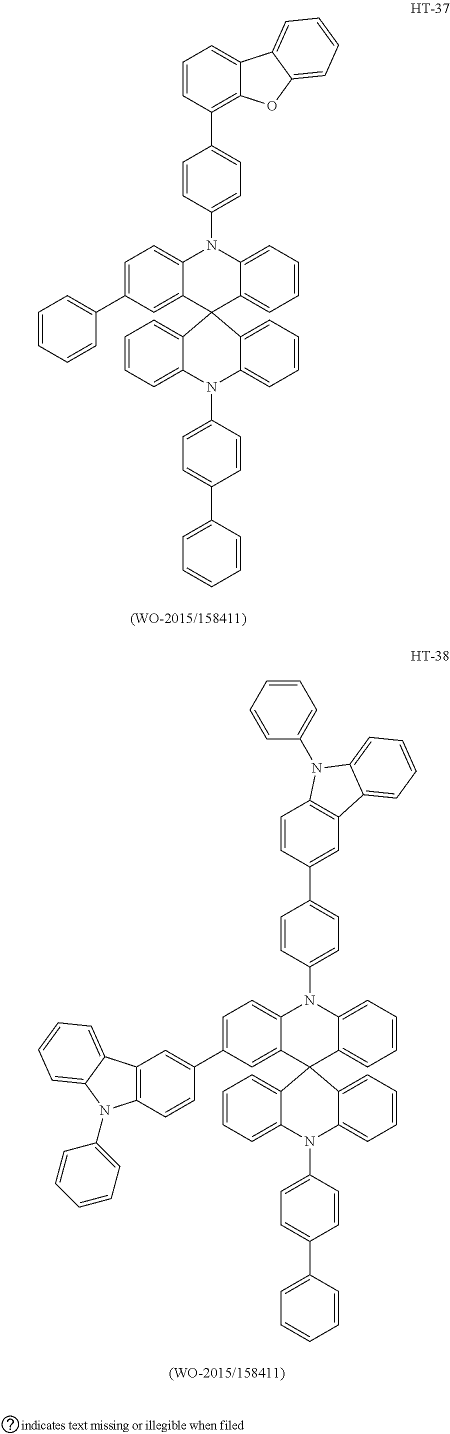 [SMILES: c1ccc(-c2ccc(N3c4ccccc4C4(c5ccccc53)c3ccccc3N(c3ccc(-c5cccc6c5oc5ccccc56)cc3)c3ccc(-c5ccccc5)cc34)cc2)cc1 ; c1ccc(-c2ccc(N3c4ccccc4C4(c5ccccc53)c3ccccc3N(c3ccc(-c5ccc6c(c5)c5ccccc5n6-c5ccccc5)cc3)c3ccc(-c5ccc6c(c5)c5ccccc5n6-c5ccccc5)cc34)cc2)cc1]

The compounds HT-1 to HT-38 are generally of good suitability for the abovementioned uses in OLEDs of any design and composition, not just in OLEDs according to the present application. Processes for preparing these compounds and the further relevant disclosure relating to the use of these compounds are disclosed in the published specifications that are each cited in brackets in the table beneath the respective compounds. The compounds show good performance data in OLEDs, especially good lifetime and good efficiency.

The electronic device is preferably an organic electroluminescent device. The first electrode of the device is preferably the anode, and the second electrode is preferably the cathode.

Preferred cathodes of the electronic device are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag or Al, in which case combinations of the metals such as Ca/Ag, Mg/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). It is also possible to use lithium quinolinate (LiQ) for this purpose. The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. Secondly, metal/metal oxide electrodes (e.g. Al/Ni/NiOx, Al/PtOx) may also be preferred. For some applications, at least one of the electrodes has to be transparent or partly transparent in order to enable either the irradiation of the organic material (organic solar cell) or the emission of light (OLED, O-LASER). Preferred anode materials here are conductive mixed metal oxides. Particular preference is given to indium tin oxide (ITO) or indium zinc oxide (IZO). Preference is further given to conductive doped organic materials, especially conductive doped polymers. In addition, the anode may also consist of two or more layers, for example of an inner layer of ITO and an outer layer of a metal oxide, preferably tungsten oxide, molybdenum oxide or vanadium oxide.

Apart from the anode, cathode, layers H1, H2 and the emitting layer, the device preferably comprises further layers, especially one or more electron-transporting layers. It is further preferable that the device contains a hole injection layer that directly adjoins the anode. Layer H1 may assume the function of such a hole injection layer. In this case, it is preferable that layer H1 is p-doped.

Alternatively, an additional layer that assumes the function of a hole injection layer may be present in the device. Preferably, such a hole injection layer conforms to one of the following two embodiments: a) it contains a triarylamine and a p-dopant; or b) it contains a single, very electron-deficient material (electron acceptor). In a preferred embodiment of embodiment a), the triarylamine is a monotriarylamine, especially a triarylamine containing a compound of the formula (L-1), (L-2) or (L-3). In a preferred embodiment of embodiment b), the electron acceptor is a hexaazatriphenylene derivative as described in US 2007/0092755.

The device of the invention preferably comprises, between anode and cathode:
directly adjoining the anode, a hole injection layer (HIL), and
directly adjoining the cathode side of the HIL, layer H1, and
directly adjoining the cathode side of layer H1, layer H2, and
directly adjoining the cathode side of layer H2, the emitting layer.

On the cathode side of the emitting layer, the device preferably comprises one or more electron-transporting layers. It preferably comprises an electron transport layer and, on the cathode side thereof, an electron injection layer. There may additionally be a hole blocker layer disposed between the emitting layer and electron transport layer.

In a preferred embodiment of the invention, the device comprises two or three, preferably three, identical or different layer sequences stacked one on top of another, where each of the layer sequences comprises the following layers: hole injection layer, hole transport layer, electron blocker layer, emitting layer, and electron transport layer, and wherein at least one of the layer sequences comprises
an emitting layer E comprising a compound of the formula (E-1)
a layer H1 which is disposed between the first electrode and the emitting layer and contains a compound of the formula (L-1), (L-2) or (L-3), and
a layer H2 disposed between layer H1 and the emitting layer.

Preferably, all of the two or three layer sequences comprise
an emitting layer E comprising a compound of the formula (E-1)
a layer H1 which is disposed between the first electrode and the emitting layer and contains a compound of the formula (L-1), (L-2) or (L-3), and
a layer H2 disposed between layer H1 and the emitting layer.

Preferably, all of the two or three layer sequences emit blue light.

It is further preferable that all of the two or three layer sequences contain an emitting layer E comprising a compound of the formula (E-1).

A double layer composed of adjoining n-CGL and p-CGL is preferably arranged between the layer sequences in each case, where the n-CGL is disposed on the anode side and the p-CGL correspondingly on the cathode side. CGL here stands for charge generation layer. Materials for use in such layers are known to the person skilled in the art. Preference is given to using a p-doped amine in the p-CGL, more preferably a material selected from the abovementioned preferred structure classes of hole transport materials.

Suitable materials as may be used in the electron injection layer, in the electron transport layer and/or in the hole blocker layer of the device of the invention are, as well as the compounds of the invention, for example, the compounds disclosed in Y. Shirota et al., Chem. Rev. 2007, 107(4), 953-1010, or other materials as used in these layers according to the prior art. More particularly, materials used for these layers may be any materials known according to the prior art for use in these layers. Especially suitable are aluminium complexes, for example Alq₃, zirconium complexes, for example Zrq₄, lithium complexes, for example Liq, benzimidazole derivatives, triazine derivatives, pyrimidine derivatives, pyridine derivatives, pyrazine derivatives, quinoxaline derivatives, quinoline derivatives, oxadiazole derivatives, aromatic ketones, lactams, boranes, diazaphosphole derivatives and phosphine oxide derivatives. Explicit examples of suitable compounds are shown in the following table:

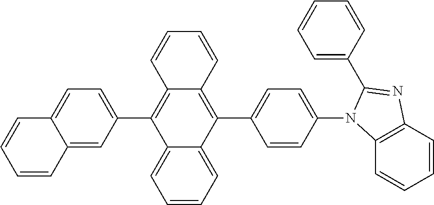 [SMILES: c1ccc(-c2nc3ccccc3n2-c2ccc(-c3c4ccccc4c(-c4ccc5ccccc5c4)c4ccccc34)cc2)cc1]

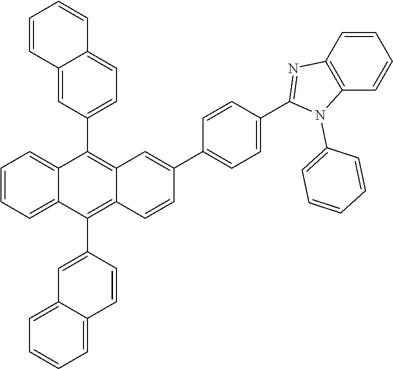 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

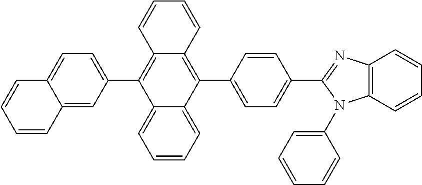 [SMILES: c1ccc(-n2c(-c3ccc(-c4c5ccccc5c(-c5ccc6ccccc6c5)c5ccccc45)cc3)nc3ccccc32)cc1]

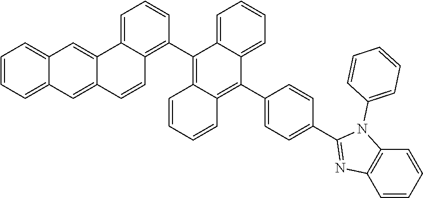 [SMILES: c1ccc(-n2c(-c3ccc(-c4c5ccccc5c(-c5cccc6c5ccc5cc7ccccc7cc56)c5ccccc45)cc3)nc3ccccc32)cc1]

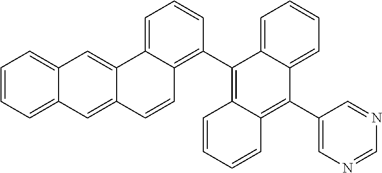 [SMILES: c1ccc2cc3c(ccc4c(-c5c6ccccc6c(-c6cncnc6)c6ccccc56)cccc43)cc2c1]

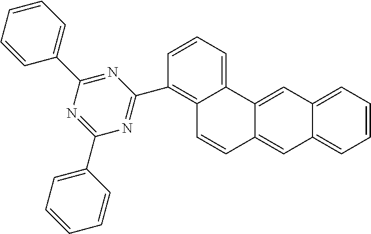 [SMILES: c1ccc(-c2nc(-c3ccccc3)nc(-c3cccc4c3ccc3cc5ccccc5cc34)n2)cc1]

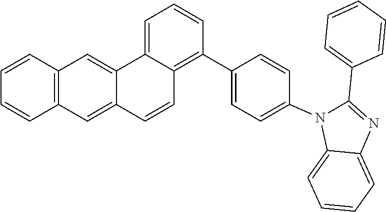 [SMILES: c1ccc(-c2nc3ccccc3n2-c2ccc(-c3cccc4c3ccc3cc5ccccc5cc34)cc2)cc1]

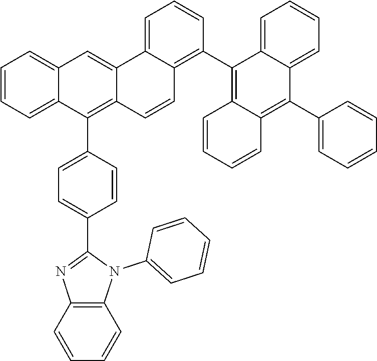 [SMILES: c1ccc(-c2c3ccccc3c(-c3cccc4c3ccc3c(-c5ccc(-c6nc7ccccc7n6-c6ccccc6)cc5)c5ccccc5cc34)c3ccccc23)cc1]

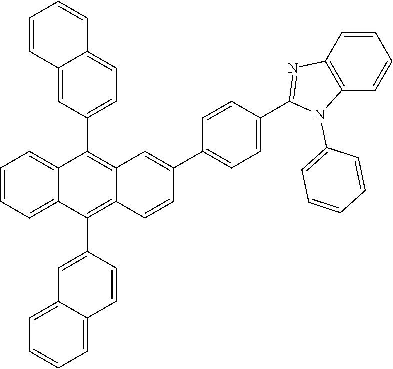 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

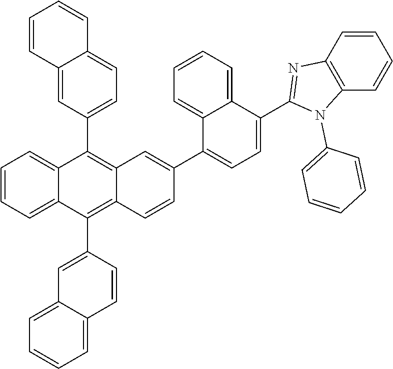 [SMILES: c1ccc(-n2c(-c3ccc(-c4ccc5c(-c6ccc7ccccc7c6)c6ccccc6c(-c6ccc7ccccc7c6)c5c4)c4ccccc34)nc3ccccc32)cc1]

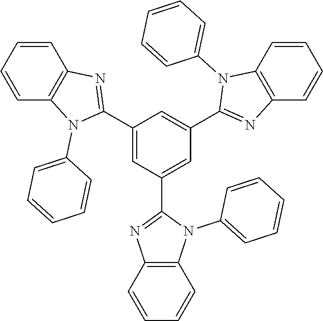 [SMILES: c1ccc(-n2c(-c3cc(-c4nc5ccccc5n4-c4ccccc4)cc(-c4nc5ccccc5n4-c4ccccc4)c3)nc3ccccc32)cc1]

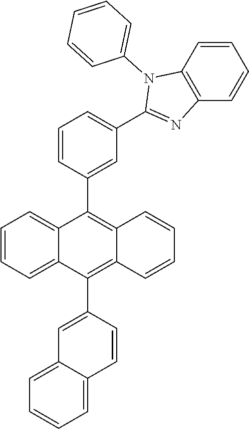 [SMILES: c1ccc(-n2c(-c3cccc(-c4c5ccccc5c(-c5ccc6ccccc6c5)c5ccccc45)c3)nc3ccccc32)cc1]

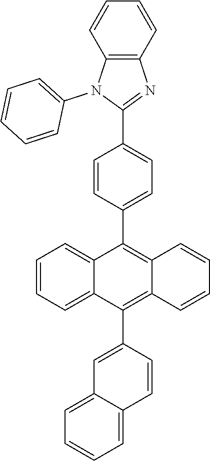 [SMILES: c1ccc(-n2c(-c3ccc(-c4c5ccccc5c(-c5ccc6ccccc6c5)c5ccccc45)cc3)nc3ccccc32)cc1]

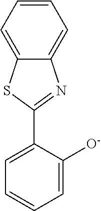 [SMILES: [O-]c1ccccc1-c1nc2ccccc2s1]

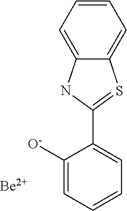

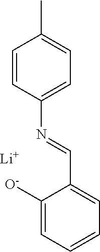 [SMILES: [Li+] ; Cc1ccc(/N=C/c2ccccc2[O-])cc1]

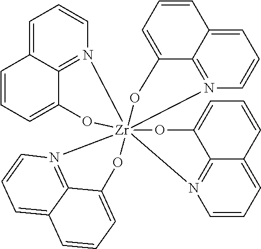

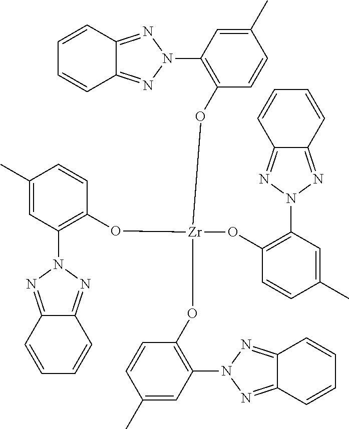

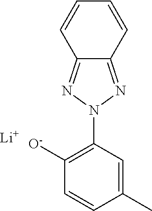 [SMILES: [Li+] ; Cc1ccc([O-])c(-n2nc3ccccc3n2)c1]

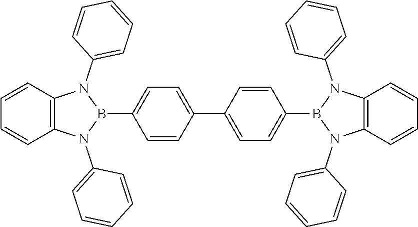 [SMILES: c1ccc(N2B(c3ccc(-c4ccc(B5N(c6ccccc6)c6ccccc6N5c5ccccc5)cc4)cc3)N(c3ccccc3)c3ccccc32)cc1]

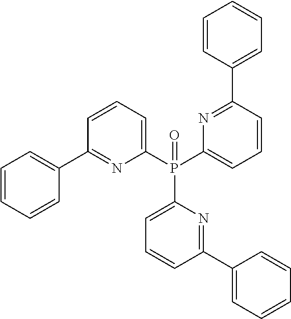 [SMILES: O=P(c1cccc(-c2ccccc2)n1)(c1cccc(-c2ccccc2)n1)c1cccc(-c2ccccc2)n1]

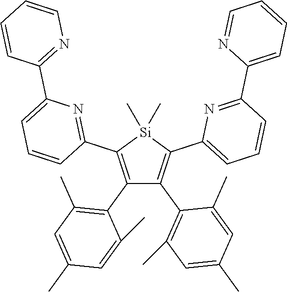 [SMILES: Cc1cc(C)c(C2=C(c3cccc(-c4ccccn4)n3)[Si](C)(C)C(c3cccc(-c4ccccn4)n3)=C2c2c(C)cc(C)cc2C)c(C)c1]

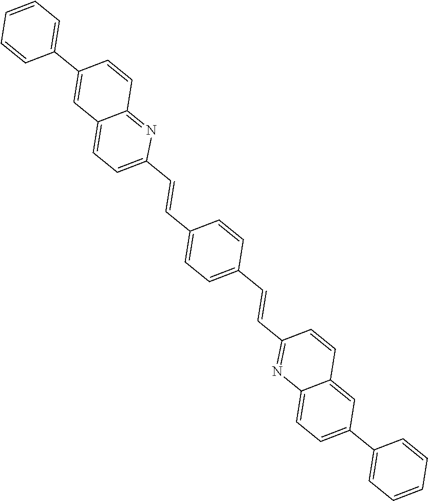 [SMILES: C(=C\c1ccc2cc(-c3ccccc3)ccc2n1)/c1ccc(/C=C/c2ccc3cc(-c4ccccc4)ccc3n2)cc1]

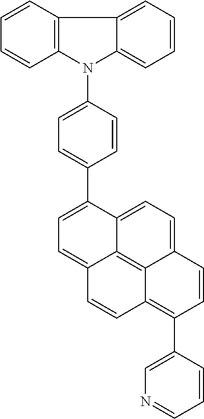 [SMILES: c1cncc(-c2ccc3ccc4c(-c5ccc(-n6c7ccccc7c7ccccc76)cc5)ccc5ccc2c3c54)c1]

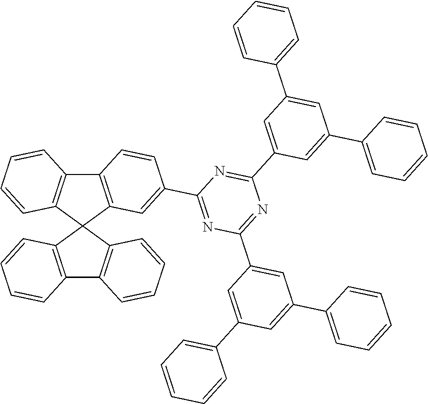 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

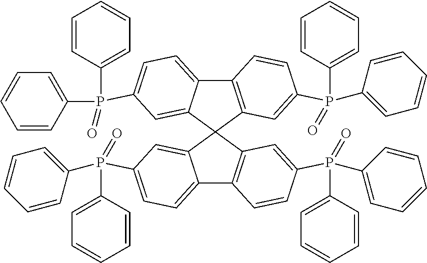 [SMILES: O=P(c1ccccc1)(c1ccccc1)c1ccc2c(c1)C1(c3cc(P(=O)(c4ccccc4)c4ccccc4)ccc3-2)c2cc(P(=O)(c3ccccc3)c3ccccc3)ccc2-c2ccc(P(=O)(c3ccccc3)c3ccccc3)cc21]

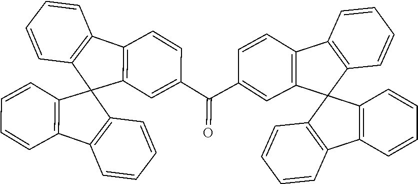 [SMILES: O=C(c1ccc2c(c1)C1(c3ccccc3-c3ccccc31)c1ccccc1-2)c1ccc2c(c1)C1(c3ccccc3-c3ccccc31)c1ccccc1-2]

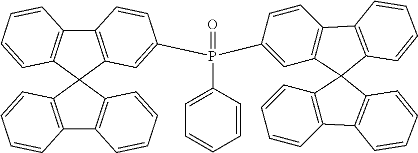 [SMILES: O=P(c1ccccc1)(c1ccc2c(c1)C1(c3ccccc3-c3ccccc31)c1ccccc1-2)c1ccc2c(c1)C1(c3ccccc3-c3ccccc31)c1ccccc1-2]

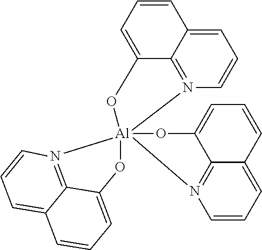

The emitting layer of the device comprises, as well as the compound of the formula (E-1), preferably one or more further compounds, preferably exactly one further compound. The compound of the formula (E-1) here is the emitting compound, and the further compound is the matrix compound. The matrix compound of the formula (E-1) is present here in the layer in a proportion of 0.5% to 15%, preferably 0.5% to 10%, more preferably 3%-6%. The further compound is preferably present here in the layer in a proportion of 85% to 99.5%, preferably in a proportion of 90%-99.5% and more preferably in a proportion of 94%-97%.

The further compound is preferably selected from compounds known in the prior art as matrix materials for fluorescent emitters, especially compounds selected from the classes of the oligoarylenes (e.g. 2,2′,7,7′-tetraphenylspirobifluorene), especially the oligoarylenes containing fused aromatic groups, the oligoarylenevinylenes, the polypodal metal complexes, the hole-conducting compounds, the electron-conducting compounds, especially ketones, phosphine oxides, and sulfoxides; the atropisomers, the boronic acid derivatives and the benzanthracenes. Particularly preferred matrix materials are selected from the classes of the oligoarylenes comprising naphthalene, anthracene, benzanthracene and/or pyrene or atropisomers of these compounds, the oligoarylenevinylenes, the ketones, the phosphine oxides and the sulfoxides. Very particularly preferred matrix materials are selected from the classes of the oligoarylenes comprising anthracene, benzanthracene, benzophenanthrene and/or pyrene or atropisomers of these compounds. Most preferred are materials selected from the classes of the anthracenes and benzanthracenes. An oligoarylene in the context of this invention is understood to mean a compound in which at least three aryl or arylene groups are bonded to one another.

The compound of the formula (E-1) is preferably a fluorescent compound. It preferably emits blue light.

The compound may also emit light by the mechanism of thermally activated delayed fluorescence (TADF), preferably likewise blue light. In this case, it is preferable that

LUMO(E), i.e. the LUMO energy level of the emitting compound of the formula (E-1), and HOMO(matrix), i.e. the HOMO energy level of the matrix material, are subject to the condition that:

LUMO(E)−HOMO(matrix)>S₁(E)−0.4 eV;

more preferably:

LUMO(E)−HOMO(matrix)>S₁(E)−0.3 eV;

and even more preferably:

LUMO(E)−HOMO(matrix)>S₁(E)−0.2 eV.

In this case, S₁(E) is the energy of the first excited singlet state of the compound of the formula (E-1).

It is additionally preferable that the energy of the T₁ state of the matrix material of the emitting layer, referred to hereinafter as T₁(matrix), is not more than 0.1 eV lower than the energy of the T₁ state of the compound of the formula (E-1), referred to hereinafter as T₁(E). More preferably, T₁(matrix)≥T₁(E). Even more preferably: T₁(matrix)−T₁(E)≥0.1 eV, most preferably T₁(matrix)−T₁(E)≥0.2 eV.

Examples of suitable matrix materials in the emitting layer, in the case of emission by the compound of the formula (E-1) by the TADF mechanism, are ketones, phosphine oxides, sulfoxides and sulfones, triarylamines, carbazole derivatives, e.g. CBP (N,N-biscarbazolylbiphenyl), or m-CBP, indolocarbazole derivatives, indenocarbazole derivatives, azacarbazoles, bipolar matrix materials, silanes, azaboroles or boronic esters, diazasilole derivatives, diazaphosphole derivatives, triazine derivatives, zinc complexes, or bridged carbazole derivatives.

For this use, preference is further given to electron-transporting organic compounds. Particular preference is given to electron-transporting organic compounds having a LUMO energy level of not more than −2.50 eV, more preferably not more than −2.60 eV, even more preferably not more than −2.65 eV and most preferably not more than −2.70 eV.

Particularly preferred matrix materials in the emitting layer, in the case of emission by the compound of the formula (E-1) by the TADF mechanism, are selected from the substance classes of the triazines, the pyrimidines, the lactams, the metal complexes, especially the Be, Zn and Al complexes, the aromatic ketones, the aromatic phosphine oxides, the azaphospholes, the azaboroles substituted by at least one electron-conducting substituent, the quinoxalines, the quinolines and the isoquinolines.

Preferably, the emitting layer of the device emits blue light.

In a preferred embodiment of the invention, the device emits light through the anode and the substrate layer (bottom emission).

In an alternative, likewise preferred embodiment of the invention, the device emits light through the cathode (top emission). In this embodiment, the cathode has a partly transparent and partly reflective configuration. For this purpose, for example, it is possible to use an alloy of Ag and Mg as cathode. In this embodiment, the anode is highly reflective. In addition, the device in this case preferably includes an outcoupling layer applied to the cathode and preferably comprising an amine compound. The layer thicknesses in this embodiment should be adapted to the materials used, especially to the refractive index of the layers and to the position of the recombination zone in the emitting layer, in order to achieve an optimal resonance effect.

In the embodiment with top emission, it is possible to achieve excellent efficiency of the OLED, combined with a narrow emission band.

After application of the layers, the device may be structured, contact-connected and finally sealed, in order to rule out damaging effects of water and air.

In a preferred embodiment, the device is characterized in that one or more layers are coated by a sublimation process. In this case, the materials are applied by vapour deposition in vacuum sublimation systems at an initial pressure of less than 10⁻⁵ mbar, preferably less than 10⁻⁶ mbar. In this case, however, it is also possible that the initial pressure is even lower, for example less than 10⁻⁷ mbar.

It is further preferable that one or more layers of the device are coated by the OVPD (organic vapour phase deposition) method or with the aid of a carrier gas sublimation. In this case, the materials are applied at a pressure between 10-5 mbar and 1 bar. A special case of this method is the OVJP (organic vapour jet printing) method, in which the materials are applied directly by a nozzle and thus structured (for example M. S. Arnold et al., Appl. Phys. Lett. 2008, 92, 053301).

It is further preferable that one or more layers of the device are applied from solution, for example by spin-coating, or by any printing method, for example screen printing, flexographic printing, nozzle printing or offset printing, but more preferably LITI (light-induced thermal imaging, thermal transfer printing) or inkjet printing.

It is further preferable that the device is produced by applying one or more layers from solution and one or more layers by a sublimation method.

A process for producing the device firstly comprises the providing of a substrate with an anode, the applying of layer H1 in a step that follows later, the applying of layer H2 in a step that follows later, the applying of the emitting layer in a step that follows later, and the applying of the anode in a step that follows later. Preferably, layers H1 and H2 and the emitting layer are applied from the gas phase. More preferably, all layers between the anode and cathode of the device are applied from the gas phase.

The devices of the invention are preferably used in displays, as light sources in lighting applications and as light sources in medical and/or cosmetic applications.

### EXAMPLES

A) General Production Process for the OLEDs and Characterization of the OLEDs

Glass plaques which have been coated with structured ITO (indium tin oxide) in a thickness of 50 nm are the substrates to which the OLEDs are applied.

The OLEDs have the following layer structure: substrate/hole injection layer (HIL)/hole transport layer (HTL)/electron blocker layer (EBL)/emission layer (EML)/electron transport layer (ETL)/electron injection layer (EIL) and finally a cathode. The cathode is formed by an aluminium layer of thickness 100 nm. The exact structure of the OLEDs can be found in the tables which follow. The materials present in the individual layers of the OLED are shown in a table below.

All materials are applied by thermal vapour deposition in a vacuum chamber. In this case, the emission layer consists of at least one matrix material (host material) and an emitting dopant (emitter) which is added to the matrix material(s) in a particular proportion by volume by co-evaporation. Details given in such a form as H:SEB(95%:5%) mean here that the material H is present in the layer in a proportion by volume of 95% and the material SEB in a proportion by volume of 5%.

In an analogous manner, the electron transport layer and the hole injection layer consist of a mixture of two materials.

The OLEDs are characterized in a standard manner. For this purpose, the operating voltage and the external quantum efficiency (EQE, measured in %) as a function of the luminance, calculated from current-voltage-luminance characteristics assuming Lambertian radiation characteristics, are determined. The parameter EQE@10 mA/cm² refers to the external quantum efficiency which is attained at 10 mA/cm². The parameter U@10 mA/cm² refers to the operating voltage at 10 mA/cm².

B) Production and Characterization of Inventive OLEDs with a Bottom Emission Structure

OLEDs are produced with the following structure:

| | HIL | HTL | EBL | EML | ETL | EIL |
|---|---|---|---|---|---|---|
| Ex. | Thickness/nm | Thickness/nm | Thickness/nm | Thickness/nm | Thickness/nm | Thickness/nm |
| C1 | HTM-1: PDM (5%) | HTM-1 | EBM-1 | H: PA(5%) | ETM: LiQ(50%) | LiQ |
| | 20 nm | 180 nm | 10 nm | 20 nm | 30 nm | 1 nm |
| I1 | HTM-1: PDM (5%) | HTM-1 | EBM-1 | H: SEB(5%) | ETM: LiQ(50%) | LiQ |
| | 20 nm | 180 nm | 10 nm | 20 nm | 30 nm | 1 nm |
| I2 | HTM-2: PDM (5%) | HTM-2 | EBM-1 | H: SEB(5%) | ETM: LiQ(50%) | LiQ |
| | 20 nm | 180 nm | 10 nm | 20 nm | 30 nm | 1 nm |
| I3 | HTM-3: PDM (5%) | HTM-3 | EBM-1 | H: SEB(5%) | ETM: LiQ(50%) | LiQ |
| | 20 nm | 180 nm | 10 nm | 20 nm | 30 nm | 1 nm |
| I4 | HTM-4: PDM (5%) | HTM-4 | EBM-1 | H: SEB(5%) | ETM: LiQ(50%) | LiQ |
| | 20 nm | 180 nm | 10 nm | 20 nm | 30 nm | 1 nm |

In OLEDs 11 to 14, there is variation in each case in the compound used in the HTL and HIL. Compounds HTM-1 to HTM-4 are used that are spirobifluorenylamines or fluorenylamines. In all cases, the spirobifluorenylamine EBM-1 is used in the EBL.

Comparative OLED C1 is of identical structure to OLED I1, with the sole difference that the compound PA rather than the compound SEB is present as emitter in the emitting layer.

The OLEDs can achieve the following device data:

| | U @ 10 mA/cm² (V) | EQE @ 10 mA/cm² (%) |
|---|---|---|
| C1 | 4.3 | 7.2 |
| I1 | 4.0 | 8.9 |
| I2 | 4.0 | 9.2 |
| I3 | 4.1 | 8.7 |
| I4 | 4.0 | 9.1 |

For all inventive OLEDs I1 to I4, a good operating voltage and high efficiency are achieved. The half-height width of the emission in all cases is about 26 nm.

The comparative OLED C1 shows distinctly poorer efficiency and a higher operating voltage than the corresponding inventive OLED I1.

In addition, OLEDs with the following structures are produced:

| | HIL | HTL | EBL | EML | ETL | EIL |
|---|---|---|---|---|---|---|
| Ex. | Thickness/nm | Thickness/nm | Thickness/nm | Thickness/nm | Thickness/nm | Thickness/nm |
| I5 | HTM-3: PDM (5%) | HTM-3 | EBM-2 | H: SEB(5%) | ETM: LiQ(50%) | LiQ |
| | 20 nm | 180 nm | 10 nm | 20 nm | 30 nm | 1 nm |
| I6 | HTM-3: PDM (5%) | HTM-3 | EBM-3 | H: SEB(5%) | ETM: LiQ(50%) | LiQ |
| | 20 nm | 180 nm | 10 nm | 20 nm | 30 nm | 1 nm |
| I7 | HTM-3: PDM (5%) | HTM-3 | EBM-4 | H: SEB(5%) | ETM: LiQ(50%) | LiQ |
| | 20 nm | 180 nm | 10 nm | 20 nm | 30 nm | 1 nm |
| I8 | HTM-3: PDM (5%) | HTM-3 | EBM-5 | H: SEB(5%) | ETM: LiQ(50%) | LiQ |
| | 20 nm | 180 nm | 10 nm | 20 nm | 30 nm | 1 nm |
| I9 | HTM-3: PDM (5%) | HTM-3 | EBM-6 | H: SEB(5%) | ETM: LiQ(50%) | LiQ |
| | 20 nm | 180 nm | 10 nm | 20 nm | 30 nm | 1 nm |
| I10 | HTM-3: PDM (5%) | HTM-3 | EBM-7 | H: SEB(5%) | ETM: LiQ(50%) | LiQ |
| | 20 nm | 180 nm | 10 nm | 20 nm | 30 nm | 1 nm |

In OLEDs 15 to 110, the compound HTML-3 is always used in the HIL and the HTL. Compound HTL-3 is a 2-spirobifluorenylamine that bears a phenyl group as substituent on the spiro ring. In OLEDs 15 to 110, there is variation in the compound used in the EBL. Compounds EBM-2 to EBM-7 having different structures are used. Compounds EBM-2 to EBM-7 are selected from spirobifluorenylamines, indenofluorenylamines, fluorenylamines and amines having phenylenedibenzofuran groups on the amine.

The OLEDs can achieve the following device data:

| | U @ 10 mA/cm² (V) | EQE @ 10 mA/cm² (%) |
|---|---|---|
| I5 | 4.0 | 8.9 |
| I6 | 4.0 | 8.9 |
| I7 | 3.9 | 8.6 |
| i8 | 3.9 | 8.5 |
| I9 | 4.0 | 9.3 |
| I10 | 4.0 | 9.1 |

A good operating voltage and high efficiency are achieved in all cases. The half-height width of the emission in all cases is about 28 nm.

C) Production and Characterization of Inventive OLEDs with a Top Emission Structure

OLEDs are produced with the following structure:

substrate /HIL/HTL/EBL/EML/ETL/EIL/cathode/outcoupling layer.

The substrate used here is a glass plaque coated with structured ITO (indium tin oxide) of thickness 50 nm. The cathode consists of a 15 nm-thick layer of a mixture of 91% Ag and 9% Mg. The outcoupling layer consists of a 70 nm-thick layer of the compound HTM-1. The structure of the layers HIL, HTL, EBL, EML, ETL and EIL is shown in the following table:

| | HIL | HTL | EBL | EML | ETL | EIL |
|---|---|---|---|---|---|---|
| Ex. | Thickness/nm | Thickness/nm | Thickness/nm | Thickness/nm | Thickness/nm | Thickness/nm |
| I11 | HTM-1: PDM (5%) | HTM-1 | EBM-1 | H: SEB(4%) | ETM: LiQ(50%) | Yb: LiF(50%) |
| | 10 nm | 118 nm | 15 nm | 20 nm | 30 nm | 2 nm |

The OLED I11 has colour coordinates CIE x,y=0.14, 0.05. It attains a very high EQE at 10 mA/cm² of 16%-19%. The emission band of the OLEDs is very narrow and has a half-height width between 17 and 18 nm.

In addition, it is possible to produce the following OLEDs with top emission structure in which, by comparison with OLED I11, HTM-1 has been respectively exchanged for HTM-2, HTM-3 or HTM-4, or EBM-1 for one of materials EBM-2 to EBM-7.

| Ex. | HIL | HTL | EBL | EML | ETL | EIL |
|---|---|---|---|---|---|---|
| I12 | HTM-1: PDM (5%) | HTM-1 | EBM-2 | H: SEB(4%) | ETM: LiQ(50%) | Yb: LiF(50%) |
| I13 | ″ | ″ | EBM-3 | ″ | ″ | ″ |
| I14 | ″ | ″ | EBM-4 | ″ | ″ | ″ |
| I15 | ″ | ″ | EBM-5 | ″ | ″ | ″ |
| I16 | ″ | ″ | EBM-6 | ″ | ″ | ″ |
| I17 | ″ | ″ | EBM-7 | ″ | ″ | ″ |
| I18 | HTM-2: PDM (5%) | HTM-2 | EBM-1 | ″ | ″ | ″ |
| I19 | ″ | ″ | EBM-2 | ″ | ″ | ″ |
| I20 | ″ | ″ | EBM-3 | ″ | ″ | ″ |
| I21 | ″ | ″ | EBM-4 | ″ | ″ | ″ |
| I22 | ″ | ″ | EBM-5 | ″ | ″ | ″ |
| I23 | ″ | ″ | EBM-6 | ″ | ″ | ″ |
| I24 | ″ | ″ | EBM-7 | ″ | ″ | ″ |
| I25 | HTM-3: PDM (5%) | HTM-3 | EBM-1 | ″ | ″ | ″ |
| I26 | ″ | ″ | EBM-2 | ″ | ″ | ″ |
| I27 | ″ | ″ | EBM-3 | ″ | ″ | ″ |
| I28 | ″ | ″ | EBM-4 | ″ | ″ | ″ |
| I29 | ″ | ″ | EBM-5 | ″ | ″ | ″ |
| I30 | ″ | ″ | EBM-6 | ″ | ″ | ″ |
| I31 | ″ | ″ | EBM-7 | ″ | ″ | ″ |
| I32 | HTM-4: PDM (5%) | HTM-4 | EBM-1 | ″ | ″ | ″ |
| I33 | ″ | ″ | EBM-2 | ″ | ″ | ″ |
| I34 | ″ | ″ | EBM-3 | ″ | ″ | ″ |
| I35 | ″ | ″ | EBM-4 | ″ | ″ | ″ |
| I36 | ″ | ″ | EBM-5 | ″ | ″ | ″ |
| I37 | ″ | ″ | EBM-6 | ″ | ″ | ″ |
| I38 | ″ | ″ | EBM-7 | ″ | ″ | ″ |

It is possible here to obtain OLEDs having the colour coordinates CIE x,y=0.14, 0.05. After adjustment of the layer thicknesses to the material combination used in order to optimize the resonance effect, it is possible using these OLEDs to attain very high EQE values at 10 mA/cm² of 16-19%, and very small half-height widths of the emission band of 17 to 18 nm.

Compounds used

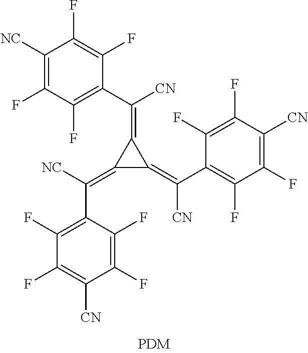 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

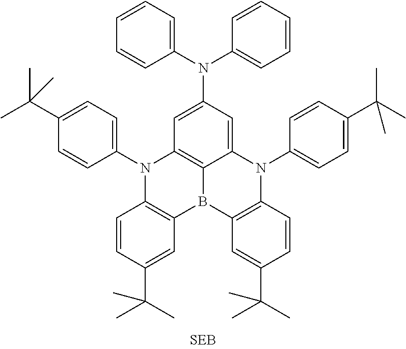 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1]

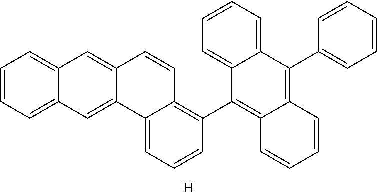

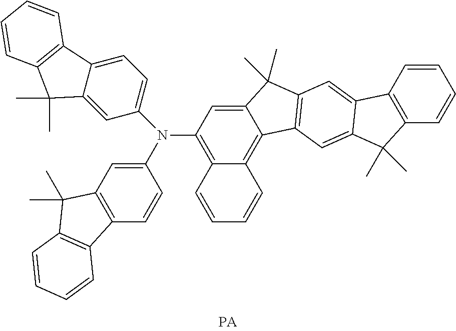 [SMILES: CC1(C)c2ccccc2-c2ccc(N(c3ccc4c(c3)C(C)(C)c3ccccc3-4)c3cc4c(c5ccccc35)-c3cc5c(cc3C4(C)C)-c3ccccc3C5(C)C)cc21]

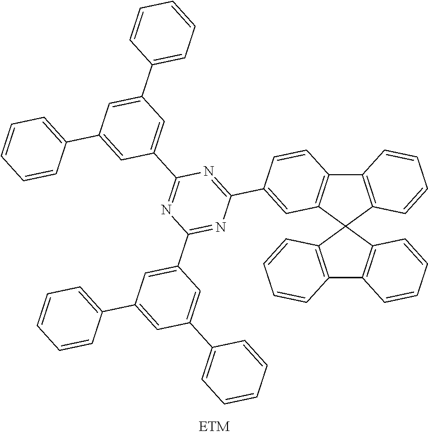 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

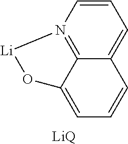

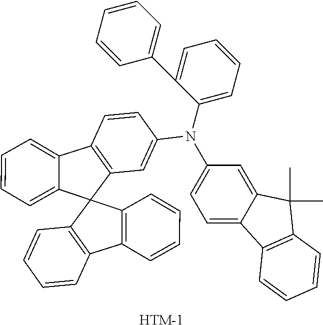

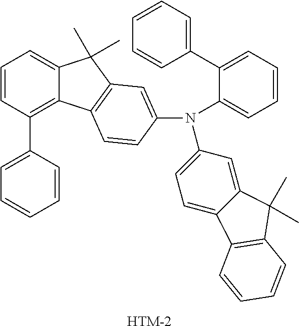

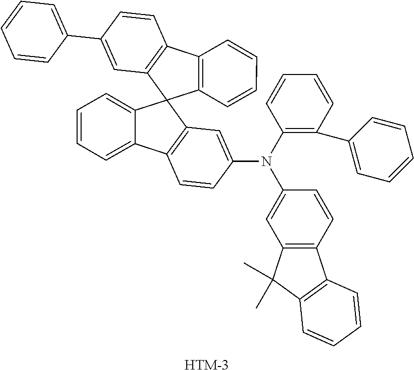

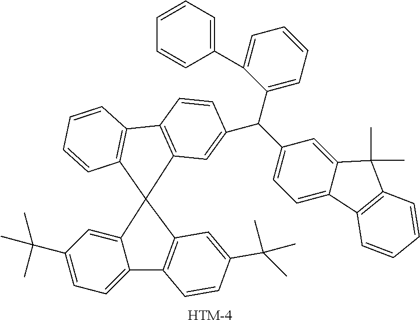

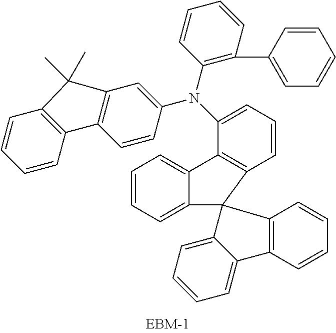 [SMILES: CC1(C)c2ccccc2-c2ccc(N(c3ccccc3-c3ccccc3)c3cccc4c3-c3ccccc3C43c4ccccc4-c4ccccc43)cc21]

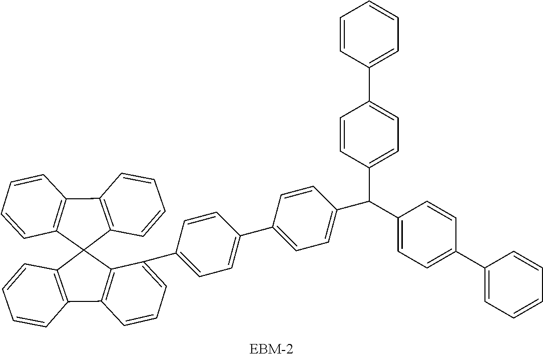 [SMILES: c1ccc(-c2ccc(C(c3ccc(-c4ccccc4)cc3)c3ccc(-c4ccc(-c5cccc6c5C5(c7ccccc7-c7ccccc75)c5ccccc5-6)cc4)cc3)cc2)cc1]

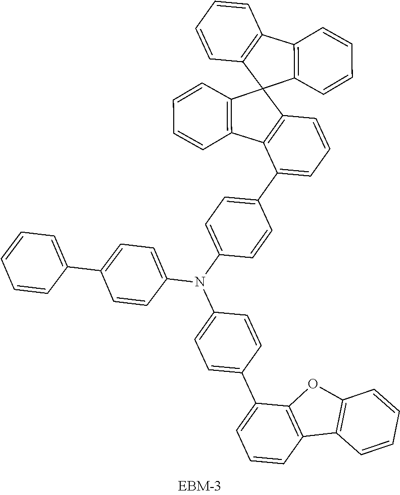 [SMILES: c1ccc(-c2ccc(N(c3ccc(-c4cccc5c4-c4ccccc4C54c5ccccc5-c5ccccc54)cc3)c3ccc(-c4cccc5c4oc4ccccc45)cc3)cc2)cc1]

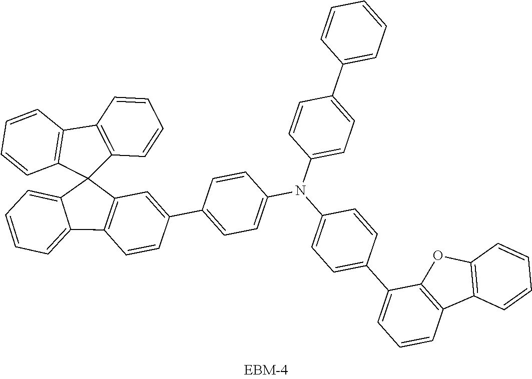 [SMILES: c1ccc(-c2ccc(N(c3ccc(-c4ccc5c(c4)C4(c6ccccc6-c6ccccc64)c4ccccc4-5)cc3)c3ccc(-c4cccc5c4oc4ccccc45)cc3)cc2)cc1]

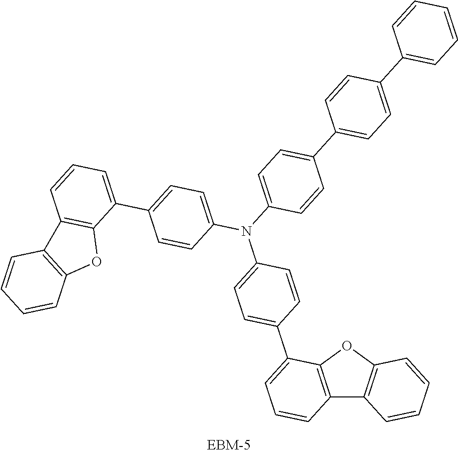 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

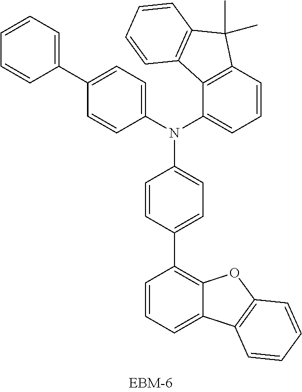 [SMILES: CC1(C)c2ccccc2-c2c(N(c3ccc(-c4ccccc4)cc3)c3ccc(-c4cccc5c4oc4ccccc45)cc3)cccc21]

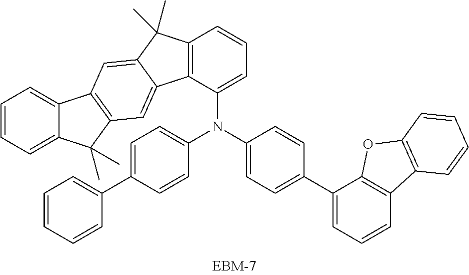 [SMILES: CC1(C)c2ccccc2-c2cc3c(cc21)-c1c(N(c2ccc(-c4ccccc4)cc2)c2ccc(-c4cccc5c4oc4ccccc45)cc2)cccc1C3(C)C]

1.-24. (canceled)

25. An electronic device comprising a first electrode, a second electrode and, arranged in between,
an emitting layer E comprising a compound of a formula (E-1) 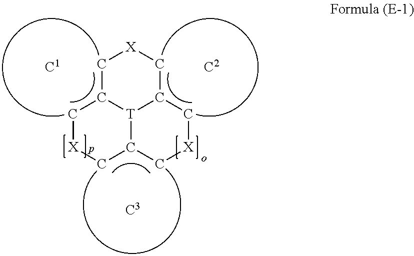
for which:
T is B, P, P(═O) or SiR^{E1};
X is the same or different at each instance and is selected from O, S, NR^{E2} and C(R^{E2})₂, where there must be at least one X present which is selected from O, S and NR^{E2};
C¹, C² and C³ are the same or different and are selected from ring systems which have 5 to 40 ring atoms and are substituted by R^{E3} radicals;
R^{E1} is selected from H, D, F, Cl, Br, I, C(═O)R^{E4}, CN, Si(R^{E4})₃, N(R^{E4})₂, P(═O)(R^{E4})₂, OR^{E4}, S(═O)R^{E4}, S(═O)₂R^{E4}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where the alkyl, alkoxy, alkenyl and alkynyl groups and the aromatic ring systems and heteroaromatic ring systems are each substituted by R^{E4} radicals; and where one or more CH₂ groups in the alkyl, alkoxy, alkenyl and alkynyl groups optionally are replaced by —R^{E4}C═CR^{E4}—, —C≡C—, Si(R^{E4})₂, C═O, C═NR^{E4}, —C(═O)O—, —C(═O)NR^{E4}—, NR^{E4}, P(═O)(R^{E4}), —O—, —S—, SO or SO₂;
R^{E2} is the same or different at each instance and is selected from H, D, F, Cl, Br, I, C(═O)R^{E4}, CN, Si(R^{E4})₃, N(R^{E4})₂, P(═O)(R^{E4})₂, OR^{E4}, S(═O)R^{E4}, S(═O)₂R^{E4}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where the alkyl, alkoxy, alkenyl and alkynyl groups and the aromatic ring systems and heteroaromatic ring systems are each substituted by R^{E4} radicals; and where one or more CH₂ groups in the alkyl, alkoxy, alkenyl and alkynyl groups optionally are replaced by —R^{E4}C═CR^{E4}—, —C≡C—, Si(R^{E4})₂, C═O, C═NR^{E4}, —C(═O)O—, —C(═O)NR^{E4}—, NR^{E4}, P(═O)(R^{E4}), —O—, —S—, SO or SO₂; where two or more R^{E2} radicals may be joined to one another and may form a ring, and where one or more R^{E2} radicals may be joined via their R^{E4} radicals to a ring selected from C¹, C² and C³ and may form a ring;
R^{E3} is the same or different at each instance and is selected from H, D, F, Cl, Br, I, C(═O)R^{E4}, CN, Si(R^{E4})₃, N(R^{E4})₂, P(═O)(R^{E4})₂, OR^{E4}, S(═O)R^{E4}, S(═O)₂R^{E4}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{E3} radicals may be joined to one another and may form a ring; where the alkyl, alkoxy, alkenyl and alkynyl groups and the aromatic ring systems and heteroaromatic ring systems are each substituted by R^{E4} radicals; and where one or more CH₂ groups in the alkyl, alkoxy, alkenyl and alkynyl groups optionally are replaced by —R^{E4}C═CR^{E4}—, —C≡C—, Si(R^{E4})₂, C═O, C═NR^{E4}, —C(═O)O—, —C(═O)NR^{E4}—, NR^{E4}, P(═O)(R^{E4}), —O—, —S—, SO or SO₂;
R^{E4} is the same or different at each instance and is selected from H, D, F, Cl, Br, I, C(═O)R^{E5}CN, Si(R^{E5})₃, N(R^{E5})₂, P(═O)(R^{E5})₂, OR^{E5}, S(═O)R^{E5}, S(═O)₂R^{E5}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{E4} radicals may be joined to one another and may form a ring; where the alkyl, alkoxy, alkenyl and alkynyl groups and the aromatic ring systems and heteroaromatic ring systems are each substituted by R^{E5} radicals; and where one or more CH₂ groups in the alkyl, alkoxy, alkenyl and alkynyl groups optionally are replaced by —R^{E5}C═CR^{E5}—, —C≡C—, Si(R^{E5})₂, C═O, C═NR^{E5}, —C(═O)O—, —C(═O)NR^{E5}—, NR^{E5}, P(═O)(R^{E5}), —O—, —S—, SO or SO₂;
R^{E5} is the same or different at each instance and is selected from H, D, F, Cl, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R^{E5} radicals may be joined to one another and may form a ring; and where the alkyl, alkoxy, alkenyl and alkynyl groups, aromatic ring systems and heteroaromatic ring systems optionally substituted by one or more radicals selected from F and CN;
and p are the same or different and are 0 or 1, where p=0 and o=0 mean that the X group indicated by p or o together with its bonds to the rings C¹, C² and C³ is absent;
a layer H1 which is disposed between the first electrode and the emitting layer and contains a compound of a formula (L-1), (L-2) or (L-3) 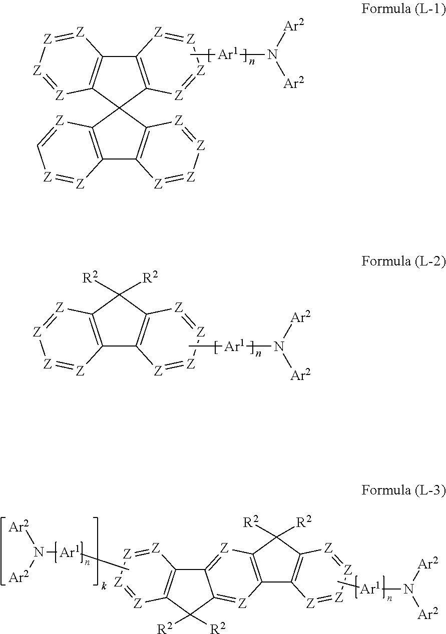
for which:
Z, when a —[Ar¹]ₙ—N(Ar²)₂ group is bonded thereto, is C, and Z, when no —[Ar¹]ₙ—N(Ar²)₂ group is bonded thereto, is the same or different at each instance and is N or CR¹;
Ar¹ is the same or different at each instance and is an aromatic ring system which has 6 to 40 aromatic ring atoms and is substituted by R³ radicals, or a heteroaromatic ring system which has 5 to 40 aromatic ring atoms and is substituted by R³ radicals;
Ar² is the same or different at each instance and is an aromatic ring system which has 6 to 40 aromatic ring atoms and is substituted by R³ radicals, or a heteroaromatic ring system which has 5 to 40 aromatic ring atoms and is substituted by R³ radicals;
R¹ is the same or different at each instance and is selected from H, D, F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R¹ radicals may be joined to one another and may form a ring; where the alkyl, alkoxy, alkenyl and alkynyl groups and the aromatic ring systems and heteroaromatic ring systems are each substituted by R⁴ radicals; and where one or more CH₂ groups in the alkyl, alkoxy, alkenyl and alkynyl groups optionally are replaced by —R⁴C═CR⁴—, —C≡C—, Si(R⁴)₂, C═O, C═NR⁴, —C(═O)O—, —C(═O)NR⁴—, NR⁴, P(═O)(R⁴), —O—, —S—, SO or SO₂;
R² is the same or different at each instance and is selected from H, D, F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R² radicals may be joined to one another and may form a ring; where the alkyl, alkoxy, alkenyl and alkynyl groups and the aromatic ring systems and heteroaromatic ring systems are each substituted by R⁴ radicals; and where one or more CH₂ groups in the alkyl, alkoxy, alkenyl and alkynyl groups optionally are replaced by —R⁴C═CR⁴—, —C≡C—, Si(R⁴)₂, C═O, C═NR⁴, —C(═O)O—, —C(═O)NR⁴—, NR⁴, P(═O)(R⁴), —O—, —S—, SO or SO₂;
R³ is the same or different at each instance and is selected from H, D, F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R³ radicals may be joined to one another and may form a ring; where the alkyl, alkoxy, alkenyl and alkynyl groups and the aromatic ring systems and heteroaromatic ring systems are each substituted by R⁴ radicals; and where one or more CH₂ groups in the alkyl, alkoxy, alkenyl and alkynyl groups optionally are replaced by —R⁴C═CR⁴—, —C≡C—, Si(R⁴)₂, C═O, C═NR⁴, —C(═O)O—, —C(═O)NR⁴—, NR⁴, P(═O)(R⁴), —O—, —S—, SO or SO₂;
R⁴ is the same or different at each instance and is selected from H, D, F, Cl, Br, I, C(═O)R⁵, CN, Si(R⁵)₃, N(R⁵)₂, P(═O)(R⁵)₂, OR⁵, S(═O)R⁵, S(═O)₂R⁵, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁴ radicals may be joined to one another and may form a ring; where the alkyl, alkoxy, alkenyl and alkynyl groups and the aromatic ring systems and heteroaromatic ring systems are each substituted by R⁵ radicals; and where one or more CH₂ groups in the alkyl, alkoxy, alkenyl and alkynyl groups optionally are replaced by —R⁵C═CR⁵—, —C≡C—, Si(R⁵)₂, C═O, C═NR⁵, —C(═O)O—, —C(═O)NR⁵—, NR⁵, P(═O)(R⁵), —O—, —S—, SO or SO₂;
R⁵ is the same or different at each instance and is selected from H, D, F, Cl, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R⁵ radicals may be joined to one another and may form a ring; and where the alkyl, alkoxy, alkenyl and alkynyl groups, aromatic ring systems and heteroaromatic ring systems optionally substituted by one or more radicals selected from F and CN;
n is the same or different at each instance and is 0, 1, 2, 3 or 4;
k is 0 or 1;
and
a layer H2 disposed between layer H1 and the emitting layer.

26. The electronic device according to claim 25, wherein the T group is B.

27. The electronic device according to claim 25, wherein the X group is the same at each instance and is NR^{E2}.

28. The electronic device according to claim 25, wherein R^{E2} is the same or different at each instance and is selected from aromatic ring systems which have 6 to 40 aromatic ring atoms and are each substituted by R^{E4} radicals, where two or more R^{E2} radicals may be joined to one another and may form a ring and where one or more R^{E2} radicals may be joined via their R^{E4} radicals to a ring selected from C¹, C² and C³ and may form a ring.

29. The electronic device according to claim 25, wherein R^{E3} is the same or different at each instance and is selected from H, D, F, CN, Si(R^{E4})₃, N(R^{E4})₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups, the aromatic ring systems and the heteroaromatic ring systems are each substituted by one or more R^{E4} radicals; and where one or more CH₂ groups in the alkyl or alkoxy groups optionally are replaced by —C≡C—, —R^{E4}C═CR^{E4}—, Si(R^{E4})₂, C═O, C═NR^{E4}, —NR^{E4}—, —O—, —S—, —C(═O)O— or —C(═O)NR^{E4}—.

30. The electronic device according to claim 25, wherein at least one R^{E3} radical in formula (E-1) is selected from alkyl groups which have 1 to 10 carbon atoms and are substituted by R^{E4} radicals, and N(R^{E4})₂.

31. The electronic device according to claim 25, wherein R^{E4} is the same or different at each instance and is selected from H, D, F, CN, Si(R^{E5})₃, N(R^{E5})₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups, the aromatic ring systems and the heteroaromatic ring systems are each substituted by one or more R^{E5} radicals; and where one or more CH₂ groups in the alkyl or alkoxy groups optionally are replaced by —C≡C—, —R^{E5}C═CR^{E5}—, Si(R^{E5})₂, C═O, C═NR^{E5}, —NR^{E5}—, —O—, —S—, —C(═O)O— or —C(═O)NR^{E5}—.

32. The electronic device according to claim 25, wherein one of the indices o and p is 1, and the other of the indices o and p is 0.

33. The electronic device according to claim 25, wherein the compound of the formula (E-1) conforms to one of the formulae (E-1-1-1-1-1) and (E-1-1-1-1-2) 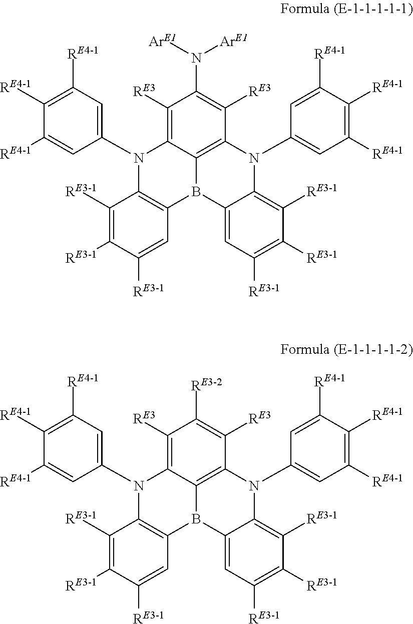
where R^{E3-1} is as defined for R^{E3}; and R^{E3-2} is selected from alkyl groups which have 1 to 10 carbon atoms and are substituted by R^{E4} radicals, preferably methyl, ethyl, isopropyl and tert-butyl, more preferably methyl; and R^{E4-1} is as defined for R^{E4}.

34. The electronic device according to claim 25, wherein layer H comprises a compound of the formula (L-1).

35. The electronic device according to claim 25, wherein the compound of the formula (L-1) conforms to a formula selected from the formulae (L-1-1-1) to (L-1-1-3) 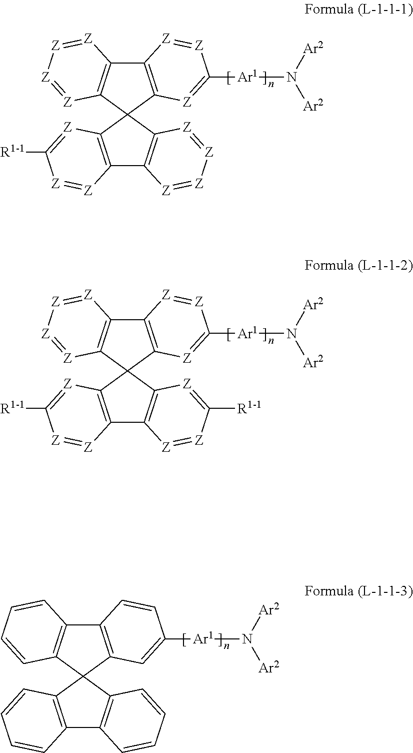
where R¹⁻¹ is the same or different at each instance and is selected from alkyl groups having 1 to 10 carbon atoms, and aromatic ring systems which have 6 to 40 aromatic ring atoms and are each substituted by R⁴ radicals, and where Z is CR¹, and where Z is CH, and where the other variables are as defined in claim 25.

36. The electronic device according to claim 25, wherein
R¹ and R³ are the same or different at each instance and are selected from H, D, F, CN, Si(R⁴)₃, N(R⁴)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms, where the alkyl and alkoxy groups, the aromatic ring systems and the heteroaromatic ring systems are each substituted by one or more R⁴ radicals; and where one or more CH₂ groups in the alkyl or alkoxy groups optionally are replaced by —C≡C—, —R⁴C═CR⁴—, Si(R⁴)₂, C═O, C═NR⁴, —NR⁴—, —O—, —S—, —C(═O)O— or —C(═O)NR⁴—; and further wherein
R² is the same or different at each instance and is selected from alkyl groups having 1 to 10 carbon atoms, aromatic ring systems which have 6 to 40 aromatic ring atoms and are substituted by R⁴ radicals, and heteroaromatic ring systems substituted by R⁴ radicals; and further wherein
R⁴ is the same or different at each instance and is selected from H, D, F, CN, Si(R⁵)₃, N(R⁵)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups, the aromatic ring systems and the heteroaromatic ring systems are each substituted by R⁵ radicals; and where one or more CH₂ groups in the alkyl or alkoxy groups optionally are replaced by —C≡C—, —R⁵C═CR⁵—, Si(R⁵)₂, C═O, C═NR⁵, —NR⁵—, —O—, —S—, —C(═O)O— or —C(═O)NR⁵—.

37. The electronic device according to claim 25, wherein Ar¹ groups are the same or different and are selected from divalent groups derived from benzene, biphenyl, terphenyl, naphthalene, fluorene, indenofluorene, indenocarbazole, spirobifluorene, dibenzofuran, dibenzothiophene, and carbazole, each of which optionally substituted by one or more R³ radicals.

38. The electronic device according to claim 25, wherein Ar² is the same or different at each instance and is selected from phenyl, biphenyl, terphenyl, quaterphenyl, naphthyl, fluorenyl, especially 9,9′-dimethylfluorenyl and 9,9′-diphenylfluorenyl, benzofluorenyl, spirobifluorenyl, indenofluorenyl, indenocarbazolyl, dibenzofuranyl, dibenzothiophenyl, carbazolyl, benzofuranyl, benzothiophenyl, benzofused dibenzofuranyl, benzofused dibenzothiophenyl, naphthyl-substituted phenyl, fluorenyl-substituted phenyl, spirobifluorenyl-substituted phenyl, dibenzofuranyl-substituted phenyl, dibenzothiophenyl-substituted phenyl, carbazolyl-substituted phenyl, pyridyl-substituted phenyl, pyrimidyl-substituted phenyl, and triazinyl-substituted phenyl, where the groups may each be substituted by one or more R³ radicals.

39. The electronic device according to claim 25, wherein layer H2 adjoins the emitting layer directly on the anode side.

40. The electronic device according to claim 25, wherein layer H2 comprises a compound that conforms to a formula selected from the formulae (L-1-2), (L-2-2), (L-3-1), (L-3-2), (L-4) and (L-5) 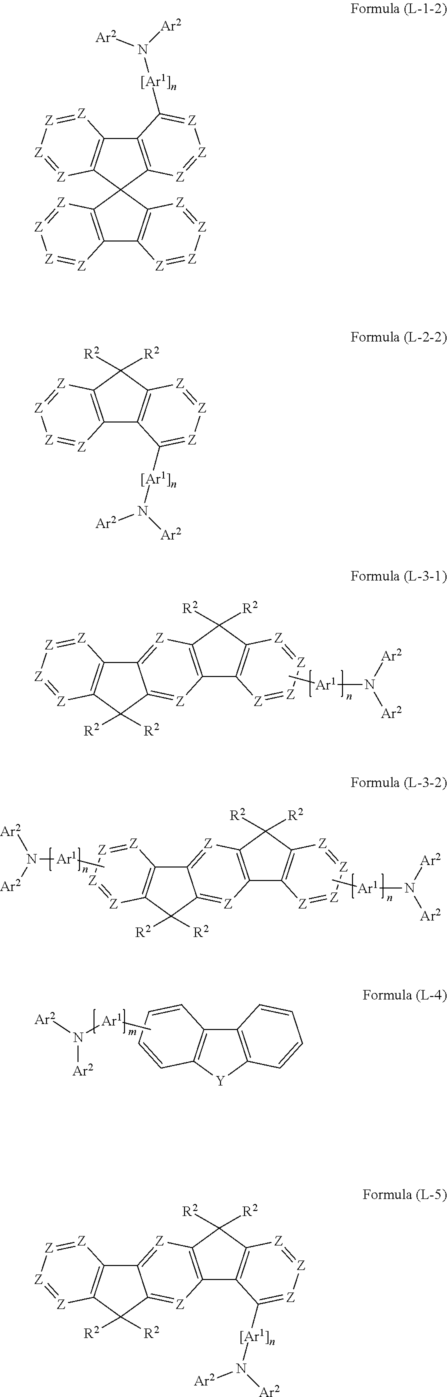
where Z is CR¹, and Y is O, S or NR³; and m is 0, 1, 2 or 3; and the substituted positions on the benzene rings in formula (L-4) may each be substituted by an R³ radical, and the other variables are as defined in claim 25.

41. The electronic device according to claim 25, wherein the electronic device comprises, between anode and cathode:
directly adjoining the anode, a hole injection layer (HIL), and
directly adjoining the cathode side of the HIL, layer H1, and
directly adjoining the cathode side of layer H1, layer H2, and
directly adjoining the cathode side of layer H2, the emitting layer, and
on the cathode side of the emitting layer, one or more electron-transporting layers.

42. The electronic device according to claim 25, wherein the emitting layer, in addition to the compound of the formula (E-1), comprises a matrix compound which is an anthracene compound.

43. The electronic device according to claim 25, wherein the electronic device is an organic electroluminescent device.

44. The electronic device according to claim 25, wherein the electronic device emits blue light.

45. The electronic device according to claim 25, wherein the electronic device is an organic electroluminescent device that emits light through the cathode.

46. The electronic device according to claim 25, wherein the electronic device comprises two or three identical or different layer sequences stacked one on top of another, where each of the layer sequences comprises the following layers: hole injection layer, hole transport layer, electron blocker layer, emitting layer, and electron transport layer, and wherein at least one of the layer sequences comprises
an emitting layer E comprising a compound of the formula (E-1)
a layer H1 which is disposed between the first electrode and the emitting layer and contains a compound of the formula (L-1), (L-2) or (L-3), and
a layer H2 disposed between layer H1 and the emitting layer.

47. A process for producing a device according to claim 25, comprising first the providing of a substrate with an anode, the applying of layer H1 in a step that follows later, the applying of layer H2 in a step that follows later, the applying of the emitting layer in a step that follows later, and the applying of the anode in a step that follows later.

48. A Process comprising including the electronic device according to claim 25 in displays, as a light source in lighting applications or as a light source in medical and/or cosmetic applications.
